(19) United States
(12) Patent Application Publication
(10) Pub. No.: US 2017/0186975 A1
(43) Pub. Date: Jun. 29, 2017

(54) ORGANIC LIGHT-EMITTING DEVICE

(71) Applicant: Samsung Display Co., Ltd., Yongin-si (KR)

(72) Inventors: Younsun Kim, Yongin-si (KR); Seulong Kim, Yongin-si (KR); Jungsub Lee, Yongin-si (KR); Jino Lim, Yongin-si (KR); Hyein Jeong, Yongin-si (KR); Dongwoo Shin, Yongin-si (KR)

(21) Appl. No.: 15/229,751

(22) Filed: Aug. 5, 2016

(30) Foreign Application Priority Data
Dec. 29, 2015 (KR) 10-2015-0188914

(51) Int. Cl. H01L 51/00; C09K 11/06; C09K 11/02

(52) U.S. Cl. CPC H01L 51/0072; C09K 11/025; C09K 11/06; H01L 51/0059; H01L 51/006; H01L 51/0061; H01L 51/0085; H01L 51/0081; H01L 51/0077; H01L 51/0067; H01L 51/0052; H01L 51/0071; H01L 51/0058; H01L 51/0073; H01L 51/5024

(57) ABSTRACT

An organic light-emitting device includes: a first electrode; a second electrode; and an organic layer between the first electrode and the second electrode, the organic layer including an emission layer, wherein the organic layer includes a first compound represented by Formula 1 and a second compound represented by Formula 2, wherein a case where the first compound is 4,4′-bis(N-carbazolyl)-1,1′-biphenyl(CBP) is excluded:

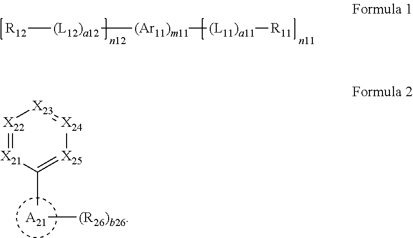

### CROSS-REFERENCE TO RELATED APPLICATION

This application claims priority to and the benefit of Korean Patent Application No. 10-2015-0188914, filed on Dec. 29, 2015, in the Korean Intellectual Property Office, the entire content of which is incorporated herein by reference.

### BACKGROUND

1. Field

One or more aspects of embodiments of the present disclosure relate to an organic light-emitting device.

2. Description of the Related Art

Organic light-emitting devices are self-emission devices that have wide viewing angles, high contrast ratios, short response times, and excellent luminance, driving voltage, and response speed characteristics, and can produce full-color images.

An organic light-emitting device may include a first electrode disposed (e.g., positioned) on a substrate, and a hole transport region, an emission layer, an electron transport region, and a second electrode, which are sequentially disposed on the first electrode. Holes provided from, for example, the first electrode may move toward the emission layer through the hole transport region, and electrons provided from, for example, the second electrode may move toward the emission layer through the electron transport region. Carriers, such as holes and electrons, may then recombine in the emission layer to produce excitons. These excitons transition from an excited state to a ground state, thereby generating light.

### SUMMARY

One or more aspects of embodiments of the present disclosure are directed toward an organic light-emitting device.

Additional aspects will be set forth in part in the description which follows and, in part, will be apparent from the description, or may be learned by practice of the presented embodiments.

According to one or more embodiments, an organic light-emitting device includes a first electrode, a second electrode, and an organic layer between the first electrode and the second electrode, the organic layer including an emission layer,

wherein the organic layer includes a first compound represented by Formula 1 and a second compound represented by Formula 2, wherein a case where the first compound is 4,4′-bis(N-carbazolyl)-1,1′-biphenyl (CBP) is excluded:

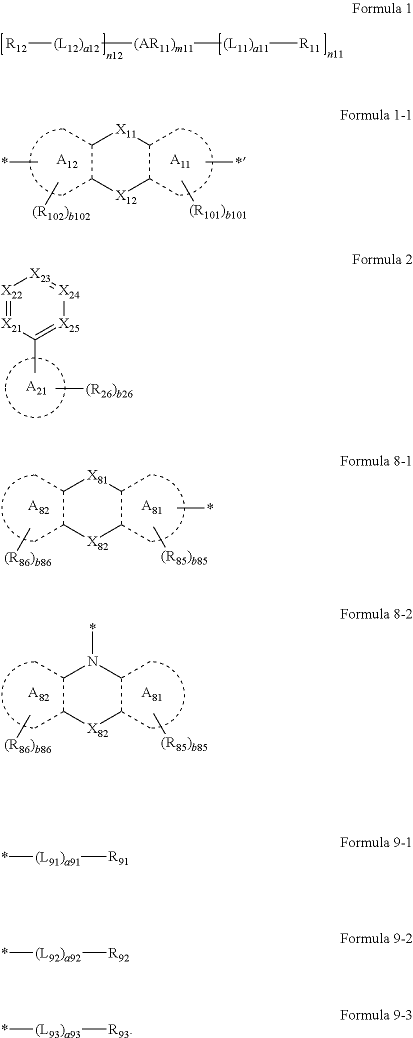

In Formulae 1, 1-1, 2, 8-1, 8-2, and 9-1 to 9-3,

Ar₁₁ may be a group represented by Formula 1-1,

m11 may be selected from 1 and 2,

A₁₁, A₁₂, A₈₁, and A₈₂ may each independently be selected from a C₅-C₂₀ carbocyclic group and a C₁-C₂₀ heterocyclic group,

X₁₁ may be selected from N[(L₁₃)ₐ₁₃-R₁₃], C[(L₁₃)ₐ₁₃-R₁₃][(L₁₄)ₐ₁₄-R₁₄], O, and S,

X₁₂ may be selected from a single bond, N[(L₁₅)ₐ₁₅-R₁₅], C[(L₁₅)ₐ₁₅-R₁₅][(L₁₆)ₐ₁₆-R₁₆], O, and S,

X₈₁ may be N[(L₈₁)ₐ₈₁-R₈₁], C[(L₈₁)ₐ₈₁-R₈₁][(L₈₂)ₐ₈₂-R₈₂], O, and S,

X₈₂ may be selected from a single bond, N[(L₈₃)ₐ₈₃-R₈₃], C[(L₈₃)ₐ₈₃-R₈₃][(L₈₄)ₐ₈₄-R₈₄], O, and S,

L₁₁ to L₁₆ and L₈₁ to L₈₄ may each independently be selected from *—O—*′, *—S—*′, *—C(═O)—*′, *—P(═O)(Q₁)-*′, *—Si(Q₁)(Q₂)-*′, a substituted or unsubstituted C₆-C₆₀ arylene group, and a substituted or unsubstituted C₁-C₆₀ heteroarylene group,

a11 to a16 and a81 to a84 may each independently be selected from 0, 1, 2, and 3,

R₁₁ to R₁₆ may each independently be selected from a group represented by Formula 8-1, a group represented by Formula 8-2, hydrogen, deuterium, —F, —Cl, —Br, —I, a cyano group, a nitro group, a substituted or unsubstituted C₁-C₆₀ alkyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, —Si(Q₁)(Q₂)(Q₃), —B(Q₁)(Q₂), —C(═O)(Q₁), —S(═O)₂(Q₁), and —P(═O)(Q₁)(Q₂), wherein R₁₃ and R₁₄ may be optionally connected to each other to form a ring, and R₁₅ and R₁₆ may be optionally connected to each other to form a ring,

n11 and n12 may each independently be selected from 0, 1, 2, 3, and 4,

R₈₁ to R₈₄ may each independently be selected from hydrogen, deuterium, —F, —Cl, —Br, —I, a cyano group, a nitro group, a substituted or unsubstituted C₁-C₆₀ alkyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, —Si(Q₁)(Q₂)(Q₃), —B(Q₁)(Q₂), —C(═O)(Q₁), —S(═O)₂(Q₁), and —P(═O)(Q₁)(Q₂), wherein R₈₁ and R₈₂ may be optionally connected to each other to form a ring, and R₈₃ and R₈₄ may be optionally connected to each other to form a ring,

R₁₀₁, R₁₀₂, R₈₅, and R₈₆ may each independently be selected from hydrogen, deuterium, —F, —Cl, —Br, —I, a cyano group, a nitro group, a substituted or unsubstituted C₁-C₆₀ alkyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, —Si(Q₁)(Q₂)(Q₃), —B(Q₁)(Q₂), —C(═O)(Q₁), —S(═O)₂(Q₁), and —P(═O)(Q₁ (Q₂),

b101, b102, b85, and b86 may each independently be selected from 1, 2, 3, 4, 5, and 6,

A₂₁ may be selected from a C₆-C₂₀ arene group and a C₁-C₂₀ heteroarene group,

X₂₁ may be selected from N and C(R₂₁), X₂₂ may be selected from N and C(R₂₂), X₂₃ may be selected from N and C(R₂₃), X₂₄ may be selected from N and C(R₂₄), and X₂₅ may be selected from N and C(R₂₅), wherein at least one selected from X₂₁ to X₂₅ may be N,

R₂₁ to R₂₆ may each independently be selected from a group represented by any of Formulae 9-1 to 9-3, hydrogen, deuterium, —F, —Cl, —Br, —I, a hydroxyl group, a cyano group, a nitro group, an amidino group, a hydrazino group, a hydrazono group, a substituted or unsubstituted C₁-C₆₀ alkyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₁)(Q₂), —B(Q₁)(Q₂), —C(═O)(Q₁), —S(═O)₂(Q₁), and —P(═O)(Q₁)(Q₂), and at least one selected from R₂₁ to R₂₆ may be selected from a group represented by Formula 9-1 and a group represented by Formula 9-2,

b26 may be selected from 1, 2, 3, 4, 5, and 6,

L₉₁ may be selected from a C₆-C₆₀ arylene group and a C₁-C₆₀ heteroarylene group, each substituted with at least one selected from a C₁-C₆₀ alkyl group and a C₃-C₁₀ cycloalkyl group,

L₉₂ and L₉₃ may each independently be selected from a substituted or unsubstituted C₆-C₆₀ arylene group and a substituted or unsubstituted C₁-C₆₀ heteroarylene group,

a91 may be selected from 1 and 2,

a92 and a93 may each independently be selected from 0, 1, and 2,

R₉₁ and R₉₃ may each independently be selected from a substituted or unsubstituted C₆-C₆₀ aryl group and a substituted or unsubstituted C₁-C₆₀ heteroaryl group,

R₉₂ may be selected from a C₆-C₆₀ aryl group and a C₁-C₆₀ heteroaryl group, each substituted with at least one selected from a C₁-C₆₀ alkyl group and a C₃-C₁₀ cycloalkyl group,

Q₁ to Q₃ may each independently be selected from hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, and a terphenyl group, and

* and *′ may each independently indicate a binding site to a neighboring atom.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic cross-sectional view of an organic light-emitting device according to an embodiment;

FIG. 2 is a schematic cross-sectional view of an organic light-emitting device according to another embodiment;

FIG. 3 is a schematic cross-sectional view of an organic light-emitting device according to another embodiment; and

FIG. 4 is a schematic cross-sectional view of an organic light-emitting device according to another embodiment.

### DETAILED DESCRIPTION

The present disclosure will now be described more fully with reference to example embodiments. The disclosure may, however, be embodied in many different forms and should not be construed as being limited to the embodiments set forth herein; rather, these embodiments are provided so that this disclosure will be thorough and complete, and will fully convey the concept of the disclosure to those skilled in the art. Advantages and features of the present disclosure, as well as methods of achieving them, will become apparent by reference to the described embodiments, together with the accompanying drawings. This present disclosure may, however, be embodied in many different forms and should not be limited to the example embodiments.

Hereinafter, embodiments are described in more detail by referring to the attached drawings, and in the drawings, like reference numerals denote like elements, and redundant explanations thereof will not be provided herein.

As used herein, the singular forms “a,” “an” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or component is referred to as being “on” or “onto” another layer, region, or component, it may be directly or indirectly formed on the other layer, region, or component. That is, for example, intervening layers, regions, or components may be present. In contrast, when an element is referred to as being “directly on” or “directly contacting” another element, there are no intervening elements present.

Sizes of components in the drawings may be exaggerated for convenience of explanation. In other words, since sizes and thicknesses of components in the drawings are arbitrarily illustrated for convenience of explanation, the following embodiments are not limited thereto.

The expression “an (organic layer) includes a first compound” may refer to a case in which an (organic layer) includes a first compound represented by Formula 1 and a case in which an (organic layer) includes two or more different first compounds represented by Formula 1.

The term “organic layer” used herein refers to a single and/or a plurality of layers between a first electrode and a second electrode in an organic light-emitting device. A material included in the “organic layer” is not limited to an organic material.

Expressions such as “at least one of,” “one of,” and “selected from,” when preceding a list of elements, modify the entire list of elements and do not modify the individual elements of the list. Further, the use of “may” when describing embodiments of the present invention refers to “one or more embodiments of the present invention.”

According to one or more embodiments, an organic light-emitting device may include a first electrode, a second electrode, and an organic layer between the first electrode and the second electrode, the organic layer including an emission layer,

wherein the organic layer may include a first compound represented by Formula 1 and a second compound represented by Formula 2, and wherein a case where the first compound is 4,4′-bis(N-carbazolyl)-1,1′-biphenyl (CBP) may be excluded:

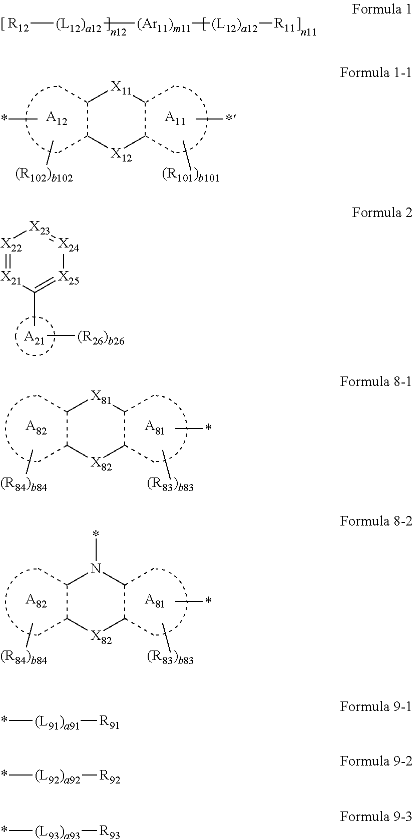

Ar₁ in Formula 1 may be a group represented by Formulae 1-1; A₁₁, A₁₂, X₁₁, X₁₂, R₁₀₁, R₁₀₂, b101, and b102 in Formula 1-1 are the same as described below, and * and *′ each independently indicate a binding site to a neighboring atom.

In Formula 1, m11 indicates the number of Ar₁₁(s), and m11 may be selected from 1 and 2.

A₁₁, A₁₂, A₈₁, and A₈₂ in Formulae 1-1, 8-1, and 8-2 may each independently be selected from a C₅-C₂₀ carbocyclic group and a C₁-C₂₀ heterocyclic group.

For example, A₁₁, A₁₂, A₈₁, and A₈₂ in Formulae 1-1, 8-1, and 8-2 may each independently be selected from a benzene group, a naphthalene group, a phenanthrene group, an anthracene group, a triphenylene group, a pyrene group, a chrysene group, a furan group, a thiophene group, a pyrrole group, a pyridine group, a pyrazine group, a pyrimidine group, a pyridazine group, a triazine group, a quinoline group, an isoquinoline group, a 2,6-naphthyridine group, a 1,8-naphthyridine group, a 1,5-naphthyridine group, a 1,6-naphthyridine group, a 1,7-naphthyridine group, a 2,7-naphthyridine group, a quinoxaline group, a quinazoline group, a phenanthridine group, a phenanthroline group, a benzofuran group, a benzothiophene group, an indene group, an indole group, a furopyridine group, a thienopyridine group, a cyclopentapyridine group, a pyrrolopyridine group, a dibenzofuran group, a dibenzothiophene group, a fluorene group, a carbazole group, a benzofuropyrrole group, a benzothienopyrrole group, an indenopyrrole group, an indolopyrrole group, a benzofurothiophene group, a benzothienothiophene group, an indenothiophene group, an indolothiophene group, a benzofurofuran group, a benzothienofuran group, an indenofuran group, an indolofuran group, a benzofuropyridine group, a benzothienopyridine group, an indenopyridine group, an indolopyridine group, a benzofuropyrimidine group, a benzothienopyrimidine group, an indenopyrimidine group, an indolopyrimidine group, a benzofuroindole group, a benzothienoindole group, an indenoindole group, an indoloindole group, a benzofurobenzofuran group, a benzothienobenzofuran group, an indenobenzofuran group, an indolobenzofuran group, a benzofurobenzothiophene group, a benzothienobenzothiophene group, an indenobenzothiophene group, an indolobenzothiophene group, a benzofuroquinoline group, a benzothienoquinoline group, an indenoquinoline group, an indoloquinoline group, a benzonaphthofuran group, a benzonaphthothiophene group, a benzofluorene group, a benzocarbazole group, a dinaphthofuran group, a dinaphthothiophene group, a dibenzofluorene group, a dibenzocarbazole group, a benzoxazole group, a benzothiazole group, a benzimidazole group, a naphthofuran group, a naphthothiophene group, a cyclopentanaphthalene group, a spiro-bifluorene group, and a spiro-fluorene-indene group, but are not limited thereto.

In various embodiments, A₁₁ and A₈₁ in Formulae 1-1, 8-1, and 8-2 may each independently be selected from a benzene group, a naphthalene group, a pyridine group, a pyrimidine group, a pyrazine group, a quinoline group, an isoquinoline group, and a phenanthroline group, and

A₁₂ and A₈₂ may each independently be selected from a benzene group, a naphthalene group, a pyridine group, a pyrimidine group, a pyrazine group, a quinoline group, an isoquinoline group, a phenanthroline group, a benzofuran group, a benzothiophene group, an indene group, an indole group, a furopyridine group, a thienopyridine group, a cyclopentapyridine group, a pyrrolopyridine group, a dibenzofuran group, a dibenzothiophene group, a fluorene group, a carbazole group, a benzofuropyridine group, a benzothienopyridine group, an indenopyridine group, an indolopyridine group, a benzofuropyrimidine group, a benzothienopyrimidine group, an indenopyrimidine group, an indolopyrimidine group, a benzonaphthofuran group, a benzonaphthothiophene group, a benzofluorene group, a benzocarbazole group, a dinaphthofuran group, a dinaphthothiophene group, a dibenzofluorene group, a dibenzocarbazole group, a benzoxazole group, a benzothiazole group, a benzimidazole group, a naphthofuran group, and a naphthothiophene group, but are not limited thereto.

X₁₁ in Formula 1-1 may be selected from N[(L₁₃)ₐ₁₃-R₁₃], C[(L₁₃)ₐ₁₃-R₁₃][(L₁₄)ₐ₁₄-R₁₄], O, and S,

X₁₂ may be selected from a single bond, N[(L₁₅)ₐ₁₅-R₁₅], C[(L₁₅)ₐ₁₅-R₁₅][(L₁₆)ₐ₁₆-R₁₆], O, and S,

where L₁₃ to L₁₆, a13 to a16, R₁₃, and R₁₆ are the same as described below.

For example, X₁₁ in Formula 1-1 may be N[(L₁₃)ₐ₁₃-R₁₃], and

X₁₂ may be a single bond, but embodiments are not limited thereto.

In various embodiments, X₁₁ in Formula 1-1 may be C[(L₁₃)ₐ₁₃-R₁₃][(L₁₄)ₐ₁₄-R₁₄], and

X₁₂ may be a single bond, but embodiments are not limited thereto.

In various embodiments, X₁₁ in Formula 1-1 may be 0, and

X₁₂ may be a single bond, but embodiments are not limited thereto.

In various embodiments, X₁₁ in Formula 1-1 may be S, and

X₁₂ may be a single bond, but embodiments are not limited thereto.

X₈₁ in Formulae 8-1 and 8-2 may be selected from N[(L₈₁)ₐ₈₁-R₈₁], C[(L₈₁)ₐ₈₁-R₈₁][(L₈₂)ₐ₈₂-R₈₂], O, and S,

X₈₂ may be selected from a single bond, N[(L₈₃)ₐ₈₃-R₈₃], C[(L₈₃)ₐ₈₃-R₈₃][(L₈₄)ₐ₈₄-R₈₄], O, and S,

where L₈₁ to L₈₄, a81 to a84, and R₈₁ to R₈₄ are the same as described below.

For example, X₈₁ in Formulae 8-1 and 8-2 may be N[(L₈₁)ₐ₈₁-R₈₁], and

X₈₂ may be a single bond, but embodiments are not limited thereto.

L₁₁ to L₁₆ and L₈₁ to L₈₄ in Formulae 1, 1-1, 1-2, 8-1, and 8-2 may each independently be selected from *—O—*′, *—S—*′, *—C(═O)—*′, *—P(═O)(Q₁)-*′, *—Si(Q₁)(Q₂)-*′, a substituted or unsubstituted C₆-C₆₀ arylene group, and a substituted or unsubstituted C₁-C₆₀ heteroarylene group,

wherein Q₁ and Q₂ may each independently be selected from hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, and a terphenyl group.

For example, L₁₁ to L₁₆ and L₈₁ to L₈₄ in Formulae 1, 1-1, 1-2, 8-1, and 8-2 may each independently be selected from the group consisting of:

*—Si(CH₃)₂*′, *—Si(CH₃)(Ph)-*′, *—Si(Ph)₂-*′, a phenylene group, a naphthylene group, a phenanthrenylene group, an anthracenylene group, a triphenylenylene group, a pyrenylene group, a chrysenylene group, a pyridinylene group, a pyrazinylene group, a pyrimidinylene group, a quinolinylene group, an isoquinolinylene group, a benzoquinolinylene group, a phthalazinylene group, a naphthyridinylene group, a quinoxalinylene group, a quinazolinylene group, a phenanthridinylene group, an acridinylene group, a phenanthrolinylene group, and a triazinylene group;

a phenylene group, a naphthylene group, a phenanthrenylene group, an anthracenylene group, a triphenylenylene group, a pyrenylene group, a chrysenylene group, a pyridinylene group, a pyrazinylene group, a pyrimidinylene group, a quinolinylene group, an isoquinolinylene group, a benzoquinolinylene group, a phthalazinylene group, a naphthyridinylene group, a quinoxalinylene group, a quinazolinylene group, a phenanthridinylene group, an acridinylene group, a phenanthrolinylene group, and a triazinylene group, each substituted with at least one selected from deuterium, —F, —Cl, —Br, —I, a cyano group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂); and

a phenylene group, a naphthylene group, a phenanthrenylene group, an anthracenylene group, a triphenylenylene group, a pyrenylene group, a chrysenylene group, a pyridinylene group, a pyrazinylene group, a pyrimidinylene group, a quinolinylene group, an isoquinolinylene group, a benzoquinolinylene group, a phthalazinylene group, a naphthyridinylene group, a quinoxalinylene group, a quinazolinylene group, a phenanthridinylene group, an acridinylene group, a phenanthrolinylene group, and a triazinylene group, each substituted with at least one selected from a cyclopentyl group, a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, and a dibenzocarbazolyl group, each substituted with at least one selected from deuterium, —F, —Cl, —Br, —I, a cyano group, a C₁-C₂₀ alkyl group, a C₁-C₂₀ alkoxy group, a phenyl group, a biphenyl group, and a terphenyl group,

wherein Q₃₁ to Q₃₃ may each independently be selected from hydrogen, a methyl group, an ethyl group, an n-propyl group, an iso-propyl group, a tert-butyl group, a phenyl group, a biphenyl group, and a terphenyl group, but embodiments are not limited thereto.

In various embodiments, L₁₁ to L₁₆ and L₈₁ to L₈₄ in Formulae 1, 1-1, 1-2, 8-1, and 8-2 may each independently be selected from the group consisting of:

*—Si(CH₃)₂*′, *—Si(Ph)₂-*′, a phenylene group, a naphthylene group, a pyridinylene group, a pyrazinylene group, a pyrimidinylene group, a quinolinylene group, an isoquinolinylene group, a naphthyridinylene group, a quinoxalinylene group, and a triazinylene group;

a phenylene group, a naphthylene group, a pyridinylene group, a pyrazinylene group, a pyrimidinylene group, a quinolinylene group, an isoquinolinylene group, a naphthyridinylene group, a quinoxalinylene group, and a triazinylene group, each substituted with at least one selected from deuterium, —F, —Cl, —Br, —I, a cyano group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a dibenzofuranyl group, a dibenzothiophenyl group, a carbazolyl group, a triazinyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂); and

a phenylene group, a naphthylene group, a pyridinylene group, a pyrazinylene group, a pyrimidinylene group, a quinolinylene group, an isoquinolinylene group, a naphthyridinylene group, a quinoxalinylene group, and a triazinylene group, each substituted with at least one selected from a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a dibenzofuranyl group, a dibenzothiophenyl group, a carbazolyl group, and a triazinyl group, each substituted with at least one selected from deuterium, —F, —Cl, —Br, —I, a cyano group, a C₁-C₂₀ alkyl group, a C₁-C₂₀ alkoxy group, and a phenyl group,

wherein Q₃₁ to Q₃₃ may each independently be selected from hydrogen, a methyl group, an ethyl group, an n-propyl group, an iso-propyl group, a tert-butyl group, a phenyl group, a biphenyl group, and a terphenyl group, but embodiments are not limited thereto.

In various embodiments, L₁₁ to L₁₆ and L₈₁ to L₈₄ in Formulae 1, 1-1, 1-2, 8-1, and 8-2 may each independently be selected from *—Si(CH₃)₂*′, *—Si(Ph)₂-*′, and a group represented by any of Formulae 3-1 to 3-13 and 3-16 to 3-163, but are not limited thereto:

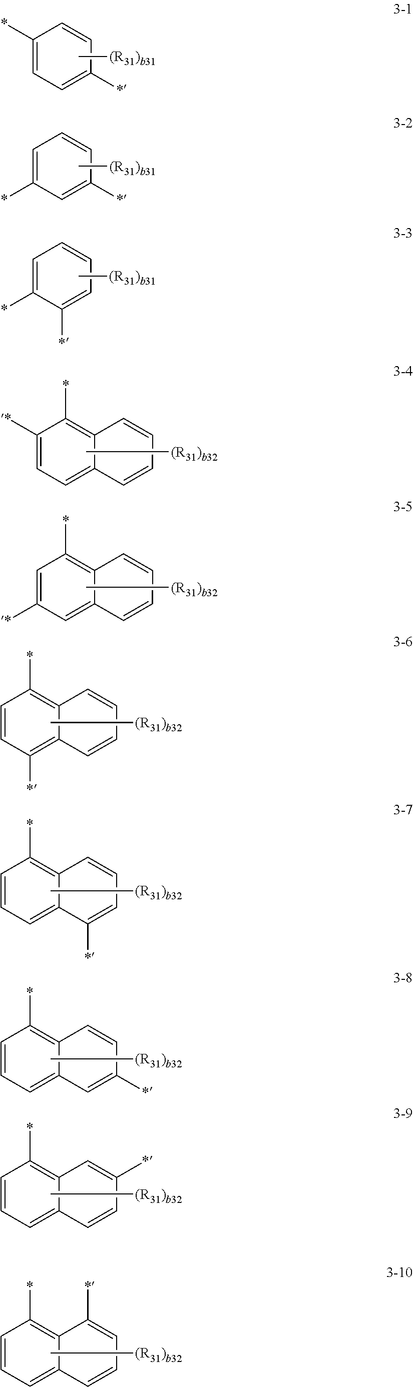

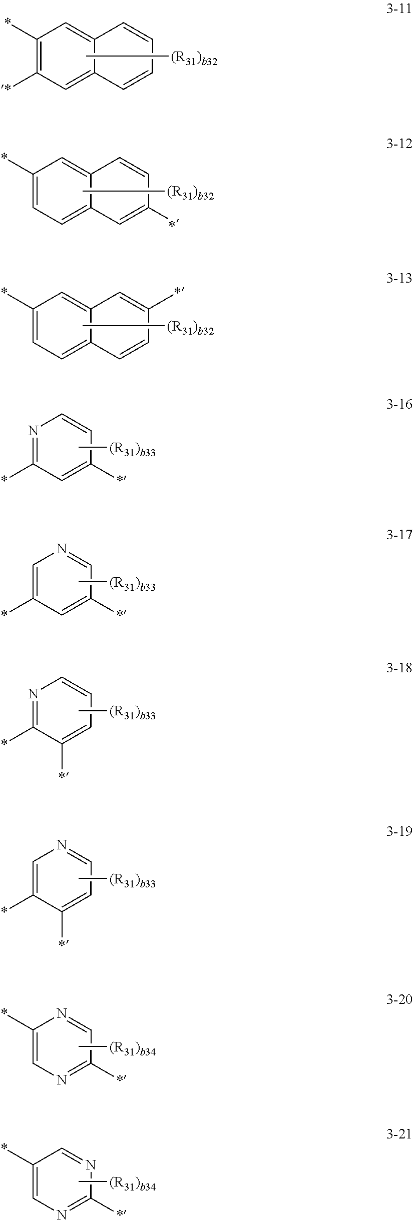

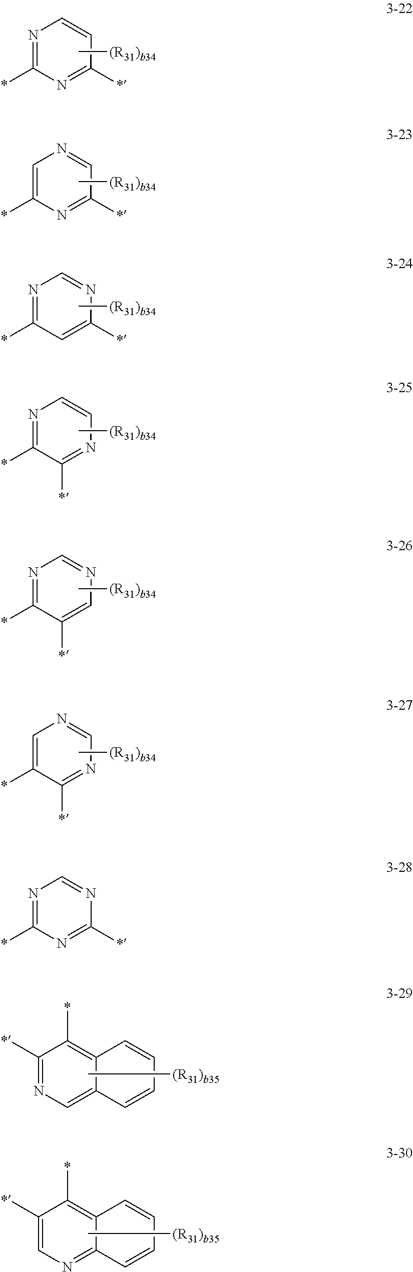

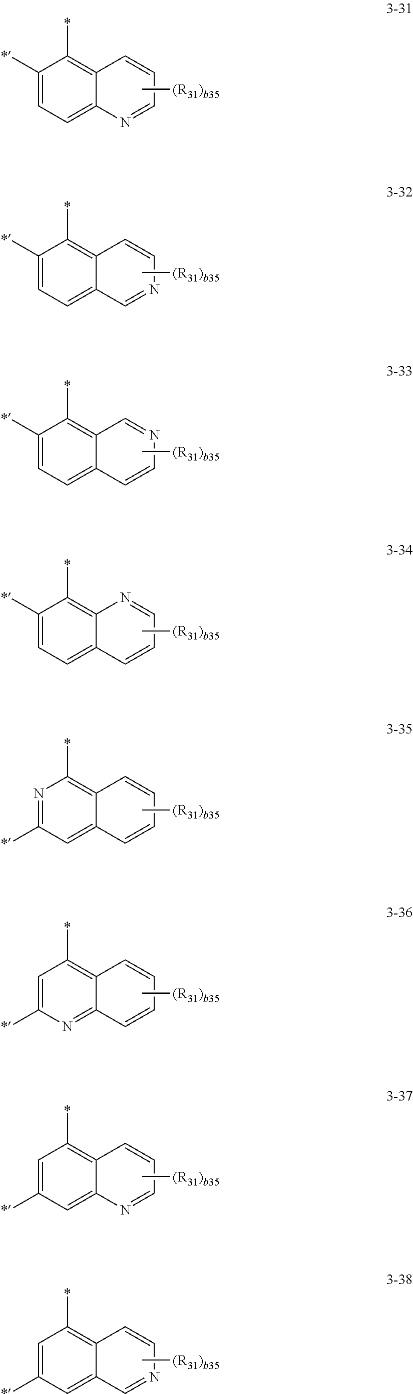

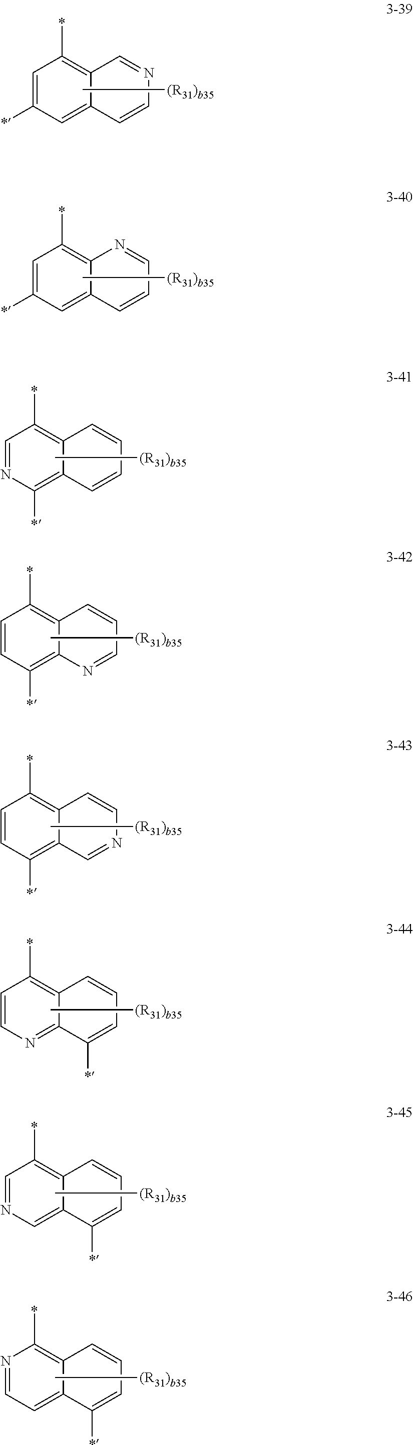

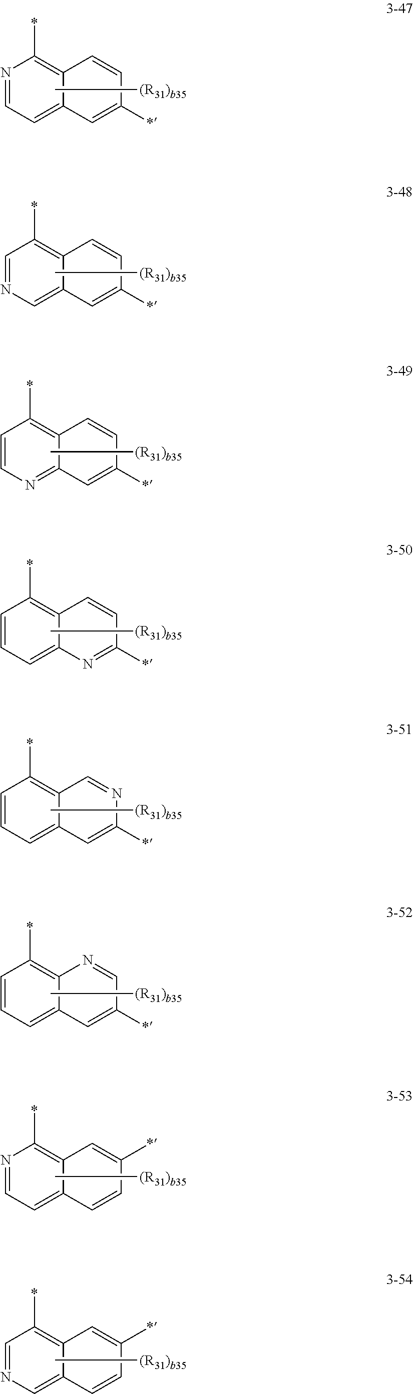

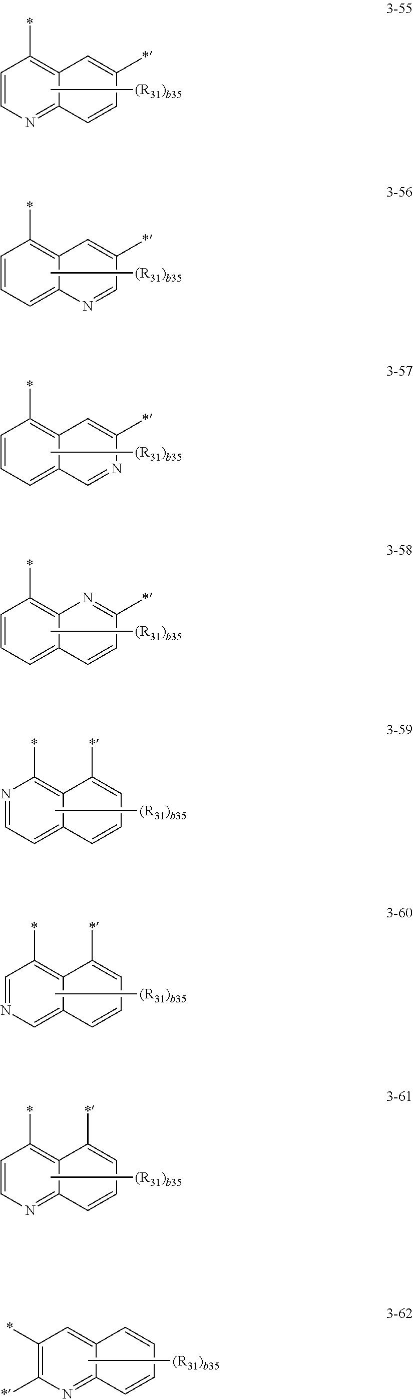

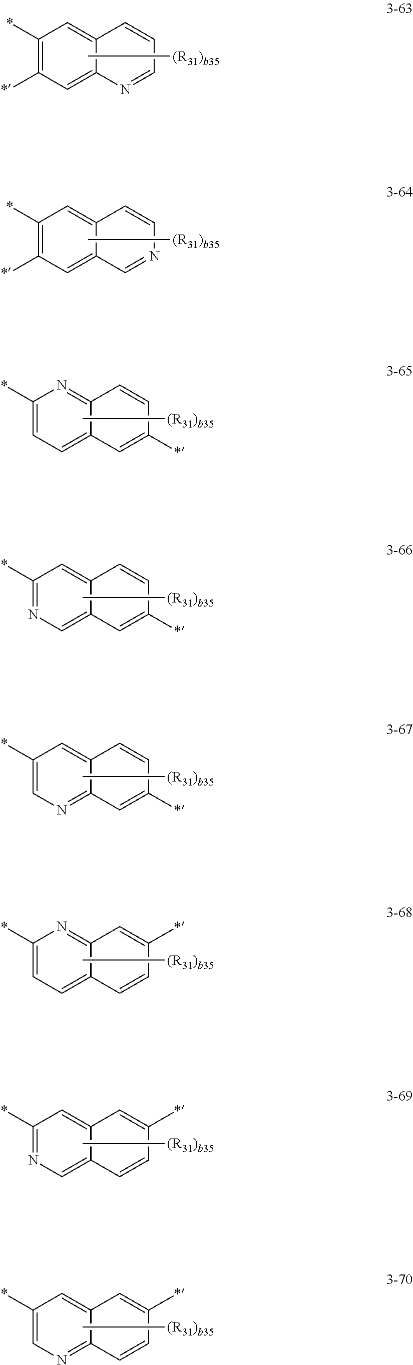

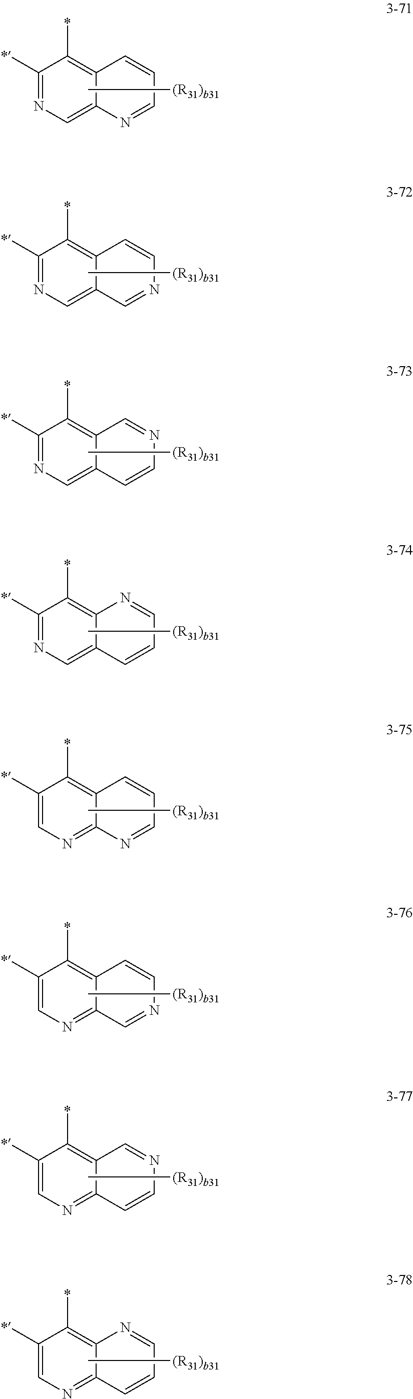

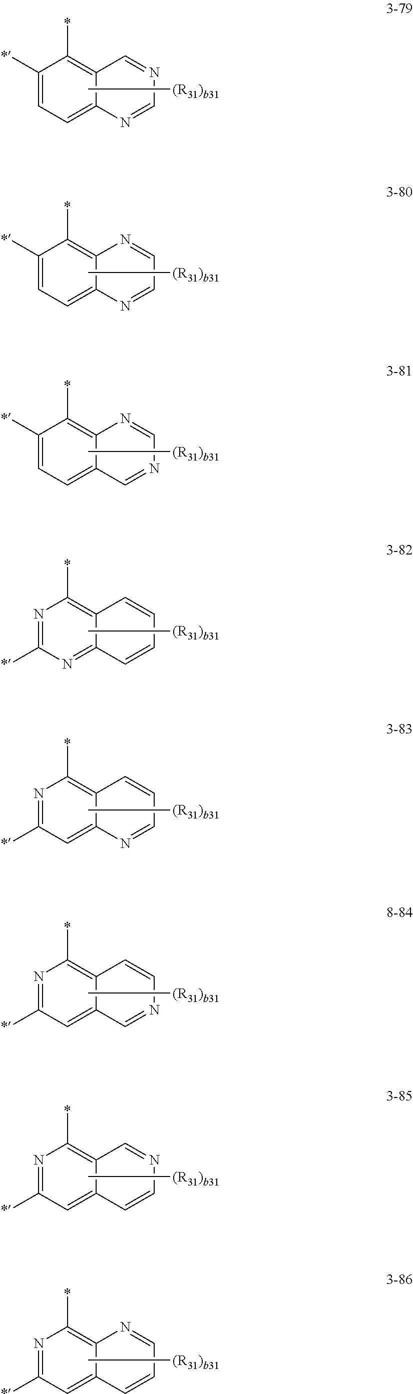

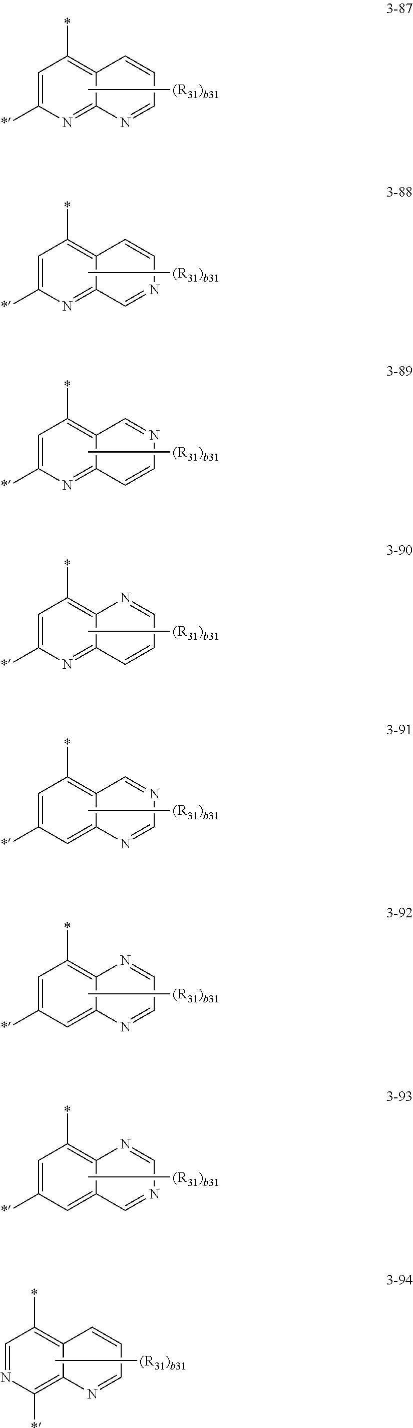

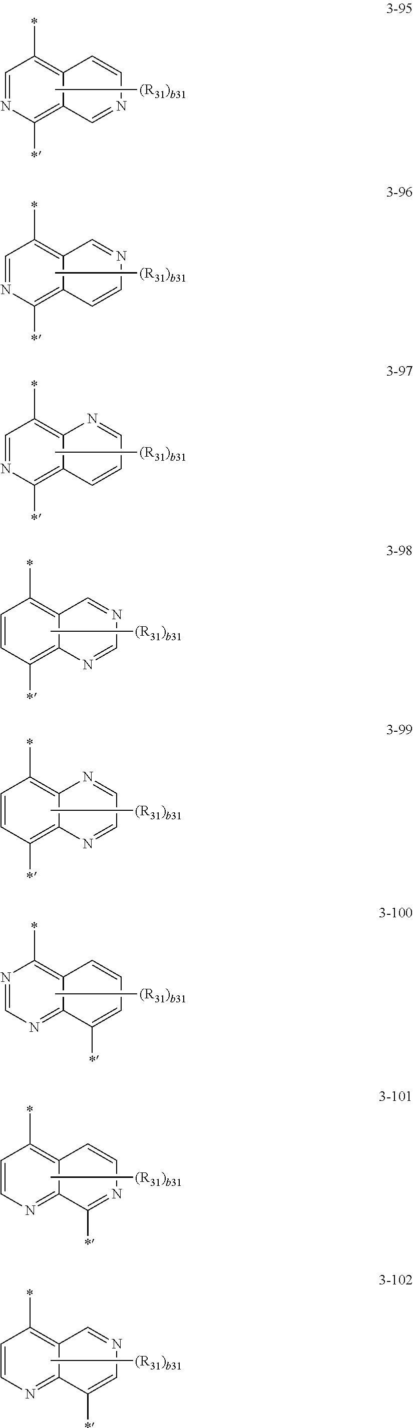

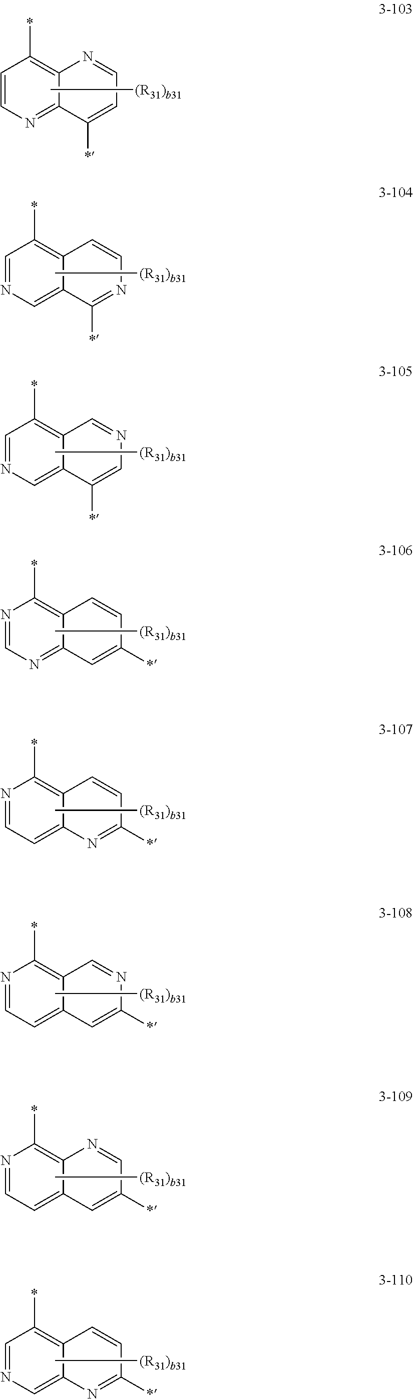

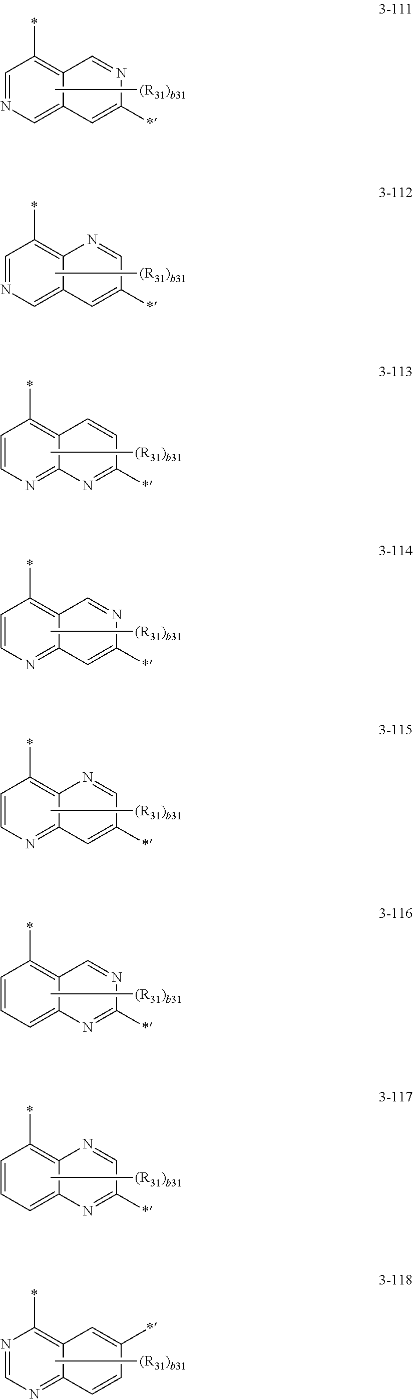

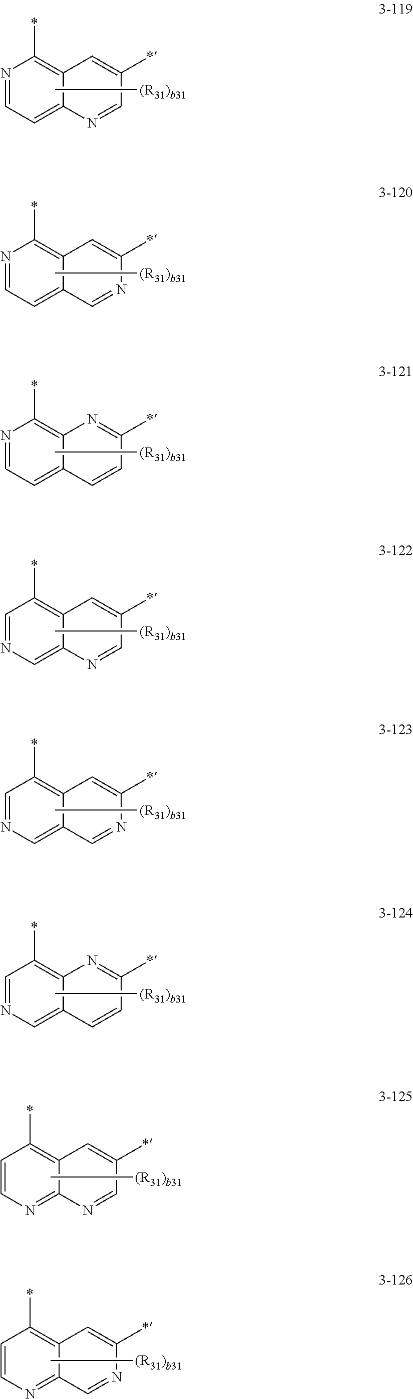

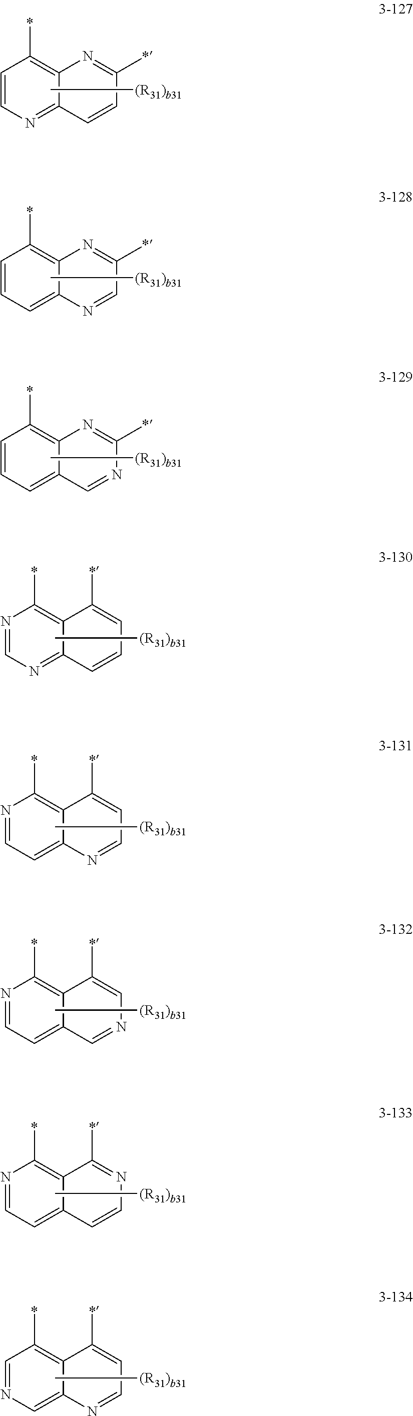

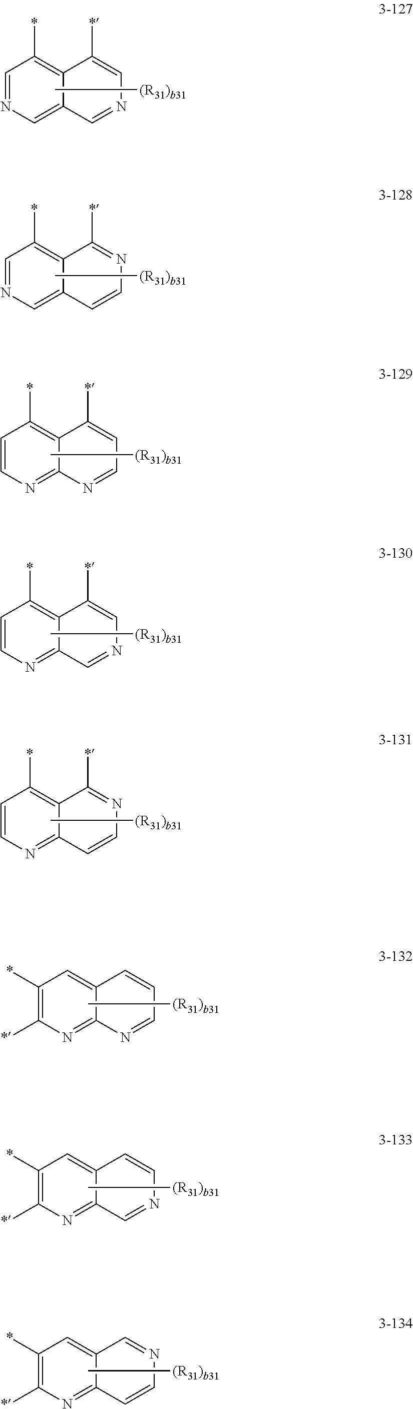

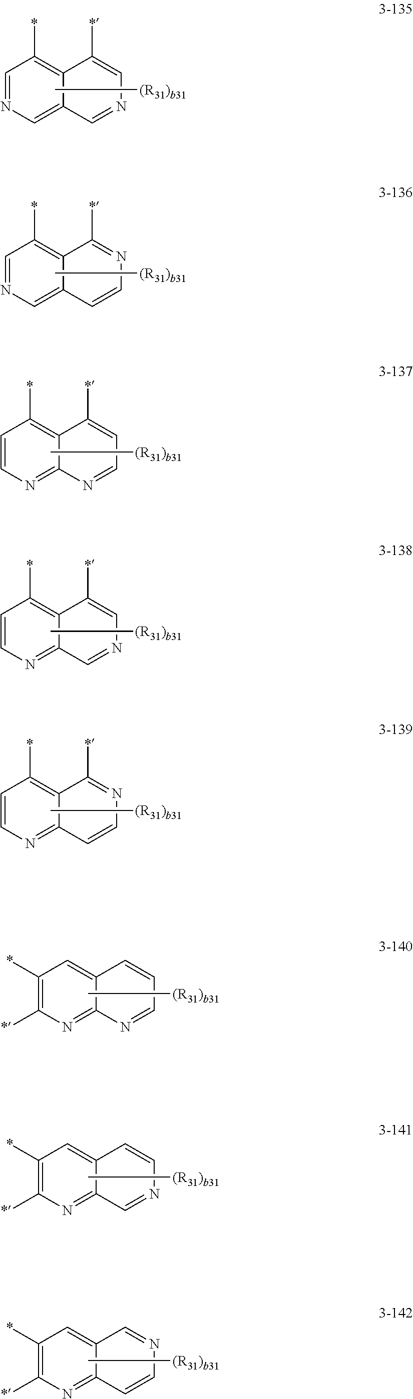

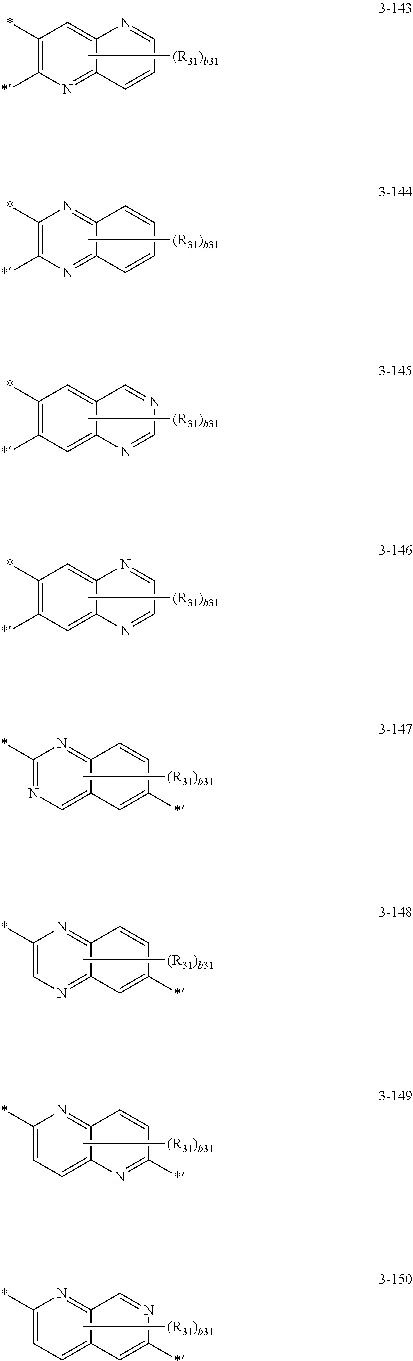

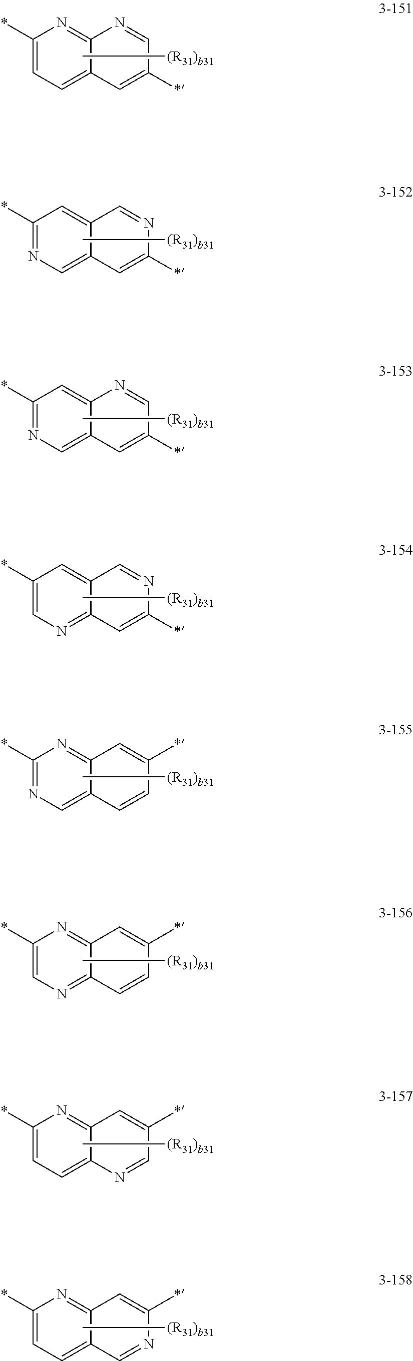

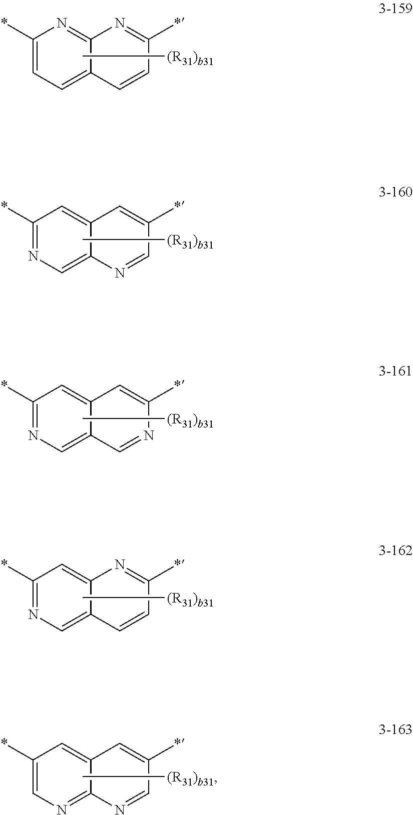

wherein, in Formulae 3-1 to 3-13 and 3-16 to 3-163,

R₃₁ may be selected from the group consisting of:

hydrogen, deuterium, —F, —Cl, —Br, —I, a cyano group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a dibenzofuranyl group, a dibenzothiophenyl group, a carbazolyl group, a triazinyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂); and

a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a dibenzofuranyl group, a dibenzothiophenyl group, a carbazolyl group, and a triazinyl group, each substituted with at least one selected from deuterium, —F, —Cl, —Br, —I, a cyano group, a C₁-C₂₀ alkyl group, a C₁-C₂₀ alkoxy group, a phenyl group, a biphenyl group, and a terphenyl group,

wherein Q₃₁ to Q₃₃ may each independently be selected from hydrogen, a methyl group, an ethyl group, an n-propyl group, an iso-propyl group, a tert-butyl group, a phenyl group, a biphenyl group, and a terphenyl group,

b31 may be selected from 1, 2, 3, and 4,

b32 may be selected from 1, 2, 3, 4, 5, and 6,

b33 may be selected from 1, 2, and 3,

b34 may be selected from 1 and 2,

b35 may be 1, 2, 3, 4, and 5, and

* and *′ may each independently indicate a binding site to a neighboring atom.

a11 to a16 and a81 to a84 in Formulae 1, 1-1, 1-2, 8-1, and 8-2 may each independently be selected from 0, 1, 2, and 3. When a11 is zero, (L₁₁)ₐ₁₁ may be a single bond, and when a11 is two or more, a plurality of L₁₁(s) may be identical to or different from each other. Descriptions of a12 to a16 and a81 to a84 may be the same as those provided in connection with a11.

For example, a11 to a16 and a81 to a84 in Formulae 1, 1-1, 1-2, 8-1, and 8-2 may each independently be selected from 0, 1, and 2, but are not limited thereto.

R₁₁ to R₁₆ in Formulae 1 and 1-1 may each independently be selected from a group represented by Formula 8-1, a group represented by Formula 8-2, hydrogen, deuterium, —F, —Cl, —Br, —I, a cyano group, a nitro group, a substituted or unsubstituted C₁-C₆₀ alkyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, —Si(Q₁)(Q₂)(Q₃), —B(Q₁)(Q₂), —C(═O)(Q₁), —S(═O)₂(Q₁), and —P(═O)(Q₁)(Q₂), where R₁₃ and R₁₄ may be optionally connected to each other to form a ring, and R₁₅ and R₁₆ may be optionally connected to each other to form a ring,

wherein Q₁ to Q₃ may each independently be selected from hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, and a terphenyl group.

For example, R₁₁ to R₁₆ in Formulae 1 and 1-1 may each independently be selected from the group consisting of:

a group represented by Formula 8-1, a group represented by Formula 8-2, a C₁-C₂₀ alkyl group, a C₆-C₃₀ aryl group, and a C₁-C₃₀ heteroaryl group;

a C₆-C₃₀ aryl group and a C₁-C₃₀ heteroaryl group, each substituted with at least one selected from deuterium, —F, —Cl, —Br, —I, a C₁-C₂₀ alkyl group, a C₁-C₂₀ alkoxy group, a C₃-C₁₀ cycloalkyl group, a C₆-C₃₀ aryl group, a C₁-C₃₀ heteroaryl group, —N(Q₃₁)(Q₃₂), and —Si(Q₃₁)(Q₃₂)(Q₃₃); and

a C₆-C₃₀ aryl group and a C₁-C₃₀ heteroaryl group, each substituted with at least one selected from a C₆-C₃₀ aryl group and a C₁-C₃₀ heteroaryl group, each substituted with at least one selected from deuterium, —F, —Cl, —Br, —I, a C₁-C₂₀ alkyl group, a C₁-C₂₀ alkoxy group, a C₃-C₁₀ cycloalkyl group, a C₆-C₃₀ aryl group, a C₁-C₃₀ heteroaryl group, —N(Q₂₁)(Q₂₂), and —Si(Q₂₁)(Q₂₂)(Q₂₃),

wherein Q₂₁ to Q₂₃ and Q₃₁ to Q₃₃ may each independently be selected from a C₁-C₂₀ alkyl group and a C₆-C₃₀ aryl group, but embodiments are not limited thereto.

In various embodiments, R₁₁ to R₁₆ in Formulae 1 and 1-1 may each independently be selected from the group consisting of:

a group represented by Formula 8-1, a group represented by Formula 8-2, a methyl group, an ethyl group, an n-propyl group, a phenyl group, a biphenyl group, a terphenyl group, a naphthyl group, an anthracenyl group, a triphenylenyl group, a phenanthrenyl group, a pyrenyl group, a tetraphenyl group, a chrysenyl group, a fluoranthenyl group, a pyrrolyl group, a furanyl group, a thiophenyl group, a pyridinyl group, a pyrazinyl group, a pyrimidinyl group, a triazinyl group, a quinolinyl group, an isoquinolinyl group, a benzoquinolinyl group, a phthalazinyl group, a naphthyridinyl group, a quinoxalinyl group, a quinazolinyl group, a pyridopyrimidinyl group, a phenanthridinyl group, an acridinyl group, a phenanthrolinyl group, a phenazinyl group, a benzonaphthyridinyl group, a benzoquinoxalinyl group, a benzoquinazolinyl group, a benzophenanthrolinyl group, a thiazolyl group, an oxazolyl group, an imidazolyl group, a triazolyl group, an indolyl group, a benzimidazolyl group, an imidazopyridinyl group, a benzofuranyl group, a benzothiophenyl group, and a benzoxazolyl group;

a phenyl group, a biphenyl group, a terphenyl group, a naphthyl group, an anthracenyl group, a triphenylenyl group, a phenanthrenyl group, a pyrenyl group, a tetraphenyl group, a chrysenyl group, a fluoranthenyl group, a pyrrolyl group, a furanyl group, a thiophenyl group, a pyridinyl group, a pyrazinyl group, a pyrimidinyl group, a triazinyl group, a quinolinyl group, an isoquinolinyl group, a benzoquinolinyl group, a phthalazinyl group, a naphthyridinyl group, a quinoxalinyl group, a quinazolinyl group, a pyridopyrimidinyl group, a phenanthridinyl group, an acridinyl group, a phenanthrolinyl group, a phenazinyl group, a benzonaphthyridinyl group, a benzoquinoxalinyl group, a benzoquinazolinyl group, a benzophenanthrolinyl group, a thiazolyl group, an oxazolyl group, an imidazolyl group, a triazolyl group, an indolyl group, a benzimidazolyl group, an imidazopyridinyl group, a benzofuranyl group, a benzothiophenyl group, and a benzoxazolyl group, each substituted with at least one selected from deuterium, —F, —Cl, —Br, —I, a C₁-C₂₀ alkyl group, a phenyl group, a biphenyl group, a terphenyl group, a naphthyl group, a pyridinyl group, a pyrazinyl group, a pyrimidinyl group, a triazinyl group, a quinolinyl group, an isoquinolinyl group, —N(Q₃₁)(Q₃₂), and —Si(Q₃₁)(Q₃₂)(Q₃₃); and

a phenyl group, a biphenyl group, a terphenyl group, a naphthyl group, an anthracenyl group, a triphenylenyl group, a phenanthrenyl group, a pyrenyl group, a tetraphenyl group, a chrysenyl group, a fluoranthenyl group, a pyrrolyl group, a furanyl group, a thiophenyl group, a pyridinyl group, a pyrazinyl group, a pyrimidinyl group, a triazinyl group, a quinolinyl group, an isoquinolinyl group, a benzoquinolinyl group, a phthalazinyl group, a naphthyridinyl group, a quinoxalinyl group, a quinazolinyl group, a pyridopyrimidinyl group, a phenanthridinyl group, an acridinyl group, a phenanthrolinyl group, a phenazinyl group, a benzonaphthyridinyl group, a benzoquinoxalinyl group, a benzoquinazolinyl group, a benzophenanthrolinyl group, a thiazolyl group, an oxazolyl group, an imidazolyl group, a triazolyl group, an indolyl group, a benzimidazolyl group, an imidazopyridinyl group, a benzofuranyl group, a benzothiophenyl group, and a benzoxazolyl group, each substituted with at least one selected from a phenyl group, a biphenyl group, a terphenyl group, a naphthyl group, an anthracenyl group, a triphenylenyl group, a phenanthrenyl group, a pyrenyl group, a tetraphenyl group, a chrysenyl group, a pyrrolyl group, a furanyl group, a thiophenyl group, a pyridinyl group, a pyrazinyl group, a pyrimidinyl group, a triazinyl group, a quinolinyl group, an isoquinolinyl group, a benzoquinolinyl group, a phthalazinyl group, a naphthyridinyl group, a quinoxalinyl group, a quinazolinyl group, a phenanthridinyl group, an acridinyl group, a phenanthrolinyl group, a phenazinyl group, a benzophenanthrolinyl group, a thiazolyl group, an oxazolyl group, an imidazolyl group, a triazolyl group, an indolyl group, a benzimidazolyl group, a benzofuranyl group, a benzothiophenyl group, and a benzoxazolyl group, each substituted with at least one selected from deuterium, —F, —Cl, —Br, —I, a C₁-C₂₀ alkyl group, a phenyl group, a biphenyl group, a terphenyl group, a naphthyl group, a pyridinyl group, a pyrazinyl group, a pyrimidinyl group, a triazinyl group, a quinolinyl group, an isoquinolinyl group, —N(Q₂₁)(Q₂₂), and —Si(Q₂₁)(Q₂₂)(Q₂₃),

wherein Q₂₁ to Q₂₃ and Q₃₁ to Q₃₃ may each independently be selected from a phenyl group, a biphenyl group, a terphenyl group, and a naphthyl group, but embodiments are not limited thereto.

In various embodiments, R₁₁ to R₁₆ in Formulae 1 and 1-1 may each independently be selected from a group represented by Formula 8-1, a group represented by Formula 8-2, a methyl group, an ethyl group, an n-propyl group, and a group represented by any of Formulae 5-1 to 5-55 and 5-80 to 5-92, but are not limited thereto:

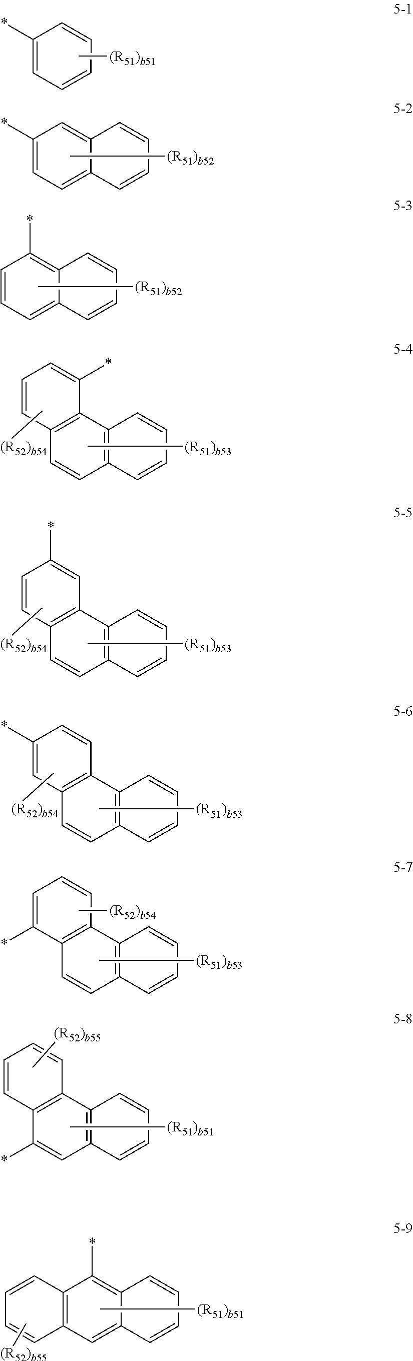

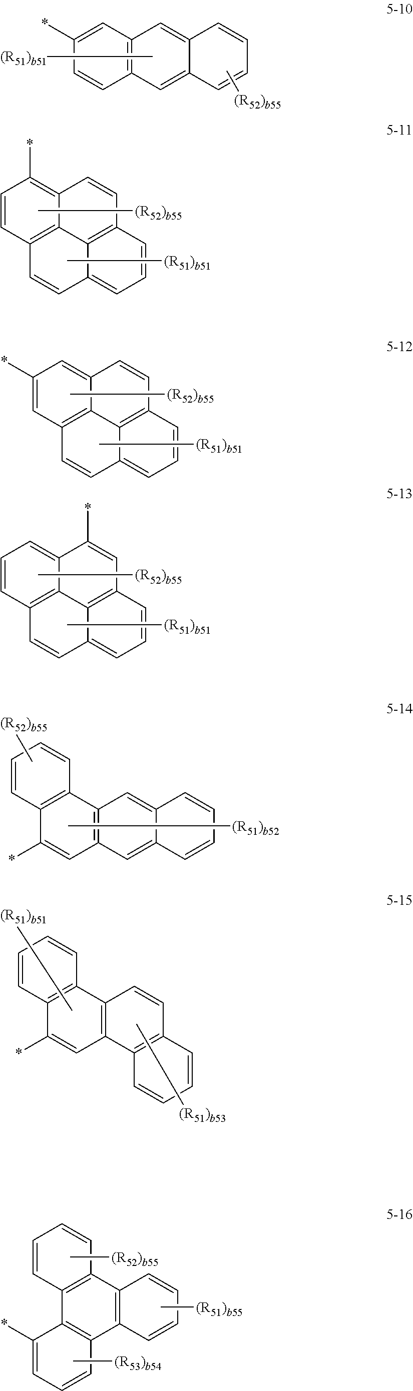

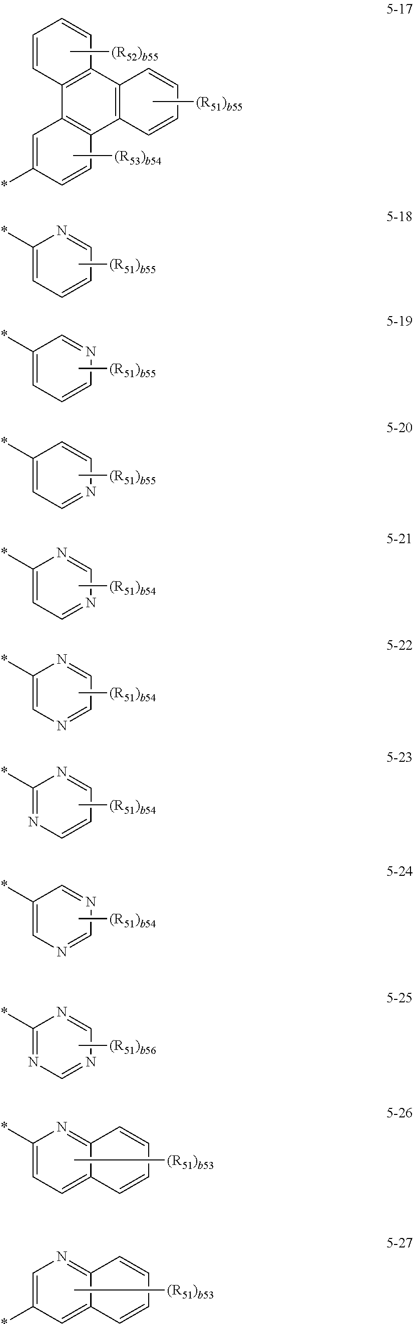

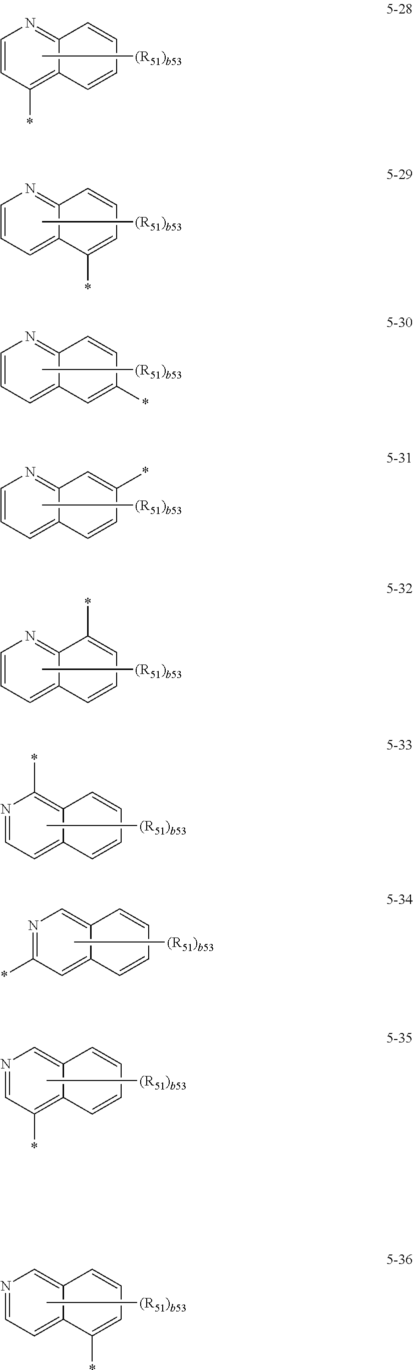

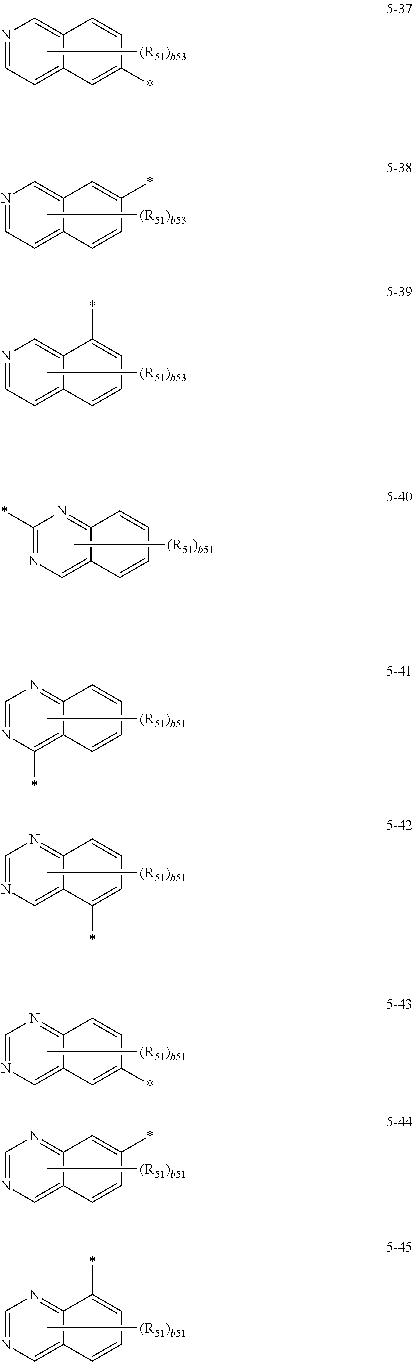

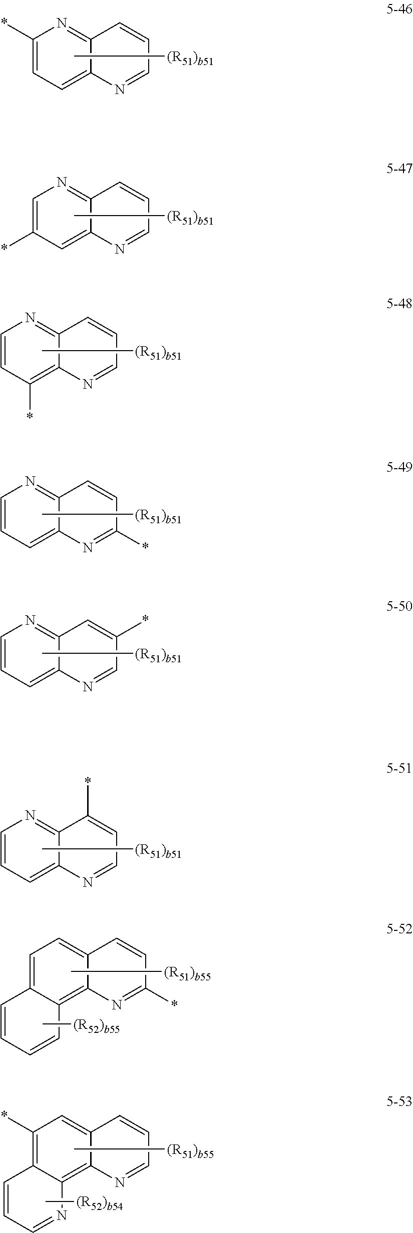

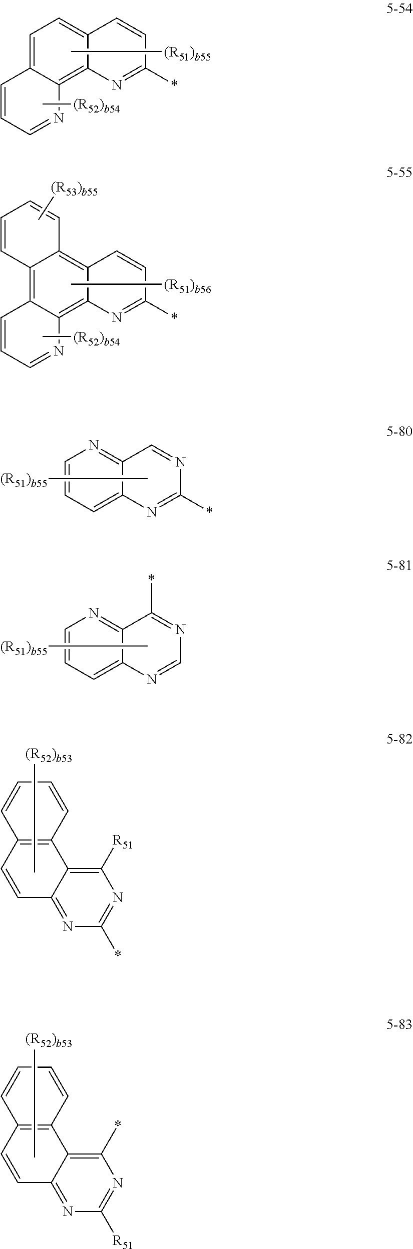

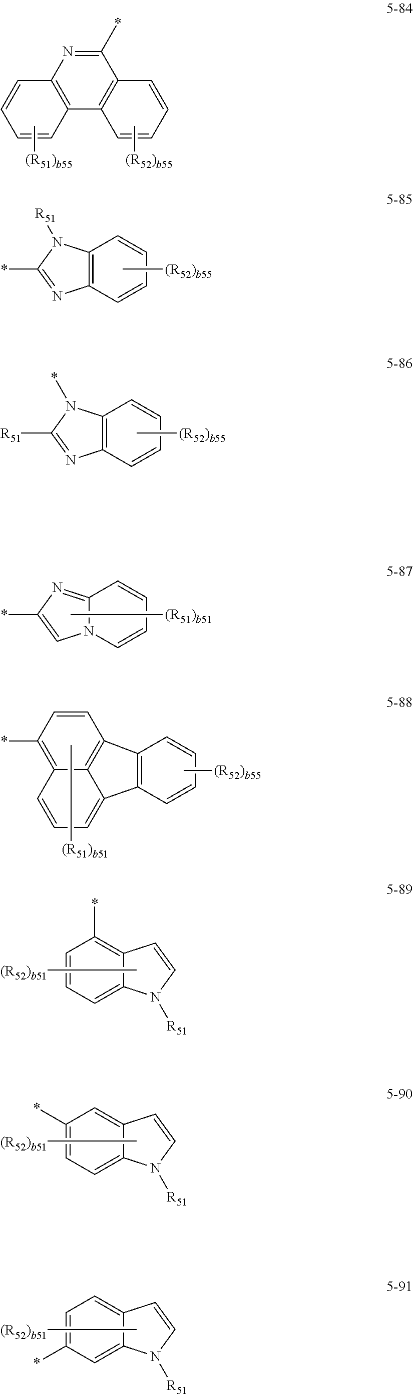

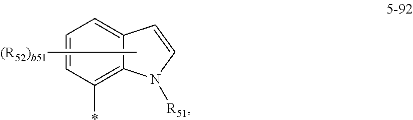

wherein, in Formulae 5-1 to 5-55 and 5-80 to 5-92,

R₅₁ to R₅₃ may each independently be selected from the group consisting of:

hydrogen, deuterium, —F, —Cl, —Br, —I, a C₁-C₂₀ alkyl group, a phenyl group, a biphenyl group, a terphenyl group, a naphthyl group, a pyridinyl group, a pyrazinyl group, a pyrimidinyl group, a triazinyl group, a quinolinyl group, an isoquinolinyl group, —N(Q₃₁)(Q₃₂), and —Si(Q₃₁)(Q₃₂)(Q₃₃); and

a phenyl group, a biphenyl group, a terphenyl group, a naphthyl group, an anthracenyl group, a triphenylenyl group, a phenanthrenyl group, a pyrenyl group, a tetraphenyl group, a chrysenyl group, a pyrrolyl group, a furanyl group, a thiophenyl group, a pyridinyl group, a pyrazinyl group, a pyrimidinyl group, a triazinyl group, a quinolinyl group, an isoquinolinyl group, a benzoquinolinyl group, a phthalazinyl group, a naphthyridinyl group, a quinoxalinyl group, a quinazolinyl group, a phenanthridinyl group, an acridinyl group, a phenanthrolinyl group, a phenazinyl group, a benzophenanthrolinyl group, a thiazolyl group, an oxazolyl group, an imidazolyl group, a triazolyl group, an indolyl group, a benzimidazolyl group, a benzofuranyl group, a benzothiophenyl group, and a benzoxazolyl group, each substituted with at least one selected from deuterium, —F, —Cl, —Br, —I, a C₁-C₂₀ alkyl group, a phenyl group, a biphenyl group, a terphenyl group, a naphthyl group, a pyridinyl group, a pyrazinyl group, a pyrimidinyl group, a triazinyl group, a quinolinyl group, an isoquinolinyl group, —N(Q₂₁)(Q₂₂), and —Si(Q₂₁)(Q₂₂)(Q₂₃),

wherein Q₂₁ to Q₂₃ and Q₃₁ to Q₃₃ may each independently be selected from a phenyl group, a biphenyl group, a terphenyl group, and a naphthyl group,

b51 may be selected from 1, 2, 3, 4, and 5,

b52 may be selected from 1, 2, 3, 4, 5, 6, and 7,

b53 may be selected from 1, 2, 3, 4, 5, and 6,

b54 may be selected from 1, 2, and 3,

b55 may be selected from 1, 2, 3, and 4,

b56 may be 1 or 2, and

* indicates a binding site to a neighboring atom.

n11 in Formula 1 indicates the number of moieties represented by *-(L₁₁)ₐ₁₁-R₁₁, wherein n11 may be selected from 0, 1, 2, 3, and 4. When n11 is zero, A₁₁ in Formula 1-1 (where compound represented by Formula 1-1 represents Ar₁₁ in Formula 1) is not substituted with a moiety represented by *-(L₁₁)ₐ₁₁-R₁₁. When n11 is two or more, a plurality of moieties represented by *-(L₁₁)ₐ₁₁-R₁₁ may be identical to or different from each other.

n12 in Formula 1 indicates the number of moieties represented by *-(L₁₂)ₐ₁₂-R₁₂, wherein n12 may be selected from 0, 1, 2, 3, and 4. When n12 is zero, A₁₂ in Formula 1-1 (where compound represented by Formula 1-1 represents Ar₁, in Formula 1) is not substituted with a moiety represented by *-(L₁₂)ₐ₁₂-R₁₂. When n12 is two or more, a plurality of moieties represented by *-(L₁₂)ₐ₁₂-R₁₂ may be identical to or different from each other.

For example, the sum of n11 and n12 in Formula 1 may be selected from 0 and 1, but is not limited thereto.

R₈₁ to R₈₄ in Formulae 8-1 and 8-2 may each independently be selected from hydrogen, deuterium, —F, —Cl, —Br, —I, a cyano group, a nitro group, a substituted or unsubstituted C₁-C₆₀ alkyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, —Si(Q₁)(Q₂)(Q₃), —B(Q₁)(Q₂), —C(═O)(Q₁), —S(═O)₂(Q₁), and —P(═O)(Q₁)(Q₂),

wherein Q₁ to Q₃ may each independently be selected from hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, and a terphenyl group.

For example, R₈₁ to R₈₄ in Formulae 8-1 and 8-2 may each independently be selected from the group consisting of:

a C₁-C₂₀ alkyl group, a C₆-C₃₀ aryl group, and a C₁-C₃₀ heteroaryl group;

a C₆-C₃₀ aryl group and a C₁-C₃₀ heteroaryl group, each substituted with at least one selected from deuterium, —F, —Cl, —Br, —I, a C₁-C₂₀ alkyl group, a C₁-C₂₀ alkoxy group, a C₃-C₁₀ cycloalkyl group, a C₆-C₃₀ aryl group, a C₁-C₃₀ heteroaryl group, —N(Q₃₁)(Q₃₂), and —Si(Q₃₁)(Q₃₂)(Q₃₃); and

a C₆-C₃₀ aryl group and a C₁-C₃₀ heteroaryl group, each substituted with at least one selected from a C₆-C₃₀ aryl group and a C₁-C₃₀ heteroaryl group, each substituted with at least one selected from deuterium, —F, —Cl, —Br, —I, a C₁-C₂₀ alkyl group, a C₁-C₂₀ alkoxy group, a C₃-C₁₀ cycloalkyl group, a C₆-C₃₀ aryl group, a C₁-C₃₀ heteroaryl group, —N(Q₂₁)(Q₂₂), and —Si(Q₂₁)(Q₂₂)(Q₂₃),

wherein Q₂₁ to Q₂₃ and Q₃₁ to Q₃₃ may each independently be selected from a C₁-C₂₀ alkyl group and a C₆-C₃₀ aryl group, but embodiments are not limited thereto.

In various embodiments, R₈₁ to R₈₄ in Formulae 8-1 and 8-2 may each independently be selected from the group consisting of:

a methyl group, an ethyl group, an n-propyl group, a phenyl group, a biphenyl group, a terphenyl group, a naphthyl group, an anthracenyl group, a triphenylenyl group, a phenanthrenyl group, a pyrenyl group, a tetraphenyl group, a chrysenyl group, a fluoranthenyl group, a pyrrolyl group, a furanyl group, a thiophenyl group, a pyridinyl group, a pyrazinyl group, a pyrimidinyl group, a triazinyl group, a quinolinyl group, an isoquinolinyl group, a benzoquinolinyl group, a phthalazinyl group, a naphthyridinyl group, a quinoxalinyl group, a quinazolinyl group, a pyridopyrimidinyl group, a phenanthridinyl group, an acridinyl group, a phenanthrolinyl group, a phenazinyl group, a benzonaphthyridinyl group, a benzoquinoxalinyl group, a benzoquinazolinyl group, a benzophenanthrolinyl group, a thiazolyl group, an oxazolyl group, an imidazolyl group, a triazolyl group, an indolyl group, a benzimidazolyl group, an imidazopyridinyl group, a benzofuranyl group, a benzothiophenyl group, and a benzoxazolyl group;

a phenyl group, a biphenyl group, a terphenyl group, a naphthyl group, an anthracenyl group, a triphenylenyl group, a phenanthrenyl group, a pyrenyl group, a tetraphenyl group, a chrysenyl group, a fluoranthenyl group, a pyrrolyl group, a furanyl group, a thiophenyl group, a pyridinyl group, a pyrazinyl group, a pyrimidinyl group, a triazinyl group, a quinolinyl group, an isoquinolinyl group, a benzoquinolinyl group, a phthalazinyl group, a naphthyridinyl group, a quinoxalinyl group, a quinazolinyl group, a pyridopyrimidinyl group, a phenanthridinyl group, an acridinyl group, a phenanthrolinyl group, a phenazinyl group, a benzonaphthyridinyl group, a benzoquinoxalinyl group, a benzoquinazolinyl group, a benzophenanthrolinyl group, a thiazolyl group, an oxazolyl group, an imidazolyl group, a triazolyl group, an indolyl group, a benzimidazolyl group, an imidazopyridinyl group, a benzofuranyl group, a benzothiophenyl group, and a benzoxazolyl group, each substituted with at least one selected from deuterium, —F, —Cl, —Br, —I, a C₁-C₂₀ alkyl group, a phenyl group, a biphenyl group, a terphenyl group, a naphthyl group, a pyridinyl group, a pyrazinyl group, a pyrimidinyl group, a triazinyl group, a quinolinyl group, an isoquinolinyl group, —N(Q₃₁)(Q₃₂), and —Si(Q₃₁)(Q₃₂)(Q₃₃); and

a phenyl group, a biphenyl group, a terphenyl group, a naphthyl group, an anthracenyl group, a triphenylenyl group, a phenanthrenyl group, a pyrenyl group, a tetraphenyl group, a chrysenyl group, a fluoranthenyl group, a pyrrolyl group, a furanyl group, a thiophenyl group, a pyridinyl group, a pyrazinyl group, a pyrimidinyl group, a triazinyl group, a quinolinyl group, an isoquinolinyl group, a benzoquinolinyl group, a phthalazinyl group, a naphthyridinyl group, a quinoxalinyl group, a quinazolinyl group, a pyridopyrimidinyl group, a phenanthridinyl group, an acridinyl group, a phenanthrolinyl group, a phenazinyl group, a benzonaphthyridinyl group, a benzoquinoxalinyl group, a benzoquinazolinyl group, a benzophenanthrolinyl group, a thiazolyl group, an oxazolyl group, an imidazolyl group, a triazolyl group, an indolyl group, a benzimidazolyl group, an imidazopyridinyl group, a benzofuranyl group, a benzothiophenyl group, and a benzoxazolyl group, each substituted with at least one selected from a phenyl group, a biphenyl group, a terphenyl group, a naphthyl group, an anthracenyl group, a triphenylenyl group, a phenanthrenyl group, a pyrenyl group, a tetraphenyl group, a chrysenyl group, a pyrrolyl group, a furanyl group, a thiophenyl group, a pyridinyl group, a pyrazinyl group, a pyrimidinyl group, a triazinyl group, a quinolinyl group, an isoquinolinyl group, a benzoquinolinyl group, a phthalazinyl group, a naphthyridinyl group, a quinoxalinyl group, a quinazolinyl group, a phenanthridinyl group, an acridinyl group, a phenanthrolinyl group, a phenazinyl group, a benzophenanthrolinyl group, a thiazolyl group, an oxazolyl group, an imidazolyl group, a triazolyl group, an indolyl group, a benzimidazolyl group, a benzofuranyl group, a benzothiophenyl group, and a benzoxazolyl group, each substituted with at least one selected from deuterium, —F, —Cl, —Br, —I, a C₁-C₂₀ alkyl group, a phenyl group, a biphenyl group, a terphenyl group, a naphthyl group, a pyridinyl group, a pyrazinyl group, a pyrimidinyl group, a triazinyl group, a quinolinyl group, an isoquinolinyl group, —N(Q₂₁)(Q₂₂), and —Si(Q₂₁)(Q₂₂)(Q₂₃),

wherein Q₂₁ to Q₂₃ and Q₃₁ to Q₃₃ may each independently be selected from a phenyl group, a biphenyl group, a terphenyl group, and a naphthyl group, but embodiments are not limited thereto.

In various embodiments, R₈₁ to R₈₄ in Formulae 8-1 and 8-2 may each independently be selected from a methyl group, an ethyl group, an n-propyl group, and a group represented by any of Formulae 5-1 to 5-55 and 5-80 to 5-92, but are not limited thereto:

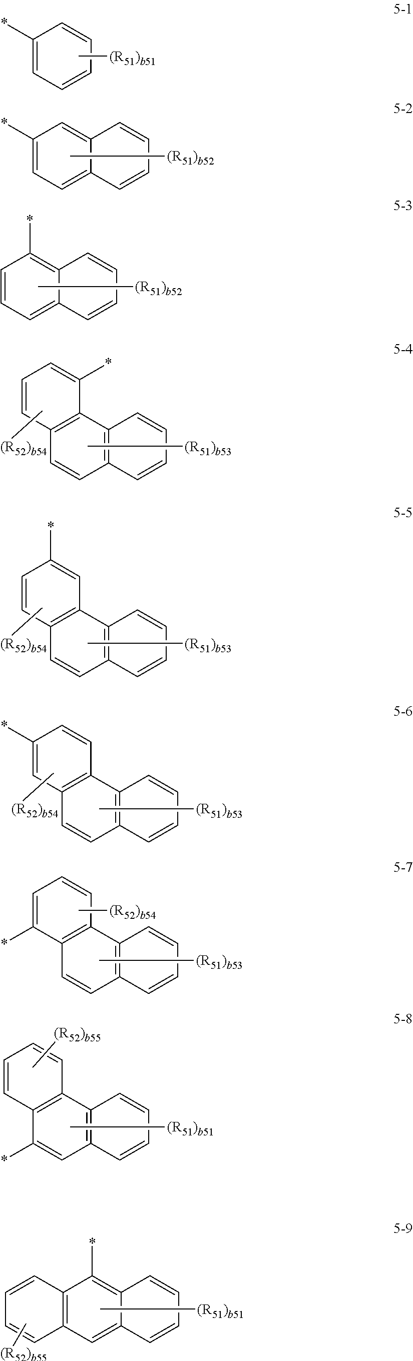

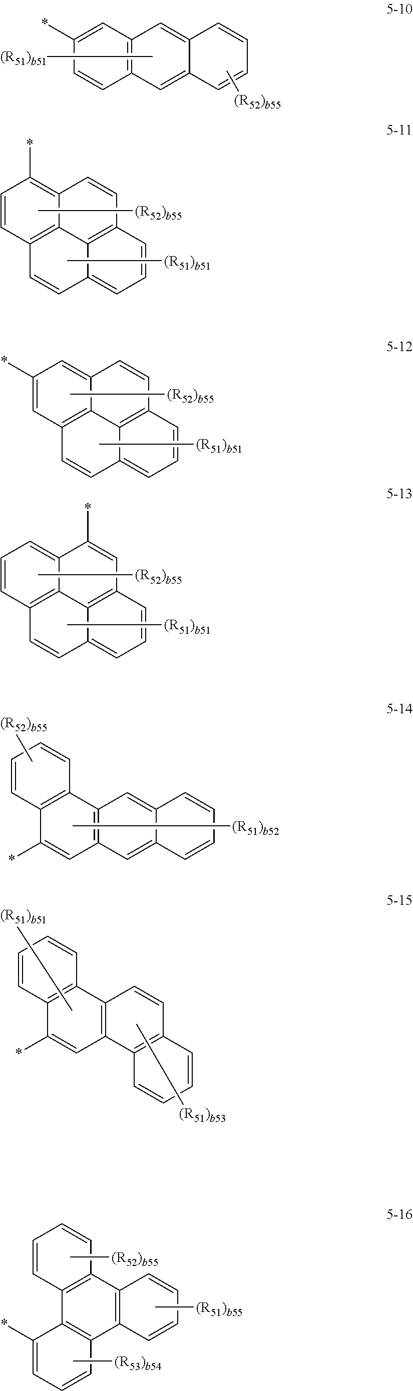

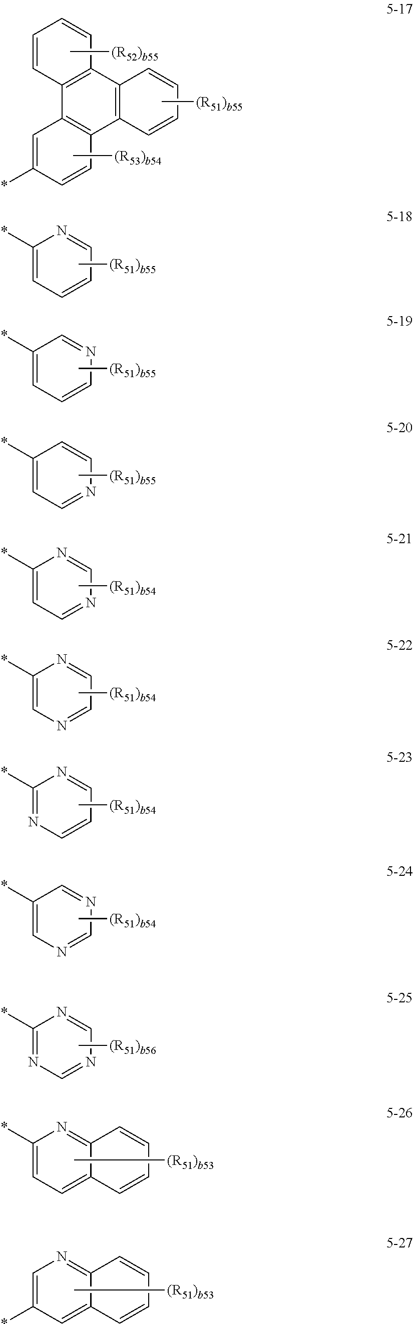

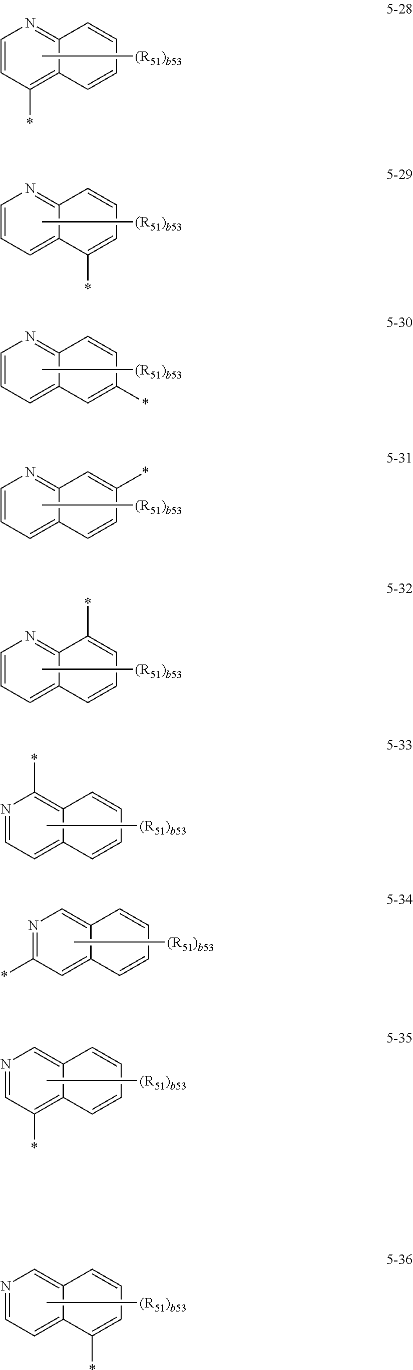

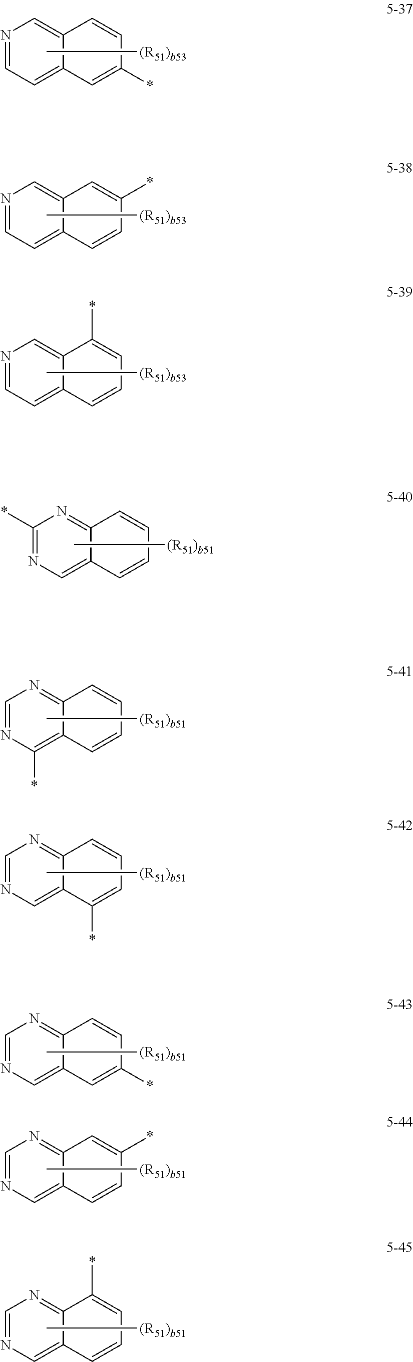

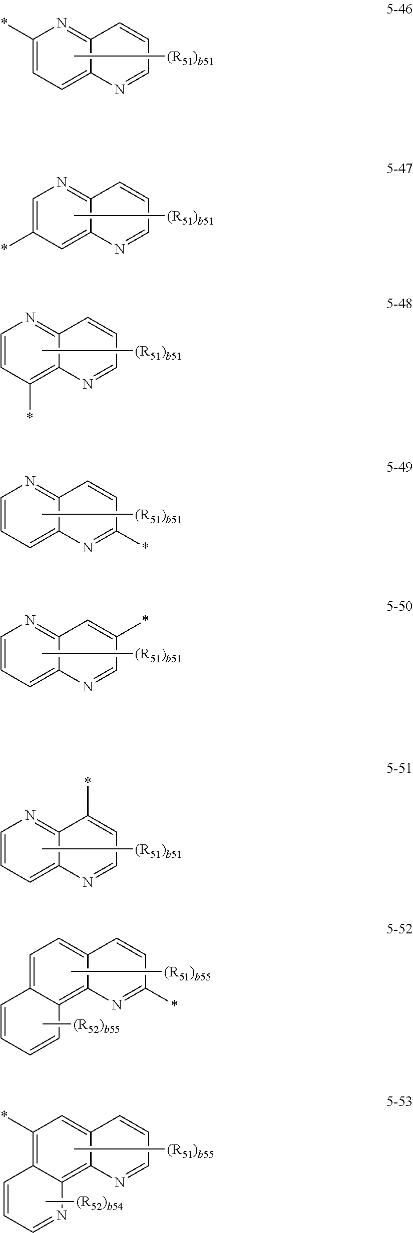

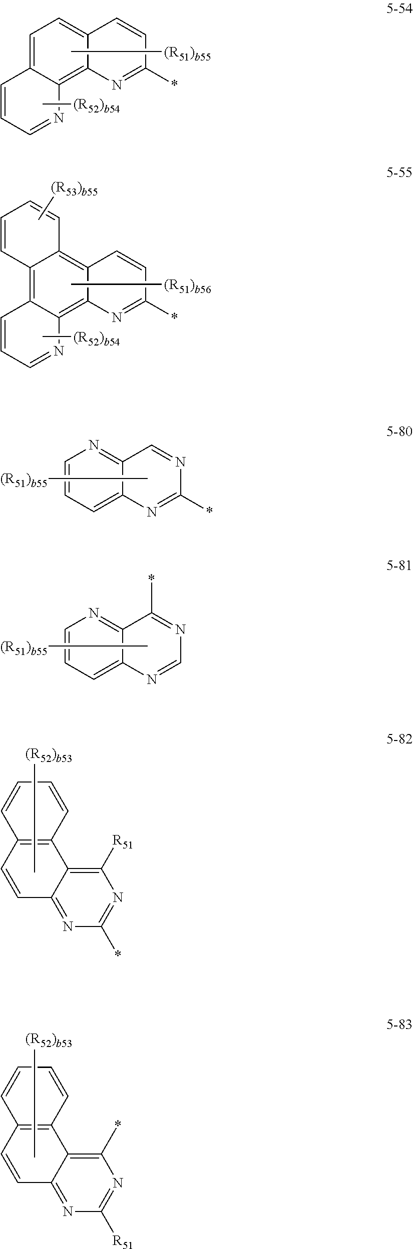

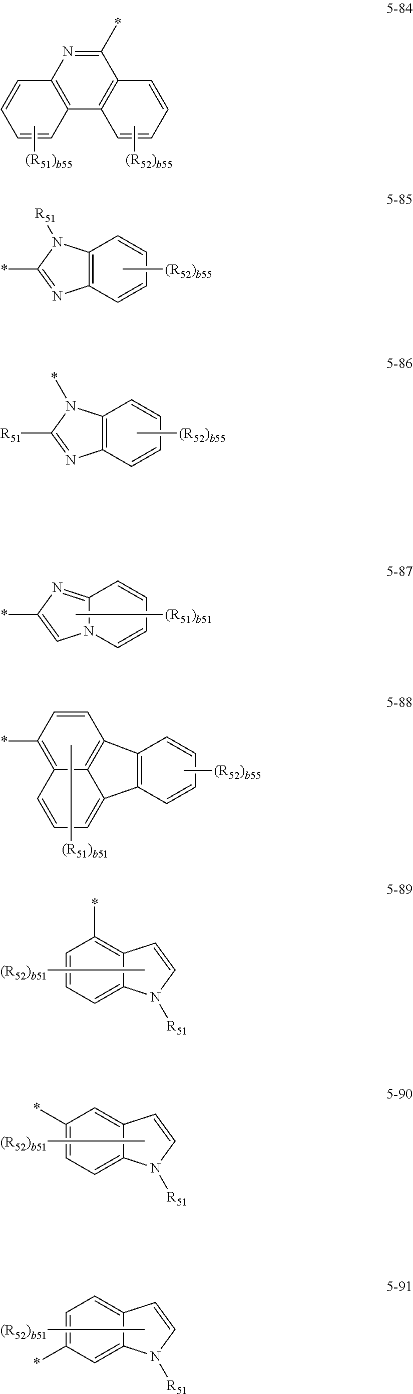

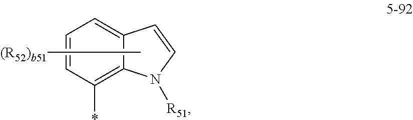

wherein, in Formulae 5-1 to 5-55 and 5-80 to 5-92,

R₅₁ to R₅₃ may each independently be selected from the group consisting of:

hydrogen, deuterium, —F, —Cl, —Br, —I, a C₁-C₂₀ alkyl group, a phenyl group, a biphenyl group, a terphenyl group, a naphthyl group, a pyridinyl group, a pyrazinyl group, a pyrimidinyl group, a triazinyl group, a quinolinyl group, an isoquinolinyl group, —N(Q₃₁)(Q₃₂), and —Si(Q₃₁)(Q₃₂)(Q₃₃); and

a phenyl group, a biphenyl group, a terphenyl group, a naphthyl group, an anthracenyl group, a triphenylenyl group, a phenanthrenyl group, a pyrenyl group, a tetraphenyl group, a chrysenyl group, a pyrrolyl group, a furanyl group, a thiophenyl group, a pyridinyl group, a pyrazinyl group, a pyrimidinyl group, a triazinyl group, a quinolinyl group, an isoquinolinyl group, a benzoquinolinyl group, a phthalazinyl group, a naphthyridinyl group, a quinoxalinyl group, a quinazolinyl group, a phenanthridinyl group, an acridinyl group, a phenanthrolinyl group, a phenazinyl group, a benzophenanthrolinyl group, a thiazolyl group, an oxazolyl group, an imidazolyl group, a triazolyl group, an indolyl group, a benzimidazolyl group, a benzofuranyl group, a benzothiophenyl group, and a benzoxazolyl group, each substituted with at least one selected from deuterium, —F, —Cl, —Br, —I, a C₁-C₂₀ alkyl group, a phenyl group, a biphenyl group, a terphenyl group, a naphthyl group, a pyridinyl group, a pyrazinyl group, a pyrimidinyl group, a triazinyl group, a quinolinyl group, an isoquinolinyl group, —N(Q₂₁)(Q₂₂), and —Si(Q₂₁₎(Q₂₂)(Q₂₃),

wherein Q₂₁ to Q₂₃ and Q₃₁ to Q₃₃ may each independently be selected from a phenyl group, a biphenyl group, a terphenyl group, and a naphthyl group,

b51 may be selected from 1, 2, 3, 4, and 5,

b52 may be selected from 1, 2, 3, 4, 5, 6, and 7,

b53 may be selected from 1, 2, 3, 4, 5, and 6,

b54 may be selected from 1, 2, and 3,

b55 may be selected from 1, 2, 3, and 4,

b56 may be 1 or 2, and

* indicates a binding site to a neighboring atom.

R₁₀₁, R₁₀₂, R₈₅, and R₈₆ in Formulae 1, 1-1, 8-1, and 8-2 may each independently be selected from hydrogen, deuterium, —F, —Cl, —Br, —I, a cyano group, a nitro group, a substituted or unsubstituted C₁-C₆₀ alkyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, —Si(Q₁)(Q₂)(Q₃), —B(Q₁)(Q₂), —C(═O)(Q₁), —S(═O)₂(Q₁), and —P(═O)(Q₁)(Q₂),

wherein Q₁ to Q₃ may each independently be selected from hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, and a terphenyl group.

For example, R₁₀₁, R₁₀₂, R₈₅, and R₈₆ in Formulae 1, 1-1, 8-1, and 8-2 may each independently be selected from the group consisting of:

hydrogen, deuterium, —F, —Cl, —Br, —I, a cyano group, a C₁-C₂₀ alkyl group, a C₁-C₂₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₃₀ aryl group, a C₆-C₃₀ aryloxy group, a C₆-C₃₀ arylthio group, a C₁-C₃₀ heteroaryl group, and —Si(Q₁)(Q₂)(Q₃);

a C₁-C₂₀ alkyl group and a C₃-C₁₀ cycloalkyl group, each substituted with at least one selected from deuterium, —F, —Cl, —Br, —I, a cyano group, and —Si(Q₃₁)(Q₃₂)(Q₃₃); and

a C₆-C₃₀ aryl group and a C₁-C₃₀ heteroaryl group, each substituted with at least one selected from a C₁-C₂₀ alkyl group, a C₆-C₃₀ aryl group, and a C₁-C₃₀ heteroaryl group, each substituted with at least one selected from deuterium, —F, —Cl, —Br, —I, a cyano group, and —Si(Q₂₁)(Q₂₂)(Q₂₃),

wherein Q₁ to Q₃, Q₂₁ to Q₂₃, and Q₃₁ to Q₃₃ may each independently be selected from a C₁-C₂₀ alkyl group, a C₆-C₃₀ aryl group, a C₁-C₃₀ heteroaryl group, a biphenyl group, and a terphenyl group, but embodiments are not limited thereto.

In various embodiments, R₁₀₁, R₁₀₂, R₈₅, and R₈₆ in Formulae 1, 1-1, 8-1, and 8-2 may each independently be selected from the group consisting of:

hydrogen, deuterium, —F, —Cl, —Br, —I, a cyano group, a methyl group, an ethyl group, an n-propyl group, an iso-propyl group, an n-butyl group, an iso-butyl group, a sec-butyl group, a tert-butyl group, a phenyl group, a biphenyl group, a terphenyl group, a naphthyl group, a pyridinyl group, a pyrimidinyl group, a pyridazinyl group, a triazinyl group, a quinolinyl group, an isoquinolinyl group, and —Si(Q₁)(Q₂)(Q₃);

a methyl group, an ethyl group, an n-propyl group, an iso-propyl group, an n-butyl group, an iso-butyl group, a sec-butyl group, and a tert-butyl group, each substituted with at least one selected from deuterium, —F, —Cl, —Br, —I, a cyano group, and —Si(Q₃₁)(Q₃₂)(Q₃₃); and

a phenyl group, a biphenyl group, a terphenyl group, a naphthyl group, a pyridinyl group, a pyrimidinyl group, a pyridazinyl group, a triazinyl group, a quinolinyl group, and an isoquinolinyl group, each substituted with at least one selected from a methyl group, an ethyl group, an n-propyl group, an iso-propyl group, an n-butyl group, an iso-butyl group, a sec-butyl group, a tert-butyl group, a phenyl group, a biphenyl group, a terphenyl group, a naphthyl group, a pyridinyl group, a pyrimidinyl group, a pyridazinyl group, a triazinyl group, a quinolinyl group, and an isoquinolinyl group, each substituted with at least one selected from deuterium, —F, —Cl, —Br, —I, a cyano group, and —Si(Q₂₁)(Q₂₂)(Q₂₃),

wherein Q₁ to Q₃, Q₂₁ to Q₂₃, and Q₃₁ to Q₃₃ may each independently be selected from a methyl group and a phenyl group, but embodiments are not limited thereto.

b101, b102, b85, and b86 in Formulae 1, 1-1, 8-1, and 8-2 may each independently be selected from 1, 2, 3, 4, 5, and 6. When b101 is two or more, a plurality of R₁₀₁(s) may be identical to or different from each other. Descriptions of b102, b85, and b86 may each independently be the same as the description provided in connection with b101.

A case where the first compound represented by Formula 1 is 4,4′-bis(N-carbazolyl)-1,1′-biphenyl (CBP) may be excluded.

For example, when m11 in Formula 1 is 1, n11 and n12 are both zero, X₁₁ is N[(L₁₃)ₐ₁₃-R₁₃], and R₁₃ is a group represented by Formula 8-2, a case where (L₁₃)ₐ₁₃ is represented by Formula 10-1 may be excluded:

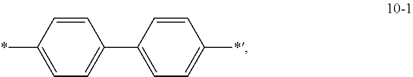

wherein * and *′ in Formula 10-1 each independently indicate a binding site to a neighboring atom.

For example, a group represented by Formula 1-1 may be selected from groups represented by Formulae 1-11 to 1-67, but is not limited thereto:

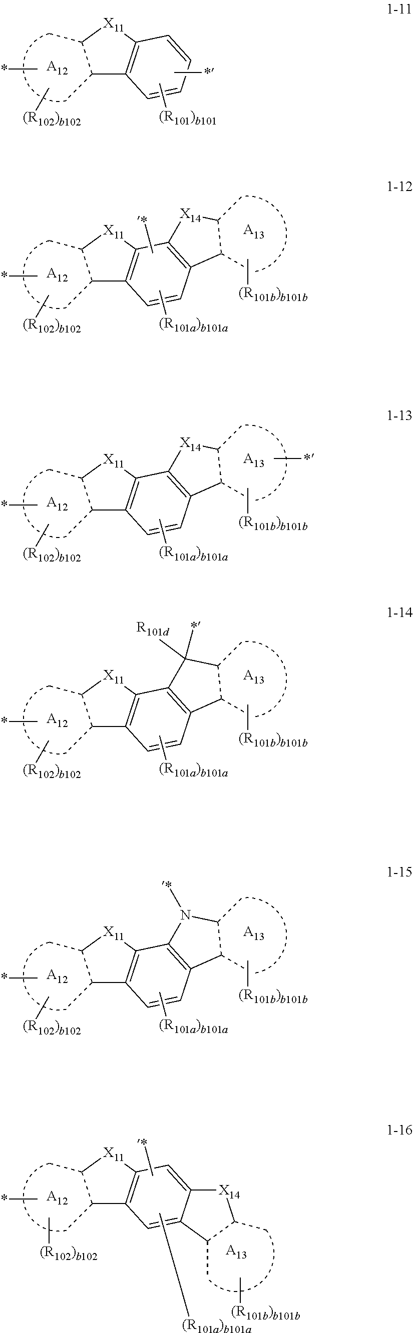

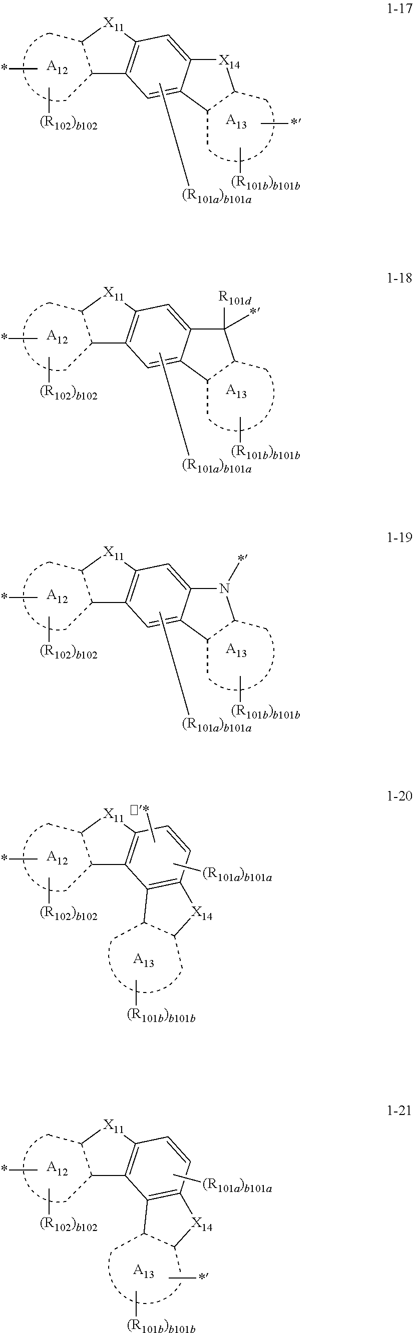

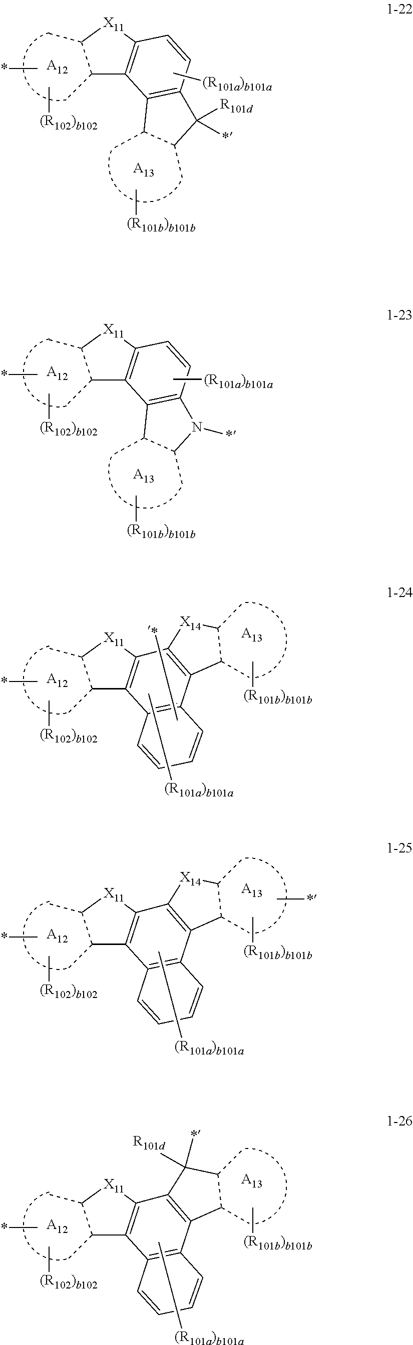

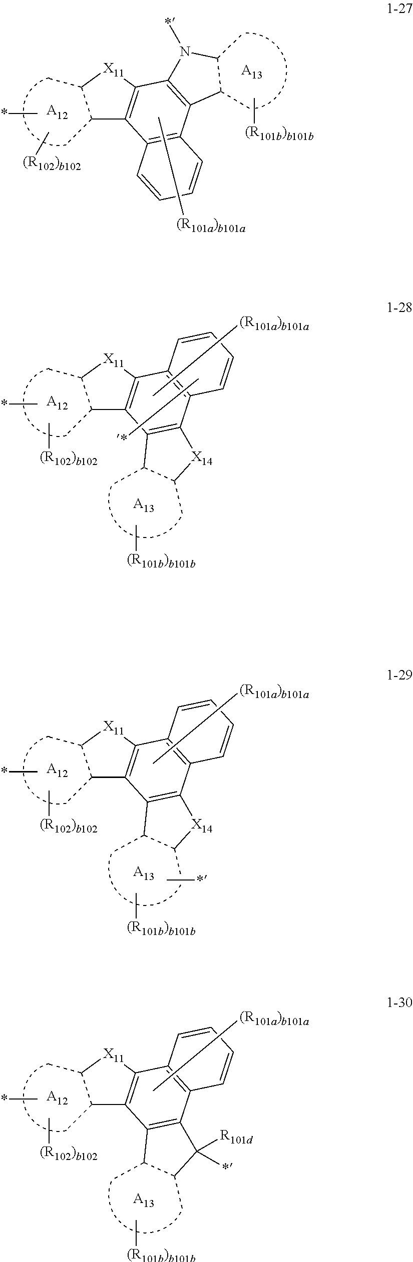

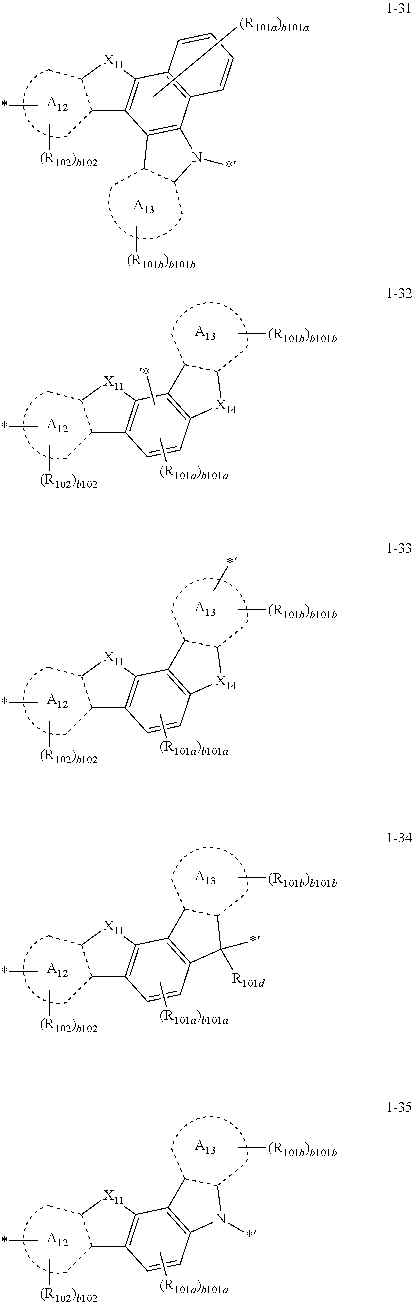

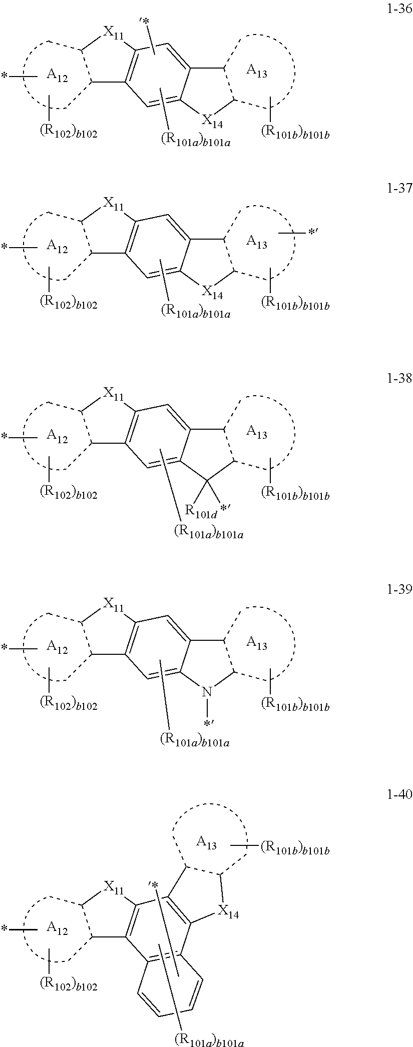

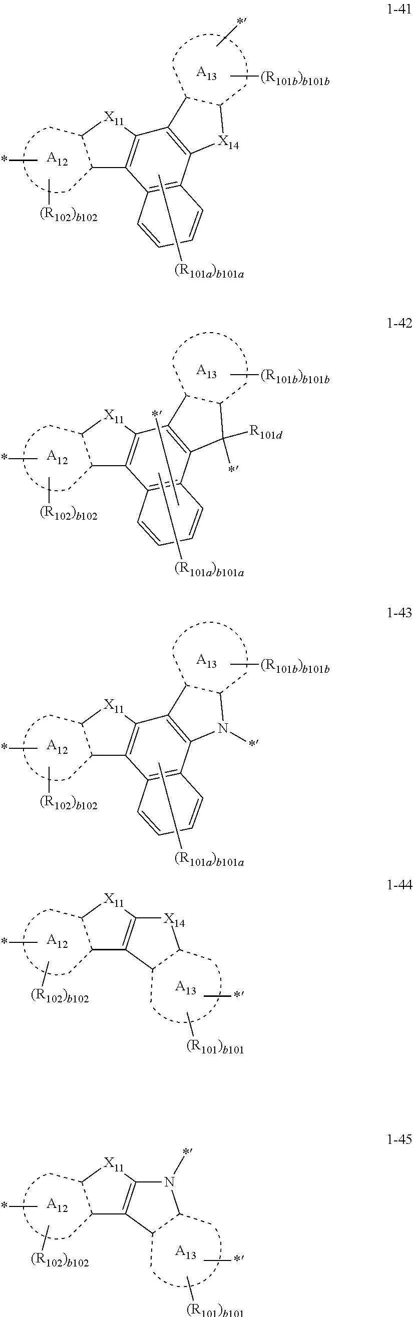

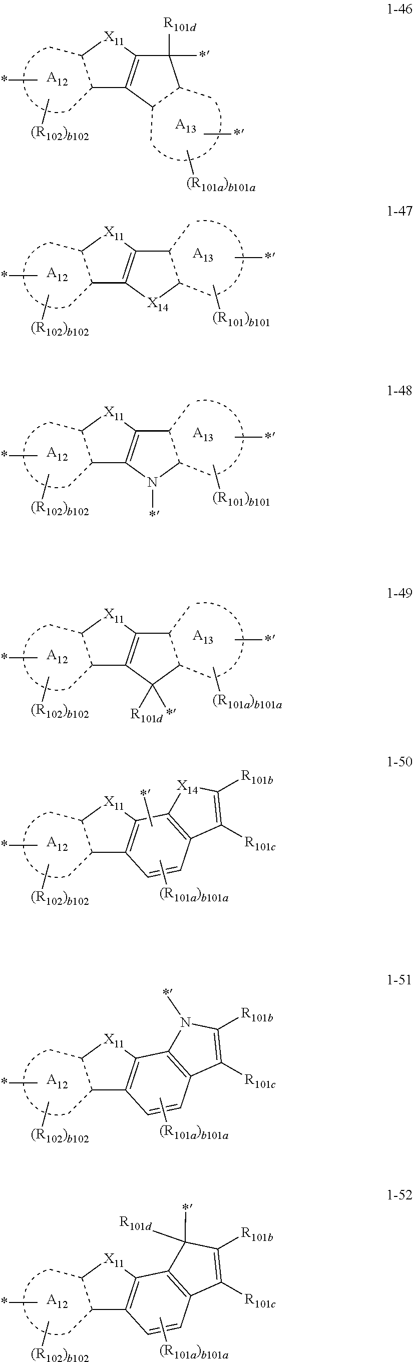

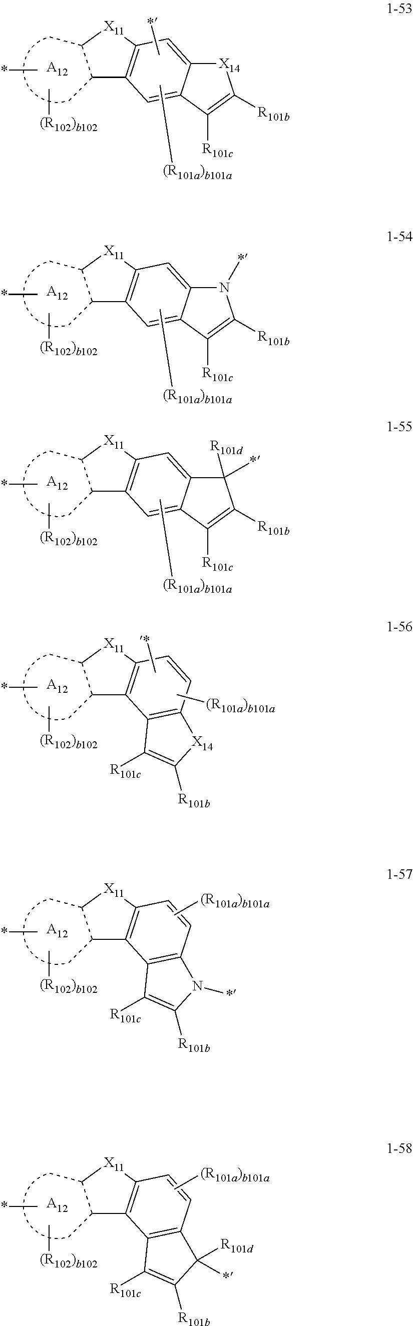

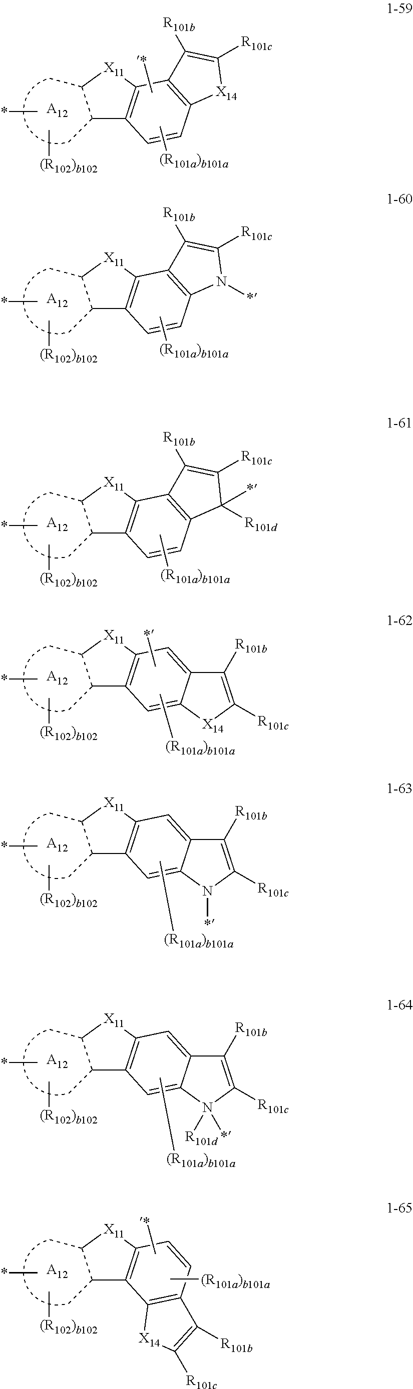

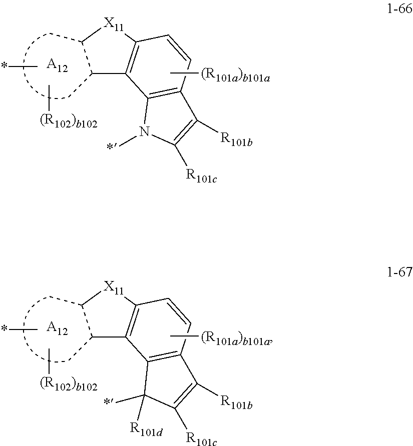

wherein, in Formulae 1-11 to 1-67,

A₁₁ and A₁₃ may each independently be selected from a benzene group, a naphthalene group, a pyridine group, a pyrimidine group, a pyrazine group, a quinoline group, an isoquinoline group, and a phenanthroline group,

X₁₁ may be selected from N[(L₁₃)ₐ₁₃-R₁₃], C[(L₁₃)ₐ₁₃-R₁₃][(L₁₄)ₐ₁₄-R₁₄], O, and S,

X₁₄ may be selected from C(R_{101d})(R₁₀₁ₑ), N(R_{101d}), O, and S,

descriptions of L₁₃, L₁₄, a13, a14, R₁₃, R₁₄, R₁₀₁, R₁₀₂, b101, and b102 are the same as those provided in connection with Formula 1,

descriptions of R₁₀₁ₐ, R_{101b}, R₁₀₁ₑ, R_{101d}, and R₁₀₁ₑ are each independently the same as the description provided in connection with R₁₀₁ in Formula 1,

descriptions of b101a and b101b are each independently the same as the description provided in connection with b101 in Formula 1, and

* and *′ each independently indicate a binding site to a neighboring atom.

For example, a group represented by Formula 8-1 and a group represented by Formula 8-2 may each independently be selected from groups represented by Formulae 8-11 to 8-44 but are not limited thereto:

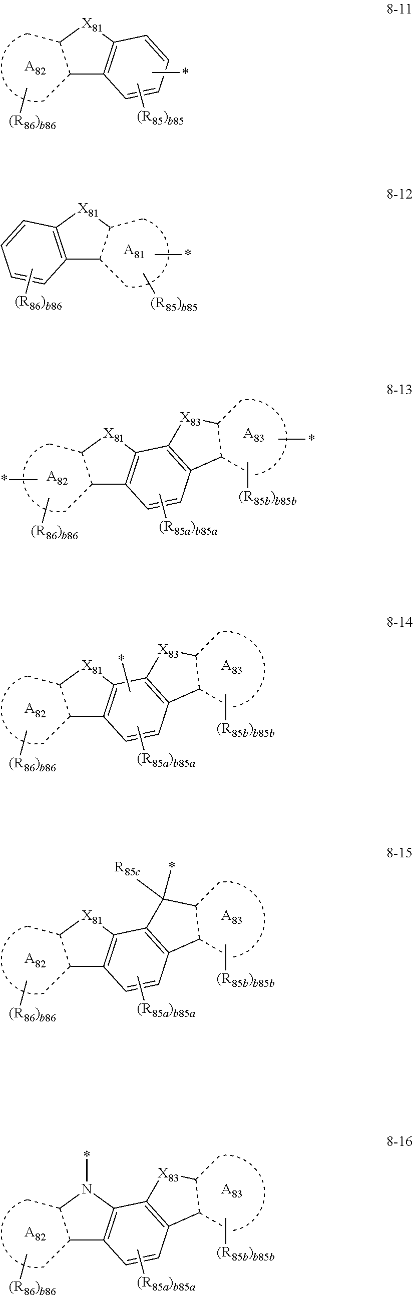

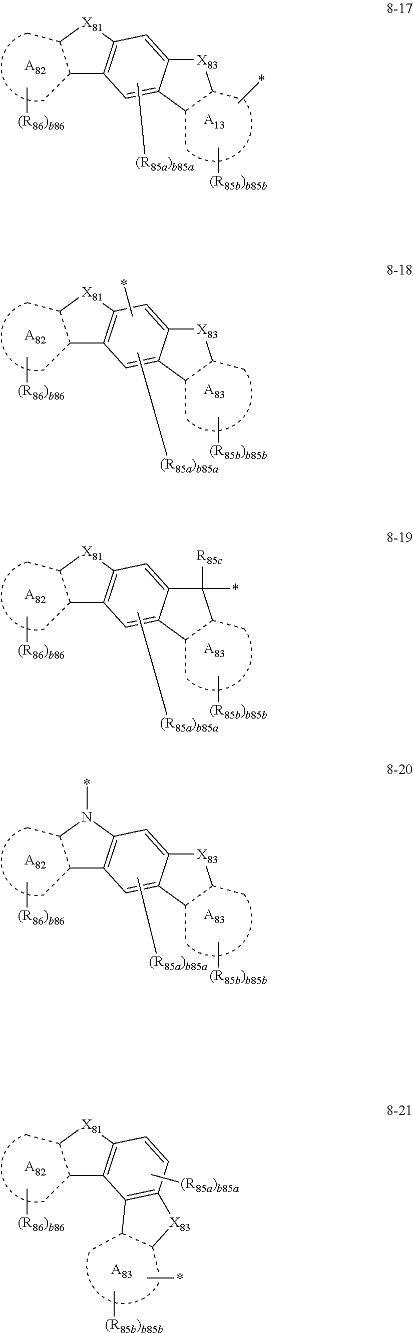

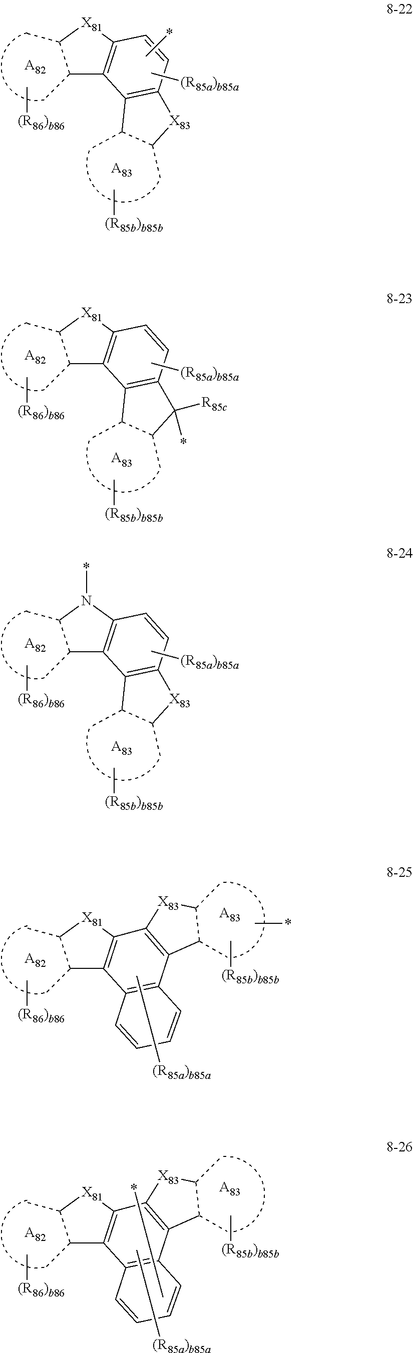

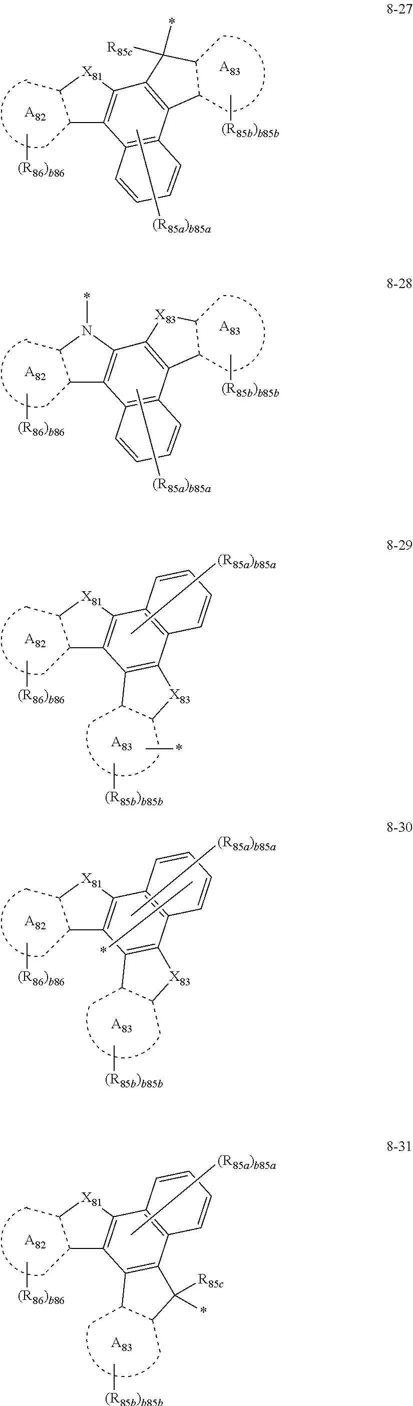

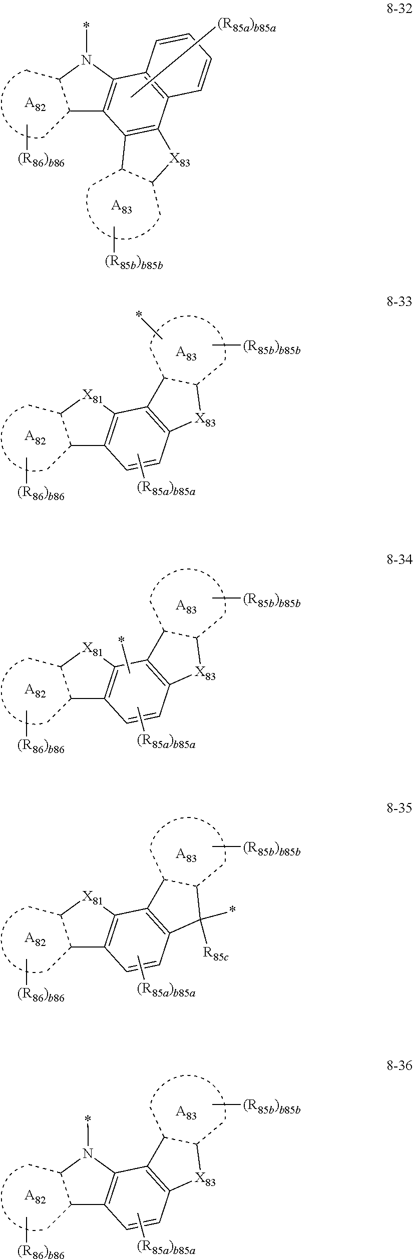

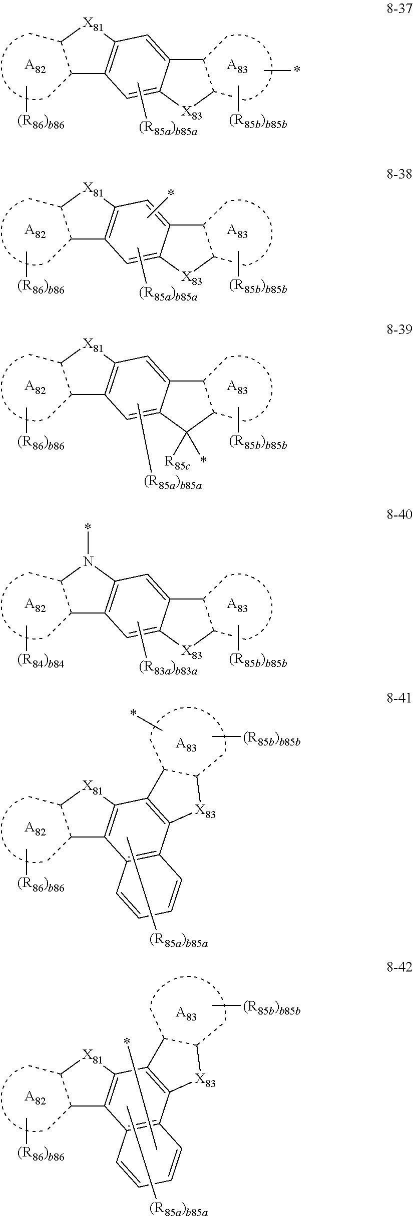

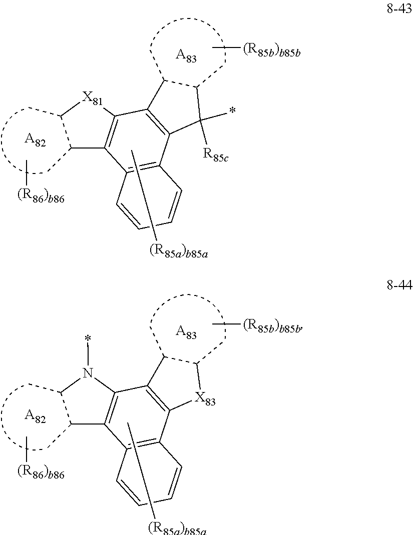

wherein, in Formulae 8-11 to 8-44,

A₈₁ and A₈₃ may each independently be selected from a benzene group, a naphthalene group, a pyridine group, a pyrimidine group, a pyrazine group, a quinoline group, an isoquinoline group, and a phenanthroline group,

X₈₁ may be selected from N[(L₈₁)ₐ₈₁-R₈₁], C[(L₈₁a)ₐ₈₁-R₈₁][(L₈₂)ₐ₈₂-R₈₂], O, and S,

X₈₃ may be selected from C(R_{85c})(R_{85d}), N(R_{85c}), O, and S,

descriptions of L₈₁, L₈₂, a81, a82, R₈₁, R₈₂, R₈₅, R₈₆, b85, and b86 are the same as those provided in connection with Formulae 8-1 and 8-2,

descriptions of R₈₅ₐ, R_{85b}, R_{85c}, and R_{85d} are each independently the same as the description provided in connection with R₈₅ in Formulae 8-1 and 8-2,

descriptions of b85a and b86b are each independently the same as the description provided in connection with b85 in Formula 8-1, and

* and *′ each independently indicate a binding site to a neighboring atom.

A₂₁ in Formula 2 may be selected from a C₆-C₂₀ arene group and a C₁-C₂₀ heteroarene group.

For example, A₂₁ in Formula 2 may be selected from a benzene group, a naphthalene group, a phenanthrene group, an anthracene group, a pyridine group, a pyrazine group, a pyrimidine group, a triazine group, a quinoline group, an isoquinoline group, a quinoxaline group, and a quinazoline group, but is not limited thereto.

In various embodiments, A₂₁ in Formula 2 may be selected from a benzene group, a pyridine group, a pyrazine group, a pyrimidine group, and a triazine group, but is not limited thereto.

In Formula 2, X₂₁ may be selected from N and C(R₂₁), X₂₂ may be selected from N and C(R₂₂), X₂₃ may be selected from N and C(R₂₃), X₂₄ may be selected from N and C(R₂₄), and X₂₅ may be selected from N and C(R₂₅), wherein at least one selected from X₂₁ to X₂₅ may be N, and R₂₁ to R₂₅ are the same as described below.

For example, in Formula 2, X₂₁ may be N, X₂₂ may be C(R₂₂), X₂₃ may be C(R₂₃), X₂₄ may be C(R₂₄), and X₂₅ may be C(R₂₅);

X₂₁ may be C(R₂₁), X₂₂ may be N, X₂₃ may be C(R₂₃), X₂₄ may be C(R₂₄), and X₂₅ may be C(R₂₅);

X₂₁ may be C(R₂₁), X₂₂ may be C(R₂₂), X₂₃ may be N, X₂₄ may be C(R₂₄), and X₂₅ may be C(R₂₅);

X₂₁ may be C(R₂₁), X₂₂ may be C(R₂₂), X₂₃ may be C(R₂₃), X₂₄ may be N, and X₂₅ may be C(R₂₅);

X₂₁ may be C(R₂₁), X₂₂ may be C(R₂₂), X₂₃ may be C(R₂₃), X₂₄ may be C(R₂₄), and X₂₅ may be N;

X₂₁ may be N, X₂₂ may be C(R₂₂), X₂₃ may be C(R₂₃), X₂₄ may be C(R₂₄), and X₂₅ may be N;

X₂₁ may be N, X₂₂ may be C(R₂₂), X₂₃ may be N, X₂₄ may be C(R₂₄), and X₂₅ may be C(R₂₅);

X₂₁ may be C(R₂₁), X₂₂ may be C(R₂₂), X₂₃ may be N, X₂₄ may be C(R₂₄), and X₂₅ may be N; or

X₂₁ may be N, X₂₂ may be C(R₂₂), X₂₃ may be N, X₂₄ may be C(R₂₄), and X₂₅ may be N, but embodiments are not limited thereto.

R₂₁ to R₂₆ in Formula 2 may each independently be selected from a group represented by any of Formulae 9-1 to 9-3, hydrogen, deuterium, —F, —Cl, —Br, —I, a hydroxyl group, a cyano group, a nitro group, an amidino group, a hydrazino group, a hydrazono group, a substituted or unsubstituted C₁-C₆₀ alkyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₁)(Q₂), —B(Q₁)(Q₂), —C(═O)(Q₁), —S(═O)₂(Q₁), and —P(═O)(Q₁)(Q₂), and at least one selected from R₂₁ to R₂₆ may be selected from the group represented by Formula 9-1 and the group represented by Formula 9-2,

wherein Q₁ to Q₃ may each independently be selected from hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, and a terphenyl group.

For example, R₂₁ to R₂₆ in Formula 2 may each independently be selected from the group consisting of:

a group represented by any of Formulae 9-1 to 9-3, hydrogen, a C₁-C₂₀ alkyl group, and a C₃-C₁₀ cycloalkyl group;

a C₆-C₃₀ aryl group, a C₁-C₃₀ heteroaryl group, a monovalent non-aromatic condensed polycyclic group, and a monovalent non-aromatic condensed heteropolycyclic group;

a C₆-C₃₀ aryl group, a C₁-C₃₀ heteroaryl group, a monovalent non-aromatic condensed polycyclic group, and a monovalent non-aromatic condensed heteropolycyclic group, each substituted with at least one selected from deuterium, —F, —Cl, —Br, —I, a C₁-C₂₀ alkyl group, a C₃-C₁₀ cycloalkyl group, a C₆-C₃₀ aryl group, a C₁-C₃₀ heteroaryl group, a monovalent non-aromatic condensed polycyclic group, a monovalent non-aromatic condensed heteropolycyclic group, —N(Q₃₁)(Q₃₂), and —Si(Q₃₁)(Q₃₂)(Q₃₃); and

a C₆-C₃₀ aryl group, a C₁-C₃₀ heteroaryl group, a monovalent non-aromatic condensed polycyclic group, and a monovalent non-aromatic condensed heteropolycyclic group, each substituted with at least one selected from a C₆-C₃₀ aryl group, a C₁-C₃₀ heteroaryl group, a monovalent non-aromatic condensed polycyclic group, and a monovalent non-aromatic condensed heteropolycyclic group, each substituted with at least one selected from deuterium, —F, —Cl, —Br, —I, a C₁-C₂₀ alkyl group, a C₃-C₁₀ cycloalkyl group, a C₆-C₃₀ aryl group, a C₁-C₃₀ heteroaryl group, a monovalent non-aromatic condensed polycyclic group, a monovalent non-aromatic condensed heteropolycyclic group, —N(Q₂₁)(Q₂₂), and —Si(Q₂₁)(Q₂₂)(Q₂₃),

wherein Q₂₁ to Q₂₃ and Q₃₁ to Q₃₃ may each independently be selected from a C₁-C₂₀ alkyl group and a C₆-C₃₀ aryl group, but embodiments are not limited thereto.

In various embodiments, R₂₁ to R₂₆ in Formula 2 may each independently be selected from the group consisting of:

a group represented by any of Formulae 9-1 to 9-3, hydrogen, a methyl group, an ethyl group, an n-propyl group, an iso-propyl group, an n-butyl group, an iso-butyl group, a sec-butyl group, a tert-butyl group, a cyclopentyl group, and a cyclohexyl group;

a phenyl group, a biphenyl group, a terphenyl group, a naphthyl group, an anthracenyl group, a triphenylenyl group, a phenanthrenyl group, a pyrenyl group, a tetraphenyl group, a chrysenyl group, a pyrrolyl group, a furanyl group, a thiophenyl group, a pyridinyl group, a pyrazinyl group, a pyrimidinyl group, a triazinyl group, a quinolinyl group, an isoquinolinyl group, a benzoquinolinyl group, a phthalazinyl group, a naphthyridinyl group, a quinoxalinyl group, a quinazolinyl group, a phenanthridinyl group, an acridinyl group, a phenanthrolinyl group, a phenazinyl group, a benzophenanthrolinyl group, a thiazolyl group, an oxazolyl group, an imidazolyl group, a triazolyl group, an indolyl group, a benzimidazolyl group, a benzofuranyl group, a benzothiophenyl group, a benzoxazolyl group, a dibenzofuranyl group, a dibenzothiophenyl group, a carbazolyl group, a fluorenyl group, a spiro-cyclopentane-fluorenyl group, a spiro-bifluorenyl group, a benzonaphthofuranyl group, a benzonaphthothiophenyl group, a benzocarbazolyl group, and a benzofluorenyl group;

a phenyl group, a biphenyl group, a terphenyl group, a naphthyl group, an anthracenyl group, a triphenylenyl group, a phenanthrenyl group, a pyrenyl group, a tetraphenyl group, a chrysenyl group, a pyrrolyl group, a furanyl group, a thiophenyl group, a pyridinyl group, a pyrazinyl group, a pyrimidinyl group, a triazinyl group, a quinolinyl group, an isoquinolinyl group, a benzoquinolinyl group, a phthalazinyl group, a naphthyridinyl group, a quinoxalinyl group, a quinazolinyl group, a phenanthridinyl group, an acridinyl group, a phenanthrolinyl group, a phenazinyl group, a benzophenanthrolinyl group, a thiazolyl group, an oxazolyl group, an imidazolyl group, a triazolyl group, an indolyl group, a benzimidazolyl group, a benzofuranyl group, a benzothiophenyl group, a benzoxazolyl group, a dibenzofuranyl group, a dibenzothiophenyl group, a carbazolyl group, a fluorenyl group, a spiro-cyclopentane-fluorenyl group, a spiro-bifluorenyl group, a benzonaphthofuranyl group, a benzonaphthothiophenyl group, a benzocarbazolyl group, and a benzofluorenyl group, each substituted with at least one selected from deuterium, —F, —Cl, —Br, —I, a C₁-C₂₀ alkyl group, a C₃-C₁₀ cycloalkyl group, a C₆-C₃₀ aryl group, a C₁-C₃₀ heteroaryl group, a monovalent non-aromatic condensed polycyclic group, a monovalent non-aromatic condensed heteropolycyclic group, —N(Q₃₁)(Q₃₂), and —Si(Q₃₁)(Q₃₂)(Q₃₃); and

a phenyl group, a biphenyl group, a terphenyl group, a naphthyl group, an anthracenyl group, a triphenylenyl group, a phenanthrenyl group, a pyrenyl group, a tetraphenyl group, a chrysenyl group, a pyrrolyl group, a furanyl group, a thiophenyl group, a pyridinyl group, a pyrazinyl group, a pyrimidinyl group, a triazinyl group, a quinolinyl group, an isoquinolinyl group, a benzoquinolinyl group, a phthalazinyl group, a naphthyridinyl group, a quinoxalinyl group, a quinazolinyl group, a phenanthridinyl group, an acridinyl group, a phenanthrolinyl group, a phenazinyl group, a benzophenanthrolinyl group, a thiazolyl group, an oxazolyl group, an imidazolyl group, a triazolyl group, an indolyl group, a benzimidazolyl group, a benzofuranyl group, a benzothiophenyl group, a benzoxazolyl group, a dibenzofuranyl group, a dibenzothiophenyl group, a carbazolyl group, a fluorenyl group, a spiro-cyclopentane-fluorenyl group, a spiro-bifluorenyl group, a benzonaphtho furanyl group, a benzonaphthothiophenyl group, a benzocarbazolyl group, and a benzofluorenyl group, each substituted with at least one selected from a phenyl group, a biphenyl group, a terphenyl group, a naphthyl group, a pyridinyl group, a pyrimidinyl group, a pyridazinyl group, and a triazinyl group, each substituted with at least one selected from deuterium, —F, —Cl, —Br, —I, a C₁-C₂₀ alkyl group, a C₃-C₁₀ cycloalkyl group, a C₆-C₃₀ aryl group, a C₁-C₃₀ heteroaryl group, a monovalent non-aromatic condensed polycyclic group, a monovalent non-aromatic condensed heteropolycyclic group, —N(Q₂₁)(Q₂₂), and —Si(Q₂₁)(Q₂₂)(Q₂₃),

wherein Q₂₁ to Q₂₃ and Q₃₁ to Q₃₃ may each independently be selected from a methyl group, an ethyl group, a phenyl group, a biphenyl group, a terphenyl group, and a naphthyl group, but embodiments are not limited thereto.

In various embodiments, R₂₁ to R₂₆ in Formula 2 may each independently be selected from a group represented by any of Formulae 9-1 to 9-3, hydrogen, a methyl group, an ethyl group, an n-propyl group, an iso-propyl group, an n-butyl group, an iso-butyl group, a sec-butyl group, a tert-butyl group, a cyclopentyl group, a cyclohexyl group, and a group represented by any of Formulae 5-1 to 5-79, but are not limited thereto:

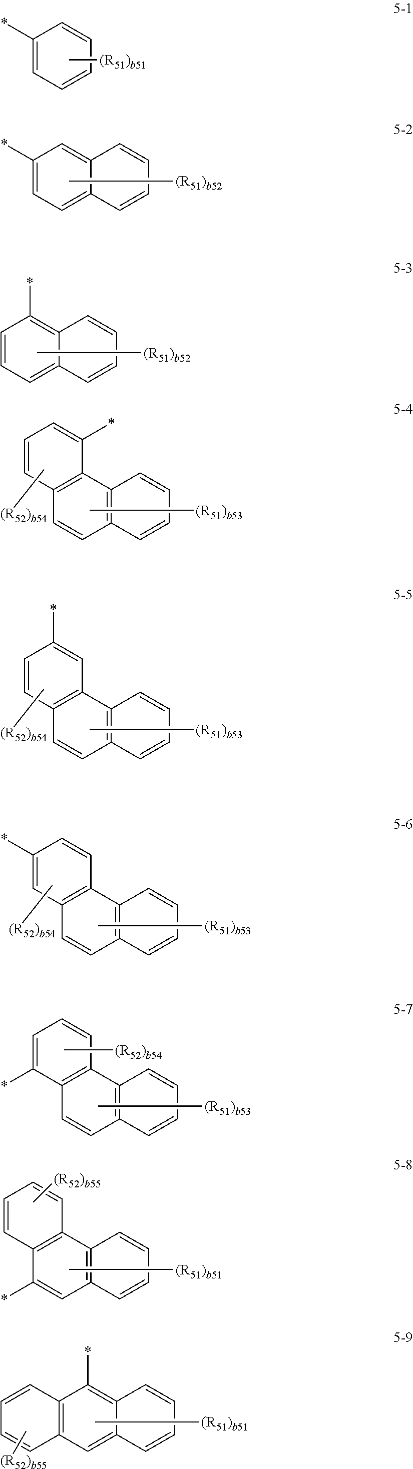

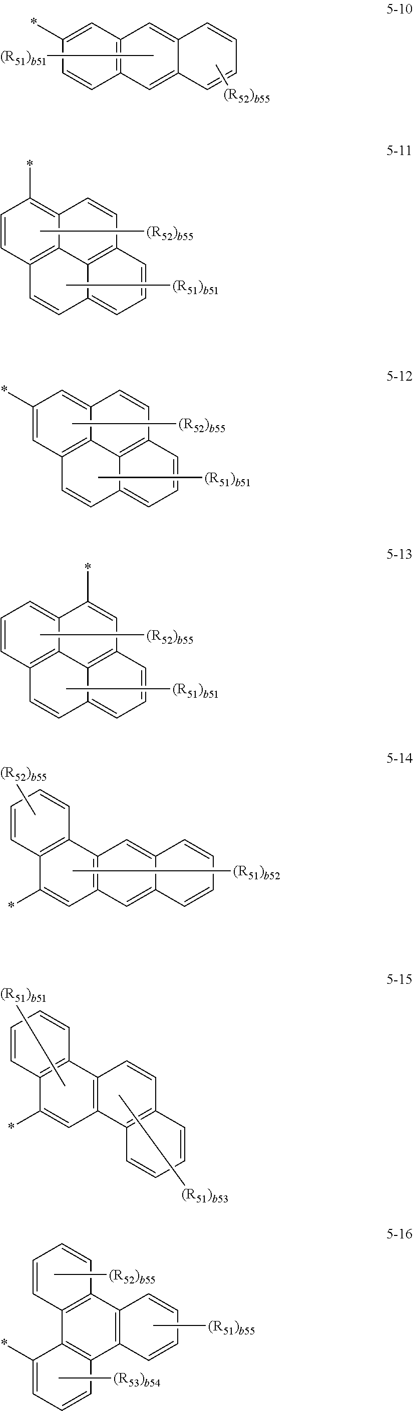

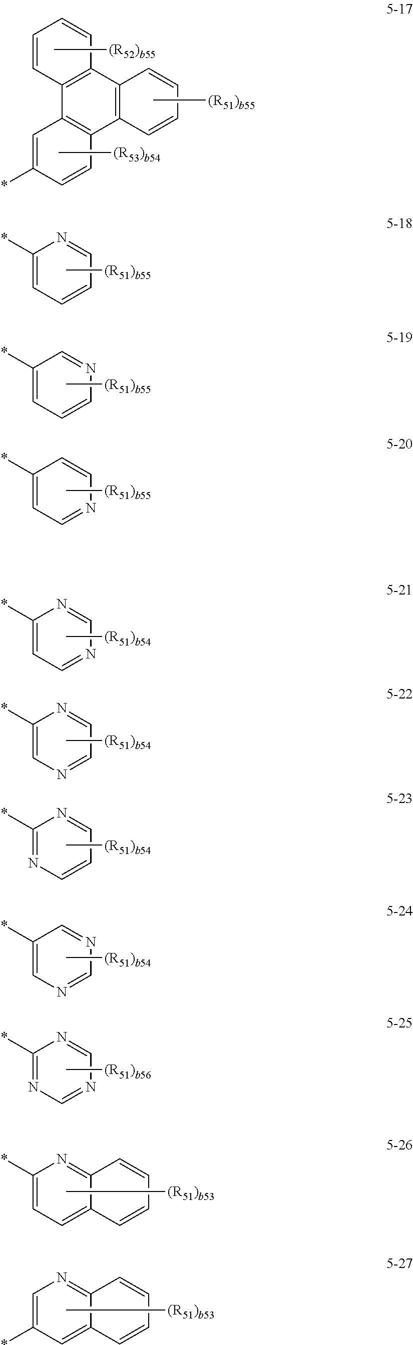

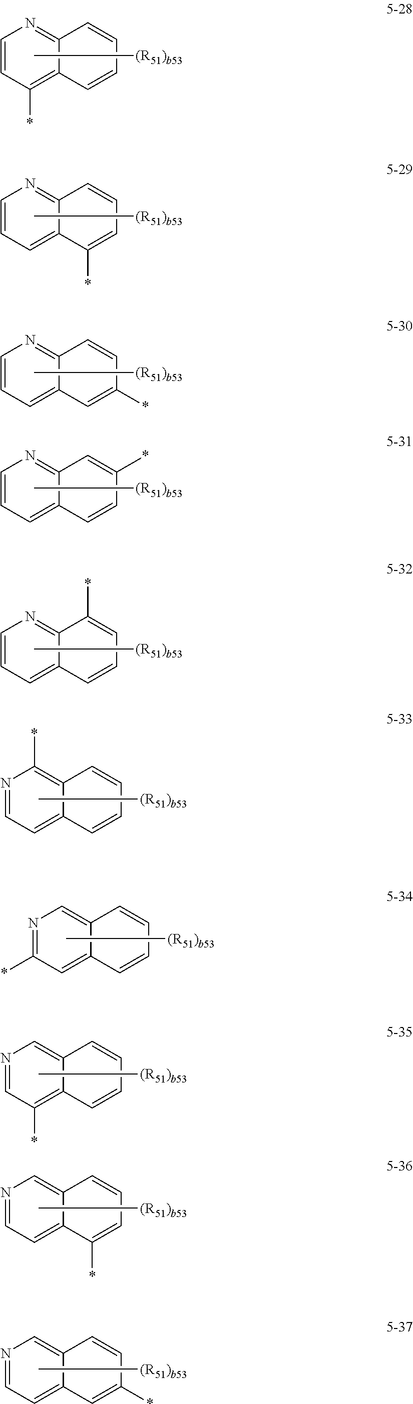

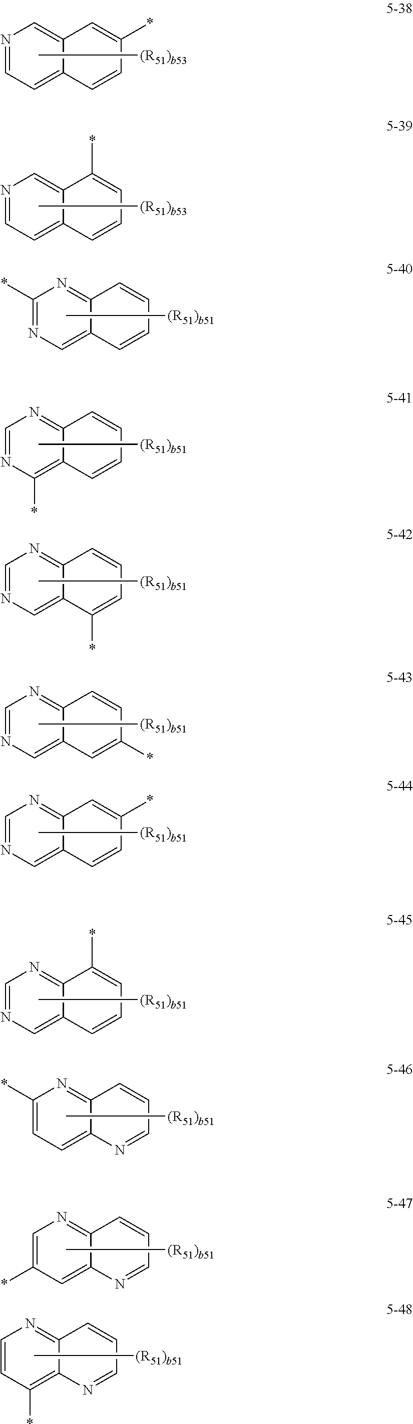

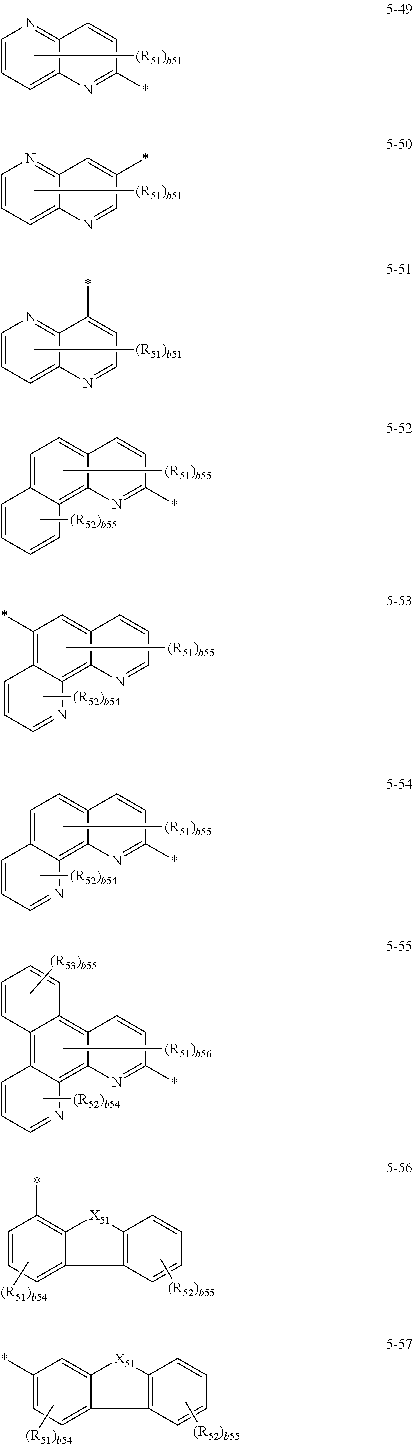

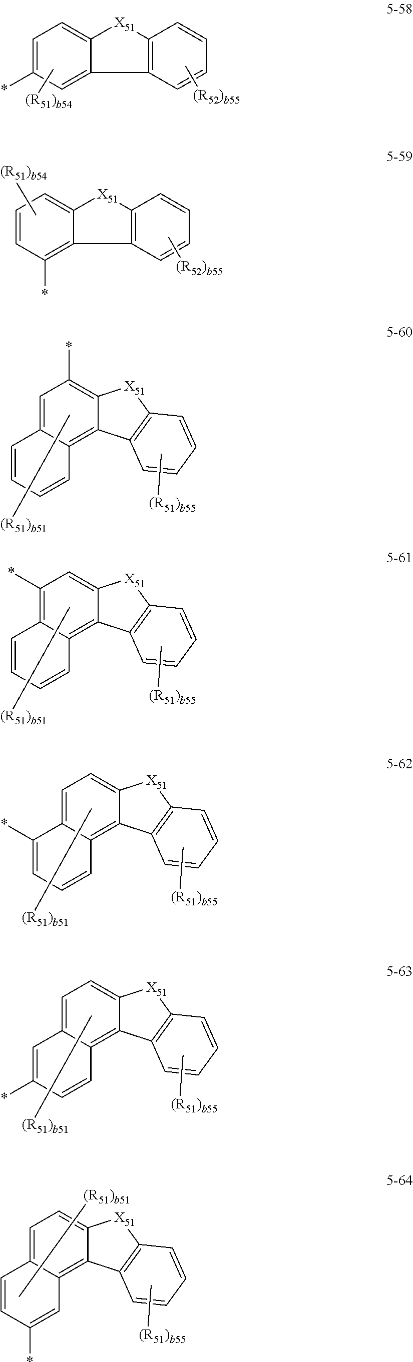

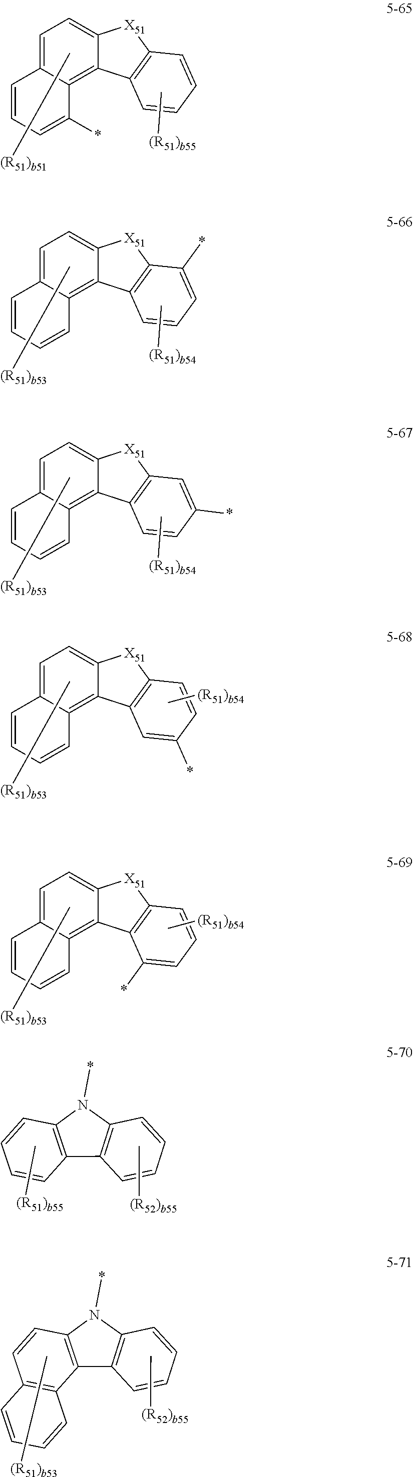

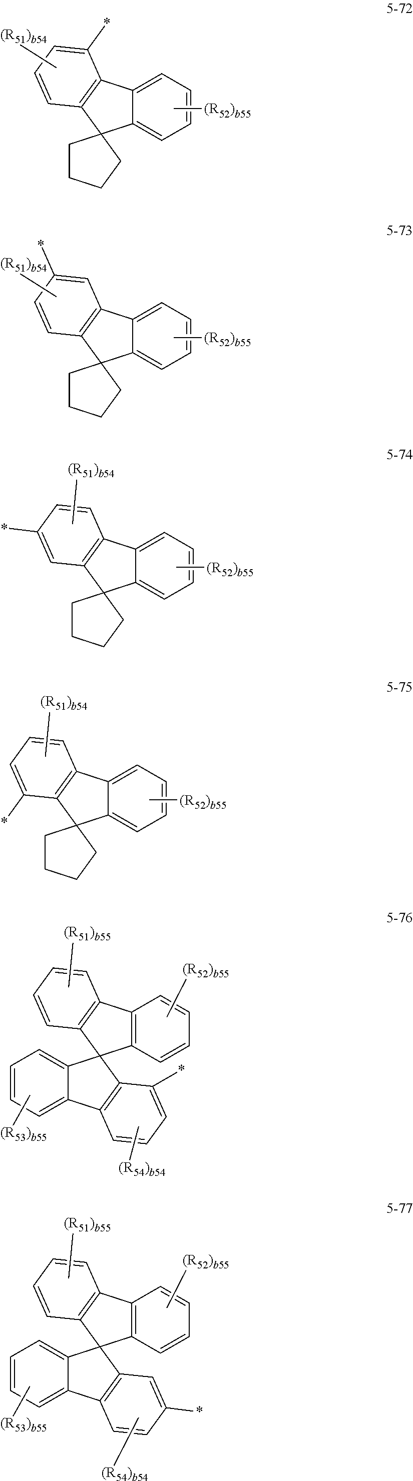

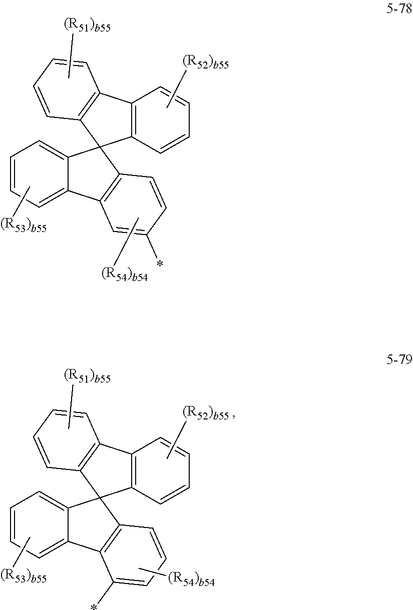

wherein, in Formulae 5-1 to 5-79,

X₅₁ may be selected from N(R₅₅), C(R₅₅)(R₅₆), O, and S,

R₅₁ to R₅₆ may each independently be selected from the group consisting of:

hydrogen, deuterium, —F, —Cl, —Br, —I, a C₁-C₂₀ alkyl group, a C₃-C₁₀ cycloalkyl group, a C₆-C₃₀ aryl group, a C₁-C₃₀ heteroaryl group, a monovalent non-aromatic condensed polycyclic group, a monovalent non-aromatic condensed heteropolycyclic group, —N(Q₃₁)(Q₃₂), and —Si(Q₃₁)(Q₃₂)(Q₃₃); and

a phenyl group, a biphenyl group, a terphenyl group, a naphthyl group, a pyridinyl group, a pyrimidinyl group, a pyridazinyl group, and a triazinyl group, each substituted with at least one selected from deuterium, —F, —Cl, —Br, —I, a C₁-C₂₀ alkyl group, a C₃-C₁₀ cycloalkyl group, a C₆-C₃₀ aryl group, a C₁-C₃₀ heteroaryl group, a monovalent non-aromatic condensed polycyclic group, a monovalent non-aromatic condensed heteropolycyclic group, —N(Q₂₁)(Q₂₂), and —Si(Q₂₁)(Q₂₂)(Q₂₃),

wherein Q₂₁ to Q₂₃ and Q₃₁ to Q₃₃ may each independently be selected from a methyl group, an ethyl group, a phenyl group, a biphenyl group, a terphenyl group, and a naphthyl group,

b51 may be selected from 1, 2, 3, 4, and 5,

b52 may be selected from 1, 2, 3, 4, 5, 6, and 7,

b53 may be selected from 1, 2, 3, 4, 5, and 6,

b54 may be selected from 1, 2, and 3,

b55 may be selected from 1, 2, 3, and 4,

b56 may be 1 or 2, and

* indicates a binding site to a neighboring atom.

b26 in Formula 2 indicates the number of R₂₆(s), and b26 may be selected from 1, 2, 3, 4, 5, and 6. When b26 is two or more, a plurality of R₂₆(s) may be identical to or different from each other.

L₉₁ in Formula 9-1 may be selected from a C₆-C₆₀ arylene group and a C₁-C₆₀ heteroarylene group, each substituted with a C₁-C₆₀ alkyl group and a C₃-C₁₀ cycloalkyl group.

For example, L₉₁ in Formula 9-1 may be selected from a phenylene group, a naphthylene group, a phenanthrenylene group, an anthracenylene group, a triphenylenylene group, a pyrenylene group, a chrysenylene group, a pyridinylene group, a pyrazinylene group, a pyrimidinylene group, a quinolinylene group, an isoquinolinylene group, a benzoquinolinylene group, a phthalazinylene group, a naphthyridinylene group, a quinoxalinylene group, a quinazolinylene group, a phenanthridinylene group, an acridinylene group, a phenanthrolinylene group, and a triazinylene group, each substituted with at least one selected from a C₁-C₂₀ alkyl group, a cyclopentyl group, a cyclohexyl group, and a cycloheptyl group, but is not limited thereto.

In various embodiments, L₉₁ in Formula 9-1 may be selected from a phenylene group, a naphthylene group, a pyridinylene group, a pyrazinylene group, a pyrimidinylene group, a quinolinylene group, an isoquinolinylene group, a naphthyridinylene group, a quinoxalinylene group, and a triazinylene group, each substituted with at least one selected from a methyl group, an ethyl group, an n-propyl group, an iso-propyl group, an n-butyl group, an iso-butyl group, a sec-butyl group, a tert-butyl group, a cyclopentyl group, a cyclohexyl group, and a cycloheptyl group, but is not limited thereto.

In various embodiments, L₉₁ in Formula 9-1 may be selected from groups represented by Formulae 3-1 to 3-13 and 3-16 to 3-163:

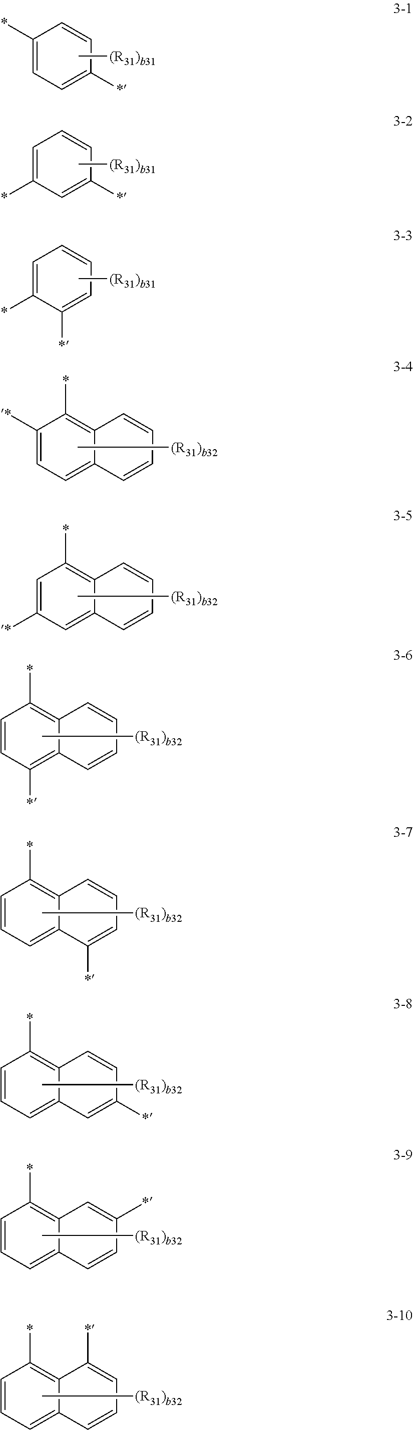

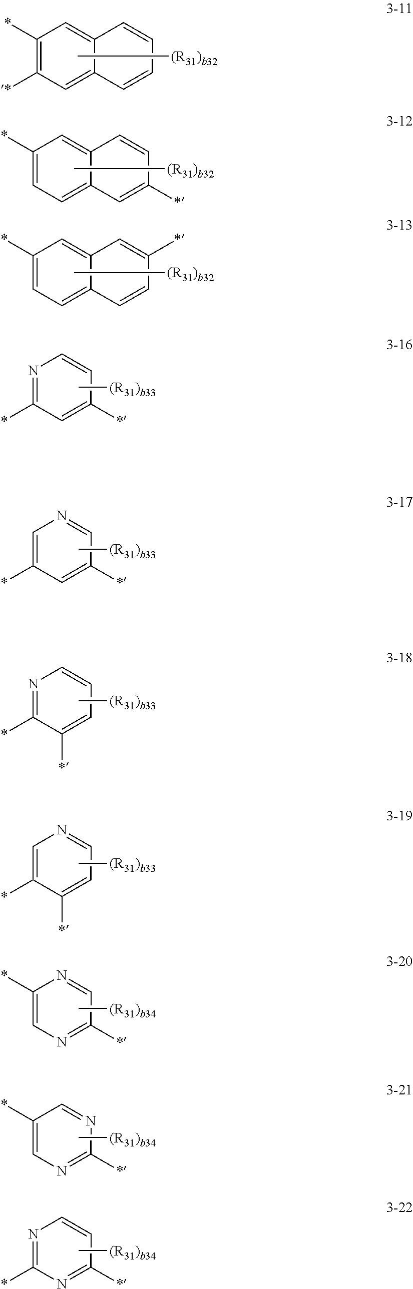

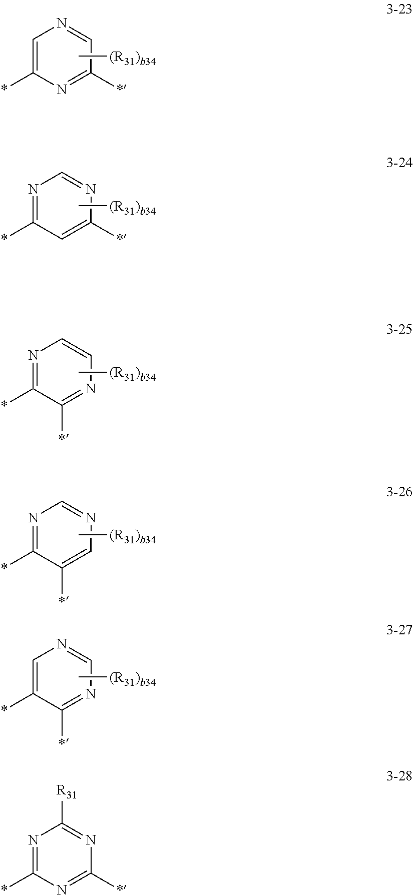

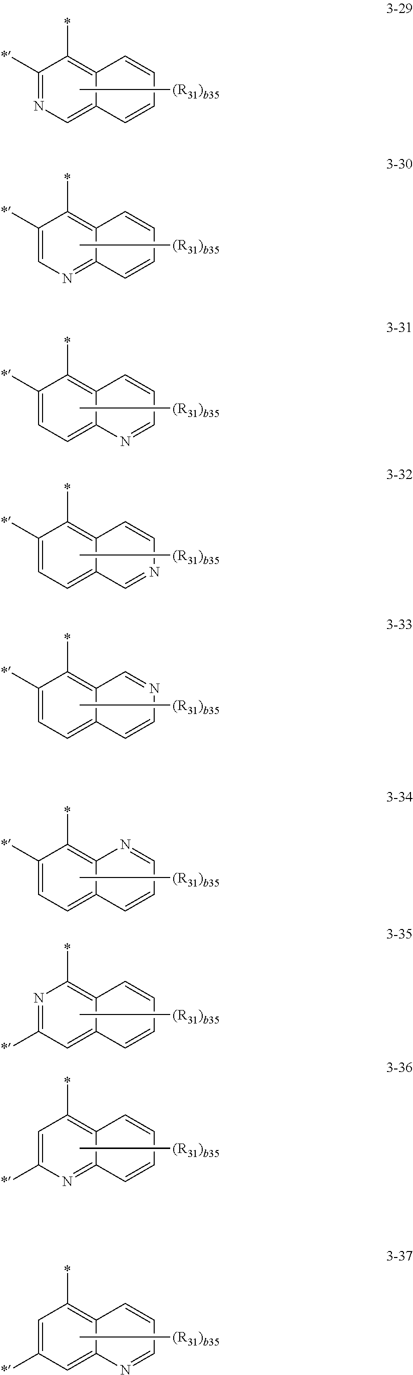

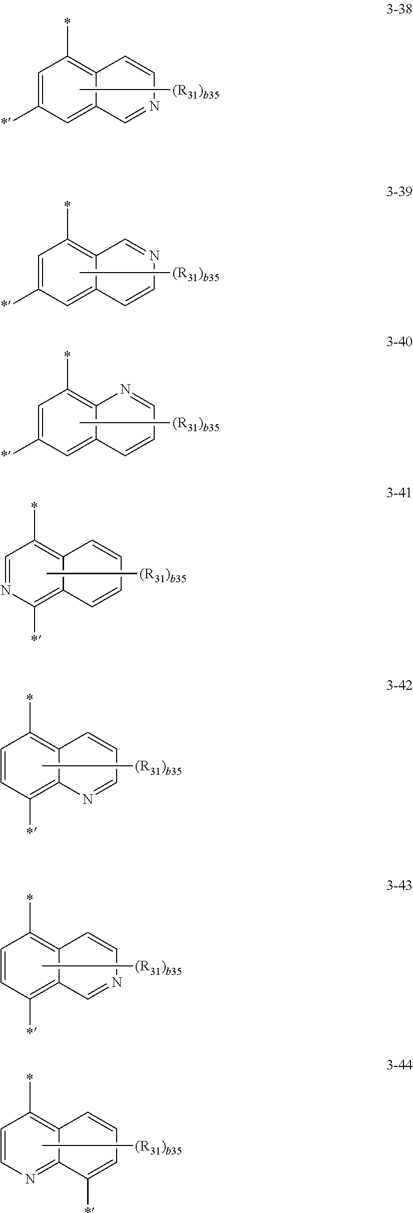

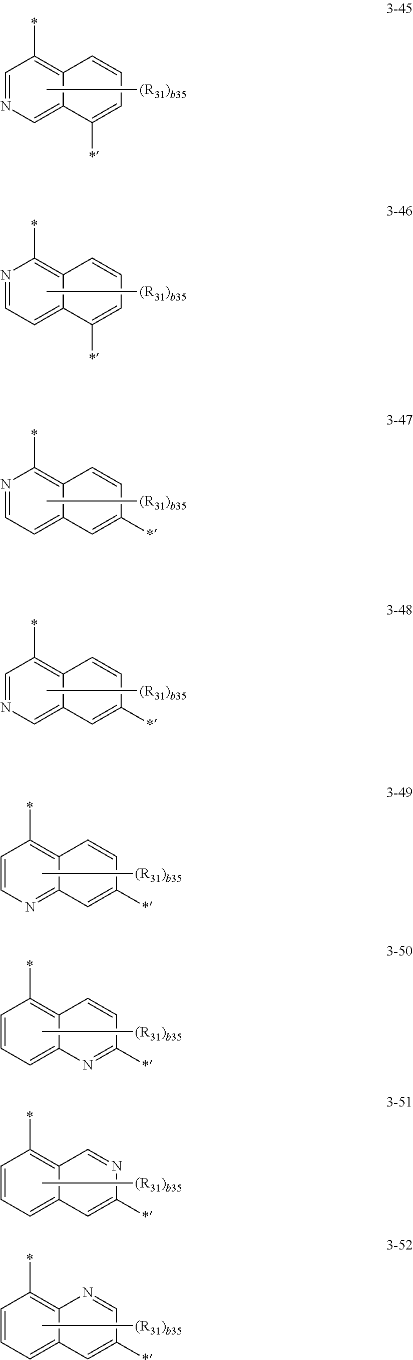

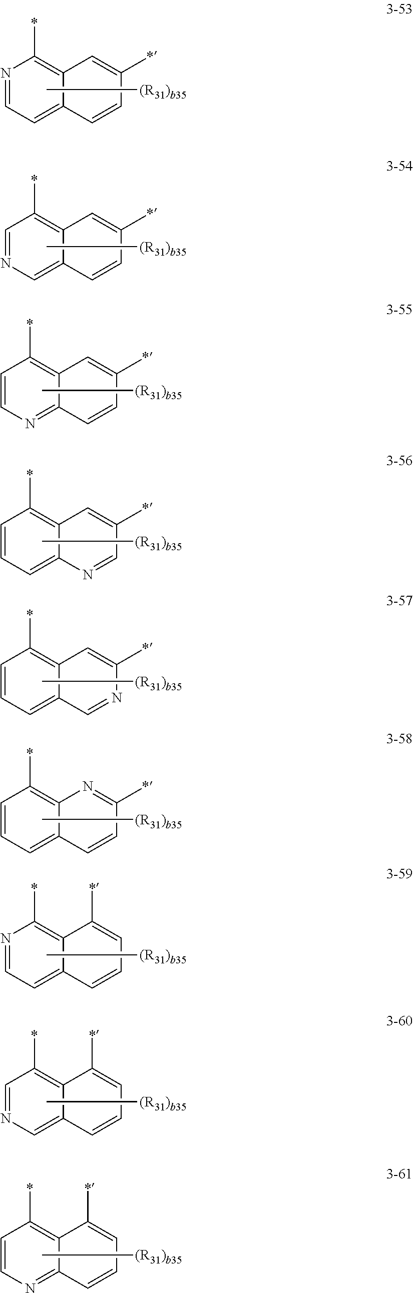

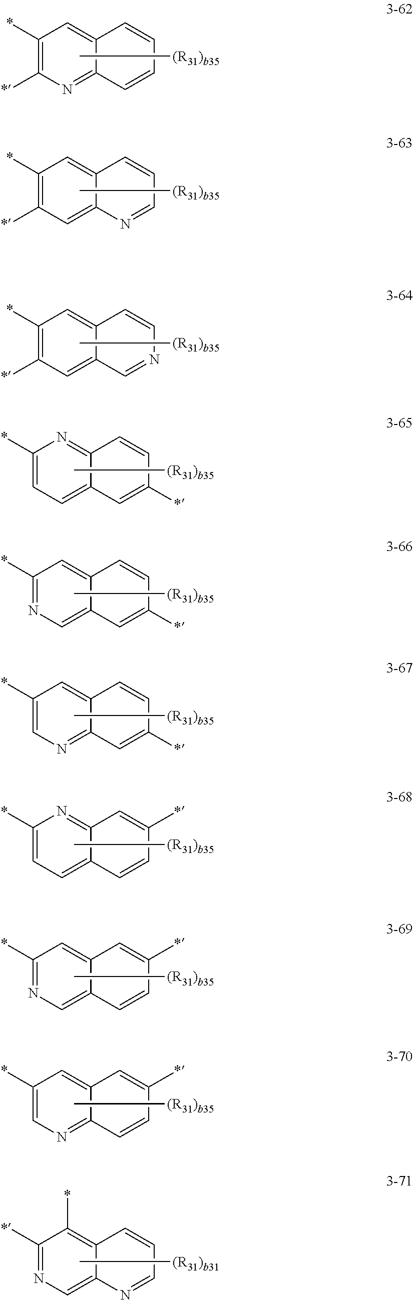

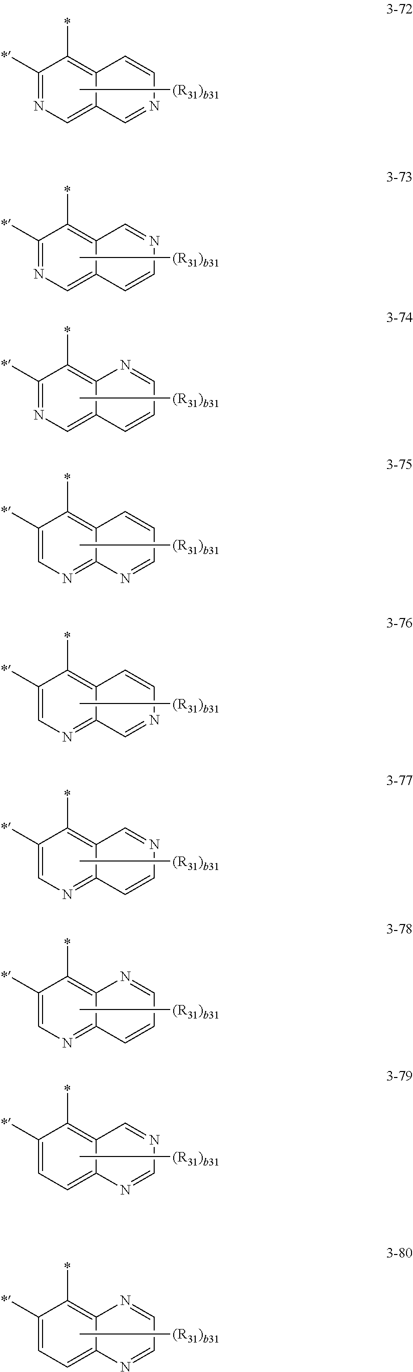

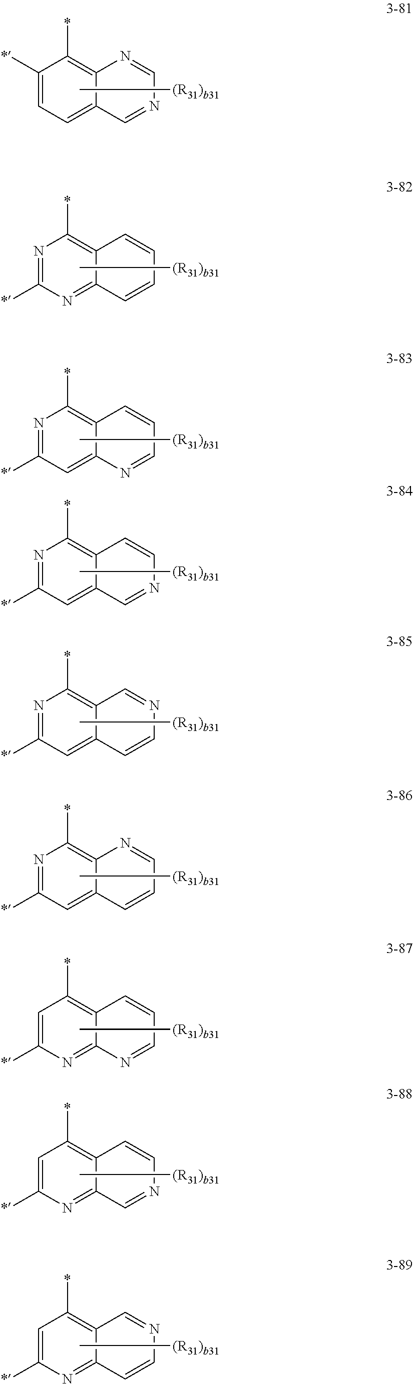

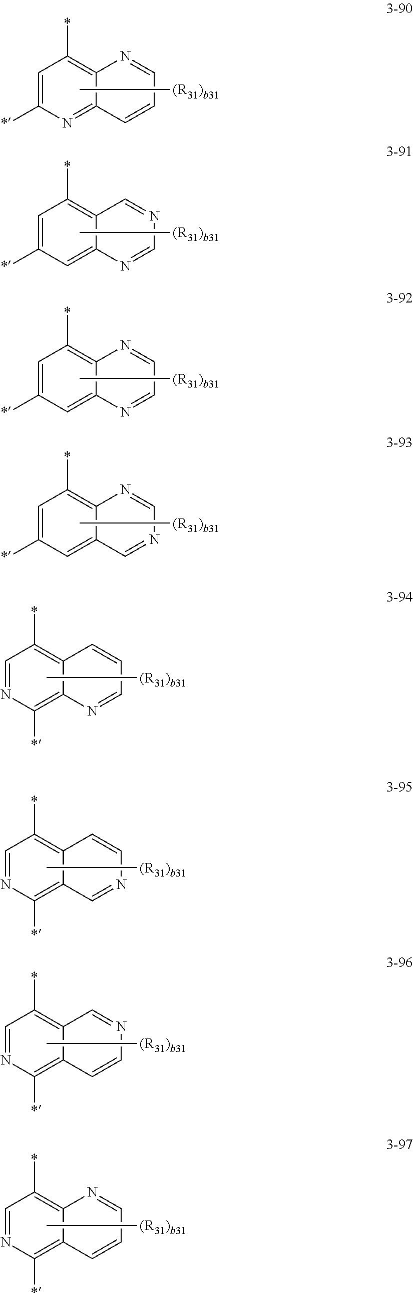

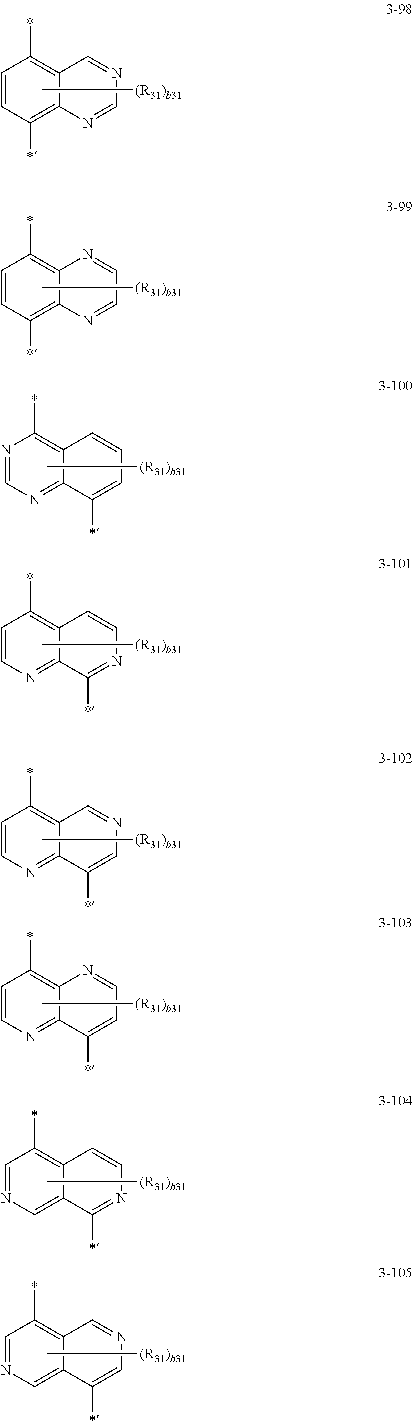

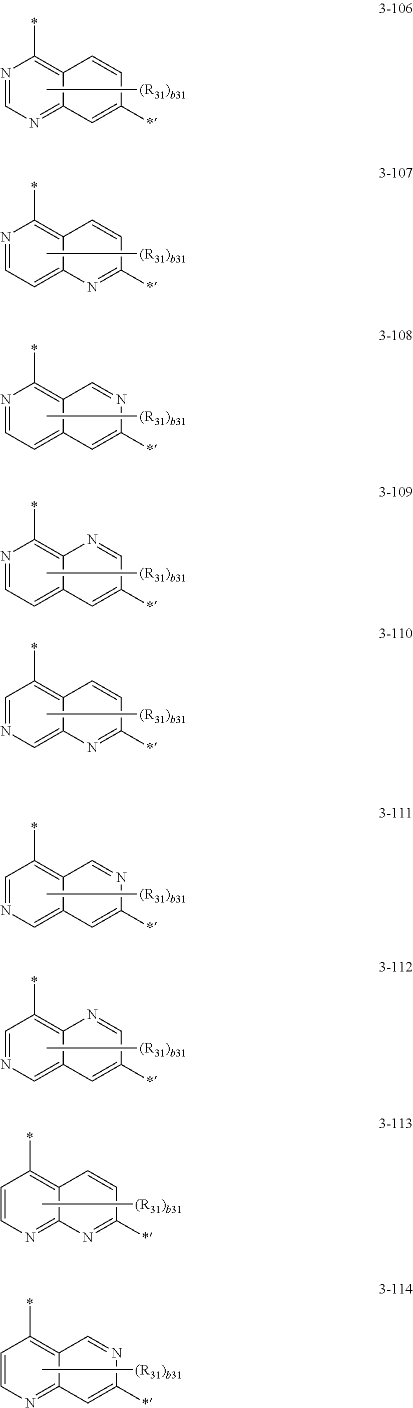

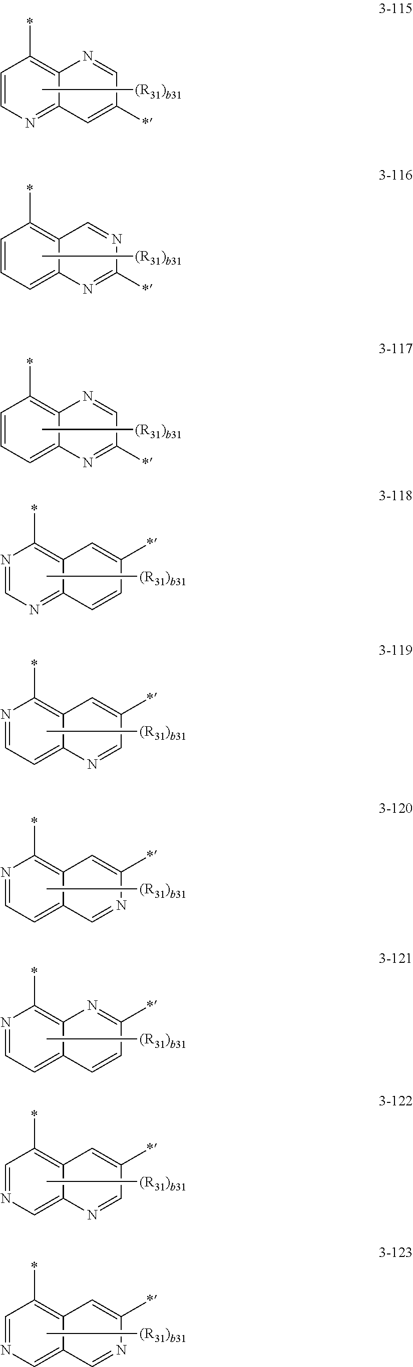

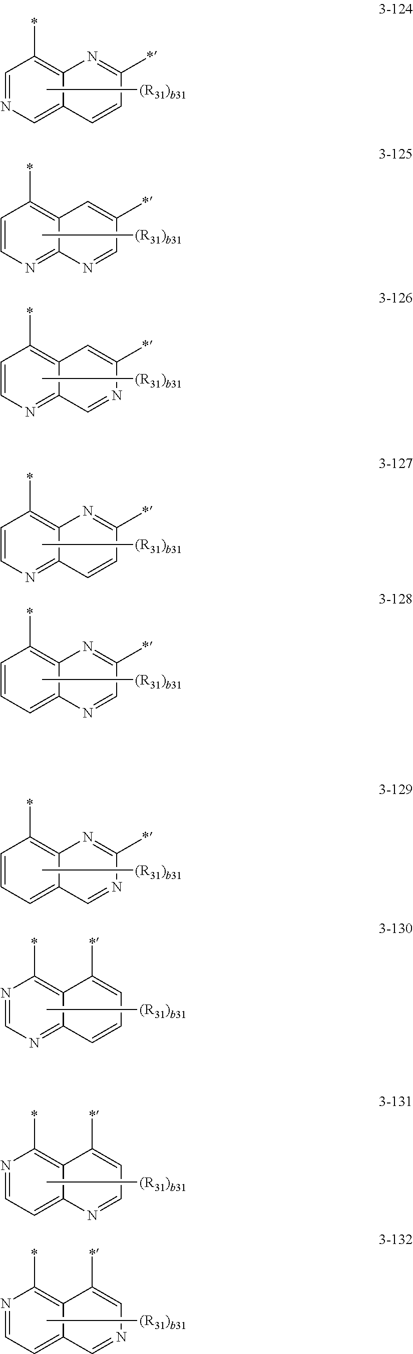

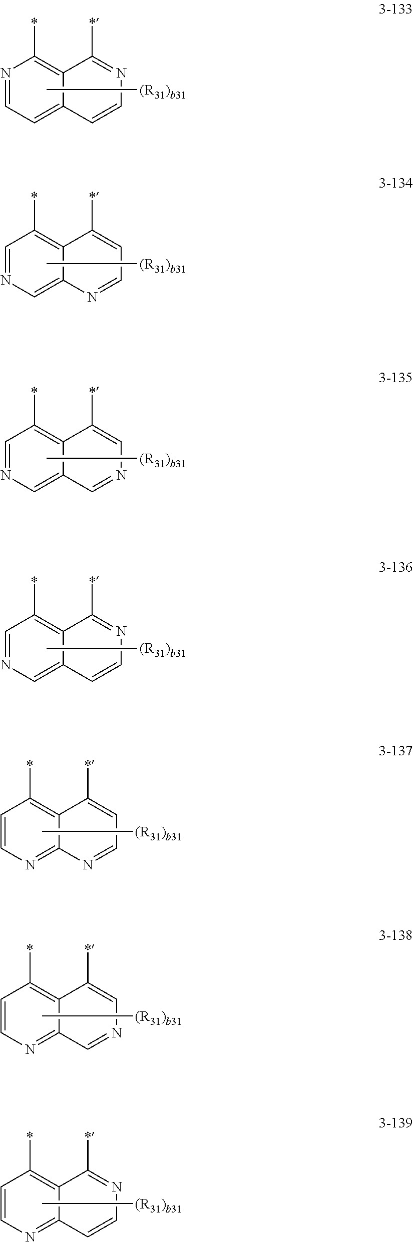

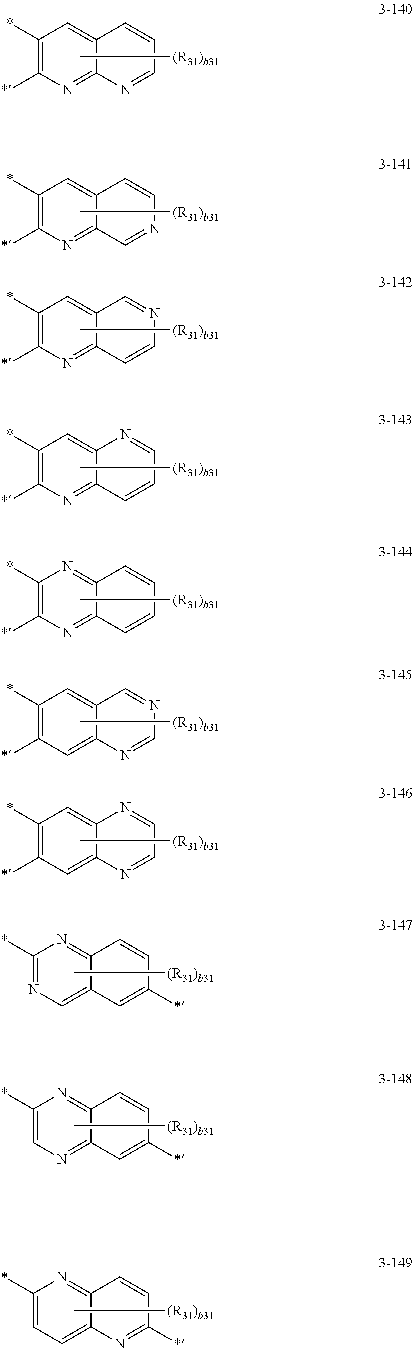

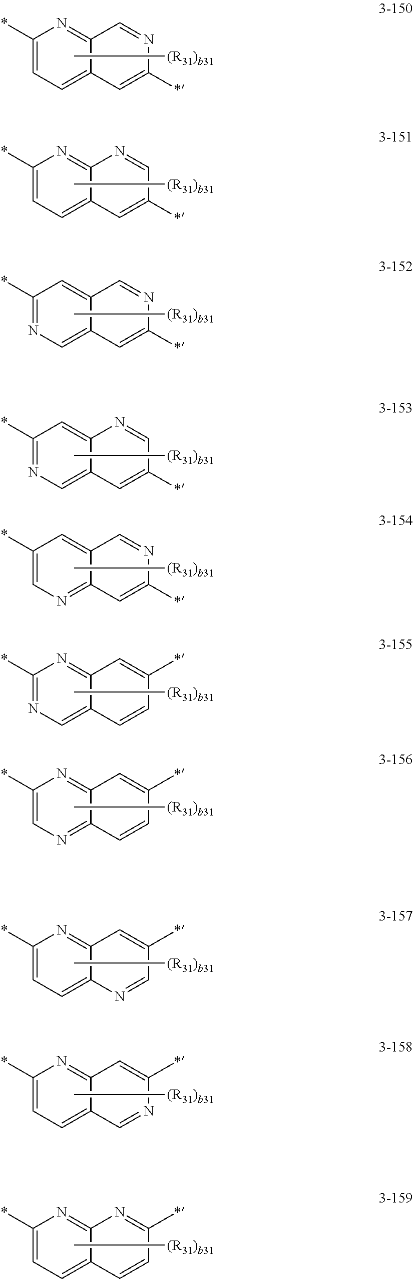

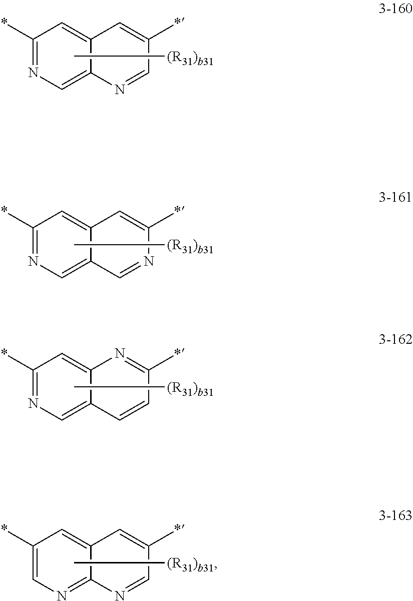

wherein, in Formulae 3-1 to 3-13 and 3-16 to 3-163,

R₃₁ may be selected from a methyl group, an ethyl group, an n-propyl group, an iso-propyl group, an n-butyl group, an iso-butyl group, a sec-butyl group, a tert-butyl group, a cyclopentyl group, a cyclohexyl group, and a cycloheptyl group,

b31 may be selected from 1, 2, 3, and 4,

b32 may be selected from 1, 2, 3, 4, 5, and 6,

b33 may be selected from 1, 2, and 3,

b34 may be selected from 1 and 2,

b35 may be selected from 1, 2, 3, 4, and 5, and

* and *′ each independently indicate a binding site to a neighboring atom.

L₉₂ and L₉₃ in Formulae 9-2 and 9-3 may each independently be selected from a substituted or unsubstituted C₆-C₆₀ arylene group and a substituted or unsubstituted C₁-C₆₀ heteroarylene group.

For example, L₉₂ and L₉₃ in Formulae 9-2 and 9-3 may each independently be selected from the group consisting of:

a phenylene group, a naphthylene group, a phenanthrenylene group, an anthracenylene group, a triphenylenylene group, a pyrenylene group, a chrysenylene group, a pyridinylene group, a pyrazinylene group, a pyrimidinylene group, a quinolinylene group, an isoquinolinylene group, a benzoquinolinylene group, a phthalazinylene group, a naphthyridinylene group, a quinoxalinylene group, a quinazolinylene group, a phenanthridinylene group, an acridinylene group, a phenanthrolinylene group, and a triazinylene group;

a phenylene group, a naphthylene group, a phenanthrenylene group, an anthracenylene group, a triphenylenylene group, a pyrenylene group, a chrysenylene group, a pyridinylene group, a pyrazinylene group, a pyrimidinylene group, a quinolinylene group, an isoquinolinylene group, a benzoquinolinylene group, a phthalazinylene group, a naphthyridinylene group, a quinoxalinylene group, a quinazolinylene group, a phenanthridinylene group, an acridinylene group, a phenanthrolinylene group, and a triazinylene group, each substituted with at least one selected from deuterium, —F, —Cl, —Br, —I, a cyano group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂); and

a phenylene group, a naphthylene group, a phenanthrenylene group, an anthracenylene group, a triphenylenylene group, a pyrenylene group, a chrysenylene group, a pyridinylene group, a pyrazinylene group, a pyrimidinylene group, a quinolinylene group, an isoquinolinylene group, a benzoquinolinylene group, a phthalazinylene group, a naphthyridinylene group, a quinoxalinylene group, a quinazolinylene group, a phenanthridinylene group, an acridinylene group, a phenanthrolinylene group, and a triazinylene group, each substituted with at least one selected from a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, and a dibenzocarbazolyl group, each substituted with at least one selected from deuterium, —F, —Cl, —Br, —I, a cyano group, a C₁-C₂₀ alkyl group, and a C₁-C₂₀ alkoxy group,

wherein Q₃₁ to Q₃₃ may each independently be selected from hydrogen, a methyl group, an ethyl group, an n-propyl group, an iso-propyl group, a tert-butyl group, a phenyl group, a biphenyl group, and a terphenyl group, but embodiments are not limited thereto.

In various embodiments, L₉₂ and L₉₃ in Formulae 9-2 and 9-3 may each independently be selected from the group consisting of:

a phenylene group, a naphthylene group, a pyridinylene group, a pyrazinylene group, a pyrimidinylene group, a quinolinylene group, an isoquinolinylene group, a naphthyridinylene group, a quinoxalinylene group, and a triazinylene group;

a phenylene group, a naphthylene group, a pyridinylene group, a pyrazinylene group, a pyrimidinylene group, a quinolinylene group, an isoquinolinylene group, a naphthyridinylene group, a quinoxalinylene group, and a triazinylene group, each substituted with at least one selected from deuterium, —F, —Cl, —Br, —I, a cyano group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a dibenzofuranyl group, a dibenzothiophenyl group, a carbazolyl group, a triazinyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂); and

a phenylene group, a naphthylene group, a pyridinylene group, a pyrazinylene group, a pyrimidinylene group, a quinolinylene group, an isoquinolinylene group, a naphthyridinylene group, a quinoxalinylene group, and a triazinylene group, each substituted with at least one selected from a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a dibenzofuranyl group, a dibenzothiophenyl group, a carbazolyl group, and a triazinyl group, each substituted with at least one selected from deuterium, —F, —Cl, —Br, —I, a cyano group, a C₁-C₂₀ alkyl group, and a C₁-C₂₀ alkoxy group,

wherein Q₃₁ to Q₃₃ may each independently be selected from hydrogen, a methyl group, an ethyl group, an n-propyl group, an iso-propyl group, a tert-butyl group, a phenyl group, a biphenyl group, and a terphenyl group, but embodiments are not limited thereto.

In various embodiments, L₉₂ and L₉₃ in Formulae 9-2 and 9-3 may each independently be selected from groups represented by Formulae 3-1 to 3-13 and 3-16 to 3-163,

wherein, in Formulae 3-1 to 3-13 and 3-16 to 3-163,

R₃₁ may be selected from the group consisting of:

hydrogen, deuterium, —F, —Cl, —Br, —I, a cyano group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a dibenzofuranyl group, a dibenzothiophenyl group, a carbazolyl group, a triazinyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂); and

a phenyl group, a naphthyl group, a pyridinyl group, a pyrazinyl group, a pyrimidinyl group, a quinolinyl group, an isoquinolinyl group, a naphthyridinyl group, a quinoxalinyl group, and a triazinyl group, each substituted with at least one selected from a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a dibenzofuranyl group, a dibenzothiophenyl group, a carbazolyl group, and a triazinyl group, each substituted with at least one selected from deuterium, —F, —Cl, —Br, —I, a cyano group, a C₁-C₂₀ alkyl group and a C₁-C₂₀ alkoxy group,

wherein Q₃₁ to Q₃₃ may each independently be selected from hydrogen, a methyl group, an ethyl group, an n-propyl group, an iso-propyl group, a tert-butyl group, a phenyl group, a biphenyl group, and a terphenyl group,

b31 may be selected from 1, 2, 3, and 4,

b32 may be selected from 1, 2, 3, 4, 5, and 6,

b33 may be selected from 1, 2, and 3,

b34 may be selected from 1 and 2,

b35 may be selected from 1, 2, 3, 4, and 5, and

* and *′ each independently indicate a binding site to a neighboring atom, but embodiments are not limited thereto.

a91 in Formula 9-1 indicates the number of L₉₁(s), and a91 may be selected from 1 and 2. When a91 is two, two L₉₁(s) may be identical to or different from each other.

a92 and a93 in Formulae 9-2 and 9-3 may each independently be selected from 0, 1, and 2. When a92 is zero, (L₉₂)ₐ₉₂ may indicate a single bond, when a92 is two, two L₉₂(s) may be identical to or different from each other. Description of a93 may be the same as the description of a92.

R₉₁ and R₉₃ in Formulae 9-1 and 9-3 may each independently be selected from a substituted or unsubstituted C₆-C₆₀ aryl group and a substituted or unsubstituted C₁-C₆₀ heteroaryl group.

For example, R₉₁ and R₉₃ in Formulae 9-1 and 9-3 may each independently be selected from the group consisting of:

a C₆-C₃₀ aryl group and a C₁-C₃₀ heteroaryl group;

a C₆-C₃₀ aryl group and a C₁-C₃₀ heteroaryl group, each substituted with at least one selected from deuterium, —F, —Cl, —Br, —I, a C₁-C₂₀ alkyl group, a C₁-C₂₀ alkoxy group, a C₃-C₁₀ cycloalkyl group, a C₆-C₃₀ aryl group, a C₁-C₃₀ heteroaryl group, —N(Q₃₁)(Q₃₂), and —Si(Q₃₁)(Q₃₂)(Q₃₃); and

a C₆-C₃₀ aryl group and a C₁-C₃₀ heteroaryl group, each substituted with at least one selected from a C₆-C₃₀ aryl group and a C₁-C₃₀ heteroaryl group, each substituted with at least one selected from deuterium, —F, —Cl, —Br, —I, a C₁-C₂₀ alkyl group, a C₁-C₂₀ alkoxy group, a C₃-C₁₀ cycloalkyl group, a C₆-C₃₀ aryl group, a C₁-C₃₀ heteroaryl group, —N(Q₂₁)(Q₂₂), and —Si(Q₂₁)(Q₂₂)(Q₂₃),

wherein Q₂₁ to Q₂₃ and Q₃₁ to Q₃₃ may each independently be selected from a C₁-C₂₀ alkyl group and a C₆-C₃₀ aryl group, but embodiments are not limited thereto.

In various embodiments, R₉₁ and R₉₃ in Formulae 9-1 and 9-3 may each independently be selected from the group consisting of:

a phenyl group, a biphenyl group, a terphenyl group, a naphthyl group, an anthracenyl group, a triphenylenyl group, a phenanthrenyl group, a pyrenyl group, a tetraphenyl group, a chrysenyl group, a pyrrolyl group, a furanyl group, a thiophenyl group, a pyridinyl group, a pyrazinyl group, a pyrimidinyl group, a triazinyl group, a quinolinyl group, an isoquinolinyl group, a benzoquinolinyl group, a phthalazinyl group, a naphthyridinyl group, a quinoxalinyl group, a quinazolinyl group, a phenanthridinyl group, an acridinyl group, a phenanthrolinyl group, a phenazinyl group, a benzophenanthrolinyl group, a thiazolyl group, an oxazolyl group, an imidazolyl group, a triazolyl group, an indolyl group, a benzimidazolyl group, a benzofuranyl group, a benzothiophenyl group, and a benzoxazolyl group;

a phenyl group, a biphenyl group, a terphenyl group, a naphthyl group, an anthracenyl group, a triphenylenyl group, a phenanthrenyl group, a pyrenyl group, a tetraphenyl group, a chrysenyl group, a pyrrolyl group, a furanyl group, a thiophenyl group, a pyridinyl group, a pyrazinyl group, a pyrimidinyl group, a triazinyl group, a quinolinyl group, an isoquinolinyl group, a benzoquinolinyl group, a phthalazinyl group, a naphthyridinyl group, a quinoxalinyl group, a quinazolinyl group, a phenanthridinyl group, an acridinyl group, a phenanthrolinyl group, a phenazinyl group, a benzophenanthrolinyl group, a thiazolyl group, an oxazolyl group, an imidazolyl group, a triazolyl group, an indolyl group, a benzimidazolyl group, a benzofuranyl group, a benzothiophenyl group, and a benzoxazolyl group, each substituted with at least one selected from deuterium, —F, —Cl, —Br, —I, a C₁-C₂₀ alkyl group, a phenyl group, a biphenyl group, a terphenyl group, a naphthyl group, a pyridinyl group, a pyrazinyl group, a pyrimidinyl group, a triazinyl group, —N(Q₃₁)(Q₃₂), and —Si(Q₃₁)(Q₃₂)(Q₃₃); and

a phenyl group, a biphenyl group, a terphenyl group, a naphthyl group, an anthracenyl group, a triphenylenyl group, a phenanthrenyl group, a pyrenyl group, a tetraphenyl group, a chrysenyl group, a pyrrolyl group, a furanyl group, a thiophenyl group, a pyridinyl group, a pyrazinyl group, a pyrimidinyl group, a triazinyl group, a quinolinyl group, an isoquinolinyl group, a benzoquinolinyl group, a phthalazinyl group, a naphthyridinyl group, a quinoxalinyl group, a quinazolinyl group, a phenanthridinyl group, an acridinyl group, a phenanthrolinyl group, a phenazinyl group, a benzophenanthrolinyl group, a thiazolyl group, an oxazolyl group, an imidazolyl group, a triazolyl group, an indolyl group, a benzimidazolyl group, a benzofuranyl group, a benzothiophenyl group, and a benzoxazolyl group, each substituted with at least one selected from a phenyl group, a biphenyl group, a terphenyl group, a naphthyl group, an anthracenyl group, a triphenylenyl group, a phenanthrenyl group, a pyrenyl group, a tetraphenyl group, a chrysenyl group, a pyrrolyl group, a furanyl group, a thiophenyl group, a pyridinyl group, a pyrazinyl group, a pyrimidinyl group, a triazinyl group, a quinolinyl group, an isoquinolinyl group, a benzoquinolinyl group, a phthalazinyl group, a naphthyridinyl group, a quinoxalinyl group, a quinazolinyl group, a phenanthridinyl group, an acridinyl group, a phenanthrolinyl group, a phenazinyl group, a benzophenanthrolinyl group, a thiazolyl group, an oxazolyl group, an imidazolyl group, a triazolyl group, an indolyl group, a benzimidazolyl group, a benzofuranyl group, a benzothiophenyl group, and a benzoxazolyl group, each substituted with at least one selected from deuterium, —F, —Cl, —Br, —I, a C₁-C₂₀ alkyl group, a phenyl group, a biphenyl group, a terphenyl group, a naphthyl group, a pyridinyl group, a pyrazinyl group, a pyrimidinyl group, a triazinyl group, —N(Q₂₁)(Q₂₂), and —Si(Q₂₁)(Q₂₂)(Q₂₃),

wherein Q₂₁ to Q₂₃ and Q₃₁ to Q₃₃ may each independently be selected from a phenyl group, a biphenyl group, a terphenyl group, and a naphthyl group, but are not limited thereto.

In various embodiments, R₉₁ and R₉₃ in Formulae 9-1 and 9-3 may each independently be selected from groups represented by Formulae 5-1 to 5-55,

wherein, in Formulae 5-1 to 5-55,

R₅₁ to R₅₃ may each independently be selected from the group consisting of:

hydrogen, deuterium, —F, —Cl, —Br, —I, a C₁-C₂₀ alkyl group, a phenyl group, a biphenyl group, a terphenyl group, a naphthyl group, a pyridinyl group, a pyrazinyl group, a pyrimidinyl group, a triazinyl group, —N(Q₃₁)(Q₃₂), and —Si(Q₃₁)(Q₃₂)(Q₃₃); and

a phenyl group, a biphenyl group, a terphenyl group, a naphthyl group, an anthracenyl group, a triphenylenyl group, a phenanthrenyl group, a pyrenyl group, a tetraphenyl group, a chrysenyl group, a pyrrolyl group, a furanyl group, a thiophenyl group, a pyridinyl group, a pyrazinyl group, a pyrimidinyl group, a triazinyl group, a quinolinyl group, an isoquinolinyl group, a benzoquinolinyl group, a phthalazinyl group, a naphthyridinyl group, a quinoxalinyl group, a quinazolinyl group, a phenanthridinyl group, an acridinyl group, a phenanthrolinyl group, a phenazinyl group, a benzophenanthrolinyl group, a thiazolyl group, an oxazolyl group, an imidazolyl group, a triazolyl group, an indolyl group, a benzimidazolyl group, a benzofuranyl group, a benzothiophenyl group, and a benzoxazolyl group, each substituted with at least one selected from deuterium, —F, —Cl, —Br, —I, a C₁-C₂₀ alkyl group, a phenyl group, a biphenyl group, a terphenyl group, a naphthyl group, a pyridinyl group, a pyrazinyl group, a pyrimidinyl group, a triazinyl group, —N(Q₂₁)(Q₂₂), and —Si(Q₂₁)(Q₂₂)(Q₂₃),

wherein Q₂₁ to Q₂₃ and Q₃₁ to Q₃₃ may each independently be selected from a phenyl group, a biphenyl group, a terphenyl group, and a naphthyl group,

b51 may be selected from 1, 2, 3, 4, and 5,

b52 may be selected from 1, 2, 3, 4, 5, 6, and 7,

b53 may be selected from 1, 2, 3, 4, 5, and 6,

b54 may be selected from 1, 2, and 3,

b55 may be selected from 1, 2, 3, and 4,

b56 may be 1 or 2, and

* indicates a binding site to a neighboring atom, but embodiments are not limited thereto.

R₉₂ in Formula 9-2 may be selected from a C₆-C₆₀ aryl group and a C₁-C₆₀ heteroaryl group, each substituted with at least one selected from a C₁-C₆₀ alkyl group and a C₃-C₁₀ cycloalkyl group.

For example, R₉₂ in Formula 9-2 may be selected from the group consisting of:

a phenyl group, a biphenyl group, a terphenyl group, a naphthyl group, an anthracenyl group, a triphenylenyl group, a phenanthrenyl group, a pyrenyl group, a tetraphenyl group, a chrysenyl group, a pyrrolyl group, a furanyl group, a thiophenyl group, a pyridinyl group, a pyrazinyl group, a pyrimidinyl group, a triazinyl group, a quinolinyl group, an isoquinolinyl group, a benzoquinolinyl group, a phthalazinyl group, a naphthyridinyl group, a quinoxalinyl group, a quinazolinyl group, a phenanthridinyl group, an acridinyl group, a phenanthrolinyl group, a phenazinyl group, a benzophenanthrolinyl group, a thiazolyl group, an oxazolyl group, an imidazolyl group, a triazolyl group, an indolyl group, a benzimidazolyl group, a benzofuranyl group, a benzothiophenyl group, and a benzoxazolyl group, each substituted with at least one selected from a C₁-C₂₀ alkyl group, a cyclopentyl group, a cyclohexyl group, and a cycloheptyl group, but is not limited thereto.

In various embodiments, R₉₂ in Formula 9-2 may be selected from a phenyl group, a biphenyl group, a terphenyl group, a naphthyl group, an anthracenyl group, a triphenylenyl group, a phenanthrenyl group, a pyrenyl group, a tetraphenyl group, a chrysenyl group, a pyrrolyl group, a furanyl group, a thiophenyl group, a pyridinyl group, a pyrazinyl group, a pyrimidinyl group, a triazinyl group, a quinolinyl group, an isoquinolinyl group, a benzoquinolinyl group, a phthalazinyl group, a naphthyridinyl group, a quinoxalinyl group, a quinazolinyl group, a phenanthridinyl group, an acridinyl group, a phenanthrolinyl group, a phenazinyl group, a benzophenanthrolinyl group, a thiazolyl group, an oxazolyl group, an imidazolyl group, a triazolyl group, an indolyl group, a benzimidazolyl group, a benzofuranyl group, a benzothiophenyl group, and a benzoxazolyl group, each substituted with at least one selected from a methyl group, an ethyl group, an n-propyl group, an iso-propyl group, an n-butyl group, an iso-butyl group, a sec-butyl group, a tert-butyl group, a cyclopentyl group, a cyclohexyl group, and a cycloheptyl group, but is not limited thereto.

In various embodiments, R₉₂ in Formula 9-2 may be selected from groups represented by Formulae 5-1 to 5-55,

wherein, in Formulae 5-1 to 5-55,

R₅₁ to R₅₃ may each independently be selected from a methyl group, an ethyl group, an n-propyl group, an iso-propyl group, an n-butyl group, an iso-butyl group, a sec-butyl group, a tert-butyl group, a cyclopentyl group, a cyclohexyl group, and a cycloheptyl group,

b51 may be selected from 1, 2, 3, 4, and 5,

b52 may be selected from 1, 2, 3, 4, 5, 6, and 7,

b53 may be selected from 1, 2, 3, 4, 5, and 6,

b54 may be selected from 1, 2, and 3,

b55 may be selected from 1, 2, 3, and 4,

b56 may be 1 or 2, and

* indicates a binding site to a neighboring atom, but embodiments are not limited thereto.

For example, the second compound represented by Formula 2 may be represented by Formula 2-1, but is not limited thereto:

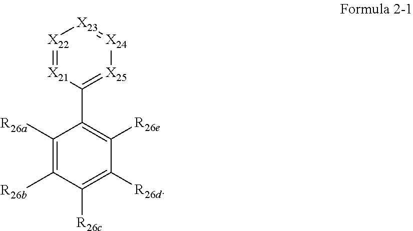

In Formula 2-1,

X₂₁ may be selected from N and C(R₂₁), X₂₂ may be selected from N and C(R₂₂), X₂₃ may be selected from N and C(R₂₃), X₂₄ may be selected from N and C(R₂₄), and X₂₅ may be selected from N and C(R₂₅), wherein at least one selected from X₂₁ to X₂₅ may be N,

R₂₁ to R₂₅ and R₂₆ₐ to R₂₆ₑ may each independently be selected from a group represented by any of Formulae 9-1 to 9-3, hydrogen, deuterium, —F, —Cl, —Br, —I, a hydroxyl group, a cyano group, a nitro group, an amidino group, a hydrazino group, a hydrazono group, a substituted or unsubstituted C₁-C₆₀ alkyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₁)(Q₂), —B(Q₁)(Q₂), —C(═O)(Q₁), —S(═O)₂(Q₁), and —P(═O)(Q₁)(Q₂), and at least one selected from R₂₁ to R₂₅ and R₂₆ₐ to R₂₆ₑ may be selected from the group represented by Formula 9-1 and the group represented by Formula 9-2,

wherein Q₁ to Q₃ may each independently be selected from hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, and a terphenyl group.

In various embodiments, the second compound represented by Formula 2 may be represented by one selected from Formulae 2-11 to 2-22, but is not limited thereto:

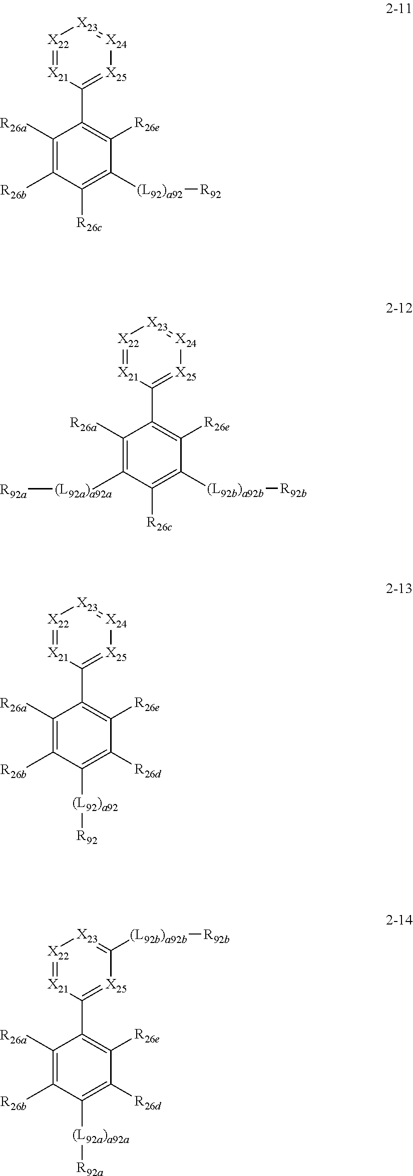

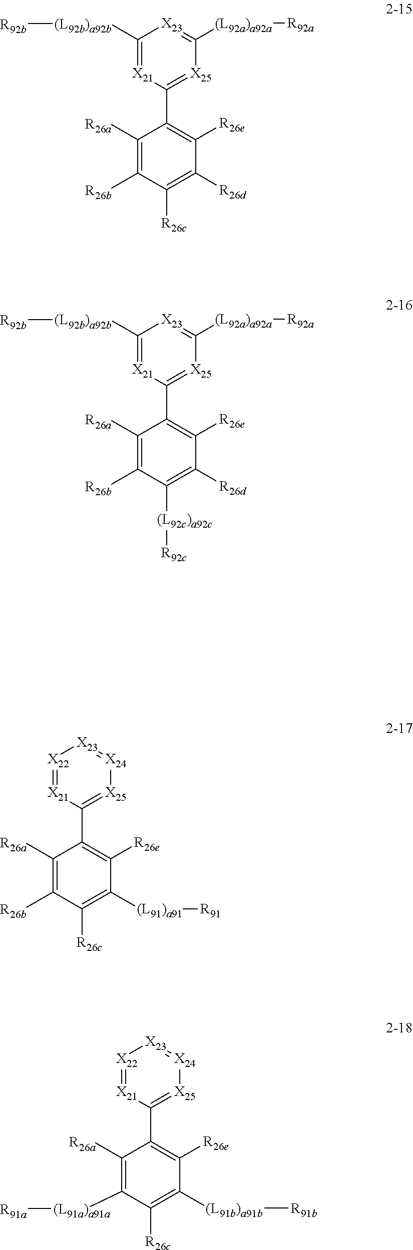

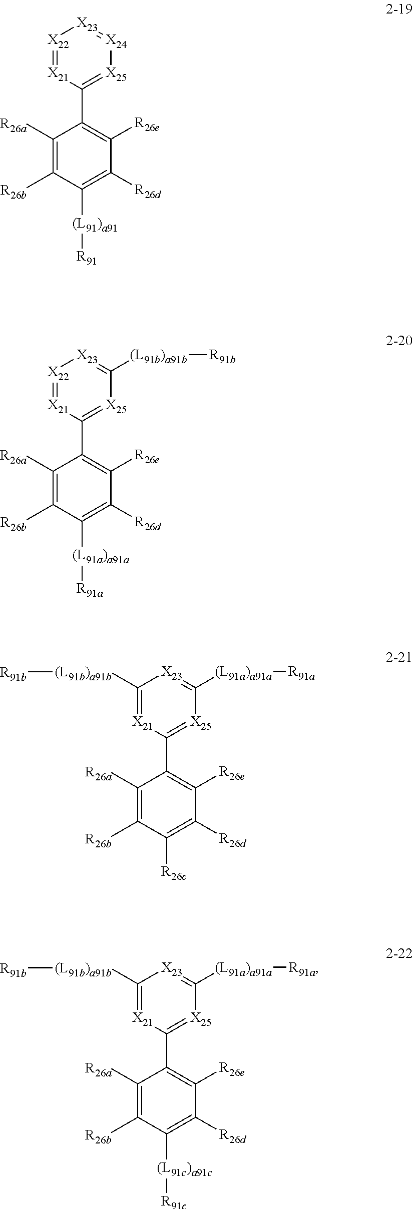

wherein, in Formulae 2-11 to 2-22,

X₂₁ may be selected from N and C(R₂₁), X₂₂ may be selected from N and C(R₂₂), X₂₃ may be selected from N and C(R₂₃), X₂₄ may be selected from N and C(R₂₄), and X₂₅ may be selected from N and C(R₂₅), wherein at least one selected from X₂₁ to X₂₅ may be N,

R₂₁ to R₂₅ and R₂₆ₐ to R₂₆ₑ may each independently be selected from hydrogen, deuterium, —F, —Cl, —Br, —I, a hydroxyl group, a cyano group, a nitro group, an amidino group, a hydrazino group, a hydrazono group, a substituted or unsubstituted C₁-C₆₀ alkyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₁)(Q₂), —B(Q₁)(Q₂), —C(═O)(Q₁), —S(═O)₂(Q₁), and —P(═O)(Q₁)(Q₂),

L₉₁, L₉₁ₐ, L_{91b}, and L_{91c} may each independently be selected from a C₆-C₆₀ arylene group and a C₁-C₆₀ heteroarylene group, each substituted with at least one selected from a C₁-C₆₀ alkyl group and a C₃-C₁₀ cycloalkyl group,

L₉₂, L₉₂ₐ, L_{92b}, and L₉₂c may each independently be selected from a substituted or unsubstituted C₆-C₆₀ arylene group and a substituted or unsubstituted C₁-C₆₀ heteroarylene group,

a91, a91a, a91b, and a91c may each independently be selected from 1 and 2,

a92, a92a, a92b, and a92c may each independently be selected from 0, 1, and 2,

R₉₁, R₉₁ₐ, R_{91b}, and R_{91c} may each independently be selected from a substituted or unsubstituted C₆-C₆₀ aryl group and a substituted or unsubstituted C₁-C₆₀ heteroaryl group, and

R₉₂, R₉₂ₐ, R_{92b}, and R_{92c} may each independently be selected from a C₆-C₆₀ aryl group and a C₁-C₆₀ heteroaryl group, each substituted with at least one selected from a C₁-C₆₀ alkyl group and a C₃-C₁₀ cycloalkyl group,

wherein Q₁ to Q₃ may each independently be selected from hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, and a terphenyl group.

The first compound represented by Formula 1 may be represented by any of Compounds 1-1 to 1-380, but is not limited thereto:

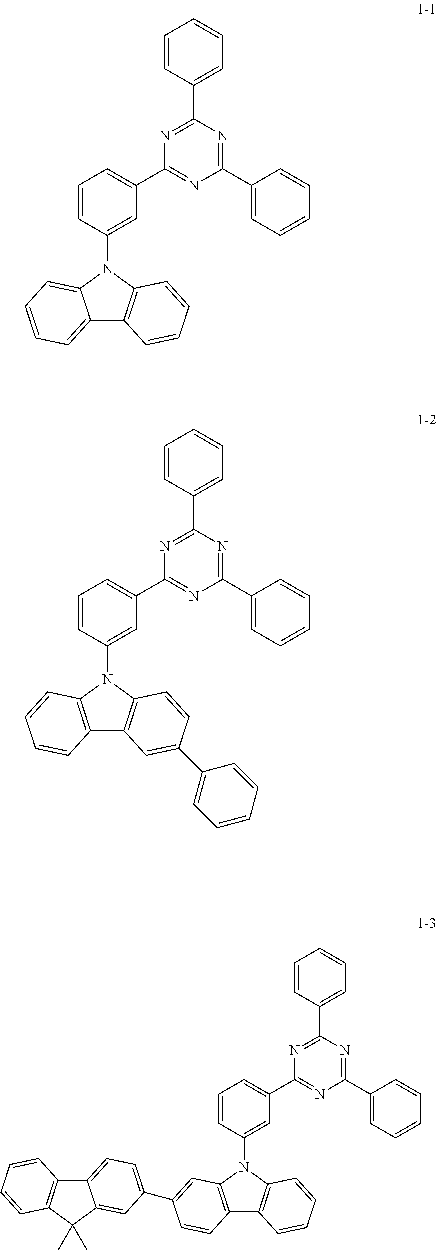 [SMILES: c1ccc(-c2nc(-c3ccccc3)nc(-c3cccc(-n4c5ccccc5c5ccccc54)c3)n2)cc1 ; c1ccc(-c2ccc3c(c2)c2ccccc2n3-c2cccc(-c3nc(-c4ccccc4)nc(-c4ccccc4)n3)c2)cc1 ; CC1(C)c2ccccc2-c2ccc(-c3ccc4c5ccccc5n(-c5cccc(-c6nc(-c7ccccc7)nc(-c7ccccc7)n6)c5)c4c3)cc21]

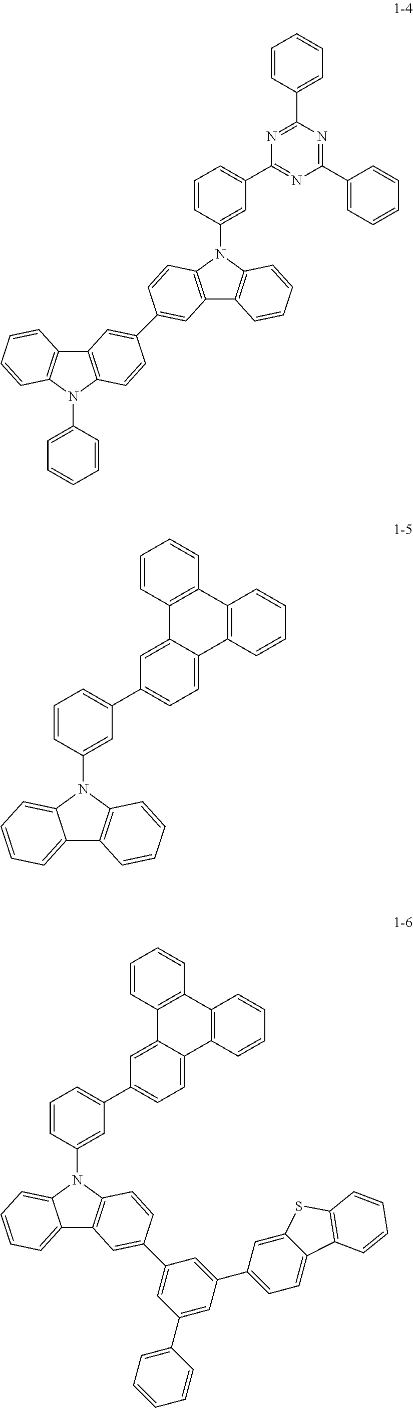 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1cc(-c2ccc3c4ccccc4c4ccccc4c3c2)cc(-n2c3ccccc3c3ccccc32)c1 ; c1ccc(-c2cc(-c3ccc4c(c3)sc3ccccc34)cc(-c3ccc4c(c3)c3ccccc3n4-c3cccc(-c4ccc5c6ccccc6c6ccccc6c5c4)c3)c2)cc1]

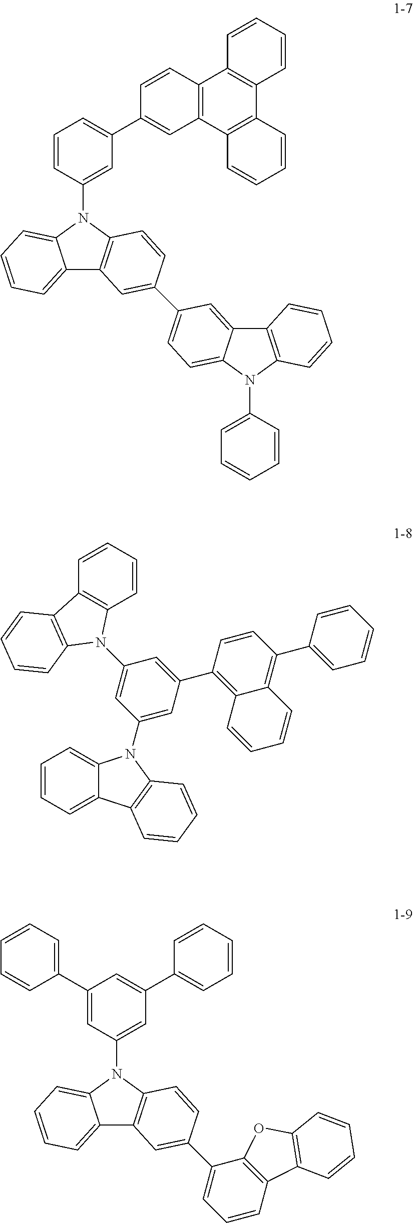 [SMILES: c1ccc(-n2c3ccccc3c3cc(-c4ccc5c(c4)c4ccccc4n5-c4cccc(-c5ccc6c7ccccc7c7ccccc7c6c5)c4)ccc32)cc1 ; c1ccc(-c2ccc(-c3cc(-n4c5ccccc5c5ccccc54)cc(-n4c5ccccc5c5ccccc54)c3)c3ccccc23)cc1 ; c1ccc(-c2cc(-c3ccccc3)cc(-n3c4ccccc4c4cc(-c5cccc6c5oc5ccccc56)ccc43)c2)cc1]

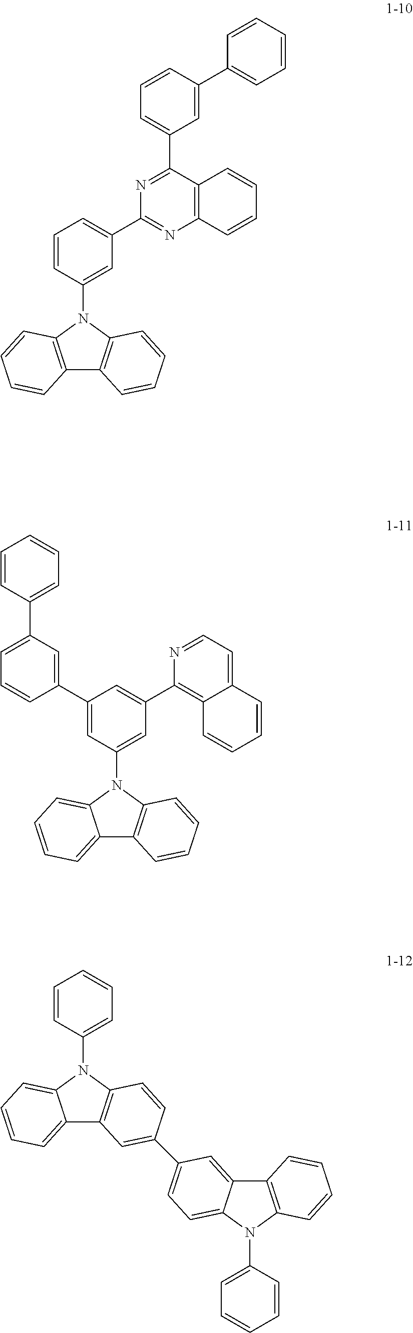 [SMILES: c1ccc(-c2cccc(-c3nc(-c4cccc(-n5c6ccccc6c6ccccc65)c4)nc4ccccc34)c2)cc1 ; c1ccc(-c2cccc(-c3cc(-c4nccc5ccccc45)cc(-n4c5ccccc5c5ccccc54)c3)c2)cc1 ; c1ccc(-n2c3ccccc3c3cc(-c4ccc5c(c4)c4ccccc4n5-c4ccccc4)ccc32)cc1]

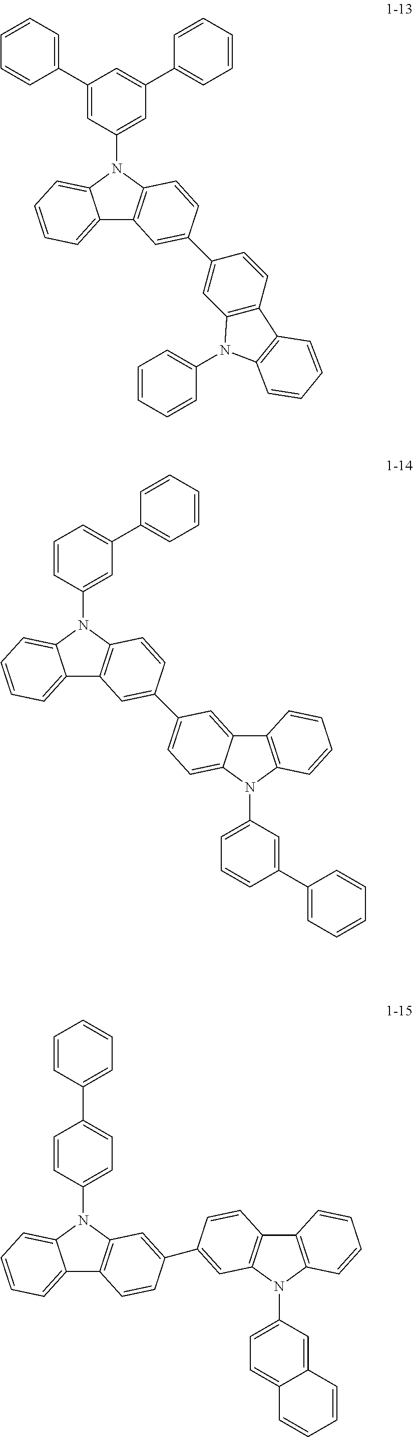 [SMILES: c1ccc(-c2cc(-c3ccccc3)cc(-n3c4ccccc4c4cc(-c5ccc6c7ccccc7n(-c7ccccc7)c6c5)ccc43)c2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2ccc(-n3c4ccccc4c4ccc(-c5ccc6c7ccccc7n(-c7ccc8ccccc8c7)c6c5)cc43)cc2)cc1]

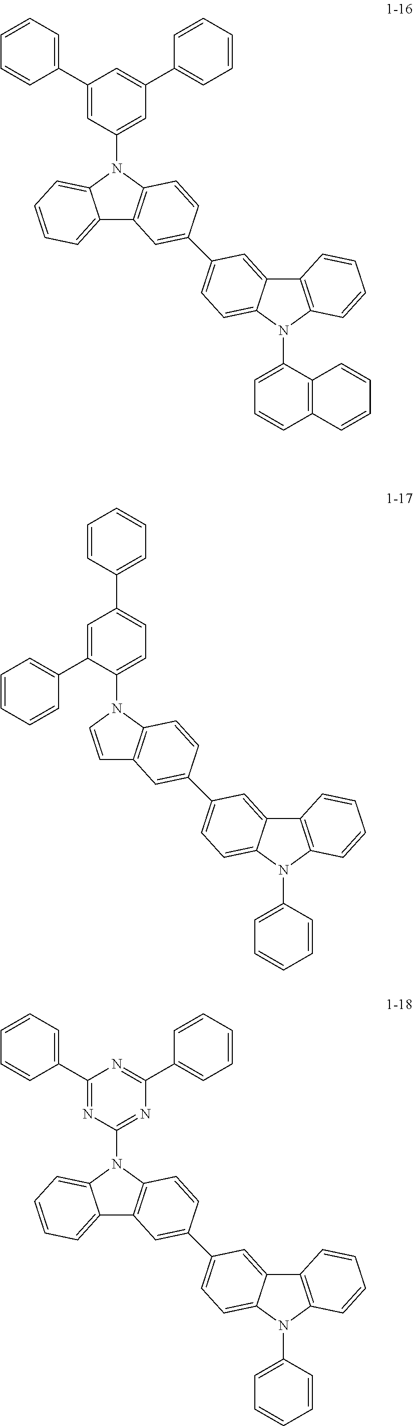 [SMILES: c1ccc(-c2cc(-c3ccccc3)cc(-n3c4ccccc4c4cc(-c5ccc6c(c5)c5ccccc5n6-c5cccc6ccccc56)ccc43)c2)cc1 ; c1ccc(-c2ccc(-n3ccc4cc(-c5ccc6c(c5)c5ccccc5n6-c5ccccc5)ccc43)c(-c3ccccc3)c2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

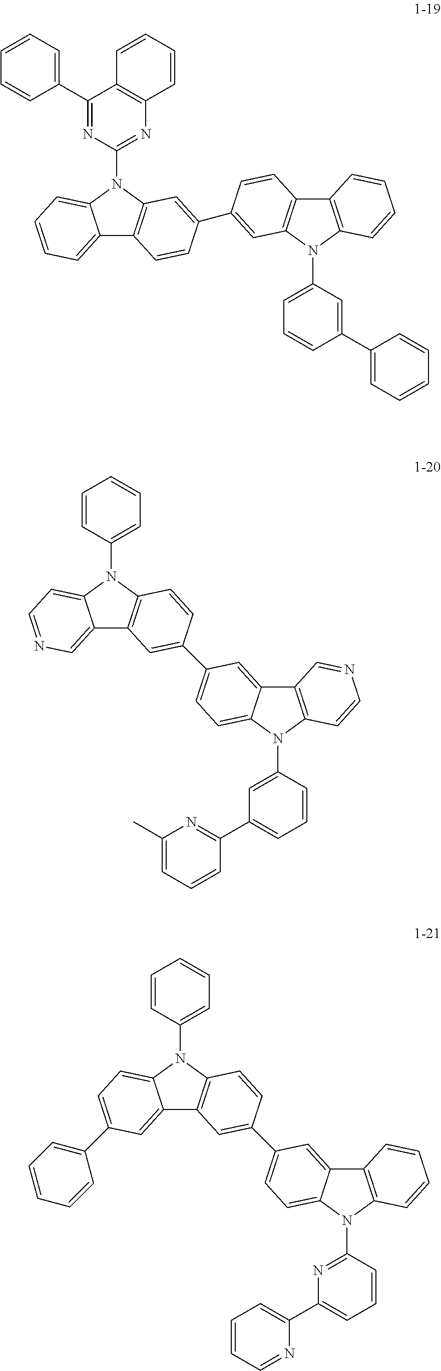 [SMILES: c1ccc(-c2cccc(-n3c4ccccc4c4ccc(-c5ccc6c7ccccc7n(-c7nc(-c8ccccc8)c8ccccc8n7)c6c5)cc43)c2)cc1 ; Cc1cccc(-c2cccc(-n3c4ccncc4c4cc(-c5ccc6c(c5)c5cnccc5n6-c5ccccc5)ccc43)c2)n1 ; c1ccc(-c2ccc3c(c2)c2cc(-c4ccc5c(c4)c4ccccc4n5-c4cccc(-c5ccccn5)n4)ccc2n3-c2ccccc2)cc1]

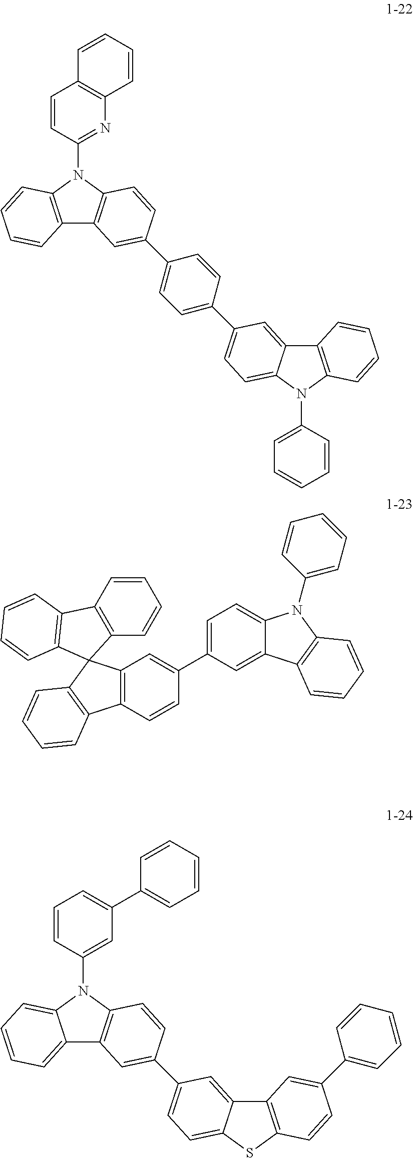

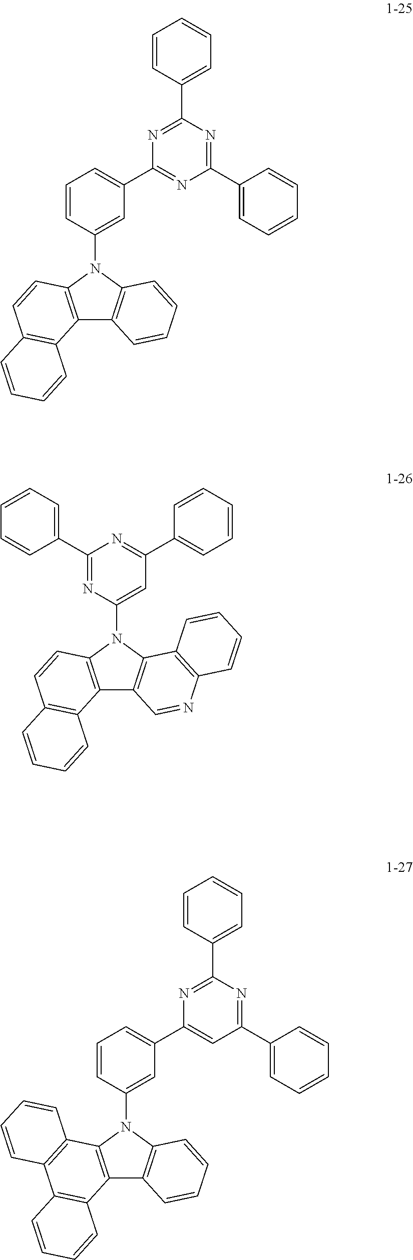 [SMILES: c1ccc(-c2nc(-c3ccccc3)nc(-c3cccc(-n4c5ccccc5c5c6ccccc6ccc54)c3)n2)cc1 ; c1ccc(-c2cc(-n3c4ccc5ccccc5c4c4cnc5ccccc5c43)nc(-c3ccccc3)n2)cc1 ; c1ccc(-c2cc(-c3cccc(-n4c5ccccc5c5c6ccccc6c6ccccc6c54)c3)nc(-c3ccccc3)n2)cc1]

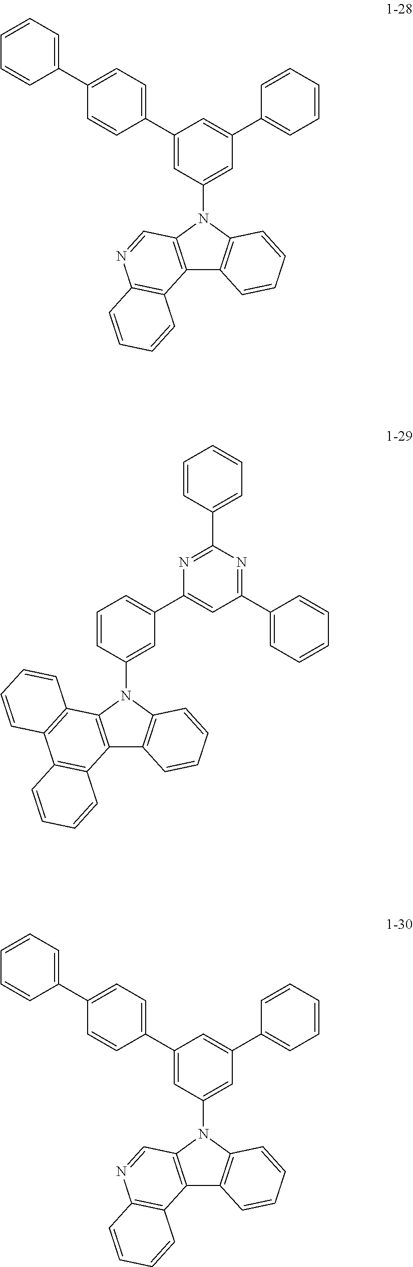 [SMILES: c1ccc(-c2ccc(-c3cc(-c4ccccc4)cc(-n4c5ccccc5c5c6ccccc6ncc54)c3)cc2)cc1 ; c1ccc(-c2cc(-c3cccc(-n4c5ccccc5c5c6ccccc6c6ccccc6c54)c3)nc(-c3ccccc3)n2)cc1 ; c1ccc(-c2ccc(-c3cc(-c4ccccc4)cc(-n4c5ccccc5c5c6ccccc6ncc54)c3)cc2)cc1]

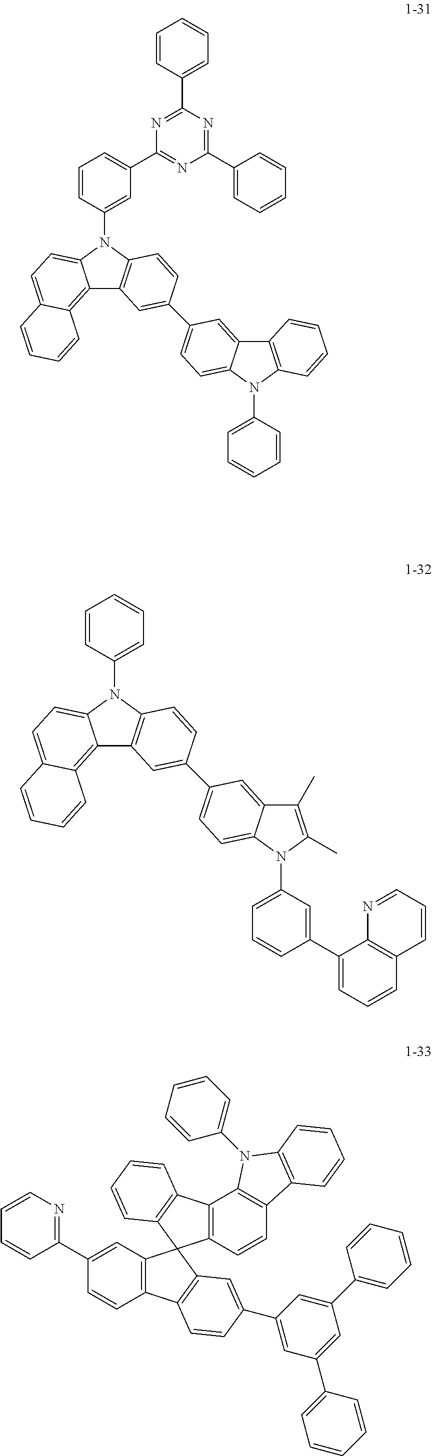 [SMILES: c1ccc(-c2nc(-c3ccccc3)nc(-c3cccc(-n4c5ccc(-c6ccc7c(c6)c6ccccc6n7-c6ccccc6)cc5c5c6ccccc6ccc54)c3)n2)cc1 ; Cc1c(C)n(-c2cccc(-c3cccc4cccnc34)c2)c2ccc(-c3ccc4c(c3)c3c5ccccc5ccc3n4-c3ccccc3)cc12 ; c1ccc(-c2cc(-c3ccccc3)cc(-c3ccc4c(c3)C3(c5cc(-c6ccccn6)ccc5-4)c4ccccc4-c4c3ccc3c5ccccc5n(-c5ccccc5)c43)c2)cc1]

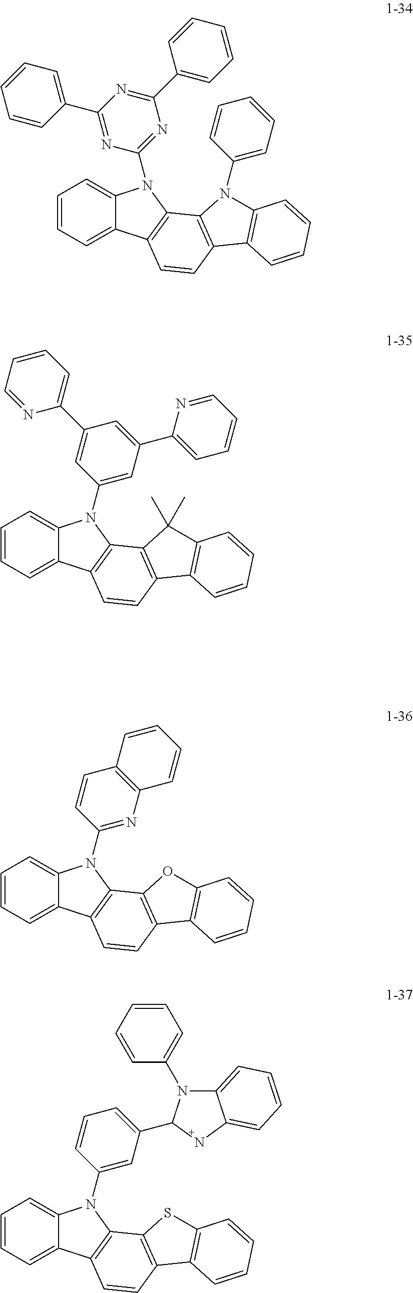 [SMILES: c1ccc(-c2nc(-c3ccccc3)nc(-n3c4ccccc4c4ccc5c6ccccc6n(-c6ccccc6)c5c43)n2)cc1 ; CC1(C)c2ccccc2-c2ccc3c4ccccc4n(-c4cc(-c5ccccn5)cc(-c5ccccn5)c4)c3c21 ; c1ccc2nc(-n3c4ccccc4c4ccc5c6ccccc6oc5c43)ccc2c1 ; c1ccc(N2c3ccccc3NC2c2cccc(-n3c4ccccc4c4ccc5c6ccccc6sc5c43)c2)cc1]

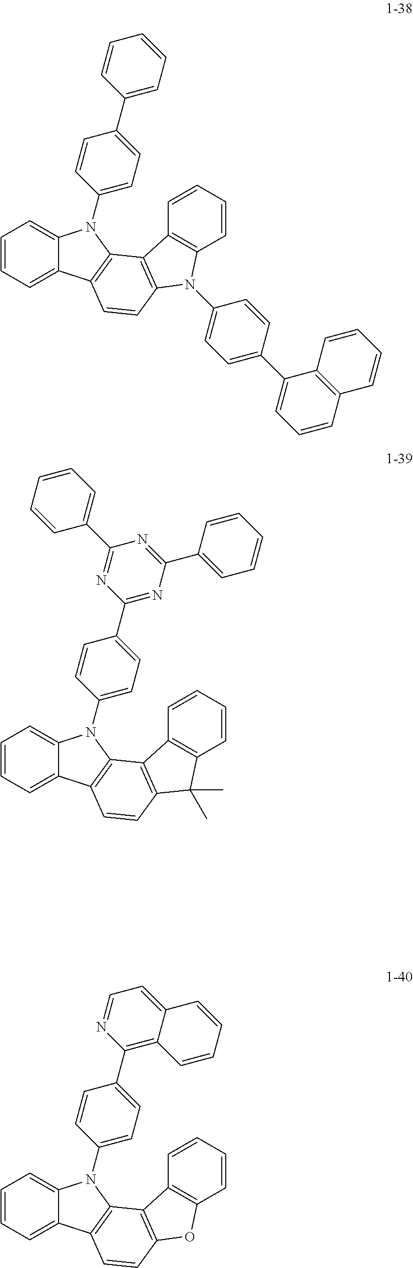 [SMILES: c1ccc(-c2ccc(-n3c4ccccc4c4ccc5c(c6ccccc6n5-c5ccc(-c6cccc7ccccc67)cc5)c43)cc2)cc1 ; CC1(C)c2ccccc2-c2c1ccc1c3ccccc3n(-c3ccc(-c4nc(-c5ccccc5)nc(-c5ccccc5)n4)cc3)c21 ; c1ccc2c(-c3ccc(-n4c5ccccc5c5ccc6oc7ccccc7c6c54)cc3)nccc2c1]

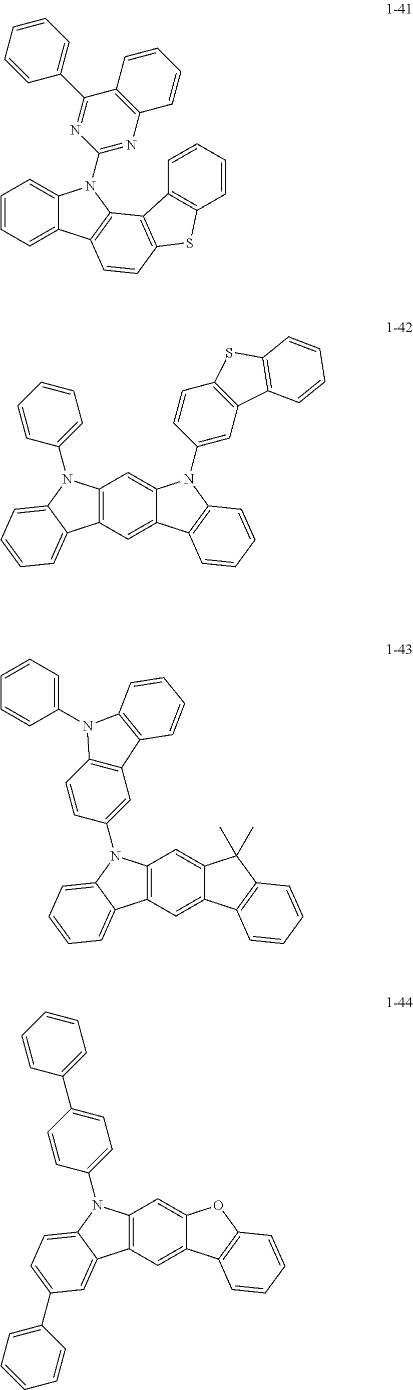 [SMILES: c1ccc(-c2nc(-n3c4ccccc4c4ccc5sc6ccccc6c5c43)nc3ccccc23)cc1 ; c1ccc(-n2c3ccccc3c3cc4c5ccccc5n(-c5ccc6sc7ccccc7c6c5)c4cc32)cc1 ; CC1(C)c2ccccc2-c2cc3c4ccccc4n(-c4ccc5c(c4)c4ccccc4n5-c4ccccc4)c3cc21 ; c1ccc(-c2ccc(-n3c4ccc(-c5ccccc5)cc4c4cc5c(cc43)oc3ccccc35)cc2)cc1]

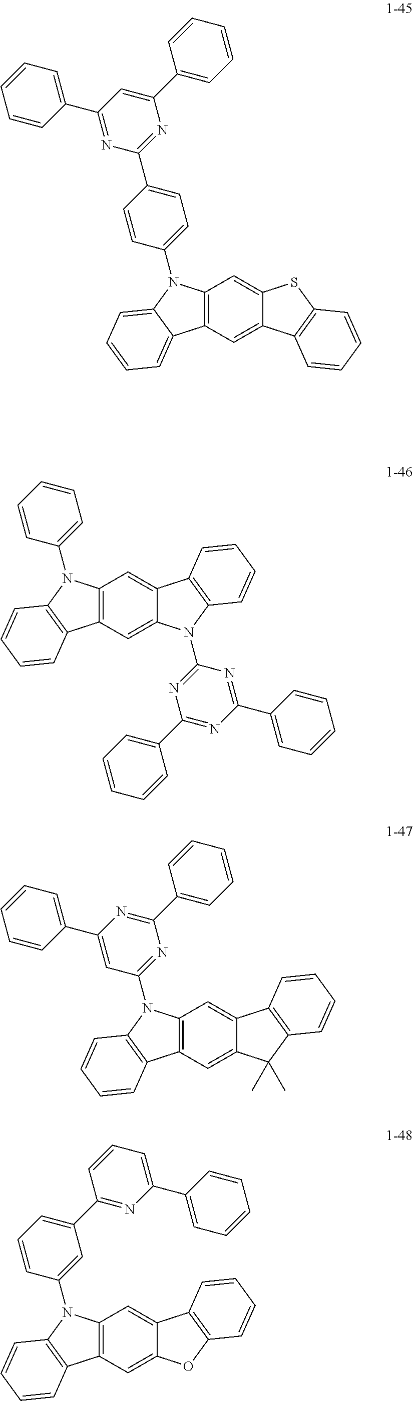 [SMILES: c1ccc(-c2cc(-c3ccccc3)nc(-c3ccc(-n4c5ccccc5c5cc6c(cc54)sc4ccccc46)cc3)n2)cc1 ; c1ccc(-c2nc(-c3ccccc3)nc(-n3c4ccccc4c4cc5c(cc43)c3ccccc3n5-c3ccccc3)n2)cc1 ; CC1(C)c2ccccc2-c2cc3c(cc21)c1ccccc1n3-c1cc(-c2ccccc2)nc(-c2ccccc2)n1 ; c1ccc(-c2cccc(-c3cccc(-n4c5ccccc5c5cc6oc7ccccc7c6cc54)c3)n2)cc1]

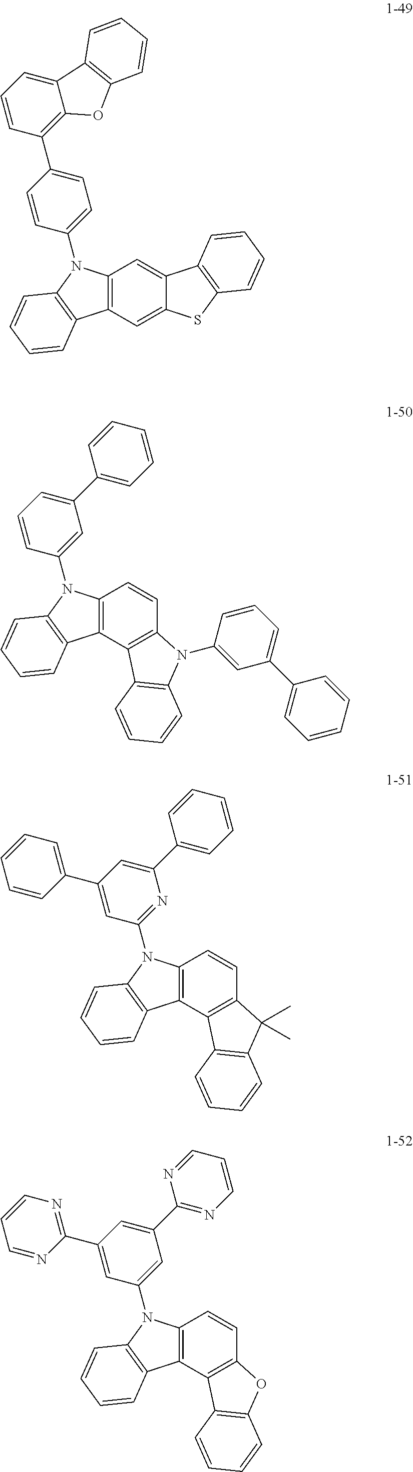

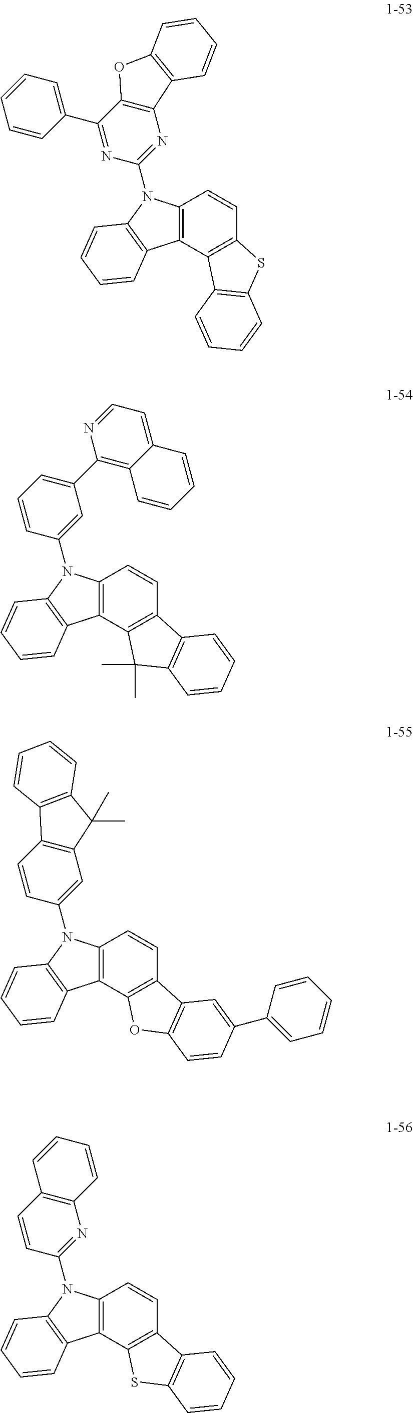 [SMILES: c1ccc(-c2nc(-n3c4ccccc4c4c5c(ccc43)sc3ccccc35)nc3c2oc2ccccc23)cc1 ; CC1(C)c2ccccc2-c2ccc3c(c21)c1ccccc1n3-c1cccc(-c2nccc3ccccc23)c1 ; CC1(C)c2ccccc2-c2ccc(-n3c4ccccc4c4c5oc6ccc(-c7ccccc7)cc6c5ccc43)cc21 ; c1ccc2nc(-n3c4ccccc4c4c5sc6ccccc6c5ccc43)ccc2c1]

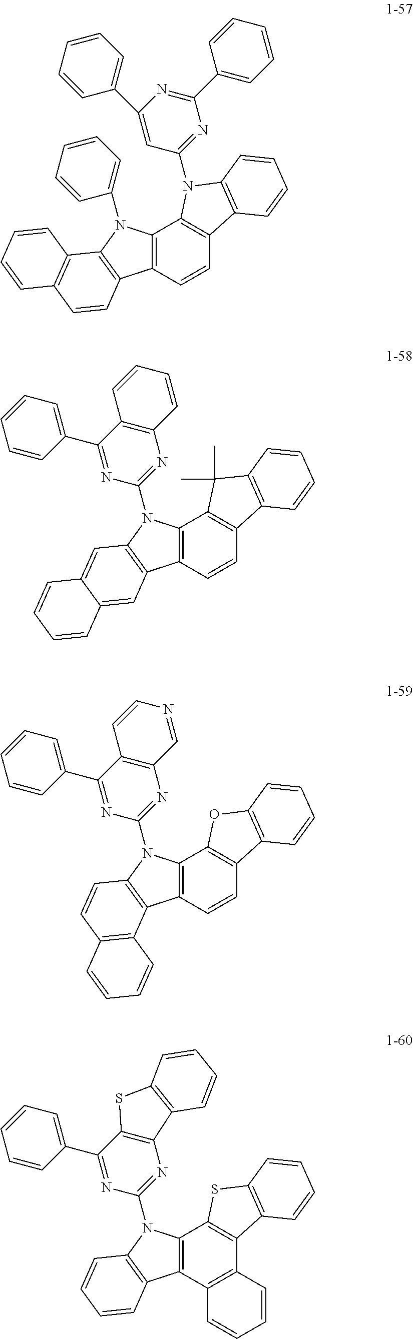 [SMILES: c1ccc(-c2cc(-n3c4ccccc4c4ccc5c6ccc7ccccc7c6n(-c6ccccc6)c5c43)nc(-c3ccccc3)n2)cc1 ; CC1(C)c2ccccc2-c2ccc3c4cc5ccccc5cc4n(-c4nc(-c5ccccc5)c5ccccc5n4)c3c21 ; c1ccc(-c2nc(-n3c4ccc5ccccc5c4c4ccc5c6ccccc6oc5c43)nc3cnccc23)cc1 ; c1ccc(-c2nc(-n3c4ccccc4c4c5ccccc5c5c6ccccc6sc5c43)nc3c2sc2ccccc23)cc1]

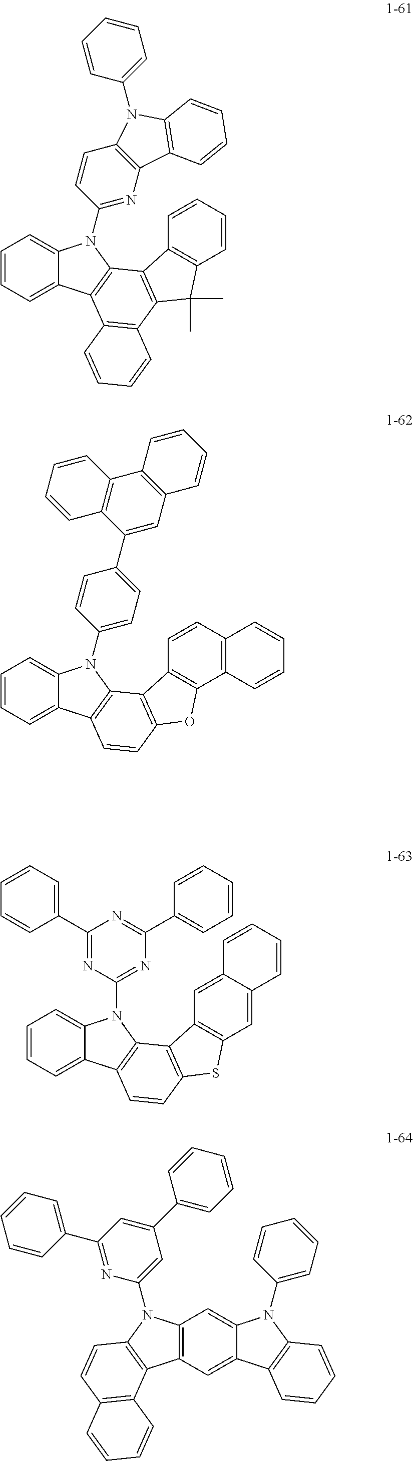

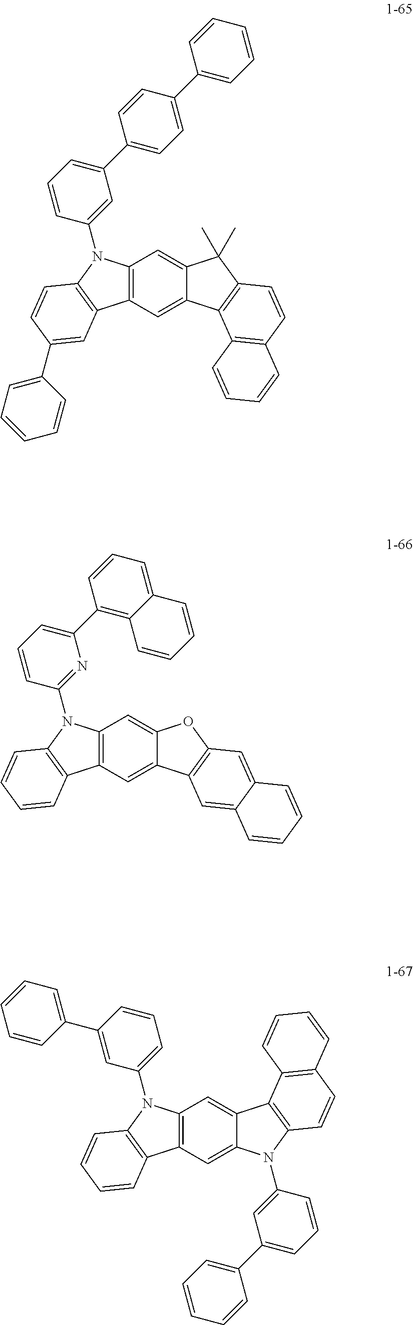 [SMILES: CC1(C)c2cc3c(cc2-c2c1ccc1ccccc21)c1cc(-c2ccccc2)ccc1n3-c1cccc(-c2ccc(-c3ccccc3)cc2)c1 ; c1cc(-c2cccc3ccccc23)nc(-n2c3ccccc3c3cc4c(cc32)oc2cc3ccccc3cc24)c1 ; c1ccc(-c2cccc(-n3c4ccccc4c4cc5c(cc43)c3c4ccccc4ccc3n5-c3cccc(-c4ccccc4)c3)c2)cc1]

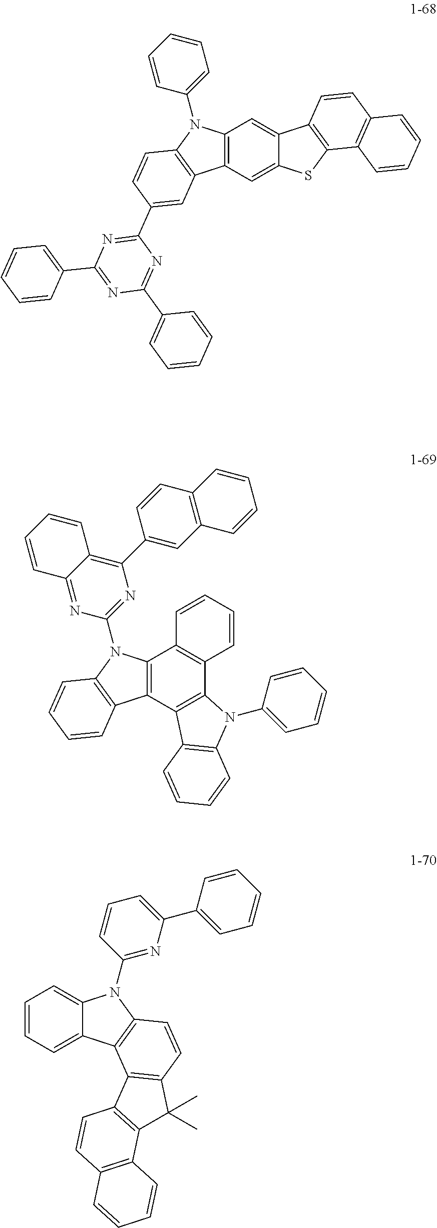 [SMILES: c1ccc(-c2nc(-c3ccccc3)nc(-c3ccc4c(c3)c3cc5sc6c7ccccc7ccc6c5cc3n4-c3ccccc3)n2)cc1 ; c1ccc(-n2c3ccccc3c3c4c5ccccc5n(-c5nc(-c6ccc7ccccc7c6)c6ccccc6n5)c4c4ccccc4c32)cc1 ; CC1(C)c2ccc3c(c2-c2ccc4ccccc4c21)c1ccccc1n3-c1cccc(-c2ccccc2)n1]

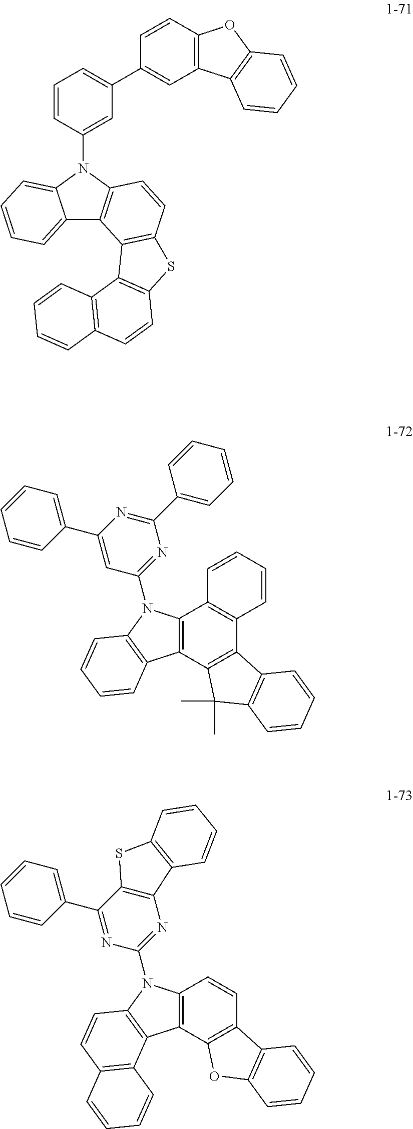 [SMILES: c1cc(-c2ccc3oc4ccccc4c3c2)cc(-n2c3ccccc3c3c4c(ccc32)sc2ccc3ccccc3c24)c1 ; CC1(C)c2ccccc2-c2c1c1c3ccccc3n(-c3cc(-c4ccccc4)nc(-c4ccccc4)n3)c1c1ccccc21 ; c1ccc(-c2nc(-n3c4ccc5ccccc5c4c4c5oc6ccccc6c5ccc43)nc3c2sc2ccccc23)cc1]

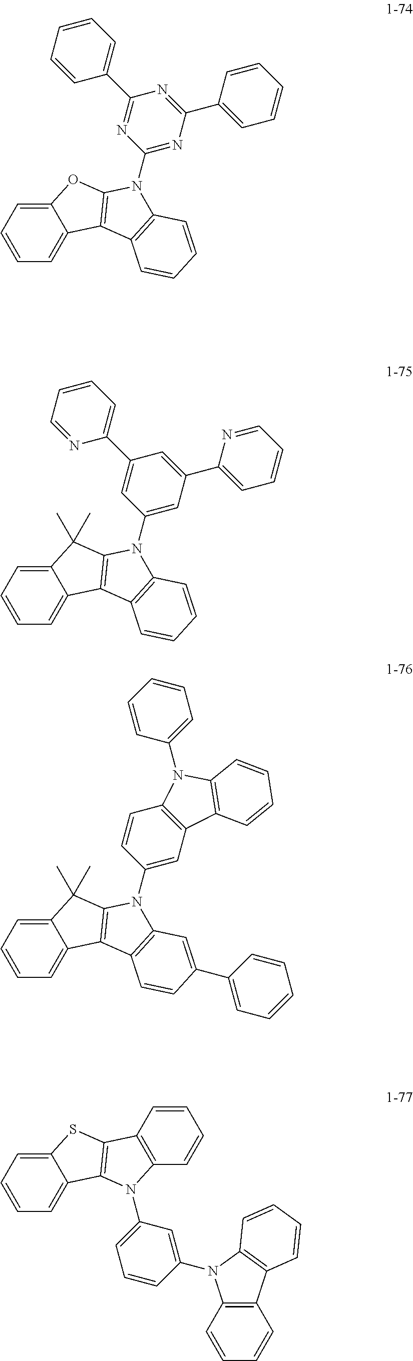

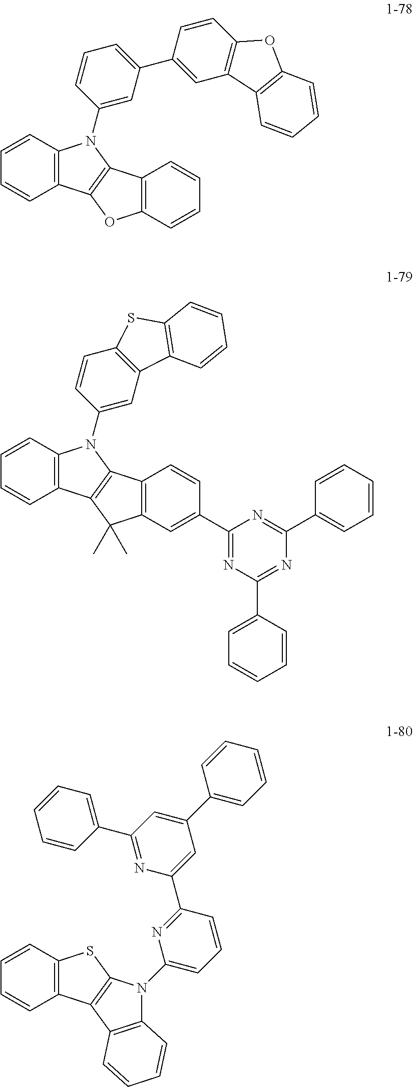 [SMILES: c1cc(-c2ccc3oc4ccccc4c3c2)cc(-n2c3ccccc3c3oc4ccccc4c32)c1 ; CC1(C)c2cc(-c3nc(-c4ccccc4)nc(-c4ccccc4)n3)ccc2-c2c1c1ccccc1n2-c1ccc2sc3ccccc3c2c1 ; c1ccc(-c2cc(-c3ccccc3)nc(-c3cccc(-n4c5ccccc5c5c6ccccc6sc54)n3)c2)cc1]

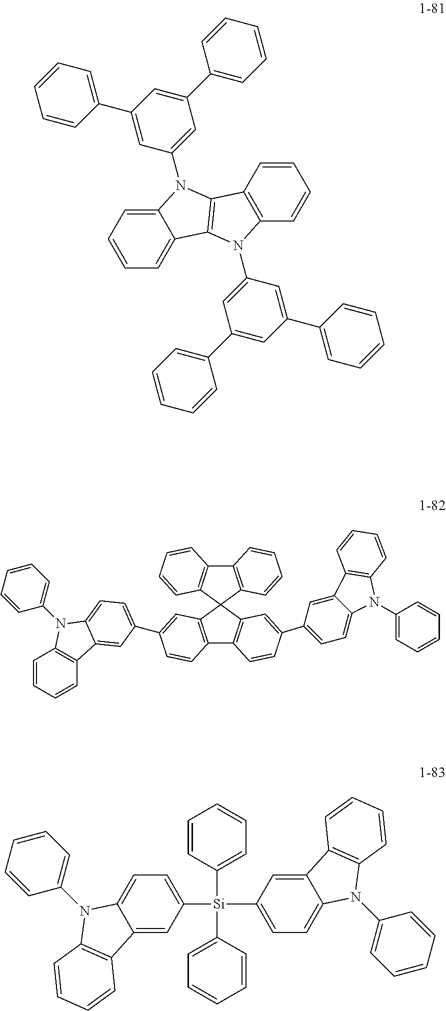

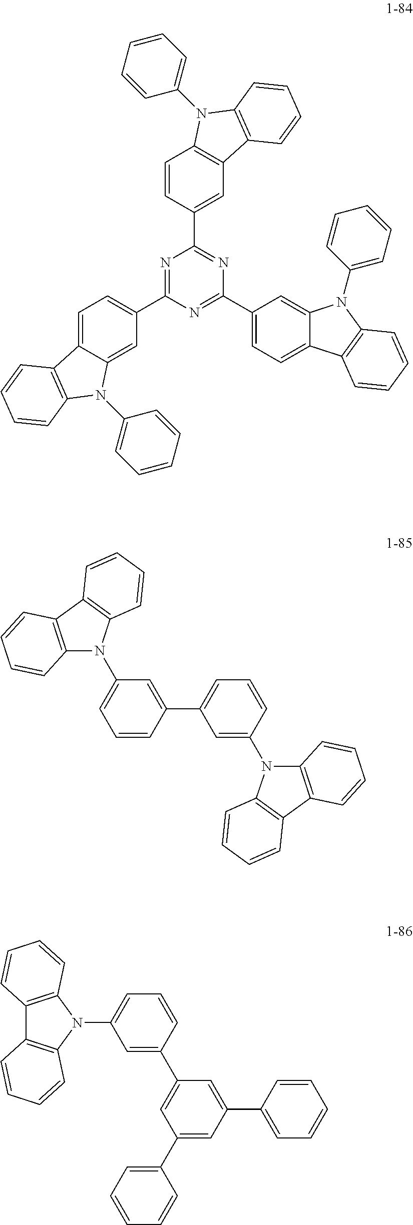 [SMILES: c1ccc(-n2c3ccccc3c3cc(-c4nc(-c5ccc6c7ccccc7n(-c7ccccc7)c6c5)nc(-c5ccc6c7ccccc7n(-c7ccccc7)c6c5)n4)ccc32)cc1 ; c1cc(-c2cccc(-n3c4ccccc4c4ccccc43)c2)cc(-n2c3ccccc3c3ccccc32)c1 ; c1ccc(-c2cc(-c3ccccc3)cc(-c3cccc(-n4c5ccccc5c5ccccc54)c3)c2)cc1]

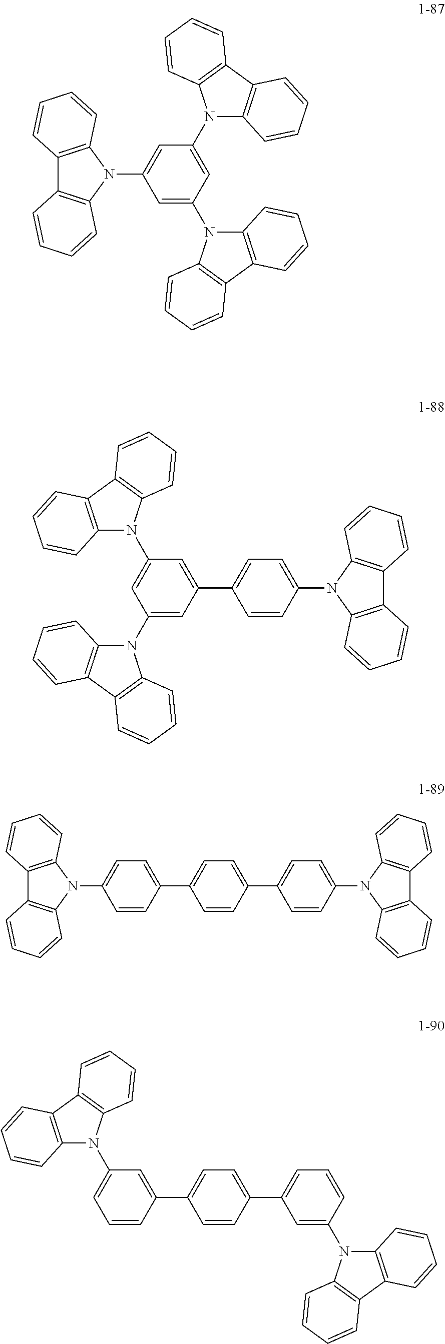 [SMILES: c1ccc2c(c1)c1ccccc1n2-c1cc(-n2c3ccccc3c3ccccc32)cc(-n2c3ccccc3c3ccccc32)c1 ; c1ccc2c(c1)c1ccccc1n2-c1ccc(-c2cc(-n3c4ccccc4c4ccccc43)cc(-n3c4ccccc4c4ccccc43)c2)cc1 ; c1ccc2c(c1)c1ccccc1n2-c1ccc(-c2ccc(-c3ccc(-n4c5ccccc5c5ccccc54)cc3)cc2)cc1 ; c1cc(-c2ccc(-c3cccc(-n4c5ccccc5c5ccccc54)c3)cc2)cc(-n2c3ccccc3c3ccccc32)c1]

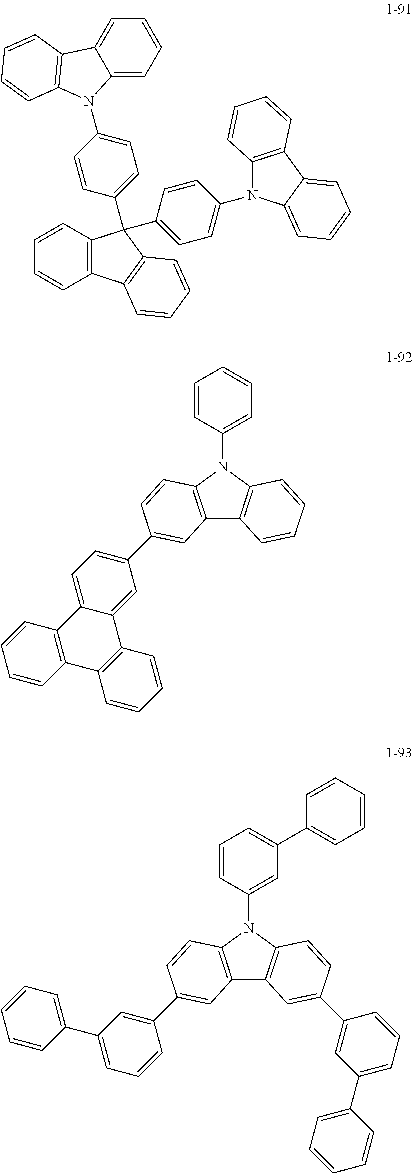 [SMILES: c1ccc2c(c1)-c1ccccc1C2(c1ccc(-n2c3ccccc3c3ccccc32)cc1)c1ccc(-n2c3ccccc3c3ccccc32)cc1 ; c1ccc(-n2c3ccccc3c3cc(-c4ccc5c6ccccc6c6ccccc6c5c4)ccc32)cc1 ; c1ccc(-c2cccc(-c3ccc4c(c3)c3cc(-c5cccc(-c6ccccc6)c5)ccc3n4-c3cccc(-c4ccccc4)c3)c2)cc1]

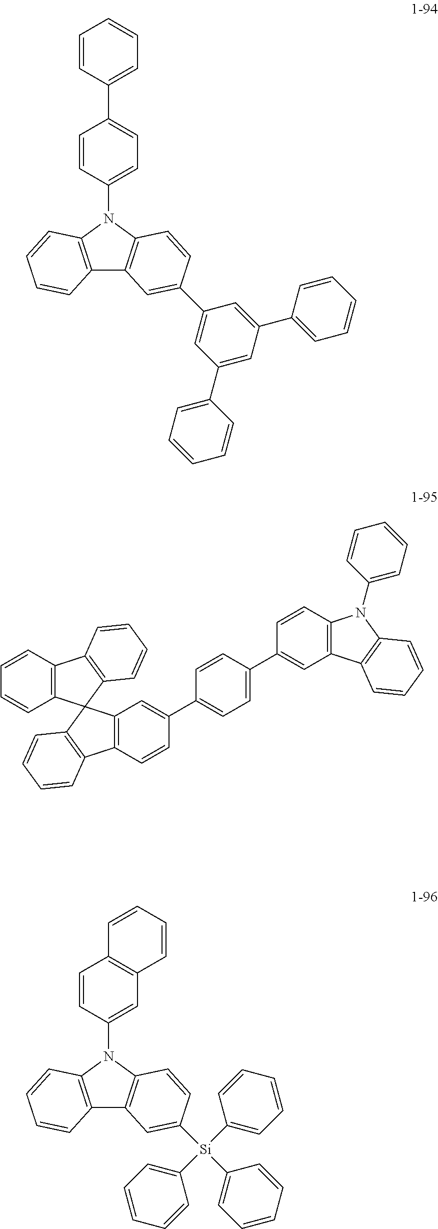 [SMILES: c1ccc(-c2ccc(-n3c4ccccc4c4cc(-c5cc(-c6ccccc6)cc(-c6ccccc6)c5)ccc43)cc2)cc1 ; c1ccc(-n2c3ccccc3c3cc(-c4ccc(-c5ccc6c(c5)C5(c7ccccc7-c7ccccc75)c5ccccc5-6)cc4)ccc32)cc1 ; c1ccc([Si](c2ccccc2)(c2ccccc2)c2ccc3c(c2)c2ccccc2n3-c2ccc3ccccc3c2)cc1]

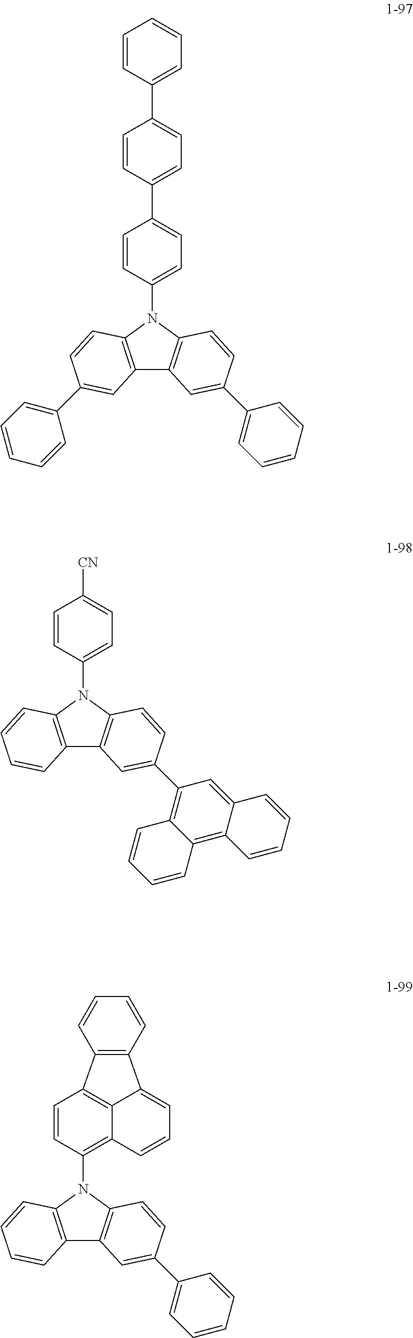 [SMILES: c1ccc(-c2ccc(-c3ccc(-n4c5ccc(-c6ccccc6)cc5c5cc(-c6ccccc6)ccc54)cc3)cc2)cc1 ; N#Cc1ccc(-n2c3ccccc3c3cc(-c4cc5ccccc5c5ccccc45)ccc32)cc1 ; c1ccc(-c2ccc3c(c2)c2ccccc2n3-c2ccc3c4c(cccc24)-c2ccccc2-3)cc1]

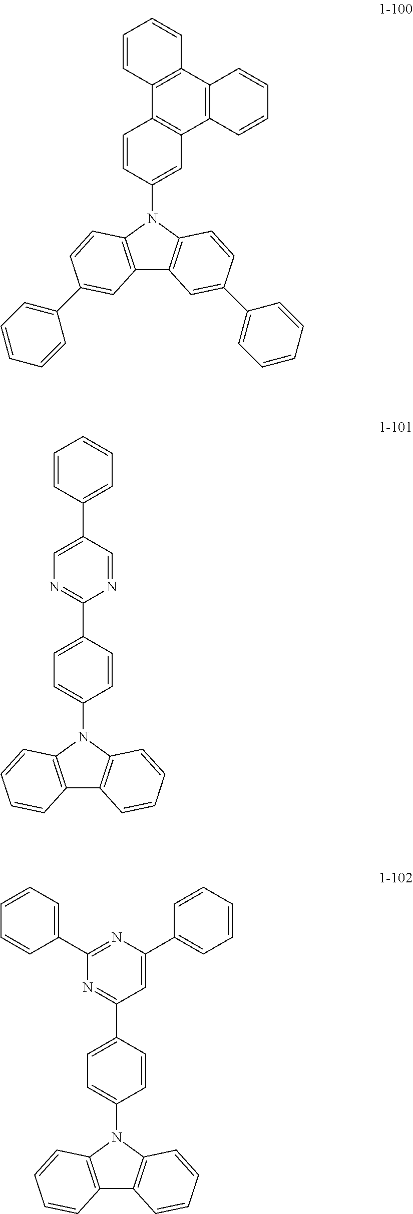 [SMILES: c1ccc(-c2ccc3c(c2)c2cc(-c4ccccc4)ccc2n3-c2ccc3c4ccccc4c4ccccc4c3c2)cc1 ; c1ccc(-c2cnc(-c3ccc(-n4c5ccccc5c5ccccc54)cc3)nc2)cc1 ; c1ccc(-c2cc(-c3ccc(-n4c5ccccc5c5ccccc54)cc3)nc(-c3ccccc3)n2)cc1]

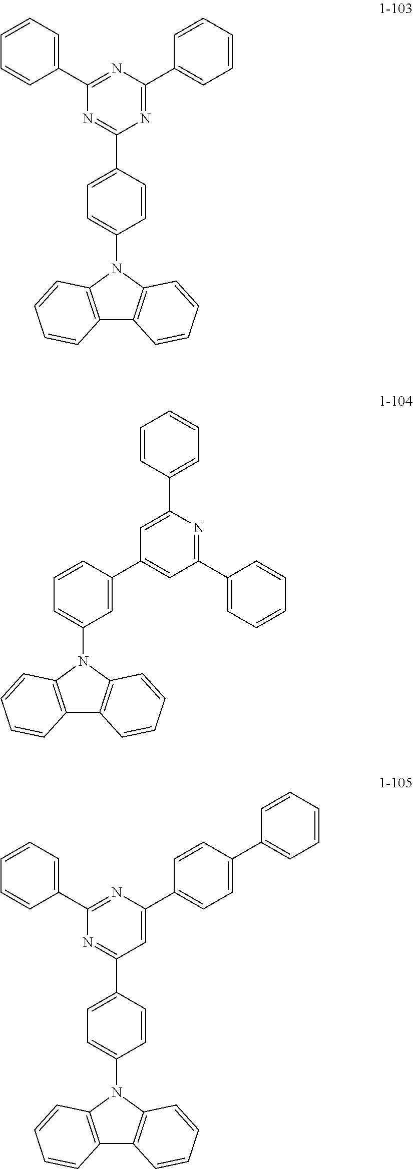 [SMILES: c1ccc(-c2nc(-c3ccccc3)nc(-c3ccc(-n4c5ccccc5c5ccccc54)cc3)n2)cc1 ; c1ccc(-c2cc(-c3cccc(-n4c5ccccc5c5ccccc54)c3)cc(-c3ccccc3)n2)cc1 ; c1ccc(-c2ccc(-c3cc(-c4ccc(-n5c6ccccc6c6ccccc65)cc4)nc(-c4ccccc4)n3)cc2)cc1]

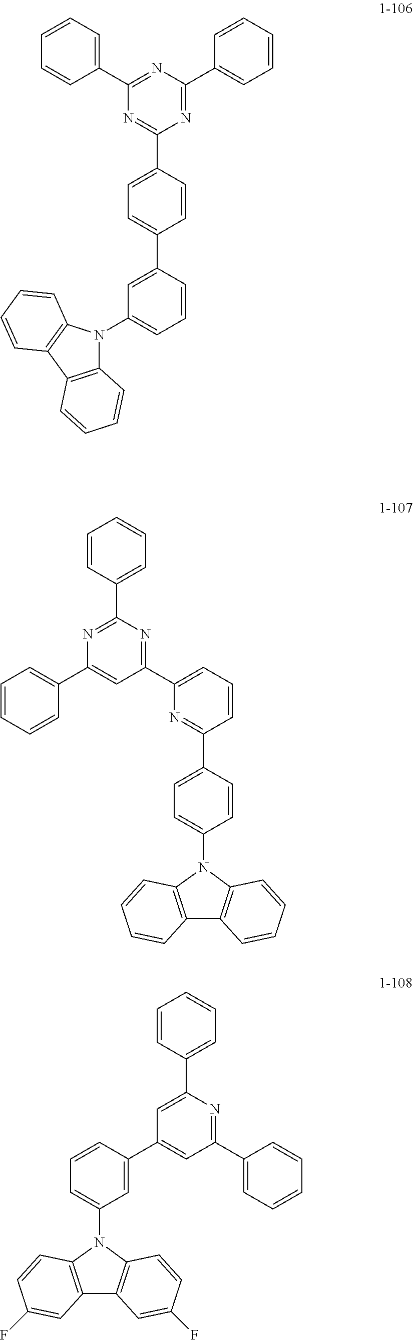 [SMILES: c1ccc(-c2nc(-c3ccccc3)nc(-c3ccc(-c4cccc(-n5c6ccccc6c6ccccc65)c4)cc3)n2)cc1 ; c1ccc(-c2cc(-c3cccc(-c4ccc(-n5c6ccccc6c6ccccc65)cc4)n3)nc(-c3ccccc3)n2)cc1 ; Fc1ccc2c(c1)c1cc(F)ccc1n2-c1cccc(-c2cc(-c3ccccc3)nc(-c3ccccc3)c2)c1]

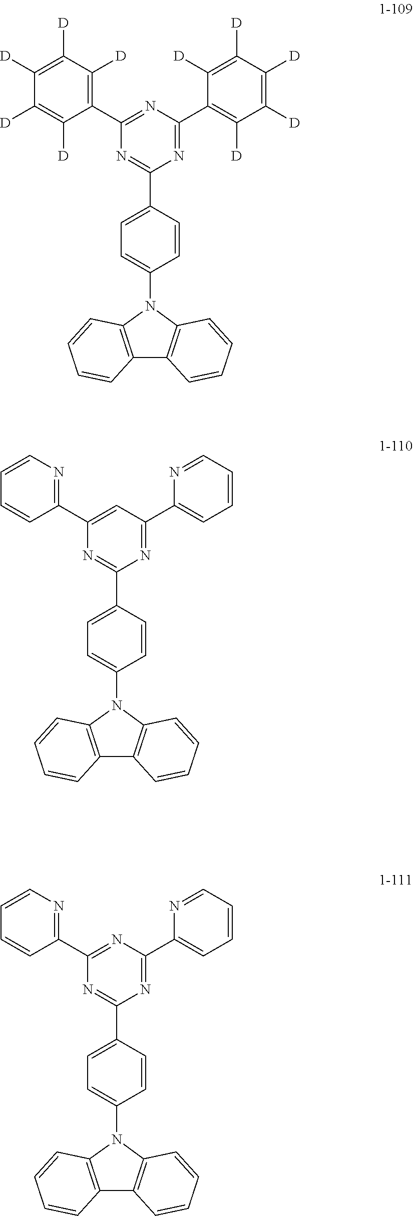 [SMILES: [2H]c1c([2H])c([2H])c(-c2nc(-c3ccc(-n4c5ccccc5c5ccccc54)cc3)nc(-c3c([2H])c([2H])c([2H])c([2H])c3[2H])n2)c([2H])c1[2H] ; c1ccc(-c2cc(-c3ccccn3)nc(-c3ccc(-n4c5ccccc5c5ccccc54)cc3)n2)nc1 ; c1ccc(-c2nc(-c3ccc(-n4c5ccccc5c5ccccc54)cc3)nc(-c3ccccn3)n2)nc1]

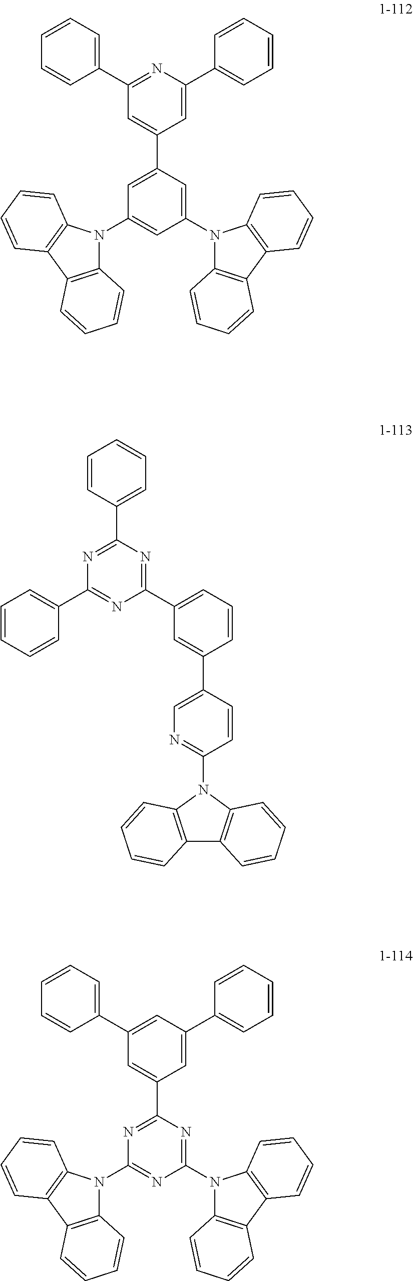 [SMILES: c1ccc(-c2cc(-c3cc(-n4c5ccccc5c5ccccc54)cc(-n4c5ccccc5c5ccccc54)c3)cc(-c3ccccc3)n2)cc1 ; c1ccc(-c2nc(-c3ccccc3)nc(-c3cccc(-c4ccc(-n5c6ccccc6c6ccccc65)nc4)c3)n2)cc1 ; c1ccc(-c2cc(-c3ccccc3)cc(-c3nc(-n4c5ccccc5c5ccccc54)nc(-n4c5ccccc5c5ccccc54)n3)c2)cc1]

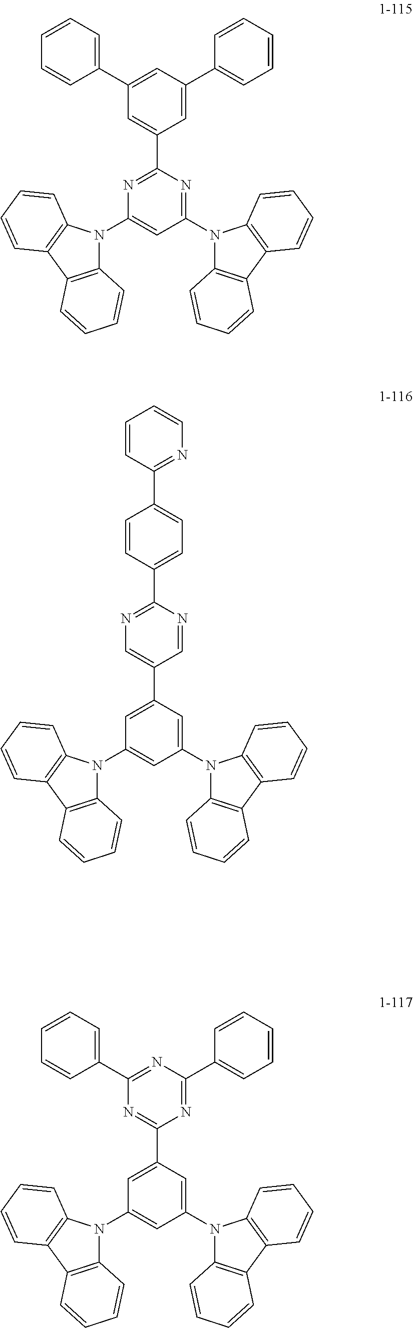 [SMILES: c1ccc(-c2cc(-c3ccccc3)cc(-c3nc(-n4c5ccccc5c5ccccc54)cc(-n4c5ccccc5c5ccccc54)n3)c2)cc1 ; c1ccc(-c2ccc(-c3ncc(-c4cc(-n5c6ccccc6c6ccccc65)cc(-n5c6ccccc6c6ccccc65)c4)cn3)cc2)nc1 ; c1ccc(-c2nc(-c3ccccc3)nc(-c3cc(-n4c5ccccc5c5ccccc54)cc(-n4c5ccccc5c5ccccc54)c3)n2)cc1]

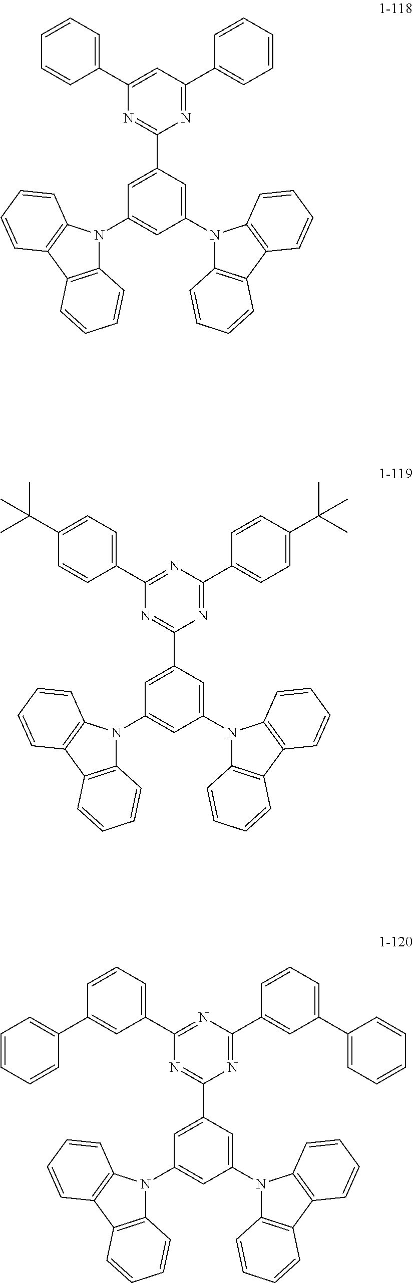 [SMILES: c1ccc(-c2cc(-c3ccccc3)nc(-c3cc(-n4c5ccccc5c5ccccc54)cc(-n4c5ccccc5c5ccccc54)c3)n2)cc1 ; CC(C)(C)c1ccc(-c2nc(-c3ccc(C(C)(C)C)cc3)nc(-c3cc(-n4c5ccccc5c5ccccc54)cc(-n4c5ccccc5c5ccccc54)c3)n2)cc1 ; c1ccc(-c2cccc(-c3nc(-c4cccc(-c5ccccc5)c4)nc(-c4cc(-n5c6ccccc6c6ccccc65)cc(-n5c6ccccc6c6ccccc65)c4)n3)c2)cc1]

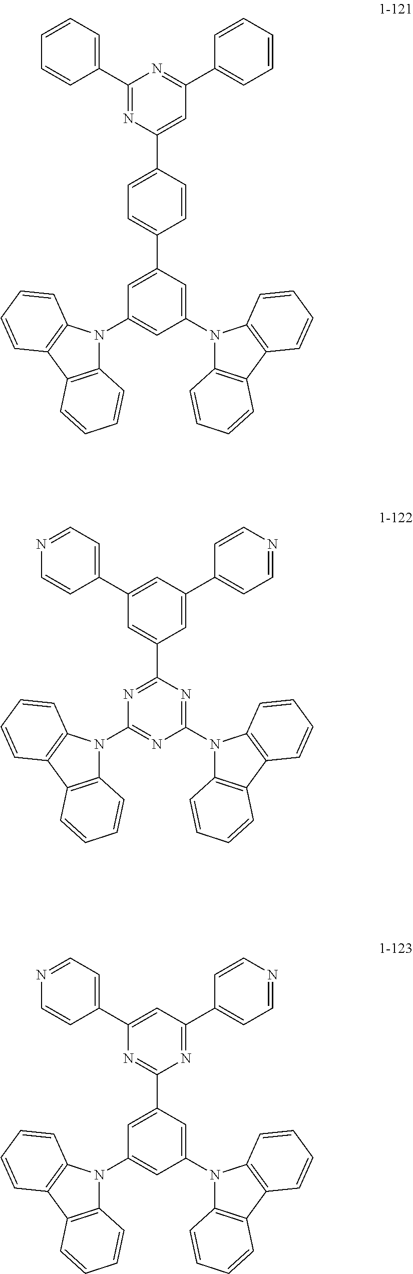 [SMILES: c1ccc(-c2cc(-c3ccc(-c4cc(-n5c6ccccc6c6ccccc65)cc(-n5c6ccccc6c6ccccc65)c4)cc3)nc(-c3ccccc3)n2)cc1 ; c1ccc2c(c1)c1ccccc1n2-c1nc(-c2cc(-c3ccncc3)cc(-c3ccncc3)c2)nc(-n2c3ccccc3c3ccccc32)n1 ; c1ccc2c(c1)c1ccccc1n2-c1cc(-c2nc(-c3ccncc3)cc(-c3ccncc3)n2)cc(-n2c3ccccc3c3ccccc32)c1]

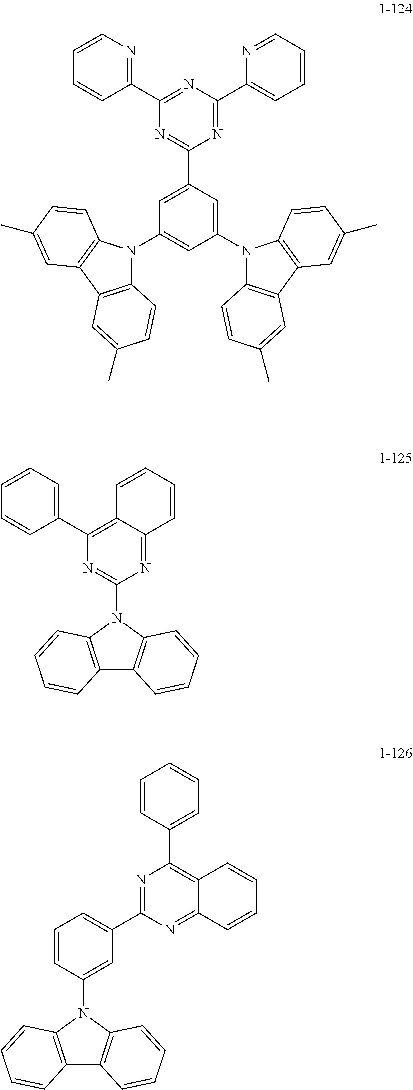

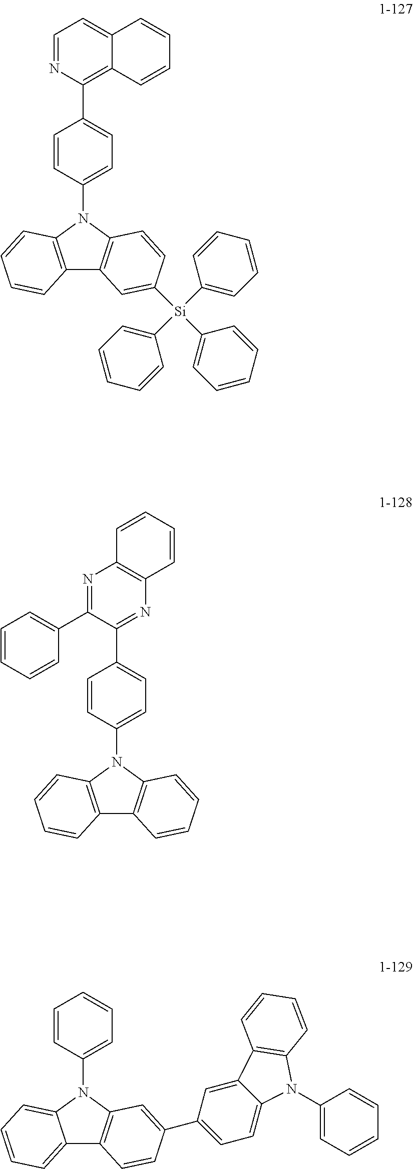 [SMILES: c1ccc([Si](c2ccccc2)(c2ccccc2)c2ccc3c(c2)c2ccccc2n3-c2ccc(-c3nccc4ccccc34)cc2)cc1 ; c1ccc(-c2nc3ccccc3nc2-c2ccc(-n3c4ccccc4c4ccccc43)cc2)cc1 ; c1ccc(-n2c3ccccc3c3cc(-c4ccc5c6ccccc6n(-c6ccccc6)c5c4)ccc32)cc1]

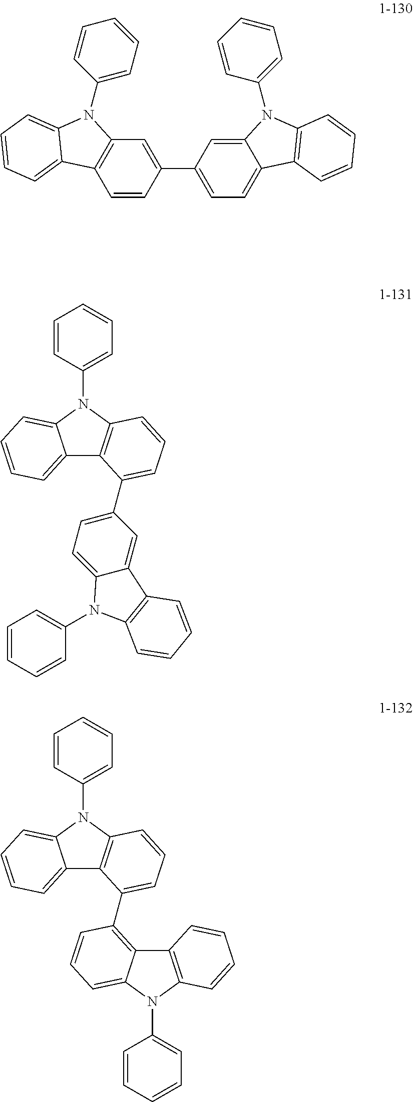 [SMILES: c1ccc(-n2c3ccccc3c3ccc(-c4ccc5c6ccccc6n(-c6ccccc6)c5c4)cc32)cc1 ; c1ccc(-n2c3ccccc3c3cc(-c4cccc5c4c4ccccc4n5-c4ccccc4)ccc32)cc1 ; c1ccc(-n2c3ccccc3c3c(-c4cccc5c4c4ccccc4n5-c4ccccc4)cccc32)cc1]

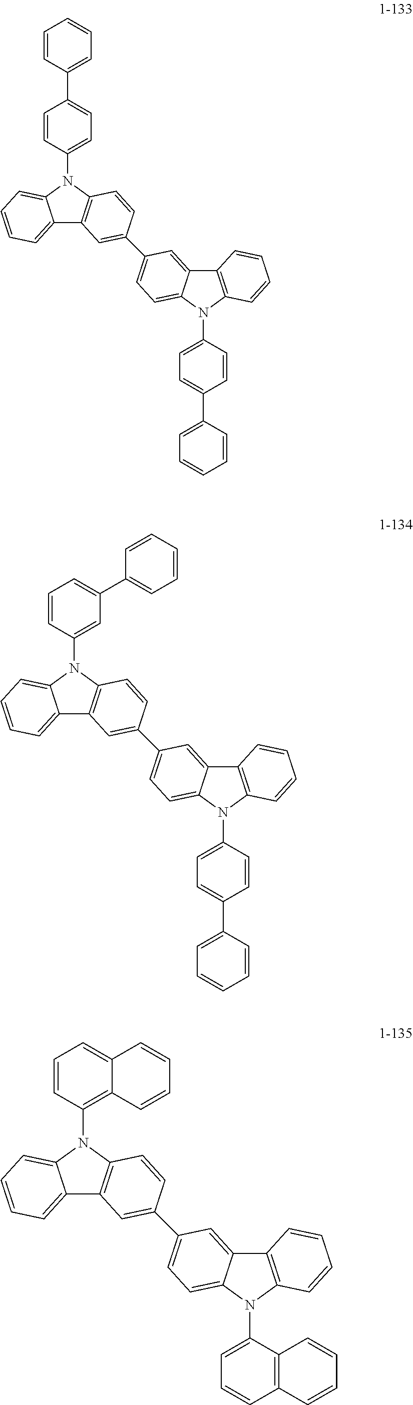 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-n3c4ccccc4c4cc(-c5ccc6c(c5)c5ccccc5n6-c5cccc6ccccc56)ccc43)cccc2c1]

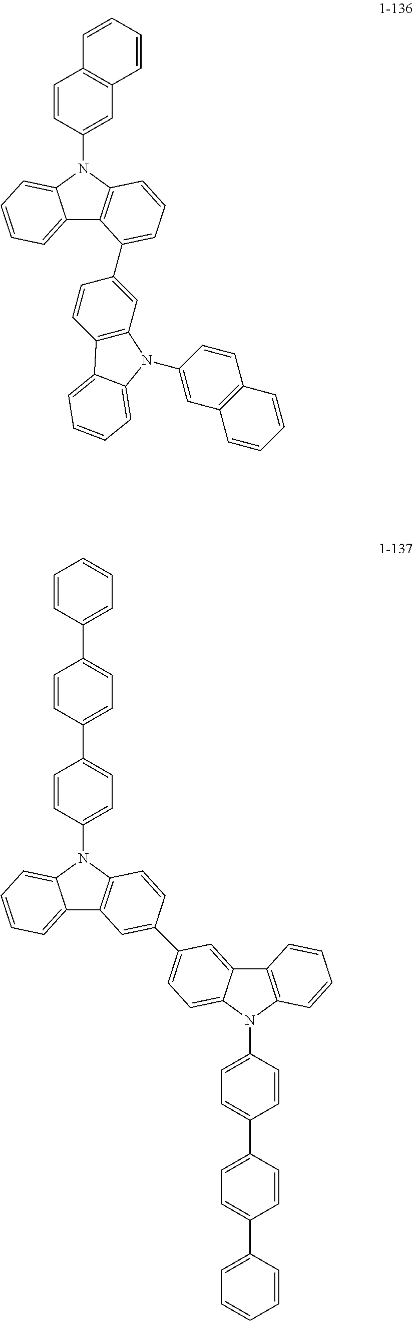 [SMILES: c1ccc2cc(-n3c4ccccc4c4ccc(-c5cccc6c5c5ccccc5n6-c5ccc6ccccc6c5)cc43)ccc2c1 ; c1ccc(-c2ccc(-c3ccc(-n4c5ccccc5c5cc(-c6ccc7c(c6)c6ccccc6n7-c6ccc(-c7ccc(-c8ccccc8)cc7)cc6)ccc54)cc3)cc2)cc1]

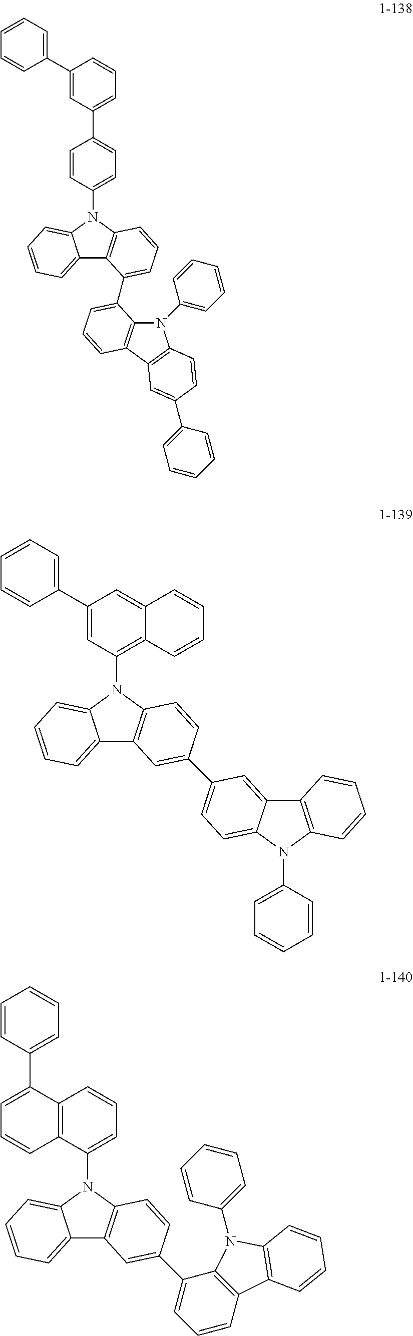 [SMILES: c1ccc(-c2cccc(-c3ccc(-n4c5ccccc5c5c(-c6cccc7c8cc(-c9ccccc9)ccc8n(-c8ccccc8)c67)cccc54)cc3)c2)cc1 ; c1ccc(-c2cc(-n3c4ccccc4c4cc(-c5ccc6c(c5)c5ccccc5n6-c5ccccc5)ccc43)c3ccccc3c2)cc1 ; c1ccc(-c2cccc3c(-n4c5ccccc5c5cc(-c6cccc7c8ccccc8n(-c8ccccc8)c67)ccc54)cccc23)cc1]

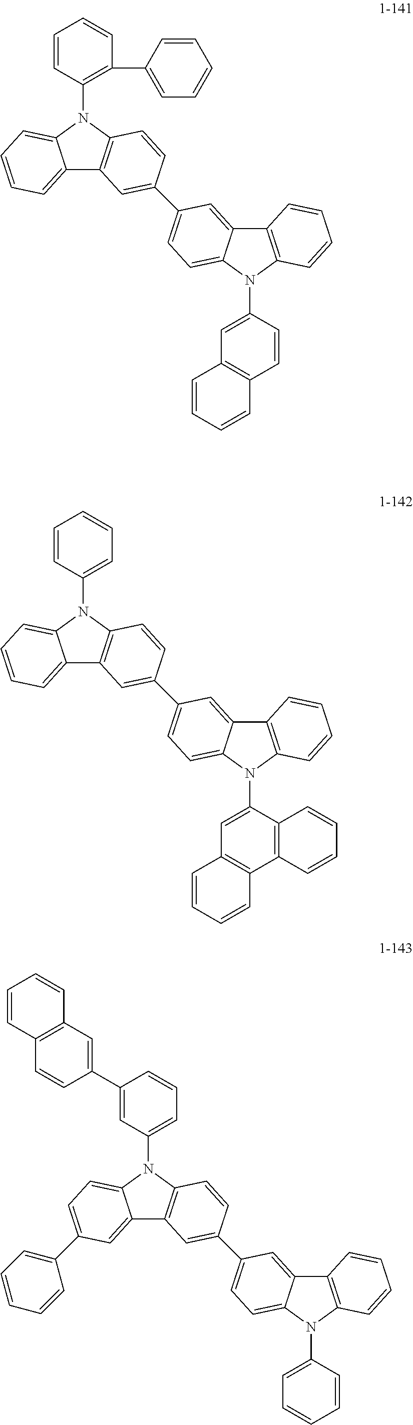 [SMILES: c1ccc(-c2ccccc2-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cc5ccccc5c5ccccc45)ccc32)cc1 ; c1ccc(-c2ccc3c(c2)c2cc(-c4ccc5c(c4)c4ccccc4n5-c4ccccc4)ccc2n3-c2cccc(-c3ccc4ccccc4c3)c2)cc1]

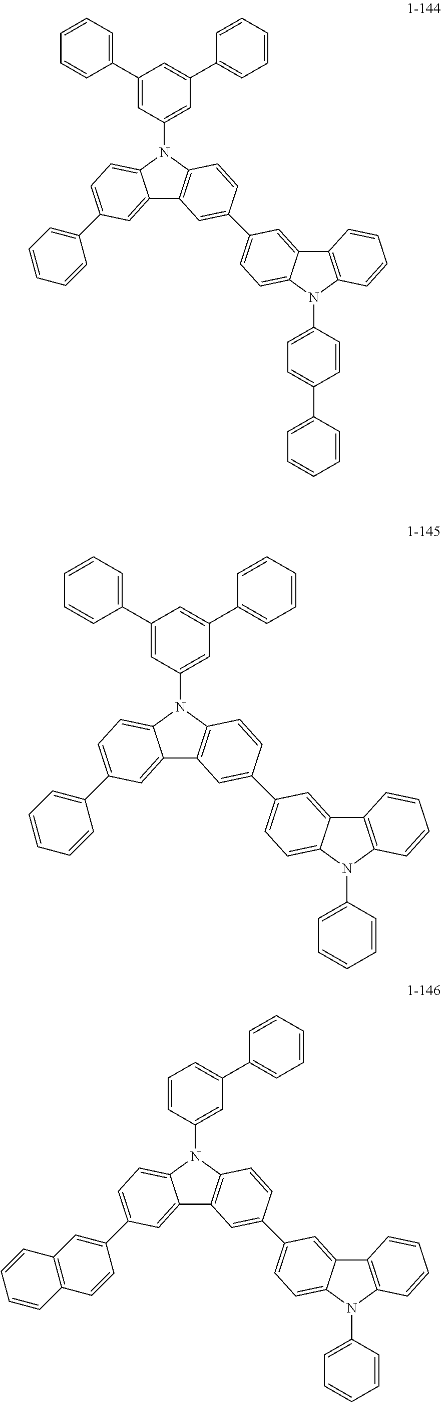 [SMILES: c1ccc(-c2ccc(-n3c4ccccc4c4cc(-c5ccc6c(c5)c5cc(-c7ccccc7)ccc5n6-c5cc(-c6ccccc6)cc(-c6ccccc6)c5)ccc43)cc2)cc1 ; c1ccc(-c2cc(-c3ccccc3)cc(-n3c4ccc(-c5ccccc5)cc4c4cc(-c5ccc6c(c5)c5ccccc5n6-c5ccccc5)ccc43)c2)cc1 ; c1ccc(-c2cccc(-n3c4ccc(-c5ccc6ccccc6c5)cc4c4cc(-c5ccc6c(c5)c5ccccc5n6-c5ccccc5)ccc43)c2)cc1]

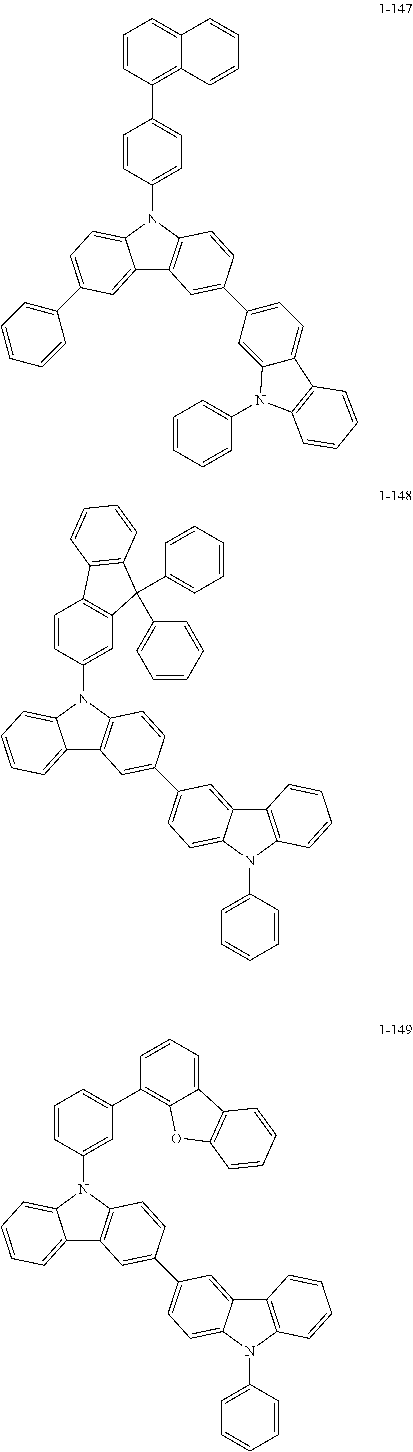 [SMILES: c1ccc(-c2ccc3c(c2)c2cc(-c4ccc5c6ccccc6n(-c6ccccc6)c5c4)ccc2n3-c2ccc(-c3cccc4ccccc34)cc2)cc1 ; c1ccc(-n2c3ccccc3c3cc(-c4ccc5c(c4)c4ccccc4n5-c4ccc5c(c4)C(c4ccccc4)(c4ccccc4)c4ccccc4-5)ccc32)cc1 ; c1ccc(-n2c3ccccc3c3cc(-c4ccc5c(c4)c4ccccc4n5-c4cccc(-c5cccc6c5oc5ccccc56)c4)ccc32)cc1]

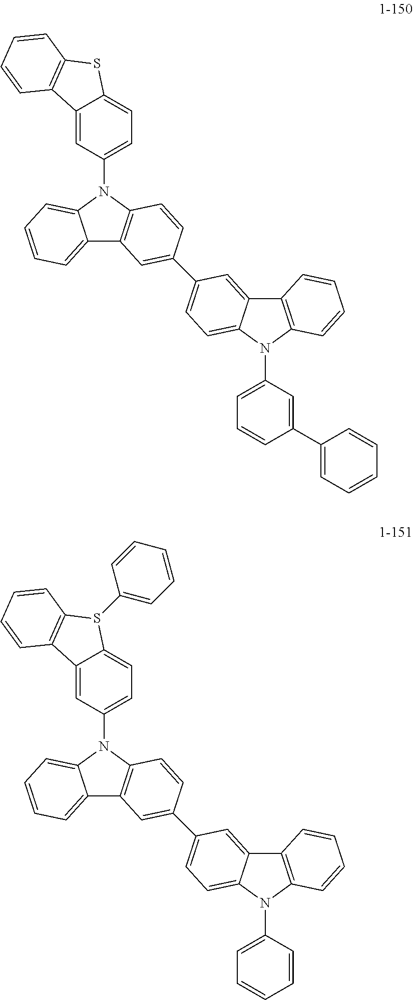

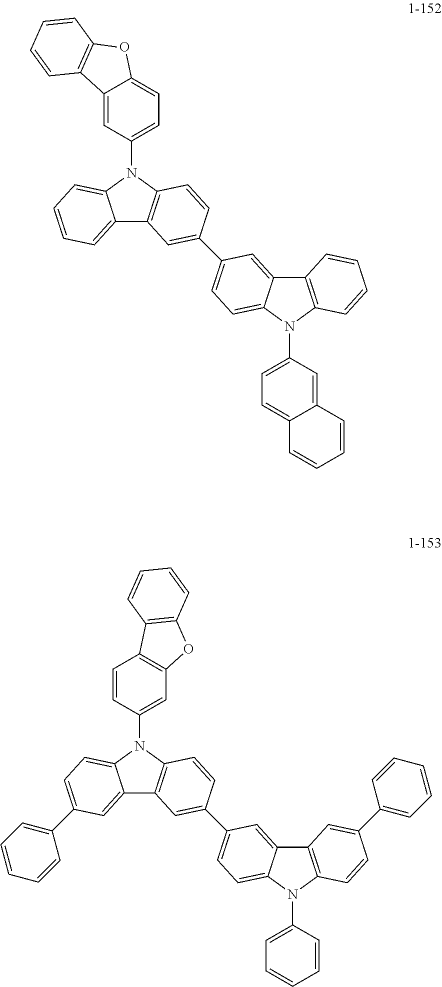 [SMILES: c1ccc2cc(-n3c4ccccc4c4cc(-c5ccc6c(c5)c5ccccc5n6-c5ccc6oc7ccccc7c6c5)ccc43)ccc2c1 ; c1ccc(-c2ccc3c(c2)c2cc(-c4ccc5c(c4)c4cc(-c6ccccc6)ccc4n5-c4ccc5c(c4)oc4ccccc45)ccc2n3-c2ccccc2)cc1]

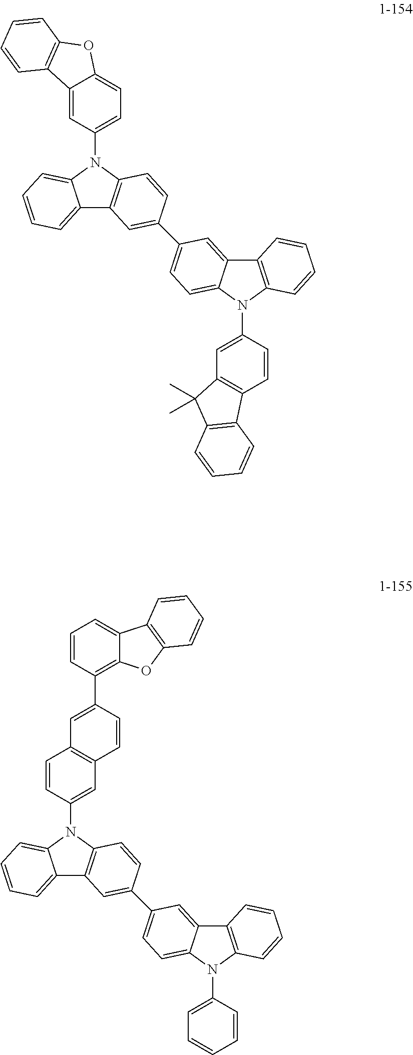 [SMILES: CC1(C)c2ccccc2-c2ccc(-n3c4ccccc4c4cc(-c5ccc6c(c5)c5ccccc5n6-c5ccc6oc7ccccc7c6c5)ccc43)cc21 ; c1ccc(-n2c3ccccc3c3cc(-c4ccc5c(c4)c4ccccc4n5-c4ccc5cc(-c6cccc7c6oc6ccccc67)ccc5c4)ccc32)cc1]

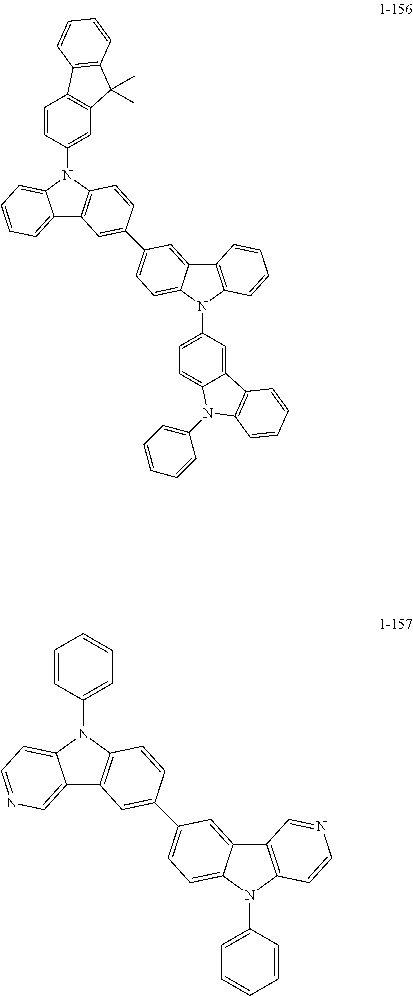 [SMILES: CC1(C)c2ccccc2-c2ccc(-n3c4ccccc4c4cc(-c5ccc6c(c5)c5ccccc5n6-c5ccc6c(c5)c5ccccc5n6-c5ccccc5)ccc43)cc21 ; c1ccc(-n2c3ccncc3c3cc(-c4ccc5c(c4)c4cnccc4n5-c4ccccc4)ccc32)cc1]

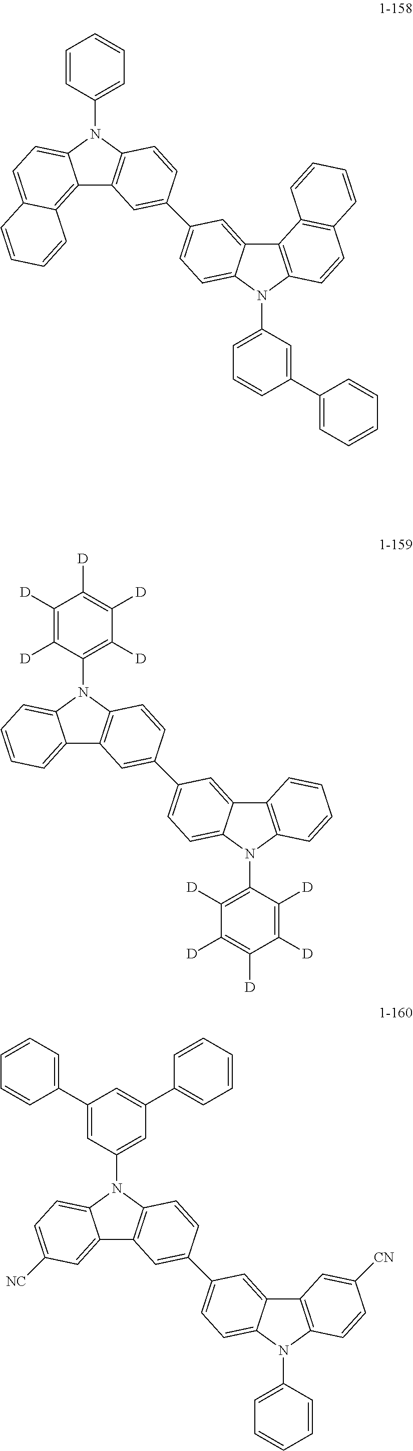 [SMILES: c1ccc(-c2cccc(-n3c4ccc(-c5ccc6c(c5)c5c7ccccc7ccc5n6-c5ccccc5)cc4c4c5ccccc5ccc43)c2)cc1 ; [2H]c1c([2H])c([2H])c(-n2c3ccccc3c3cc(-c4ccc5c(c4)c4ccccc4n5-c4c([2H])c([2H])c([2H])c([2H])c4[2H])ccc32)c([2H])c1[2H] ; N#Cc1ccc2c(c1)c1cc(-c3ccc4c(c3)c3cc(C#N)ccc3n4-c3cc(-c4ccccc4)cc(-c4ccccc4)c3)ccc1n2-c1ccccc1]

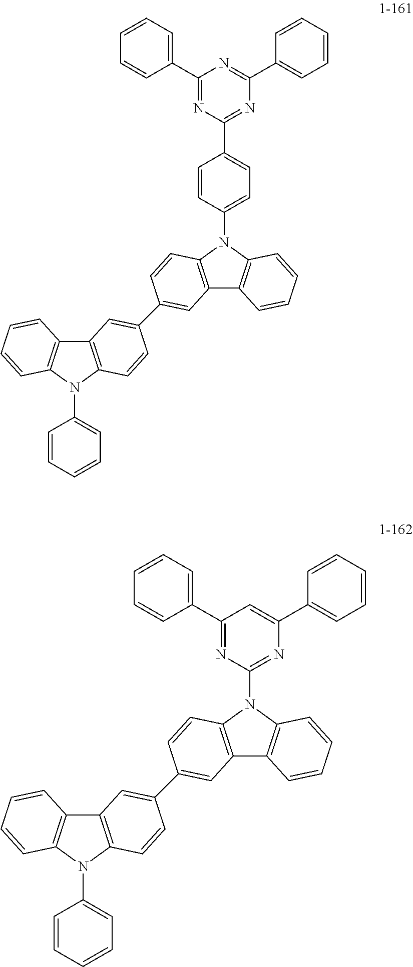 [SMILES: c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2cc(-c3ccccc3)nc(-n3c4ccccc4c4cc(-c5ccc6c(c5)c5ccccc5n6-c5ccccc5)ccc43)n2)cc1]

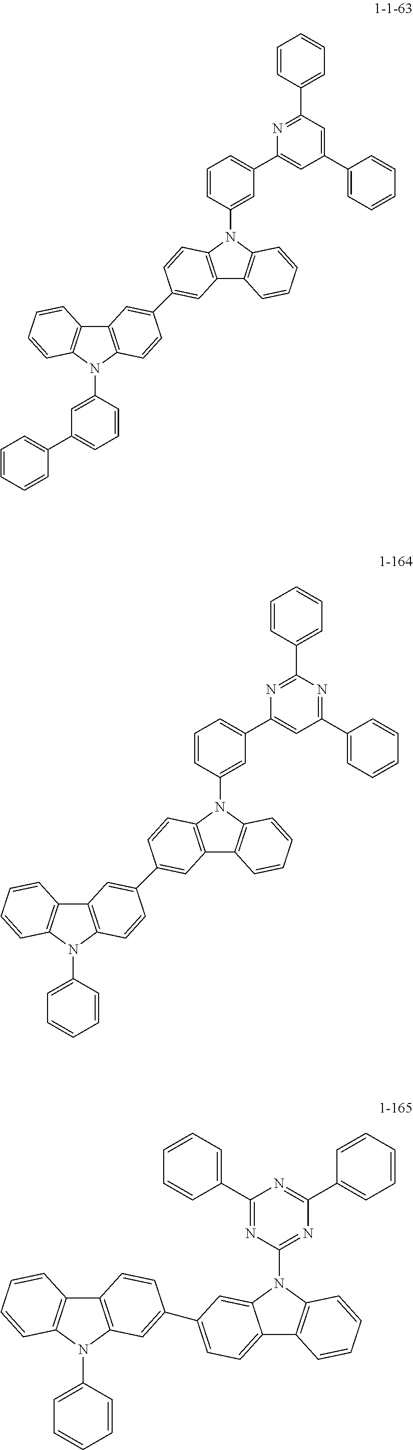 [SMILES: c1ccc(-c2cccc(-n3c4ccccc4c4cc(-c5ccc6c(c5)c5ccccc5n6-c5cccc(-c6cc(-c7ccccc7)cc(-c7ccccc7)n6)c5)ccc43)c2)cc1 ; c1ccc(-c2cc(-c3cccc(-n4c5ccccc5c5cc(-c6ccc7c(c6)c6ccccc6n7-c6ccccc6)ccc54)c3)nc(-c3ccccc3)n2)cc1 ; c1ccc(-c2nc(-c3ccccc3)nc(-n3c4ccccc4c4ccc(-c5ccc6c7ccccc7n(-c7ccccc7)c6c5)cc43)n2)cc1]

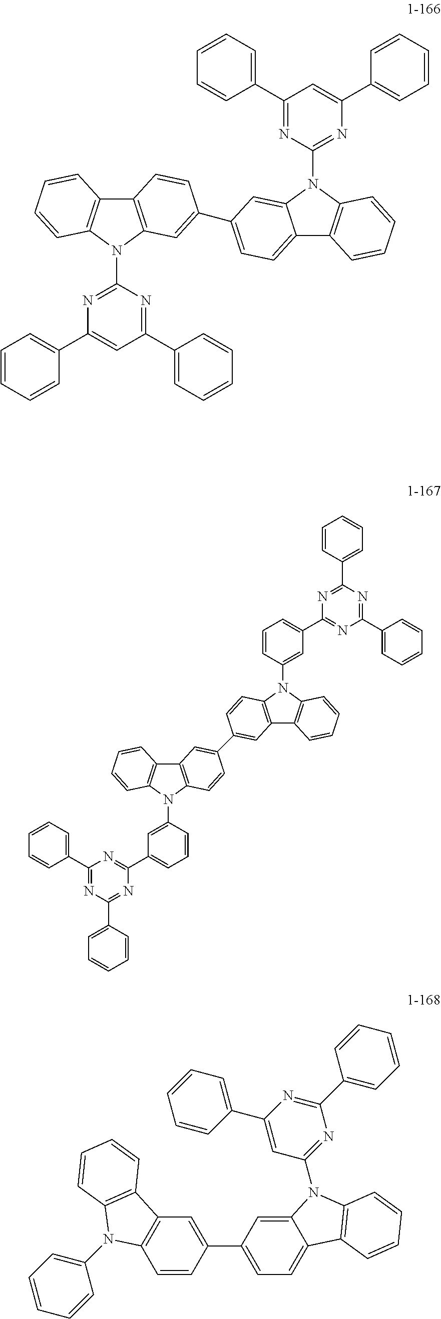 [SMILES: c1ccc(-c2cc(-c3ccccc3)nc(-n3c4ccccc4c4ccc(-c5ccc6c7ccccc7n(-c7nc(-c8ccccc8)cc(-c8ccccc8)n7)c6c5)cc43)n2)cc1 ; c1ccc(-c2nc(-c3ccccc3)nc(-c3cccc(-n4c5ccccc5c5cc(-c6ccc7c(c6)c6ccccc6n7-c6cccc(-c7nc(-c8ccccc8)nc(-c8ccccc8)n7)c6)ccc54)c3)n2)cc1 ; c1ccc(-c2cc(-n3c4ccccc4c4ccc(-c5ccc6c(c5)c5ccccc5n6-c5ccccc5)cc43)nc(-c3ccccc3)n2)cc1]

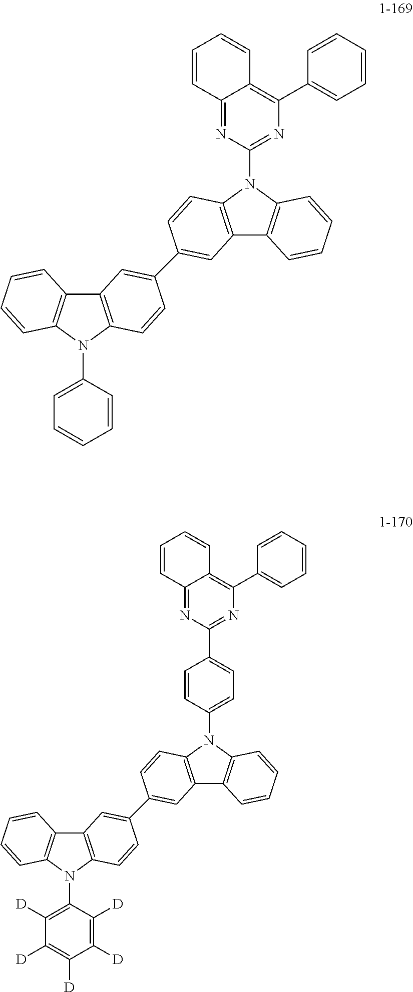 [SMILES: c1ccc(-c2nc(-n3c4ccccc4c4cc(-c5ccc6c(c5)c5ccccc5n6-c5ccccc5)ccc43)nc3ccccc23)cc1 ; [2H]c1c([2H])c([2H])c(-n2c3ccccc3c3cc(-c4ccc5c(c4)c4ccccc4n5-c4ccc(-c5nc(-c6ccccc6)c6ccccc6n5)cc4)ccc32)c([2H])c1[2H]]

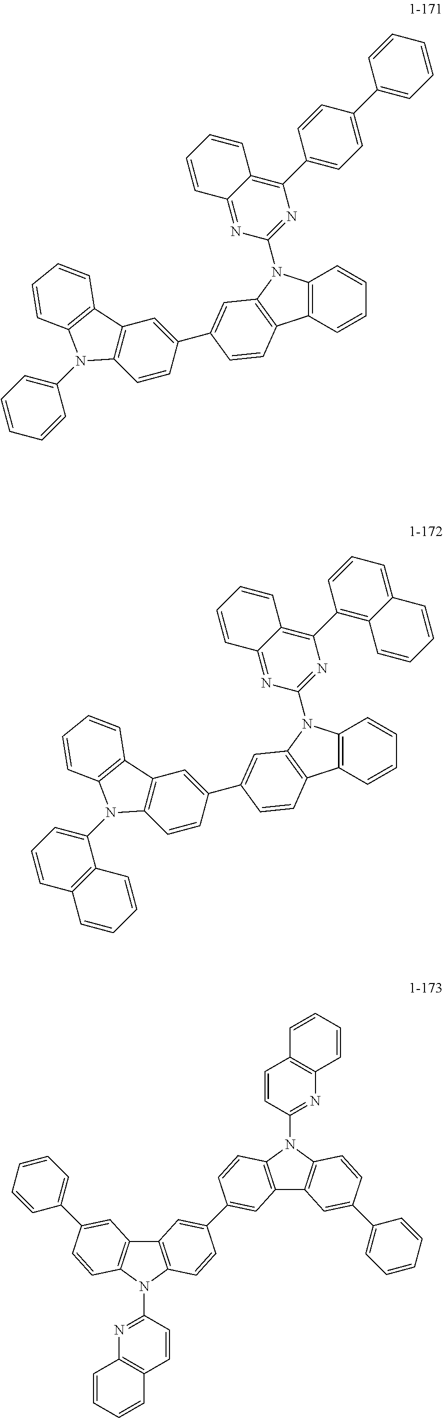 [SMILES: c1ccc(-c2ccc(-c3nc(-n4c5ccccc5c5ccc(-c6ccc7c(c6)c6ccccc6n7-c6ccccc6)cc54)nc4ccccc34)cc2)cc1 ; c1ccc2c(-c3nc(-n4c5ccccc5c5ccc(-c6ccc7c(c6)c6ccccc6n7-c6cccc7ccccc67)cc54)nc4ccccc34)cccc2c1 ; c1ccc(-c2ccc3c(c2)c2cc(-c4ccc5c(c4)c4cc(-c6ccccc6)ccc4n5-c4ccc5ccccc5n4)ccc2n3-c2ccc3ccccc3n2)cc1]

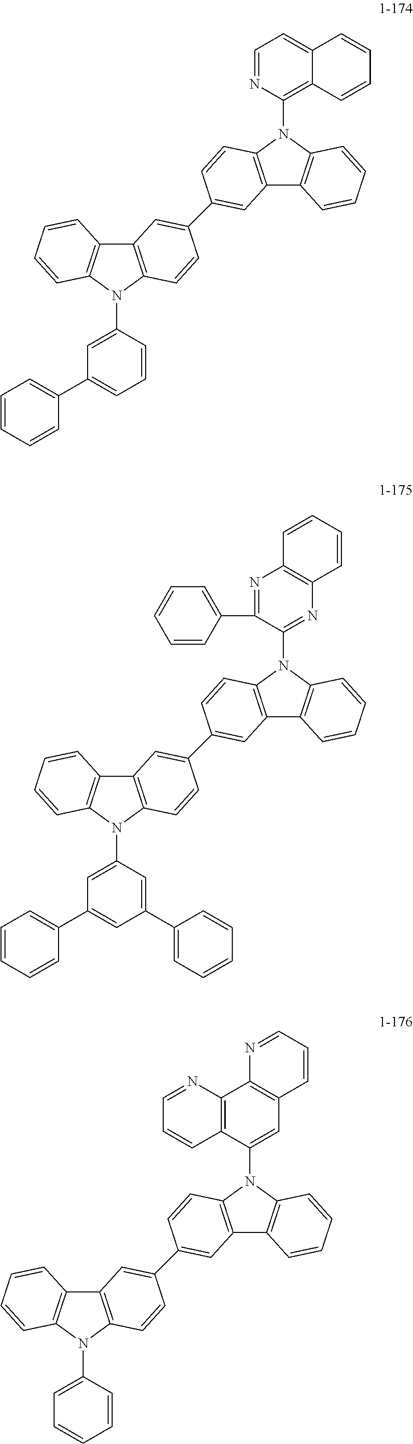 [SMILES: c1ccc(-c2cccc(-n3c4ccccc4c4cc(-c5ccc6c(c5)c5ccccc5n6-c5nccc6ccccc56)ccc43)c2)cc1 ; c1ccc(-c2cc(-c3ccccc3)cc(-n3c4ccccc4c4cc(-c5ccc6c(c5)c5ccccc5n6-c5nc6ccccc6nc5-c5ccccc5)ccc43)c2)cc1 ; c1ccc(-n2c3ccccc3c3cc(-c4ccc5c(c4)c4ccccc4n5-c4cc5cccnc5c5ncccc45)ccc32)cc1]

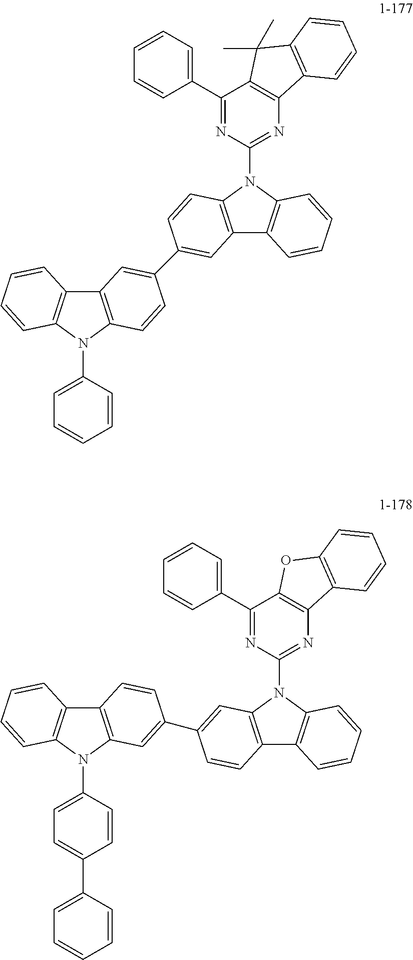 [SMILES: CC1(C)c2ccccc2-c2nc(-n3c4ccccc4c4cc(-c5ccc6c(c5)c5ccccc5n6-c5ccccc5)ccc43)nc(-c3ccccc3)c21 ; c1ccc(-c2ccc(-n3c4ccccc4c4ccc(-c5ccc6c7ccccc7n(-c7nc(-c8ccccc8)c8oc9ccccc9c8n7)c6c5)cc43)cc2)cc1]

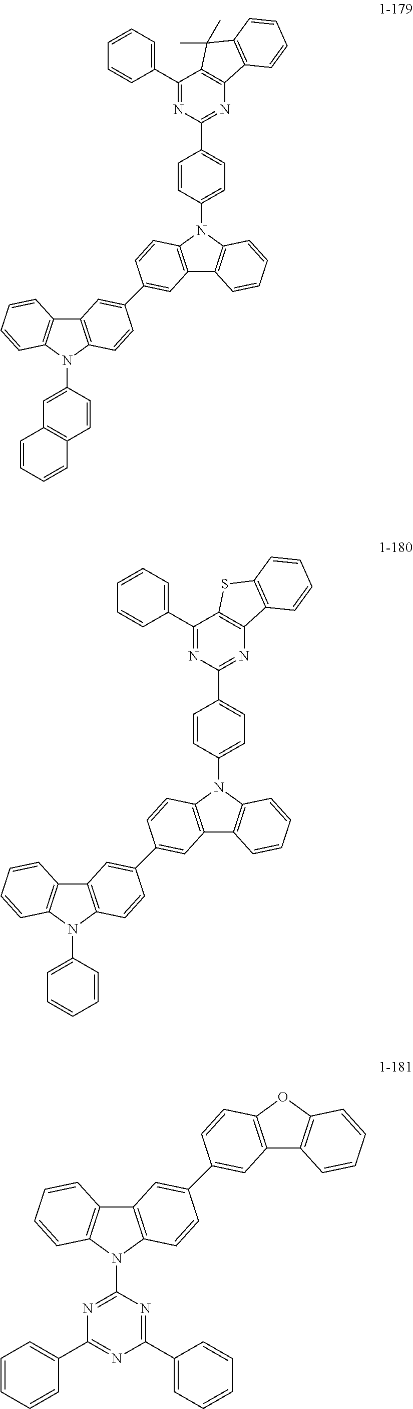 [SMILES: CC1(C)c2ccccc2-c2nc(-c3ccc(-n4c5ccccc5c5cc(-c6ccc7c(c6)c6ccccc6n7-c6ccc7ccccc7c6)ccc54)cc3)nc(-c3ccccc3)c21 ; c1ccc(-c2nc(-c3ccc(-n4c5ccccc5c5cc(-c6ccc7c(c6)c6ccccc6n7-c6ccccc6)ccc54)cc3)nc3c2sc2ccccc23)cc1 ; c1ccc(-c2nc(-c3ccccc3)nc(-n3c4ccccc4c4cc(-c5ccc6oc7ccccc7c6c5)ccc43)n2)cc1]

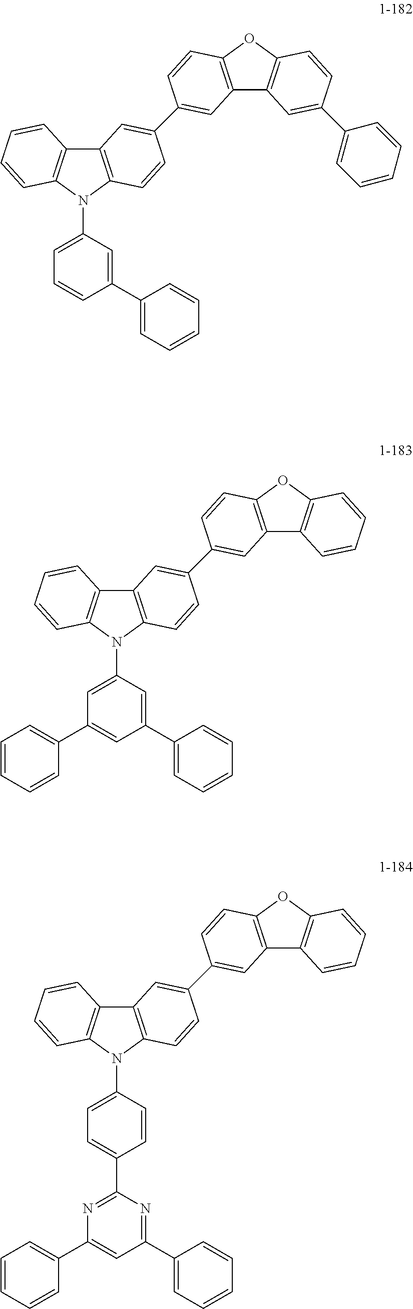 [SMILES: c1ccc(-c2cccc(-n3c4ccccc4c4cc(-c5ccc6oc7ccc(-c8ccccc8)cc7c6c5)ccc43)c2)cc1 ; c1ccc(-c2cc(-c3ccccc3)cc(-n3c4ccccc4c4cc(-c5ccc6oc7ccccc7c6c5)ccc43)c2)cc1 ; c1ccc(-c2cc(-c3ccccc3)nc(-c3ccc(-n4c5ccccc5c5cc(-c6ccc7oc8ccccc8c7c6)ccc54)cc3)n2)cc1]

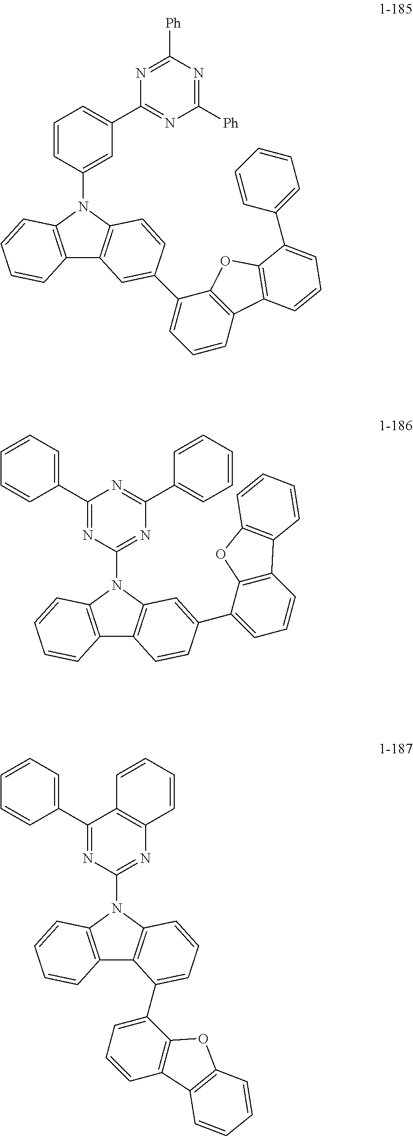 [SMILES: c1ccc(-c2nc(-c3ccccc3)nc(-c3cccc(-n4c5ccccc5c5cc(-c6cccc7c6oc6c(-c8ccccc8)cccc67)ccc54)c3)n2)cc1 ; c1ccc(-c2nc(-c3ccccc3)nc(-n3c4ccccc4c4ccc(-c5cccc6c5oc5ccccc56)cc43)n2)cc1 ; c1ccc(-c2nc(-n3c4ccccc4c4c(-c5cccc6c5oc5ccccc56)cccc43)nc3ccccc23)cc1]

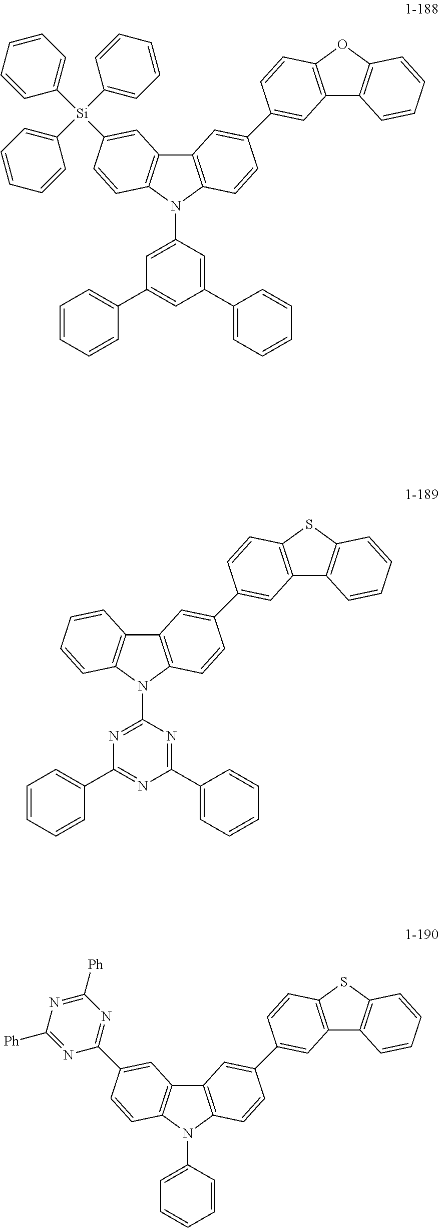 [SMILES: c1ccc(-c2cc(-c3ccccc3)cc(-n3c4ccc(-c5ccc6oc7ccccc7c6c5)cc4c4cc([Si](c5ccccc5)(c5ccccc5)c5ccccc5)ccc43)c2)cc1 ; c1ccc(-c2nc(-c3ccccc3)nc(-n3c4ccccc4c4cc(-c5ccc6sc7ccccc7c6c5)ccc43)n2)cc1 ; c1ccc(-c2nc(-c3ccccc3)nc(-c3ccc4c(c3)c3cc(-c5ccc6sc7ccccc7c6c5)ccc3n4-c3ccccc3)n2)cc1]

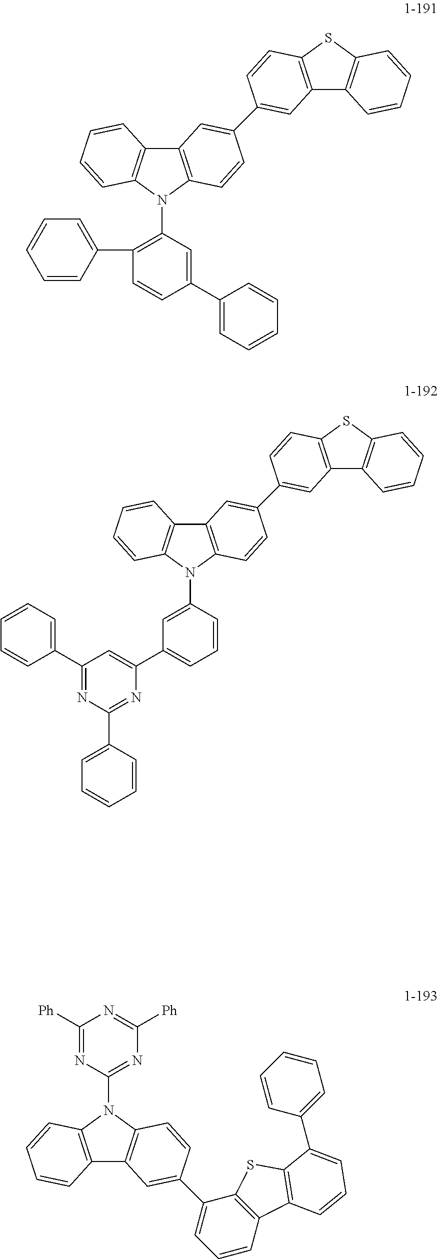 [SMILES: c1ccc(-c2ccc(-c3ccccc3)c(-n3c4ccccc4c4cc(-c5ccc6sc7ccccc7c6c5)ccc43)c2)cc1 ; c1ccc(-c2cc(-c3cccc(-n4c5ccccc5c5cc(-c6ccc7sc8ccccc8c7c6)ccc54)c3)nc(-c3ccccc3)n2)cc1 ; c1ccc(-c2nc(-c3ccccc3)nc(-n3c4ccccc4c4cc(-c5cccc6c5sc5c(-c7ccccc7)cccc56)ccc43)n2)cc1]

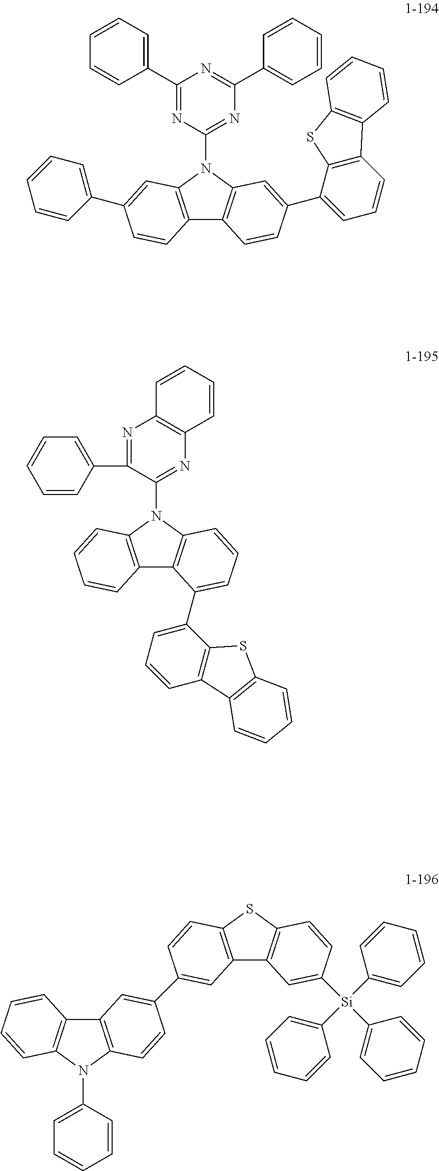 [SMILES: c1ccc(-c2ccc3c4ccc(-c5cccc6c5sc5ccccc56)cc4n(-c4nc(-c5ccccc5)nc(-c5ccccc5)n4)c3c2)cc1 ; c1ccc(-c2nc3ccccc3nc2-n2c3ccccc3c3c(-c4cccc5c4sc4ccccc45)cccc32)cc1 ; c1ccc(-n2c3ccccc3c3cc(-c4ccc5sc6ccc([Si](c7ccccc7)(c7ccccc7)c7ccccc7)cc6c5c4)ccc32)cc1]

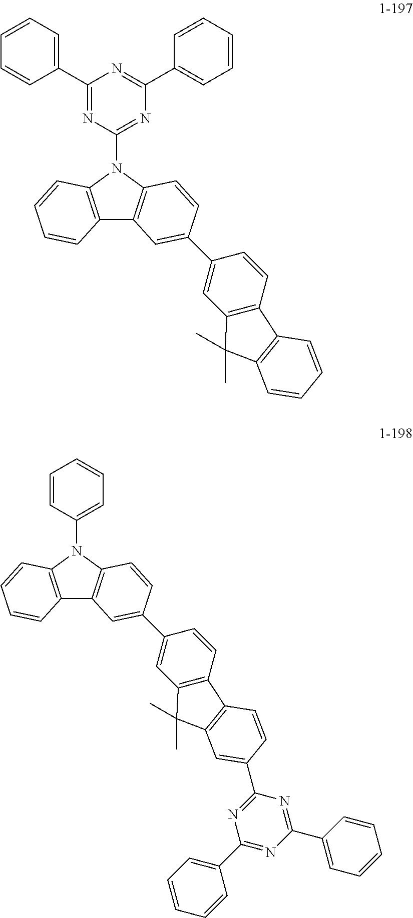 [SMILES: CC1(C)c2ccccc2-c2ccc(-c3ccc4c(c3)c3ccccc3n4-c3nc(-c4ccccc4)nc(-c4ccccc4)n3)cc21 ; CC1(C)c2cc(-c3ccc4c(c3)c3ccccc3n4-c3ccccc3)ccc2-c2ccc(-c3nc(-c4ccccc4)nc(-c4ccccc4)n3)cc21]

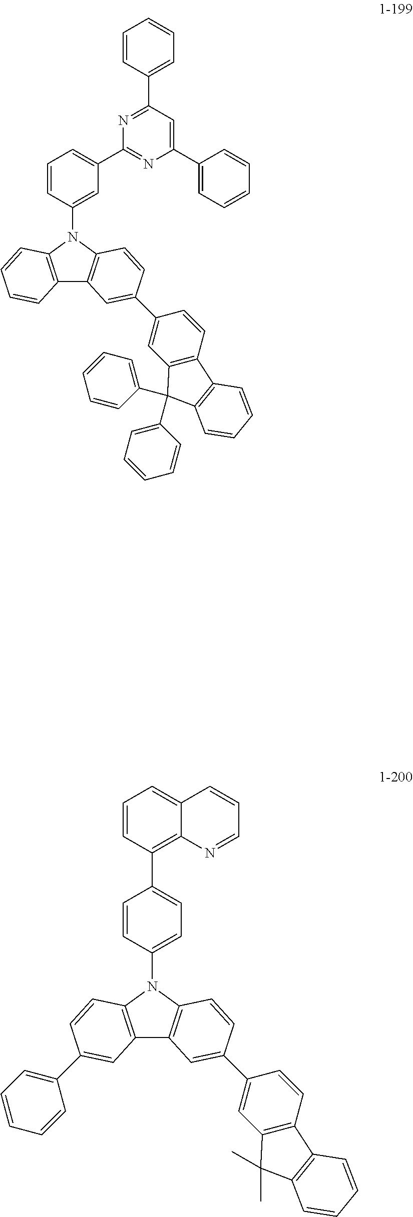 [SMILES: c1ccc(-c2cc(-c3ccccc3)nc(-c3cccc(-n4c5ccccc5c5cc(-c6ccc7c(c6)C(c6ccccc6)(c6ccccc6)c6ccccc6-7)ccc54)c3)n2)cc1 ; CC1(C)c2ccccc2-c2ccc(-c3ccc4c(c3)c3cc(-c5ccccc5)ccc3n4-c3ccc(-c4cccc5cccnc45)cc3)cc21]

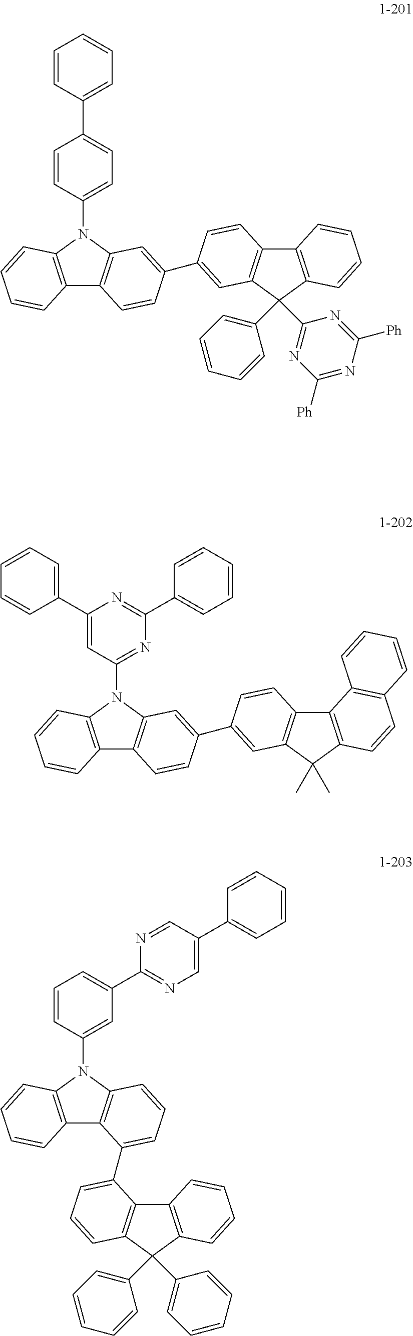 [SMILES: c1ccc(-c2ccc(-n3c4ccccc4c4ccc(-c5ccc6c(c5)C(c5ccccc5)(c5nc(-c7ccccc7)nc(-c7ccccc7)n5)c5ccccc5-6)cc43)cc2)cc1 ; CC1(C)c2cc(-c3ccc4c5ccccc5n(-c5cc(-c6ccccc6)nc(-c6ccccc6)n5)c4c3)ccc2-c2c1ccc1ccccc21 ; c1ccc(-c2cnc(-c3cccc(-n4c5ccccc5c5c(-c6cccc7c6-c6ccccc6C7(c6ccccc6)c6ccccc6)cccc54)c3)nc2)cc1]

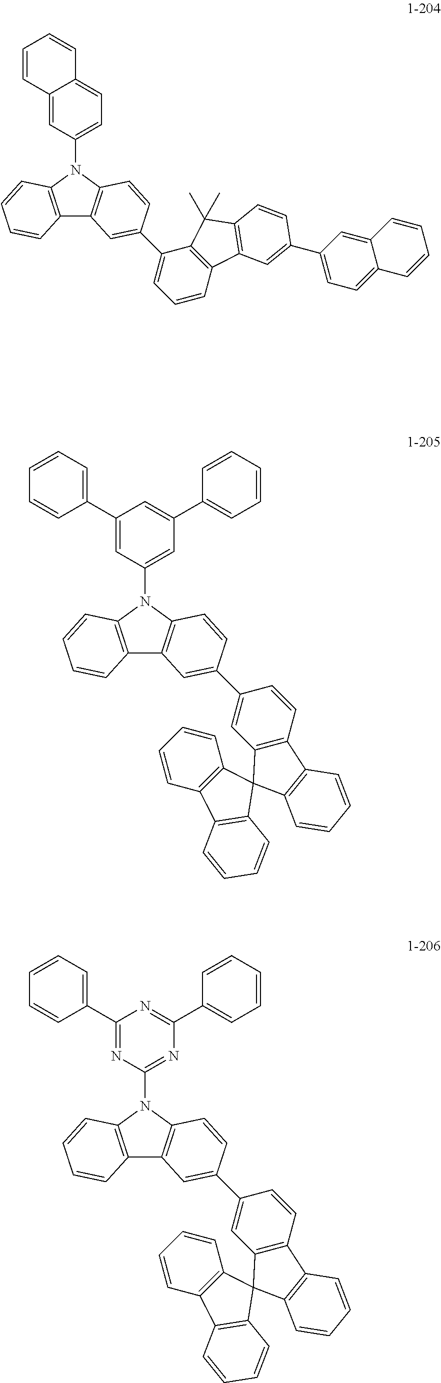 [SMILES: CC1(C)c2ccc(-c3ccc4ccccc4c3)cc2-c2cccc(-c3ccc4c(c3)c3ccccc3n4-c3ccc4ccccc4c3)c21 ; c1ccc(-c2cc(-c3ccccc3)cc(-n3c4ccccc4c4cc(-c5ccc6c(c5)C5(c7ccccc7-c7ccccc75)c5ccccc5-6)ccc43)c2)cc1 ; c1ccc(-c2nc(-c3ccccc3)nc(-n3c4ccccc4c4cc(-c5ccc6c(c5)C5(c7ccccc7-c7ccccc75)c5ccccc5-6)ccc43)n2)cc1]

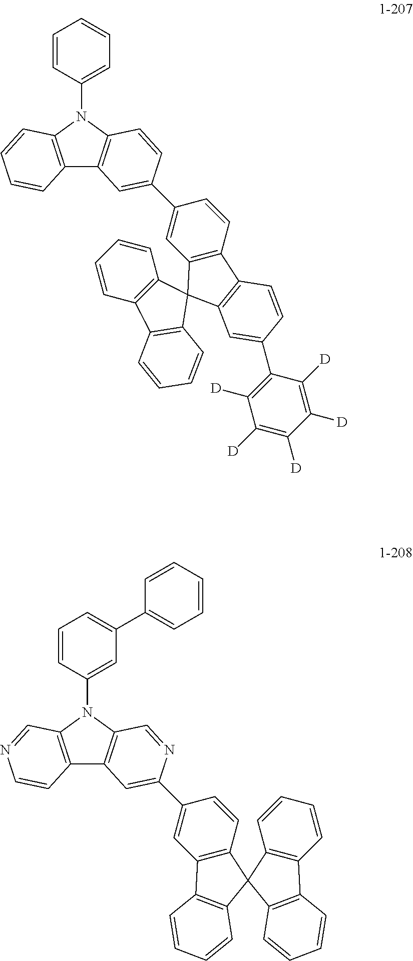 [SMILES: [2H]c1c([2H])c([2H])c(-c2ccc3c(c2)C2(c4ccccc4-c4ccccc42)c2cc(-c4ccc5c(c4)c4ccccc4n5-c4ccccc4)ccc2-3)c([2H])c1[2H] ; c1ccc(-c2cccc(-n3c4cnccc4c4cc(-c5ccc6c(c5)-c5ccccc5C65c6ccccc6-c6ccccc65)ncc43)c2)cc1]

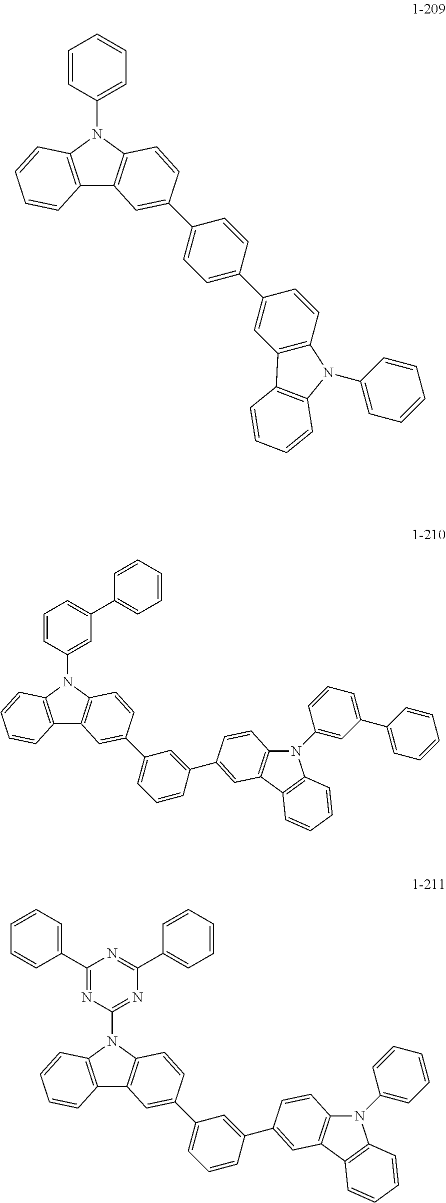 [SMILES: c1ccc(-n2c3ccccc3c3cc(-c4ccc(-c5ccc6c(c5)c5ccccc5n6-c5ccccc5)cc4)ccc32)cc1 ; c1ccc(-c2cccc(-n3c4ccccc4c4cc(-c5cccc(-c6ccc7c(c6)c6ccccc6n7-c6cccc(-c7ccccc7)c6)c5)ccc43)c2)cc1 ; c1ccc(-c2nc(-c3ccccc3)nc(-n3c4ccccc4c4cc(-c5cccc(-c6ccc7c(c6)c6ccccc6n7-c6ccccc6)c5)ccc43)n2)cc1]

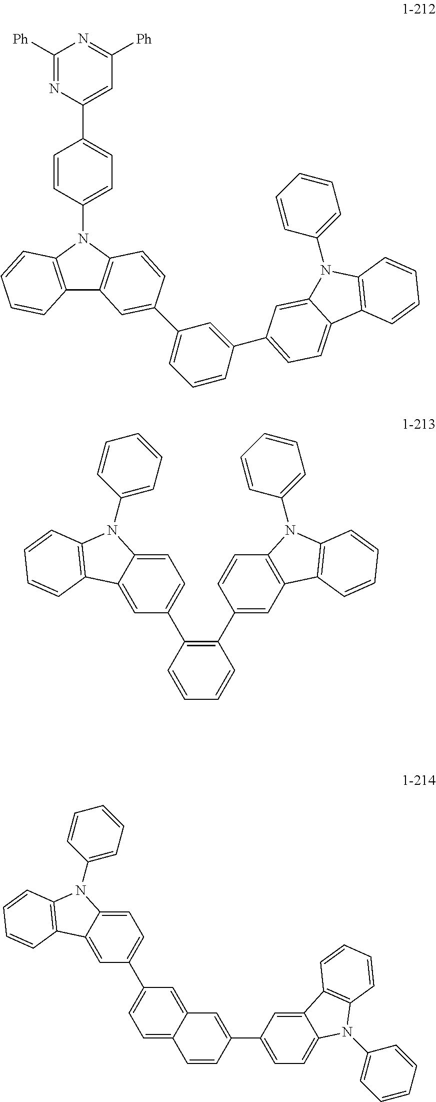 [SMILES: c1ccc(-c2cc(-c3ccc(-n4c5ccccc5c5cc(-c6cccc(-c7ccc8c9ccccc9n(-c9ccccc9)c8c7)c6)ccc54)cc3)nc(-c3ccccc3)n2)cc1 ; c1ccc(-n2c3ccccc3c3cc(-c4ccccc4-c4ccc5c(c4)c4ccccc4n5-c4ccccc4)ccc32)cc1 ; c1ccc(-n2c3ccccc3c3cc(-c4ccc5ccc(-c6ccc7c(c6)c6ccccc6n7-c6ccccc6)cc5c4)ccc32)cc1]

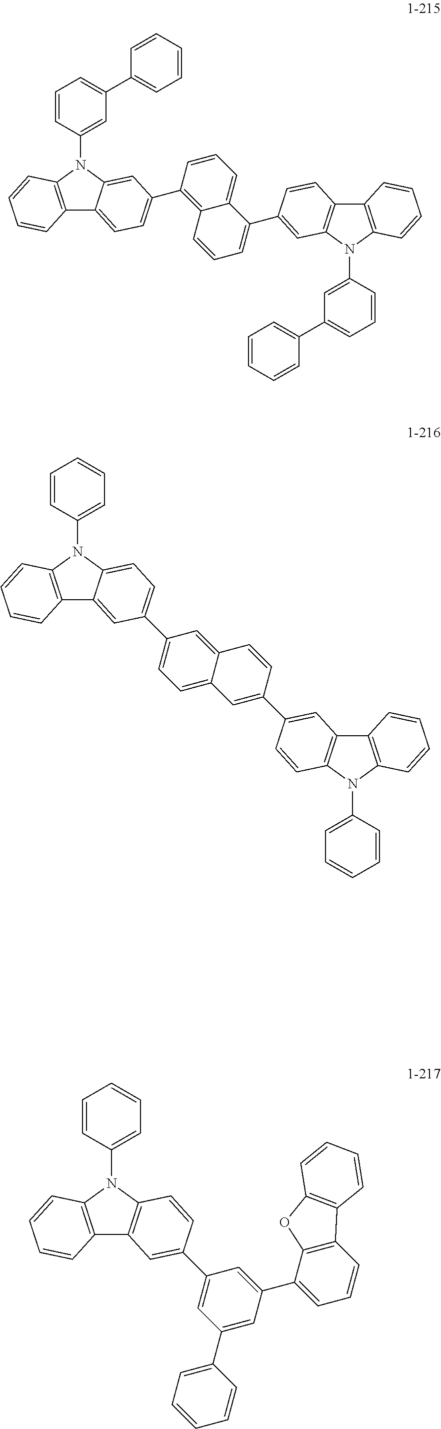 [SMILES: c1ccc(-c2cccc(-n3c4ccccc4c4ccc(-c5cccc6c(-c7ccc8c9ccccc9n(-c9cccc(-c%10ccccc%10)c9)c8c7)cccc56)cc43)c2)cc1 ; c1ccc(-n2c3ccccc3c3cc(-c4ccc5cc(-c6ccc7c(c6)c6ccccc6n7-c6ccccc6)ccc5c4)ccc32)cc1 ; c1ccc(-c2cc(-c3ccc4c(c3)c3ccccc3n4-c3ccccc3)cc(-c3cccc4c3oc3ccccc34)c2)cc1]

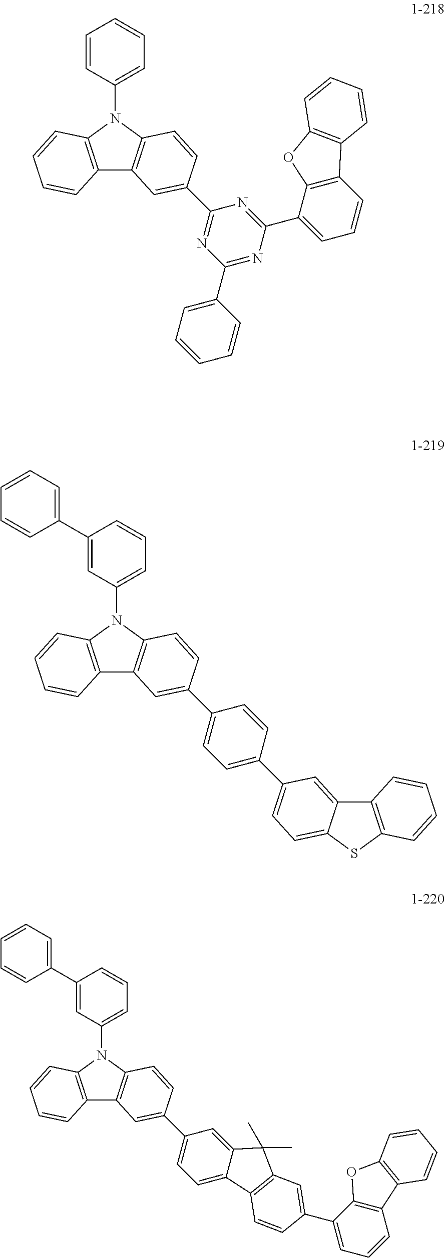 [SMILES: c1ccc(-c2nc(-c3ccc4c(c3)c3ccccc3n4-c3ccccc3)nc(-c3cccc4c3oc3ccccc34)n2)cc1 ; c1ccc(-c2cccc(-n3c4ccccc4c4cc(-c5ccc(-c6ccc7sc8ccccc8c7c6)cc5)ccc43)c2)cc1 ; CC1(C)c2cc(-c3ccc4c(c3)c3ccccc3n4-c3cccc(-c4ccccc4)c3)ccc2-c2ccc(-c3cccc4c3oc3ccccc34)cc21]

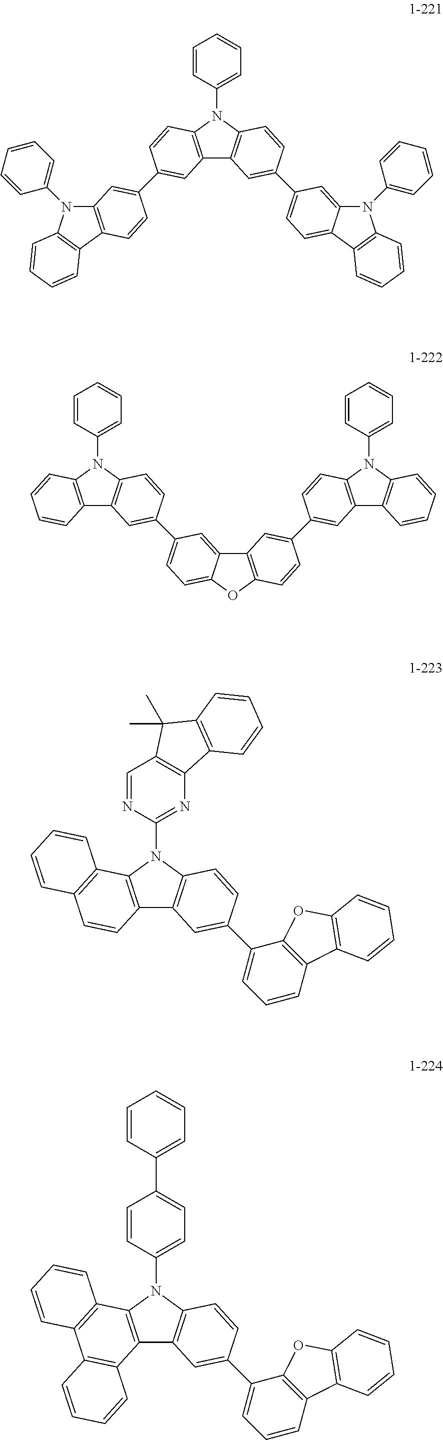 [SMILES: c1ccc(-n2c3ccc(-c4ccc5c6ccccc6n(-c6ccccc6)c5c4)cc3c3cc(-c4ccc5c6ccccc6n(-c6ccccc6)c5c4)ccc32)cc1 ; c1ccc(-n2c3ccccc3c3cc(-c4ccc5oc6ccc(-c7ccc8c(c7)c7ccccc7n8-c7ccccc7)cc6c5c4)ccc32)cc1 ; CC1(C)c2ccccc2-c2nc(-n3c4ccc(-c5cccc6c5oc5ccccc56)cc4c4ccc5ccccc5c43)ncc21 ; c1ccc(-c2ccc(-n3c4ccc(-c5cccc6c5oc5ccccc56)cc4c4c5ccccc5c5ccccc5c43)cc2)cc1]

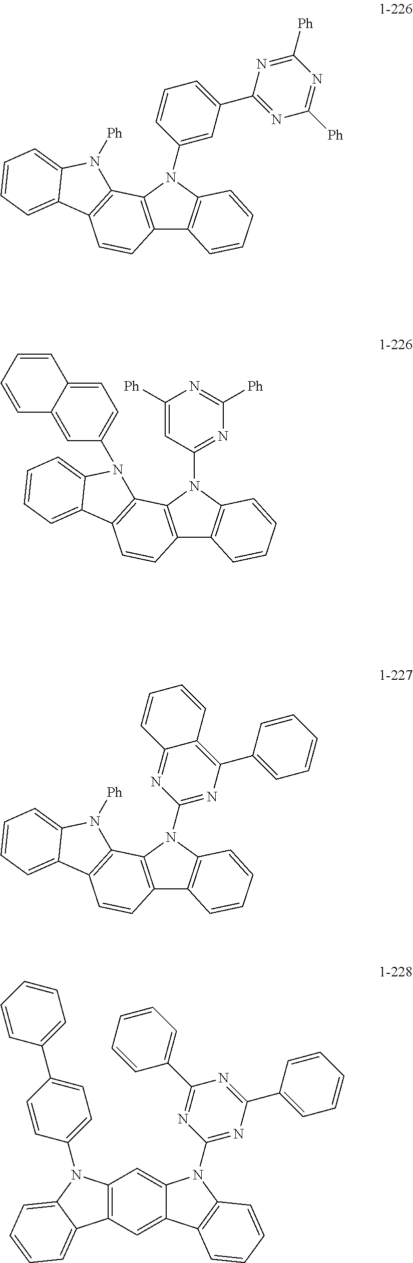 [SMILES: c1ccc(-c2nc(-c3ccccc3)nc(-c3cccc(-n4c5ccccc5c5ccc6c7ccccc7n(-c7ccccc7)c6c54)c3)n2)cc1 ; c1ccc(-c2cc(-n3c4ccccc4c4ccc5c6ccccc6n(-c6ccc7ccccc7c6)c5c43)nc(-c3ccccc3)n2)cc1 ; c1ccc(-c2nc(-n3c4ccccc4c4ccc5c6ccccc6n(-c6ccccc6)c5c43)nc3ccccc23)cc1 ; c1ccc(-c2ccc(-n3c4ccccc4c4cc5c6ccccc6n(-c6nc(-c7ccccc7)nc(-c7ccccc7)n6)c5cc43)cc2)cc1]

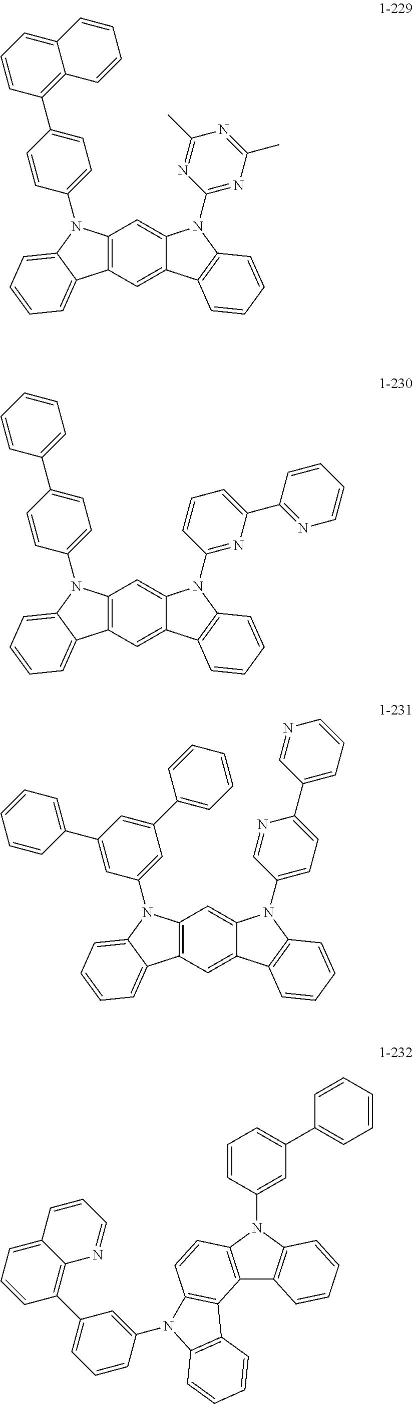 [SMILES: Cc1nc(C)nc(-n2c3ccccc3c3cc4c5ccccc5n(-c5ccc(-c6cccc7ccccc67)cc5)c4cc32)n1 ; c1ccc(-c2ccc(-n3c4ccccc4c4cc5c6ccccc6n(-c6cccc(-c7ccccn7)n6)c5cc43)cc2)cc1 ; c1ccc(-c2cc(-c3ccccc3)cc(-n3c4ccccc4c4cc5c6ccccc6n(-c6ccc(-c7cccnc7)nc6)c5cc43)c2)cc1 ; c1ccc(-c2cccc(-n3c4ccccc4c4c5c6ccccc6n(-c6cccc(-c7cccc8cccnc78)c6)c5ccc43)c2)cc1]

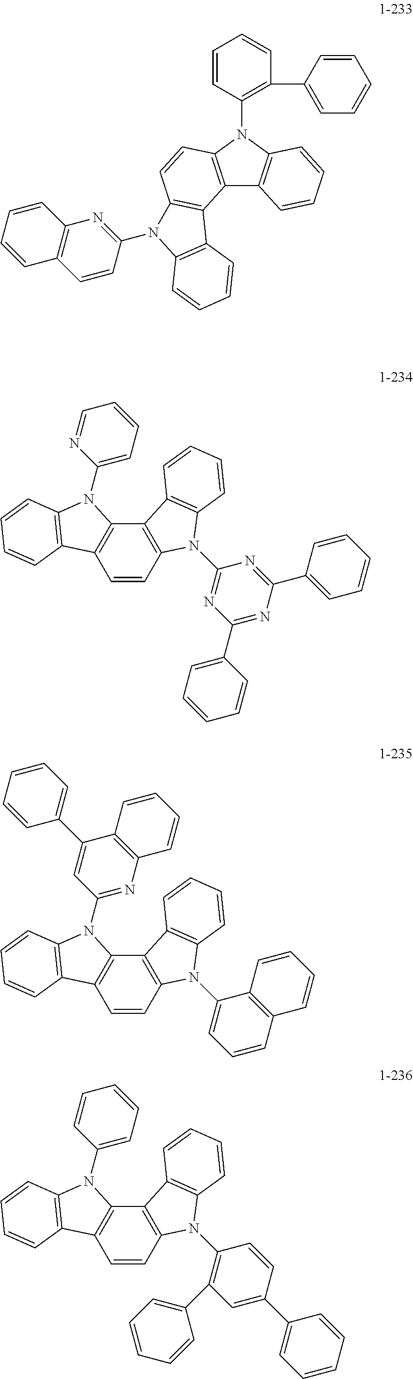 [SMILES: c1ccc(-c2ccccc2-n2c3ccccc3c3c4c5ccccc5n(-c5ccc6ccccc6n5)c4ccc32)cc1 ; c1ccc(-c2nc(-c3ccccc3)nc(-n3c4ccccc4c4c3ccc3c5ccccc5n(-c5ccccn5)c34)n2)cc1 ; c1ccc(-c2cc(-n3c4ccccc4c4ccc5c(c6ccccc6n5-c5cccc6ccccc56)c43)nc3ccccc23)cc1 ; c1ccc(-c2ccc(-n3c4ccccc4c4c3ccc3c5ccccc5n(-c5ccccc5)c34)c(-c3ccccc3)c2)cc1]

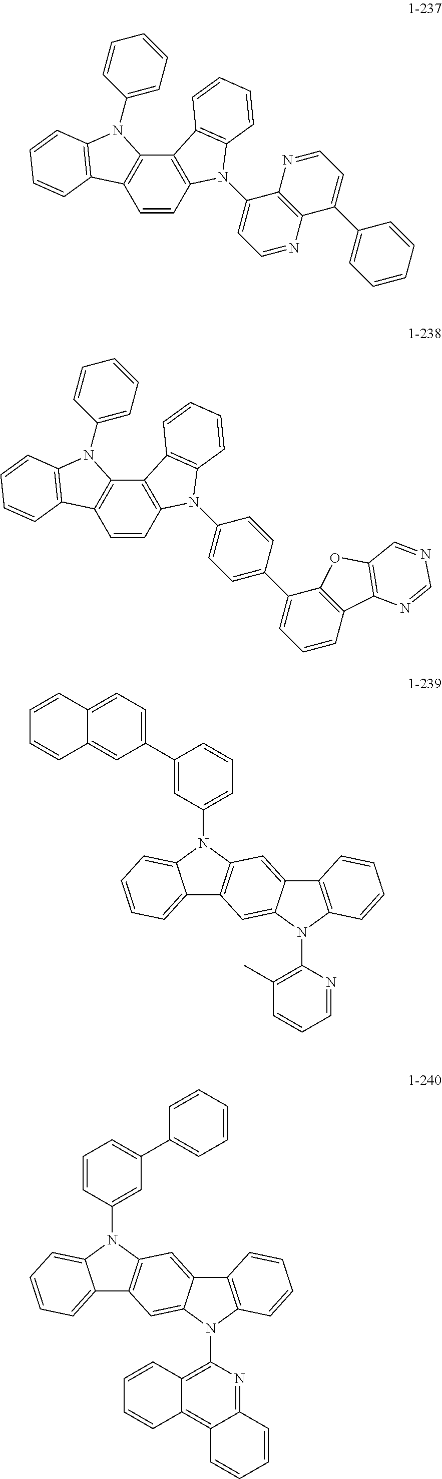 [SMILES: c1ccc(-c2ccnc3c(-n4c5ccccc5c5c4ccc4c6ccccc6n(-c6ccccc6)c45)ccnc23)cc1 ; c1ccc(-n2c3ccccc3c3ccc4c(c5ccccc5n4-c4ccc(-c5cccc6c5oc5cncnc56)cc4)c32)cc1 ; Cc1cccnc1-n1c2ccccc2c2cc3c(cc21)c1ccccc1n3-c1cccc(-c2ccc3ccccc3c2)c1 ; c1ccc(-c2cccc(-n3c4ccccc4c4cc5c(cc43)c3ccccc3n5-c3nc4ccccc4c4ccccc34)c2)cc1]

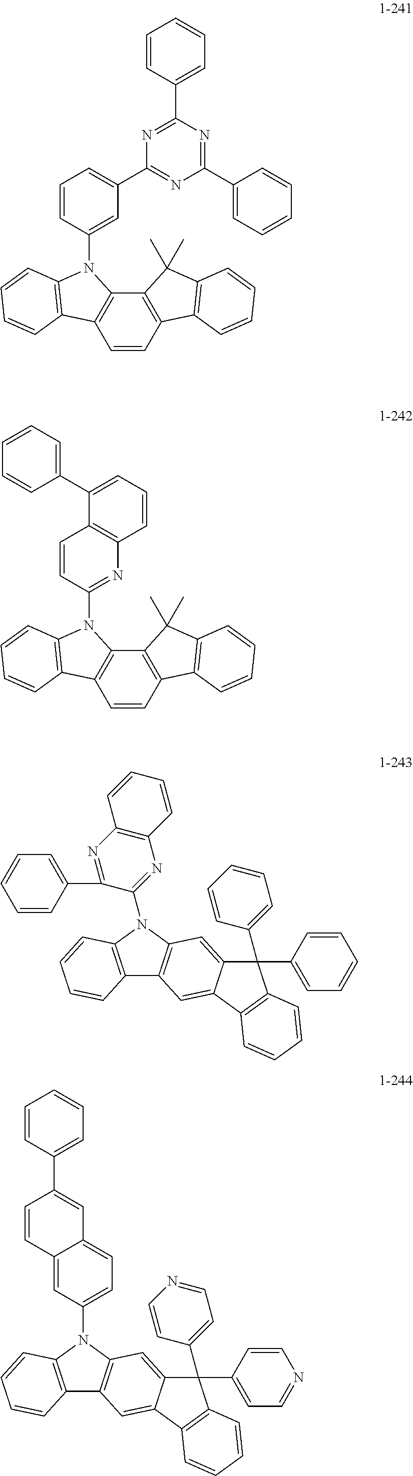 [SMILES: CC1(C)c2ccccc2-c2ccc3c4ccccc4n(-c4cccc(-c5nc(-c6ccccc6)nc(-c6ccccc6)n5)c4)c3c21 ; CC1(C)c2ccccc2-c2ccc3c4ccccc4n(-c4ccc5c(-c6ccccc6)cccc5n4)c3c21 ; c1ccc(-c2nc3ccccc3nc2-n2c3ccccc3c3cc4c(cc32)C(c2ccccc2)(c2ccccc2)c2ccccc2-4)cc1 ; c1ccc(-c2ccc3cc(-n4c5ccccc5c5cc6c(cc54)C(c4ccncc4)(c4ccncc4)c4ccccc4-6)ccc3c2)cc1]

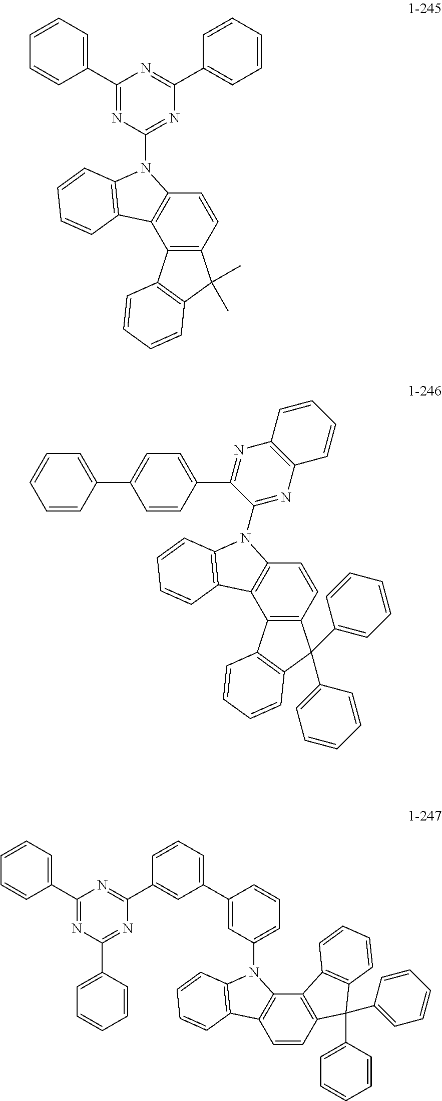 [SMILES: CC1(C)c2ccccc2-c2c1ccc1c2c2ccccc2n1-c1nc(-c2ccccc2)nc(-c2ccccc2)n1 ; c1ccc(-c2ccc(-c3nc4ccccc4nc3-n3c4ccccc4c4c5c(ccc43)C(c3ccccc3)(c3ccccc3)c3ccccc3-5)cc2)cc1 ; c1ccc(-c2nc(-c3ccccc3)nc(-c3cccc(-c4cccc(-n5c6ccccc6c6ccc7c(c65)-c5ccccc5C7(c5ccccc5)c5ccccc5)c4)c3)n2)cc1]

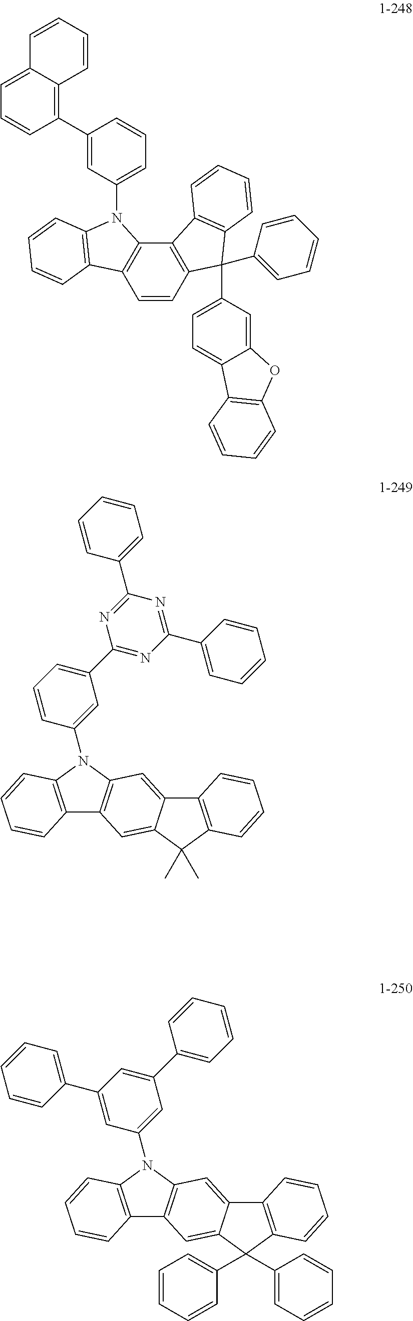 [SMILES: c1ccc(C2(c3ccc4c(c3)oc3ccccc34)c3ccccc3-c3c2ccc2c4ccccc4n(-c4cccc(-c5cccc6ccccc56)c4)c32)cc1 ; CC1(C)c2ccccc2-c2cc3c(cc21)c1ccccc1n3-c1cccc(-c2nc(-c3ccccc3)nc(-c3ccccc3)n2)c1 ; c1ccc(-c2cc(-c3ccccc3)cc(-n3c4ccccc4c4cc5c(cc43)-c3ccccc3C5(c3ccccc3)c3ccccc3)c2)cc1]

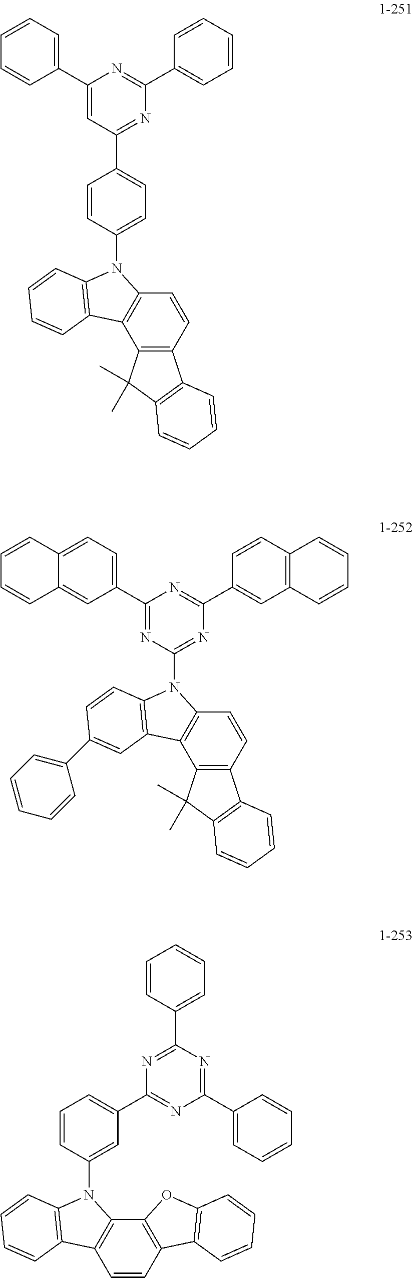 [SMILES: CC1(C)c2ccccc2-c2ccc3c(c21)c1ccccc1n3-c1ccc(-c2cc(-c3ccccc3)nc(-c3ccccc3)n2)cc1 ; CC1(C)c2ccccc2-c2ccc3c(c21)c1cc(-c2ccccc2)ccc1n3-c1nc(-c2ccc3ccccc3c2)nc(-c2ccc3ccccc3c2)n1 ; c1ccc(-c2nc(-c3ccccc3)nc(-c3cccc(-n4c5ccccc5c5ccc6c7ccccc7oc6c54)c3)n2)cc1]

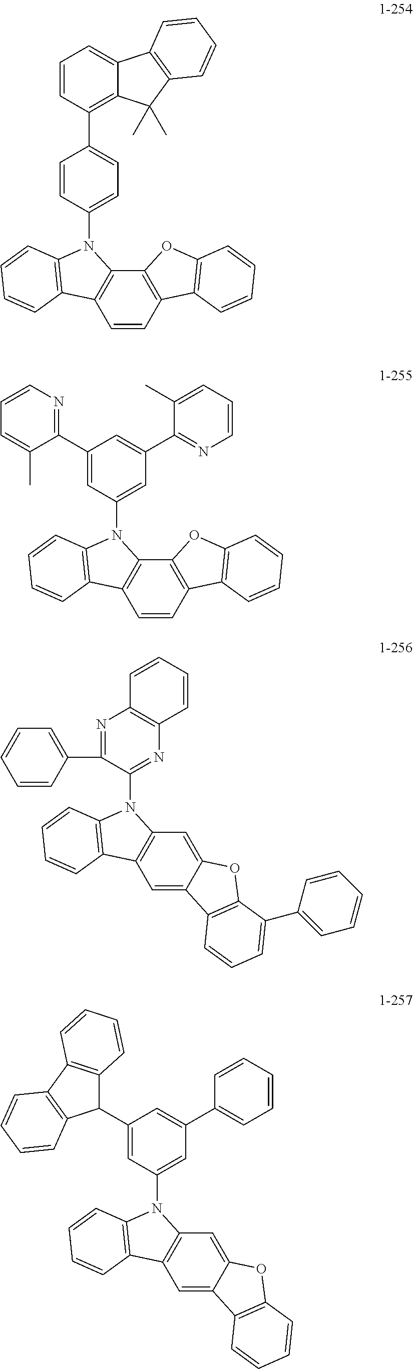

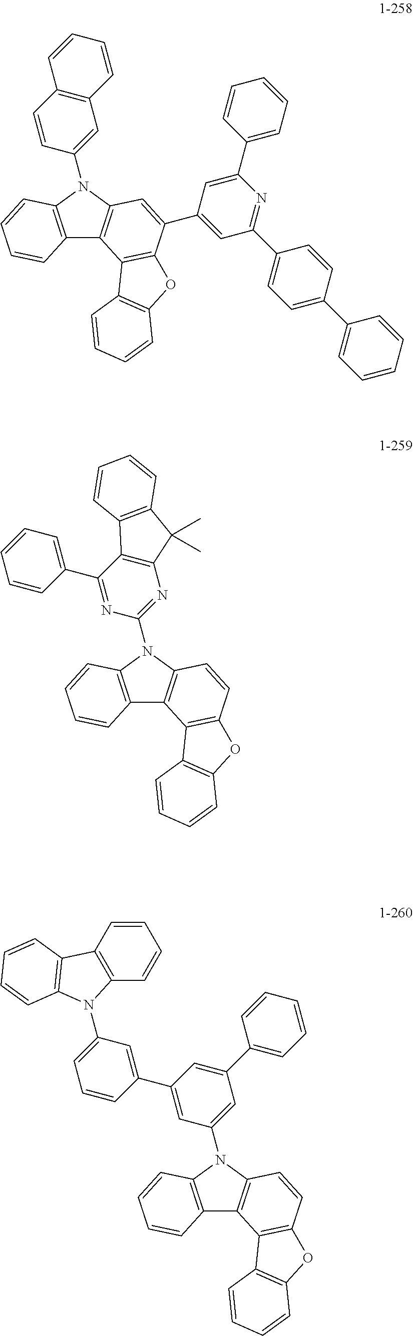 [SMILES: c1ccc(-c2ccc(-c3cc(-c4cc5c(c6ccccc6n5-c5ccc6ccccc6c5)c5c4oc4ccccc45)cc(-c4ccccc4)n3)cc2)cc1 ; CC1(C)c2ccccc2-c2c(-c3ccccc3)nc(-n3c4ccccc4c4c5c(ccc43)oc3ccccc35)nc21 ; c1ccc(-c2cc(-c3cccc(-n4c5ccccc5c5ccccc54)c3)cc(-n3c4ccccc4c4c5c(ccc43)oc3ccccc35)c2)cc1]

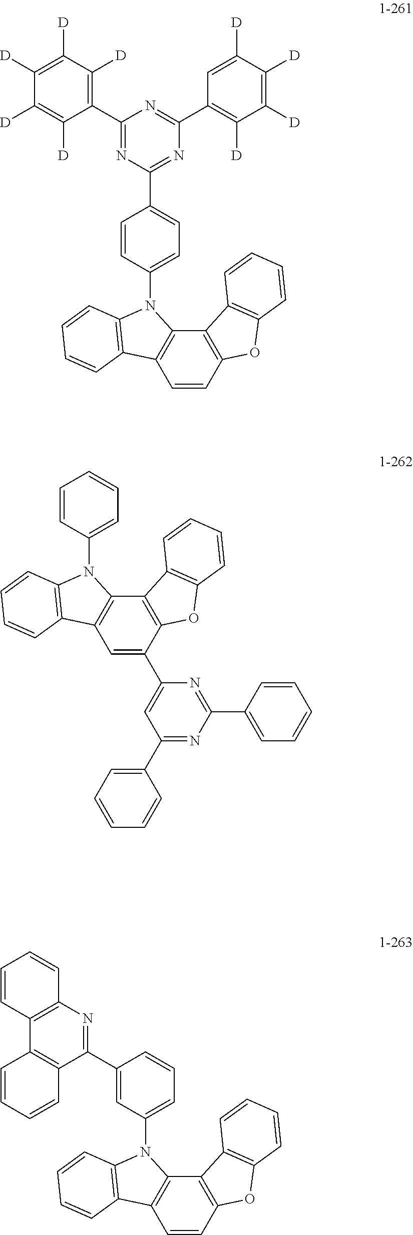 [SMILES: [2H]c1cc(-c2nc(-c3ccc(-n4c5ccccc5c5ccc6oc7ccccc7c6c54)cc3)nc(-c3c([2H])c([2H])c([2H])c([2H])c3[2H])n2)c([2H])c([2H])c1[2H] ; c1ccc(-c2cc(-c3cc4c5ccccc5n(-c5ccccc5)c4c4c3oc3ccccc34)nc(-c3ccccc3)n2)cc1 ; c1cc(-c2nc3ccccc3c3ccccc23)cc(-n2c3ccccc3c3ccc4oc5ccccc5c4c32)c1]

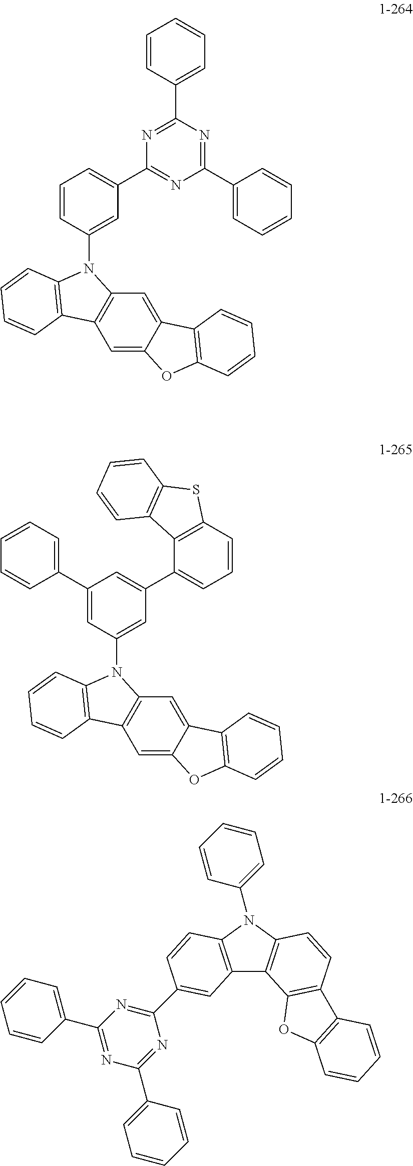 [SMILES: c1ccc(-c2nc(-c3ccccc3)nc(-c3cccc(-n4c5ccccc5c5cc6oc7ccccc7c6cc54)c3)n2)cc1 ; c1ccc(-c2cc(-c3cccc4sc5ccccc5c34)cc(-n3c4ccccc4c4cc5oc6ccccc6c5cc43)c2)cc1 ; c1ccc(-c2nc(-c3ccccc3)nc(-c3ccc4c(c3)c3c5oc6ccccc6c5ccc3n4-c3ccccc3)n2)cc1]

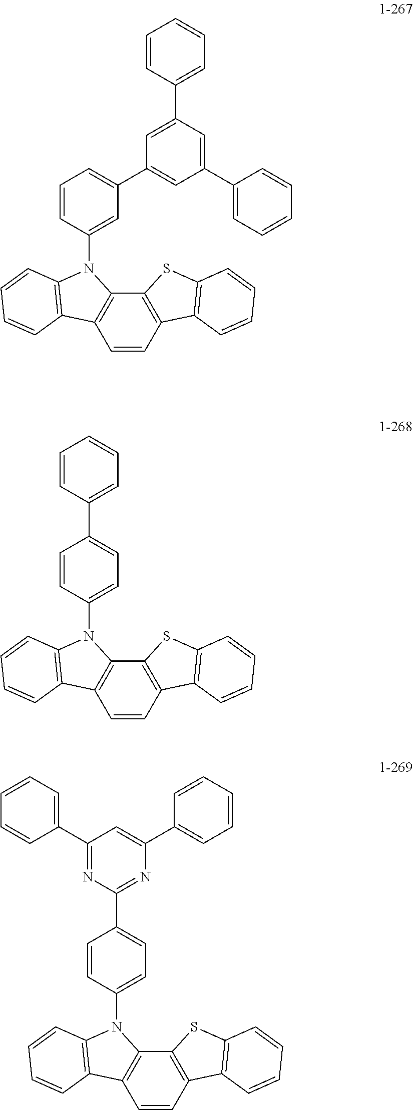 [SMILES: c1ccc(-c2cc(-c3ccccc3)cc(-c3cccc(-n4c5ccccc5c5ccc6c7ccccc7sc6c54)c3)c2)cc1 ; c1ccc(-c2ccc(-n3c4ccccc4c4ccc5c6ccccc6sc5c43)cc2)cc1 ; c1ccc(-c2cc(-c3ccccc3)nc(-c3ccc(-n4c5ccccc5c5ccc6c7ccccc7sc6c54)cc3)n2)cc1]

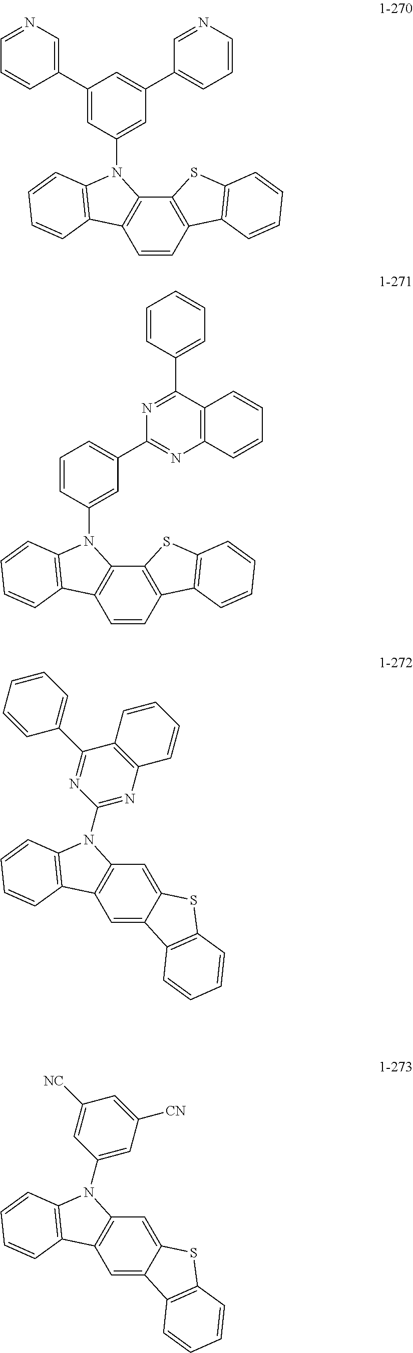

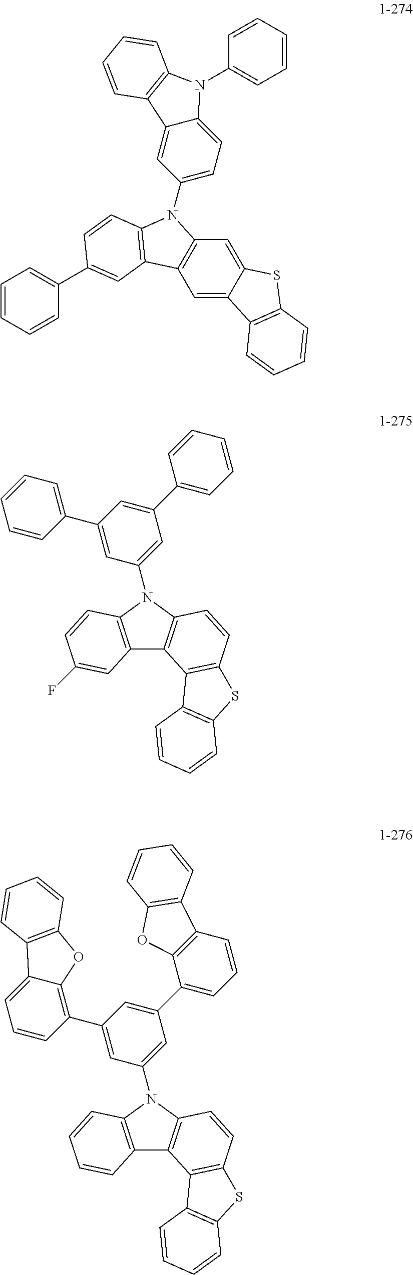 [SMILES: c1ccc(-c2ccc3c(c2)c2cc4c(cc2n3-c2ccc3c(c2)c2ccccc2n3-c2ccccc2)sc2ccccc24)cc1 ; Fc1ccc2c(c1)c1c3c(ccc1n2-c1cc(-c2ccccc2)cc(-c2ccccc2)c1)sc1ccccc13 ; c1ccc2c(c1)oc1c(-c3cc(-c4cccc5c4oc4ccccc45)cc(-n4c5ccccc5c5c6c(ccc54)sc4ccccc46)c3)cccc12]

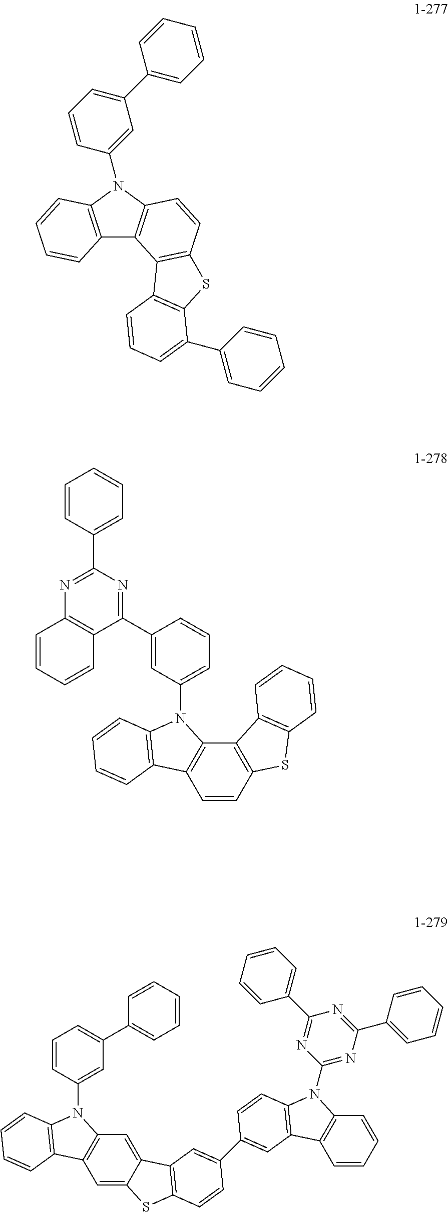 [SMILES: c1ccc(-c2cccc(-n3c4ccccc4c4c5c(ccc43)sc3c(-c4ccccc4)cccc35)c2)cc1 ; c1ccc(-c2nc(-c3cccc(-n4c5ccccc5c5ccc6sc7ccccc7c6c54)c3)c3ccccc3n2)cc1 ; c1ccc(-c2cccc(-n3c4ccccc4c4cc5sc6ccc(-c7ccc8c(c7)c7ccccc7n8-c7nc(-c8ccccc8)nc(-c8ccccc8)n7)cc6c5cc43)c2)cc1]

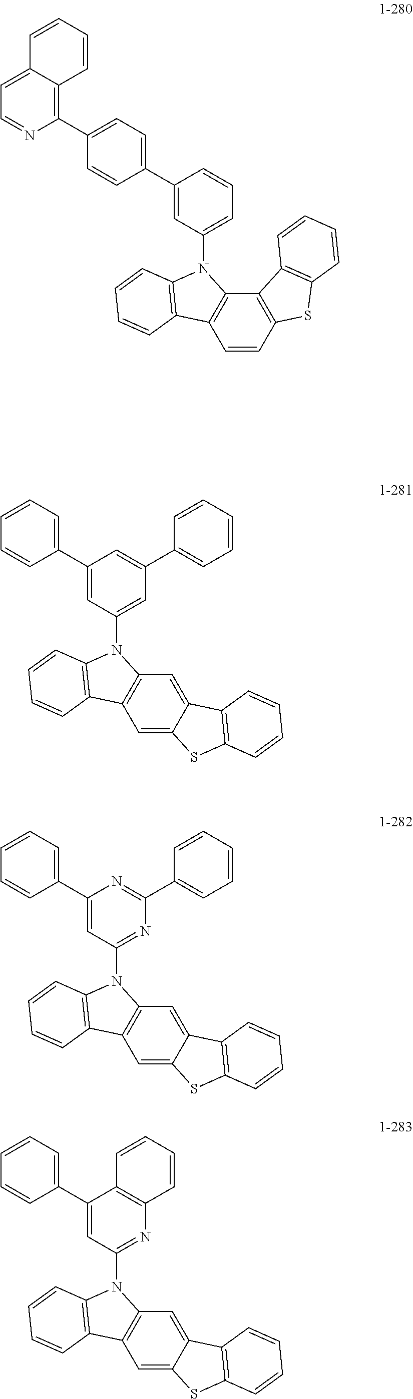 [SMILES: c1cc(-c2ccc(-c3nccc4ccccc34)cc2)cc(-n2c3ccccc3c3ccc4sc5ccccc5c4c32)c1 ; c1ccc(-c2cc(-c3ccccc3)cc(-n3c4ccccc4c4cc5sc6ccccc6c5cc43)c2)cc1 ; c1ccc(-c2cc(-n3c4ccccc4c4cc5sc6ccccc6c5cc43)nc(-c3ccccc3)n2)cc1 ; c1ccc(-c2cc(-n3c4ccccc4c4cc5sc6ccccc6c5cc43)nc3ccccc23)cc1]

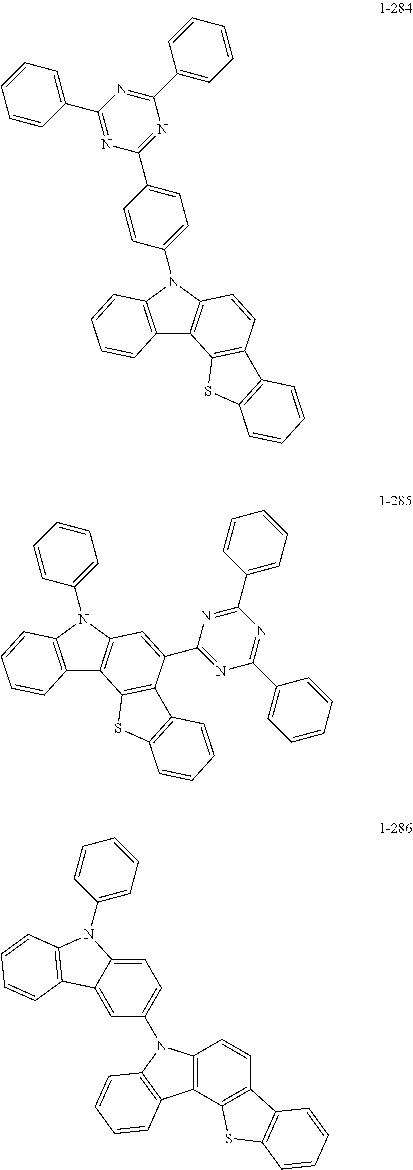 [SMILES: c1ccc(-c2nc(-c3ccccc3)nc(-c3ccc(-n4c5ccccc5c5c6sc7ccccc7c6ccc54)cc3)n2)cc1 ; c1ccc(-c2nc(-c3ccccc3)nc(-c3cc4c(c5ccccc5n4-c4ccccc4)c4sc5ccccc5c34)n2)cc1 ; c1ccc(-n2c3ccccc3c3cc(-n4c5ccccc5c5c6sc7ccccc7c6ccc54)ccc32)cc1]

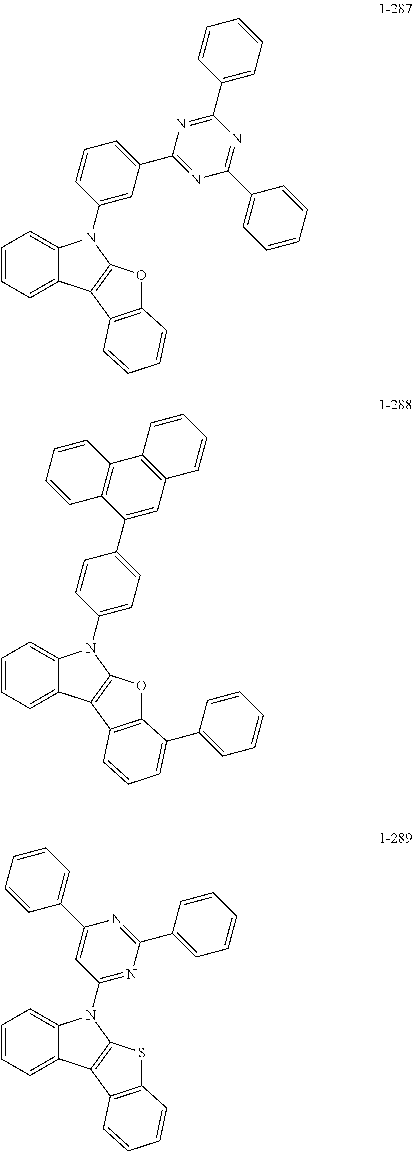 [SMILES: c1ccc(-c2nc(-c3ccccc3)nc(-c3cccc(-n4c5ccccc5c5c6ccccc6oc54)c3)n2)cc1 ; c1ccc(-c2cccc3c2oc2c3c3ccccc3n2-c2ccc(-c3cc4ccccc4c4ccccc34)cc2)cc1 ; c1ccc(-c2cc(-n3c4ccccc4c4c5ccccc5sc43)nc(-c3ccccc3)n2)cc1]

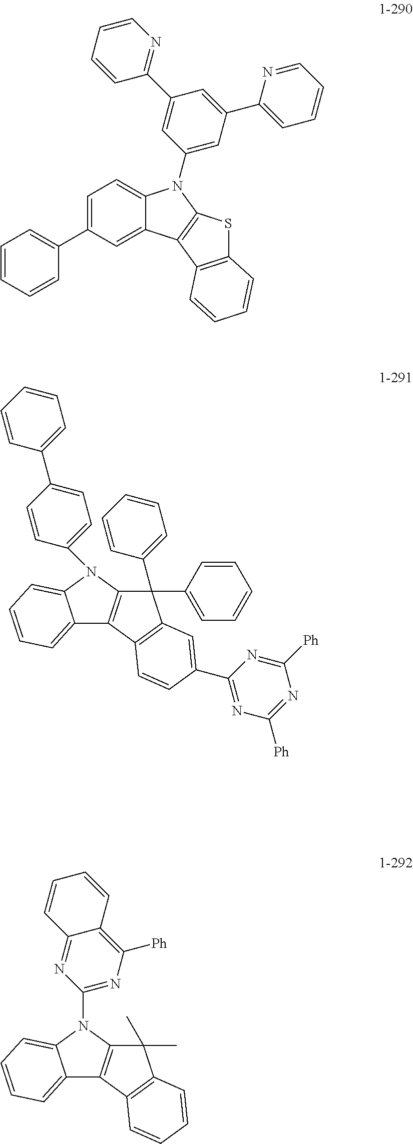 [SMILES: c1ccc(-c2ccc3c(c2)c2c4ccccc4sc2n3-c2cc(-c3ccccn3)cc(-c3ccccn3)c2)cc1 ; c1ccc(-c2ccc(-n3c4c(c5ccccc53)-c3ccc(-c5nc(-c6ccccc6)nc(-c6ccccc6)n5)cc3C4(c3ccccc3)c3ccccc3)cc2)cc1 ; CC1(C)c2ccccc2-c2c1n(-c1nc(-c3ccccc3)c3ccccc3n1)c1ccccc21]

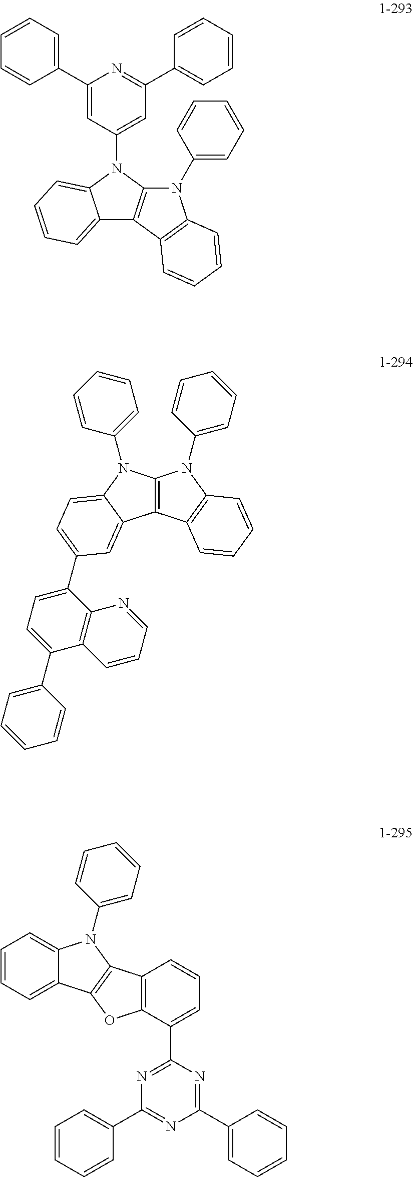 [SMILES: c1ccc(-c2cc(-n3c4ccccc4c4c5ccccc5n(-c5ccccc5)c43)cc(-c3ccccc3)n2)cc1 ; c1ccc(-c2ccc(-c3ccc4c(c3)c3c5ccccc5n(-c5ccccc5)c3n4-c3ccccc3)c3ncccc23)cc1 ; c1ccc(-c2nc(-c3ccccc3)nc(-c3cccc4c3oc3c5ccccc5n(-c5ccccc5)c43)n2)cc1]

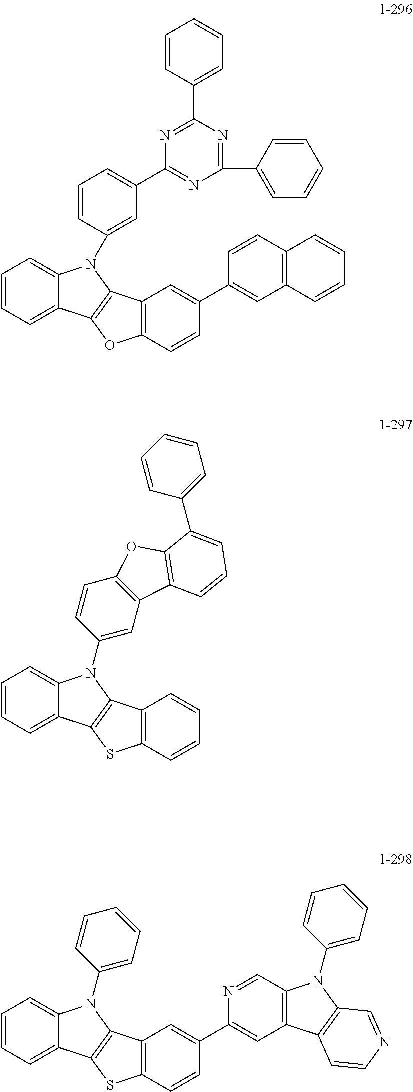 [SMILES: c1ccc(-c2nc(-c3ccccc3)nc(-c3cccc(-n4c5ccccc5c5oc6ccc(-c7ccc8ccccc8c7)cc6c54)c3)n2)cc1 ; c1ccc(-c2cccc3c2oc2ccc(-n4c5ccccc5c5sc6ccccc6c54)cc23)cc1 ; c1ccc(-n2c3cnccc3c3cc(-c4ccc5sc6c7ccccc7n(-c7ccccc7)c6c5c4)ncc32)cc1]

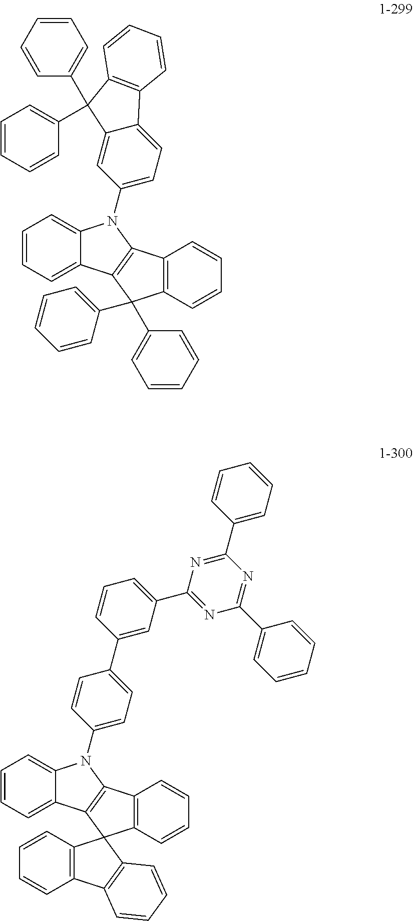 [SMILES: c1ccc(C2(c3ccccc3)c3ccccc3-c3ccc(-n4c5c(c6ccccc64)C(c4ccccc4)(c4ccccc4)c4ccccc4-5)cc32)cc1 ; c1ccc(-c2nc(-c3ccccc3)nc(-c3cccc(-c4ccc(-n5c6c(c7ccccc75)C5(c7ccccc7-c7ccccc75)c5ccccc5-6)cc4)c3)n2)cc1]

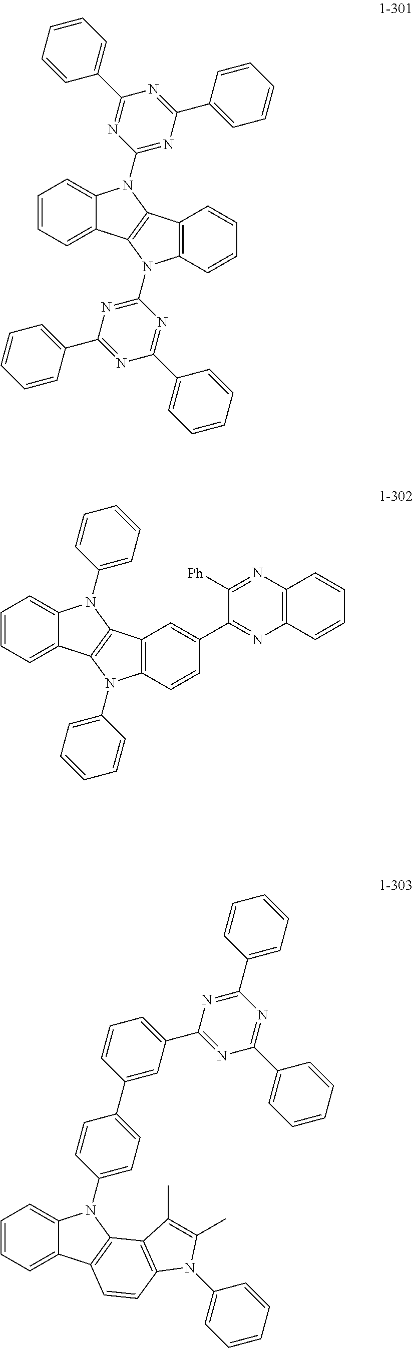 [SMILES: c1ccc(-c2nc(-c3ccccc3)nc(-n3c4ccccc4c4c3c3ccccc3n4-c3nc(-c4ccccc4)nc(-c4ccccc4)n3)n2)cc1 ; c1ccc(-c2nc3ccccc3nc2-c2ccc3c(c2)c2c(c4ccccc4n2-c2ccccc2)n3-c2ccccc2)cc1 ; Cc1c(C)n(-c2ccccc2)c2ccc3c4ccccc4n(-c4ccc(-c5cccc(-c6nc(-c7ccccc7)nc(-c7ccccc7)n6)c5)cc4)c3c12]

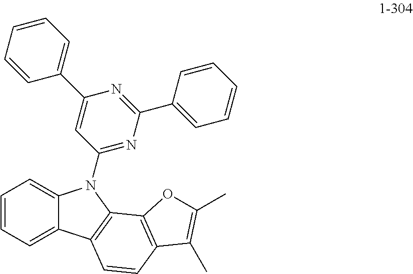 [SMILES: Cc1oc2c(ccc3c4ccccc4n(-c4cc(-c5ccccc5)nc(-c5ccccc5)n4)c32)c1C]

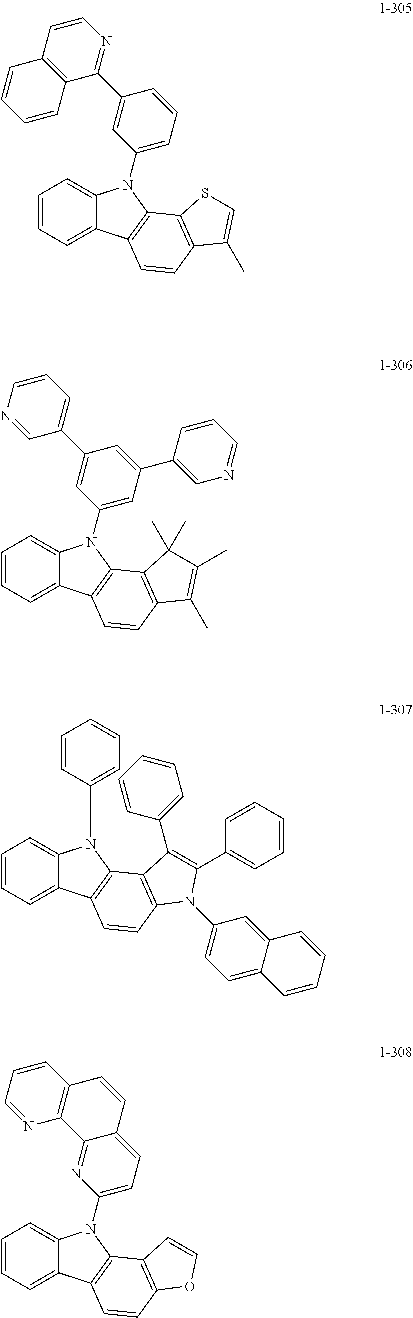 [SMILES: Cc1csc2c1ccc1c3ccccc3n(-c3cccc(-c4nccc5ccccc45)c3)c12 ; CC1=C(C)C(C)(C)c2c1ccc1c3ccccc3n(-c3cc(-c4cccnc4)cc(-c4cccnc4)c3)c21 ; c1ccc(-c2c(-c3ccccc3)n(-c3ccc4ccccc4c3)c3ccc4c5ccccc5n(-c5ccccc5)c4c23)cc1 ; c1cnc2c(c1)ccc1ccc(-n3c4ccccc4c4ccc5occc5c43)nc12]

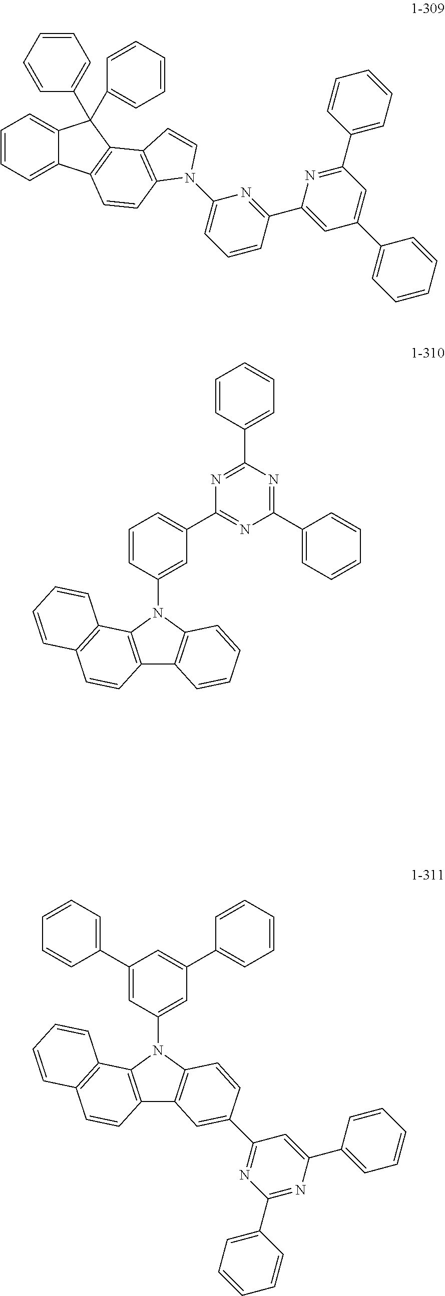 [SMILES: c1ccc(-c2cc(-c3ccccc3)nc(-c3cccc(-n4ccc5c6c(ccc54)-c4ccccc4C6(c4ccccc4)c4ccccc4)n3)c2)cc1 ; c1ccc(-c2nc(-c3ccccc3)nc(-c3cccc(-n4c5ccccc5c5ccc6ccccc6c54)c3)n2)cc1 ; c1ccc(-c2cc(-c3ccccc3)cc(-n3c4ccc(-c5cc(-c6ccccc6)nc(-c6ccccc6)n5)cc4c4ccc5ccccc5c43)c2)cc1]

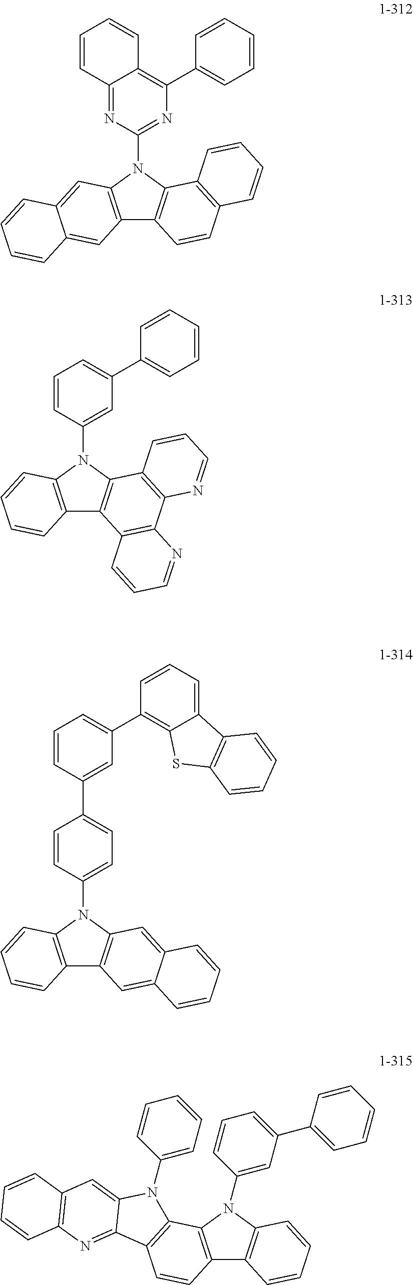 [SMILES: c1ccc(-c2nc(-n3c4cc5ccccc5cc4c4ccc5ccccc5c43)nc3ccccc23)cc1 ; c1ccc(-c2cccc(-n3c4ccccc4c4c5cccnc5c5ncccc5c43)c2)cc1 ; c1cc(-c2ccc(-n3c4ccccc4c4cc5ccccc5cc43)cc2)cc(-c2cccc3c2sc2ccccc23)c1 ; c1ccc(-c2cccc(-n3c4ccccc4c4ccc5c6nc7ccccc7cc6n(-c6ccccc6)c5c43)c2)cc1]

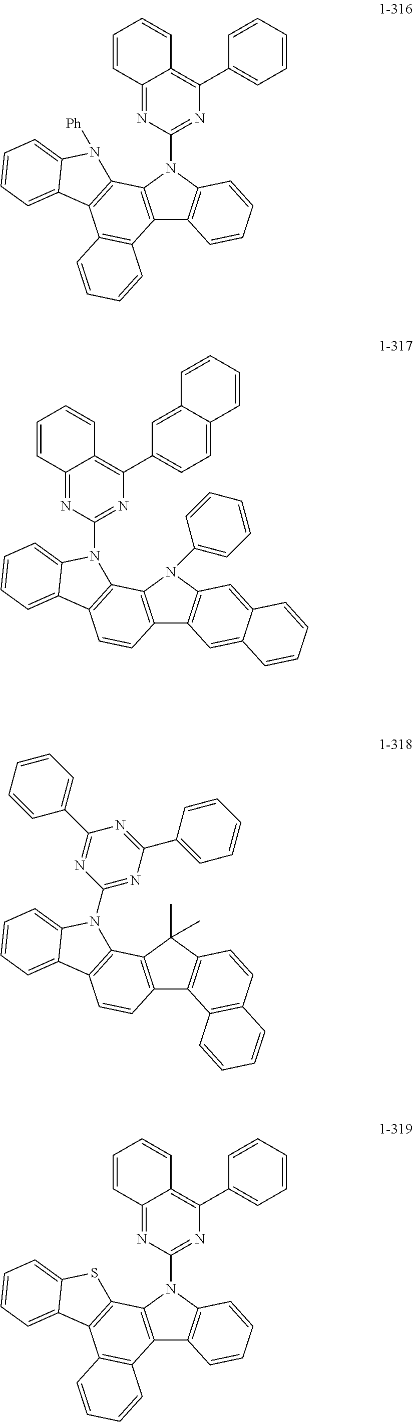 [SMILES: c1ccc(-c2nc(-n3c4ccccc4c4c5ccccc5c5c6ccccc6n(-c6ccccc6)c5c43)nc3ccccc23)cc1 ; c1ccc(-n2c3cc4ccccc4cc3c3ccc4c5ccccc5n(-c5nc(-c6ccc7ccccc7c6)c6ccccc6n5)c4c32)cc1 ; CC1(C)c2ccc3ccccc3c2-c2ccc3c4ccccc4n(-c4nc(-c5ccccc5)nc(-c5ccccc5)n4)c3c21 ; c1ccc(-c2nc(-n3c4ccccc4c4c5ccccc5c5c6ccccc6sc5c43)nc3ccccc23)cc1]

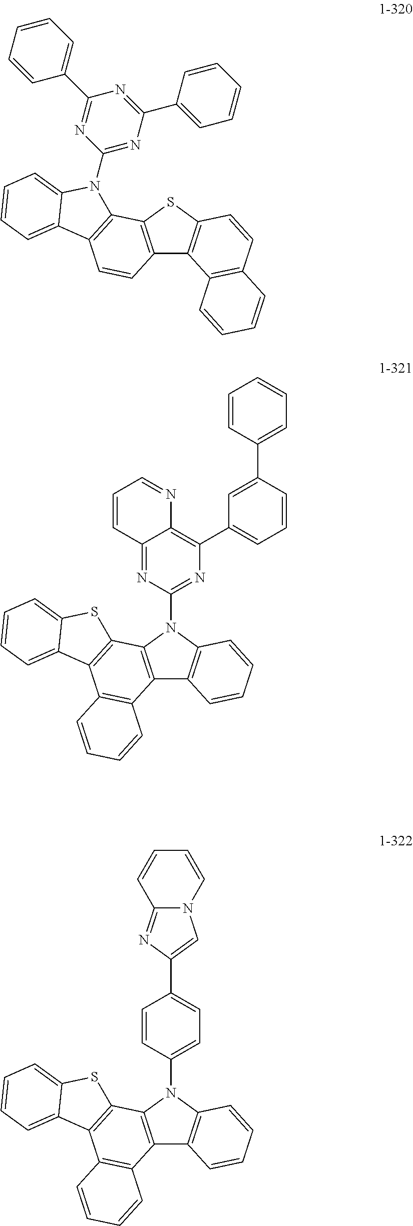 [SMILES: c1ccc(-c2nc(-c3ccccc3)nc(-n3c4ccccc4c4ccc5c(sc6ccc7ccccc7c65)c43)n2)cc1 ; c1ccc(-c2cccc(-c3nc(-n4c5ccccc5c5c6ccccc6c6c7ccccc7sc6c54)nc4cccnc34)c2)cc1 ; c1ccc2c(c1)sc1c2c2ccccc2c2c3ccccc3n(-c3ccc(-c4cn5ccccc5n4)cc3)c12]

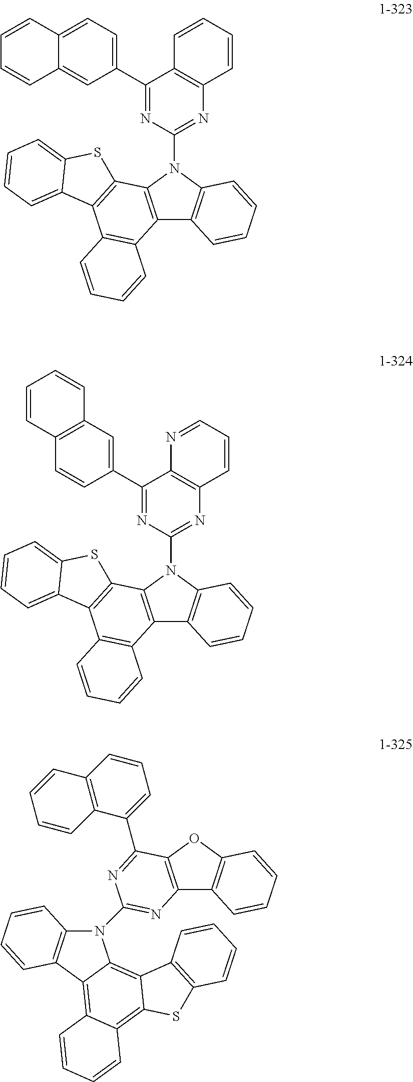 [SMILES: c1ccc2cc(-c3nc(-n4c5ccccc5c5c6ccccc6c6c7ccccc7sc6c54)nc4ccccc34)ccc2c1 ; c1ccc2cc(-c3nc(-n4c5ccccc5c5c6ccccc6c6c7ccccc7sc6c54)nc4cccnc34)ccc2c1 ; c1ccc2c(-c3nc(-n4c5ccccc5c5c6ccccc6c6sc7ccccc7c6c54)nc4c3oc3ccccc34)cccc2c1]

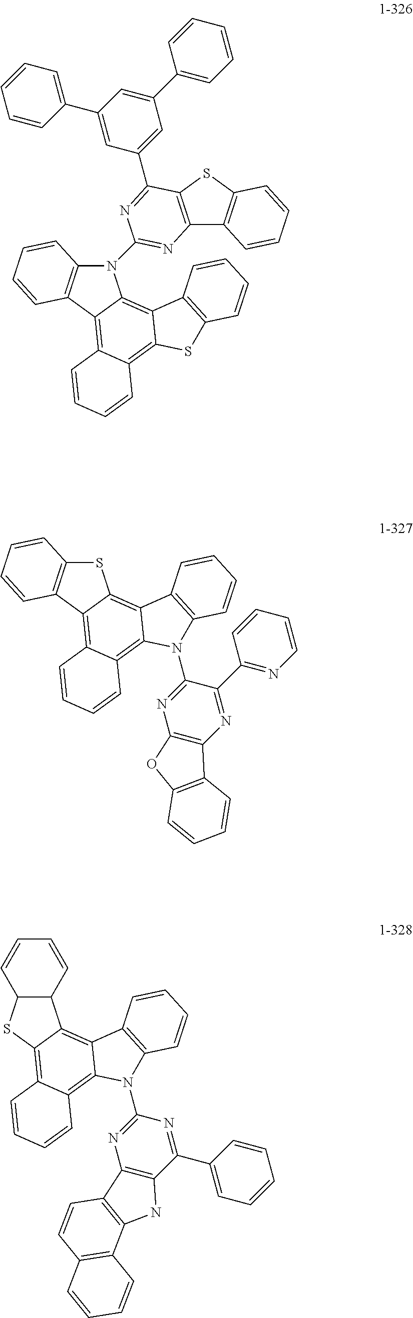 [SMILES: c1ccc(-c2cc(-c3ccccc3)cc(-c3nc(-n4c5ccccc5c5c6ccccc6c6sc7ccccc7c6c54)nc4c3sc3ccccc34)c2)cc1 ; c1ccc(-c2nc3c(nc2-n2c4ccccc4c4c5sc6ccccc6c5c5ccccc5c42)oc2ccccc23)nc1 ; C1=CC2Sc3c(c4c5ccccc5n(-c5nc(-c6ccccc6)c6[nH]c7c8ccccc8ccc7c6n5)c4c4ccccc34)C2C=C1]

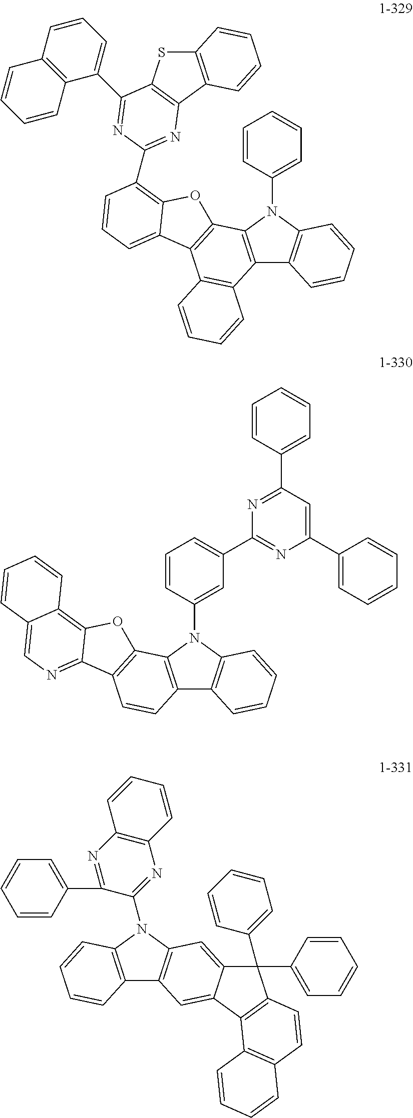 [SMILES: c1ccc(-n2c3ccccc3c3c4ccccc4c4c5cccc(-c6nc(-c7cccc8ccccc78)c7sc8ccccc8c7n6)c5oc4c32)cc1 ; c1ccc(-c2cc(-c3ccccc3)nc(-c3cccc(-n4c5ccccc5c5ccc6c7ncc8ccccc8c7oc6c54)c3)n2)cc1 ; c1ccc(-c2nc3ccccc3nc2-n2c3ccccc3c3cc4c(cc32)C(c2ccccc2)(c2ccccc2)c2ccc3ccccc3c2-4)cc1]

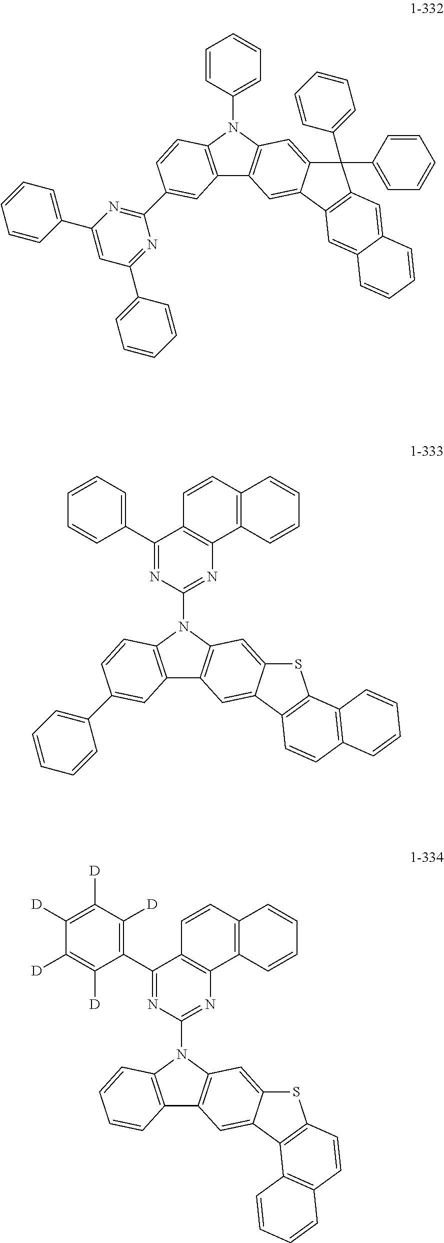 [SMILES: c1ccc(-c2cc(-c3ccccc3)nc(-c3ccc4c(c3)c3cc5c(cc3n4-c3ccccc3)C(c3ccccc3)(c3ccccc3)c3cc4ccccc4cc3-5)n2)cc1 ; c1ccc(-c2ccc3c(c2)c2cc4c(cc2n3-c2nc(-c3ccccc3)c3ccc5ccccc5c3n2)sc2c3ccccc3ccc42)cc1 ; [2H]c1c([2H])c([2H])c(-c2nc(-n3c4ccccc4c4cc5c(cc43)sc3ccc4ccccc4c35)nc3c2ccc2ccccc23)c([2H])c1[2H]]

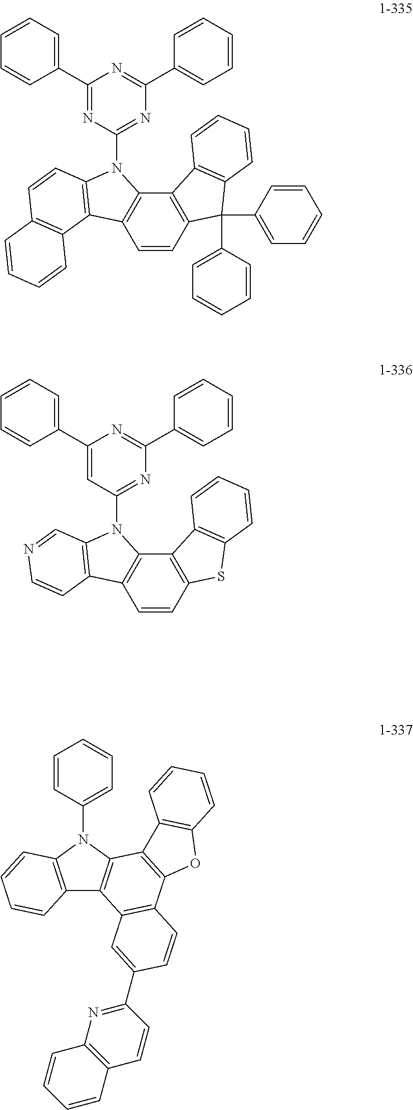 [SMILES: c1ccc(-c2nc(-c3ccccc3)nc(-n3c4ccc5ccccc5c4c4ccc5c(c43)-c3ccccc3C5(c3ccccc3)c3ccccc3)n2)cc1 ; c1ccc(-c2cc(-n3c4cnccc4c4ccc5sc6ccccc6c5c43)nc(-c3ccccc3)n2)cc1 ; c1ccc(-n2c3ccccc3c3c4cc(-c5ccc6ccccc6n5)ccc4c4oc5ccccc5c4c32)cc1]

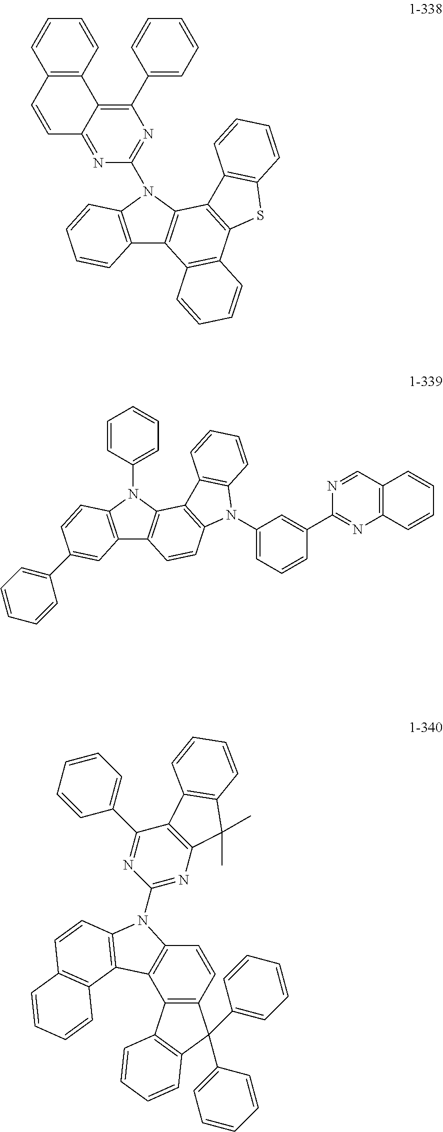 [SMILES: c1ccc(-c2nc(-n3c4ccccc4c4c5ccccc5c5sc6ccccc6c5c43)nc3ccc4ccccc4c23)cc1 ; c1ccc(-c2ccc3c(c2)c2ccc4c(c5ccccc5n4-c4cccc(-c5ncc6ccccc6n5)c4)c2n3-c2ccccc2)cc1 ; CC1(C)c2ccccc2-c2c(-c3ccccc3)nc(-n3c4ccc5c(c4c4c6ccccc6ccc43)-c3ccccc3C5(c3ccccc3)c3ccccc3)nc21]

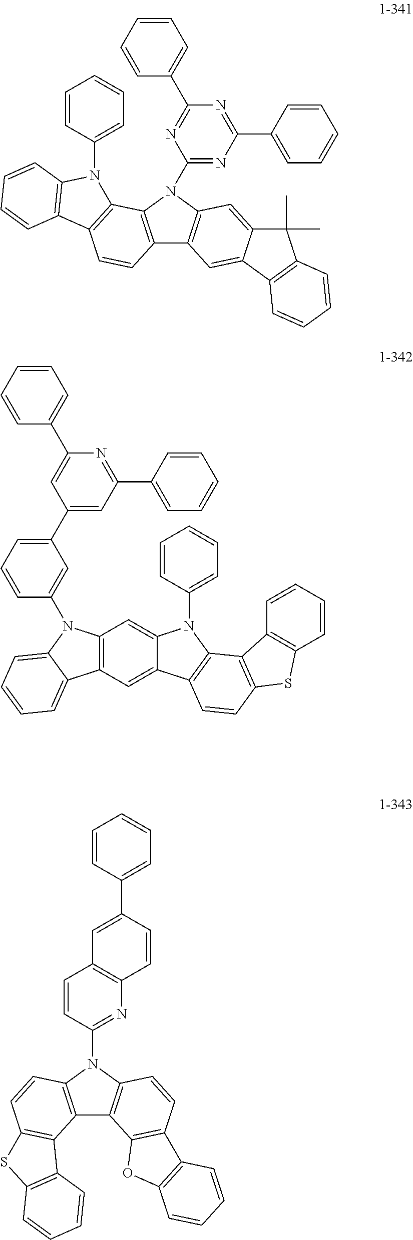 [SMILES: CC1(C)c2ccccc2-c2cc3c4ccc5c6ccccc6n(-c6ccccc6)c5c4n(-c4nc(-c5ccccc5)nc(-c5ccccc5)n4)c3cc21 ; c1ccc(-c2cc(-c3cccc(-n4c5ccccc5c5cc6c7ccc8sc9ccccc9c8c7n(-c7ccccc7)c6cc54)c3)cc(-c3ccccc3)n2)cc1 ; c1ccc(-c2ccc3nc(-n4c5ccc6c7ccccc7oc6c5c5c6c(ccc54)sc4ccccc46)ccc3c2)cc1]

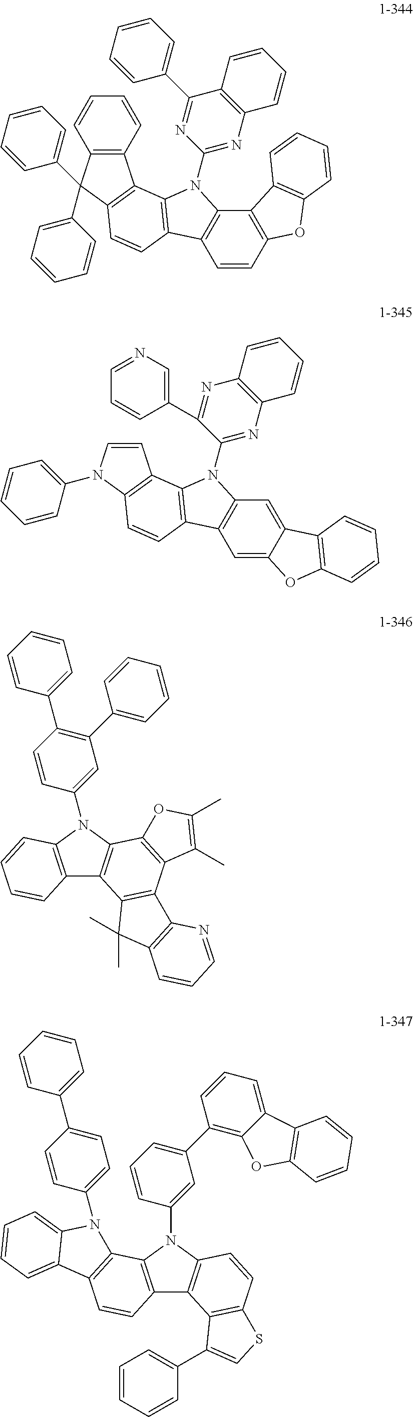 [SMILES: c1ccc(-c2nc(-n3c4c5c(ccc4c4ccc6oc7ccccc7c6c43)C(c3ccccc3)(c3ccccc3)c3ccccc3-5)nc3ccccc23)cc1 ; c1ccc(-n2ccc3c2ccc2c4cc5oc6ccccc6c5cc4n(-c4nc5ccccc5nc4-c4cccnc4)c23)cc1 ; Cc1oc2c(c1C)c1c(c3c4ccccc4n(-c4ccc(-c5ccccc5)c(-c5ccccc5)c4)c23)C(C)(C)c2cccnc2-1 ; c1ccc(-c2ccc(-n3c4ccccc4c4ccc5c6c7c(-c8ccccc8)csc7ccc6n(-c6cccc(-c7cccc8c7oc7ccccc78)c6)c5c43)cc2)cc1]

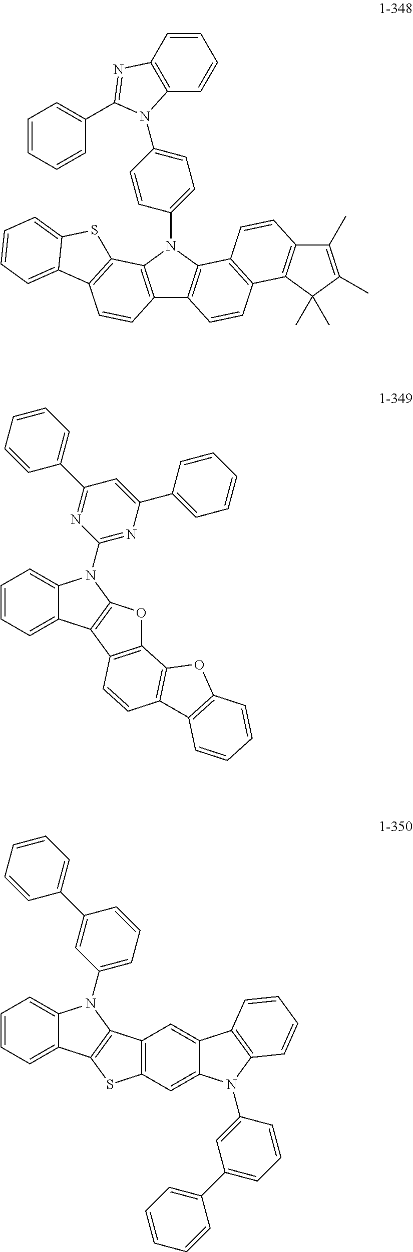 [SMILES: CC1=C(C)C(C)(C)c2c1ccc1c2ccc2c3ccc4c5ccccc5sc4c3n(-c3ccc(-n4c(-c5ccccc5)nc5ccccc54)cc3)c12 ; c1ccc(-c2cc(-c3ccccc3)nc(-n3c4ccccc4c4c5ccc6c7ccccc7oc6c5oc43)n2)cc1 ; c1ccc(-c2cccc(-n3c4ccccc4c4cc5c(cc43)sc3c4ccccc4n(-c4cccc(-c6ccccc6)c4)c53)c2)cc1]

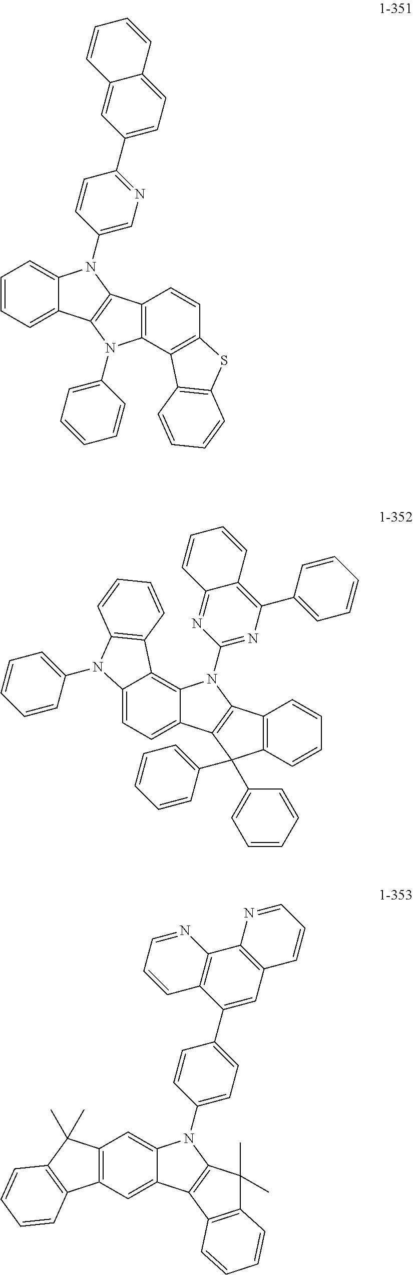 [SMILES: c1ccc(-n2c3c(ccc4sc5ccccc5c43)c3c2c2ccccc2n3-c2ccc(-c3ccc4ccccc4c3)nc2)cc1 ; c1ccc(-c2nc(-n3c4c(c5ccc6c(c7ccccc7n6-c6ccccc6)c53)C(c3ccccc3)(c3ccccc3)c3ccccc3-4)nc3ccccc23)cc1 ; CC1(C)c2ccccc2-c2cc3c4c(n(-c5ccc(-c6cc7cccnc7c7ncccc67)cc5)c3cc21)C(C)(C)c1ccccc1-4]

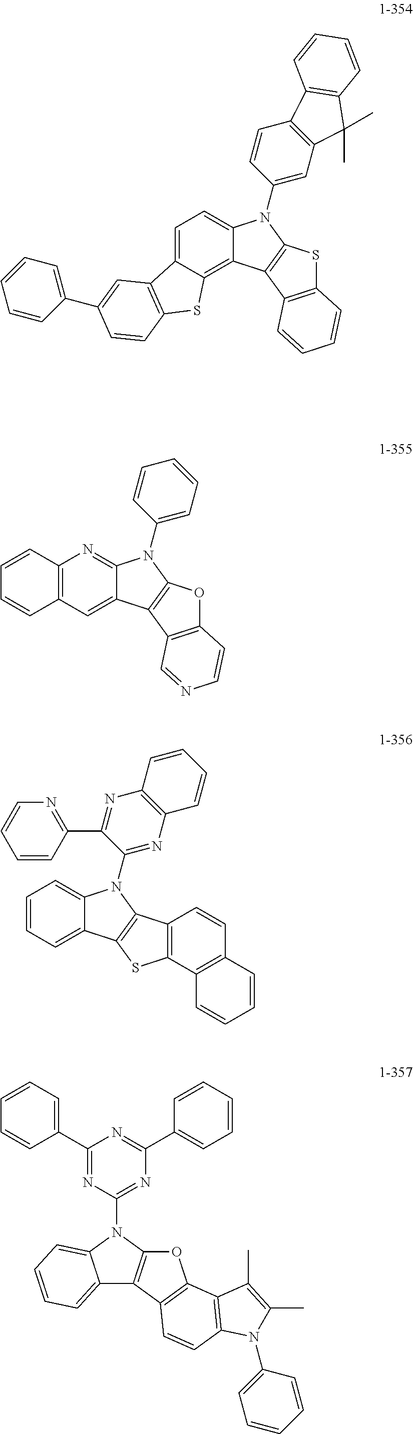 [SMILES: CC1(C)c2ccccc2-c2ccc(-n3c4ccc5c6cc(-c7ccccc7)ccc6sc5c4c4c5ccccc5sc43)cc21 ; c1ccc(-n2c3nc4ccccc4cc3c3c4cnccc4oc32)cc1 ; c1ccc(-c2nc3ccccc3nc2-n2c3ccccc3c3sc4c5ccccc5ccc4c32)nc1 ; Cc1c(C)n(-c2ccccc2)c2ccc3c(oc4c3c3ccccc3n4-c3nc(-c4ccccc4)nc(-c4ccccc4)n3)c12]

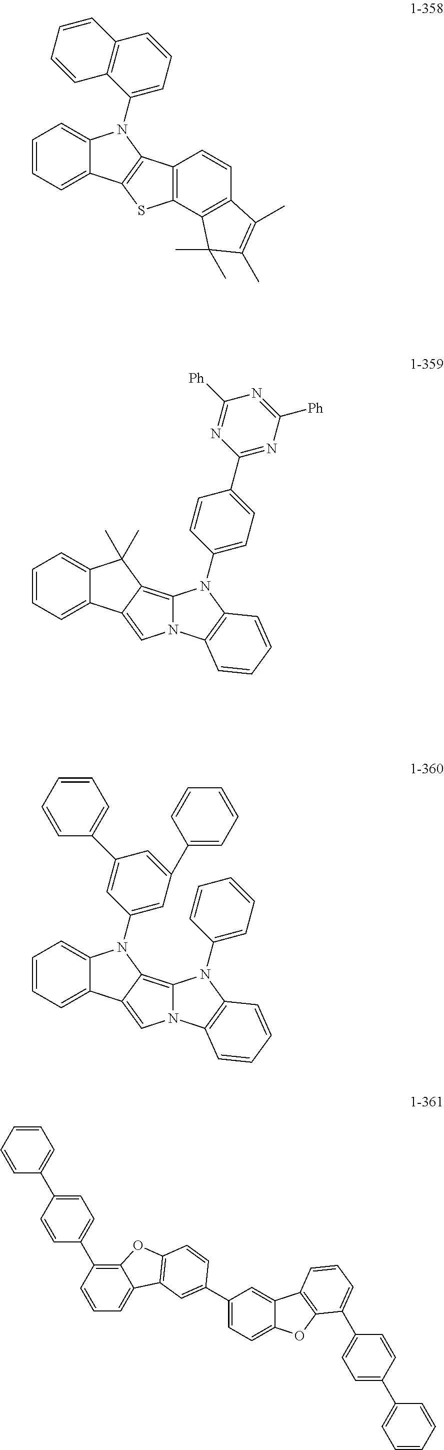 [SMILES: CC1=C(C)C(C)(C)c2c1ccc1c2sc2c3ccccc3n(-c3cccc4ccccc34)c12 ; CC1(C)c2ccccc2-c2cn3c4ccccc4n(-c4ccc(-c5nc(-c6ccccc6)nc(-c6ccccc6)n5)cc4)c3c21 ; c1ccc(-c2cc(-c3ccccc3)cc(-n3c4ccccc4c4cn5c6ccccc6n(-c6ccccc6)c5c43)c2)cc1 ; c1ccc(-c2ccc(-c3cccc4c3oc3ccc(-c5ccc6oc7c(-c8ccc(-c9ccccc9)cc8)cccc7c6c5)cc34)cc2)cc1]

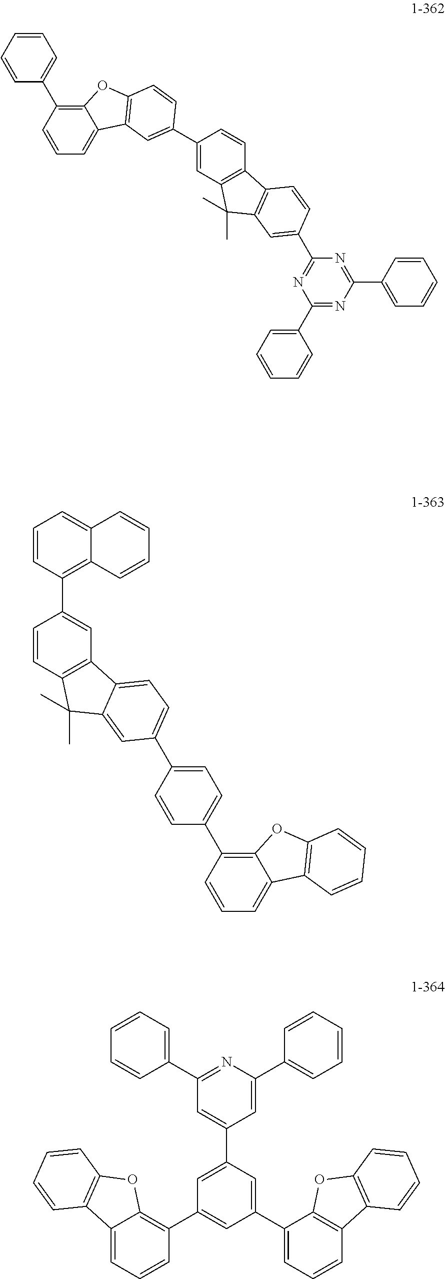 [SMILES: CC1(C)c2cc(-c3ccc4oc5c(-c6ccccc6)cccc5c4c3)ccc2-c2ccc(-c3nc(-c4ccccc4)nc(-c4ccccc4)n3)cc21 ; CC1(C)c2ccc(-c3cccc4ccccc34)cc2-c2ccc(-c3ccc(-c4cccc5c4oc4ccccc45)cc3)cc21 ; c1ccc(-c2cc(-c3cc(-c4cccc5c4oc4ccccc45)cc(-c4cccc5c4oc4ccccc45)c3)cc(-c3ccccc3)n2)cc1]

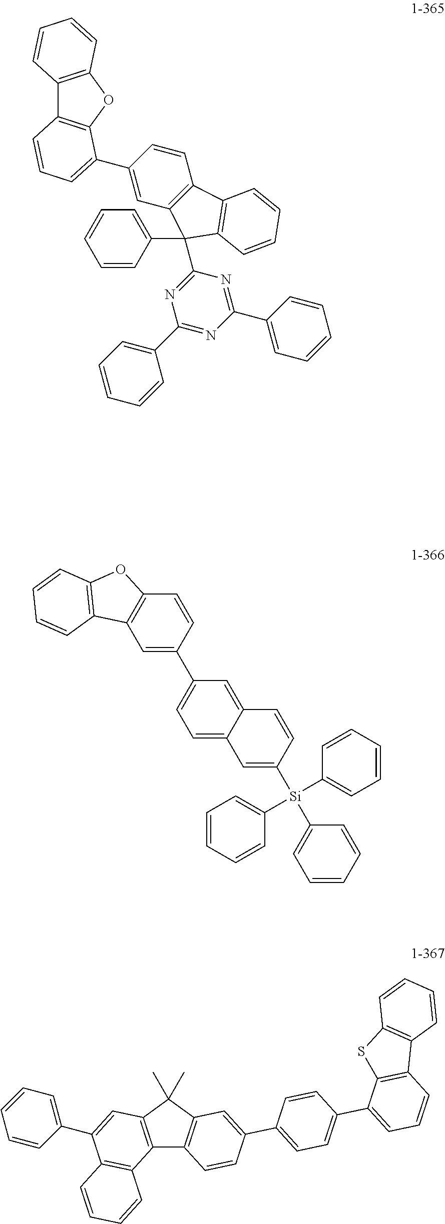 [SMILES: c1ccc(-c2nc(-c3ccccc3)nc(C3(c4ccccc4)c4ccccc4-c4ccc(-c5cccc6c5oc5ccccc56)cc43)n2)cc1 ; c1ccc([Si](c2ccccc2)(c2ccccc2)c2ccc3cc(-c4ccc5oc6ccccc6c5c4)ccc3c2)cc1 ; CC1(C)c2cc(-c3ccc(-c4cccc5c4sc4ccccc45)cc3)ccc2-c2c1cc(-c1ccccc1)c1ccccc21]

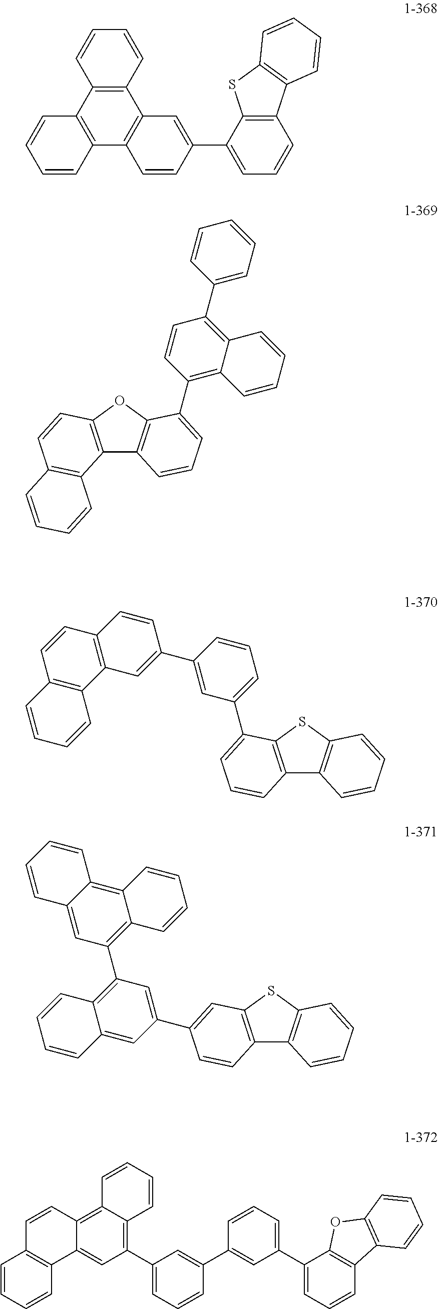 [SMILES: c1ccc2c(c1)sc1c(-c3ccc4c5ccccc5c5ccccc5c4c3)cccc12 ; c1ccc(-c2ccc(-c3cccc4c3oc3ccc5ccccc5c34)c3ccccc23)cc1 ; c1cc(-c2ccc3ccc4ccccc4c3c2)cc(-c2cccc3c2sc2ccccc23)c1 ; c1ccc2c(-c3cc4ccccc4c4ccccc34)cc(-c3ccc4c(c3)sc3ccccc34)cc2c1 ; c1cc(-c2cccc(-c3cccc4c3oc3ccccc34)c2)cc(-c2cc3c4ccccc4ccc3c3ccccc23)c1]

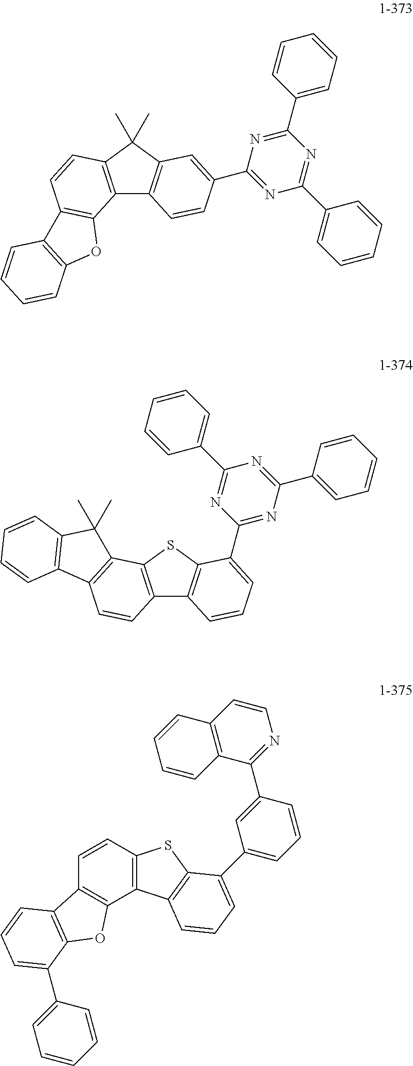 [SMILES: CC1(C)c2cc(-c3nc(-c4ccccc4)nc(-c4ccccc4)n3)ccc2-c2c1ccc1c2oc2ccccc21 ; CC1(C)c2ccccc2-c2ccc3c(sc4c(-c5nc(-c6ccccc6)nc(-c6ccccc6)n5)cccc43)c21 ; c1ccc(-c2cccc3c2oc2c3ccc3sc4c(-c5cccc(-c6nccc7ccccc67)c5)cccc4c32)cc1]

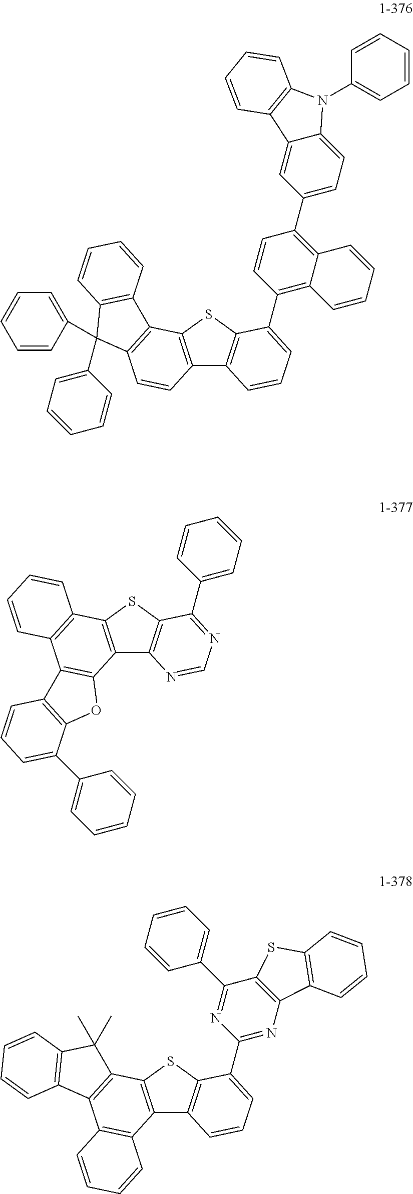 [SMILES: c1ccc(-n2c3ccccc3c3cc(-c4ccc(-c5cccc6c5sc5c7c(ccc56)C(c5ccccc5)(c5ccccc5)c5ccccc5-7)c5ccccc45)ccc32)cc1 ; c1ccc(-c2cccc3c2oc2c3c3ccccc3c3sc4c(-c5ccccc5)ncnc4c23)cc1 ; CC1(C)c2ccccc2-c2c1c1sc3c(-c4nc(-c5ccccc5)c5sc6ccccc6c5n4)cccc3c1c1ccccc21]

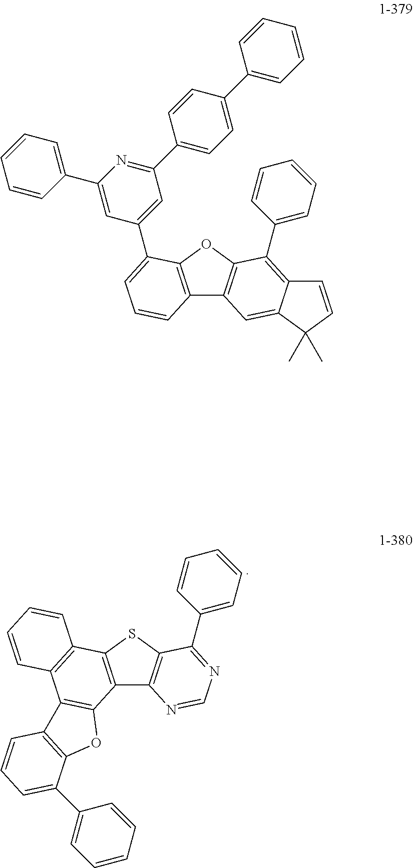 [SMILES: CC1(C)C=Cc2c1cc1c(oc3c(-c4cc(-c5ccccc5)nc(-c5ccc(-c6ccccc6)cc5)c4)cccc31)c2-c1ccccc1 ; c1ccc(-c2cccc3c2oc2c3c3ccccc3c3sc4c(-c5ccccc5)ncnc4c23)cc1]

The second compound represented by Formula 2 may be selected from Compounds 2-1 to 2-192, but is not limited thereto:

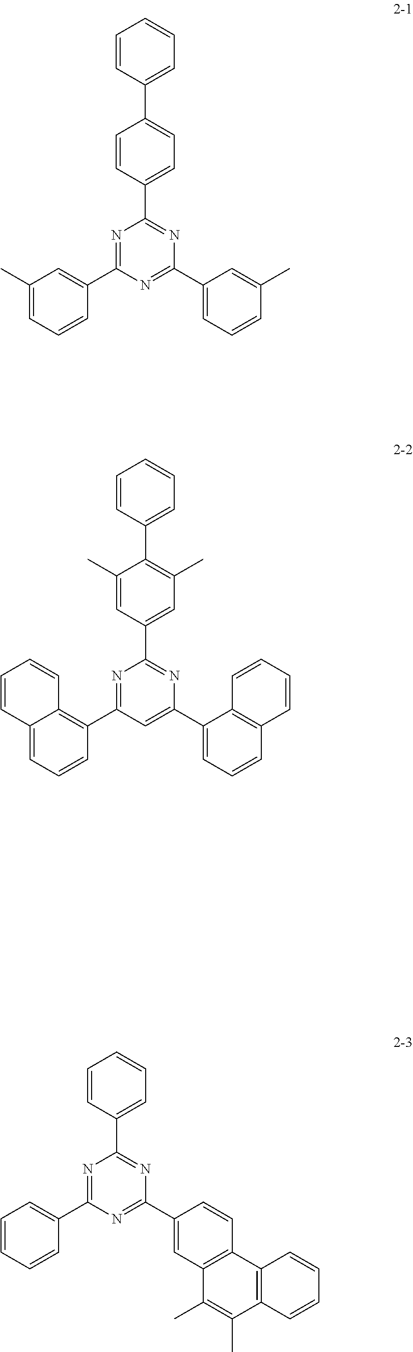

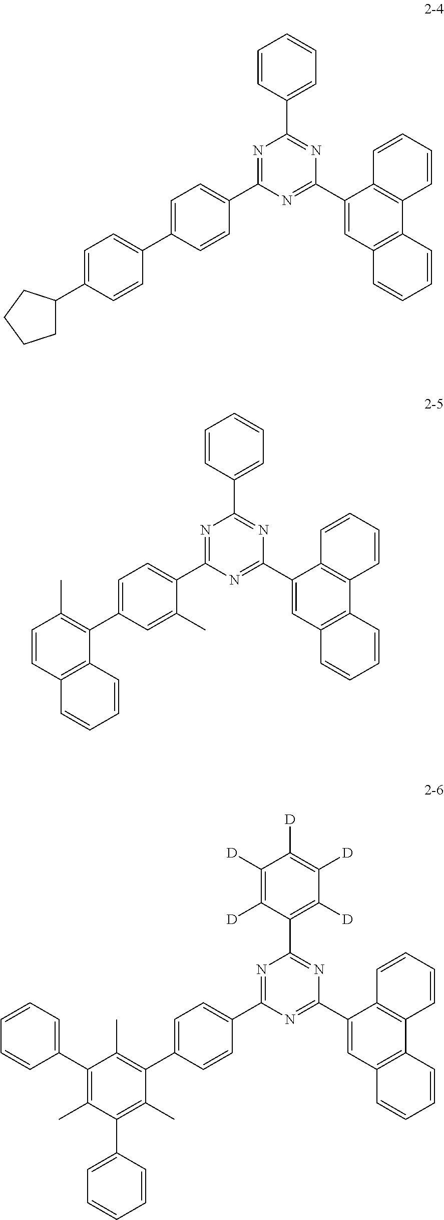 [SMILES: c1ccc(-c2nc(-c3ccc(-c4ccc(C5CCCC5)cc4)cc3)nc(-c3cc4ccccc4c4ccccc34)n2)cc1 ; Cc1cc(-c2c(C)ccc3ccccc23)ccc1-c1nc(-c2ccccc2)nc(-c2cc3ccccc3c3ccccc23)n1 ; [2H]c1c([2H])c([2H])c(-c2nc(-c3ccc(-c4c(C)c(-c5ccccc5)c(C)c(-c5ccccc5)c4C)cc3)nc(-c3cc4ccccc4c4ccccc34)n2)c([2H])c1[2H]]

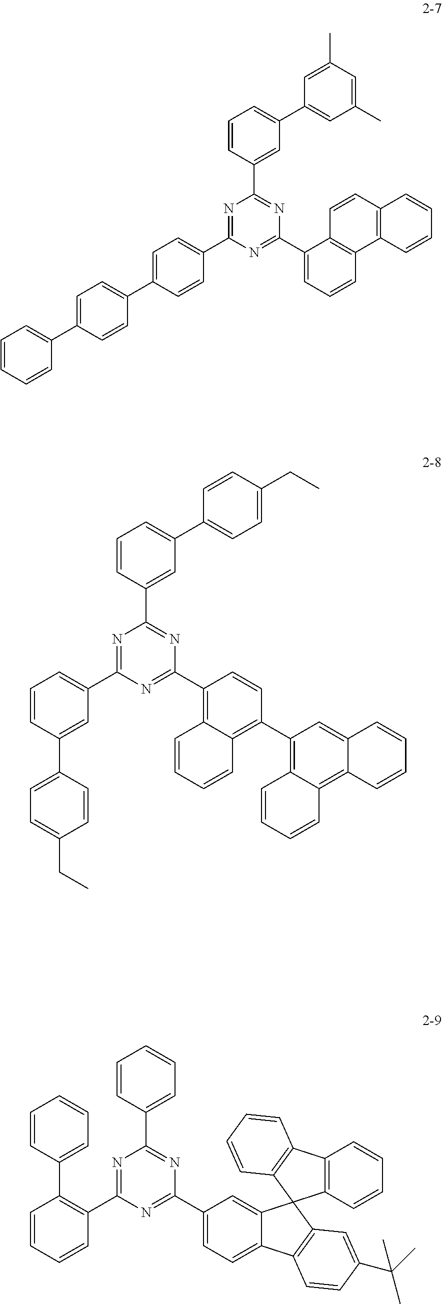 [SMILES: Cc1cc(C)cc(-c2cccc(-c3nc(-c4ccc(-c5ccc(-c6ccccc6)cc5)cc4)nc(-c4cccc5c4ccc4ccccc45)n3)c2)c1 ; CCc1ccc(-c2cccc(-c3nc(-c4cccc(-c5ccc(CC)cc5)c4)nc(-c4ccc(-c5cc6ccccc6c6ccccc56)c5ccccc45)n3)c2)cc1 ; CC(C)(C)c1ccc2c(c1)C1(c3ccccc3-c3ccccc31)c1cc(-c3nc(-c4ccccc4)nc(-c4ccccc4-c4ccccc4)n3)ccc1-2]

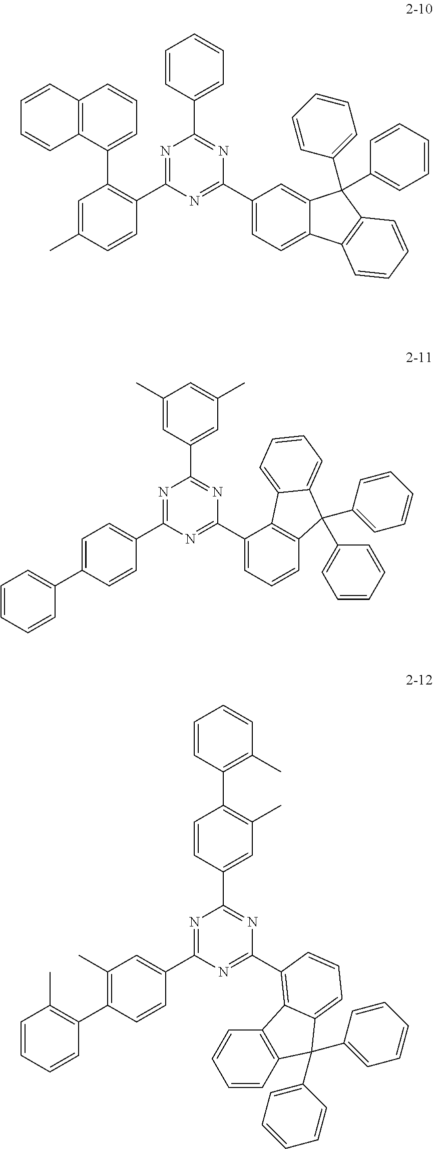 [SMILES: Cc1ccc(-c2nc(-c3ccccc3)nc(-c3ccc4c(c3)C(c3ccccc3)(c3ccccc3)c3ccccc3-4)n2)c(-c2cccc3ccccc23)c1 ; Cc1cc(C)cc(-c2nc(-c3ccc(-c4ccccc4)cc3)nc(-c3cccc4c3-c3ccccc3C4(c3ccccc3)c3ccccc3)n2)c1 ; Cc1ccccc1-c1ccc(-c2nc(-c3ccc(-c4ccccc4C)c(C)c3)nc(-c3cccc4c3-c3ccccc3C4(c3ccccc3)c3ccccc3)n2)cc1C]

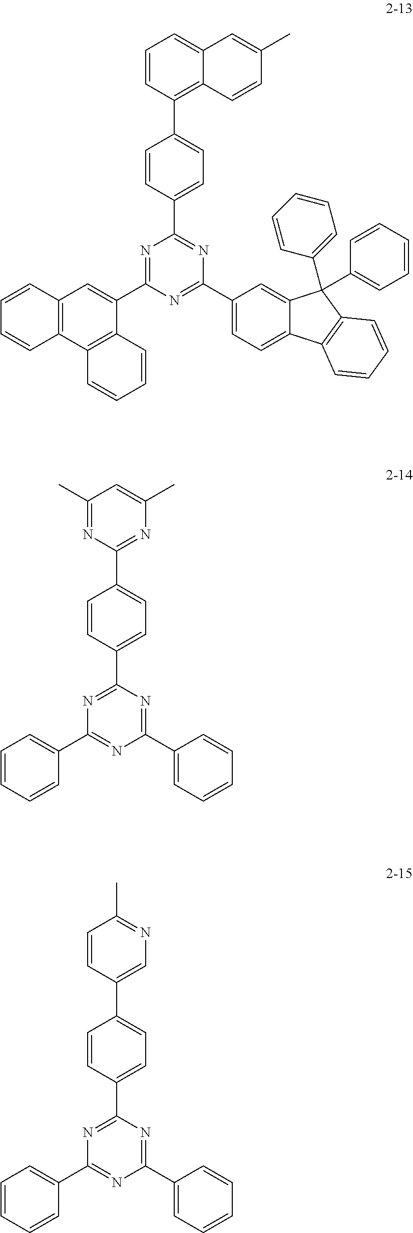 [SMILES: Cc1ccc2c(-c3ccc(-c4nc(-c5ccc6c(c5)C(c5ccccc5)(c5ccccc5)c5ccccc5-6)nc(-c5cc6ccccc6c6ccccc56)n4)cc3)cccc2c1 ; Cc1cc(C)nc(-c2ccc(-c3nc(-c4ccccc4)nc(-c4ccccc4)n3)cc2)n1 ; Cc1ccc(-c2ccc(-c3nc(-c4ccccc4)nc(-c4ccccc4)n3)cc2)cn1]

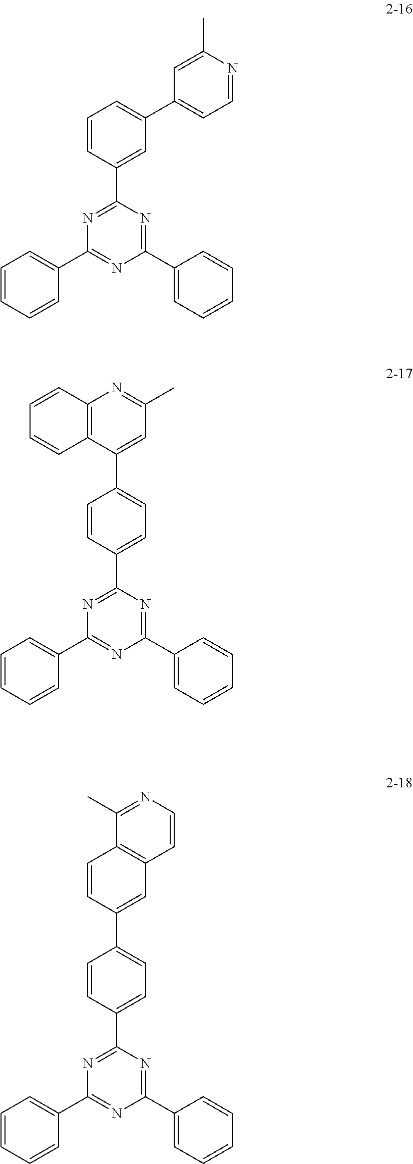 [SMILES: Cc1cc(-c2cccc(-c3nc(-c4ccccc4)nc(-c4ccccc4)n3)c2)ccn1 ; Cc1cc(-c2ccc(-c3nc(-c4ccccc4)nc(-c4ccccc4)n3)cc2)c2ccccc2n1 ; Cc1nccc2cc(-c3ccc(-c4nc(-c5ccccc5)nc(-c5ccccc5)n4)cc3)ccc12]

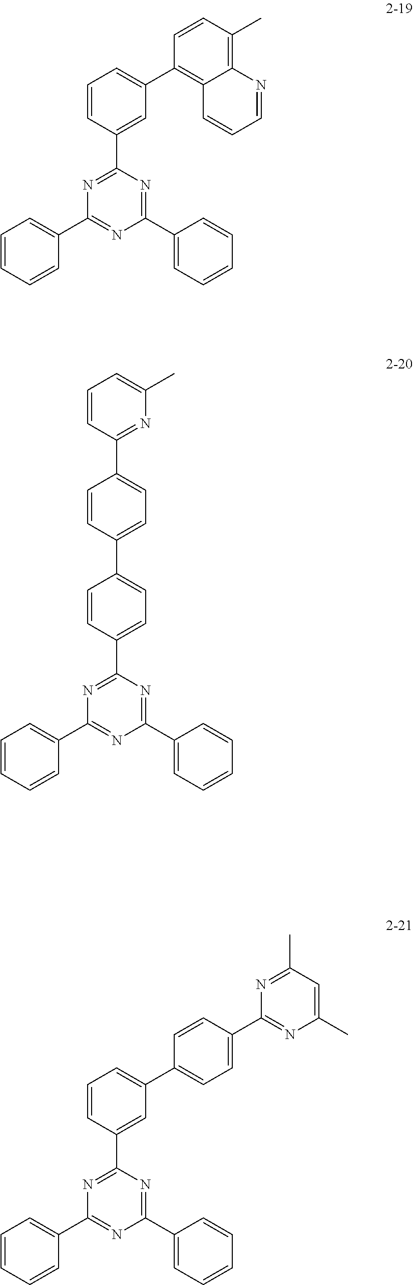 [SMILES: Cc1ccc(-c2cccc(-c3nc(-c4ccccc4)nc(-c4ccccc4)n3)c2)c2cccnc12 ; Cc1cccc(-c2ccc(-c3ccc(-c4nc(-c5ccccc5)nc(-c5ccccc5)n4)cc3)cc2)n1 ; Cc1cc(C)nc(-c2ccc(-c3cccc(-c4nc(-c5ccccc5)nc(-c5ccccc5)n4)c3)cc2)n1]

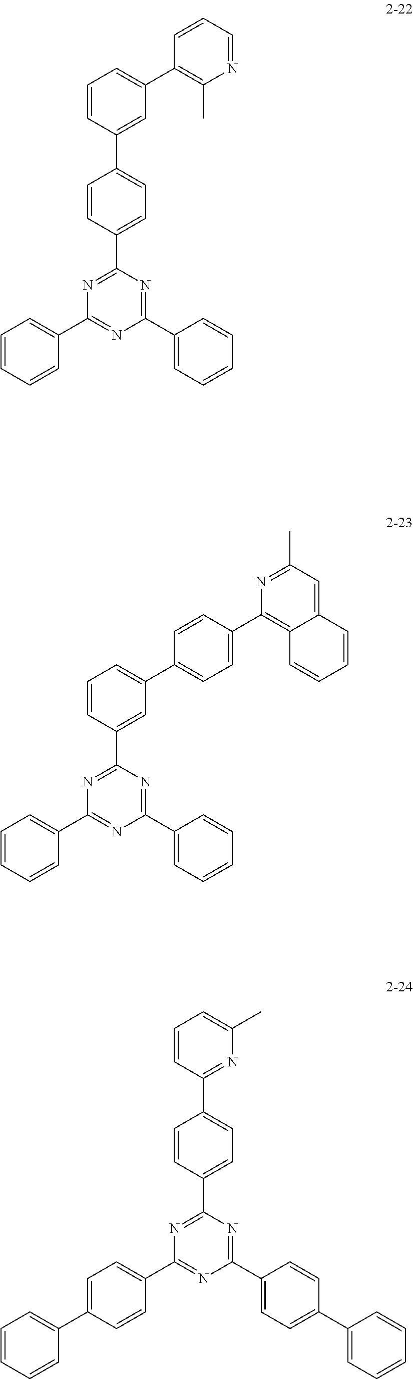 [SMILES: Cc1ncccc1-c1cccc(-c2ccc(-c3nc(-c4ccccc4)nc(-c4ccccc4)n3)cc2)c1 ; Cc1cc2ccccc2c(-c2ccc(-c3cccc(-c4nc(-c5ccccc5)nc(-c5ccccc5)n4)c3)cc2)n1 ; Cc1cccc(-c2ccc(-c3nc(-c4ccc(-c5ccccc5)cc4)nc(-c4ccc(-c5ccccc5)cc4)n3)cc2)n1]

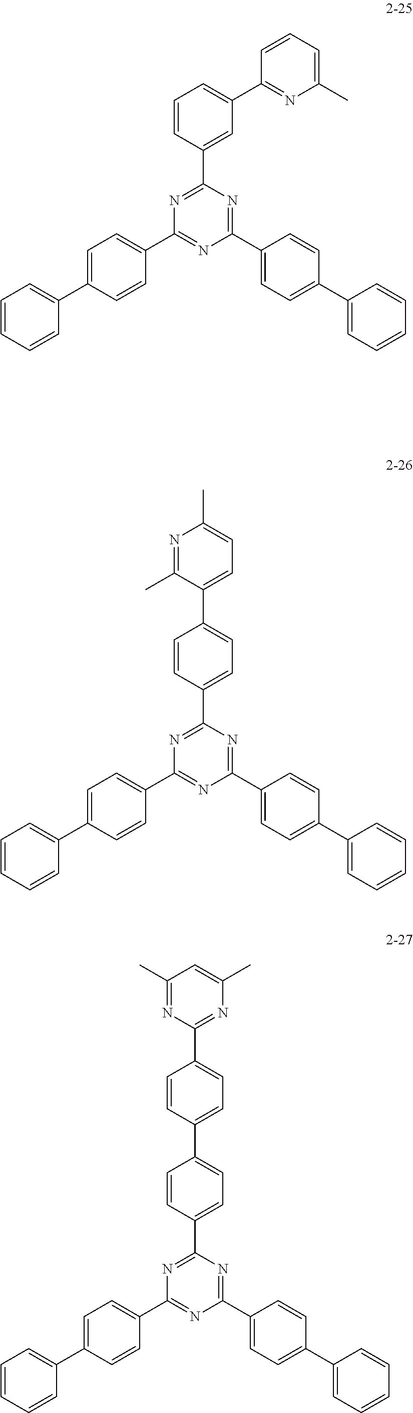 [SMILES: Cc1cccc(-c2cccc(-c3nc(-c4ccc(-c5ccccc5)cc4)nc(-c4ccc(-c5ccccc5)cc4)n3)c2)n1 ; Cc1ccc(-c2ccc(-c3nc(-c4ccc(-c5ccccc5)cc4)nc(-c4ccc(-c5ccccc5)cc4)n3)cc2)c(C)n1 ; Cc1cc(C)nc(-c2ccc(-c3ccc(-c4nc(-c5ccc(-c6ccccc6)cc5)nc(-c5ccc(-c6ccccc6)cc5)n4)cc3)cc2)n1]

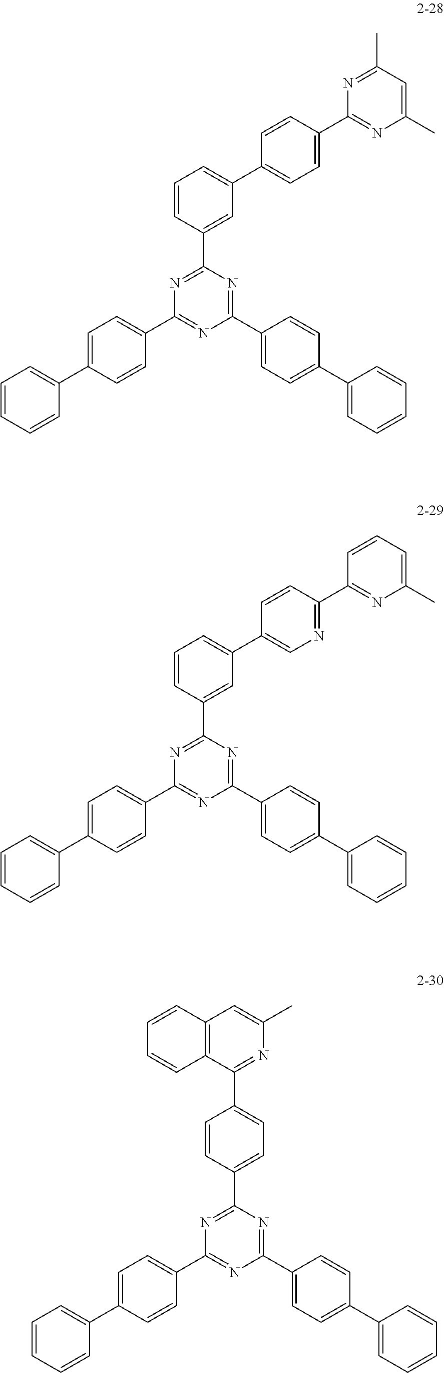 [SMILES: Cc1cc(C)nc(-c2ccc(-c3cccc(-c4nc(-c5ccc(-c6ccccc6)cc5)nc(-c5ccc(-c6ccccc6)cc5)n4)c3)cc2)n1 ; Cc1cccc(-c2ccc(-c3cccc(-c4nc(-c5ccc(-c6ccccc6)cc5)nc(-c5ccc(-c6ccccc6)cc5)n4)c3)cn2)n1 ; Cc1cc2ccccc2c(-c2ccc(-c3nc(-c4ccc(-c5ccccc5)cc4)nc(-c4ccc(-c5ccccc5)cc4)n3)cc2)n1]

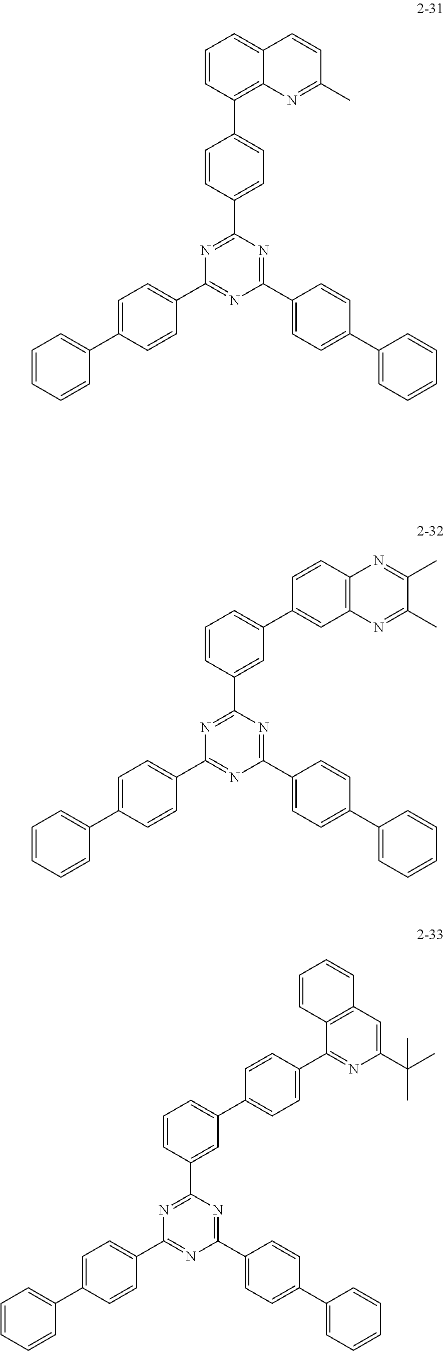 [SMILES: Cc1ccc2cccc(-c3ccc(-c4nc(-c5ccc(-c6ccccc6)cc5)nc(-c5ccc(-c6ccccc6)cc5)n4)cc3)c2n1 ; Cc1nc2ccc(-c3cccc(-c4nc(-c5ccc(-c6ccccc6)cc5)nc(-c5ccc(-c6ccccc6)cc5)n4)c3)cc2nc1C ; CC(C)(C)c1cc2ccccc2c(-c2ccc(-c3cccc(-c4nc(-c5ccc(-c6ccccc6)cc5)nc(-c5ccc(-c6ccccc6)cc5)n4)c3)cc2)n1]

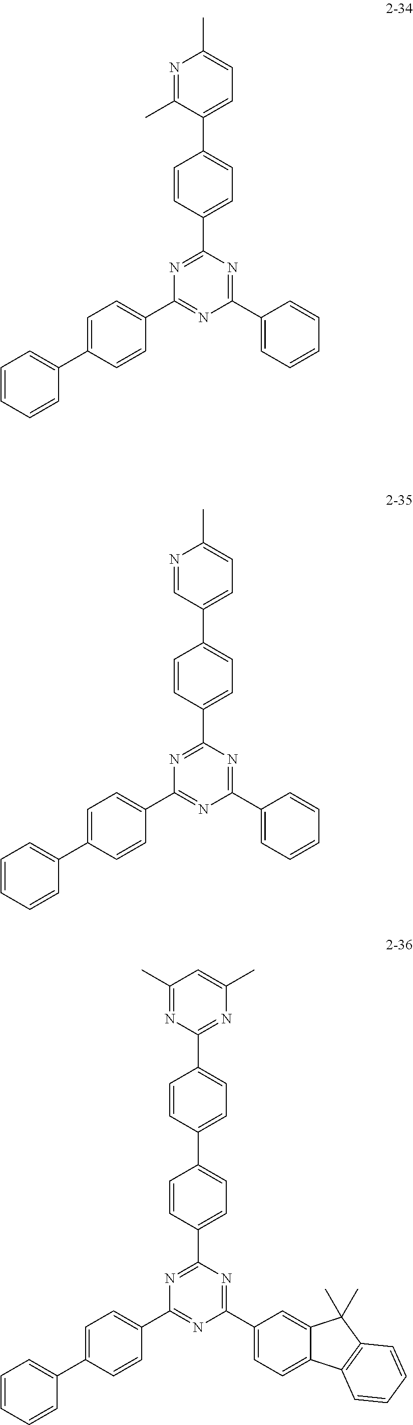 [SMILES: Cc1ccc(-c2ccc(-c3nc(-c4ccccc4)nc(-c4ccc(-c5ccccc5)cc4)n3)cc2)c(C)n1 ; Cc1ccc(-c2ccc(-c3nc(-c4ccccc4)nc(-c4ccc(-c5ccccc5)cc4)n3)cc2)cn1 ; Cc1cc(C)nc(-c2ccc(-c3ccc(-c4nc(-c5ccc(-c6ccccc6)cc5)nc(-c5ccc6c(c5)C(C)(C)c5ccccc5-6)n4)cc3)cc2)n1]

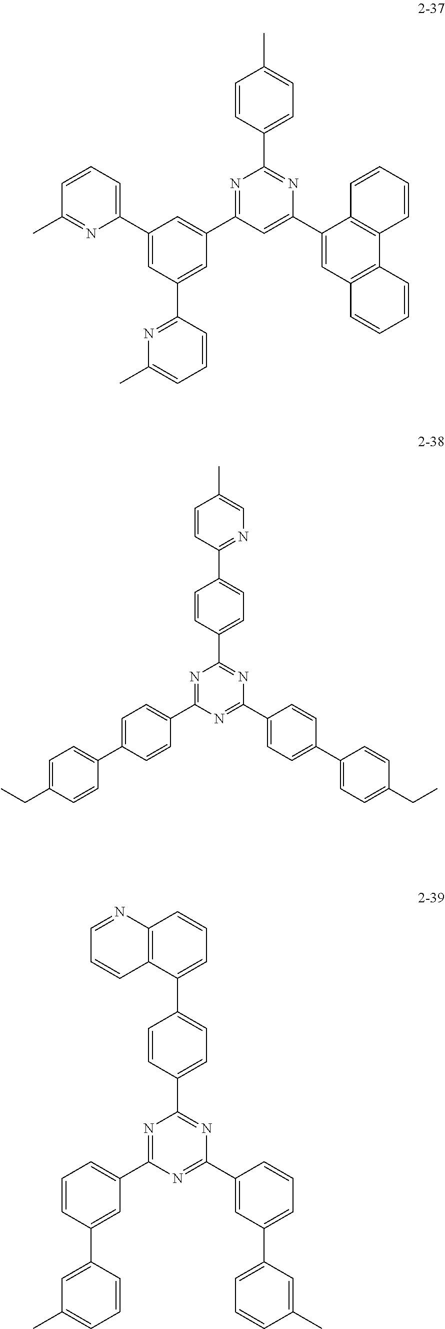

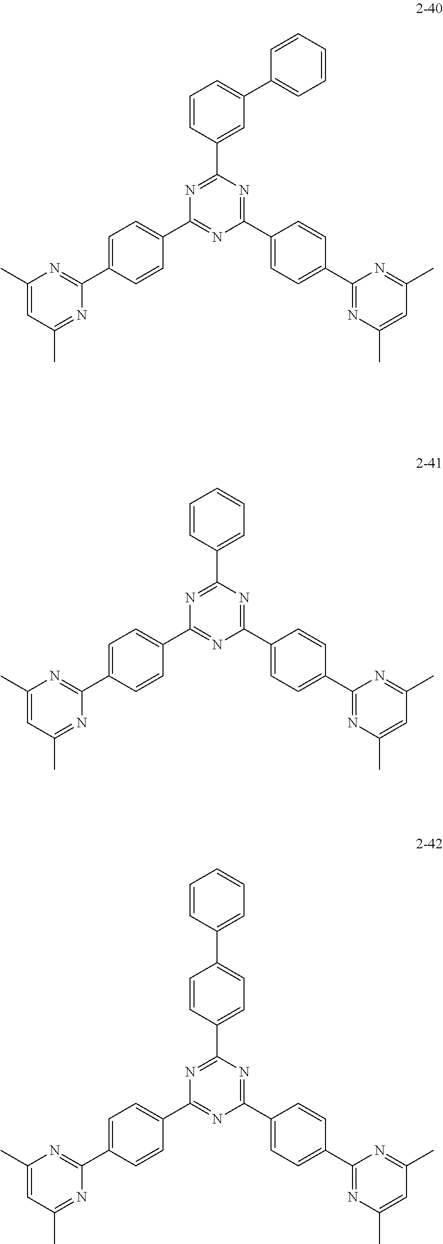

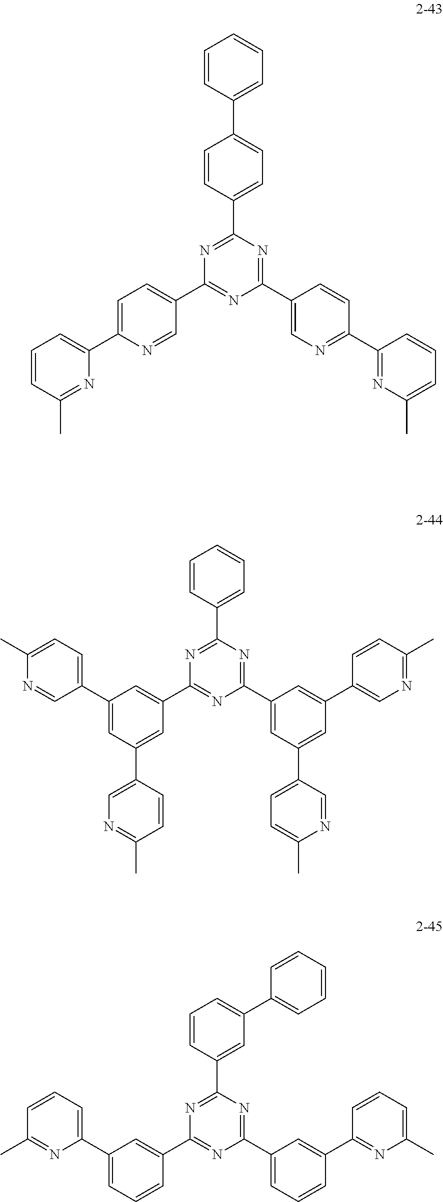

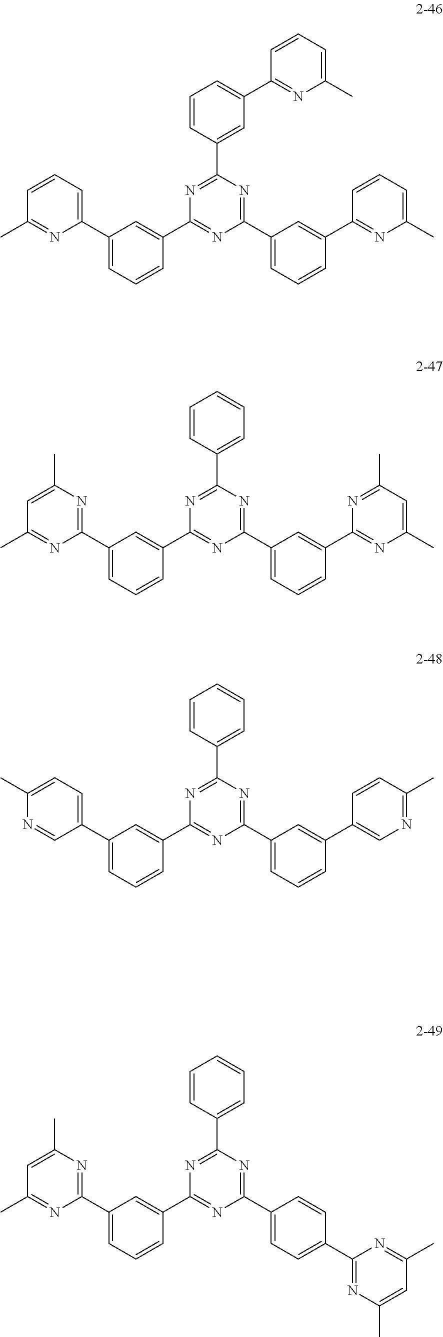

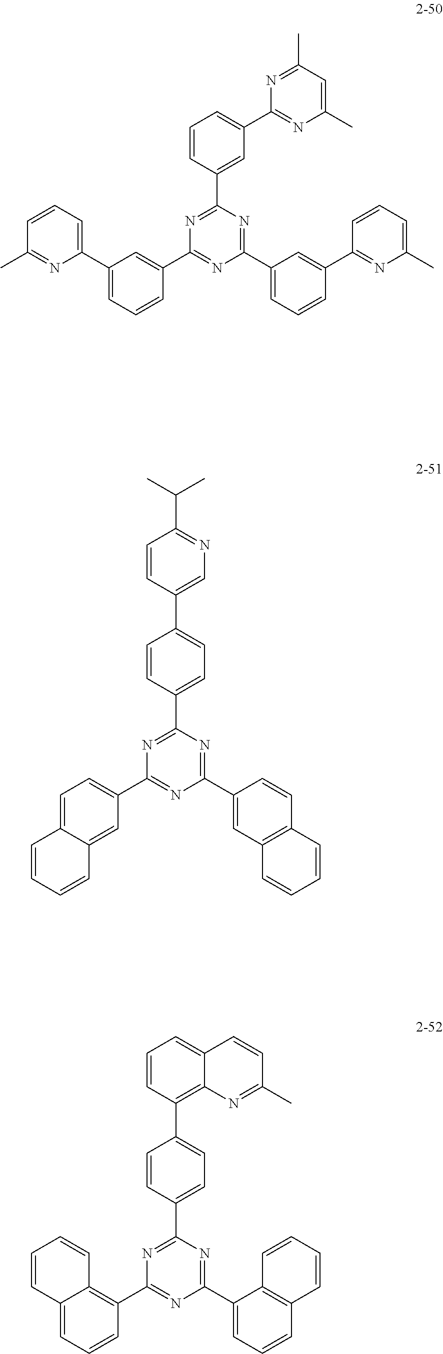

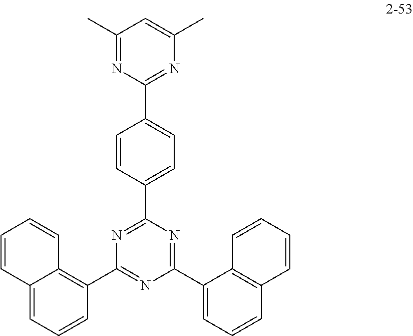 [SMILES: Cc1cc(C)nc(-c2ccc(-c3nc(-c4cccc5ccccc45)nc(-c4cccc5ccccc45)n3)cc2)n1]

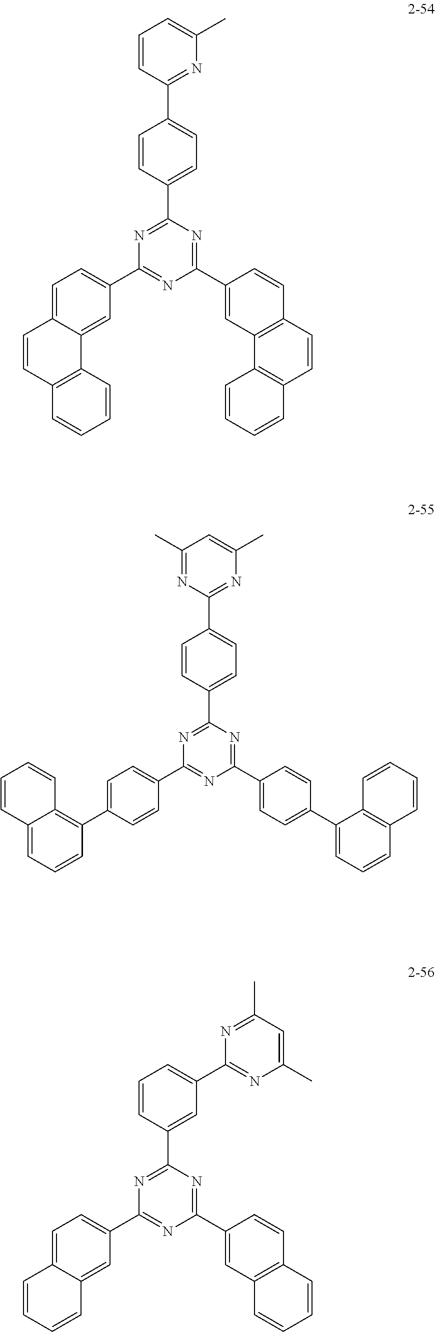 [SMILES: Cc1cccc(-c2ccc(-c3nc(-c4ccc5ccc6ccccc6c5c4)nc(-c4ccc5ccc6ccccc6c5c4)n3)cc2)n1 ; Cc1cc(C)nc(-c2ccc(-c3nc(-c4ccc(-c5cccc6ccccc56)cc4)nc(-c4ccc(-c5cccc6ccccc56)cc4)n3)cc2)n1 ; Cc1cc(C)nc(-c2cccc(-c3nc(-c4ccc5ccccc5c4)nc(-c4ccc5ccccc5c4)n3)c2)n1]

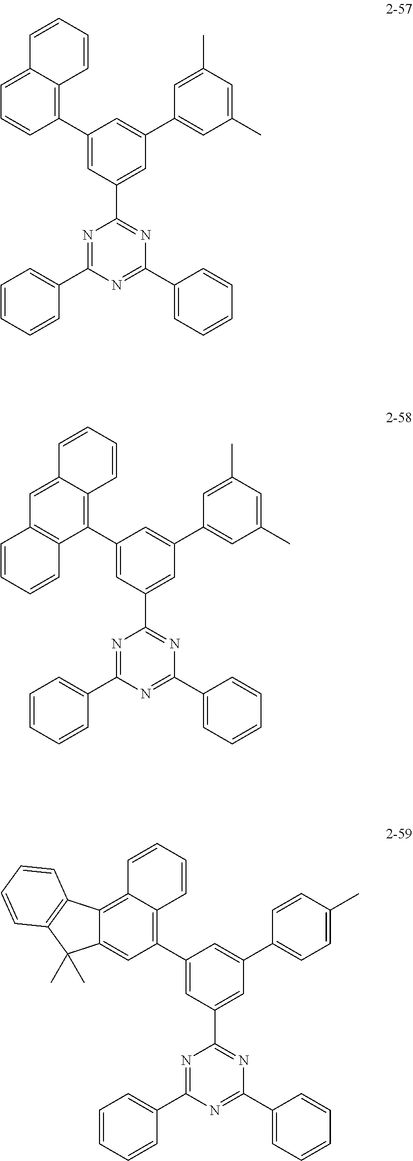 [SMILES: Cc1cc(C)cc(-c2cc(-c3nc(-c4ccccc4)nc(-c4ccccc4)n3)cc(-c3cccc4ccccc34)c2)c1 ; Cc1cc(C)cc(-c2cc(-c3nc(-c4ccccc4)nc(-c4ccccc4)n3)cc(-c3c4ccccc4cc4ccccc34)c2)c1 ; Cc1ccc(-c2cc(-c3nc(-c4ccccc4)nc(-c4ccccc4)n3)cc(-c3cc4c(c5ccccc35)-c3ccccc3C4(C)C)c2)cc1]

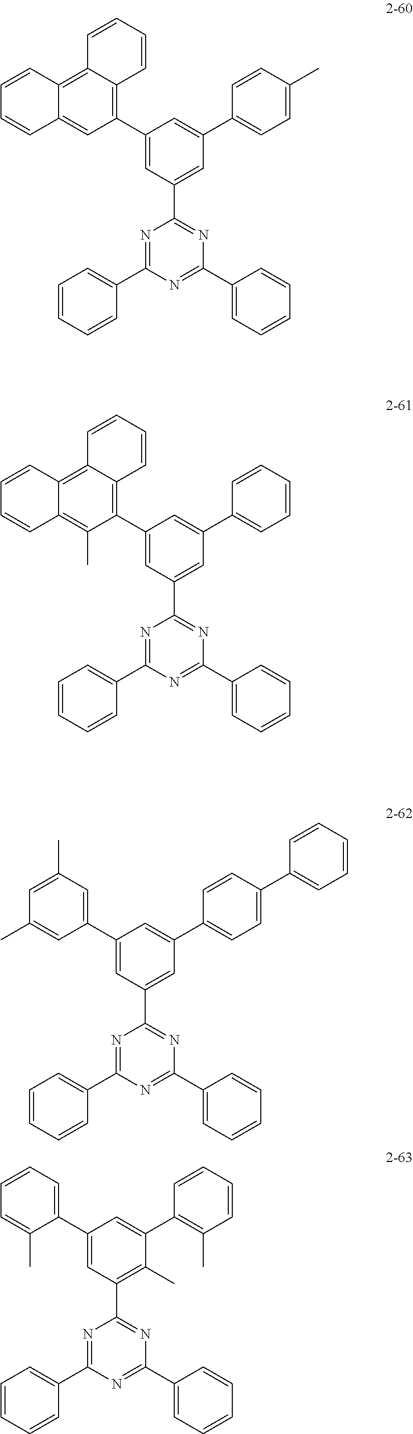

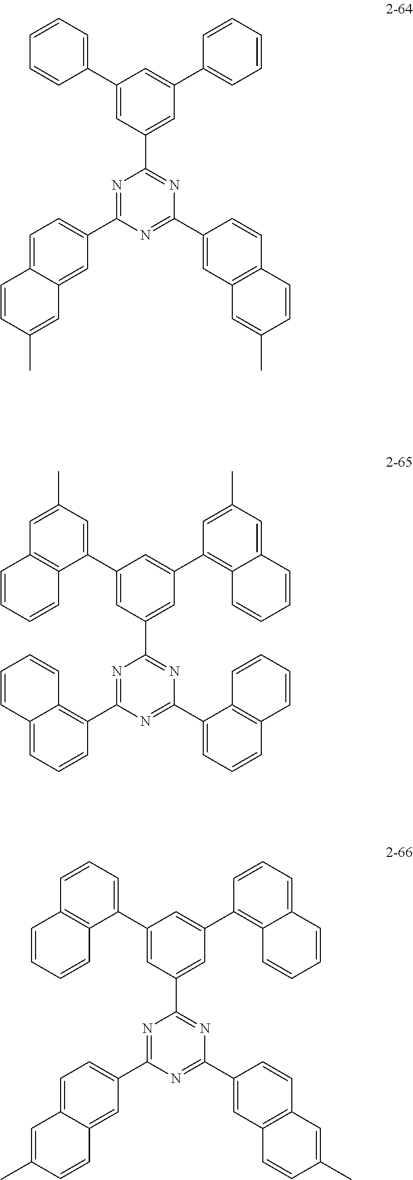

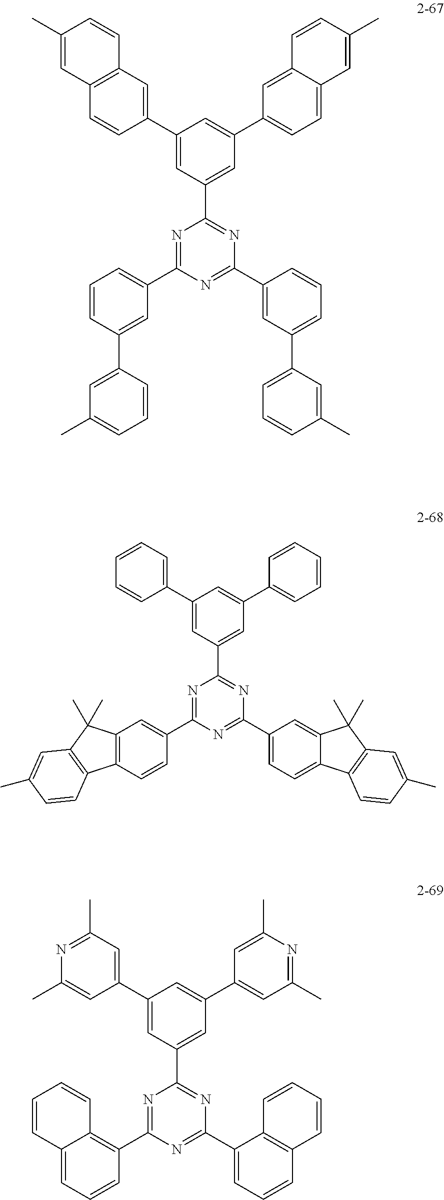

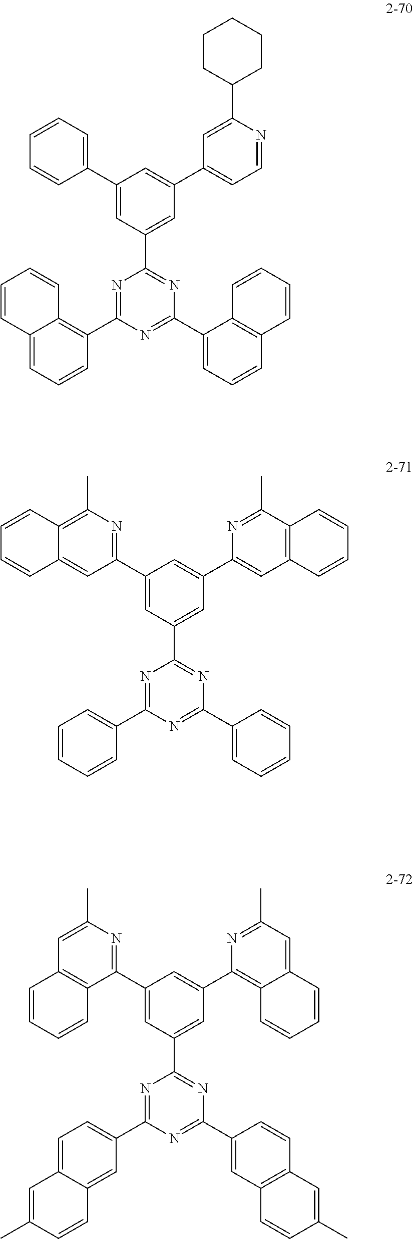

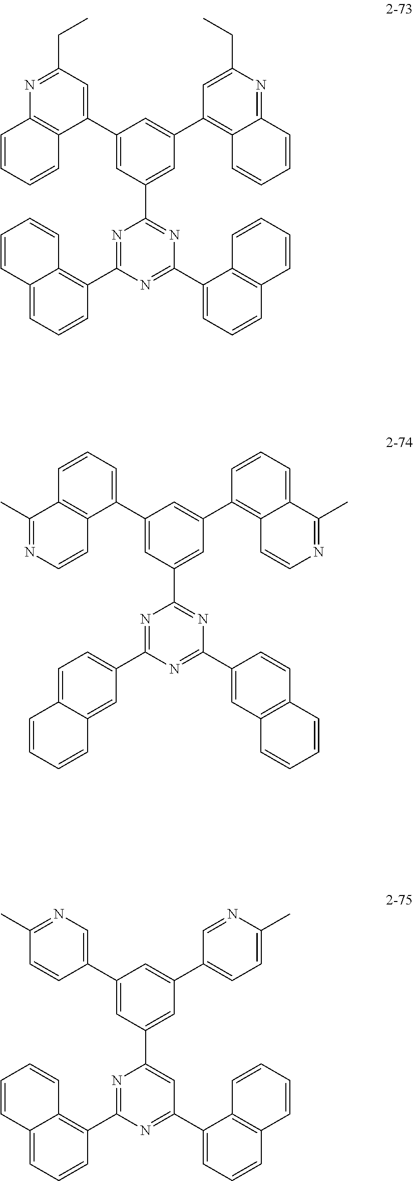

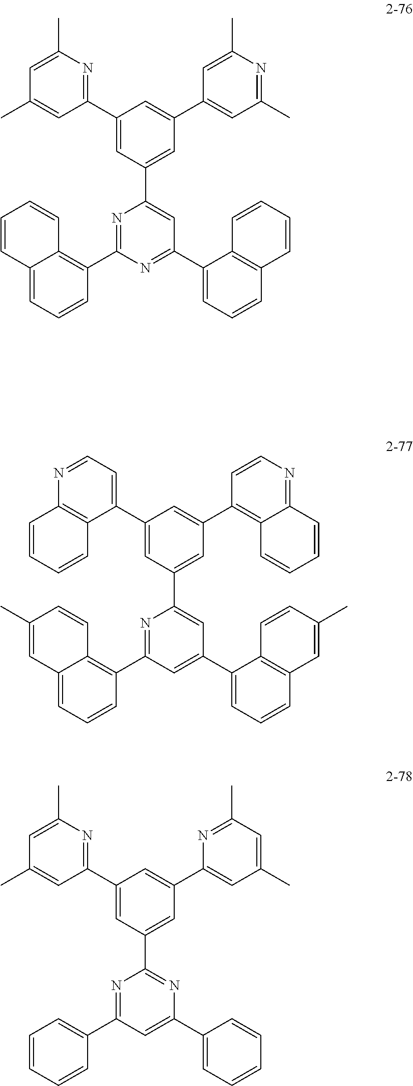

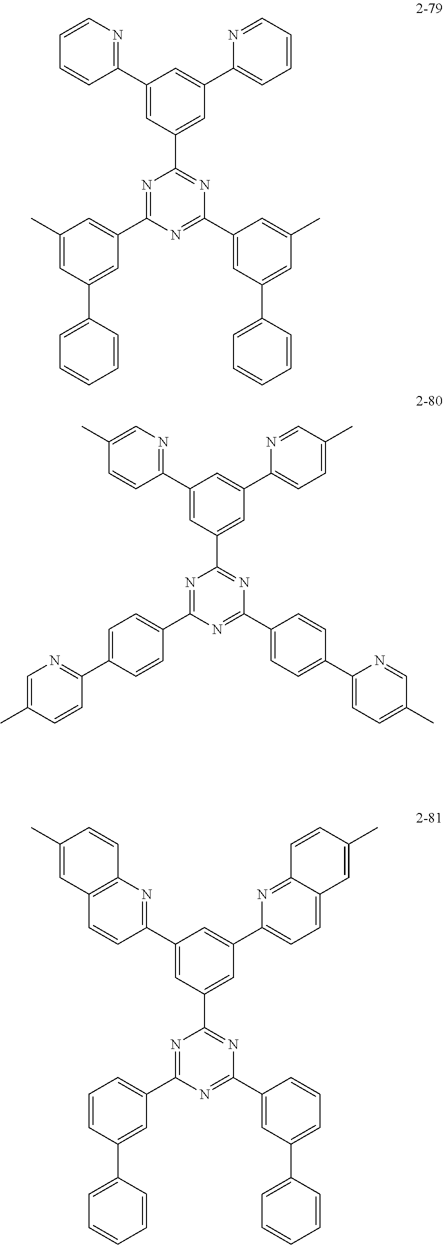

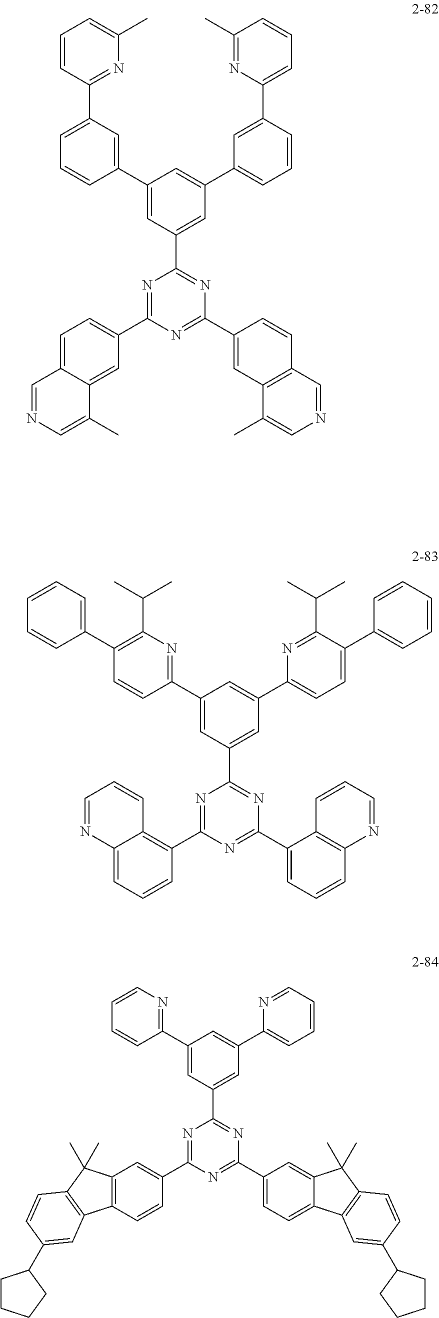 [SMILES: Cc1cccc(-c2cccc(-c3cc(-c4cccc(-c5cccc(C)n5)c4)cc(-c4nc(-c5ccc6cncc(C)c6c5)nc(-c5ccc6cncc(C)c6c5)n4)c3)c2)n1 ; CC(C)c1nc(-c2cc(-c3ccc(-c4ccccc4)c(C(C)C)n3)cc(-c3nc(-c4cccc5ncccc45)nc(-c4cccc5ncccc45)n3)c2)ccc1-c1ccccc1 ; CC1(C)c2ccc(C3CCCC3)cc2-c2ccc(-c3nc(-c4cc(-c5ccccn5)cc(-c5ccccn5)c4)nc(-c4ccc5c(c4)C(C)(C)c4ccc(C6CCCC6)cc4-5)n3)cc21]

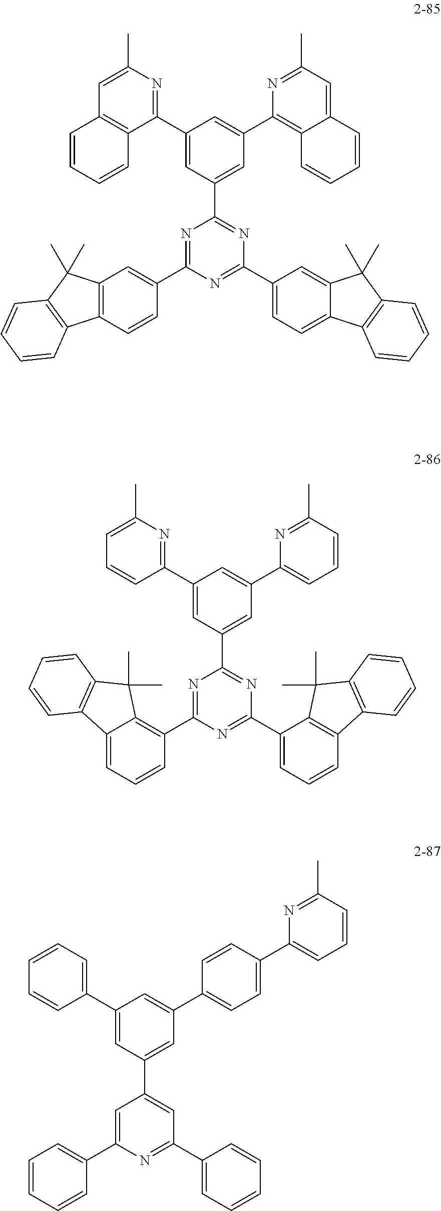 [SMILES: Cc1cc2ccccc2c(-c2cc(-c3nc(-c4ccc5c(c4)C(C)(C)c4ccccc4-5)nc(-c4ccc5c(c4)C(C)(C)c4ccccc4-5)n3)cc(-c3nc(C)cc4ccccc34)c2)n1 ; Cc1cccc(-c2cc(-c3cccc(C)n3)cc(-c3nc(-c4cccc5c4C(C)(C)c4ccccc4-5)nc(-c4cccc5c4C(C)(C)c4ccccc4-5)n3)c2)n1 ; Cc1cccc(-c2ccc(-c3cc(-c4ccccc4)cc(-c4cc(-c5ccccc5)nc(-c5ccccc5)c4)c3)cc2)n1]

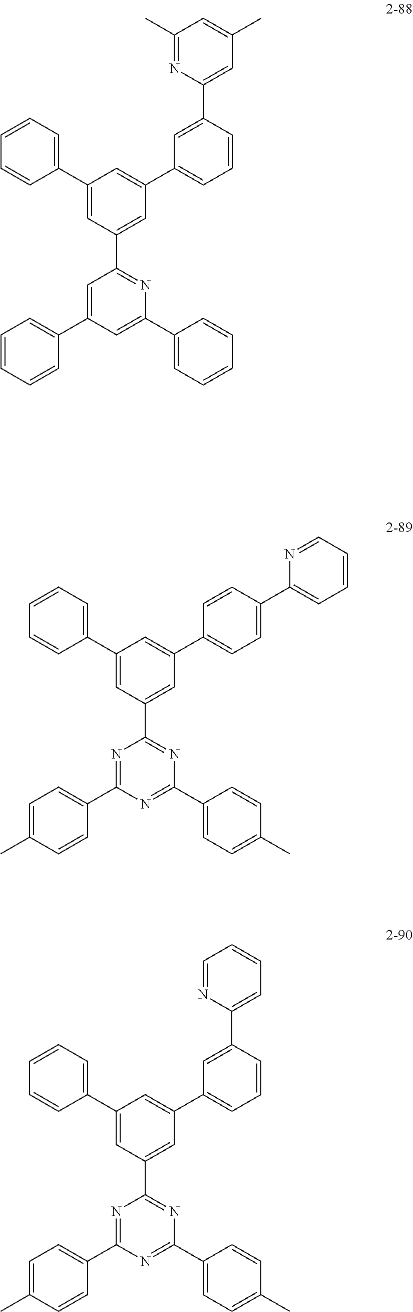

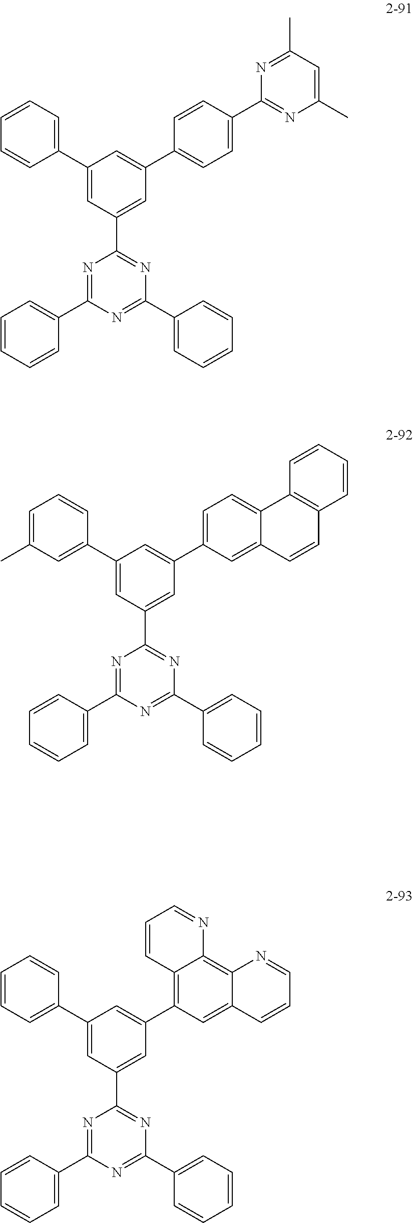

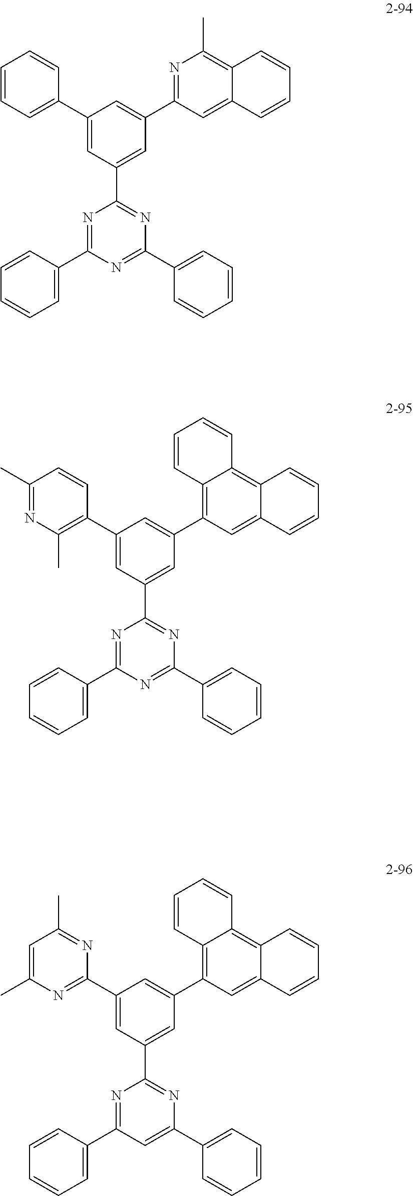 [SMILES: Cc1nc(-c2cc(-c3ccccc3)cc(-c3nc(-c4ccccc4)nc(-c4ccccc4)n3)c2)cc2ccccc12 ; Cc1ccc(-c2cc(-c3nc(-c4ccccc4)nc(-c4ccccc4)n3)cc(-c3cc4ccccc4c4ccccc34)c2)c(C)n1 ; Cc1cc(C)nc(-c2cc(-c3nc(-c4ccccc4)cc(-c4ccccc4)n3)cc(-c3cc4ccccc4c4ccccc34)c2)n1]

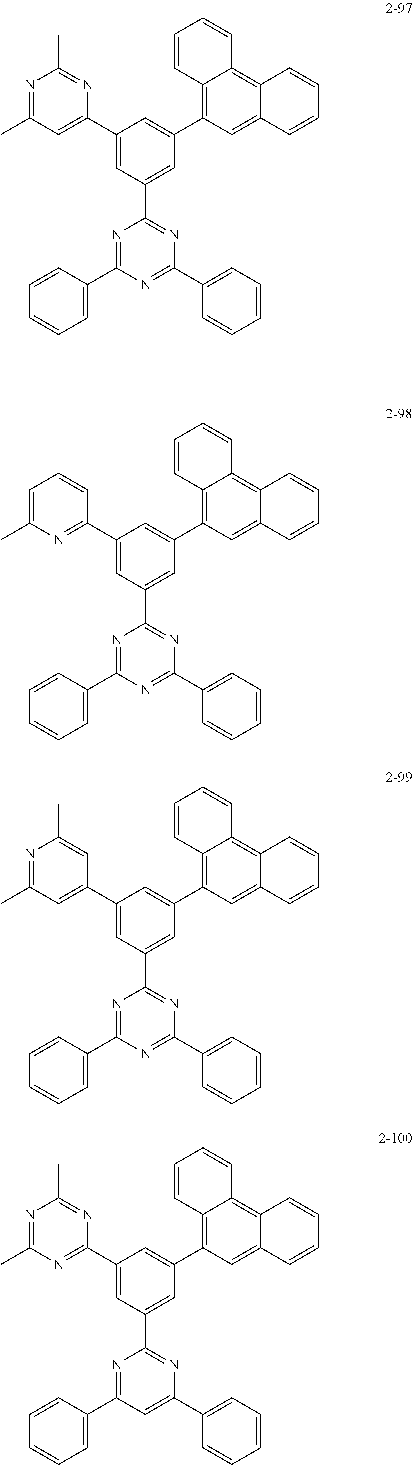 [SMILES: Cc1cc(-c2cc(-c3nc(-c4ccccc4)nc(-c4ccccc4)n3)cc(-c3cc4ccccc4c4ccccc34)c2)nc(C)n1 ; Cc1cccc(-c2cc(-c3nc(-c4ccccc4)nc(-c4ccccc4)n3)cc(-c3cc4ccccc4c4ccccc34)c2)n1 ; Cc1cc(-c2cc(-c3nc(-c4ccccc4)nc(-c4ccccc4)n3)cc(-c3cc4ccccc4c4ccccc34)c2)cc(C)n1 ; Cc1nc(C)nc(-c2cc(-c3nc(-c4ccccc4)cc(-c4ccccc4)n3)cc(-c3cc4ccccc4c4ccccc34)c2)n1]

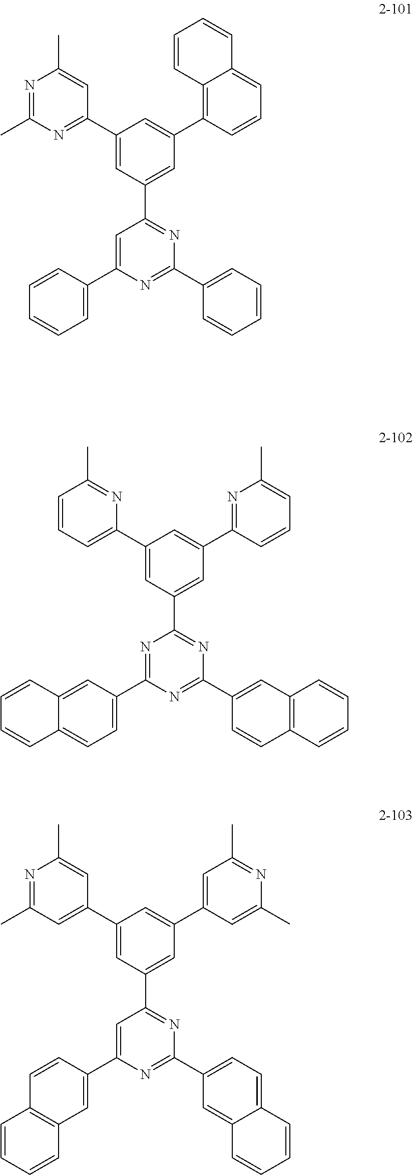 [SMILES: Cc1cc(-c2cc(-c3cc(-c4ccccc4)nc(-c4ccccc4)n3)cc(-c3cccc4ccccc34)c2)nc(C)n1 ; Cc1cccc(-c2cc(-c3cccc(C)n3)cc(-c3nc(-c4ccc5ccccc5c4)nc(-c4ccc5ccccc5c4)n3)c2)n1 ; Cc1cc(-c2cc(-c3cc(C)nc(C)c3)cc(-c3cc(-c4ccc5ccccc5c4)nc(-c4ccc5ccccc5c4)n3)c2)cc(C)n1]

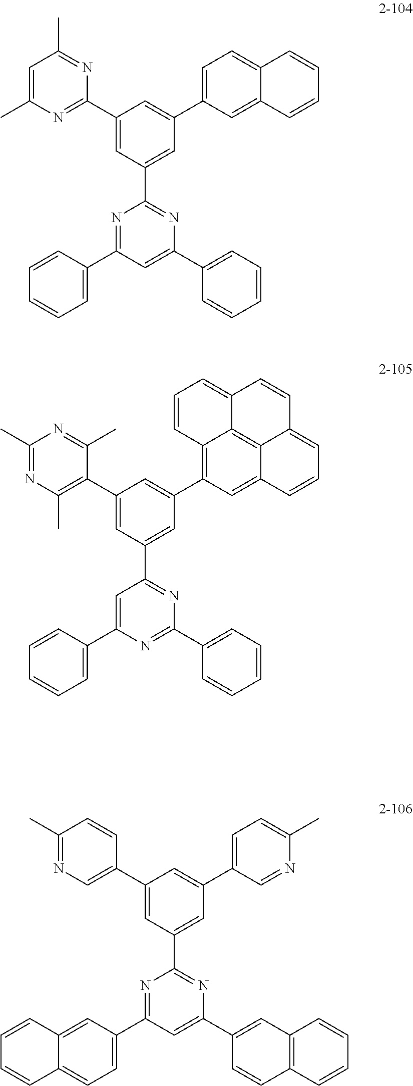 [SMILES: Cc1cc(C)nc(-c2cc(-c3ccc4ccccc4c3)cc(-c3nc(-c4ccccc4)cc(-c4ccccc4)n3)c2)n1 ; Cc1nc(C)c(-c2cc(-c3cc(-c4ccccc4)nc(-c4ccccc4)n3)cc(-c3cc4cccc5ccc6cccc3c6c54)c2)c(C)n1 ; Cc1ccc(-c2cc(-c3ccc(C)nc3)cc(-c3nc(-c4ccc5ccccc5c4)cc(-c4ccc5ccccc5c4)n3)c2)cn1]

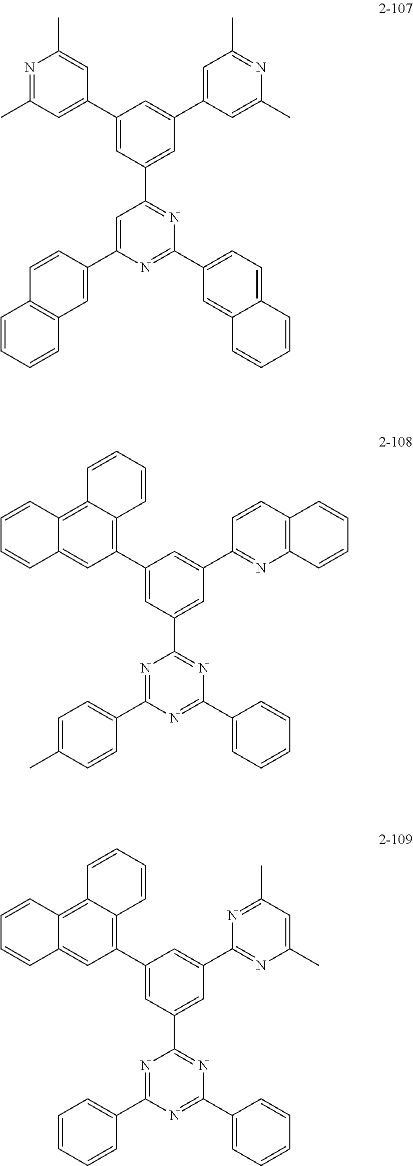 [SMILES: Cc1cc(-c2cc(-c3cc(C)nc(C)c3)cc(-c3cc(-c4ccc5ccccc5c4)nc(-c4ccc5ccccc5c4)n3)c2)cc(C)n1 ; Cc1ccc(-c2nc(-c3ccccc3)nc(-c3cc(-c4ccc5ccccc5n4)cc(-c4cc5ccccc5c5ccccc45)c3)n2)cc1 ; Cc1cc(C)nc(-c2cc(-c3nc(-c4ccccc4)nc(-c4ccccc4)n3)cc(-c3cc4ccccc4c4ccccc34)c2)n1]

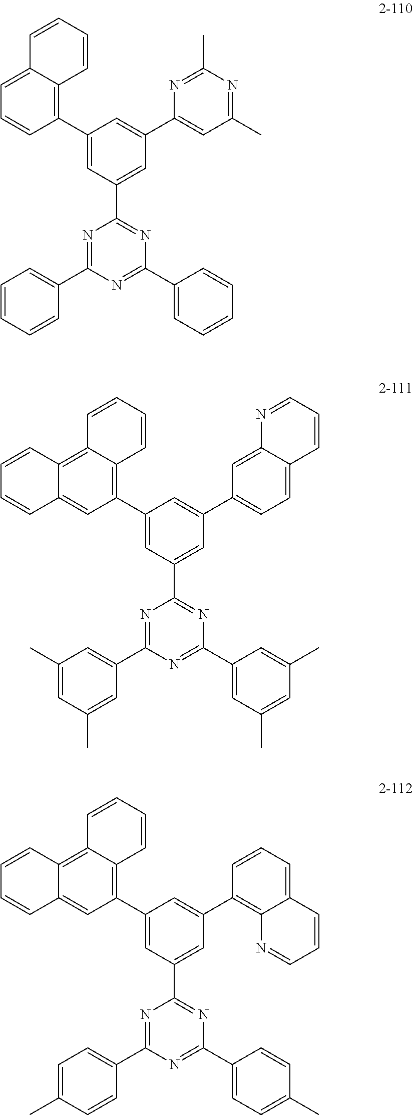 [SMILES: Cc1cc(-c2cc(-c3nc(-c4ccccc4)nc(-c4ccccc4)n3)cc(-c3cccc4ccccc34)c2)nc(C)n1 ; Cc1cc(C)cc(-c2nc(-c3cc(C)cc(C)c3)nc(-c3cc(-c4ccc5cccnc5c4)cc(-c4cc5ccccc5c5ccccc45)c3)n2)c1 ; Cc1ccc(-c2nc(-c3ccc(C)cc3)nc(-c3cc(-c4cc5ccccc5c5ccccc45)cc(-c4cccc5cccnc45)c3)n2)cc1]

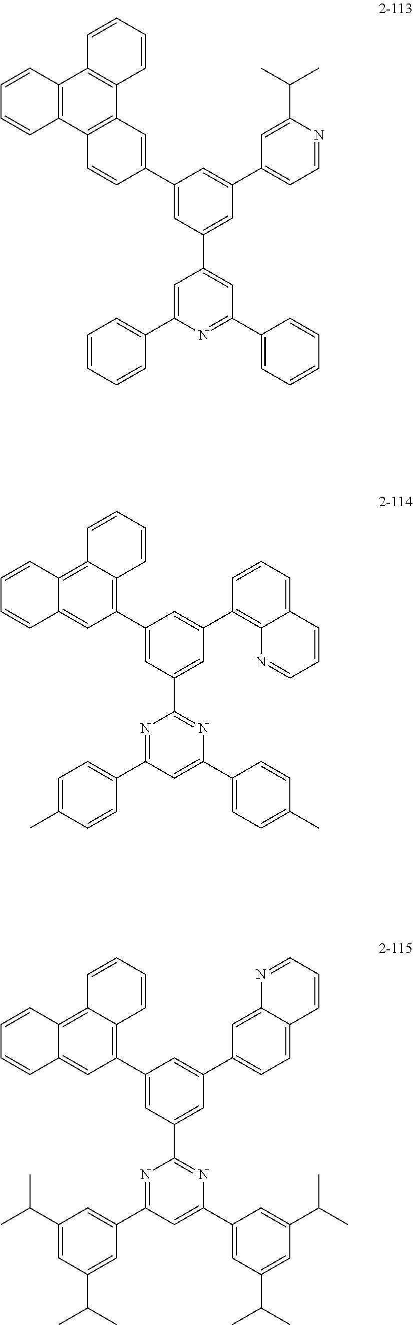 [SMILES: CC(C)c1cc(-c2cc(-c3cc(-c4ccccc4)nc(-c4ccccc4)c3)cc(-c3ccc4c5ccccc5c5ccccc5c4c3)c2)ccn1 ; Cc1ccc(-c2cc(-c3ccc(C)cc3)nc(-c3cc(-c4cc5ccccc5c5ccccc45)cc(-c4cccc5cccnc45)c3)n2)cc1 ; CC(C)c1cc(-c2cc(-c3cc(C(C)C)cc(C(C)C)c3)nc(-c3cc(-c4ccc5cccnc5c4)cc(-c4cc5ccccc5c5ccccc45)c3)n2)cc(C(C)C)c1]

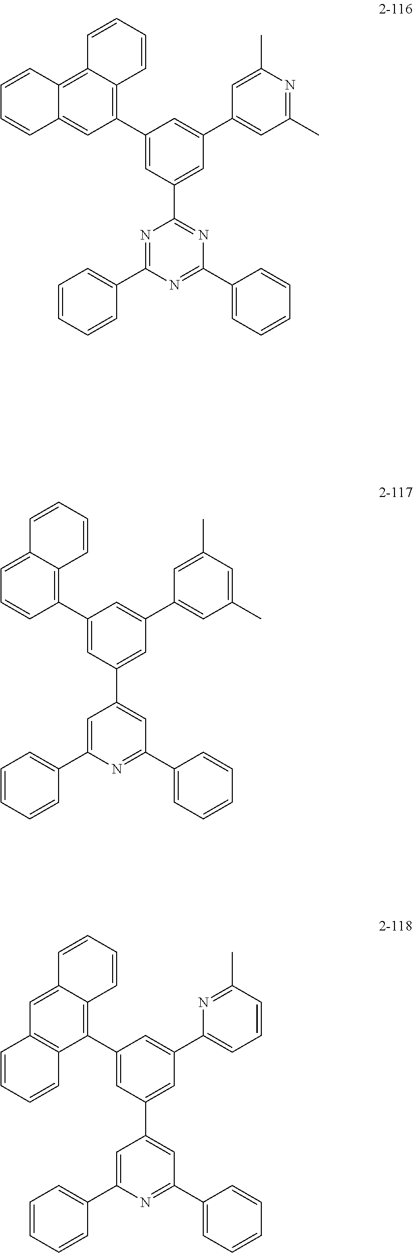 [SMILES: Cc1cc(-c2cc(-c3nc(-c4ccccc4)nc(-c4ccccc4)n3)cc(-c3cc4ccccc4c4ccccc34)c2)cc(C)n1 ; Cc1cc(C)cc(-c2cc(-c3cc(-c4ccccc4)nc(-c4ccccc4)c3)cc(-c3cccc4ccccc34)c2)c1 ; Cc1cccc(-c2cc(-c3cc(-c4ccccc4)nc(-c4ccccc4)c3)cc(-c3c4ccccc4cc4ccccc34)c2)n1]

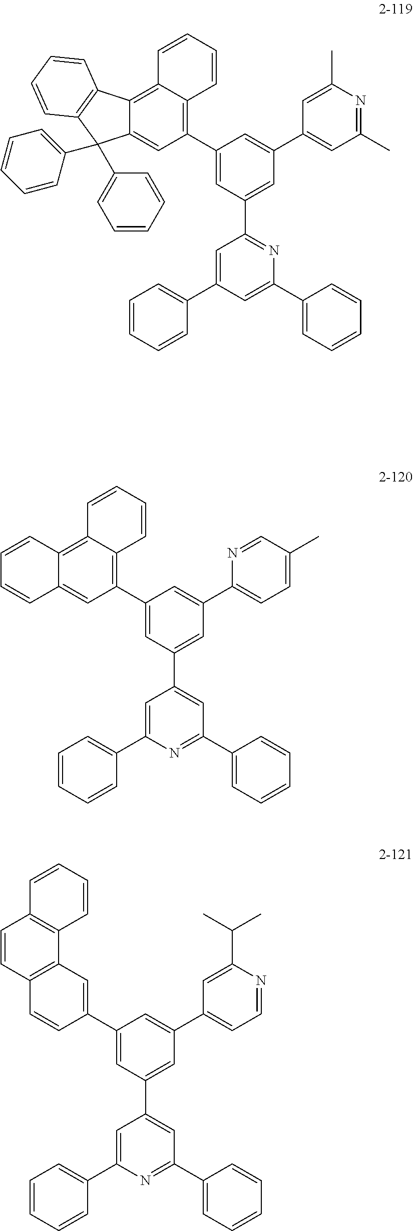 [SMILES: Cc1cc(-c2cc(-c3cc(-c4ccccc4)cc(-c4ccccc4)n3)cc(-c3cc4c(c5ccccc35)-c3ccccc3C4(c3ccccc3)c3ccccc3)c2)cc(C)n1 ; Cc1ccc(-c2cc(-c3cc(-c4ccccc4)nc(-c4ccccc4)c3)cc(-c3cc4ccccc4c4ccccc34)c2)nc1 ; CC(C)c1cc(-c2cc(-c3cc(-c4ccccc4)nc(-c4ccccc4)c3)cc(-c3ccc4ccc5ccccc5c4c3)c2)ccn1]

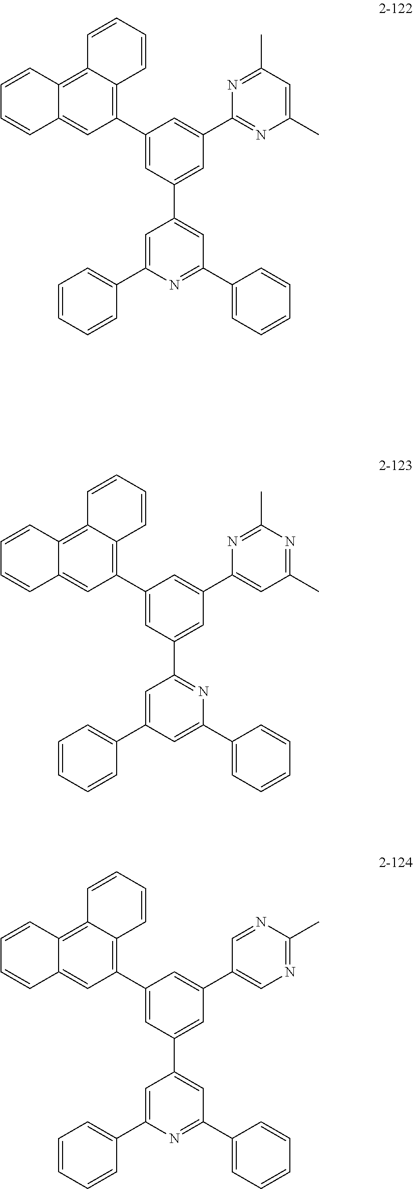 [SMILES: Cc1cc(C)nc(-c2cc(-c3cc(-c4ccccc4)nc(-c4ccccc4)c3)cc(-c3cc4ccccc4c4ccccc34)c2)n1 ; Cc1cc(-c2cc(-c3cc(-c4ccccc4)cc(-c4ccccc4)n3)cc(-c3cc4ccccc4c4ccccc34)c2)nc(C)n1 ; Cc1ncc(-c2cc(-c3cc(-c4ccccc4)nc(-c4ccccc4)c3)cc(-c3cc4ccccc4c4ccccc34)c2)cn1]

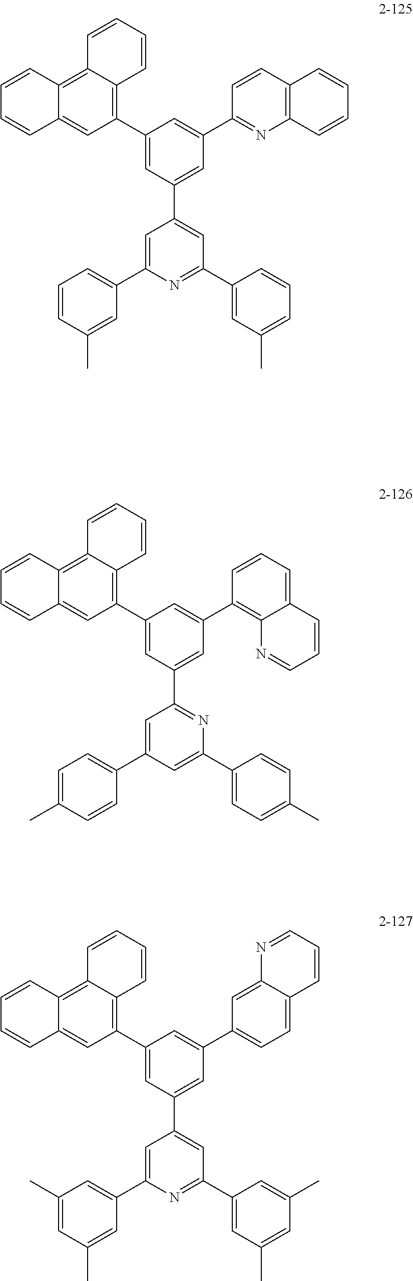 [SMILES: Cc1cccc(-c2cc(-c3cc(-c4ccc5ccccc5n4)cc(-c4cc5ccccc5c5ccccc45)c3)cc(-c3cccc(C)c3)n2)c1 ; Cc1ccc(-c2cc(-c3ccc(C)cc3)nc(-c3cc(-c4cc5ccccc5c5ccccc45)cc(-c4cccc5cccnc45)c3)c2)cc1 ; Cc1cc(C)cc(-c2cc(-c3cc(-c4ccc5cccnc5c4)cc(-c4cc5ccccc5c5ccccc45)c3)cc(-c3cc(C)cc(C)c3)n2)c1]

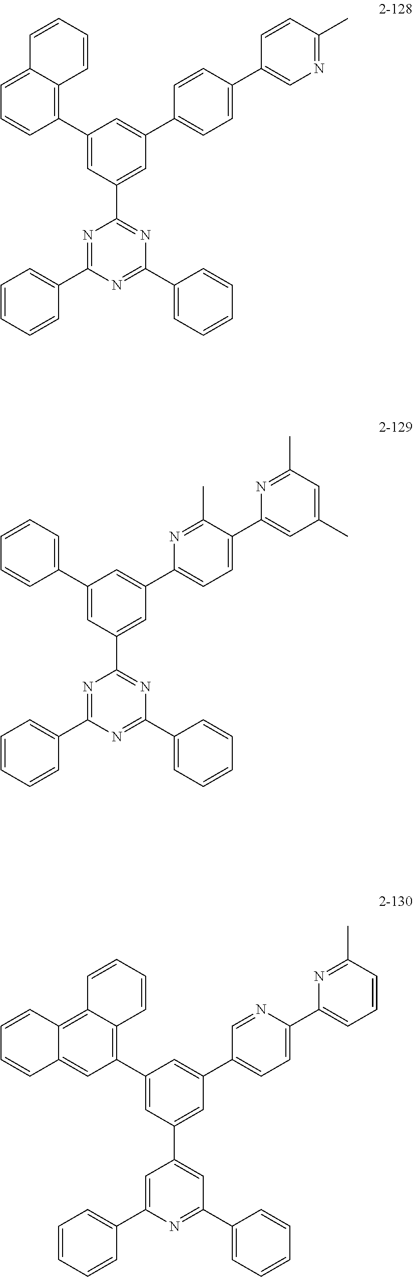 [SMILES: Cc1ccc(-c2ccc(-c3cc(-c4nc(-c5ccccc5)nc(-c5ccccc5)n4)cc(-c4cccc5ccccc45)c3)cc2)cn1 ; Cc1cc(C)nc(-c2ccc(-c3cc(-c4ccccc4)cc(-c4nc(-c5ccccc5)nc(-c5ccccc5)n4)c3)nc2C)c1 ; Cc1cccc(-c2ccc(-c3cc(-c4cc(-c5ccccc5)nc(-c5ccccc5)c4)cc(-c4cc5ccccc5c5ccccc45)c3)cn2)n1]

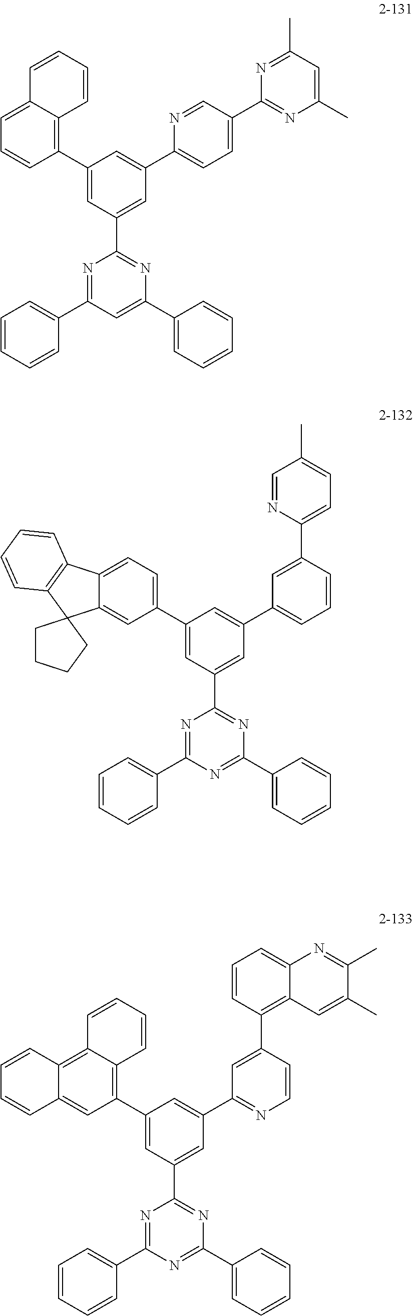 [SMILES: Cc1cc(C)nc(-c2ccc(-c3cc(-c4nc(-c5ccccc5)cc(-c5ccccc5)n4)cc(-c4cccc5ccccc45)c3)nc2)n1 ; Cc1ccc(-c2cccc(-c3cc(-c4ccc5c(c4)C4(CCCC4)c4ccccc4-5)cc(-c4nc(-c5ccccc5)nc(-c5ccccc5)n4)c3)c2)nc1 ; Cc1cc2c(-c3ccnc(-c4cc(-c5nc(-c6ccccc6)nc(-c6ccccc6)n5)cc(-c5cc6ccccc6c6ccccc56)c4)c3)cccc2nc1C]

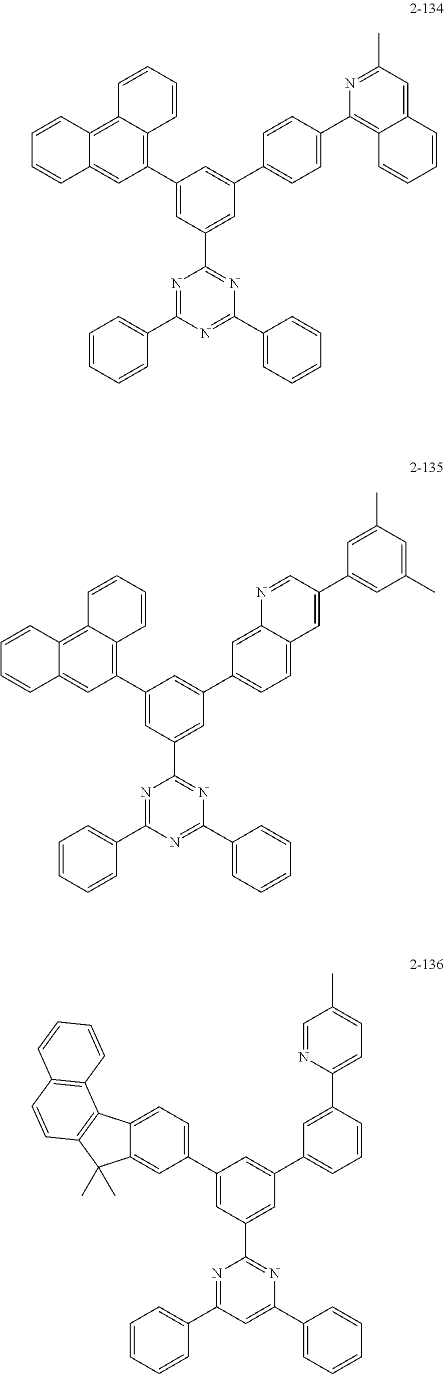 [SMILES: Cc1cc2ccccc2c(-c2ccc(-c3cc(-c4nc(-c5ccccc5)nc(-c5ccccc5)n4)cc(-c4cc5ccccc5c5ccccc45)c3)cc2)n1 ; Cc1cc(C)cc(-c2cnc3cc(-c4cc(-c5nc(-c6ccccc6)nc(-c6ccccc6)n5)cc(-c5cc6ccccc6c6ccccc56)c4)ccc3c2)c1 ; Cc1ccc(-c2cccc(-c3cc(-c4ccc5c(c4)C(C)(C)c4ccc6ccccc6c4-5)cc(-c4nc(-c5ccccc5)cc(-c5ccccc5)n4)c3)c2)nc1]

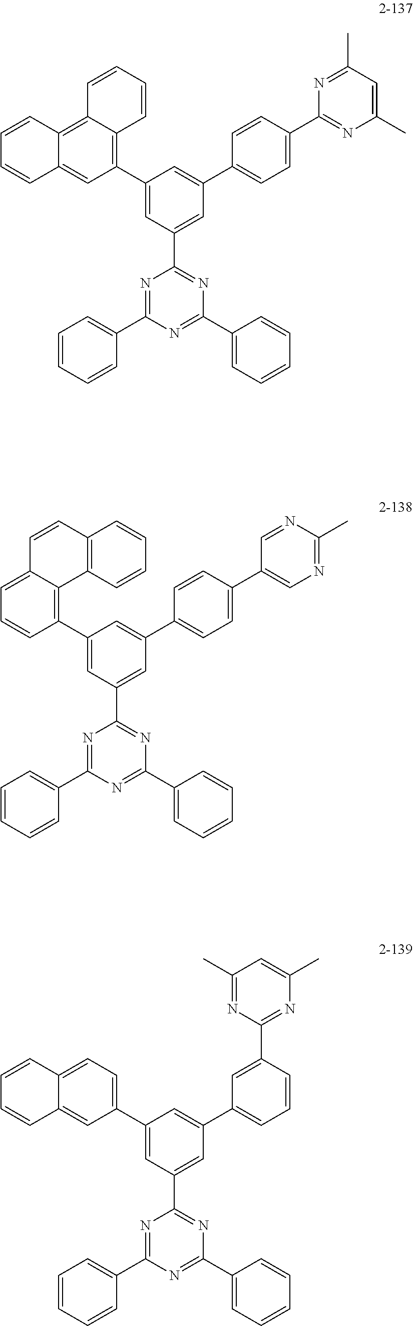 [SMILES: Cc1cc(C)nc(-c2ccc(-c3cc(-c4nc(-c5ccccc5)nc(-c5ccccc5)n4)cc(-c4cc5ccccc5c5ccccc45)c3)cc2)n1 ; Cc1ncc(-c2ccc(-c3cc(-c4nc(-c5ccccc5)nc(-c5ccccc5)n4)cc(-c4cccc5ccc6ccccc6c45)c3)cc2)cn1 ; Cc1cc(C)nc(-c2cccc(-c3cc(-c4ccc5ccccc5c4)cc(-c4nc(-c5ccccc5)nc(-c5ccccc5)n4)c3)c2)n1]

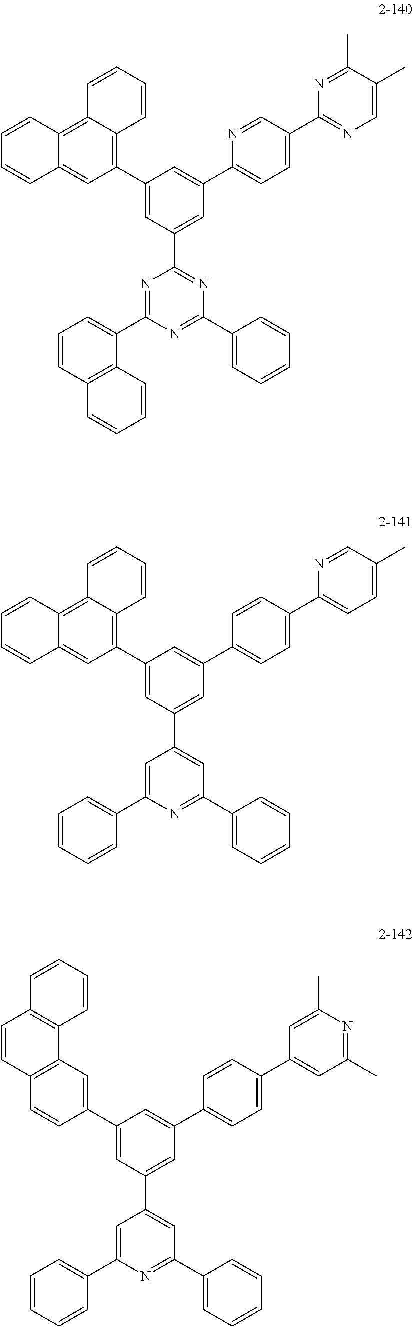 [SMILES: Cc1cnc(-c2ccc(-c3cc(-c4nc(-c5ccccc5)nc(-c5cccc6ccccc56)n4)cc(-c4cc5ccccc5c5ccccc45)c3)nc2)nc1C ; Cc1ccc(-c2ccc(-c3cc(-c4cc(-c5ccccc5)nc(-c5ccccc5)c4)cc(-c4cc5ccccc5c5ccccc45)c3)cc2)nc1 ; Cc1cc(-c2ccc(-c3cc(-c4cc(-c5ccccc5)nc(-c5ccccc5)c4)cc(-c4ccc5ccc6ccccc6c5c4)c3)cc2)cc(C)n1]

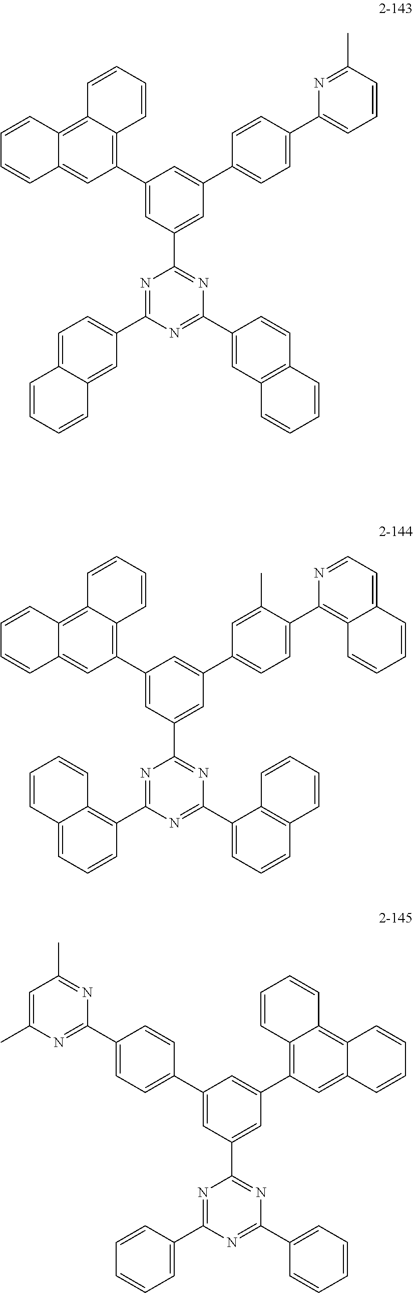 [SMILES: Cc1cccc(-c2ccc(-c3cc(-c4nc(-c5ccc6ccccc6c5)nc(-c5ccc6ccccc6c5)n4)cc(-c4cc5ccccc5c5ccccc45)c3)cc2)n1 ; Cc1cc(-c2cc(-c3nc(-c4cccc5ccccc45)nc(-c4cccc5ccccc45)n3)cc(-c3cc4ccccc4c4ccccc34)c2)ccc1-c1nccc2ccccc12 ; Cc1cc(C)nc(-c2ccc(-c3cc(-c4nc(-c5ccccc5)nc(-c5ccccc5)n4)cc(-c4cc5ccccc5c5ccccc45)c3)cc2)n1]

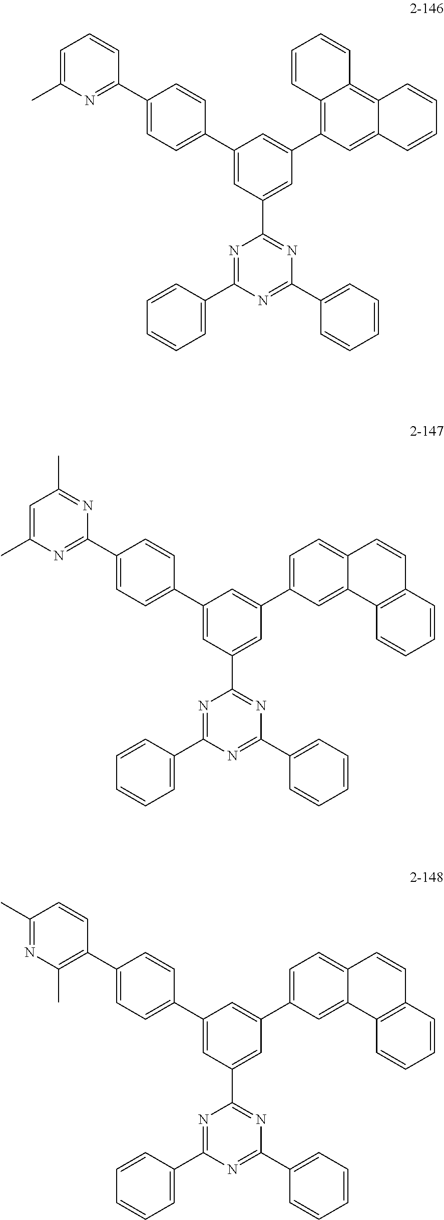 [SMILES: Cc1cccc(-c2ccc(-c3cc(-c4nc(-c5ccccc5)nc(-c5ccccc5)n4)cc(-c4cc5ccccc5c5ccccc45)c3)cc2)n1 ; Cc1cc(C)nc(-c2ccc(-c3cc(-c4ccc5ccc6ccccc6c5c4)cc(-c4nc(-c5ccccc5)nc(-c5ccccc5)n4)c3)cc2)n1 ; Cc1ccc(-c2ccc(-c3cc(-c4ccc5ccc6ccccc6c5c4)cc(-c4nc(-c5ccccc5)nc(-c5ccccc5)n4)c3)cc2)c(C)n1]

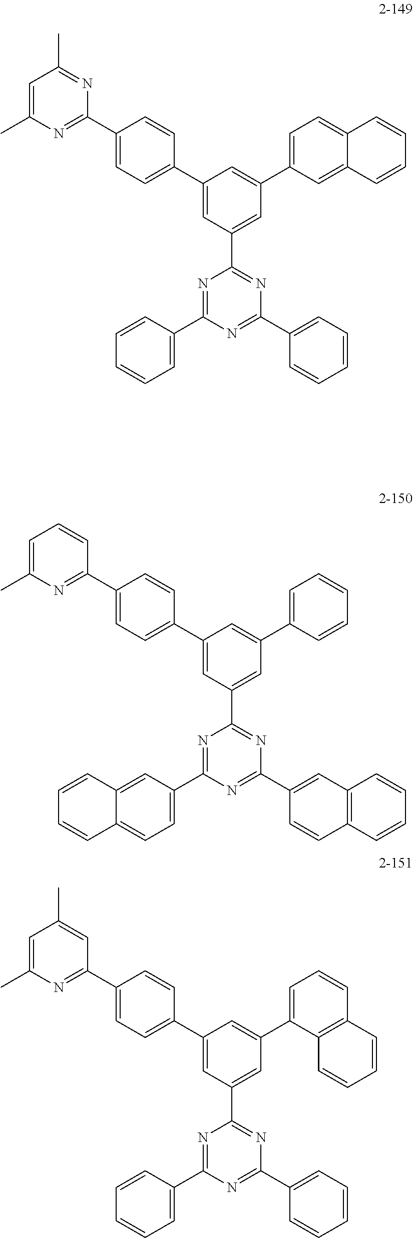 [SMILES: Cc1cc(C)nc(-c2ccc(-c3cc(-c4ccc5ccccc5c4)cc(-c4nc(-c5ccccc5)nc(-c5ccccc5)n4)c3)cc2)n1 ; Cc1cccc(-c2ccc(-c3cc(-c4ccccc4)cc(-c4nc(-c5ccc6ccccc6c5)nc(-c5ccc6ccccc6c5)n4)c3)cc2)n1 ; Cc1cc(C)nc(-c2ccc(-c3cc(-c4nc(-c5ccccc5)nc(-c5ccccc5)n4)cc(-c4cccc5ccccc45)c3)cc2)c1]

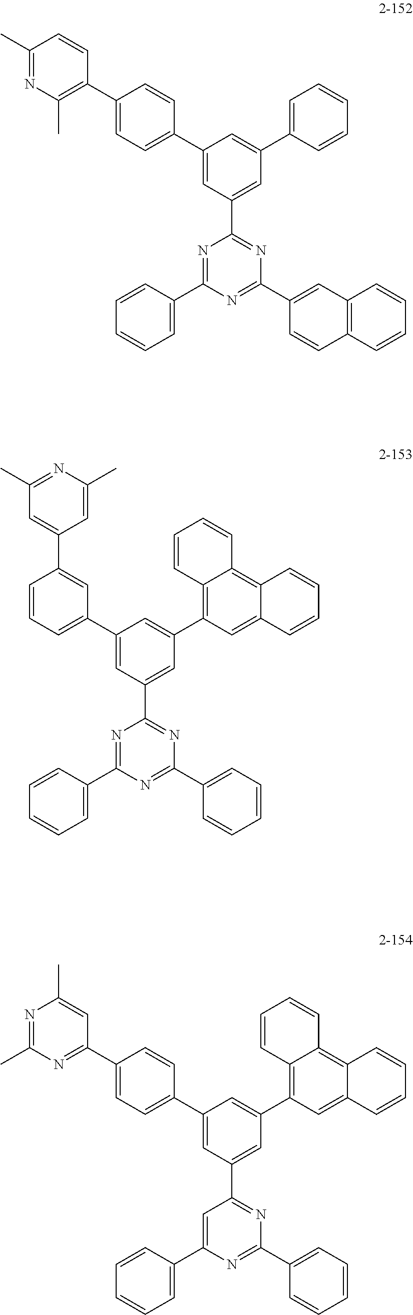 [SMILES: Cc1ccc(-c2ccc(-c3cc(-c4ccccc4)cc(-c4nc(-c5ccccc5)nc(-c5ccc6ccccc6c5)n4)c3)cc2)c(C)n1 ; Cc1cc(-c2cccc(-c3cc(-c4nc(-c5ccccc5)nc(-c5ccccc5)n4)cc(-c4cc5ccccc5c5ccccc45)c3)c2)cc(C)n1 ; Cc1cc(-c2ccc(-c3cc(-c4cc(-c5ccccc5)nc(-c5ccccc5)n4)cc(-c4cc5ccccc5c5ccccc45)c3)cc2)nc(C)n1]

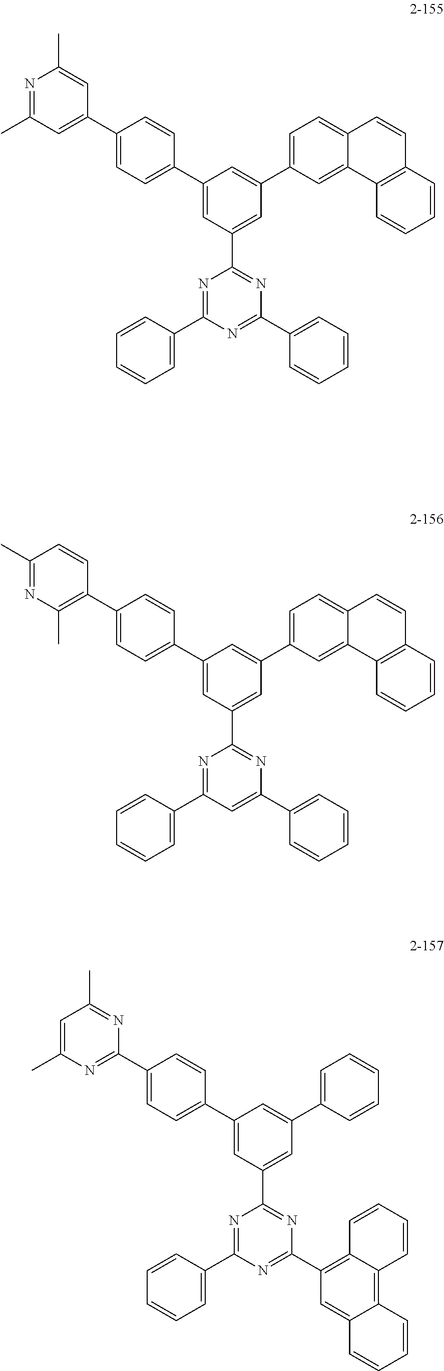 [SMILES: Cc1cc(-c2ccc(-c3cc(-c4ccc5ccc6ccccc6c5c4)cc(-c4nc(-c5ccccc5)nc(-c5ccccc5)n4)c3)cc2)cc(C)n1 ; Cc1ccc(-c2ccc(-c3cc(-c4ccc5ccc6ccccc6c5c4)cc(-c4nc(-c5ccccc5)cc(-c5ccccc5)n4)c3)cc2)c(C)n1 ; Cc1cc(C)nc(-c2ccc(-c3cc(-c4ccccc4)cc(-c4nc(-c5ccccc5)nc(-c5cc6ccccc6c6ccccc56)n4)c3)cc2)n1]

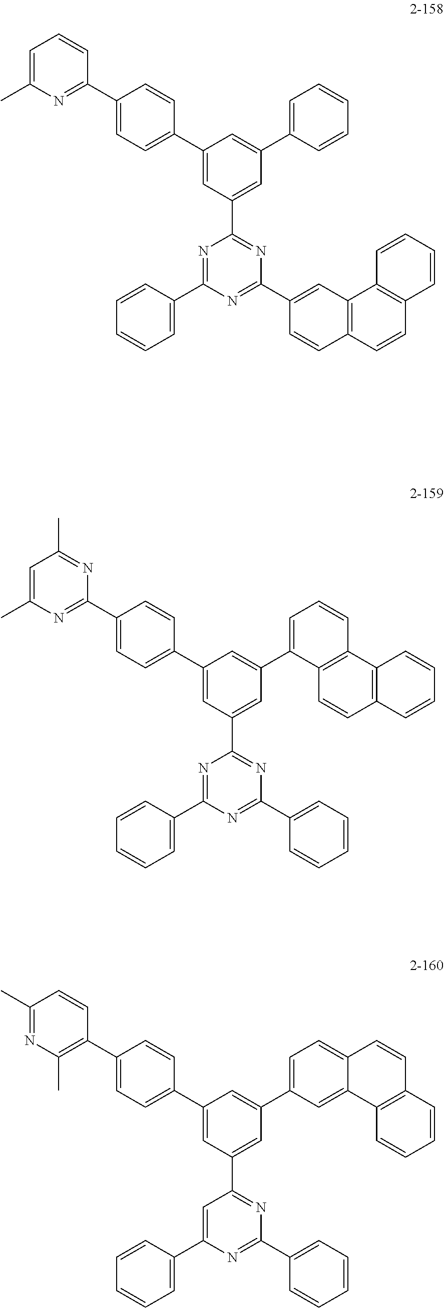 [SMILES: Cc1cccc(-c2ccc(-c3cc(-c4ccccc4)cc(-c4nc(-c5ccccc5)nc(-c5ccc6ccc7ccccc7c6c5)n4)c3)cc2)n1 ; Cc1cc(C)nc(-c2ccc(-c3cc(-c4nc(-c5ccccc5)nc(-c5ccccc5)n4)cc(-c4cccc5c4ccc4ccccc45)c3)cc2)n1 ; Cc1ccc(-c2ccc(-c3cc(-c4ccc5ccc6ccccc6c5c4)cc(-c4cc(-c5ccccc5)nc(-c5ccccc5)n4)c3)cc2)c(C)n1]

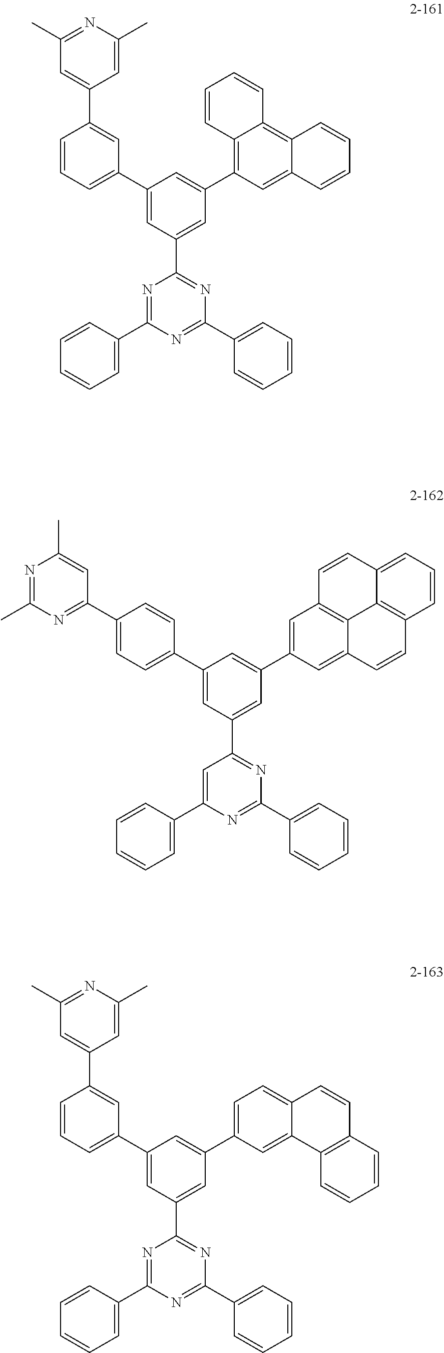 [SMILES: Cc1cc(-c2cccc(-c3cc(-c4nc(-c5ccccc5)nc(-c5ccccc5)n4)cc(-c4cc5ccccc5c5ccccc45)c3)c2)cc(C)n1 ; Cc1cc(-c2ccc(-c3cc(-c4cc5ccc6cccc7ccc(c4)c5c67)cc(-c4cc(-c5ccccc5)nc(-c5ccccc5)n4)c3)cc2)nc(C)n1 ; Cc1cc(-c2cccc(-c3cc(-c4ccc5ccc6ccccc6c5c4)cc(-c4nc(-c5ccccc5)nc(-c5ccccc5)n4)c3)c2)cc(C)n1]

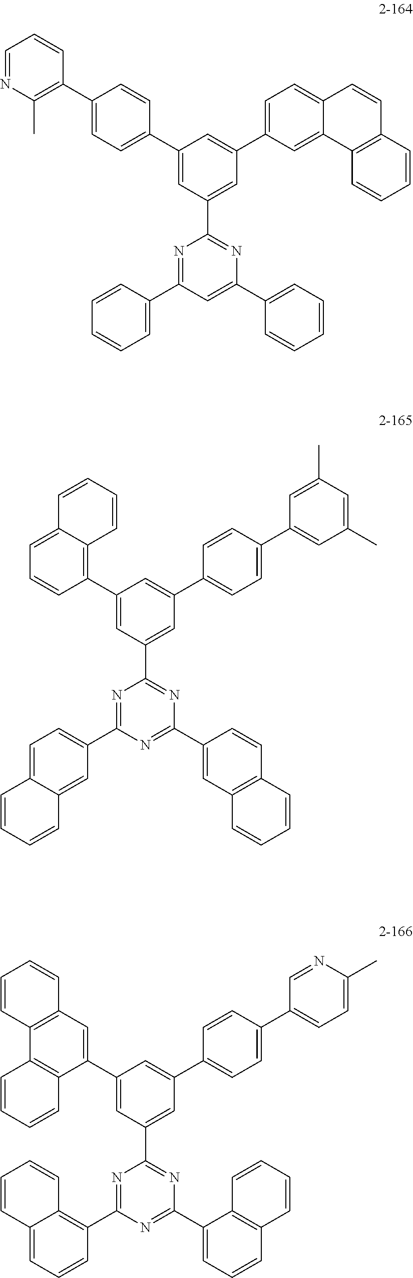 [SMILES: Cc1ncccc1-c1ccc(-c2cc(-c3ccc4ccc5ccccc5c4c3)cc(-c3nc(-c4ccccc4)cc(-c4ccccc4)n3)c2)cc1 ; Cc1cc(C)cc(-c2ccc(-c3cc(-c4nc(-c5ccc6ccccc6c5)nc(-c5ccc6ccccc6c5)n4)cc(-c4cccc5ccccc45)c3)cc2)c1 ; Cc1ccc(-c2ccc(-c3cc(-c4nc(-c5cccc6ccccc56)nc(-c5cccc6ccccc56)n4)cc(-c4cc5ccccc5c5ccccc45)c3)cc2)cn1]

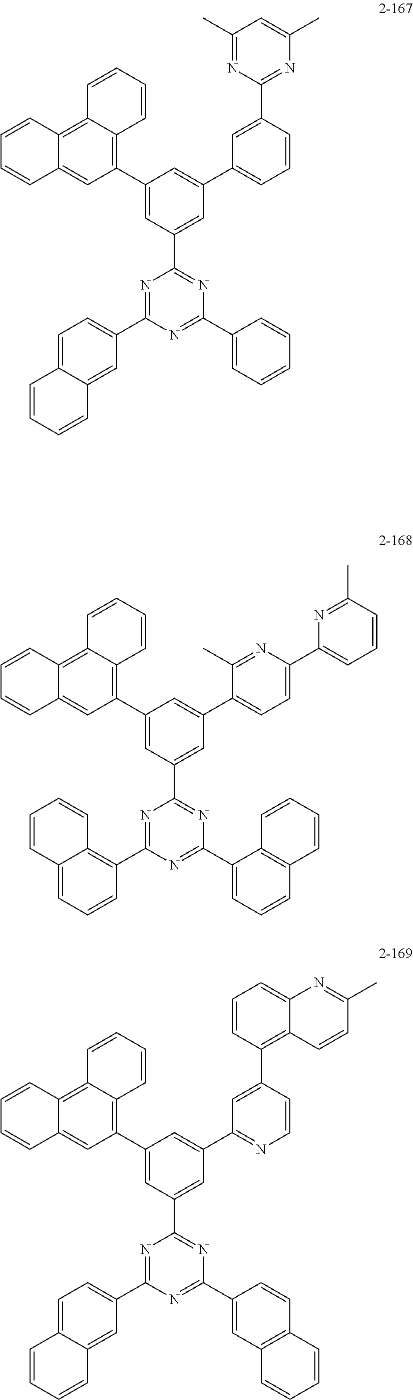 [SMILES: Cc1cc(C)nc(-c2cccc(-c3cc(-c4nc(-c5ccccc5)nc(-c5ccc6ccccc6c5)n4)cc(-c4cc5ccccc5c5ccccc45)c3)c2)n1 ; Cc1cccc(-c2ccc(-c3cc(-c4nc(-c5cccc6ccccc56)nc(-c5cccc6ccccc56)n4)cc(-c4cc5ccccc5c5ccccc45)c3)c(C)n2)n1 ; Cc1ccc2c(-c3ccnc(-c4cc(-c5nc(-c6ccc7ccccc7c6)nc(-c6ccc7ccccc7c6)n5)cc(-c5cc6ccccc6c6ccccc56)c4)c3)cccc2n1]

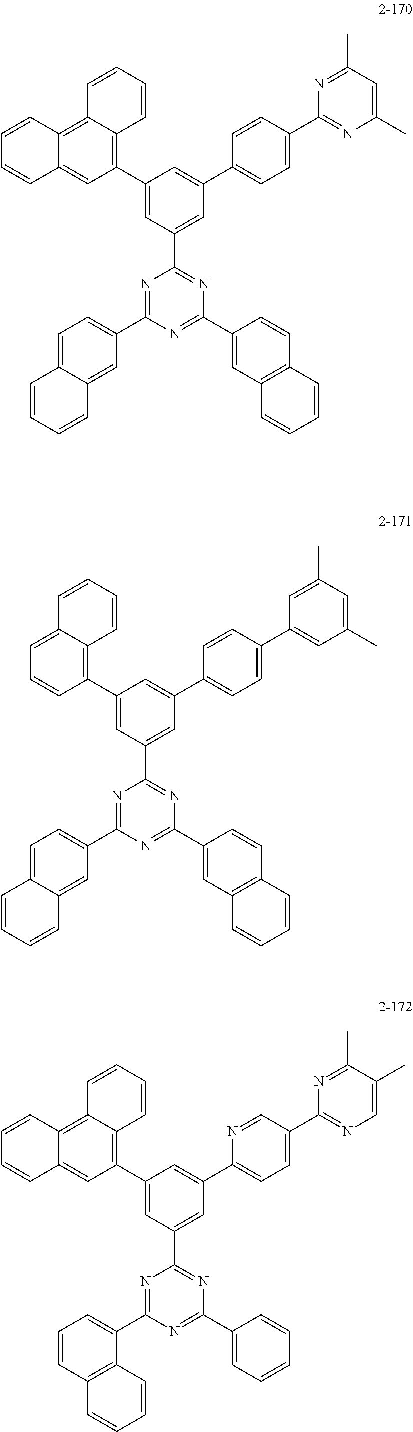 [SMILES: Cc1cc(C)nc(-c2ccc(-c3cc(-c4nc(-c5ccc6ccccc6c5)nc(-c5ccc6ccccc6c5)n4)cc(-c4cc5ccccc5c5ccccc45)c3)cc2)n1 ; Cc1cc(C)cc(-c2ccc(-c3cc(-c4nc(-c5ccc6ccccc6c5)nc(-c5ccc6ccccc6c5)n4)cc(-c4cccc5ccccc45)c3)cc2)c1 ; Cc1cnc(-c2ccc(-c3cc(-c4nc(-c5ccccc5)nc(-c5cccc6ccccc56)n4)cc(-c4cc5ccccc5c5ccccc45)c3)nc2)nc1C]

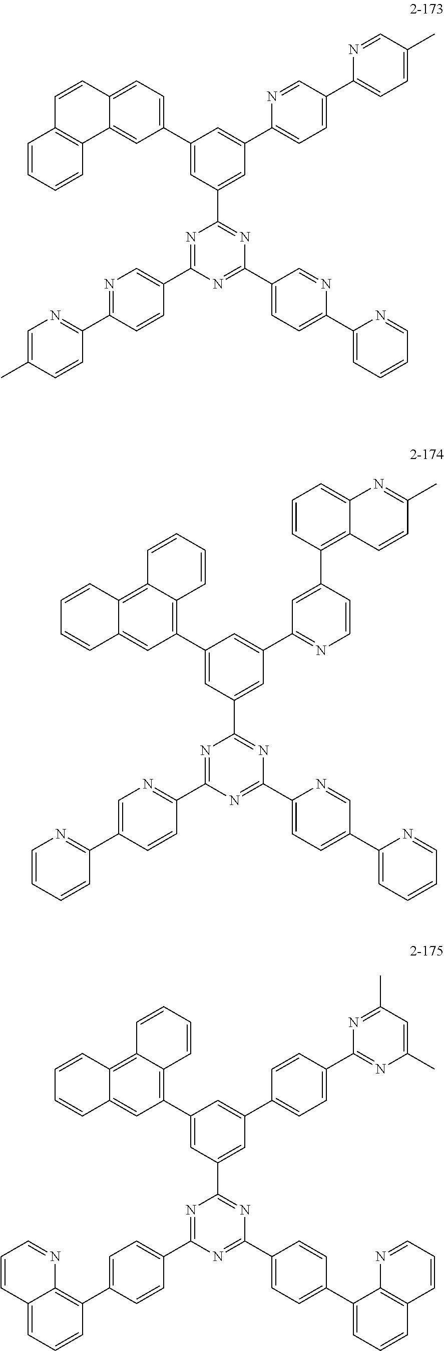

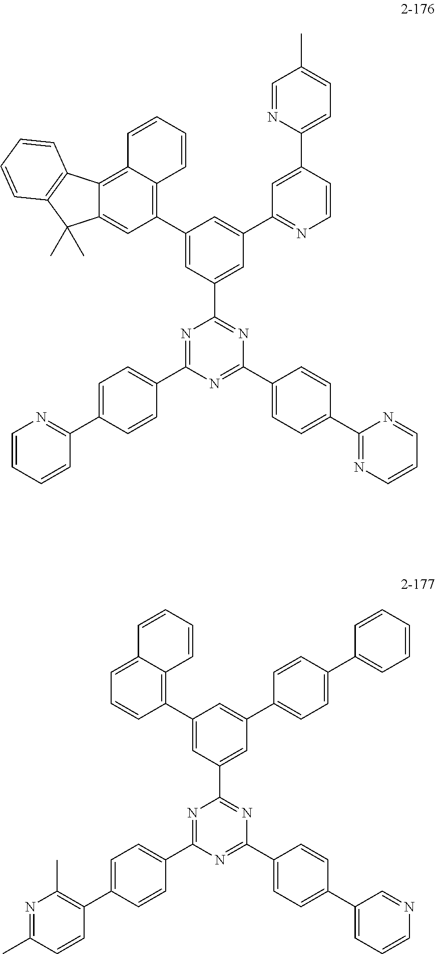 [SMILES: Cc1ccc(-c2ccnc(-c3cc(-c4nc(-c5ccc(-c6ccccn6)cc5)nc(-c5ccc(-c6ncccn6)cc5)n4)cc(-c4cc5c(c6ccccc46)-c4ccccc4C5(C)C)c3)c2)nc1 ; Cc1ccc(-c2ccc(-c3nc(-c4ccc(-c5cccnc5)cc4)nc(-c4cc(-c5ccc(-c6ccccc6)cc5)cc(-c5cccc6ccccc56)c4)n3)cc2)c(C)n1]

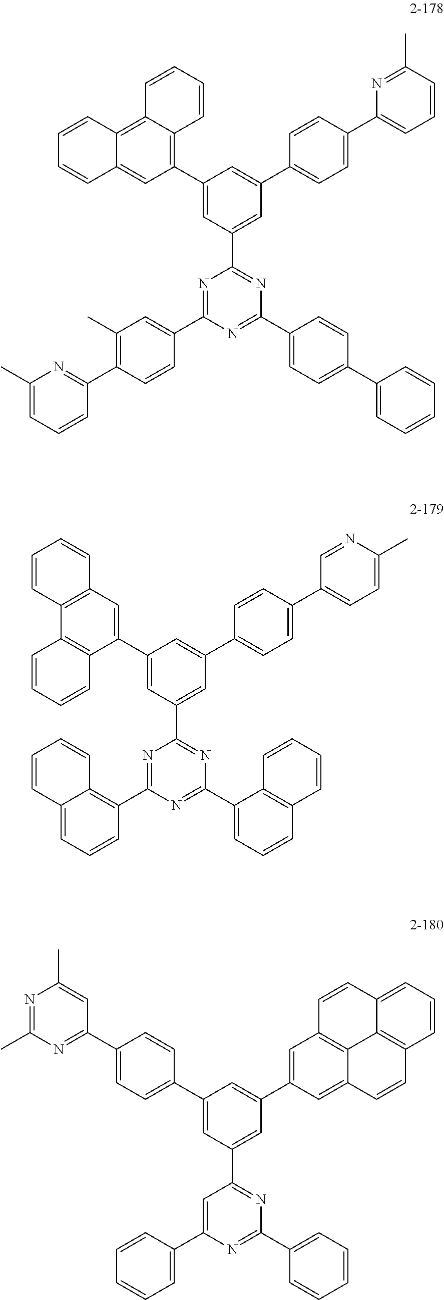

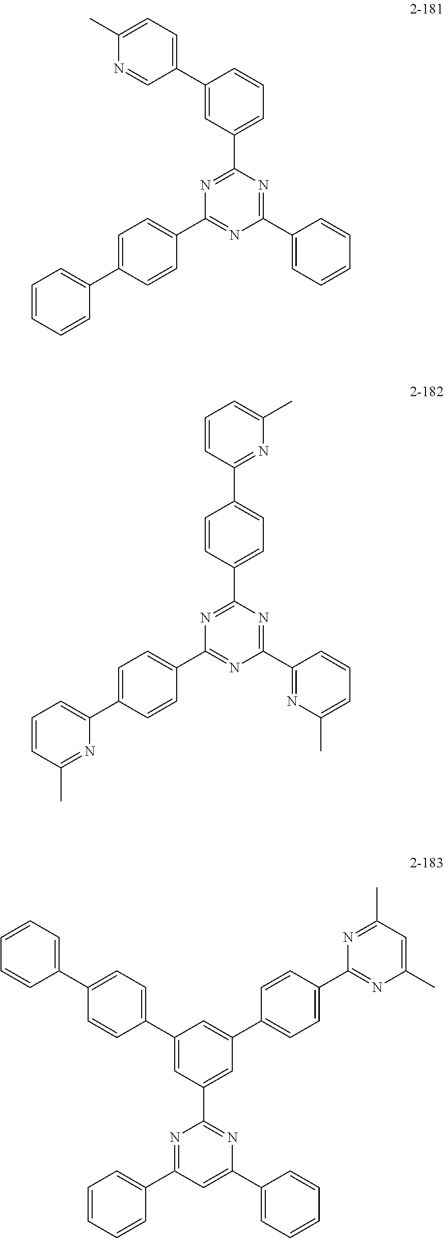 [SMILES: Cc1ccc(-c2cccc(-c3nc(-c4ccccc4)nc(-c4ccc(-c5ccccc5)cc4)n3)c2)cn1 ; Cc1cccc(-c2ccc(-c3nc(-c4ccc(-c5cccc(C)n5)cc4)nc(-c4cccc(C)n4)n3)cc2)n1 ; Cc1cc(C)nc(-c2ccc(-c3cc(-c4ccc(-c5ccccc5)cc4)cc(-c4nc(-c5ccccc5)cc(-c5ccccc5)n4)c3)cc2)n1]

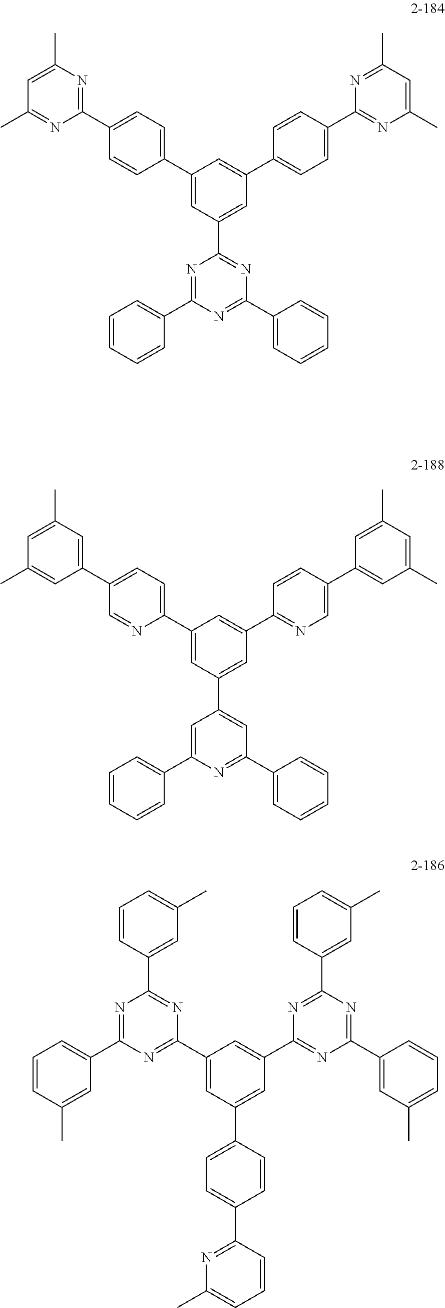

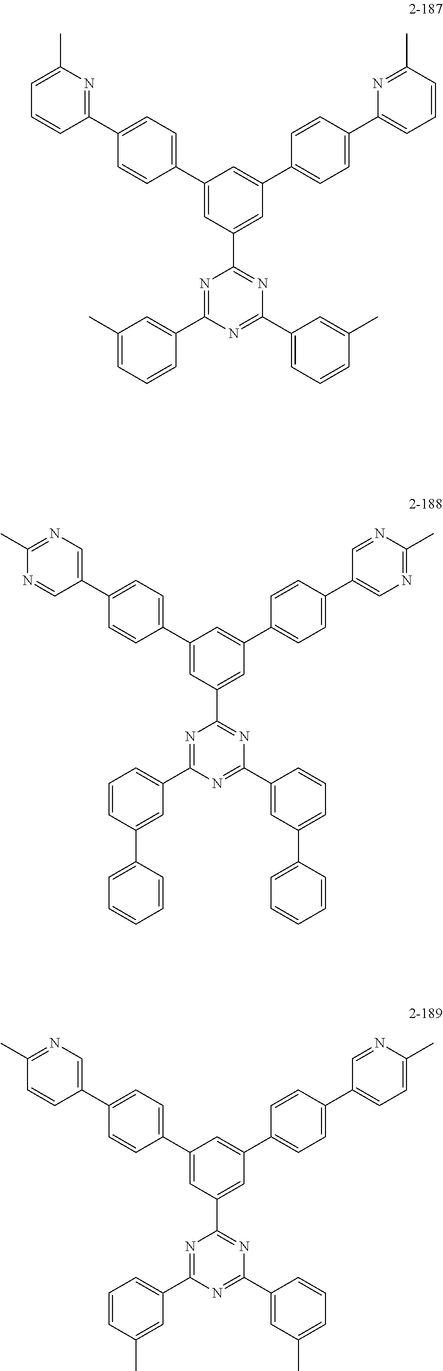

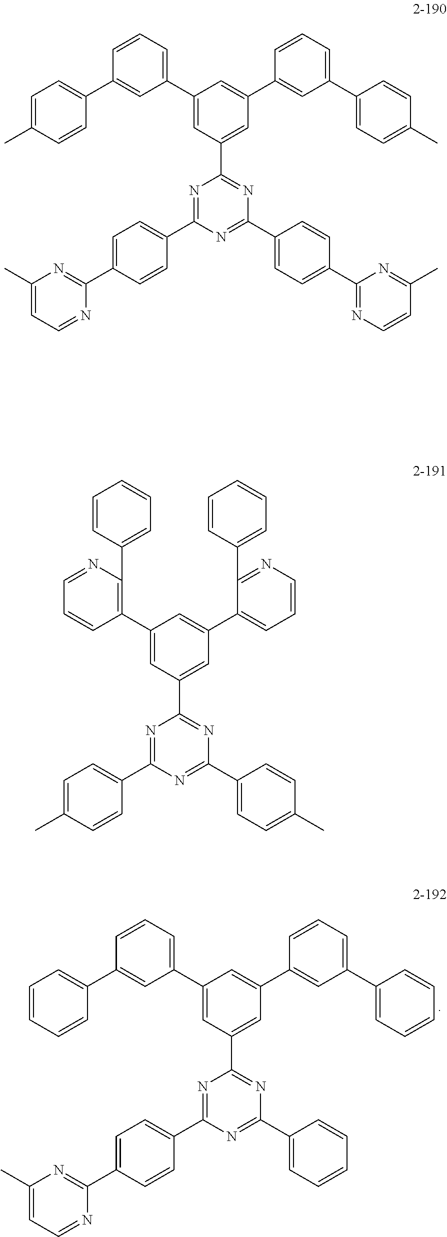

The first compound represented by Formula 1 may include i) a partial structure in which a 5-membered ring and a 6-membered ring are condensed (e.g., fused), for example, the first compound may include at least one indole group or carbazole group, and ii) various substituents having hole transporting capabilities and substituents having electron transporting capabilities. Therefore, in an organic light-emitting device in which the first compound represented by Formula 1 is included in an emission layer (e.g., as a host in the emission layer) and/or a buffer layer, a balance of charges (a balance of holes and electrons) in the emission layer may be excellent (or suitable) and charges may be smoothly injected into the emission layer, thereby improving efficiency of the organic light-emitting device.

When the second compound represented by Formula 2 includes an alkyl group and/or a cycloalkyl group, the second compound may have low crystallinity. Accordingly, when an organic layer is formed using the second compound represented by Formula 2, quality of the organic layer (e.g., film-forming characteristics of the organic layer) may be improved. Also, since the alkyl group group and/or the cycloalkyl group may function as an intermolecular or intramolecular electron donor, the second compound represented by Formula 2 including the alkyl group and/or the cycloalkyl group may have improved electrochemical stability. Accordingly, the organic light-emitting device including the second compound represented by Formula 2 may have high efficiency and a long lifespan.

Therefore, the organic light-emitting device including the first compound and the second compound may have high efficiency and a long lifespan that is at least in part due to the balance of charges in the emission layer and the improved stability of the compounds.

### Description of FIG. 1

FIG. 1 is a schematic view of an organic light-emitting device 10 according to an embodiment of the present disclosure. The organic light-emitting device 10 includes a first electrode 110, an organic layer 150, and a second electrode 190.

Hereinafter, the structure of the organic light-emitting device 10 according to an embodiment and a method of manufacturing the organic light-emitting device 10 will be described in connection with FIG. 1.

### First Electrode 110

In FIG. 1, a substrate may be additionally disposed (e.g., positioned) under the first electrode 110 or above the second electrode 190. The substrate may be a glass substrate or a plastic substrate, each having excellent (or suitable) mechanical strength, thermal stability, transparency, surface smoothness, ease of handling, and/or water-resistance.

The first electrode 110 may be formed by depositing or sputtering a material for forming the first electrode 110 on the substrate. When the first electrode 110 is an anode, the material for forming the first electrode may be selected from materials with a high work function to facilitate hole injection.

The first electrode 110 may be a reflective electrode, a semi-transmissive electrode, or a transmissive electrode. When the first electrode 110 is a transmissive electrode, a material for forming the first electrode may be selected from indium tin oxide (ITO), indium zinc oxide (IZO), tin oxide (SnO₂), zinc oxide (ZnO), and combinations thereof, but is not limited thereto. In various embodiments, when the first electrode 110 is a semi-transmissive electrode or a reflective electrode, a material for forming the first electrode may be selected from magnesium (Mg), silver (Ag), aluminum (Al), aluminum-lithium (Al—Li), calcium (Ca), magnesium-indium (Mg—In), magnesium-silver (Mg—Ag), and combinations thereof, but is not limited thereto.

The first electrode 110 may have a single-layered structure, or a multi-layered structure including two or more layers. For example, the first electrode 110 may have a three-layered structure of ITO/Ag/ITO, but the structure of the first electrode 110 is not limited thereto.

### Organic Layer 150

The organic layer 150 may be disposed on the first electrode 110. The organic layer 150 may include an emission layer.

The organic layer 150 may further include a hole transport region between the first electrode 110 and the emission layer, and an electron transport region between the emission layer and the second electrode 190.

### Hole Transport Region in Organic Layer 150

The hole transport region may have i) a single-layered structure having a single layer including a single material, ii) a single-layered structure having a single layer including a plurality of different materials, or iii) a multi-layered structure having a plurality of layers including a plurality of different materials.

The hole transport region may include at least one layer selected from a hole injection layer (HIL), a hole transport layer (HTL), an emission auxiliary layer, and an electron blocking layer (EBL).

For example, the hole transport region may have a single-layered structure having a single layer including a plurality of different materials, or a multi-layered structure having a structure of hole injection layer/hole transport layer, hole injection layer/hole transport layer/emission auxiliary layer, hole injection layer/emission auxiliary layer, hole transport layer/emission auxiliary layer, or hole injection layer/hole transport layer/electron blocking layer, wherein for each structure, constituting layers are sequentially stacked from the first electrode 110 in this stated order, but the structure of the hole transport region is not limited thereto.

The hole transport region may include at least one selected from m-MTDATA, TDATA, 2-TNATA, NPB(NPD), p-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (Pani/DBSA), poly(3,4-ethylenedioxythiophene)/poly(4-styrenesulfonate) (PEDOT/PSS), polyaniline/camphor sulfonic acid (Pani/CSA), polyaniline/poly(4-styrenesulfonate) (Pani/PSS), a compound represented by Formula 201, and a compound represented by Formula 202:

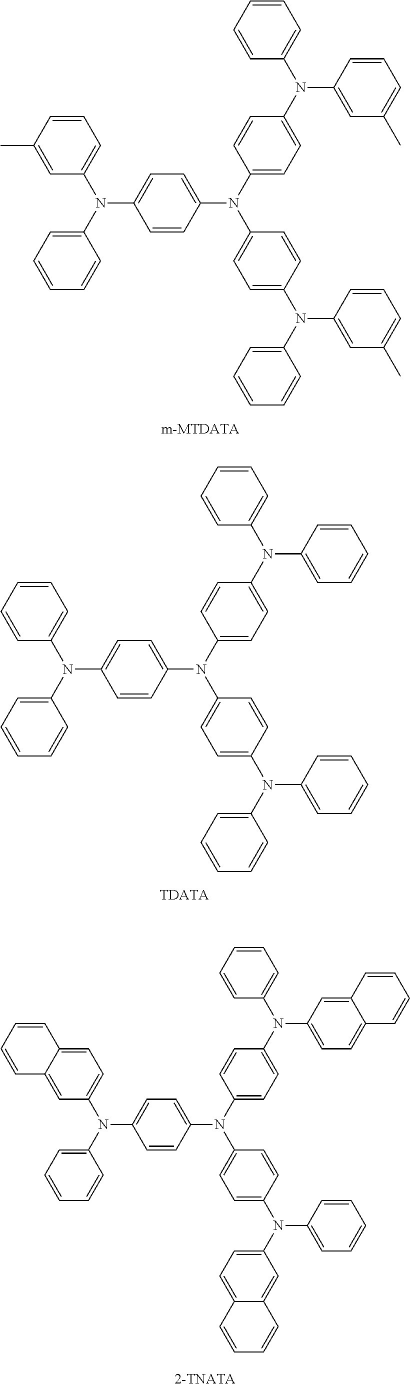

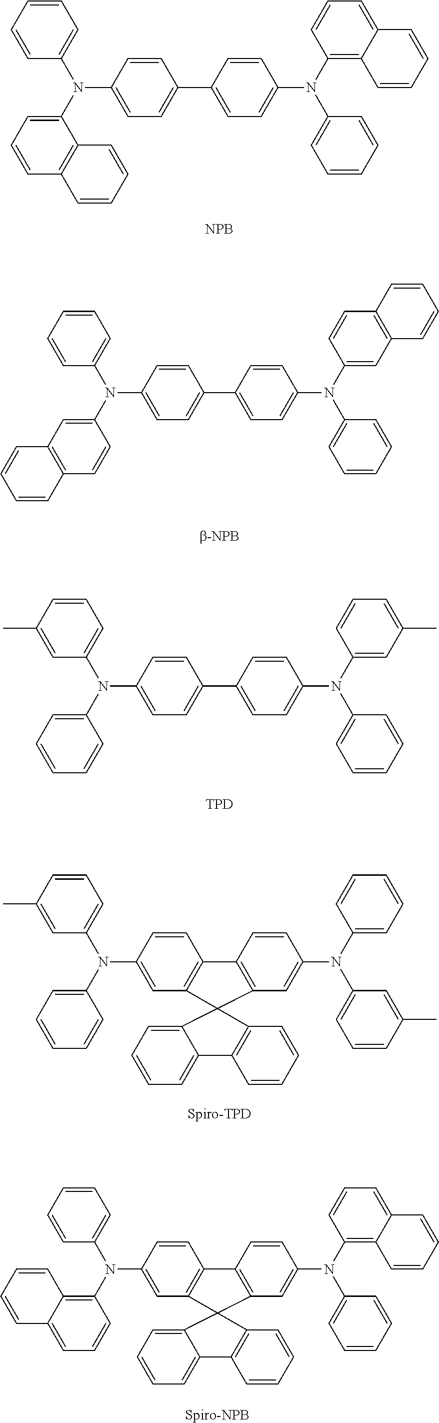

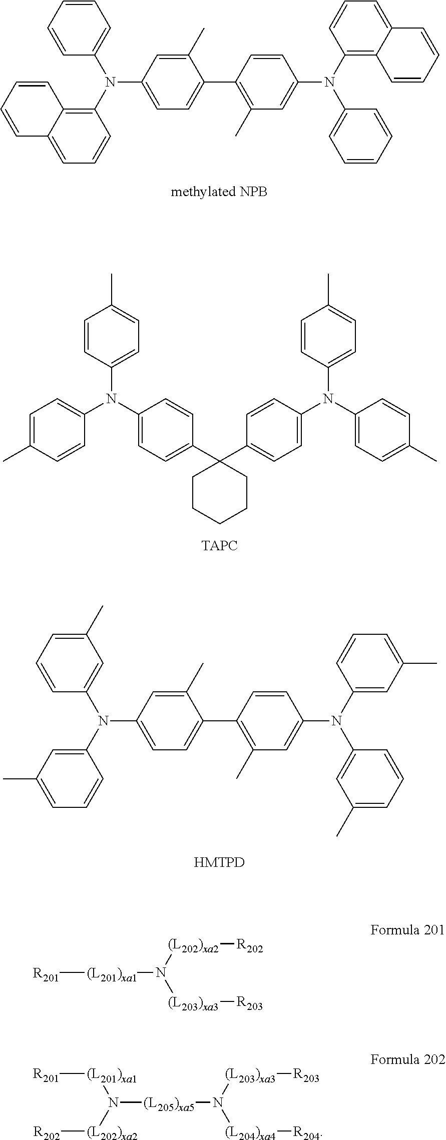

In Formulae 201 and 202,

L₂₀₁ to L₂₀₄ may each independently be selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,

L₂₀₅ may be selected from *—O—*′, *—S—*′, *—N(Q₂₀₁)-*′, a substituted or unsubstituted C₁-C₂₀ alkylene group, a substituted or unsubstituted C₂-C₂₀ alkenylene group, a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,

xa1 to xa4 may each independently be an integer selected from 0 to 3,

xa5 may be an integer selected from 1 to 10, and

R₂₀₁ to R₂₀₄ and Q₂₀₁ may each independently be selected from a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group.

For example, R₂₀₁ and R₂₀₂ in Formula 202 may be optionally connected to each other via a single bond, a dimethyl-methylene group, or a diphenyl-methylene group; and R₂₀₃ and R₂₀₄ may be optionally connected to each other via a single bond, a dimethyl-methylene group, or a diphenyl-methylene group.

In various embodiments, in Formulae 201 and 202,

L₂₀₁ to L₂₀₅ may each independently be selected from the group consisting of:

a phenylene group, a pentalenylene group, an indenylene group, a naphthylene group, an azulenylene group, a heptalenylene group, an indacenylene group, an acenaphthylene group, a fluorenylene group, a spiro-bifluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, and a pyridinylene group; and

a phenylene group, a pentalenylene group, an indenylene group, a naphthylene group, an azulenylene group, a heptalenylene group, an indacenylene group, an acenaphthylene group, a fluorenylene group, a spiro-bifluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, and a pyridinylene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a phenyl group substituted with a C₁-C₁₀ alkyl group, a phenyl group substituted with —F, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, —Si(Q₃₁)(Q₃₂)(Q₃₃), and —N(Q₃₁)(Q₃₂),

wherein Q₃₁ to Q₃₃ may each independently be selected from a C₁-C₁₀ alkyl group, a C₁-C₁₀ alkoxy group, a phenyl group, a biphenyl group, a terphenyl group, and a naphthyl group.

In various embodiments, xa1 to xa4 may each independently be 0, 1, or 2.

In various embodiments, xa5 may be 1, 2, 3, or 4.

In various embodiments, R₂₀₁ to R₂₀₄ and Q₂₀₁ may each independently be selected from the group consisting of:

a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, and a pyridinyl group; and

a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, and a pyridinyl group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a phenyl group substituted with a C₁-C₁₀ alkyl group, a phenyl group substituted with —F, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, —Si(Q₃₁)(Q₃₂)(Q₃₃), and —N(Q₃₁)(Q₃₂),

wherein Q₃₁ to Q₃₃ are the same as described herein.

In various embodiments, at least one selected from R₂₀₁ to R₂₀₃ in Formula 201 may each independently be selected from the group consisting of:

a fluorenyl group, a spiro-bifluorenyl group, a carbazolyl group, a dibenzofuranyl group, and a dibenzothiophenyl group; and

a fluorenyl group, a spiro-bifluorenyl group, a carbazolyl group, a dibenzofuranyl group, and a dibenzothiophenyl group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a phenyl group substituted with a C₁-C₁₀ alkyl group, a phenyl group substituted with —F, a naphthyl group, a fluorenyl group, a spiro-bifluorenyl group, a carbazolyl group, a dibenzofuranyl group, and a dibenzothiophenyl group,

but embodiments are not limited thereto.

In various embodiments, in Formula 202, i) R₂₀₁ and R₂₀₂ may be connected to each other via a single bond and/or ii) R₂₀₃ and R₂₀₄ may be connected to each other via a single bond.

In various embodiments, at least one selected from R₂₀₁ to R₂₀₄ in Formula 202 may be selected from the group consisting of:

a carbazolyl group; and

a carbazolyl group substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a phenyl group substituted with a C₁-C₁₀ alkyl group, a phenyl group substituted with —F, a naphthyl group, a fluorenyl group, a spiro-bifluorenyl group, a carbazolyl group, a dibenzofuranyl group, and a dibenzothiophenyl group,

but embodiments are not limited thereto.

The compound represented by Formula 201 may be represented by Formula 201A:

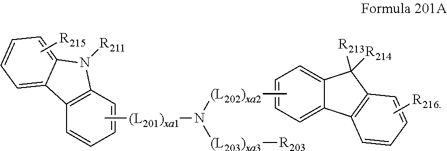

In various embodiments, the compound represented by Formula 201 may be represented by Formula 201A(1), but is not limited thereto:

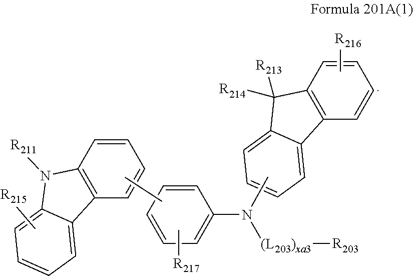

In various embodiments, the compound represented by Formula 201 may be represented by Formula 201A-1, but is not limited thereto:

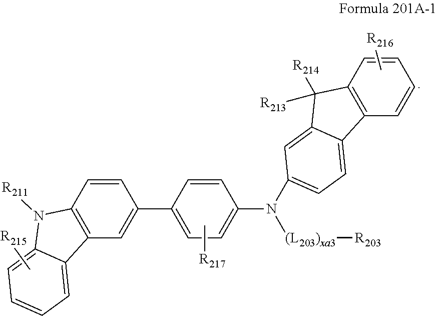

In various embodiments, the compound represented by Formula 202 may be represented by Formula 202A:

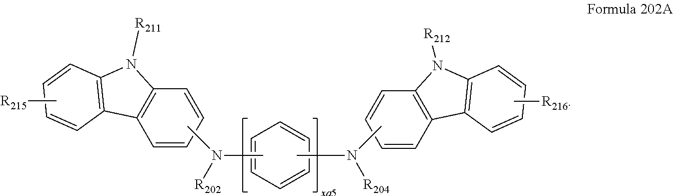

In various embodiments, the compound represented by Formula 202 may be represented by Formula 202A-1:

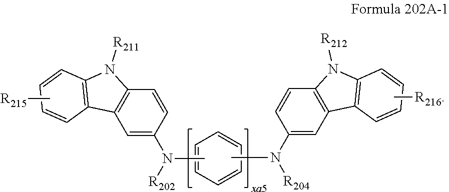

In Formulae 201A, 201A(1), 201A-1, 202A, and 202A-1,

descriptions of L₂₀₁ to L₂₀₃, xa1 to xa3, xa5, and R₂₀₂ to R₂₀₄ are the same as those provided herein,

descriptions of R₂₁₁ and R₂₁₂ are each independently the same as the description provided in connection with R₂₀₃,

R₂₁₃ to R₂₁₇ may each independently be selected from hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a phenyl group substituted with a C₁-C₁₀ alkyl group, a phenyl group substituted with —F, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, and a pyridinyl group.

The hole transport region may include at least one compound selected from Compounds HT1 to HT39, but is not limited thereto:

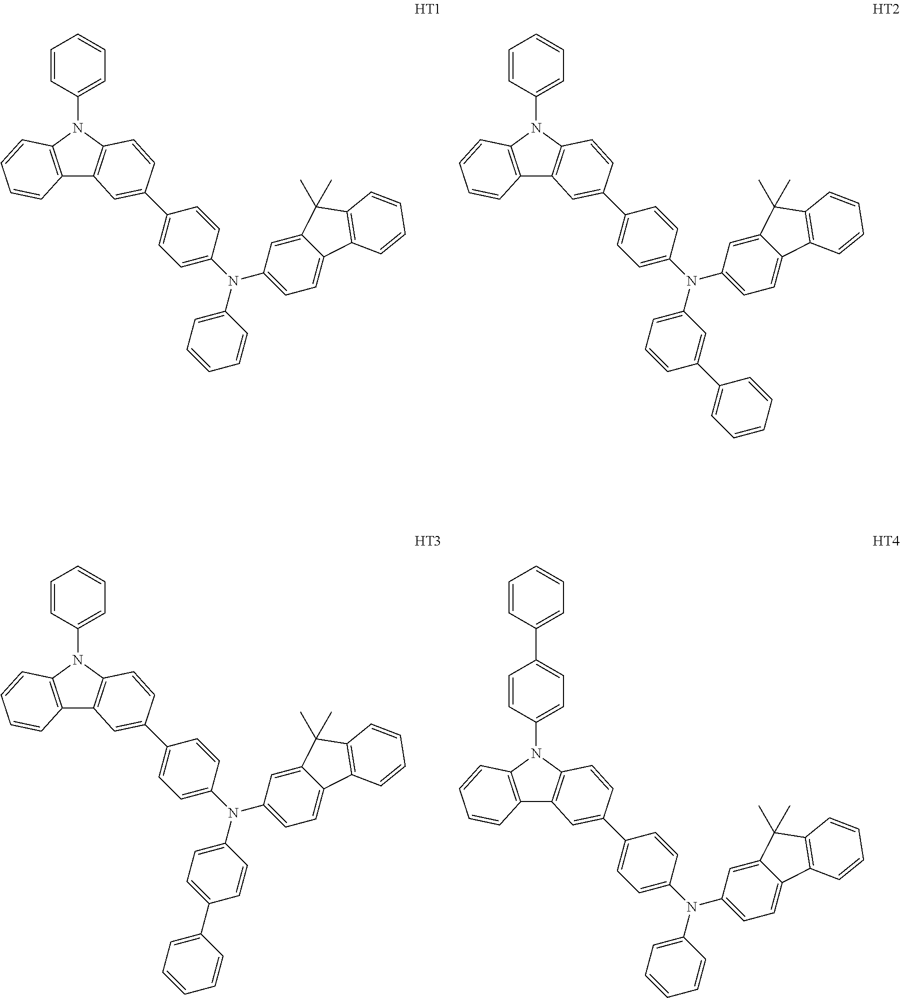 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

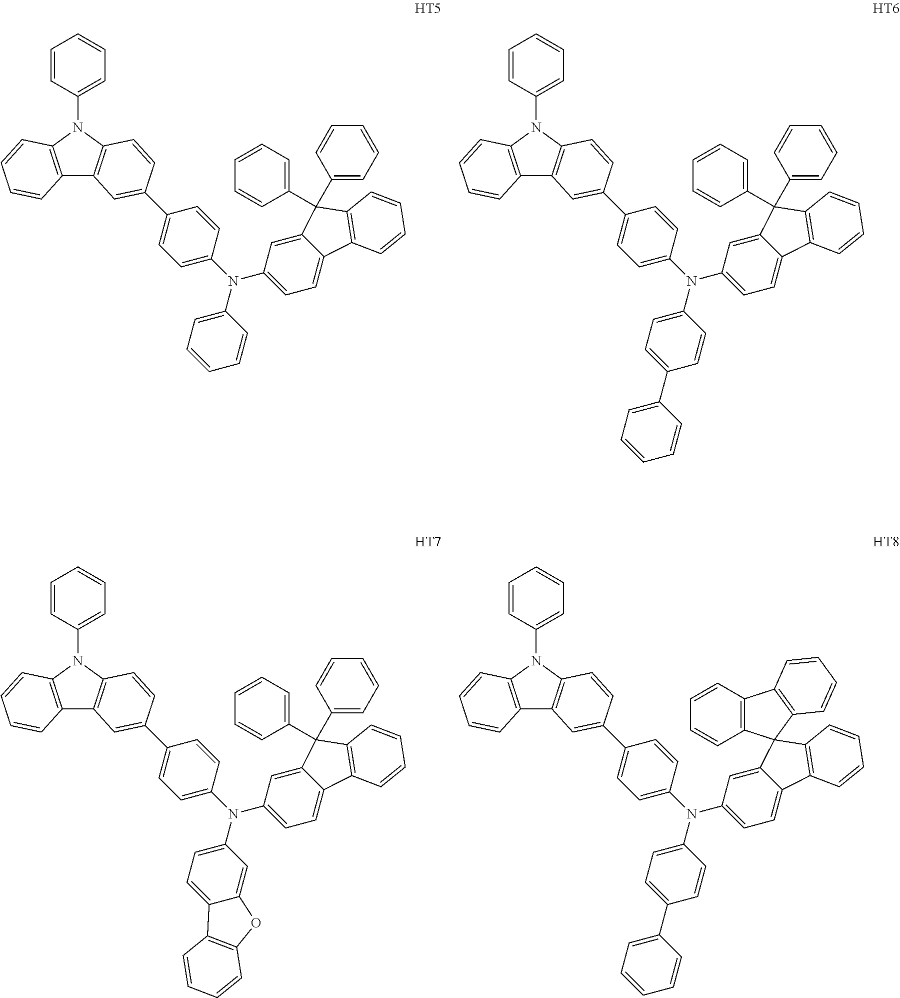 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

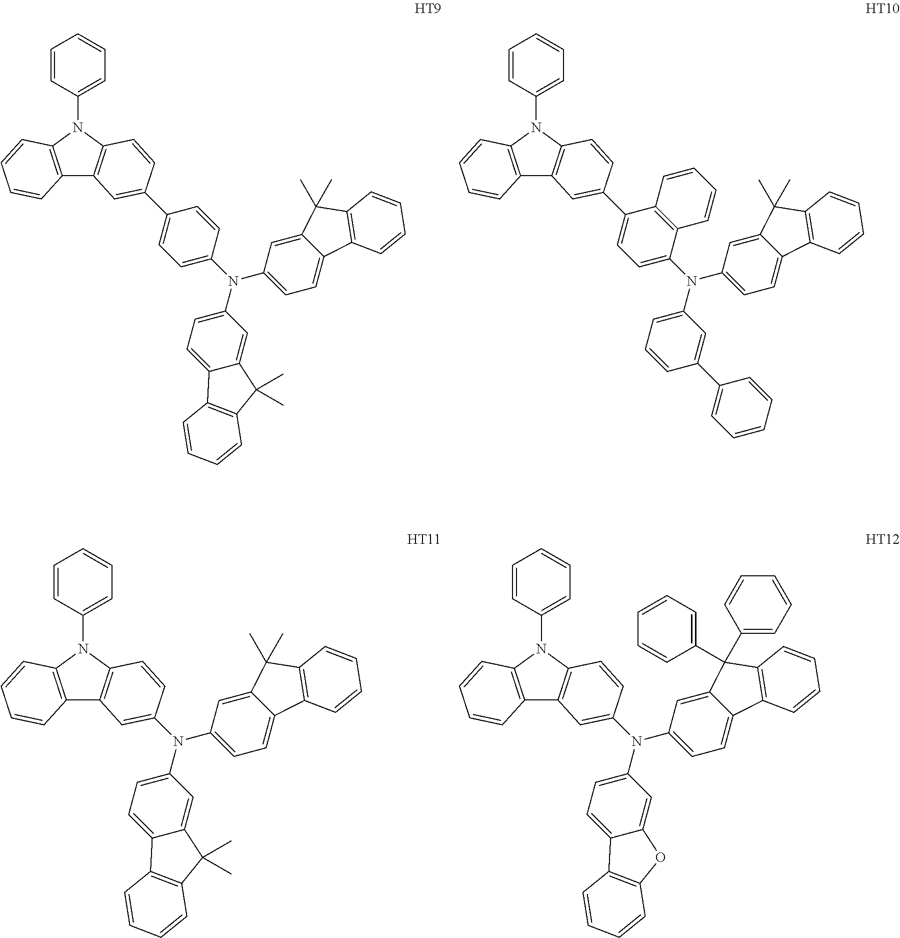 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

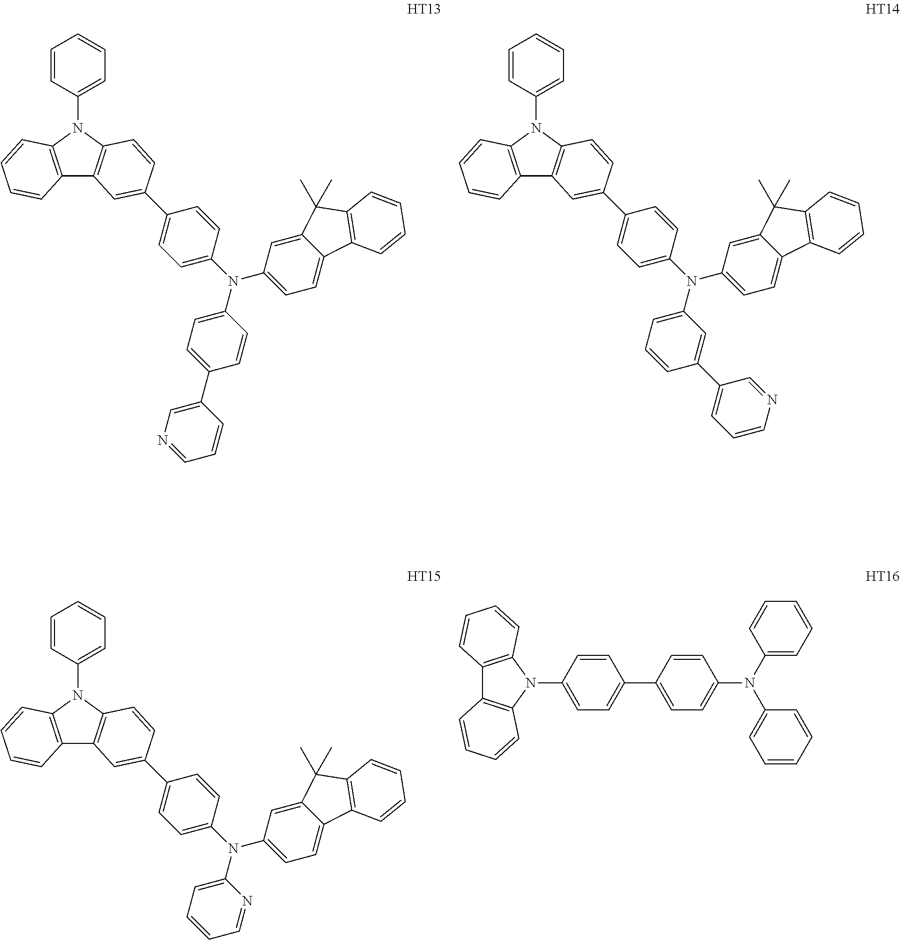 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1]

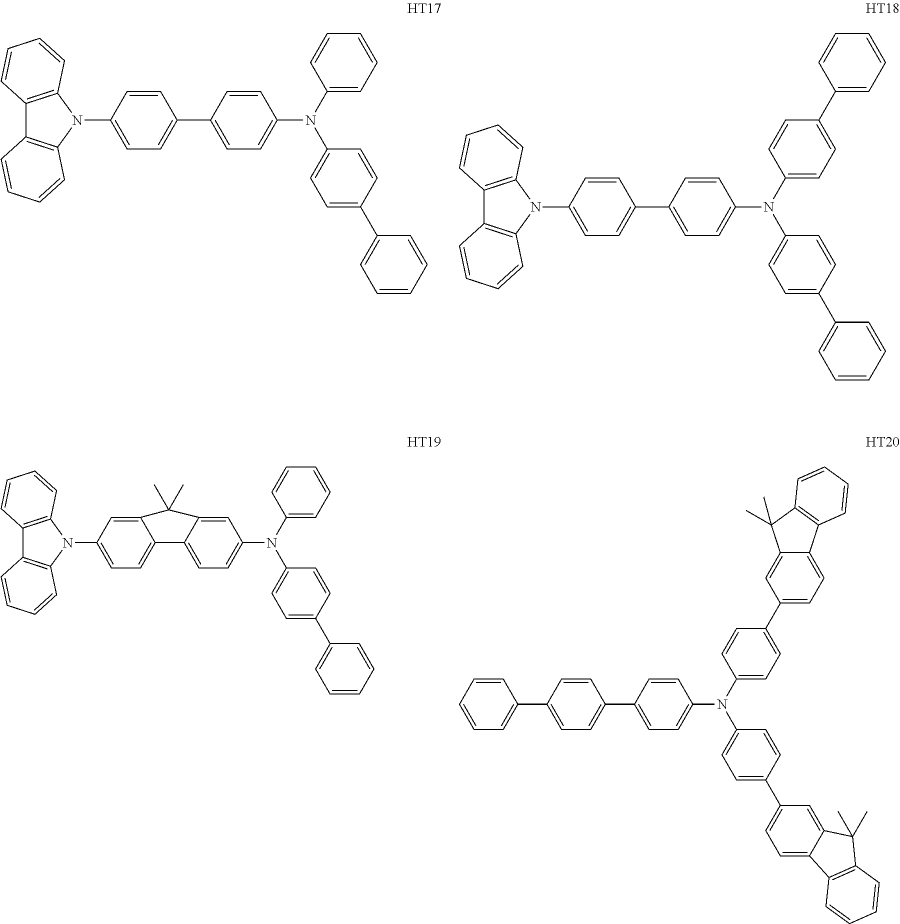

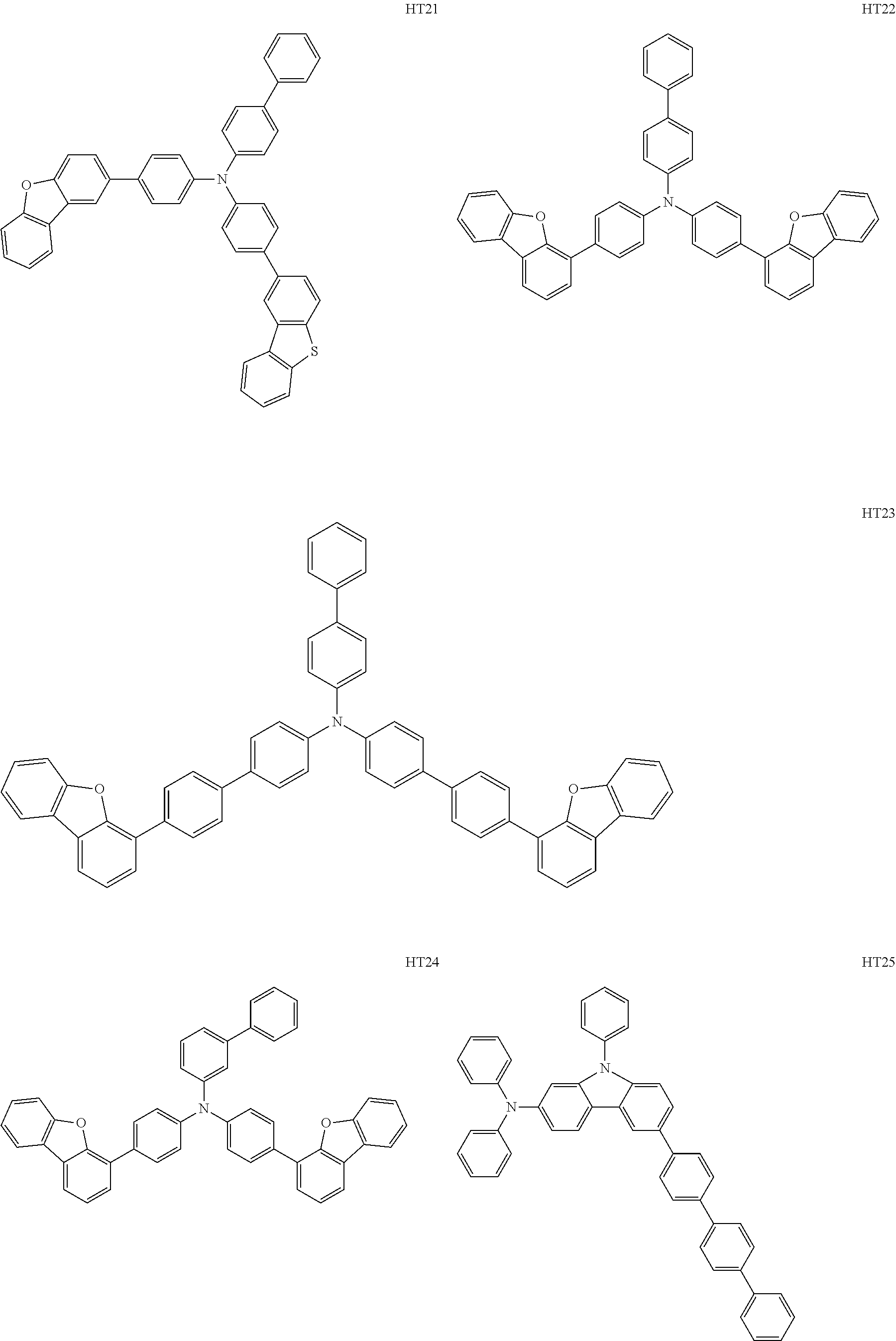 [SMILES: c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1 ; c1ccc(-c2cccc(N(c3ccc(-c4cccc5c4oc4ccccc45)cc3)c3ccc(-c4cccc5c4oc4ccccc45)cc3)c2)cc1 ; c1ccc(-c2ccc(-c3ccc(-c4ccc5c(c4)c4ccc(N(c6ccccc6)c6ccccc6)cc4n5-c4ccccc4)cc3)cc2)cc1]

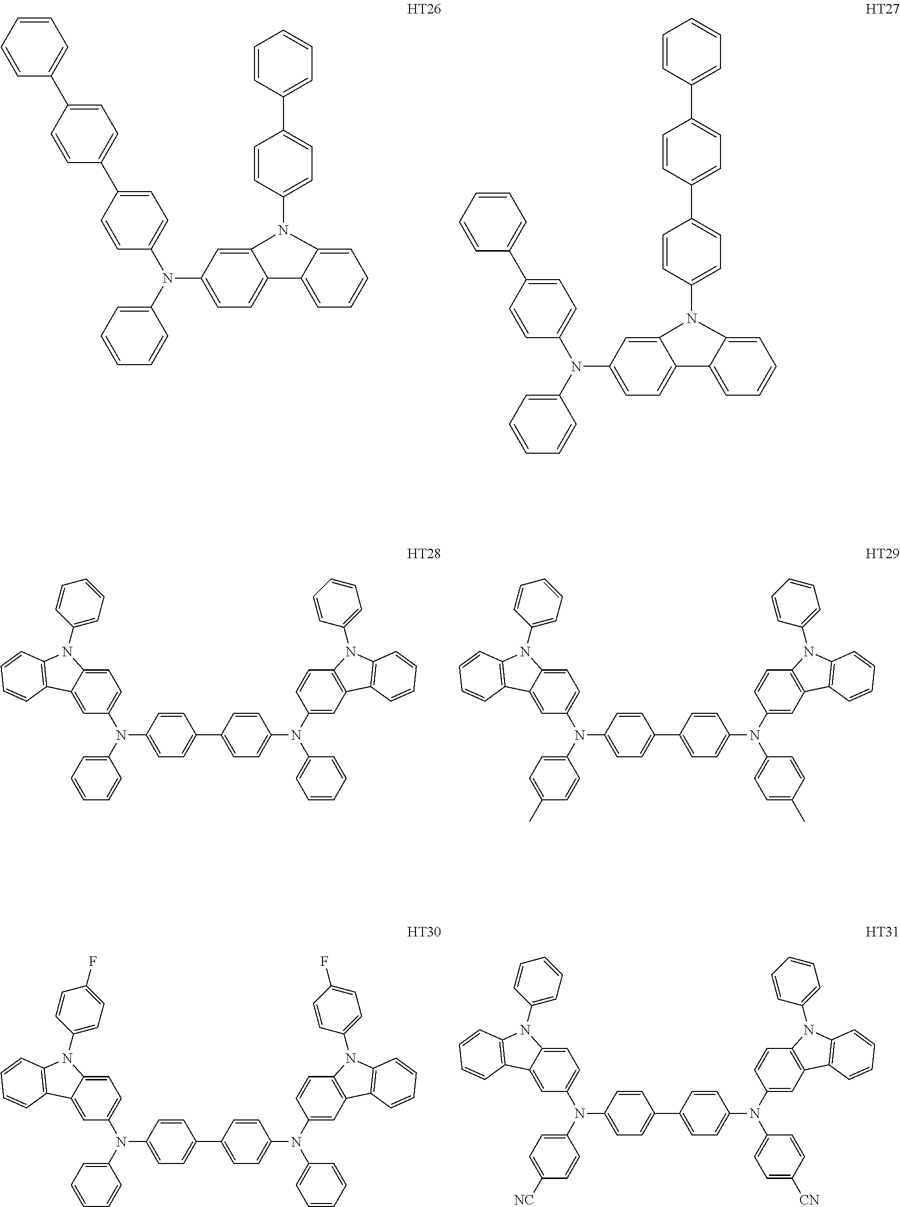

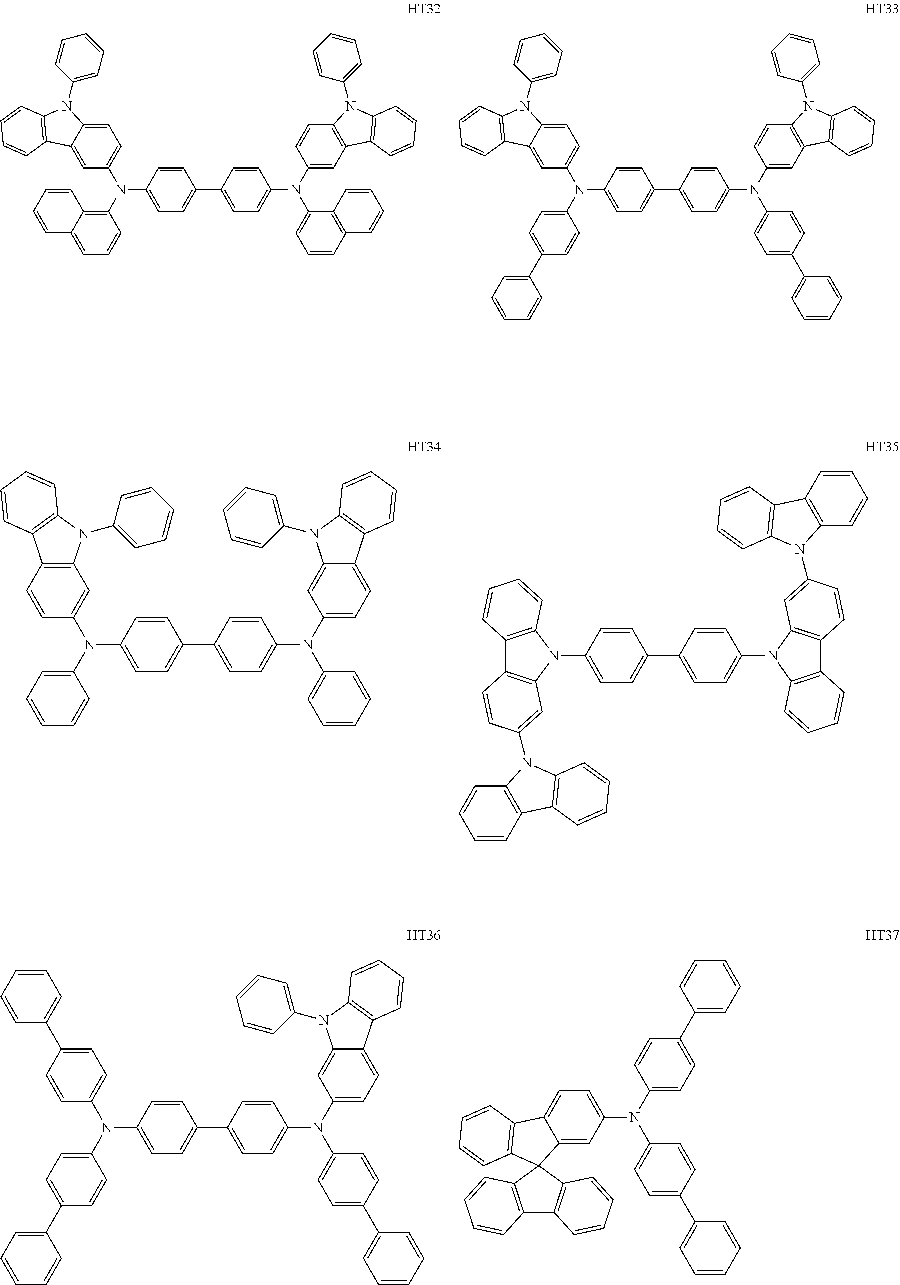

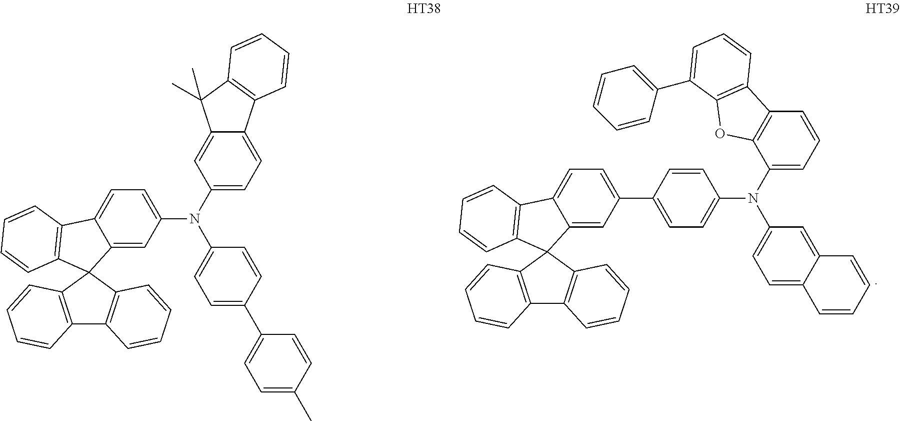 [SMILES: Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1]

A thickness of the hole transport region may be in a range of about 100 Å to about 10,000 Å, for example, about 100 Å to about 1,000 Å. When the hole transport region includes at least one of a hole injection layer and a hole transport layer, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer and the hole transport layer are within any of these ranges, satisfactory (or suitable) hole transporting characteristics may be obtained without a substantial increase in driving voltage.

The emission auxiliary layer may increase light-emission efficiency by compensating for an optical resonance distance according to the wavelength of light emitted by an emission layer, and the electron blocking layer may block or reduce the flow of electrons from an electron transport region. The emission auxiliary layer and the electron blocking layer may include any of the materials as described above.

p-Dopant

The hole transport region may further include, in addition to the materials described above, a charge-generation material for the improvement of conductive properties. The charge-generation material may be homogeneously or non-homogeneously dispersed in the hole transport region.

The charge-generation material may be, for example, a p-dopant.

In various embodiments, the p-dopant may have a lowest unoccupied molecular orbital (LUMO) energy level of −3.5 eV or less.

The p-dopant may include at least one selected from a quinone derivative, a metal oxide, and a cyano group-containing compound, but embodiments are not limited thereto.

For example, the p-dopant may include at least one selected from the group consisting of:

a quinone derivative, such as tetracyanoquinodimethane (TCNQ) and/or 2,3,5,6-tetrafluoro-7,7,8,8-tetracyanoquinodimethane (F4-TCNQ);

a metal oxide, such as tungsten oxide and/or molybdenum oxide;

1,4,5,8,9,11-hexaazatriphenylene-hexacarbonitrile (HAT-CN); and

a compound represented by Formula 221,

but is not limited thereto:

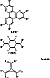

In Formula 221,

R₂₂₁ to R₂₂₃ may each independently be selected from a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, wherein at least one selected from R₂₂₁ to R₂₂₃ may have at least one substituent selected from a cyano group, —F, —Cl, —Br, —I, a C₁-C₂₀ alkyl group substituted with —F, a C₁-C₂₀ alkyl group substituted with —Cl, a C₁-C₂₀ alkyl group substituted with —Br, and a C₁-C₂₀ alkyl group substituted with —I.

### Emission Layer in Organic Layer 150

When the organic light-emitting device 10 is a full-color organic light-emitting device, the emission layer may be patterned into a red emission layer, a green emission layer, and/or a blue emission layer, according to a sub-pixel. In various embodiments, the emission layer may have a stacked structure of two or more layers selected from a red emission layer, a green emission layer, and a blue emission layer, in which the two or more layers contact each other or are separated from each other. In various embodiments, the emission layer may include two or more materials selected from a red-light emission material, a green-light emission material, and a blue-light emission material, in which the two or more materials are mixed with each other in a single layer to emit white light.

In various embodiments, the emission layer of the organic light-emitting device 10 may be a first-color-light emission layer, and

the organic layer may further include at least one second-color-light emission layer,

where the first color light and the second color light may be identical to or different from each other, and

the first color light and the second color light may be emitted as mixed light.

Herein, when the first color light is different from the second color light, a maximum luminance wavelength of the first color light is different from a maximum luminance wavelength of the second color light.

For example, the mixed light may be white light, but is not limited thereto.

In various embodiments, the emission layer of the organic light-emitting device 10 may be a first-color-light emission layer, and

the organic layer may further include at least one second-color-light emission layer and at least one third-color-light-emission layer,

where the first color light, the second color light, and the third color light may be identical to or different from one another, and

the first color light, the second color light, and the third color light may be emitted as mixed light.

Herein, when the first color light, the second color light, and the third color light are different from one another, a maximum luminance wavelength of the first color light, a maximum luminance wavelength of the second color light, a maximum luminance wavelength of the third color light are different from one another.

For example, the mixed light may be white light, but is not limited thereto.

The emission layer may include a host and a dopant. The dopant may include at least one selected from a phosphorescent dopant and a fluorescent dopant.

An amount of the dopant in the emission layer may be, for example, in a range of about 0.01 to about 15 parts by weight based on 100 parts by weight of the host, but is not limited thereto.

A thickness of the emission layer may be in a range of about 100 Å to about 1,000 Å, for example, about 200 Å to about 600 Å. When the thickness of the emission layer is within any of these ranges, excellent (or suitable) light-emission characteristics may be obtained without a substantial increase in driving voltage.

### Host in Emission Layer

The host may include the first compound represented by Formula 1.

In various embodiments, the host may include the first compound represented by Formula 1 and may futher include a compound represented by Formula 301 below.

In various embodiments, the emission layer includes a first host and a second host,

the first host may be the first compound, and

the first host may be different from the second host, but embodiments are not limited thereto.

[Ar₃₀₁]_{xb11}-[(L₃₀₁)_{xb1}-R₃₀₁]_{xb21}. Formula 301

In Formula 301,

Ar₃₀₁ may be a substituted or unsubstituted C₅-C₆₀ carbocyclic group or a substituted or unsubstituted C₁-C₆₀ heterocyclic group,

xb11 may be 1, 2, or 3,

L₃₀₁ may be selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,

xb1 may be an integer selected from 0 to 5,

R₃₀₁ may be selected from deuterium, —F, —Cl, —Br, —I, a hydroxyl group, a cyano group, a nitro group, an amidino group, a hydrazino group, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), and —P(═O)(Q₃₀₁)(Q₃₀₂), and

xb21 may be an integer selected from 1 to 5,

wherein Q₃₀₁ to Q₃₀₃ may each independently be selected from a C₁-C₁₀ alkyl group, a C₁-C₁₀ alkoxy group, a phenyl group, a biphenyl group, a terphenyl group, and a naphthyl group, but embodiments are not limited thereto.

In various embodiments, Ar₃₀₁ in Formula 301 may be selected from the group consisting of:

a naphthalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, a dibenzofuran group, and a dibenzothiophene group; and

a naphthalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, a dibenzofuran group, and a dibenzothiophene group, each substituted with at least one selected from a naphthalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, a dibenzofuran group, and a dibenzothiophene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),

wherein Q₃₁ to Q₃₃ are each independently selected from a C₁-C₁₀ alkyl group, a C₁-C₁₀ alkoxy group, a phenyl group, a biphenyl group, a terphenyl group, and a naphthyl group, but embodiments are not limited thereto.

When xb11 in Formula 301 is two or more, two or more Ar₃₀₁(s) may be connected to each other via a single bond.

In various embodiments, the compound represented by Formula 301 may be represented by Formula 301-1 or 301-2:

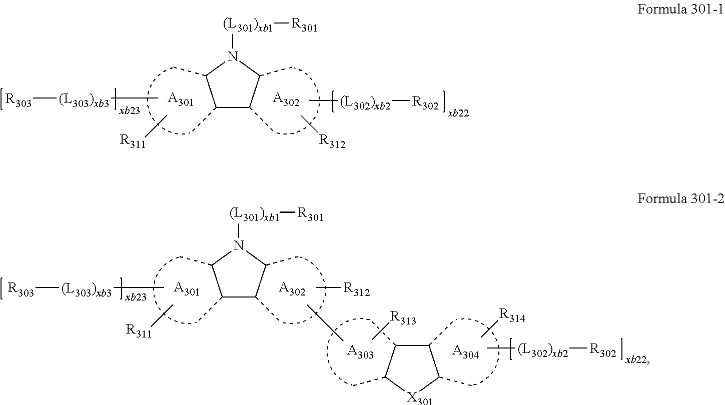

wherein in Formulae 301-1 to 301-2,

A₃₀₁ to A₃₀₄ may each independently be selected from a benzene group, a naphthalene group, a phenanthrene group, a fluoranthene group, a triphenylene group, a pyrene group, a chrysene group, a pyridine group, a pyrimidine group, an indene group, a fluorene group, a spiro-bifluorene group, a benzofluorene group, a dibenzofluorene group, an indole group, a carbazole group, benzocarbazole group, a dibenzocarbazole group, a furan group, a benzofuran group, a dibenzofuran group, a naphthofuran group, a benzonaphthofuran group, a dinaphthofuran group, a thiophene group, a benzothiophene group, a dibenzothiophene group, a naphthothiophene group, a benzonaphthothiophene group, and a dinaphthothiophene group,

X₃₀₁ may be O, S, or N-[(L₃₀₄)_{xb4}-R₃₀₄],

R₃₁₁ to R₃₁₄ may each independently be selected from hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),

xb22 and xb23 may each independently be 0, 1, or 2,

descriptions of L₃₀₁, xb1, R₃₀₁, and Q₃₁ to Q₃₃ may be the same as those provided above,

descriptions of L₃₀₂ to L₃₀₄ may each independently be the same as the description provided in connection with the L₃₀₁,

descriptions of xb2 to xb4 may each independently be the same as the description provided in connection with xb1,

descriptions of R₃₀₂ to R₃₀₄ may each independently be the same as the description provided in connection with R₃₀₁.

For example, L₃₀₁ to L₃₀₄ in Formulae 301, 301-1, and 301-2 may each independently be selected from the group consisting of:

a phenylene group, a naphthylene group, a fluorenylene group, a spiro-bifluorenylene group, a benzofluorenylene group, a dibenzofluorenylene group, a phenanthrenylene group, an anthracenylene group, a fluoranthenylene group, a triphenylenylene group, a pyrenylene group, a chrysenylene group, a perylenylene group, a pentaphenylene group, a hexacenylene group, a pentacenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, a pyridinylene group, an imidazolylene group, a pyrazolylene group, a thiazolylene group, an isothiazolylene group, an oxazolylene group, an isoxazolylene group, a thiadiazolylene group, an oxadiazolylene group, a pyrazinylene group, a pyrimidinylene group, a pyridazinylene group, a triazinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a phenanthridinylene group, an acridinylene group, a phenanthrolinylene group, a phenazinylene group, a benzimidazolylene group, an isobenzothiazolylene group, a benzoxazolylene group, an isobenzoxazolylene group, a triazolylene group, a tetrazolylene group, an imidazopyridinylene group, an imidazopyrimidinylene group, and an azacarbazolylene group; and

a phenylene group, a naphthylene group, a fluorenylene group, a spiro-bifluorenylene group, a benzofluorenylene group, a dibenzofluorenylene group, a phenanthrenylene group, an anthracenylene group, a fluoranthenylene group, a triphenylenylene group, a pyrenylene group, a chrysenylene group, a perylenylene group, a pentaphenylene group, a hexacenylene group, a pentacenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, a pyridinylene group, an imidazolylene group, a pyrazolylene group, a thiazolylene group, an isothiazolylene group, an oxazolylene group, an isoxazolylene group, a thiadiazolylene group, an oxadiazolylene group, a pyrazinylene group, a pyrimidinylene group, a pyridazinylene group, a triazinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a phenanthridinylene group, an acridinylene group, a phenanthrolinylene group, a phenazinylene group, a benzimidazolylene group, an isobenzothiazolylene group, a benzoxazolylene group, an isobenzoxazolylene group, a triazolylene group, a tetrazolylene group, an imidazopyridinylene group, an imidazopyrimidinylene group, and an azacarbazolylene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, an azacarbazolyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),

wherein Q₃₁ to Q₃₃ are the same as described herein.

In various embodiments, R₃₀₁ to R₃₀₄ in Formulae 301, 301-1, and 301-2 may each independently be selected from the group consisting of:

a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, and an azacarbazolyl group; and

a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, and an azacarbazolyl group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, an azacarbazolyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),

wherein Q₃₁ to Q₃₃ are the same as described herein.

In various embodiments, the host may include an alkaline earth-metal complex. For example, the host may be selected from a Be complex (e.g., Compound H55), a Mg complex, and a Zn complex.

The host may include at least one selected from 9,10-di(2-naphthyl)anthracene (ADN), 2-methyl-9,10-bis(naphthalen-2-yl)anthracene (MADN), 9,10-di-(2-naphthyl)-2-t-butyl-anthracene (TBADN), 4,4′-bis(N-carbazolyl)-1, 1′-biphenyl (CBP), 1,3-di-9-carbazolylbenzene (mCP), 1,3,5-tri(carbazol-9-yl)benzene (TCP), and Compounds H1 to H55, but is not limited thereto:

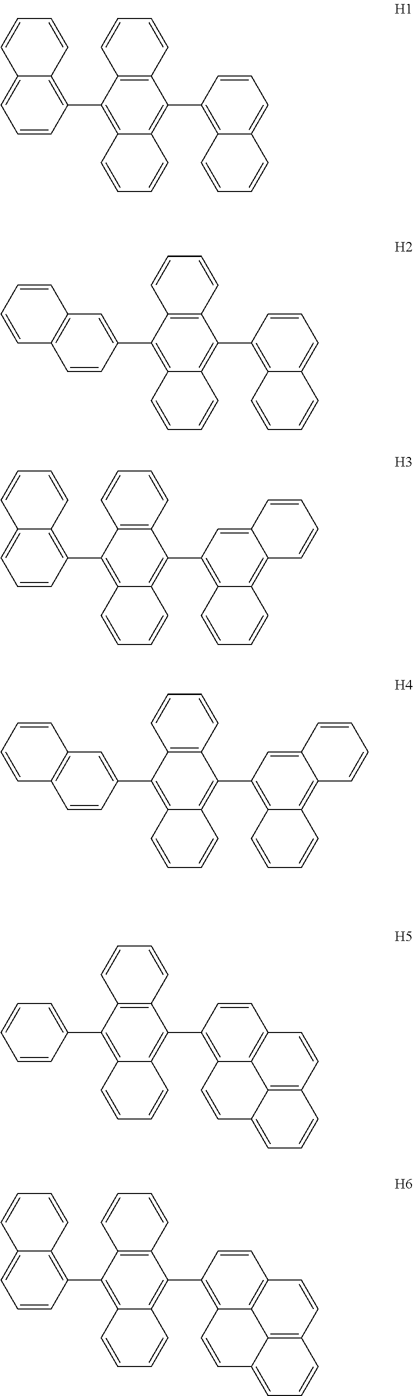

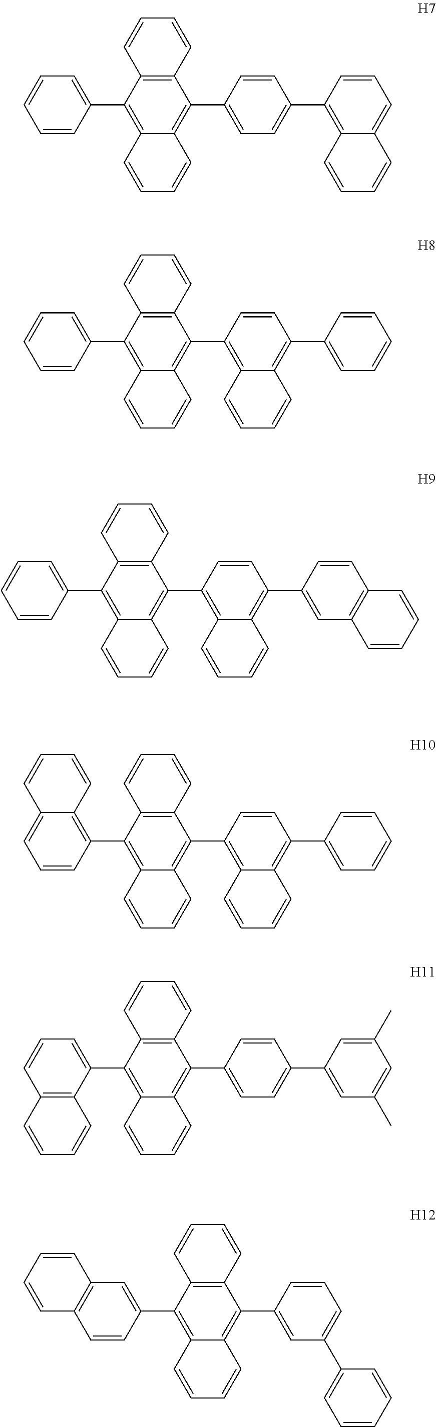

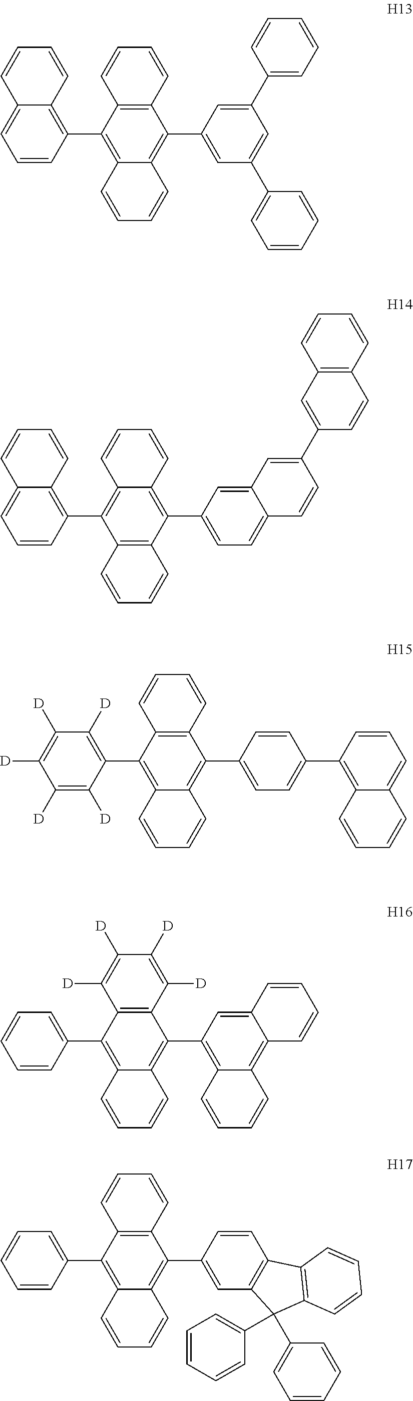

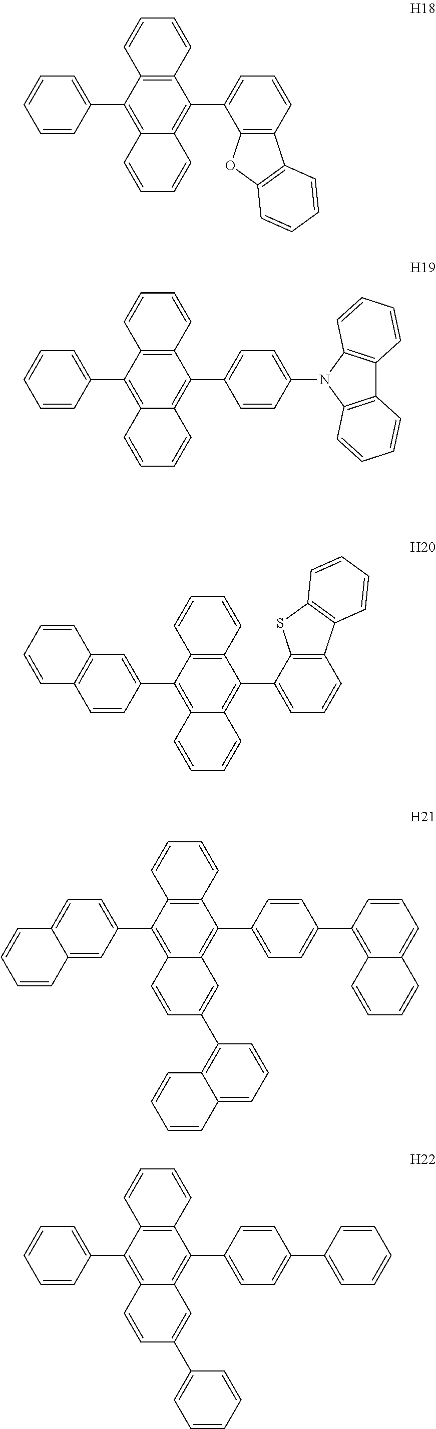

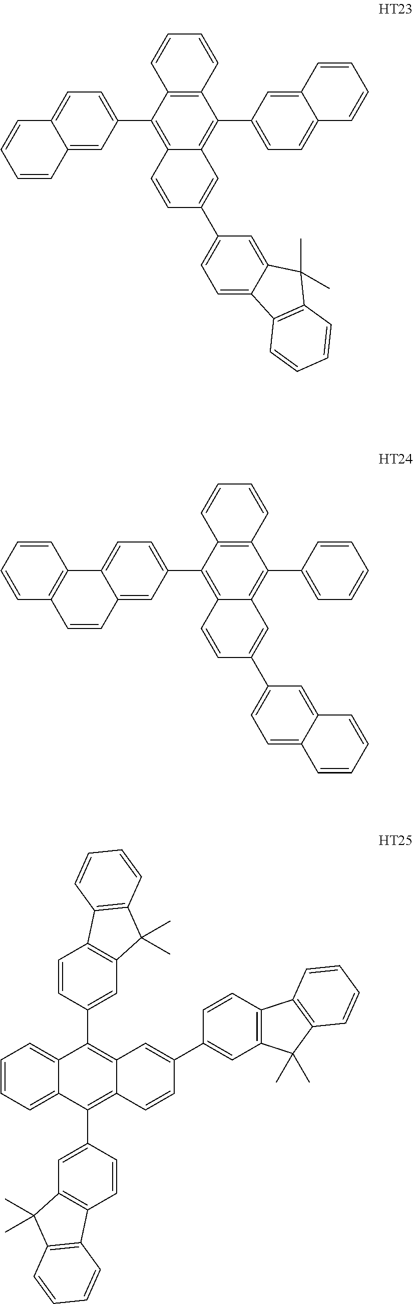

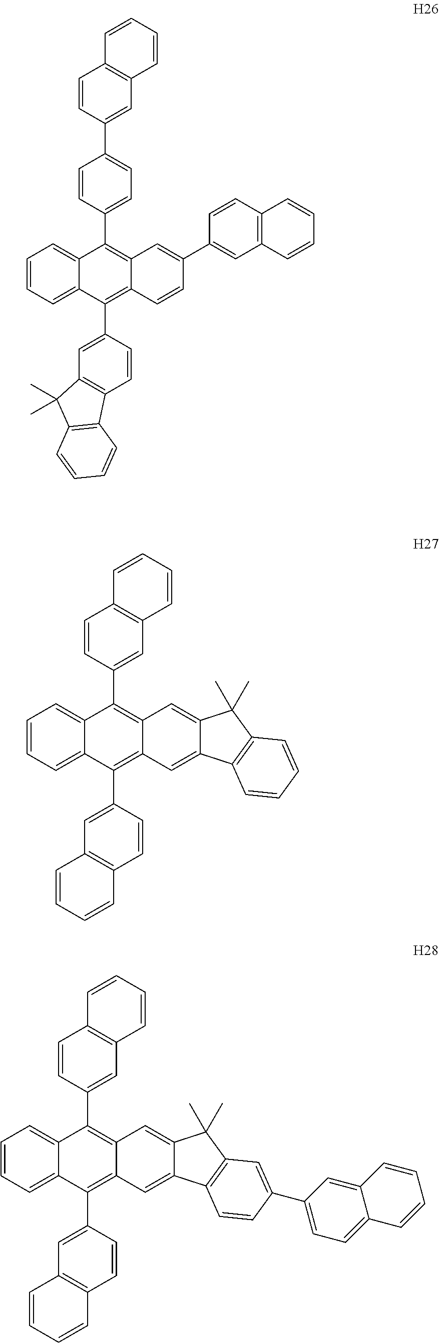

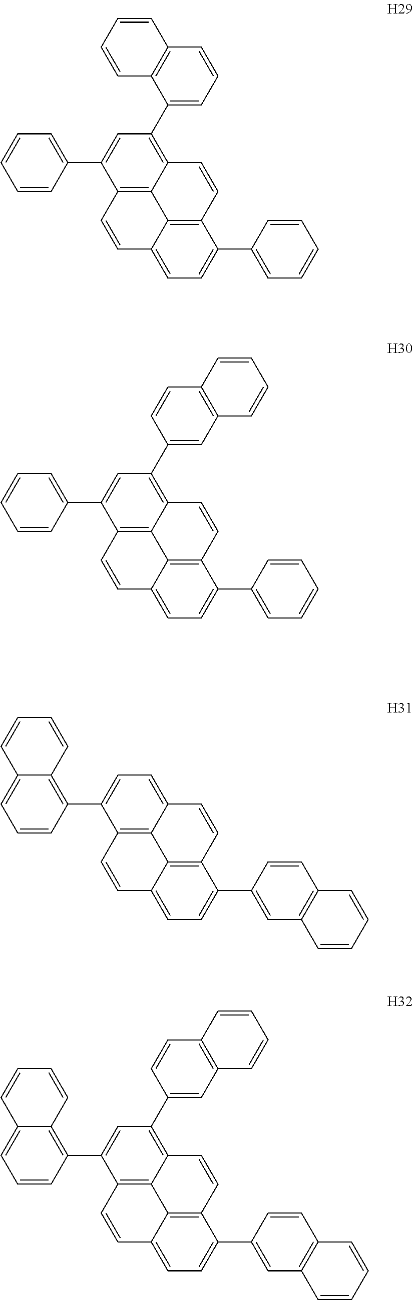

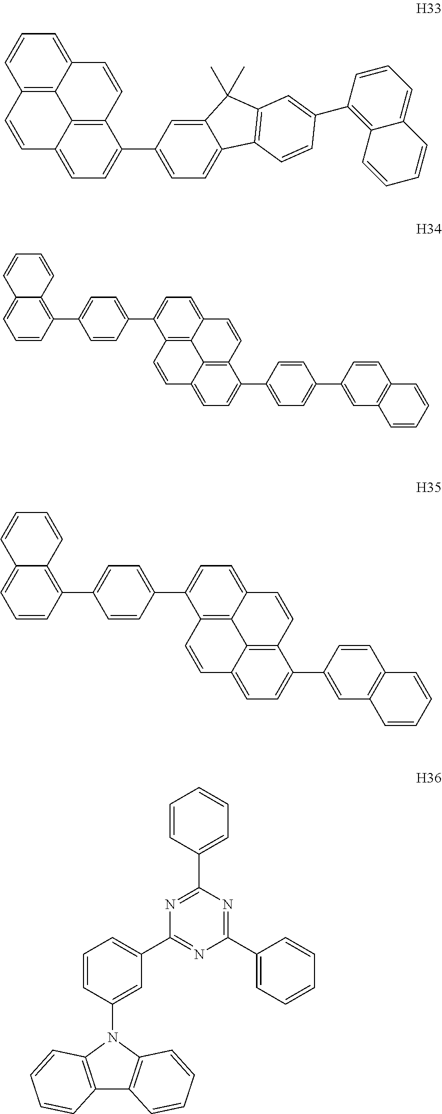

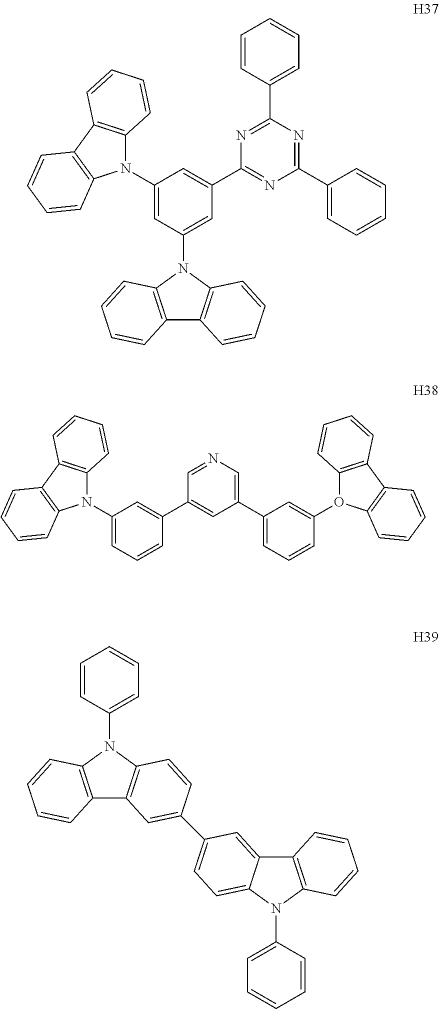

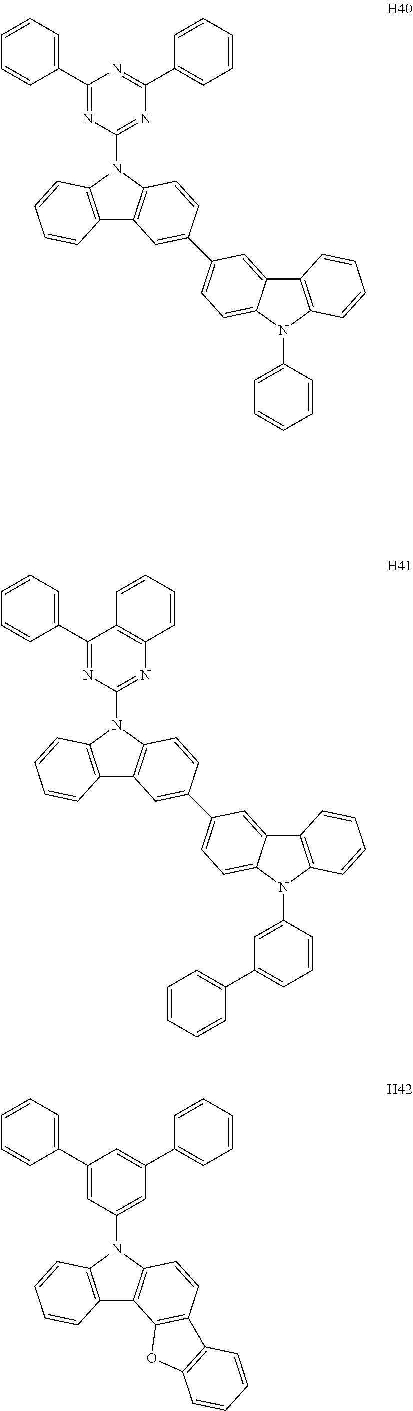 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1]

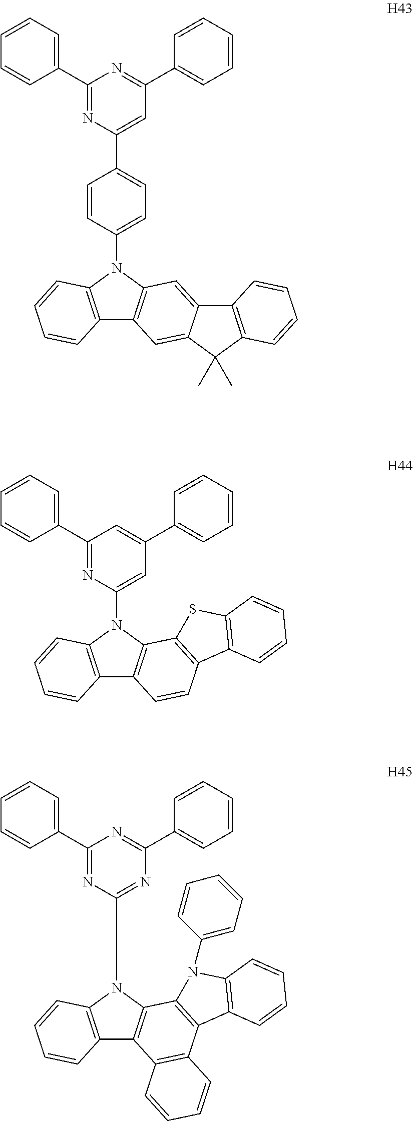 [SMILES: CC1(C)c2ccccc2-c2cc3c(cc21)c1ccccc1n3-c1ccc(-c2cc(-c3ccccc3)nc(-c3ccccc3)n2)cc1 ; c1ccc(-c2cc(-c3ccccc3)nc(-n3c4ccccc4c4ccc5c6ccccc6sc5c43)c2)cc1 ; c1ccc(-c2nc(-c3ccccc3)nc(-n3c4ccccc4c4c5ccccc5c5c6ccccc6n(-c6ccccc6)c5c43)n2)cc1]

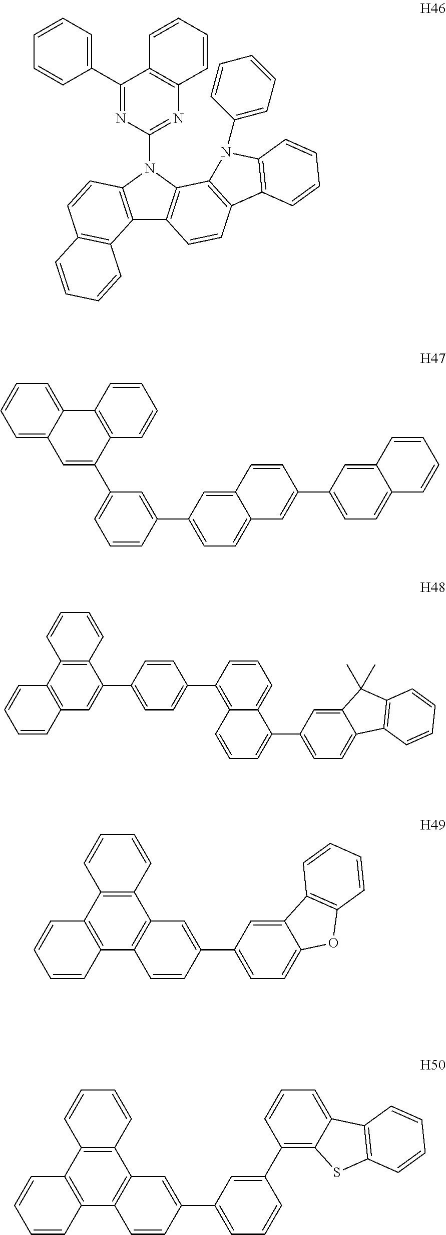

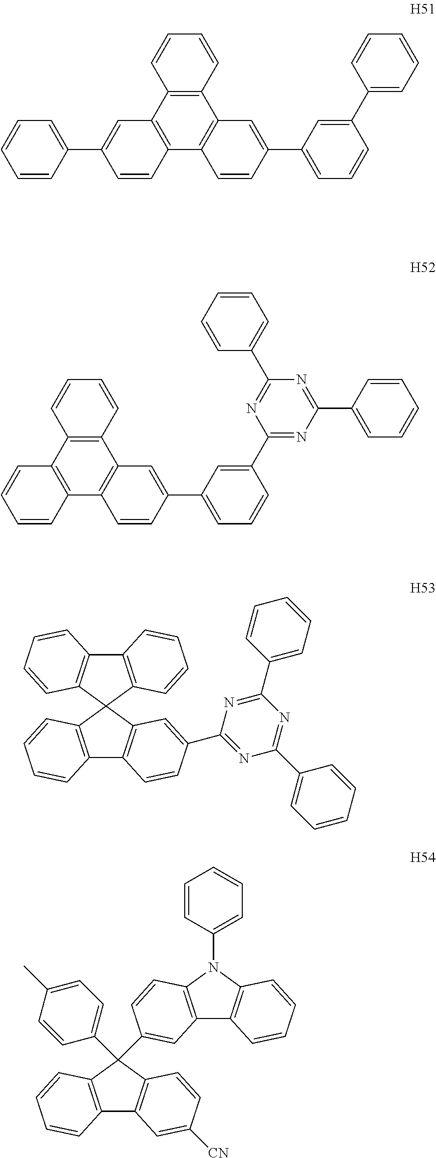

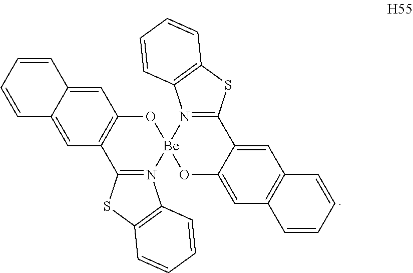

### Phosphorescent Dopant Included in Emission Layer in Organic Layer 150

The phosphorescent dopant may include an organometallic complex represented by Formula 401 below:

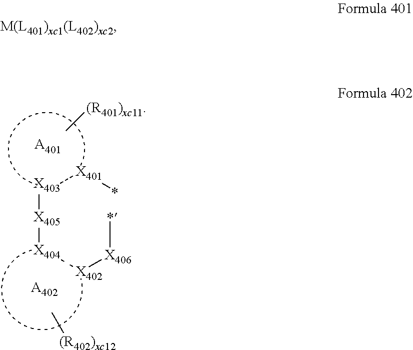

In Formulae 401 and 402,

M may be selected from iridium (Ir), platinum (Pt), palladium (Pd), osmium (Os), titanium (Ti), zirconium (Zr), hafnium (Hf), europium (Eu), terbium (Tb), rhodium (Rh), and thulium (Tm),

L₄₀₁ may be selected from ligands represented by Formula 402, and xc1 may be 1, 2, or 3, wherein when xc1 is two or more, two or more L₄₀₁(s) may be identical to or different from each other,

L₄₀₂ may be an organic ligand, and xc2 may be an integer selected from 0 to 4, wherein when xc2 is two or more, two or more L₄₀₂(s) may be identical to or different from each other,

X₄₀₁ to X₄₀₄ may each independently be nitrogen or carbon,

X₄₀₁ and X₄₀₃ may be connected to each other via a single bond or a double bond, and X₄₀₂ and X₄₀₄ may be connected to each other via a single bond or a double bond,

A₄₀₁ and A₄₀₂ may each independently be a C₅-C₆₀ carbocyclic group or a C₁-C₆₀ heterocyclic group,

X₄₀₅ may be a single bond, *—O—*′, *—S—*′, *—C(═O)—*′, *—N(Q₄₁₁)-*′, *—C(Q₄₁₁)(Q₄₁₂)-*′, *—C(Q₄₁₁)═C(Q₄₁₂)-*′, *—C(Q₄₁₁)=*′, or *═C(Q₄₁₁)=*′, wherein Q₄₁₁ and Q₄₁₂ may each independently be hydrogen, deuterium, a C₁-C₂₀ alkyl group, a C₁-C₂₀ alkoxy group, a phenyl group, a biphenyl group, a terphenyl group, or a naphthyl group,

X₄₀₆ may be a single bond, O, or S,

R₄₀₁ and R₄₀₂ may each independently be selected from hydrogen, deuterium, —F, —Cl, —Br, —I, a hydroxyl group, a cyano group, a nitro group, an amidino group, a hydrazino group, a hydrazono group, a substituted or unsubstituted C₁-C₂₀ alkyl group, a substituted or unsubstituted C₁-C₂₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), and —P(═O)(Q₄₀₁)(Q₄₀₂), wherein Q₄₀₁ to Q₄₀₃ may each independently be selected from a C₁-C₁₀ alkyl group, a C₁-C₁₀ alkoxy group, a C₆-C₂₀ aryl group, and a C₁-C₂₀ heteroaryl group,

xc11 and xc12 may each independently be an integer selected from 0 to 10, and

* and *′ in Formula 402 each independently indicate a binding site to M in Formula 401.

In various embodiments, A₄₀₁ and A₄₀₂ in Formula 402 may each independently be selected from a benzene group, a naphthalene group, a fluorene group, a spiro-bifluorene group, an indene group, a pyrrole group, a thiophene group, a furan group, an imidazole group, a pyrazole group, a thiazole group, an isothiazole group, an oxazole group, an isoxazole group, a pyridine group, a pyrazine group, a pyrimidine group, a pyridazine group, a quinoline group, an isoquinoline group, a benzoquinoline group, a quinoxaline group, a quinazoline group, a carbazole group, a benzimidazole group, a benzofuran group, a benzothiophene group, an isobenzothiophene group, a benzoxazole group, an isobenzoxazole group, a triazole group, a tetrazole group, an oxadiazole group, a triazine group, a dibenzofuran group, and a dibenzothiophene group.

In various embodiments, in Formula 402, i) X₄₀₁ may be nitrogen and X₄₀₂ may be carbon, or ii) both X₄₀₁ and X₄₀₂ may be nitrogen.

In various embodiments, R₄₀₁ and R₄₀₂ in Formula 402 may each independently be selected from the group consisting of:

hydrogen, deuterium, —F, —Cl, —Br, —I, a hydroxyl group, a cyano group, a nitro group, an amidino group, a hydrazino group, a hydrazono group, a C₁-C₂₀ alkyl group, and a C₁-C₂₀ alkoxy group;

a C₁-C₂₀ alkyl group and a C₁-C₂₀ alkoxy group, each substituted with at least one selected from deuterium, —F, —Cl, —Br, —I, a hydroxyl group, a cyano group, a nitro group, an amidino group, a hydrazino group, a hydrazono group, a phenyl group, a naphthyl group, a cyclopentyl group, a cyclohexyl group, an adamantanyl group, a norbornanyl group, and a norbornenyl group;

a cyclopentyl group, a cyclohexyl group, an adamantanyl group, a norbornanyl group, a norbornenyl group, a phenyl group, a biphenyl group, a terphenyl group, a naphthyl group, a fluorenyl group, a pyridinyl group, a pyrazinyl group, a pyrimidinyl group, a pyridazinyl group, a triazinyl group, a quinolinyl group, an isoquinolinyl group, a quinoxalinyl group, a quinazolinyl group, a carbazolyl group, a dibenzofuranyl group, and a dibenzothiophenyl group;

a cyclopentyl group, a cyclohexyl group, an adamantanyl group, a norbornanyl group, a norbornenyl group, a phenyl group, a biphenyl group, a terphenyl group, a naphthyl group, a fluorenyl group, a pyridinyl group, a pyrazinyl group, a pyrimidinyl group, a pyridazinyl group, a triazinyl group, a quinolinyl group, an isoquinolinyl group, a quinoxalinyl group, a quinazolinyl group, a carbazolyl group, a dibenzofuranyl group, and a dibenzothiophenyl group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, an adamantanyl group, a norbornanyl group, a norbornenyl group, a phenyl group, a biphenyl group, a terphenyl group, a naphthyl group, a fluorenyl group, a pyridinyl group, a pyrazinyl group, a pyrimidinyl group, a pyridazinyl group, a triazinyl group, a quinolinyl group, an isoquinolinyl group, a quinoxalinyl group, a quinazolinyl group, a carbazolyl group, a dibenzofuranyl group, and a dibenzothiophenyl group; and

—Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), and —P(═O)(Q₄₀₁)(Q₄₀₂),

wherein Q₄₀₁ to Q₄₀₃ may each independently be selected from a C₁-C₁₀ alkyl group, a C₁-C₁₀ alkoxy group, a phenyl group, a biphenyl group, and a naphthyl group, but embodiments are not limited thereto.

In various embodiments, when xc1 in Formula 401 is two or more, two A₄₀₁(s) selected from two or more L₄₀₁(s) may be optionally connected to each other via a linking group X₄₀₇, or two A₄₀₂(S) may be connected to each other via a linking group X₄₀₈ (see e.g., Compounds PD1 to PD4 and PD7 below). X₄₀₇ and X₄₀₈ may each independently be a single bond, *—O—*′, *—S—*′, *—C(═O)—*′, *—N(Q₄₁₃)-*′, *—C(Q₄₁₃)(Q₄₁₄)-*′, or *—C(Q₄₁₃)=C(Q₄₁₄)-*′ (wherein Q₄₁₃ and Q₄₁₄ may each independently be hydrogen, deuterium, a C₁-C₂₀ alkyl group, a C₁-C₂₀ alkoxy group, a phenyl group, a biphenyl group, a terphenyl group, or a naphthyl group), but are not limited thereto.

L₄₀₂ in Formula 401 may be any suitable monovalent, divalent, or trivalent organic ligand. For example, L₄₀₂ may be selected from a halogen ligand, a diketone ligand (e.g., an acetylacetonate), a carboxylic acid ligand (e.g., a picolinate), —C(═O), an isonitrile, —CN, and a phosphorus ligand (e.g., phosphine and/or phosphite), but is not limited thereto.

In various embodiments, the phosphorescent dopant may be selected from, for example, Compounds PD1 to PD25, but is not limited thereto:

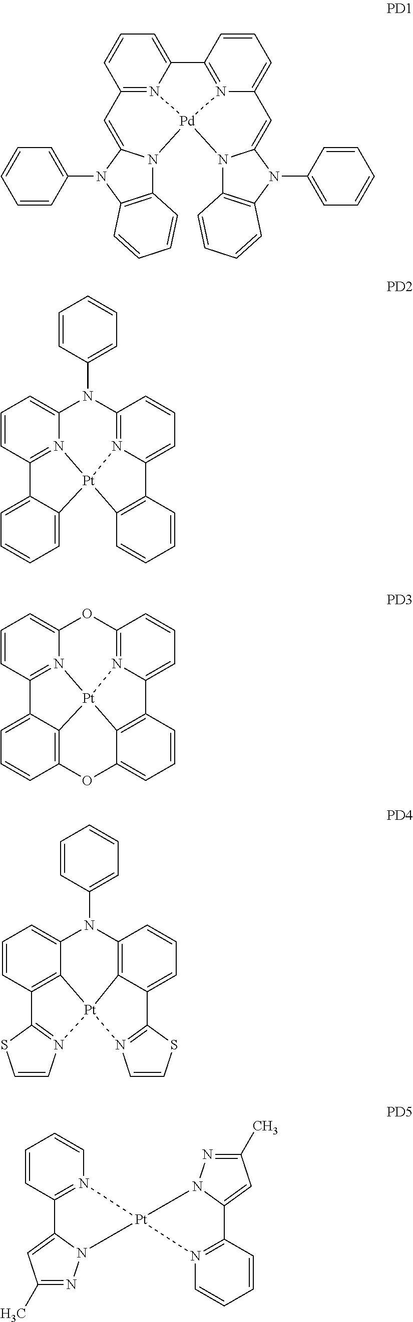

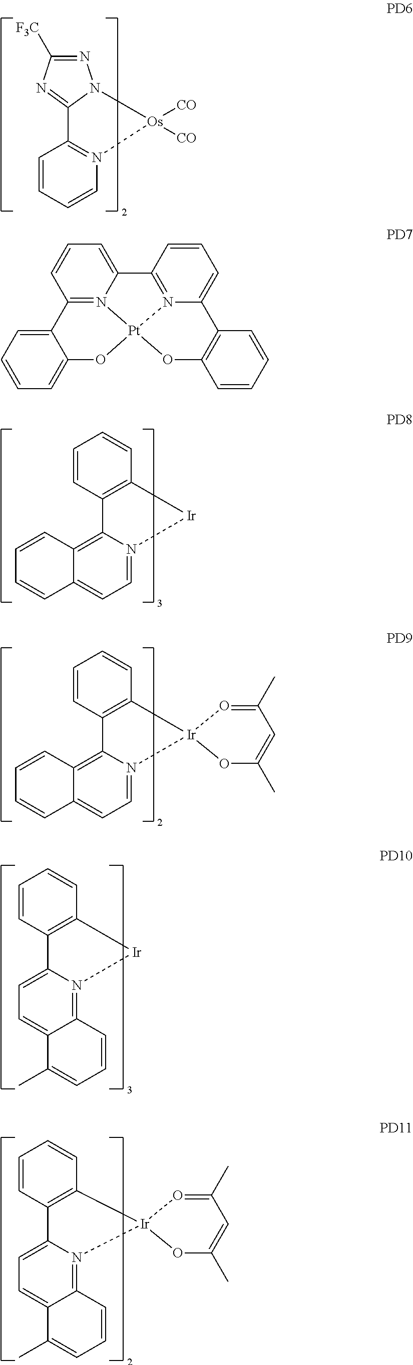

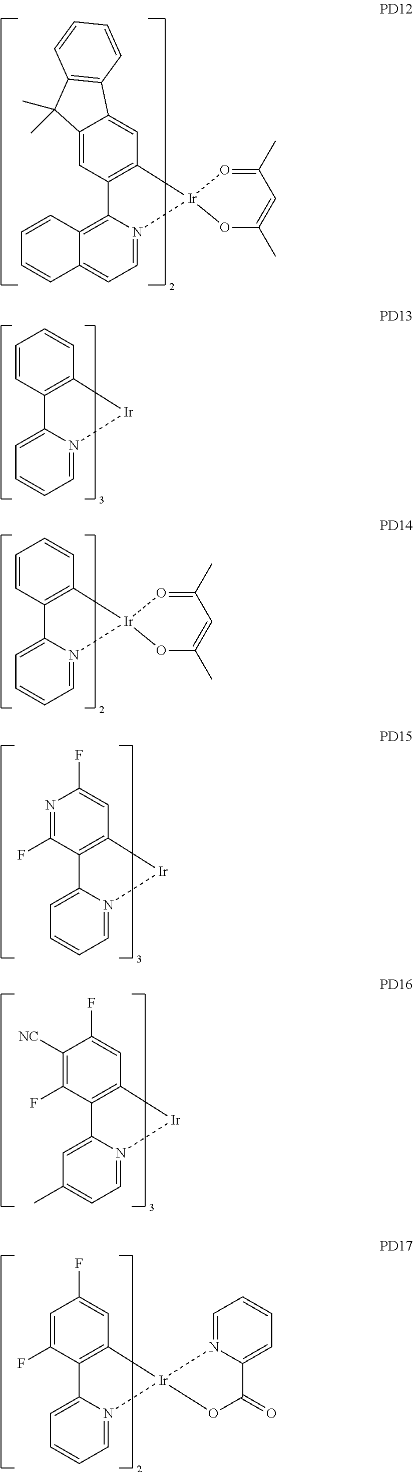

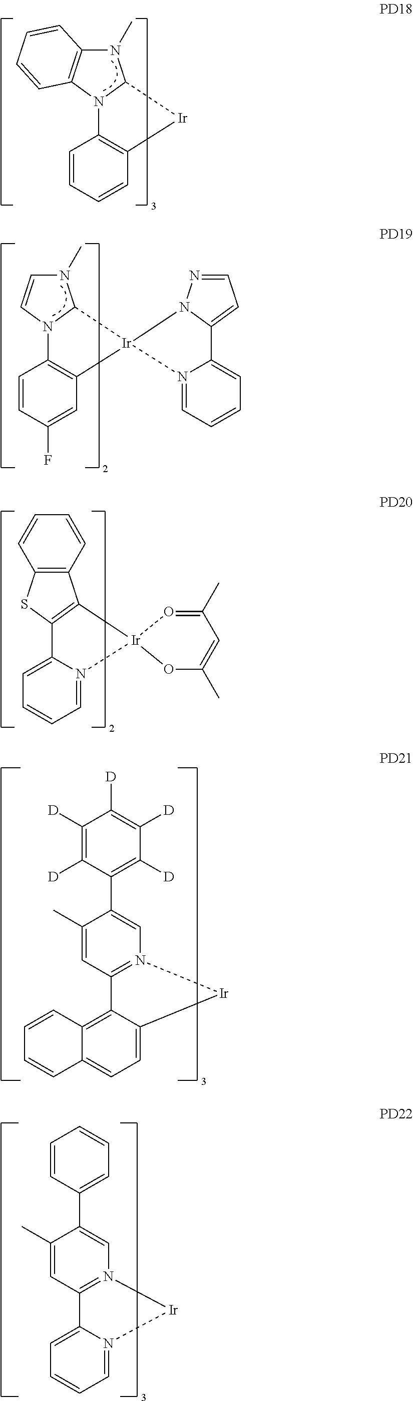

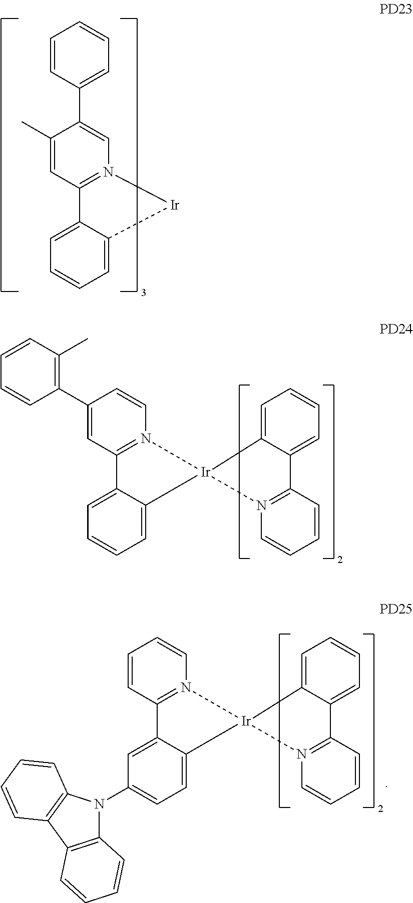

### Fluorescent Dopant in Emission Layer

The fluorescent dopant may include an arylamine compound or a styrylamine compound.

The fluorescent dopant may include a compound represented by Formula 501 below.

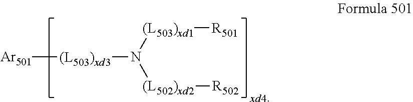

In Formula 501,

Ar₅₀₁ may be a substituted or unsubstituted C₅-C₆₀ carbocyclic group or a substituted or unsubstituted C₁-C₆₀ heterocyclic group,

L₅₀₁ to L₅₀₃ may each independently be selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,

xd1 to xd3 may each independently, be an integer selected from 0 to 3,

R₅₀₁ to R₅₀₂ may each independently be selected from a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arythio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, and

xd4 may be an integer selected from 1 to 6.

In various embodiments, Ar₅₀₁ in Formula 501 may be selected from the group consisting of:

a naphthalene group, a heptalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, and an indenophenanthrene group; and

a naphthalene group, a heptalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, and an indenophenanthrene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, and a naphthyl group.

In various embodiments, L₅₀₁ to L₅₀₃ in Formula 501 may each independently be selected from the group consisting of:

a phenylene group, a naphthylene group, a fluorenylene group, a spiro-bifluorenylene group, a benzofluorenylene group, a dibenzofluorenylene group, a phenanthrenylene group, an anthracenylene group, a fluoranthenylene group, a triphenylenylene group, a pyrenylene group, a chrysenylene group, a perylenylene group, a pentaphenylene group, a hexacenylene group, a pentacenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, and a pyridinylene group; and

a phenylene group, a naphthylene group, a fluorenylene group, a spiro-bifluorenylene group, a benzofluorenylene group, a dibenzofluorenylene group, a phenanthrenylene group, an anthracenylene group, a fluoranthenylene group, a triphenylenylene group, a pyrenylene group, a chrysenylene group, a perylenylene group, a pentaphenylene group, a hexacenylene group, a pentacenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, and a pyridinylene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, and a pyridinyl group.

In various embodiments, R₅₀₁ and R₅₀₂ in Formula 501 may each independently be selected from the group consisting of:

a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, and a pyridinyl group; and

a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, and a pyridinyl group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, and —Si(Q₃₁)(Q₃₂)(Q₃₃),

wherein Q₃₁ to Q₃₃ may each independently be selected from a C₁-C₁₀ alkyl group, a C₁-C₁₀ alkoxy group, a phenyl group, a biphenyl group, a terphenyl group, and a naphthyl group.

In various embodiments, xd4 in Formula 501 may be 2, but is not limited thereto.

For example, the fluorescent dopant may be selected from Compounds FD1 to FD22:

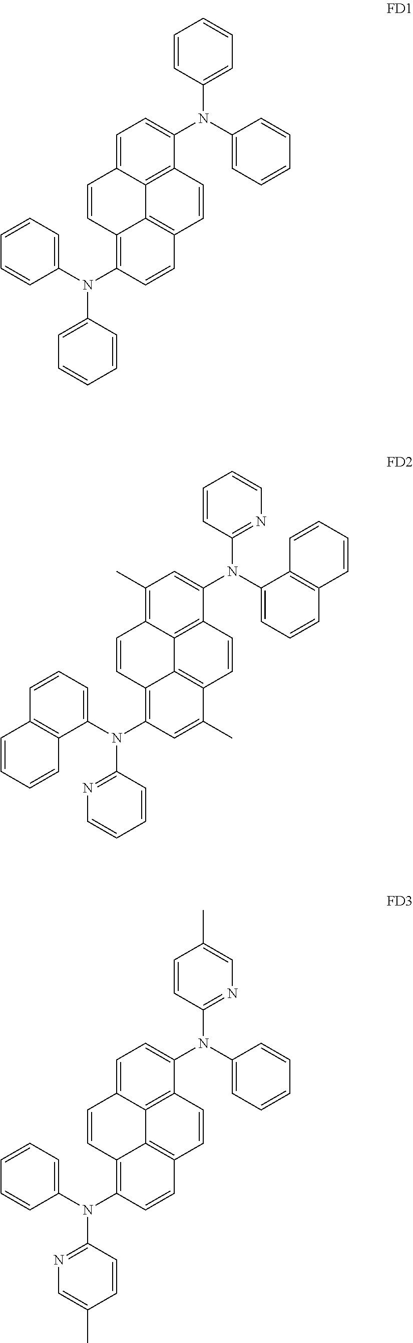 [SMILES: c1ccc(N(c2ccccc2)c2ccc3ccc4c(N(c5ccccc5)c5ccccc5)ccc5ccc2c3c54)cc1 ; Cc1cc(N(c2ccccn2)c2cccc3ccccc23)c2ccc3c(C)cc(N(c4ccccn4)c4cccc5ccccc45)c4ccc1c2c34 ; Cc1ccc(N(c2ccccc2)c2ccc3ccc4c(N(c5ccccc5)c5ccc(C)cn5)ccc5ccc2c3c54)nc1]

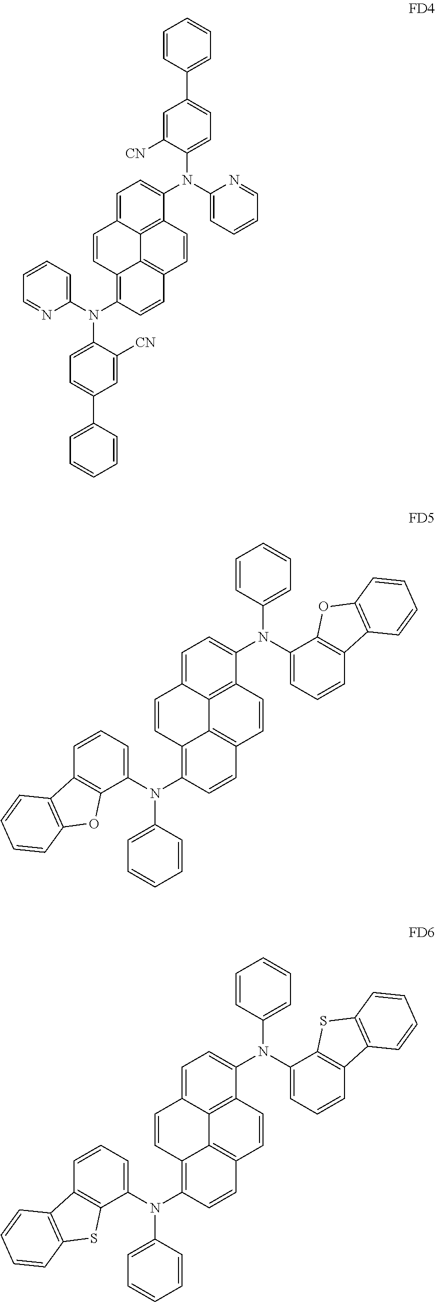

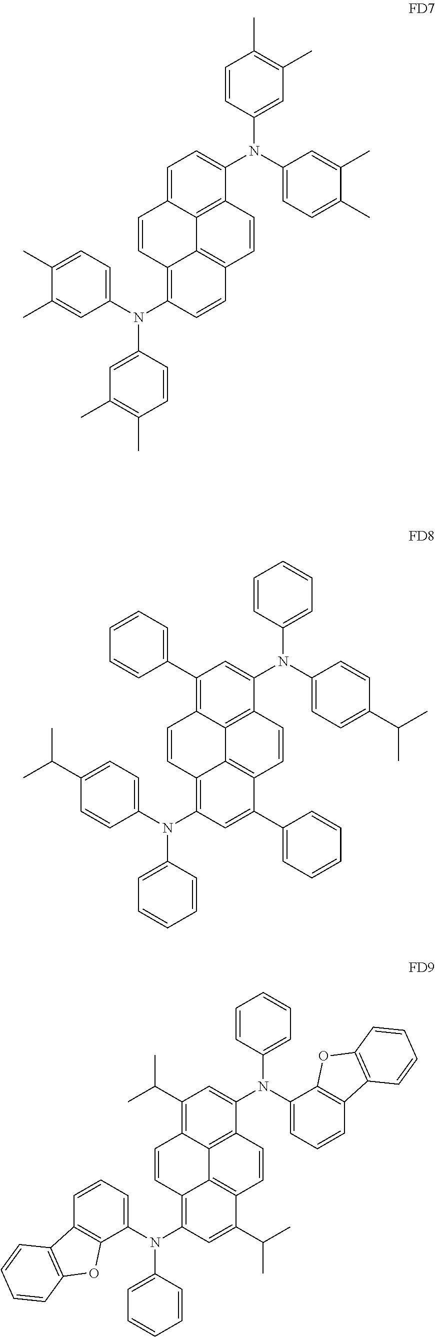

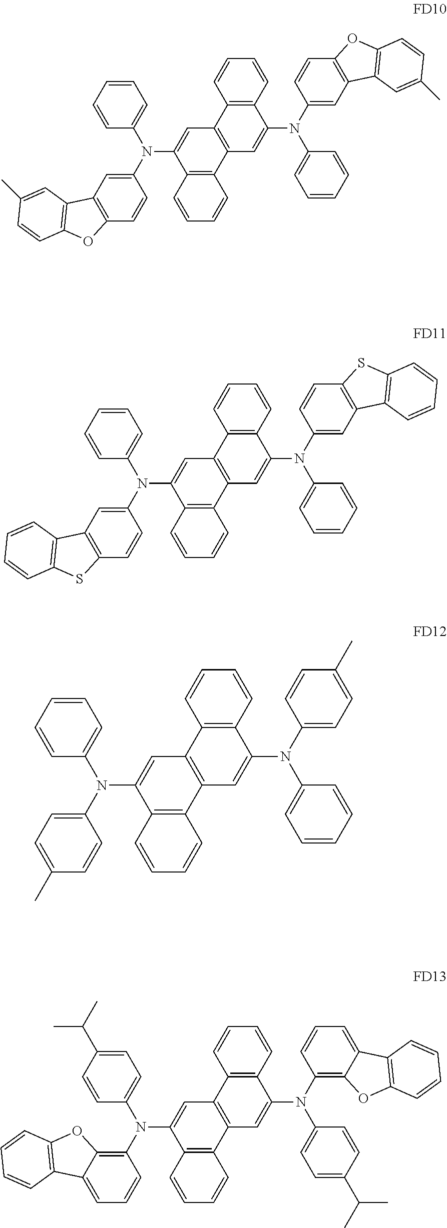

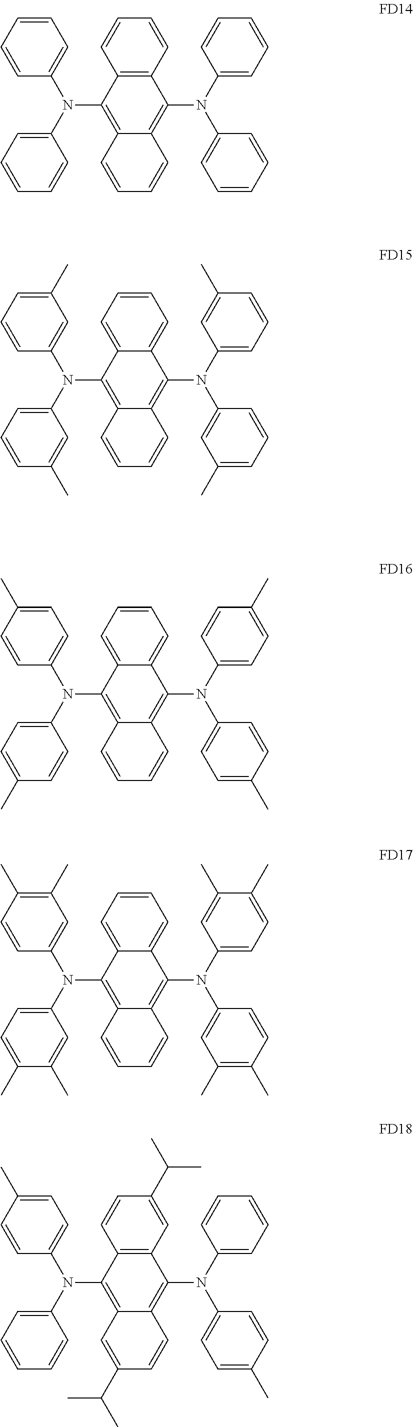 [SMILES: c1ccc(N(c2ccccc2)c2c3ccccc3c(N(c3ccccc3)c3ccccc3)c3ccccc23)cc1 ; Cc1cccc(N(c2cccc(C)c2)c2c3ccccc3c(N(c3cccc(C)c3)c3cccc(C)c3)c3ccccc23)c1 ; Cc1ccc(N(c2ccc(C)cc2)c2c3ccccc3c(N(c3ccc(C)cc3)c3ccc(C)cc3)c3ccccc23)cc1 ; Cc1ccc(N(c2ccc(C)c(C)c2)c2c3ccccc3c(N(c3ccc(C)c(C)c3)c3ccc(C)c(C)c3)c3ccccc23)cc1C ; Cc1ccc(N(c2ccccc2)c2c3ccc(C(C)C)cc3c(N(c3ccccc3)c3ccc(C)cc3)c3ccc(C(C)C)cc23)cc1]

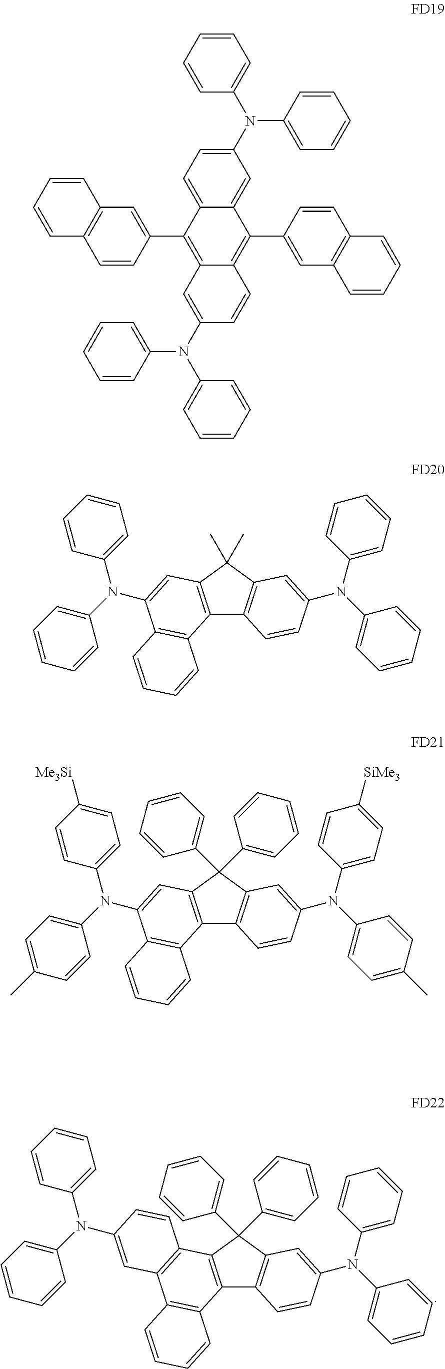

In various embodiments, the fluorescent dopant may be selected from compounds illustrated below, but is not limited thereto:

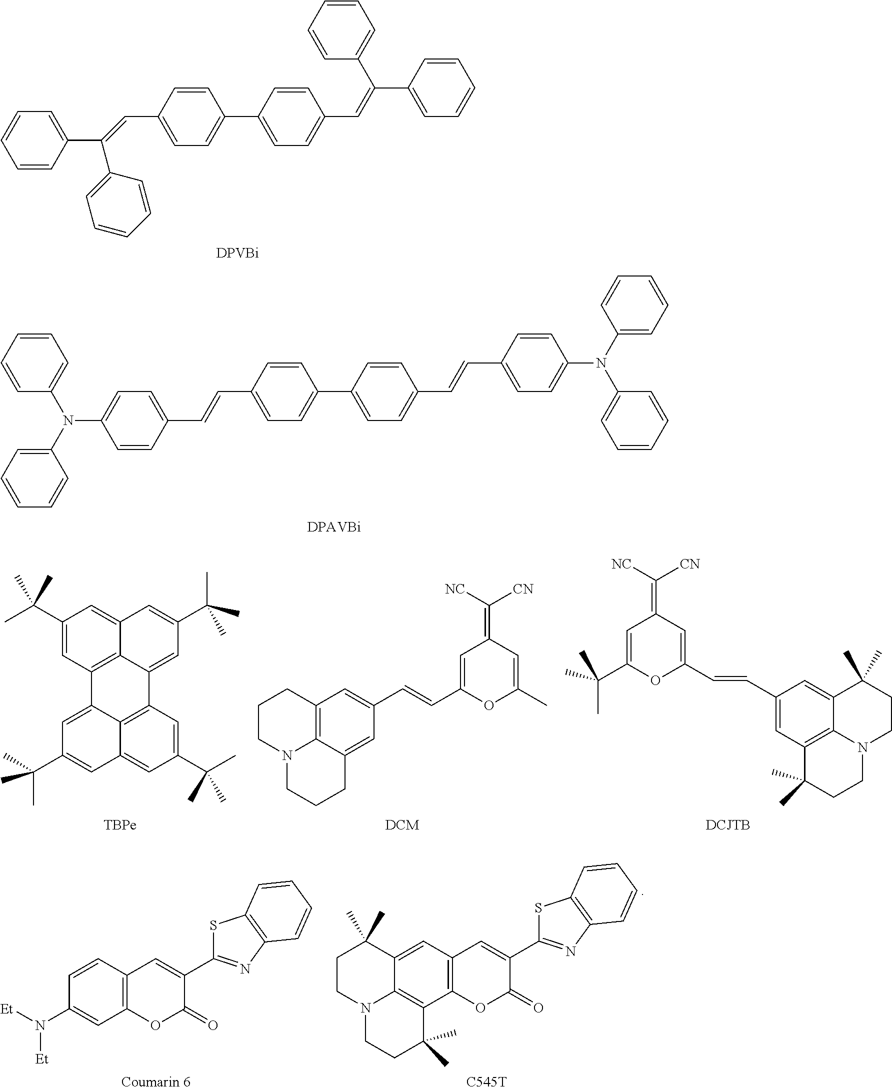

### Electron Transport Region in Organic Layer 150

The electron transport region may have i) a single-layered structure having a single layer including a single material, ii) a single-layered structure having a single layer including a plurality of different materials, or iii) a multi-layered structure having a plurality of layers including a plurality of different materials.

The electron transport region may include at least one selected from a buffer layer, a hole blocking layer, an electron control layer, an electron transport layer, and an electron injection layer, but is not limited thereto.

For example, the electron transport region may have a structure of electron transport layer/electron injection layer, a structure of hole blocking layer/electron transport layer/electron injection layer, a structure of electron control layer/electron transport layer/electron injection layer, or a structure of buffer layer/electron transport layer/electron injection layer, wherein in each of these structures, constituting layers are sequentially stacked in this stated order from an emission layer. However, the structure of the electron transport region is not limited thereto.

The electron transport region (e.g., a buffer layer, a hole blocking layer, an electron control layer, and/or an electron transport layer in the electron transport region) may include a metal-free compound containing at least one π electron-depleted nitrogen-containing ring.

The term “π electron-depleted nitrogen-containing ring” as used herein may refer to a C₁-C₆₀ heterocyclic group having at least one *—N═*′ moiety as a ring-forming moiety.

For example, the “π electron-depleted nitrogen-containing ring” may be i) a 5-membered to 7-membered hetero monocyclic group having at least one *—N═*′ moiety, ii) a hetero polycyclic group in which two or more 5-membered to 7-membered hetero monocyclic groups, each having at least one *—N═*′ moiety, are condensed (e.g., fused) with each other, or iii) a hetero polycyclic group in which at least one of 5-membered to 7-membered hetero monocyclic groups, each having at least one *—N═*′ moiety, is condensed (e.g., fused) with at least one C₅-C₆₀ carbocyclic group.

Examples of the π electron-depleted nitrogen-containing ring include an imidazole group, a pyrazole group, a thiazole group, an isothiazole group, an oxazole group, an isoxazole group, a pyridine group, a pyrazine group, a pyrimidine group, a pyridazine group, an indazole group, a purine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, and an azacarbazole group, but are not limited thereto.

For example, the electron transport region may include a compound represented by Formula 601 (described below).

For example, the electron transport region (e.g., a buffer layer, a hole blocking layer, an electron control layer, and/or an electron transport layer in the electron transport region) may include the second compound represented by Formula 2.

For example, the electron transport region (e.g., a buffer layer, a hole blocking layer, an electron control layer, and/or an electron transport layer in the electron transport region) may include the first compound represented by Formula 1 and the second compound represented by Formula 2.

In various embodiments, the electron transport region may include a first layer, and the first layer may include the second compound represented by Formula 2, but embodiments are not limited thereto. In this regard, the first layer may be an electron transport layer.

In various embodiments, the electron transport region may include a first layer and a second layer, the first layer being between the emission layer and the second layer, and the first layer may include the second compound represented by Formula 2, but embodiments are not limited thereto. In this regard, the first layer may be a buffer layer, and the second layer may be an electron transport layer.

In various embodiments, the electron transport region may include a first layer and a second layer, the first layer being between the emission layer and the second layer, and the first layer may include the first compound represented by Formula 1 and the second layer may include the second compound represented by Formula 2, but embodiments are not limited thereto. In this regard, the first layer may be a buffer layer, and the second layer may be an electron transport layer.

In various embodiments, the electron transport region may include a first layer and a second layer, the first layer being between the emission layer and the second layer, the first layer may include the second compound represented by Formula 2, the second layer may include the second compound represented by Formula 2, and the second compound included in the first layer may be different from the second compound included in the second layer, but embodiments are not limited thereto. In this regard, the first layer may be a buffer layer, and the second layer may be an electron transport layer.

The electron transport region may further include, in addition to the second compound represented by Formula 2, or in addition to the first compound represented by Formula 1 and the second compound represented by Formula 2, a compound represented by Formula 601.

[Ar₆₀₁]ₓₑ₁₁-[(L₆₀₁)ₓₑ₁-R₆₀₁]ₓₑ₂₁. Formula 601

In Formula 601,

Ar₆₀₁ may be a substituted or unsubstituted C₅-C₆₀ carbocyclic group or a substituted or unsubstituted C₁-C₆₀ heterocyclic group,

xe11 may be 1, 2, or 3,

L₆₀₁ may be selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,

xe1 may be an integer selected from 0 to 5,

R₆₀₁ may be selected from a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₆₀₁)(Q₆₀₂)(Q₆₀₃), —C(═O)(Q₆₀₁), —S(═O)₂(Q₆₀₁), and —P(═O)(Q₆₀₁)(Q₆₀₂),

where Q₆₀₁ to Q₆₀₃ may each independently be a C₁-C₁₀ alkyl group, a C₁-C₁₀ alkoxy group, a phenyl group, a biphenyl group, a terphenyl group, or a naphthyl group, and

xe21 may be an integer selected from 1 to 5.

In various embodiments, xe11 number of Ar₆₀₁(s) and/or xe21 number of R₆₀₁(s) may include the π electron-depleted nitrogen-containing ring as described herein.

In various embodiments, Ar₆₀₁ in Formula 601 may be selected from the group consisting of:

a benzene group, a naphthalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, a dibenzofuran group, a dibenzothiophene group, a carbazole group, an imidazole group, a pyrazole group, a thiazole group, an isothiazole group, an oxazole group, an isoxazole group, a pyridine group, a pyrazine group, a pyrimidine group, a pyridazine group, an indazole group, a purine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, an iso-benzothiazole group, a benzoxazole group, an isobenzoxazole group, a triazole group, a tetrazole group, an oxadiazole group, a triazine group, a thiadiazol group, an imidazopyridine group, an imidazopyrimidine group, and an azacarbazole group; and

a benzene group, a naphthalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, a dibenzofuran group, a dibenzothiophene group, a carbazole group, an imidazole group, a pyrazole group, a thiazole group, an isothiazole group, an oxazole group, an isoxazole group, a pyridine group, a pyrazine group, a pyrimidine group, a pyridazine group, an indazole group, a purine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, an iso-benzothiazole group, a benzoxazole group, an isobenzoxazole group, a triazole group, a tetrazole group, an oxadiazole group, a triazine group, a thiadiazol group, an imidazopyridine group, an imidazopyrimidine group, and an azacarbazole group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, —Si(Q₃₁)(Q₃₂)(Q₃₃), —S(═O)₂(Q₃₁), and —P(═O)(Q₃₁)(Q₃₂),

wherein Q₃₁ to Q₃₃ may each independently be selected from a C₁-C₁₀ alkyl group, a C₁-C₁₀ alkoxy group, a phenyl group, a biphenyl group, a terphenyl group, and a naphthyl group.

When xe11 in Formula 601 is two or more, two or more Ar₆₀₁(s) may be connected to each other via a single bond.

In various embodiments, Ar₆₀₁ in Formula 601 may be an anthracene group.

In various embodiments, a compound represented by Formula 601 may be represented by Formula 601-1:

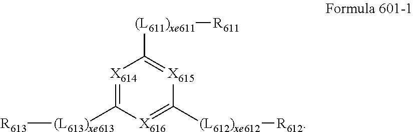

In Formula 601-1,

X₆₁₄ may be N or C(R₆₁₄), X₆₁₅ may be N or C(R₆₁₅), X₆₁₆ may be N or C(R₆₁₆), and at least one selected from X₆₁₄ to X₆₁₆ may be N,

descriptions of L₆₁₁ to L₆₁₃ may each independently be the same as the description provided in connection with L₆₀₁,

descriptions of xe611 to xe613 may each independently be the same as the description provided in connection with xe1,

descriptions of R₆₁₁ to R₆₁₃ may each independently be the same as the description provided in connection with R₆₀₁,

R₆₁₄ to R₆₁₆ may each independently be selected from hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, and a naphthyl group.

In various embodiments, L₆₀₁ and L₆₁₁ to L₆₁₃ in Formulae 601 and 601-1 may each independently be selected from the group consisting of:

a phenylene group, a naphthylene group, a fluorenylene group, a spiro-bifluorenylene group, a benzofluorenylene group, a dibenzofluorenylene group, a phenanthrenylene group, an anthracenylene group, a fluoranthenylene group, a triphenylenylene group, a pyrenylene group, a chrysenylene group, a perylenylene group, a pentaphenylene group, a hexacenylene group, a pentacenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, a pyridinylene group, an imidazolylene group, a pyrazolylene group, a thiazolylene group, an isothiazolylene group, an oxazolylene group, an isoxazolylene group, a thiadiazolylene group, an oxadiazolylene group, a pyrazinylene group, a pyrimidinylene group, a pyridazinylene group, a triazinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a phenanthridinylene group, an acridinylene group, a phenanthrolinylene group, a phenazinylene group, a benzimidazolylene group, an isobenzothiazolylene group, a benzoxazolylene group, an isobenzoxazolylene group, a triazolylene group, a tetrazolylene group, an imidazopyridinylene group, an imidazopyrimidinylene group, and an azacarbazolylene group; and

a phenylene group, a naphthylene group, a fluorenylene group, a spiro-bifluorenylene group, a benzofluorenylene group, a dibenzofluorenylene group, a phenanthrenylene group, an anthracenylene group, a fluoranthenylene group, a triphenylenylene group, a pyrenylene group, a chrysenylene group, a perylenylene group, a pentaphenylene group, a hexacenylene group, a pentacenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, a pyridinylene group, an imidazolylene group, a pyrazolylene group, a thiazolylene group, an isothiazolylene group, an oxazolylene group, an isoxazolylene group, a thiadiazolylene group, an oxadiazolylene group, a pyrazinylene group, a pyrimidinylene group, a pyridazinylene group, a triazinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a phenanthridinylene group, an acridinylene group, a phenanthrolinylene group, a phenazinylene group, a benzimidazolylene group, an isobenzothiazolylene group, a benzoxazolylene group, an isobenzoxazolylene group, a triazolylene group, a tetrazolylene group, an imidazopyridinylene group, an imidazopyrimidinylene group, and an azacarbazolylene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, and an azacarbazolyl group,

but embodiments are not limited thereto.

In various embodiments, xe1 and xe611 to xe613 in Formulae 601 and 601-1 may each independently be 0, 1, or 2.

In various embodiments, R₆₀₁ and R₆₁₁ to R₆₁₃ in Formulae 601 and 601-1 may each independently be selected from the group consisting of:

a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, and an azacarbazolyl group;

a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, and an azacarbazolyl group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, and an azacarbazolyl group; and

—S(═O)₂(Q₆₀₁) and —P(═O)(Q₆₀₁)(Q₆₀₂),

wherein Q₆₀₁ and Q₆₀₂ are the same as described herein.

The electron transport region may include at least one compound selected from Compounds ET1 to ET36, but is not limited thereto:

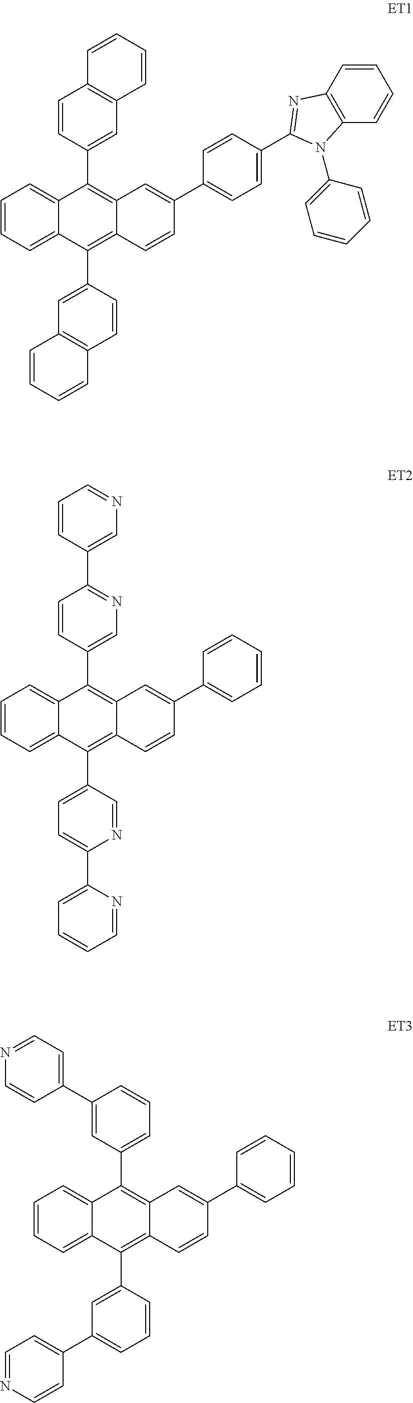 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5cccnc5)nc4)c3c2)cc1 ; c1ccc(-c2ccc3c(-c4cccc(-c5ccncc5)c4)c4ccccc4c(-c4cccc(-c5ccncc5)c4)c3c2)cc1]

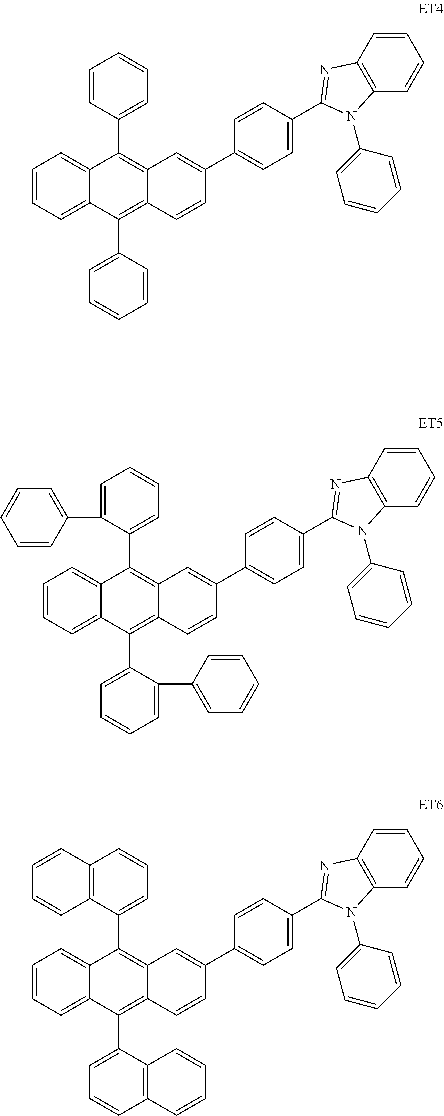 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

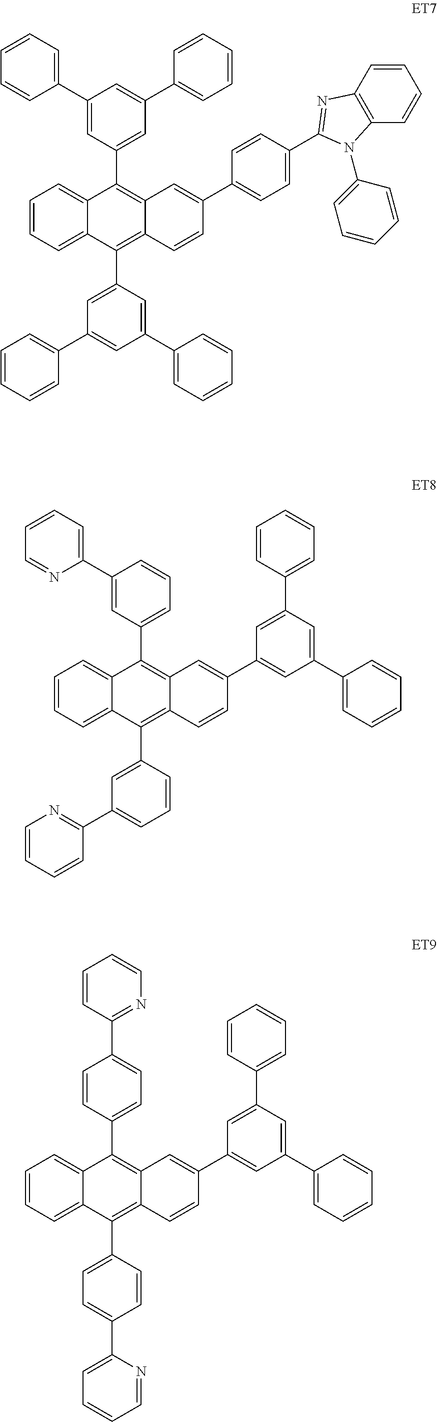 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

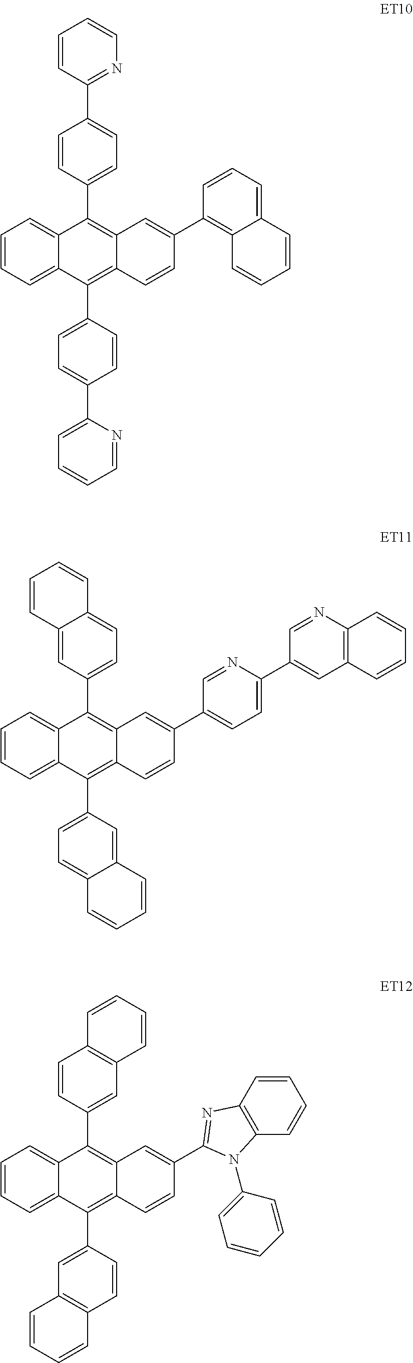 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

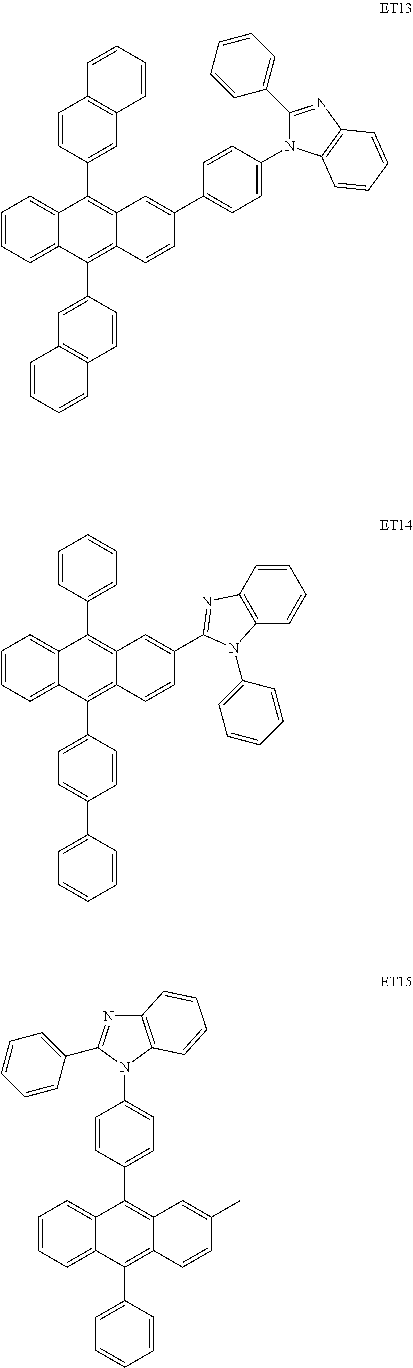 [SMILES: c1ccc(-c2nc3ccccc3n2-c2ccc(-c3ccc4c(-c5ccc6ccccc6c5)c5ccccc5c(-c5ccc6ccccc6c5)c4c3)cc2)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

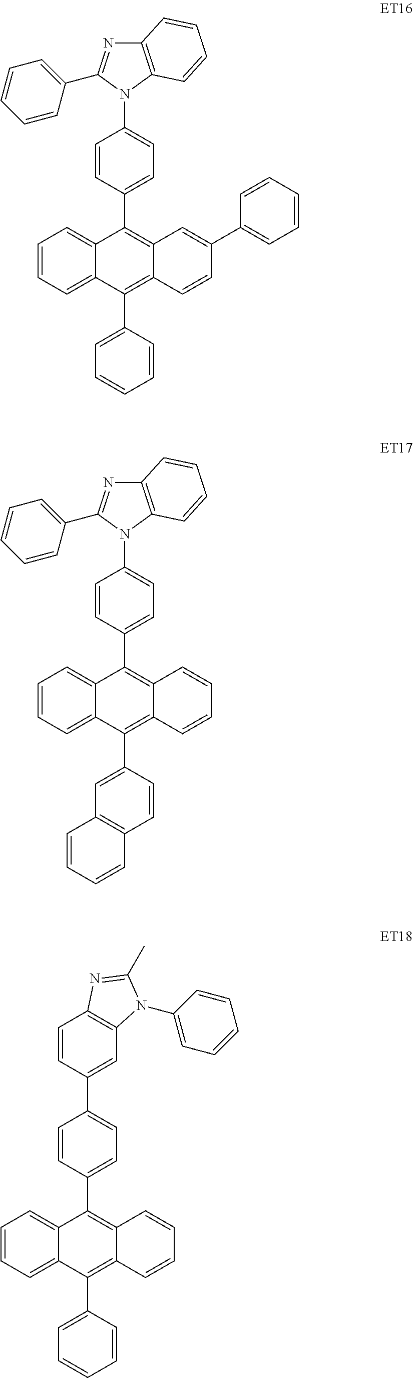 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

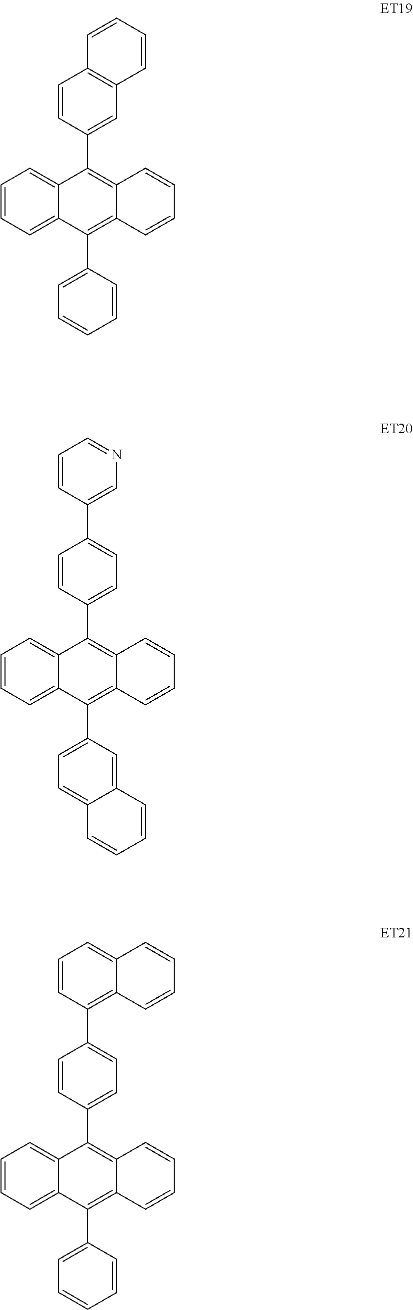

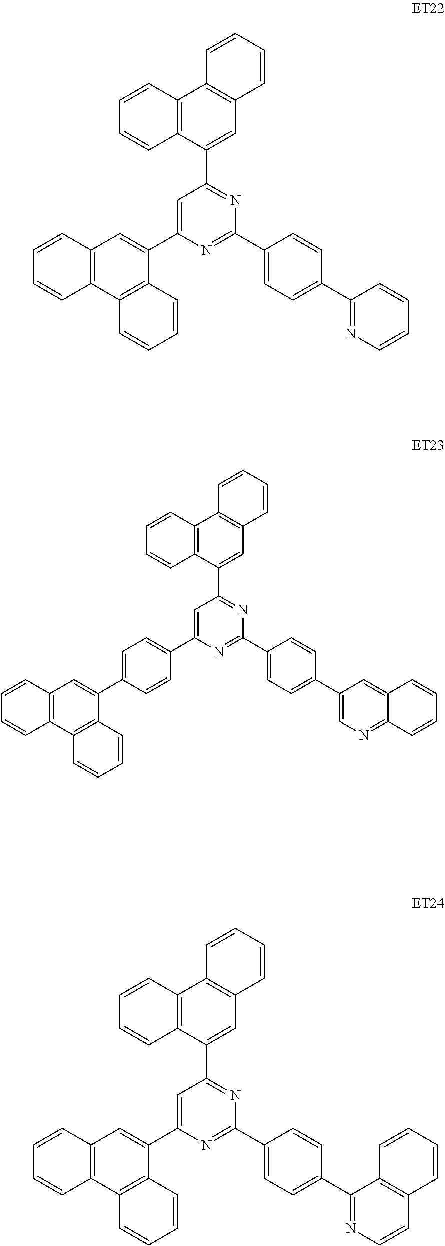 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

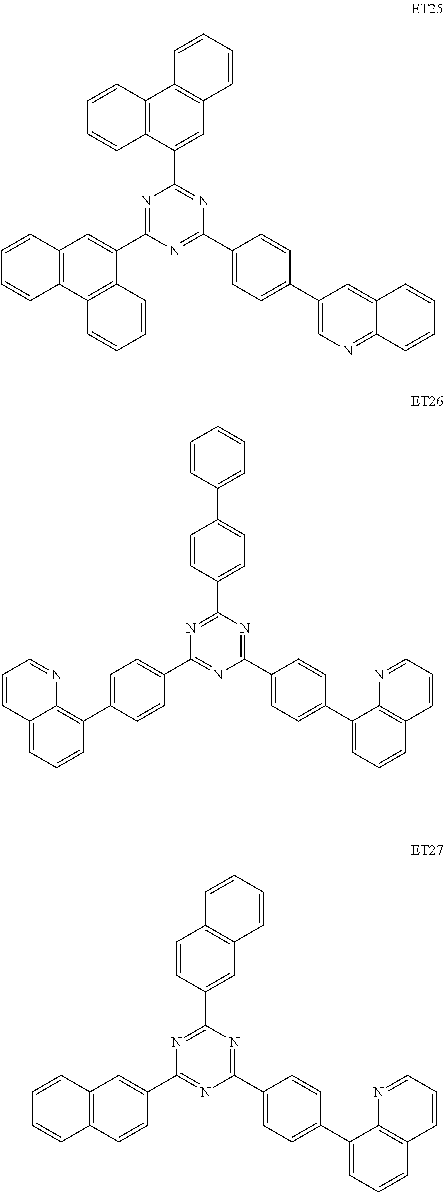 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

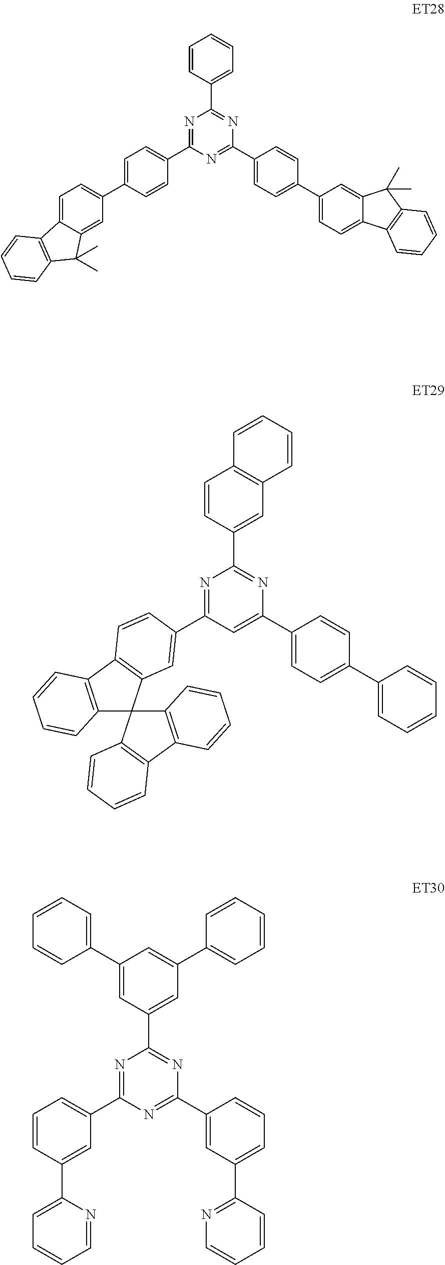 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

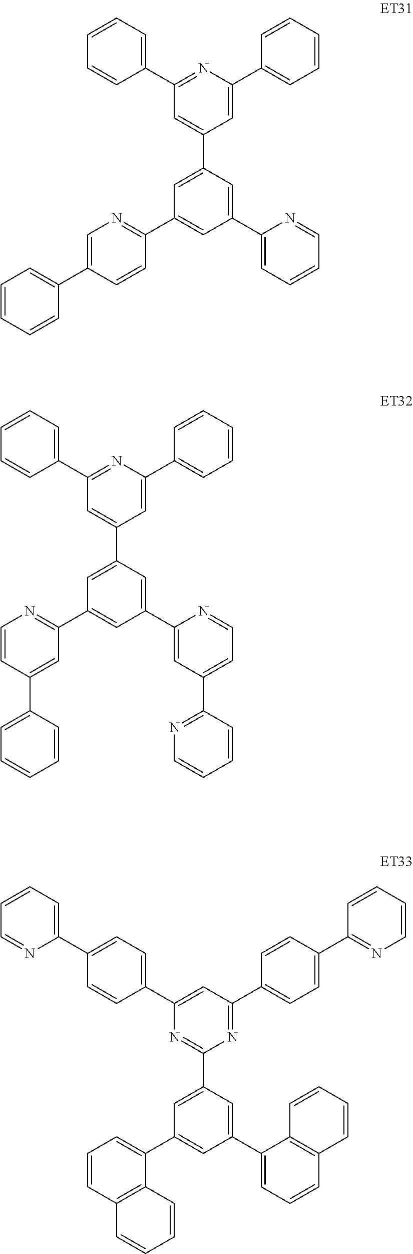 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccn5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

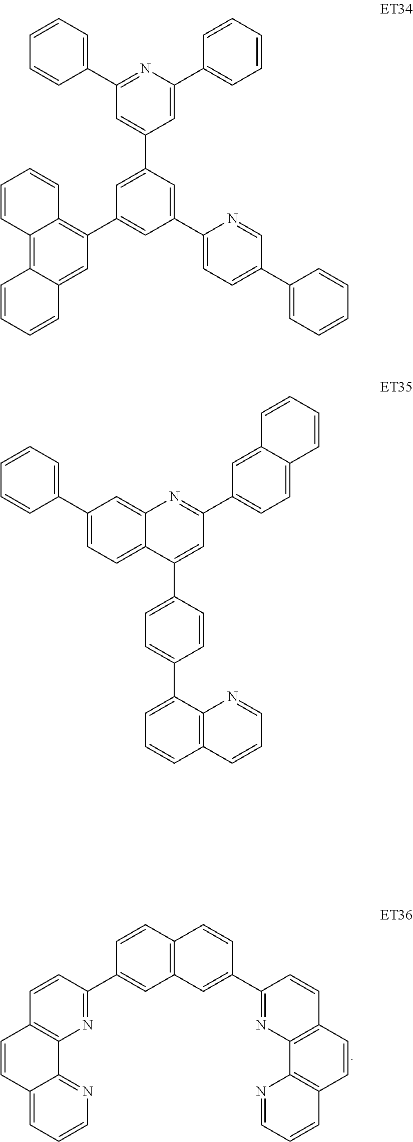 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In various embodiments, the electron transport region may include at least one selected from 2,9-dimethyl-4,7-diphenyl-1,10-phenanthroline (BCP), 4,7-diphenyl-1,10-phenanthroline (Bphen), Alq₃, BAlq, 3-(biphenyl-4-yl)-5-(4-tert-butylphenyl)-4-phenyl-4H-1,2,4-triazole (TAZ), and NTAZ:

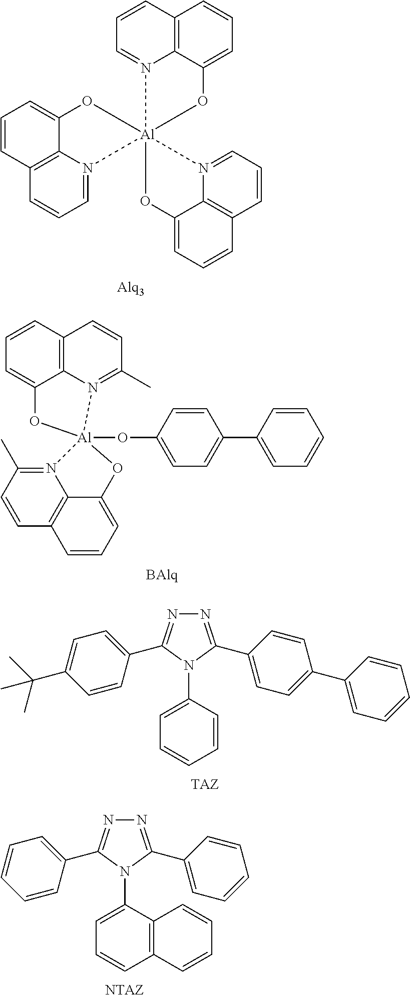

A thickness of the buffer layer, the hole blocking layer, and the electron control layer may each independently be in a range of about 20 Å to about 1,000 Å, for example, about 30 Å to about 300 Å. When the thicknesses of the buffer layer, the hole blocking layer, and the electron control layer are within any of these ranges, the electron transport region may have excellent (or suitable) hole blocking characteristics and/or electron control characteristics without a substantial increase in driving voltage.

A thickness of the electron transport layer may be in a range of about 100 Å to about 1,000 Å, for example, about 150 Å to about 500 Å. When the thickness of the electron transport layer is within any of the ranges described above, the electron transport layer may have satisfactory (or suitable) electron transport characteristics without a substantial increase in driving voltage.

The electron transport region (e.g., the electron transport layer in the electron transport region) may further include, in addition to the materials described above, a metal-containing material.

The metal-containing material may include at least one selected from an alkaline metal complex and an alkaline earth-metal complex. The alkaline metal complex may include a metal ion selected from a Li ion, a Na ion, a K ion, a Rb ion, and a Cs ion; and the alkaline earth-metal complex may include a metal ion selected from a Be ion, a Mg ion, a Ca ion, a Sr ion, and a Ba ion. A ligand coordinated with the metal ion of the alkaline metal complex or the alkaline earth-metal complex may each independently be selected from a hydroxy quinoline, a hydroxy isoquinoline, a hydroxy benzoquinoline, a hydroxy acridine, a hydroxy phenanthridine, a hydroxy phenylan oxazole, a hydroxy phenylthiazole, a hydroxy diphenylan oxadiazole, a hydroxy diphenylthiadiazole, a hydroxy phenylpyridine, a hydroxy phenylbenzimidazole, a hydroxy phenylbenzothiazole, a bipyridine, a phenanthroline, and a cyclopentadiene, but is not limited thereto.

For example, the metal-containing material may include a Li complex. The Li complex may include, for example, Compound ET-D1 (lithium quinolate, LiQ) and/or Compound ET-D2:

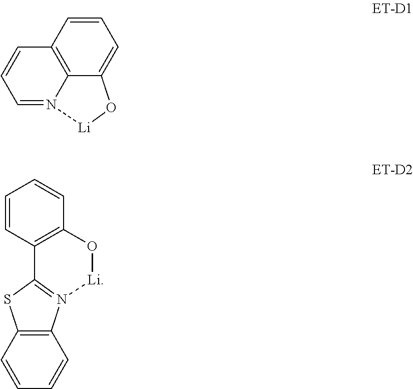

The electron transport region may include an electron injection layer that facilitates injection of electrons from the second electrode 190. The electron injection layer may directly contact the second electrode 190.

The electron injection layer may have i) a single-layered structure having a single layer including a single material, ii) a single-layered structure having a single layer including a plurality of different materials, or iii) a multi-layered structure having a plurality of layers including a plurality of different materials.

The electron injection layer may include an alkaline metal, an alkaline earth metal, a rare-earth metal, an alkaline metal compound, an alkaline earth-metal compound, a rare-earth metal compound, an alkaline metal complex, an alkaline earth-metal complex, a rare-earth metal complex, or a combination thereof.

The alkaline metal may be selected from Li, Na, K, Rb, and Cs. In various embodiments, the alkaline metal may be Li, Na, or Cs. In various embodiments, the alkaline metal may be Li or Cs, but is not limited thereto.

The alkaline earth metal may be selected from Mg, Ca, Sr, and Ba.

The rare-earth metal may be selected from Sc, Y, Ce, Tb, Yb, Gd, and Tb.

The alkaline metal compound, the alkaline earth-metal compound, and the rare-earth metal compound may be selected from oxides and halides (e.g., fluorides, chlorides, bromides, and/or iodines) of the alkaline metal, the alkaline earth-metal and the rare-earth metal, respectively.

The alkaline metal compound may be selected from alkaline metal oxides (such as Li₂O, Cs₂O, and/or K₂O) and alkaline metal halides (such as LiF, NaF, CsF, KF, LiI, NaI, CsI, and/or Kl). In various embodiments, the alkaline metal compound may be selected from LiF, Li₂O, NaF, LiI, NaI, CsI, and Kl, but is not limited thereto.

The alkaline earth-metal compound may be selected from, for example, BaO, SrO, CaO, BaₓSr₁₋ₓO (0<x<1), and BaₓCa₁₋ₓO (0<x<1). In various embodiments, the alkaline earth-metal compound may be selected from BaO, SrO, and CaO, but is not limited thereto.

The rare-earth metal compound may be selected from YbF₃, ScF₃, ScO₃, Y₂O₃, Ce₂O₃, GdF₃, and TbF₃. In various embodiments, the rare-earth metal compound may be selected from YbF₃, ScF₃, TbF₃, Ybl₃, Scl₃, and Tbl₃, but is not limited thereto.

The alkaline metal complex, the alkaline earth-metal complex, and the rare-earth metal complex may include an ion of the alkaline metal, an ion of the alkaline earth metal, and an ion of the rare-earth metal, respectively, as described above, and a ligand coordinated with the ion of the alkaline metal complex, the alkaline earth-metal complex, and the rare-earth metal complex may each independently be selected from a hydroxy quinoline, a hydroxy isoquinoline, a hydroxy benzoquinoline, a hydroxy acridine, a hydroxy phenanthridine, a hydroxy phenylan oxazole, a hydroxy phenylthiazole, a hydroxy diphenylan oxadiazole, a hydroxy diphenylthiadiazole, a hydroxy phenylpyridine, a hydroxy phenylbenzimidazole, a hydroxy phenylbenzothiazole, a bipyridine, a phenanthroline, and a cyclopentadiene, but is not limited thereto.

The electron injection layer may include an alkaline metal, an alkaline earth metal, a rare-earth metal, an alkaline metal compound, an alkaline earth-metal compound, a rare-earth metal compound, an alkaline metal complex, an alkaline earth-metal complex, a rare-earth metal complex, or a combination thereof, as described above. In various embodiments, the electron injection layer may further include an organic material. When the electron injection layer further includes an organic material, an alkaline metal, an alkaline earth metal, a rare-earth metal, an alkaline metal compound, an alkaline earth-metal compound, a rare-earth metal compound, alkaline metal complex, an alkaline earth-metal complex, a rare-earth metal complex, or a combination thereof may be homogeneously or non-homogeneously dispersed in a matrix including the organic material.

A thickness of the electron injection layer may be in a range of about 1 Å to about 100 Å, for example, about 3 Å to about 90 Å. When the thickness of the electron injection layer is within any of the ranges described above, the electron injection layer may have satisfactory (or suitable) electron injection characteristics without a substantial increase in driving voltage.

### Second Electrode 190

The second electrode 190 may be disposed (e.g., positioned) on the organic layer 150 having the structure according to embodiments of the present disclosure. The second electrode 190 may be a cathode, which is an electron injection electrode, and in this regard, a material for forming the second electrode 190 may be selected from a metal, an alloy, an electrically conductive compound, and a mixture thereof, which have a relatively low work function.

In some embodiments, the second electrode 190 may include at least one selected from lithium (Li), silver (Ag), magnesium (Mg), aluminum (Al), aluminum-lithium (Al—Li), calcium (Ca), magnesium-indium (Mg—In), magnesium-silver (Mg—Ag), ITO, and IZO, but is not limited thereto. The second electrode 190 may be a transmissive electrode, a semi-transmissive electrode, or a reflective electrode.

The second electrode 190 may have a single-layered structure, or a multi-layered structure including two or more layers.

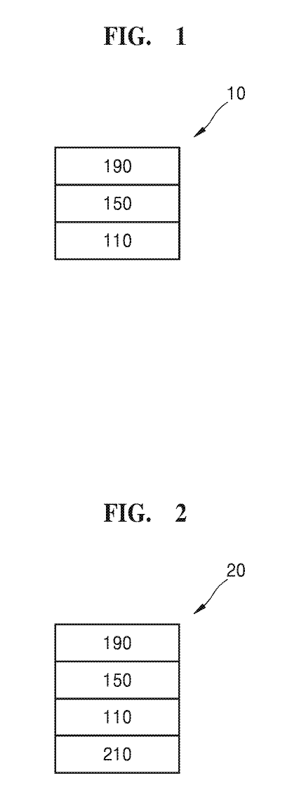

### Description of FIGS. 2 to 4

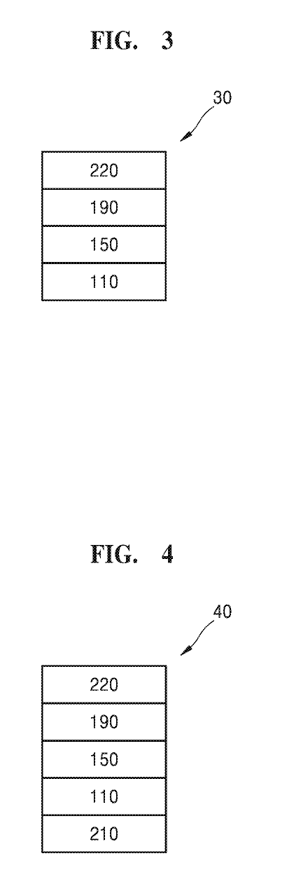

An organic light-emitting device 20 of FIG. 2 includes a first capping layer 210, a first electrode 110, an organic layer 150, and a second electrode 190 which are sequentially stacked in this stated order; an organic light-emitting device 30 of FIG. 3 includes a first electrode 110, an organic layer 150, a second electrode 190, and a second capping layer 220 which are sequentially stacked in this stated order; and an organic light-emitting device 40 of FIG. 4 includes a first capping layer 210, a first electrode 110, an organic layer 150, a second electrode 190, and a second capping layer 220 which are sequentially stacked in this stated order.

Regarding FIGS. 2 to 4, descriptions of the first electrode 110, the organic layer 150, and the second electrode 190 may be understood by referring to the descriptions thereof presented in connection with FIG. 1.

In the organic layer 150 of each of the organic light-emitting devices 20 and 40, light generated in an emission layer may pass through the first electrode 110 (which may be a semi-transmissive electrode or a transmissive electrode) and the first capping layer 210 toward the outside; and in the organic layer 150 of each of the organic light-emitting devices 30 and 40, light generated in an emission layer may pass through the second electrode 190 (which may be a semi-transmissive electrode or a transmissive electrode) and the second capping layer 220 toward the outside.

The first capping layer 210 and the second capping layer 220 may increase external luminescent efficiency according to the principle of constructive interference.

The first capping layer 210 and the second capping layer 220 may each independently be an organic capping layer including an organic material, an inorganic capping layer including an inorganic material, or a composite capping layer including an organic material and an inorganic material.

At least one selected from the first capping layer 210 and the second capping layer 220 may include at least one material selected from carbocyclic compounds, heterocyclic compounds, amine-based compounds, porphine derivatives, phthalocyanine derivatives, naphthalocyanine derivatives, alkaline metal complexes, and alkaline earth-based complexes. The carbocyclic compound, the heterocyclic compound, and the amine-based compound may be optionally substituted with a substituent containing at least one element selected from O, N, S, Se, Si, F, Cl, Br, and I. In various embodiments, at least one selected from the first capping layer 210 and the second capping layer 220 may include an amine-based compound.

In one embodiment, at least one selected from the first capping layer 210 and the second capping layer 220 may include the compound represented by Formula 201 or the compound represented by Formula 202.

In various embodiments, at least one selected from the first capping layer 210 and the second capping layer 220 may include a compound selected from Compounds HT28 to HT33 and Compounds CP1 to CP5, but is not limited thereto:

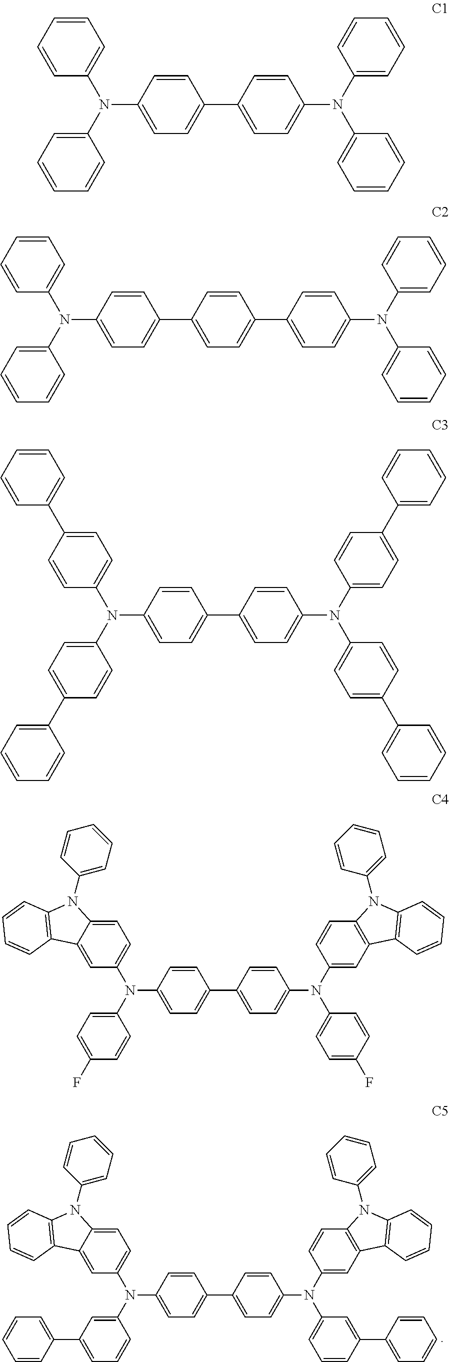 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

Hereinbefore, the organic light-emitting device according to an embodiment of the present disclosure has been described in connection with FIGS. 1 to 4. However, present embodiments are not limited thereto.

Layers constituting the hole transport region, the emission layer, and layers constituting the electron transport region may each independently be formed in a certain region by using one or more suitable methods such as vacuum deposition, spin coating, casting, langmuir-blodgett (LB) deposition, ink-jet printing, laser-printing, and/or laser-induced thermal imaging.

When layers constituting the hole transport region, the emission layer, and layers constituting the electron transport region are each independently formed by vacuum deposition, for example, the vacuum deposition may be performed at a deposition temperature of about 100 to about 500° C., at a vacuum degree of about 10⁻⁸ to about 10⁻³ torr, and at a deposition rate of about 0.01 to about 100 Å/sec, by taking into account a compound to be included in a layer to be formed, and a structure of a layer to be formed.

When layers constituting the hole transport region, the emission layer, and layers constituting the electron transport region are each independently formed by spin coating, for example, the spin coating may be performed at a coating speed of about 2,000 rpm to about 5,000 rpm and at a heat treatment temperature of about 80° C. to 200° C., by taking into account a compound to be included in a layer to be formed, and the structure of a layer to be formed.

### General Definition of Substituents

The term “C₁-C₆₀ alkyl group,” as used herein, may refer to a linear or branched aliphatic saturated hydrocarbon monovalent group having 1 to 60 carbon atoms, and non-limiting examples thereof include a methyl group, an ethyl group, a propyl group, an isobutyl group, a sec-butyl group, a tert-butyl group, a pentyl group, an iso-amyl group, and a hexyl group. The term “C₁-C₆₀ alkylene group,” as used herein, may refer to a divalent group having the same structure as the C₁-C₆₀ alkyl group.

The term “C₂-C₆₀ alkenyl group,” as used herein, may refer to a hydrocarbon group having at least one carbon-carbon double bond at one or more positions along the hydrocarbon chain of the C₂-C₆₀ alkyl group (e.g., in the middle and/or at the terminus of the C₂-C₆₀ alkyl group), and non-limiting examples thereof include an ethenyl group, a propenyl group, and a butenyl group. The term “C₂-C₆₀ alkenylene group,” as used herein, may refer to a divalent group having the same structure as the C₂-C₆₀ alkenyl group.

The term “C₂-C₆₀ alkynyl group,” as used herein, may refer to a hydrocarbon group having at least one carbon-carbon triple bond at one or more positions along the hydrocarbon chain of the C₂-C₆₀ alkyl group (e.g., in the middle and/or at the terminus of the C₂-C₆₀ alkyl group), and non-limiting examples thereof include an ethynyl group and a propynyl group. The term “C₂-C₆₀ alkynylene group,” as used herein, may refer to a divalent group having the same structure as the C₂-C₆₀ alkynyl group.

The term “C₁-C₆₀ alkoxy group,” as used herein, may refer to a monovalent group represented by —OA₁₀₁ (wherein A₁₀₁ is the C₁-C₆₀ alkyl group), and non-limiting examples thereof include a methoxy group, an ethoxy group, and an isopropoxy group.

The term “C₃-C₁₀ cycloalkyl group,” as used herein, may refer to a monovalent saturated hydrocarbon monocyclic group having 3 to 10 carbon atoms, and non-limiting examples thereof include a cyclopropyl group, a cyclobutyl group, a cyclopentyl group, a cyclohexyl group, and a cycloheptyl group. The term “C₃-C₁₀ cycloalkylene group,” as used herein, may refer to a divalent group having the same structure as the C₃-C₁₀ cycloalkyl group.

The term “C₁-C₁₀ heterocycloalkyl group,” as used herein, may refer to a monovalent monocyclic group having at least one heteroatom selected from N, O, Si, P, and S as a ring-forming atom, and 1 to 10 carbon atoms, and non-limiting examples thereof include a tetrahydrofuranyl group, a tetrahydrothiophenyl group, and a 1,2,3,4-oxatriazolidinyl group. The term “C₁-C₁₀ heterocycloalkylene group,” used herein, may refer to a divalent group having the same structure as the C₁-C₁₀ heterocycloalkyl group.

The term “C₃-C₁₀ cycloalkenyl group,” as used herein, may refer to a monovalent monocyclic group that has 3 to 10 carbon atoms and at least one carbon-carbon double bond in the ring thereof and does not have aromaticity, and non-limiting examples thereof include a cyclopentenyl group, a cyclohexenyl group, and a cycloheptenyl group. The term “C₃-C₁₀ cycloalkenylene group,” used herein, may refer to a divalent group having the same structure as the C₃-C₁₀ cycloalkenyl group.

The term “C₁-C₁₀ heterocycloalkenyl group,” as used herein, may refer to a monovalent monocyclic group that has at least one heteroatom selected from N, O, Si, P, and S as a ring-forming atom, 1 to 10 carbon atoms, and at least one double bond in its ring. Non-limiting examples of the C₁-C₁₀ heterocycloalkenyl group include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group,” used herein, may refer to a divalent group having the same structure as the C₁-C₁₀ heterocycloalkenyl group.

The term “C₆-C₆₀ aryl group,” as used herein, may refer to a monovalent group having a carbocyclic aromatic system having 6 to 60 carbon atoms, and a C₆-C₆₀ arylene group,” as used herein, may refer to a divalent group having a carbocyclic aromatic system having 6 to 60 carbon atoms. Non-limiting examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group each independently include two or more rings, the respective rings may be fused to each other.

The term “C₁-C₆₀ heteroaryl group,” as used herein, may refer to a monovalent group having a carbocyclic aromatic system that has at least one heteroatom selected from N, O, Si, P, and S as a ring-forming atom, and 1 to 60 carbon atoms. A C₁-C₆₀ heteroarylene group,” as used herein, may refer to a divalent group having an aromatic system that has at least one heteroatom selected from N, O, Si, P, and S as a ring-forming atom, and 1 to 60 carbon atoms. Non-limiting examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each independently include two or more rings, the respective rings may be fused to each other.

The term “C₆-C₆₀ aryloxy group,” used herein, may refer to a monovalent group represented by —OA₁₀₂ (wherein A₁₀₂ is the C₆-C₆₀ aryl group), and the term “C₆-C₆₀ arylthio group” may refer to a monovalent group represented by —SA₁₀₃ (wherein A₁₀₃ is the C₆-C₆₀ aryl group).

The term “monovalent non-aromatic condensed polycyclic group,” as used herein, may refer to a monovalent group that has two or more rings condensed (e.g., fused) with each other, only carbon atoms as ring-forming atoms (e.g., 8 to 60 carbon atoms), and non-aromaticity in the entire molecular structure (e.g., does not have overall aromaticity). A non-limiting example of the monovalent non-aromatic condensed polycyclic group is a fluorenyl group. The term “divalent non-aromatic condensed polycyclic group,” used herein, may refer to a divalent group having the same structure as the monovalent non-aromatic condensed polycyclic group.

The term “monovalent non-aromatic condensed heteropolycyclic group,” as used herein, may refer to a monovalent group that has two or more rings condensed (e.g., fused) to each other, has at least one heteroatom selected from N, O, Si, P, and S, other than carbon atoms (e.g., 1 to 60 carbon atoms), as ring-forming atoms, and has non-aromaticity in the entire molecular structure (e.g., does not have overall aromaticity). A non-limiting example of the monovalent non-aromatic condensed heteropolycyclic group is a carbazolyl group. The term “divalent non-aromatic condensed heteropolycyclic group,” used herein, may refer to a divalent group having the same structure as the monovalent non-aromatic condensed heteropolycyclic group.

The term “C₅-C₆₀ carbocyclic group,” as used herein, may refer to a monocyclic or polycyclic group having 5 to 60 carbon atoms in which ring-forming atoms are carbon atoms only. The C₅-C₆₀ carbocyclic group may be an aromatic carbocyclic group or a non-aromatic carbocyclic group. The C₅-C₆₀ carbocyclic group may be a ring (such as a benzene group), a monovalent group (such as a phenyl group), or a divalent group (such as a phenylene group). In various embodiments, depending on the number of substituents connected to the C₅-C₆₀ carbocyclic group, the C₅-C₆₀ carbocyclic group may be a trivalent group or a quadrivalent group.

The term “C₁-C₆₀ heterocyclic group,” as used herein, may refer to a group having the same structure as the C₅-C₆₀ carbocyclic group, except that as a ring-forming atom, at least one heteroatom selected from N, O, Si, P, and S is used in addition to carbon atoms (e.g., the number of carbon atoms may be in a range of 1 to 60).

The term “C₆-C₆₀ arene group,” as used herein, may refer to an aromatic monocyclic or polycyclic group having 6 to 60 carbon atoms in which ring-forming atoms are carbon atoms only. The C₆-C₆₀ arene group may be a ring (such as a benzene group), a monovalent group (such as a phenyl group), or a divalent group (such as a phenylene group). In various embodiments, depending on the number of substituents connected to the C₆-C₆₀ arene group, the C₆-C₆₀ arene group may be a trivalent group or a quadrivalent group.

The term “C₁-C₆₀ heteroarene group,” as used herein, may refer to a group having the same structure as the C₆-C₆₀ arene group, except that as a ring-forming atom, at least one heteroatom selected from N, O, Si, P, and S is used in addition to carbon atoms (e.g., the number of carbon atoms may be in a range of 1 to 60).

As used herein, at least one substituent of the substituted C₅-C₆₀ carbocyclic group, the substituted C₁-C₆₀ heterocyclic group, the substituted C₃-C₁₀ cycloalkylene group, the substituted C₁-C₁₀ heterocycloalkylene group, the substituted C₃-C₁₀ cycloalkenylene group, the substituted C₁-C₁₀ heterocycloalkenylene group, the substituted C₆-C₆₀ arylene group, the substituted C₁-C₆₀ heteroarylene group, the substituted divalent non-aromatic condensed polycyclic group, the substituted divalent non-aromatic condensed heteropolycyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arythio group, the substituted C₁-C₆₀ heteroaryl group, the substituted monovalent non-aromatic condensed polycyclic group, and the substituted monovalent non-aromatic condensed heteropolycyclic group may be selected from the group consisting of:

deuterium (-D), —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, a hydroxyl group, a cyano group, a nitro group, an amidino group, a hydrazino group, a hydrazono group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), and —P(═O)(Q₁₁)(Q₁₂);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), and —P(═O)(Q₂₁)(Q₂₂); and

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),

wherein Q₁₁ to Q₁₃, Q₂₁ to Q₂₃, and Q₃₁ to Q₃₃ may each independently be selected from hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, and a terphenyl group.

The term “Ph” used herein may refer to a phenyl group, the term “Me” used herein may refer to a methyl group, the term “Et” used herein may refer to an ethyl group, the term “ter-Bu” or “But” used herein may refer to a tert-butyl, the term “OMe” used herein may refer to a methoxy group, and “D” as used herein may refer to deuterium.

The term “biphenyl group” used therein may refer to a monovalent group having two benzene rings linked to each other via a single bond. For example, the “biphenyl group” may be “a phenyl group substituted with a phenyl group.” The “biphenyl group” may also be “a substituted phenyl group” having “a C₆-C₆₀ aryl group” as a substituent.

The term “terphenyl group” used herein may refer to a monovalent group having three benzene rings in which adjacent benzenes are linked to each other via a single bond. For example, the “terphenyl group” may be “a phenyl group substituted with a biphenyl group.” The “terphenyl group” may also be “a substituted phenyl group” having “a C₆-C₆₀ aryl group substituted with a C₆-C₆₀ aryl group” as a substituent.

* and *′ used herein, unless defined otherwise, each independently refer to a binding site to a neighboring atom in a corresponding formula.

Hereinafter, a compound according to embodiments of the present disclosure and an organic light-emitting device according to the embodiments will be described in more detail with reference to Synthesis Examples and Examples. However, these examples are for illustrative purposes only and are not intended to limit the scope of the present invention. The expression “B was used instead of A” used in describing Synthesis Examples may refer to an identical number of molar equivalents of A being used in place of molar equivalents of B.

### EXAMPLES

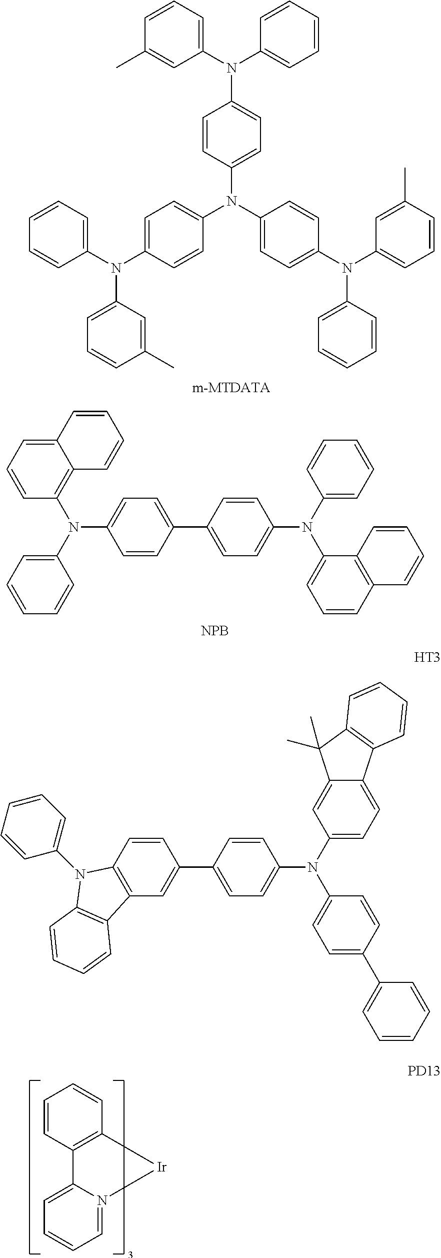

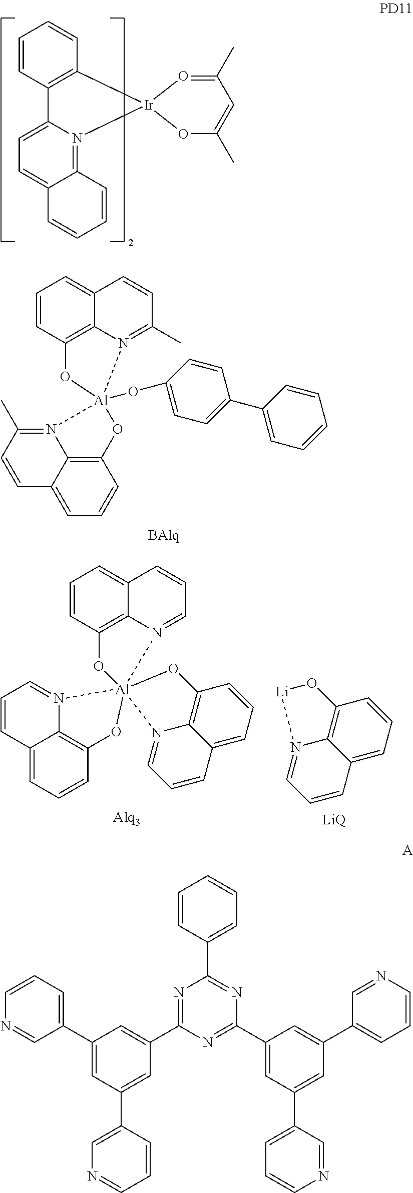

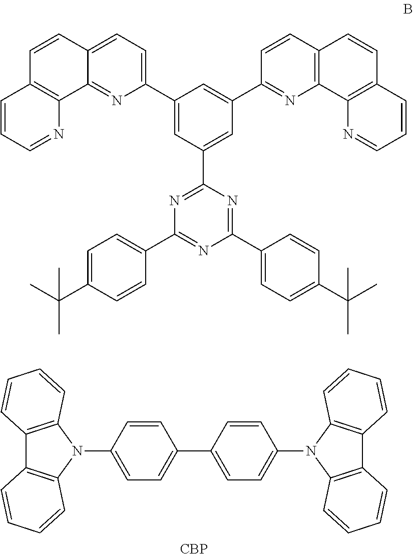

### Example 1-1

An anode was prepared by cutting a glass substrate, on which ITO was deposited to a thickness of 1,200 Å, to a size of 50 mm×50 mm×0.4 mm, ultrasonically cleaning the glass substrate (anode) using isopropyl alcohol and pure water, each for 10 minutes, and then, exposing the glass substrate (anode) to irradiation of UV light for 10 minutes and ozone to clean. Then, the resulting glass substrate (anode) was loaded into a vacuum deposition apparatus.

Compound m-MTDTA was vacuum-deposited on the glass substrate (anode) to form a hole injection layer having a thickness of 700 Å. Then, Compound HT3 was vacuum-deposited on the hole injection layer to form a hole transport layer having a thickness of 100 Å, thereby forming a hole transport region.

Compound 1-1 (as a host) and Compound PD13 (as a dopant) were co-deposited on the hole transport region at a weight ratio of 95:5 to form an emission layer having a thickness of 300 Å.

Compound 2-38 was deposited on the emission layer to form an electron transport layer having a thickness of 200 Å, and then, LiF was deposited on the electron transport layer to form an electron injection layer having a 10 Å, thereby forming an electron transport region. Then, Al was vacuum-deposited on the electron transport region to form a cathode having a thickness of 2,000 Å, thereby completing the manufacture of an organic light-emitting device.

### Examples 1-2 to 1-4 and Comparative Examples 1-1 to 1-3

Organic light-emitting devices were manufactured in the same (or substantially the same) manner as in Example 1, except that compounds listed in Table 1 were respectively used instead of Compounds 1-1 and 2-38 in forming an emission layer and an electron transport layer.

TABLE 1

| | Host for | Electron |
|---|---|---|
| | emission | transport |
| Example | layer | layer |
| Example 1-1 | 1-1 | 2-38 |
| Example 1-2 | 1-12 | 2-44 |
| Example 1-3 | 1-34 | 2-137 |
| Example 1-4 | 1-262 | 2-92 |
| Comparative | 1-12 | A |
| Example 1-1 | | |
| Comparative | CBP | 2-44 |
| Example 1-2 | | |
| Comparative | CBP | B |
| Example 1-3 | | |

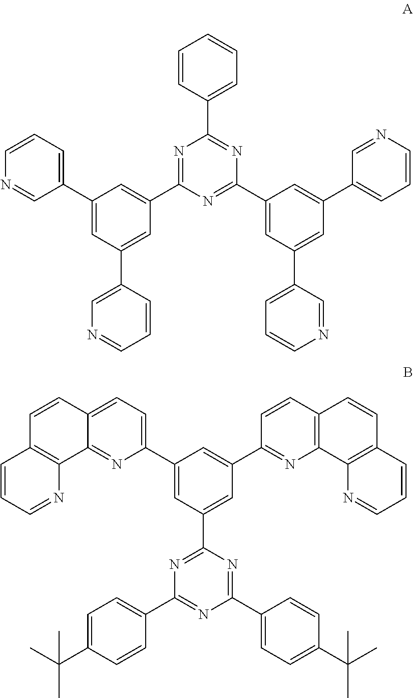

### Example 2-1

An anode was prepared by cutting a glass substrate, on which ITO was deposited to a thickness of 1,200 Å, to a size of 50 mm×50 mm×0.4 mm, ultrasonically cleaning the glass substrate (anode) using isopropyl alcohol and pure water, each for 10 minutes, and then, exposing the glass substrate (anode) to irradiation of UV light for 10 minutes and ozone to clean. Then, the resulting glass substrate (anode) was loaded into a vacuum deposition apparatus.

Compound m-MTDTA was vacuum-deposited on the glass substrate (anode) to form a hole injection layer having a thickness of 700 Å. Then, Compound HT3 was vacuum-deposited on the hole injection layer to form a hole transport layer having a thickness of 100 Å, thereby forming a hole transport region.

Compound 1-35 (as a host) and Compound PD11 (as a dopant) were co-deposited on the hole transport region at a weight ratio of 97:3 to form an emission layer having a thickness of 300 Å.

Compound 2-44 was deposited on the emission layer to form an electron transport layer having a thickness of 200 Å, and then, LIF was deposited on the electron transport layer to form an electron injection layer having a 10 Å, thereby forming an electron transport region. Then, Al was vacuum-deposited on the electron transport region to form a cathode having a thickness of 2,000 Å, thereby completing the manufacture of an organic light-emitting device.

### Examples 2-2 to 2-4 and Comparative Examples 2-1 to 2-3

Organic light-emitting devices were manufactured in the same (or substantially the same) manner as in Example 2-1, except that compounds listed in Table 2 were respectively used instead of Compounds 1-35 and 2-44 in forming an emission layer and an electron transport layer.

TABLE 2

| | Host for | Electron |
|---|---|---|
| | emission | transport |
| Example | layer | layer |
| Example 2-1 | 1-35 | 2-44 |
| Example 2-2 | 1-60 | 2-137 |
| Example 2-3 | 1-68 | 2-38 |
| Example 2-4 | 1-187 | 2-69 |
| Comparative | 1-60 | A |
| Example 2-1 | | |
| Comparative | CBP | 2-137 |
| Example 2-2 | | |
| Comparative | CBP | B |
| Example 2-3 | | |

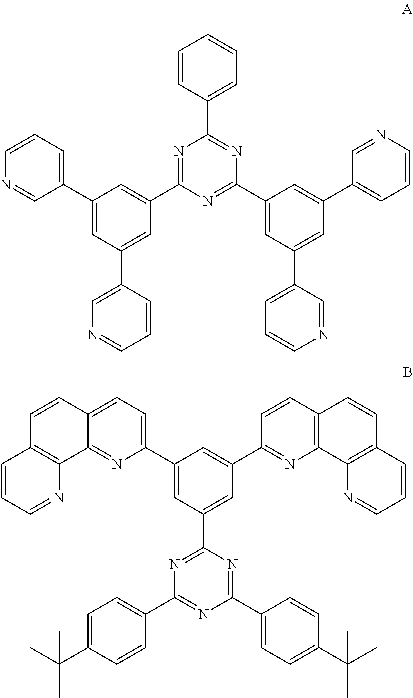

### Example 3-1

An anode was prepared by cutting a glass substrate, on which ITO was deposited to a thickness of 1,200 Å, to a size of 50 mm×50 mm×0.4 mm, ultrasonically cleaning the glass substrate (anode) using isopropyl alcohol and pure water, each for 10 minutes, and then, exposing the glass substrate (anode) to irradiation of UV light for 10 minutes and ozone to clean. Then, the resulting glass substrate (anode) was loaded into a vacuum deposition apparatus.

Compound m-MTDTA was vacuum-deposited on the glass substrate (anode) to form a hole injection layer having a thickness of 700 Å. Then, Compound HT3 was vacuum-deposited on the hole injection layer to form a hole transport layer having a thickness of 100 Å, thereby forming a hole transport region.

Compound 1-1 (as a host) and Compound PD13 (as a dopant) were co-deposited on the hole transport region at a weight ratio of 95:5 to form an emission layer having a thickness of 300 Å.

Compound 1-1 was deposited on the emission layer to form a buffer layer having a thickness of 100 Å, and then, Compound 2-38 was deposited on the buffer layer to form an electron transport layer having a thickness of 200 Å. Then, Li was deposited on the electron transport layer to form an electron injection layer having a thickness of 10 Å, thereby forming an electron transport region. Then, Al was vacuum-deposited on the electron transport region to form a cathode having a thickness of 2,000 Å, thereby completing the manufacture of an organic light-emitting device.

### Examples 3-2 to 3-5 and Comparative Example 3-1

Organic light-emitting devices were manufactured in the same (or substantially the same) manner as in Example 3-1, except that compounds listed in Table 3 were respectively used instead of Compounds 1-1 and 2-38 in forming an emission layer, a buffer layer, and an electron transport layer.

TABLE 3

| | Host for | | Electron |
|---|---|---|---|
| | emission | | transport |
| Example | layer | Buffer layer | layer |
| Example 3-1 | 1-1 | 1-1 | 2-38 |
| Example 3-2 | 1-12 | 1-1 | 2-38 |
| Example 3-3 | 1-34 | 1-1 | 2-87 |
| Example 3-4 | 1-34 | 1-34 | 2-87 |
| Example 3-5 | 1-35 | 1-1 | 2-87 |
| Comparative | CBP | BAlq | Alq₃ |
| Example 3-1 | | | |

### Example 4-1

An anode was prepared by cutting a glass substrate, on which ITO was deposited to a thickness of 1,200 Å, to a size of 50 mm×50 mm×0.4 mm, ultrasonically cleaning the glass substrate (anode) using isopropyl alcohol and pure water, each for 10 minutes, and then, exposing the glass substrate (anode) to irradiation of UV light for 10 minutes and ozone to clean. Then, the resulting glass substrate (anode) was loaded into a vacuum deposition apparatus.

Compound m-MTDTA was vacuum-deposited on the glass substrate (anode) to form a hole injection layer having a thickness of 700 Å. Then, Compound HT3 was vacuum-deposited on the hole injection layer to form a hole transport layer having a thickness of 100 Å, thereby forming a hole transport region.

Compound 1-60 (as a host) and Compound PD11 (as a dopant) were co-deposited on the hole transport region at a weight ratio of 97:3 to form an emission layer having a thickness of 300 Å.

Compound 1-1 was deposited on the emission layer to form a buffer layer having a thickness of 100 Å, and then, Compound 2-137 was deposited on the buffer layer to form an electron transport layer having a thickness of 200 Å. Then, LiF was deposited on the electron transport layer to form an electron injection layer having a thickness of 10 Å, thereby forming an electron transport region. Then, Al was vacuum-deposited on the electron transport region to form a cathode having a thickness of 2,000 Å, thereby completing the manufacture of an organic light-emitting device.

### Example 4-2 and Comparative Example 4-1

Organic light-emitting devices were manufactured in the same (or substantially the same) manner as in Example 4-1, except that compounds listed in Table 4 were respectively used instead of Compounds 1-60, 1-1, and 2-137 in forming an emission layer, a buffer layer, and an electron transport layer.

TABLE 4

| | Host for | | Electron |
|---|---|---|---|
| | emission | | transport |
| Example | layer | Buffer layer | layer |
| Example 4-1 | 1-60 | 1-1 | 2-137 |
| Example 4-2 | 1-68 | 1-1 | 2-137 |
| Comparative | CBP | BAlq | Alq₃ |
| Example 4-1 | | | |

### Example 5-1

An anode was prepared by cutting a glass substrate, on which ITO was deposited to a thickness of 1,200 Å, to a size of 50 mm×50 mm×0.4 mm, ultrasonically cleaning the glass substrate (anode) using isopropyl alcohol and pure water, each for 10 minutes, and then, exposing the glass substrate (anode) to irradiation of UV light for 10 minutes and ozone to clean. Then, the resulting glass substrate (anode) was loaded into a vacuum deposition apparatus.

Compound m-MTDTA was vacuum-deposited on the glass substrate (anode) to form a hole injection layer having a thickness of 700 Å. Then, Compound HT3 was vacuum-deposited on the hole injection layer to form a hole transport layer having a thickness of 100 Å, thereby forming a hole transport region.

Compound 1-1 (as a host) and Compound PD13 (as a dopant) were co-deposited on the hole transport region at a weight ratio of 95:5 to form an emission layer having a thickness of 300 Å.

Compound 1-1 was deposited on the emission layer to form a buffer layer having a thickness of 100 Å, and then, Compound 2-38 and LiQ were co-deposited on the buffer layer at a weight ratio of 50:50 to form an electron transport layer having a thickness of 200 Å. Then, LiF was deposited on the electron transport layer to form an electron injection layer having a thickness of 10 Å, thereby forming an electron transport region. Then, Al was vacuum-deposited on the electron transport region to form a cathode having a thickness of 2,000 Å, thereby completing the manufacture of an organic light-emitting device.

### Example 5-2

Organic light-emitting device was manufactured in the same (or substantially the same) manner as in Example 5-1, except that compounds listed in Table 5 were respectively used instead of Compounds 1-1 and 2-38 in forming an emission layer, a buffer layer, and an electron transport layer.

TABLE 5

| | Host for | | Electron |
|---|---|---|---|
| | emission | | transport |
| Example | layer | Buffer layer | layer |
| Example 5-1 | 1-1 | 1-1 | 2-38:LiQ |
| Example 5-2 | 1-35 | 1-1 | 2-87:LiQ |

### Example 6-1

An anode was prepared by cutting a glass substrate, on which ITO was deposited to a thickness of 1,200 Å, to a size of 50 mm×50 mm×0.4 mm, ultrasonically cleaning the glass substrate (anode) using isopropyl alcohol and pure water, each for 10 minutes, and then, exposing the glass substrate (anode) to irradiation of UV light for 10 minutes and ozone to clean. Then, the resulting glass substrate (anode) was loaded into a vacuum deposition apparatus.

Compound m-MTDTA was vacuum-deposited on the glass substrate (anode) to form a hole injection layer having a thickness of 700 Å. Then, Compound HT3 was vacuum-deposited on the hole injection layer to form a hole transport layer having a thickness of 100 Å, thereby forming a hole transport region.

Compound 1-60 (as a host) and Compound PD11 (as a dopant) were co-deposited on the hole transport region at a weight ratio of 97:3 to form an emission layer having a thickness of 300 Å.

Compound 1-1 was deposited on the emission layer to form a buffer layer having a thickness of 100 Å, and then, Compound 2-87 and LiQ were co-deposited on the buffer layer at a weight ratio of 50:50 to form an electron transport layer having a thickness of 200 Å. Then, LiF was deposited on the electron transport layer to form an electron injection layer having a thickness of 10 Å, thereby forming an electron transport region. Then, Al was vacuum-deposited on the electron transport region to form a cathode having a thickness of 2,000 Å, thereby completing the manufacture of an organic light-emitting device.

### Example 7-1

An anode was prepared by cutting a glass substrate, on which ITO was deposited to a thickness of 1,200 Å, to a size of 50 mm×50 mm×0.4 mm, ultrasonically cleaning the glass substrate (anode) using isopropyl alcohol and pure water, each for 10 minutes, and then, exposing the glass substrate (anode) to irradiation of UV light for 10 minutes and ozone to clean. Then, the resulting glass substrate (anode) was loaded into a vacuum deposition apparatus.

Compound m-MTDTA was vacuum-deposited on the glass substrate (anode) to form a hole injection layer having a thickness of 700 Å. Then, Compound HT3 was vacuum-deposited on the hole injection layer to form a hole transport layer having a thickness of 100 Å, thereby forming a hole transport region.

Compounds 1-1 and 1-34 (as a host), and Compound PD13 (as a dopant) were co-deposited on the hole transport region at a weight ratio of 47.5:47.5:5 to form an emission layer having a thickness of 300 Å.

Compound 2-19 was deposited on the emission layer to form a buffer layer having a thickness of 100 Å, and then, Compound 2-87 and LiQ were co-deposited on the buffer layer at a weight ratio of 50:50 to form an electron transport layer having a thickness of 200 Å. Then, LiF was deposited on the electron transport layer to form an electron injection layer having a thickness of 10 Å, thereby forming an electron transport region. Then, Al was vacuum-deposited on the electron transport region to form a cathode having a thickness of 2,000 Å, thereby completing the manufacture of an organic light-emitting device.

### Example 7-2

Organic light-emitting device was manufactured in the same (or substantially the same) manner as in Example 7-1, except that compounds listed in Table 6 were respectively used instead of Compounds 1-1, 1-34, 2-19, and 2-87 in forming an emission layer, a buffer layer, and an electron transport layer.

TABLE 6

| | Host for | | Electron |
|---|---|---|---|
| | emission | | transport |
| Example | layer | Buffer layer | layer |
| Example 7-1 | 1-1, 1-34 | 2-19 | 2-87:LiQ |
| Example 7-2 | 1-1, 1-34 | 2-45 | 2-137:LiQ |

### Evaluation Example

The driving voltage, current density, efficiency, and lifespan of the organic light-emitting devices of Examples 1-1 to 1-4, 2-1 to 2-4, 3-1 to 3-5, 4-1, 4-2, 5-1, 5-2, 6-1, 7-1, and 7-2, and Comparative Examples 1-1 to 1-3, 2-1 to 2-3, 3-1, and 4-1 were evaluated by using a Keithley SMU 236 meter a PR650 luminance measuring meter. The lifespan results were obtained by measuring the time until the luminance was reduced to 97% of the initial luminance. Results thereof are shown in Table 7.

TABLE 7

| | | | | Driving | | |
|---|---|---|---|---|---|---|
| | Emission | Buffer | Electron | voltage | Efficiency | Lifespan |
| | host | layer | transport layer | (V) | (cd/A) | (hours) |
| Example 1-1 | 1-1 | — | 2-38 | 5.6 | 39.5 | 110 |
| Example 1-2 | 1-12 | — | 2-44 | 5.6 | 41 | 95 |
| Example 1-3 | 1-34 | — | 2-137 | 5.5 | 40.3 | 103 |
| Example 1-4 | 1-162 | — | 2-92 | 5.5 | 40 | 100 |
| Example 2-1 | 1-35 | — | 2-44 | 5.8 | 42 | 192 |
| Example 2-2 | 1-60 | — | 2-137 | 5.7 | 25 | 185 |
| Example 2-3 | 1-68 | — | 2-38 | 5.8 | 26 | 200 |
| Example 2-4 | 1-187 | — | 2-69 | 5.9 | 25 | 205 |
| Example 3-1 | 1-1 | 1-1 | 2-38 | 5.7 | 41.5 | 105 |
| Example 3-2 | 1-12 | 1-1 | 2-38 | 5.7 | 41 | 99 |
| Example 3-3 | 1-34 | 1-1 | 2-87 | 5.6 | 43 | 122 |
| Example 3-4 | 1-34 | 1-34 | 2-87 | 5.4 | 42 | 109 |
| Example 3-5 | 1-35 | 1-1 | 2-87 | 5.8 | 40.2 | 100 |
| Example 4-1 | 1-60 | 1-1 | 2-137 | 5.9 | 25 | 210 |
| Example 4-2 | 1-68 | 1-1 | 2-137 | 5.8 | 24.5 | 230 |
| Example 5-1 | 1-1 | 1-1 | 2-38: LiQ | 5.5 | 41 | 200 |
| Example 5-2 | 1-35 | 1-1 | 2-87: LiQ | 5.3 | 41 | 165 |
| Example 6-1 | 1-60 | 1-1 | 2-87: LiQ | 5.7 | 25.5 | 220 |
| Example 7-1 | 1-12, 1-34 | 2-19 | 2-87: LiQ | 5.2 | 45 | 220 |
| Example 7-2 | 1-12, 1-34 | 2-45 | 2-137: LiQ | 5.2 | 44 | 180 |
| Comparative | 1-12 | — | A | 5.8 | 38.5 | 77 |
| Example 1-1 | | | | | | |
| Comparative | CBP | — | 2-44 | 6.0 | 35.3 | 72 |
| Example 1-2 | | | | | | |
| Comparative | CBP | — | B | 5.9 | 35 | 75 |
| Example 1-3 | | | | | | |
| Comparative | 1-60 | — | A | 6.0 | 23.5 | 130 |
| Example 2-1 | | | | | | |
| Comparative | CBP | — | 2-137 | 6.3 | 20.5 | 131 |
| Example 2-2 | | | | | | |
| Comparative | CBP | — | B | 6.2 | 20 | 140 |
| Example 2-3 | | | | | | |
| Comparative | CBP | BAlq | Alq₃ | 6.1 | 36.1 | 60 |
| Example 3-1 | | | | | | |
| Comparative | CBP | BAlq | Alq₃ | 6.2 | 21.6 | 125 |
| Example 4-1 | | | | | | |

Referring to Table 7, it was confirmed that the organic light-emitting devices of Examples 1-1 to 1-4, 2-1 to 2-4, 3-1 to 3-5, 4-1, 4-2, 5-1, 5-2, 6-1, 7-1, and 7-2 each had high efficiency and a long lifespan, compared to those of the organic light-emitting devices of Comparative Examples 1-1 to 1-3, 2-1 to 2-3, 3-1, and 4-1, respectively.

An organic light-emitting device according to embodiments of the present disclosure may have low driving voltage, high efficiency, and a long lifespan.

As used herein, the terms “use,” “using,” and “used” may be considered synonymous with the terms “utilize,” “utilizing,” and “utilized,” respectively.

In addition, as used herein, the terms “substantially,” “about,” and similar terms are used as terms of approximation and not as terms of degree, and are intended to account for the inherent deviations in measured or calculated values that would be recognized by those of ordinary skill in the art.

It will be understood that when an element such as a layer, film, region, or substrate is referred to as being “on” another element, it can be directly on the other element or intervening elements may also be present. In contrast, when an element is referred to as being “directly on” or “directly contacting” another element, there are no intervening elements present.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope of the present disclosure as defined by the following claims and equivalents thereof.

What is claimed is:

1. The organic light-emitting device comprising:
a first electrode;
a second electrode; and
an organic layer between the first electrode and the second electrode, the organic layer comprising an emission layer,
wherein the organic layer comprises a first compound represented by Formula 1 and a second compound represented by Formula 2, provided that a case where the first compound is 4,4′-bis(N-carbazolyl)-1,1′-biphenyl(CBP) is excluded: 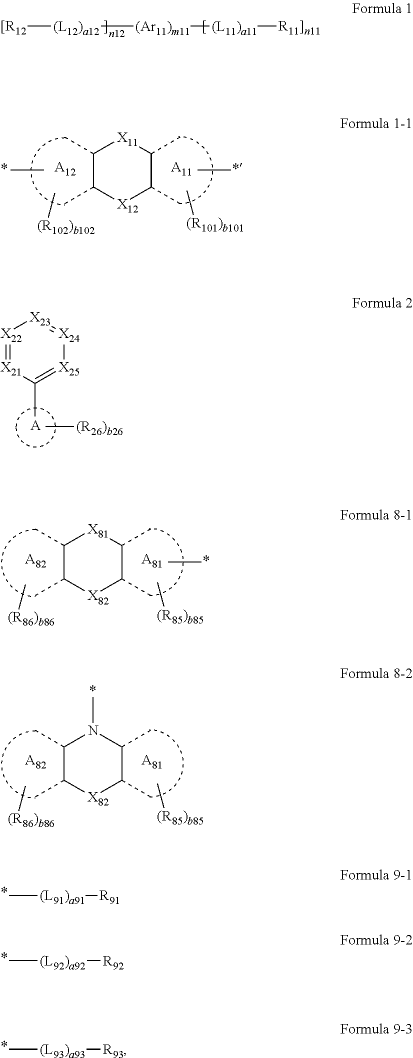
wherein, in Formulae 1, 1-1, 2, 8-1, 8-2, and 9-1 to 9-3,
Ar₁₁ is a group represented by Formula 1-1,
m11 is selected from 1 and 2,
A₁₁, A₁₂, A₈₁, and A₈₂ are each independently selected from a C₅-C₂₀ carbocyclic group and a C₁-C₂₀ heterocyclic group,
X₁₁ is selected from N[(L₁₃)ₐ₁₃-R₁₃], C[(L₁₃)ₐ₁₃-R₁₃][(L₁₄)ₐ₁₄-R₁₄], O, and S,
X₁₂ is selected from a single bond, N[(L₁₅)ₐ₁₅-R₁₅], C[(L₁₅)ₐ₁₅-R₁₅][(L₁₆)ₐ₁₆-R₁₆], O, and S,
X₈₁ is selected from N[(L₈₁)ₐ₈₁-R₈₁], C[(L₈₁)ₐ₈₁-R₈₁][(L₈₂)ₐ₈₂-R₈₂], O, and S,
X₈₂ is selected from a single bond, N[(L₈₃)ₐ₈₃-R₈₃], C[(L₈₃)ₐ₈₃-R₈₃][(L₈₄)ₐ₈₄-R₈₄], O, and S,
L₁₁ to L₁₆ and L₈₁ to L₈₄ are each independently selected from *—O—*′, *—S—*′, *—C(═O)—*′, *—P(═O)(Q₁)-*′, *—Si(Q₁)(Q₂)-*′, a substituted or unsubstituted C₆-C₆₀ arylene group, and a substituted or unsubstituted C₁-C₆₀ heteroarylene group,
a11 to a16 and a81 to a84 are each independently selected from 0, 1, 2, and 3,
R₁₁ to R₁₆ are each independently selected from a group represented by Formula 8-1, a group represented by Formula 8-2, hydrogen, deuterium, —F, —Cl, —Br, —I, a cyano group, a nitro group, a substituted or unsubstituted C₁-C₆₀ alkyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, —Si(Q₁)(Q₂)(Q₃), —B(Q₁)(Q₂), —C(═O)(Q₁), —S(═O)₂(Q₁), and —P(═O)(Q₁)(Q₂), wherein R₁₃ and R₁₄ are optionally connected to each other to form a ring, and R₁₅ and R₁₆ are optionally connected to each other to form a ring,
n11 and n12 are each independently selected from 0, 1, 2, 3, and 4,
R₈₁ to R₈₄ are each independently selected from hydrogen, deuterium, —F, —Cl, —Br, —I, a cyano group, a nitro group, a substituted or unsubstituted C₁-C₆₀ alkyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, —Si(Q₁)(Q₂)(Q₃), —B(Q₁)(Q₂), —C(═O)(Q₁), —S(═O)₂(Q₁), and —P(═O)(Q₁)(Q₂), wherein R₈₁ and R₈₂ are optionally connected to each other to form a ring, and R₈₃ and R₈₄ are optionally connected to each other to form a ring,
R₁₀₁, R₁₀₂, R₈₅, and R₈₆ are each independently selected from hydrogen, deuterium, —F, —Cl, —Br, —I, a cyano group, a nitro group, a substituted or unsubstituted C₁-C₆₀ alkyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, —Si(Q₁)(Q₂)(Q₃), —B(Q₁)(Q₂), —C(═O)(Q₁), —S(═O)₂(Q₁), and —P(═O)(Q₁)(Q₂),
b101, b102, b85, and b86 are each independently selected from 1, 2, 3, 4, 5, and 6,
A₂₁ is selected from a C₆-C₂₀ arene group and a C₁-C₂₀ heteroarene group,
X₂₁ is selected from N and C(R₂₁), X₂₂ is selected from N and C(R₂₂), X₂₃ is selected from N and C(R₂₃), X₂₄ is selected from N and C(R₂₄), X₂₅ is selected from N and C(R₂₅), at least one selected from X₂₁ to X₂₅ is N,
R₂₁ to R₂₆ are each independently selected from a group represented by any of Formulae 9-1 to 9-3, hydrogen, deuterium, —F, —Cl, —Br, —I, a hydroxyl group, a cyano group, a nitro group, an amidino group, a hydrazino group, a hydrazono group, a substituted or unsubstituted C₁-C₆₀ alkyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₁)(Q₂), —B(Q₁)(Q₂), —C(═O)(Q₁), —S(═O)₂(Q₁), and —P(═O)(Q₁)(Q₂), and at least one selected from R₂₁ to R₂₆ is selected from a group represented by Formula 9-1 and a group represented by Formula 9-2,
b26 is selected from 1, 2, 3, 4, 5, and 6,
L₉₁ is selected from a C₆-C₆₀ arylene group and a C₁-C₆₀ heteroarylene group, each substituted with at least one selected from a C₁-C₆₀ alkyl group and a C₃-C₁₀ cycloalkyl group,
L₉₂ and L₉₃ are each independently selected from a substituted or unsubstituted C₆-C₆₀ arylene group and a substituted or unsubstituted C₁-C₆₀ heteroarylene group,
a91 is selected from 1 and 2,
a92 and a93 are each independently selected from 0, 1, and 2,
R₉₁ and R₉₃ are each independently selected from a substituted or unsubstituted C₆-C₆₀ aryl group and a substituted or unsubstituted C₁-C₆₀ heteroaryl group,
R₉₂ is selected from a C₆-C₆₀ aryl group and a C₁-C₆₀ heteroaryl group, each substituted with at least one selected from a C₁-C₆₀ alkyl group and a C₃-C₁₀ cycloalkyl group,
wherein Q₁ to Q₃ are each independently be selected from hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, and a terphenyl group, and
* and *′ each independently indicate a binding site to a neighboring atom.

2. The organic light-emitting device of claim 1, wherein
A₁₁, A₁₂, A₈₁, and A₈₂ are each independently selected from a benzene group, a naphthalene group, a phenanthrene group, an anthracene group, a triphenylene group, a pyrene group, a chrysene group, a furan group, a thiophene group, a pyrrole group, a pyridine group, a pyrazine group, a pyrimidine group, a pyridazine group, a triazine group, a quinoline group, an isoquinoline group, a 2,6-naphthyridine group, a 1,8-naphthyridine group, a 1,5-naphthyridine group, a 1,6-naphthyridine group, a 1,7-naphthyridine group, a 2,7-naphthyridine group, a quinoxaline group, a quinazoline group, a phenanthridine group, a phenanthroline group, a benzofuran group, a benzothiophene group, an indene group, an indole group, a furopyridine group, a thienopyridine group, a cyclopentapyridine group, a pyrrolopyridine group, a dibenzofuran group, a dibenzothiophene group, a fluorene group, a carbazole group, a benzofuropyrrole group, a benzothienopyrrole group, an indenopyrrole group, an indolopyrrole group, a benzofurothiophene group, a benzothienothiophene group, an indenothiophene group, an indolothiophene group, a benzofurofuran group, a benzothienofuran group, an indenofuran group, an indolofuran group, a benzofuropyridine group, a benzothienopyridine group, an indenopyridine group, an indolopyridine group, a benzofuropyrimidine group, a benzothienopyrimidine group, an indenopyrimidine group, an indolopyrimidine group, a benzofuroindole group, a benzothienoindole group, an indenoindole group, an indoloindole group, a benzofurobenzofuran group, a benzothienobenzofuran group, an indenobenzofuran group, an indolobenzofuran group, a benzofurobenzothiophene group, a benzothienobenzothiophene group, an indenobenzothiophene group, an indolobenzothiophene group, a benzofuronquinoline group, a benzothienoquinoline group, an indenoquinoline group, an indoloquinoline group, a benzonaphthofuran group, a benzonaphthothiophene group, a benzofluorene group, a benzocarbazole group, a dinaphthofuran group, a dinaphthothiophene group, a dibenzofluorene group, a dibenzocarbazole group, a benzoxazole group, a benzothiazole group, a benzimidazole group, a naphthofuran group, a naphthothiophene group, a cyclopentanaphthalene group, a spiro-bifluorene group, and a spiro-fluorene-indene group.

3. The organic light-emitting device of claim 1, wherein
L₁₁ to L₁₆ and L₈₁ to L₈₄ are each independently selected from the group consisting of:
*—Si(CH₃)₂*′, *—Si(CH₃)(Ph)-*′, *—Si(Ph)₂-*′, a phenylene group, a naphthylene group, a phenanthrenylene group, an anthracenylene group, a triphenylenylene group, a pyrenylene group, a chrysenylene group, a pyridinylene group, a pyrazinylene group, a pyrimidinylene group, a quinolinylene group, an isoquinolinylene group, a benzoquinolinylene group, a phthalazinylene group, a naphthyridinylene group, a quinoxalinylene group, a quinazolinylene group, a phenanthridinylene group, an acridinylene group, a phenanthrolinylene group, and a triazinylene group; a phenylene group, a naphthylene group, a phenanthrenylene group, an anthracenylene group, a triphenylenylene group, a pyrenylene group, a chrysenylene group, a pyridinylene group, a pyrazinylene group, a pyrimidinylene group, a quinolinylene group, an isoquinolinylene group, a benzoquinolinylene group, a phthalazinylene group, a naphthyridinylene group, a quinoxalinylene group, a quinazolinylene group, a phenanthridinylene group, an acridinylene group, a phenanthrolinylene group, and a triazinylene group, each substituted with at least one selected from deuterium, —F, —Cl, —Br, —I, a cyano group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂); and
a phenylene group, a naphthylene group, a phenanthrenylene group, an anthracenylene group, a triphenylenylene group, a pyrenylene group, a chrysenylene group, a pyridinylene group, a pyrazinylene group, a pyrimidinylene group, a quinolinylene group, an isoquinolinylene group, a benzoquinolinylene group, a phthalazinylene group, a naphthyridinylene group, a quinoxalinylene group, a quinazolinylene group, a phenanthridinylene group, an acridinylene group, a phenanthrolinylene group, and a triazinylene group, each substituted with at least one selected from a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, and a dibenzocarbazolyl group, each substituted with at least one selected from deuterium, —F, —Cl, —Br, —I, a cyano group, a C₁-C₂₀ alkyl group, a C₁-C₂₀ alkoxy group, a phenyl group, a biphenyl group, and a terphenyl group,
wherein Q₃₁ to Q₃₃ are each independently selected from hydrogen, a methyl group, an ethyl group, an n-propyl group, an iso-propyl group, a tert-butyl group, a phenyl group, a biphenyl group, and a terphenyl group.

4. The organic light-emitting device of claim 1, wherein
R₁₁ to R₁₆ are each independently selected from the group consisting of:
a group represented by Formula 8-1, a group represented by Formula 8-2, a C₁-C₂₀ alkyl group, a C₆-C₃₀ aryl group, and a C₁-C₃₀ heteroaryl group;
a C₆-C₃₀ aryl group and a C₁-C₃₀ heteroaryl group, each substituted with at least one selected from deuterium, —F, —Cl, —Br, —I, a C₁-C₂₀ alkyl group, a C₁-C₂₀ alkoxy group, a C₃-C₁₀ cycloalkyl group, a C₆-C₃₀ aryl group, a C₁-C₃₀ heteroaryl group, —N(Q₃₁)(Q₃₂), and —Si(Q₃₁)(Q₃₂)(Q₃₃); and
a C₆-C₃₀ aryl group and a C₁-C₃₀ heteroaryl group, each substituted with at least one selected from a C₆-C₃₀ aryl group and a C₁-C₃₀ heteroaryl group, each substituted with at least one selected from deuterium, —F, —Cl, —Br, —I, a C₁-C₂₀ alkyl group, a C₁-C₂₀ alkoxy group, a C₃-C₁₀ cycloalkyl group, a C₆-C₃₀ aryl group, a C₁-C₃₀ heteroaryl group, —N(Q₂₁)(Q₂₂), and —Si(Q₂₁)(Q₂₂)(Q₂₃),
wherein Q₂₁ to Q₂₃ and Q₃₁ to Q₃₃ are each independently selected from a C₁-C₂₀ alkyl group and a C₆-C₃₀ aryl group.

5. The organic light-emitting device of claim 1, wherein
the sum of n11 and n12 is selected from 0 and 1.

6. The organic light-emitting device of claim 1, wherein
R₈₁ to R₈₄ are each independently selected from the group consisting of:
a C₁-C₂₀ alkyl group, a C₆-C₃₀ aryl group, and a C₁-C₃₀ heteroaryl group;
a C₆-C₃₀ aryl group and a C₁-C₃₀ heteroaryl group, each substituted with at least one selected from deuterium, —F, —Cl, —Br, —I, a C₁-C₂₀ alkyl group, a C₁-C₂₀ alkoxy group, a C₃-C₁₀ cycloalkyl group, a C₆-C₃₀ aryl group, a C₁-C₃₀ heteroaryl group, —N(Q₃₁)(Q₃₂), and —Si(Q₃₁)(Q₃₂)(Q₃₃); and
a C₆-C₃₀ aryl group and a C₁-C₃₀ heteroaryl group, each substituted with at least one selected from a C₆-C₃₀ aryl group and a C₁-C₃₀ heteroaryl group, each substituted with at least one selected from deuterium, —F, —Cl, —Br, —I, a C₁-C₂₀ alkyl group, a C₁-C₂₀ alkoxy group, a C₃-C₁₀ cycloalkyl group, a C₆-C₃₀ aryl group, a C₁-C₃₀ heteroaryl group, —N(Q₂₁)(Q₂₂), and —Si(Q₂₁)(Q₂₂)(Q₂₃),
wherein Q₂₁ to Q₂₃ and Q₃₁ to Q₃₃ are each independently selected from a C₁-C₂₀ alkyl group and a C₆-C₃₀ aryl group.

7. The organic light-emitting device of claim 1, wherein
A₂₁ is selected from a benzene group, a naphthalene group, a phenanthrene group, an anthracene group, a pyridine group, a pyrazine group, a pyrimidine group, a triazine group, a quinoline group, an isoquinoline group, a quinoxaline group, and a quinazoline group.

8. The organic light-emitting device of claim 1, wherein
R₂₁ to R₂₆ are each independently selected from the group consisting of:
a group represented by any of Formulae 9-1 to 9-3, hydrogen, a C₁-C₂₀ alkyl group, and a C₃-C₁₀ cycloalkyl group;
a C₆-C₃₀ aryl group, a C₁-C₃₀ heteroaryl group, a monovalent non-aromatic condensed polycyclic group, and a monovalent non-aromatic condensed heteropolycyclic group;
a C₆-C₃₀ aryl group, a C₁-C₃₀ heteroaryl group, a monovalent non-aromatic condensed polycyclic group, and a monovalent non-aromatic condensed heteropolycyclic group, each substituted with at least one selected from deuterium, —F, —Cl, —Br, —I, a C₁-C₂₀ alkyl group, a C₃-C₁₀ cycloalkyl group, a C₆-C₃₀ aryl group, a C₁-C₃₀ heteroaryl group, a monovalent non-aromatic condensed polycyclic group, a monovalent non-aromatic condensed heteropolycyclic group, —N(Q₃₁)(Q₃₂), and —Si(Q₃₁)(Q₃₂)(Q₃₃); and
a C₆-C₃₀ aryl group, a C₁-C₃₀ heteroaryl group, a monovalent non-aromatic condensed polycyclic group, and a monovalent non-aromatic condensed heteropolycyclic group, each substituted with at least one selected from a C₆-C₃₀ aryl group, a C₁-C₃₀ heteroaryl group, a monovalent non-aromatic condensed polycyclic group, and a monovalent non-aromatic condensed heteropolycyclic group, each substituted with at least one selected from deuterium, —F, —Cl, —Br, —I, a C₁-C₂₀ alkyl group, a C₃-C₁₀ cycloalkyl group, a C₆-C₃₀ aryl group, a C₁-C₃₀ heteroaryl group, a monovalent non-aromatic condensed polycyclic group, a monovalent non-aromatic condensed heteropolycyclic group, —N(Q₂₁)(Q₂₂), and —Si(Q₂₁)(Q₂₂)(Q₂₃),
wherein Q₂₁ to Q₂₃ and Q₃₁ to Q₃₃ are each independently selected from a C₁-C₂₀ alkyl group and a C₆-C₃₀ aryl group.

9. The organic light-emitting device of claim 1, wherein
L₉₁ is selected from a phenylene group, a naphthylene group, a phenanthrenylene group, an anthracenylene group, a triphenylenylene group, a pyrenylene group, a chrysenylene group, a pyridinylene group, a pyrazinylene group, a pyrimidinylene group, a quinolinylene group, an isoquinolinylene group, a benzoquinolinylene group, a phthalazinylene group, a naphthyridinylene group, a quinoxalinylene group, a quinazolinylene group, a phenanthridinylene group, an acridinylene group, a phenanthrolinylene group, and a triazinylene group, each substituted with at least one selected from a C₁-C₂₀ alkyl group, a cyclopentyl group, a cyclohexyl group, and a cycloheptyl group.

10. The organic light-emitting device of claim 1, wherein
L₉₂ and L₉₃ are each independently selected from the group consisting of:
a phenylene group, a naphthylene group, a phenanthrenylene group, an anthracenylene group, a triphenylenylene group, a pyrenylene group, a chrysenylene group, a pyridinylene group, a pyrazinylene group, a pyrimidinylene group, a quinolinylene group, an isoquinolinylene group, a benzoquinolinylene group, a phthalazinylene group, a naphthyridinylene group, a quinoxalinylene group, a quinazolinylene group, a phenanthridinylene group, an acridinylene group, a phenanthrolinylene group, and a triazinylene group;
a phenylene group, a naphthylene group, a phenanthrenylene group, an anthracenylene group, a triphenylenylene group, a pyrenylene group, a chrysenylene group, a pyridinylene group, a pyrazinylene group, a pyrimidinylene group, a quinolinylene group, an isoquinolinylene group, a benzoquinolinylene group, a phthalazinylene group, a naphthyridinylene group, a quinoxalinylene group, a quinazolinylene group, a phenanthridinylene group, an acridinylene group, a phenanthrolinylene group, and a triazinylene group, each substituted with at least one selected from deuterium, —F, —Cl, —Br, —I, a cyano group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, —Si(Q₃₁)(Q₃₂)(Q₃₂)₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂); and
a phenylene group, a naphthylene group, a phenanthrenylene group, an anthracenylene group, a triphenylenylene group, a pyrenylene group, a chrysenylene group, a pyridinylene group, a pyrazinylene group, a pyrimidinylene group, a quinolinylene group, an isoquinolinylene group, a benzoquinolinylene group, a phthalazinylene group, a naphthyridinylene group, a quinoxalinylene group, a quinazolinylene group, a phenanthridinylene group, an acridinylene group, a phenanthrolinylene group, and a triazinylene group, each substituted with at least one selected from a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, and a dibenzocarbazolyl group, each substituted with at least one selected from deuterium, —F, —Cl, —Br, —I, a cyano group, a C₁-C₂₀ alkyl group, a C₁-C₂₀ alkoxy group,
wherein Q₃₁ to Q₃₃ are each independently selected from hydrogen, a methyl group, an ethyl group, an n-propyl group, an iso-propyl group, a tert-butyl group, a phenyl group, a biphenyl group, and a terphenyl group.

11. The organic light-emitting device of claim 1, wherein
R₉₁ and R₉₃ are each independently selected from the group consisting of:
a C₆-C₃₀ aryl group and a C₁-C₃₀ heteroaryl group;
a C₆-C₃₀ aryl group and a C₁-C₃₀ heteroaryl group, each substituted with at least one selected from deuterium, —F, —Cl, —Br, —I, a C₁-C₂₀ alkyl group, a C₁-C₂₀ alkoxy group, a C₃-C₁₀ cycloalkyl group, a C₆-C₃₀ aryl group, a C₁-C₃₀ heteroaryl group, —N(Q₃₁)(Q₃₂), and —Si(Q₃₁)(Q₃₂)(Q₃₃); and
a C₆-C₃₀ aryl group and a C₁-C₃₀ heteroaryl group, each substituted with at least one selected from a C₆-C₃₀ aryl group and a C₁-C₃₀ heteroaryl group, each substituted with at least one selected from deuterium, —F, —Cl, —Br, —I, a C₁-C₂₀ alkyl group, a C₁-C₂₀ alkoxy group, a C₃-C₁₀ cycloalkyl group, a C₆-C₃₀ aryl group, a C₁-C₃₀ heteroaryl group, —N(Q₂₁)(Q₂₂), and —Si(Q₂₁)(Q₂₂)(Q₂₃),
wherein Q₂₁ to Q₂₃ and Q₃₁ to Q₃₃ are each independently selected from a C₁-C₂₀ alkyl group and a C₆-C₃₀ aryl group.

12. The organic light-emitting device of claim 1, wherein
R₉₂ is selected from a phenyl group, a biphenyl group, a terphenyl group, a naphthyl group, an anthracenyl group, a triphenylenyl group, a phenanthrenyl group, a pyrenyl group, a tetraphenyl group, a chrysenyl group, a pyrrolyl group, a furanyl group, a thiophenyl group, a pyridinyl group, a pyrazinyl group, a pyrimidinyl group, a triazinyl group, a quinolinyl group, an isoquinolinyl group, a benzoquinolinyl group, a phthalazinyl group, a naphthyridinyl group, a quinoxalinyl group, a quinazolinyl group, a phenanthridinyl group, an acridinyl group, a phenanthrolinyl group, a phenazinyl group, a benzophenanthrolinyl group, a thiazolyl group, an oxazolyl group, an imidazolyl group, a triazolyl group, an indolyl group, a benzimidazolyl group, a benzofuranyl group, a benzothiophenyl group, and a benzoxazolyl group, each substituted with at least one selected from a C₁-C₂₀ alkyl group, a cyclopentyl group, a cyclohexyl group, and a cycloheptyl group.

13. The organic light-emitting device of claim 1, wherein
the second compound represented by Formula 2 is represented by Formula 2-1: 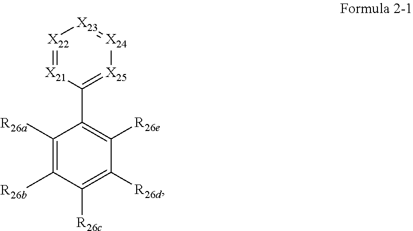
wherein, in Formula 2-1,
X₂₁ is selected from N and C(R₂₁), X₂₂ is selected from N and C(R₂₂), X₂₃ is selected from N and C(R₂₃), X₂₄ is selected from N and C(R₂₄), and X₂₅ is selected from N and C(R₂₅), wherein at least one selected from X₂₁ to X₂₅ is N, and
R₂₁ to R₂₅ and R₂₆ₐ to R₂₆ₑ are each independently selected from a group represented by any of Formulae 9-1 to 9-3, hydrogen, deuterium, —F, —Cl, —Br, —I, a hydroxyl group, a cyano group, a nitro group, an amidino group, a hydrazino group, a hydrazono group, a substituted or unsubstituted C₁-C₆₀ alkyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₁)(Q₂), —B(Q₁)(Q₂), —C(═O)(Q₁), —S(═O)₂(Q₁), and —P(═O)(Q₁)(Q₂), and at least one selected from R₂₁ to R₂₅ and R₂₆ₐ to R₂₆ₑ is selected from a group represented by Formula 9-1 and a group represented by Formula 9-2,
wherein Q₁ to Q₃ are each independently selected from hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, and a terphenyl group.

14. The organic light-emitting device of claim 1, wherein
the emission layer comprises a first host and a second host,
the first host comprises the first compound, and
the first host and the second host are different from each other.

15. The organic light-emitting device of claim 1, wherein
the emission layer comprises the first compound and a dopant, and
the dopant comprises an organometallic complex represented by Formula 401: 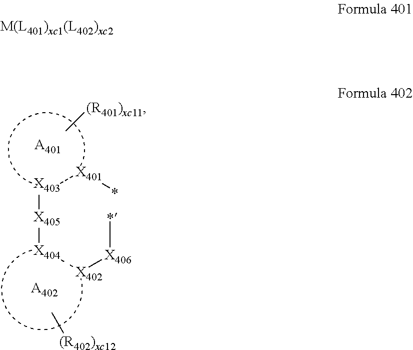
wherein, in Formulae 401 and 402,
M is selected from iridium (Ir), platinum (Pt), palladium (Pd), osmium (Os), titanium (Ti), zirconium (Zr), hafnium (Hf), europium (Eu), terbium (Tb), rhodium (Rh), and thulium (Tm),
L₄₀₁ is selected from ligands represented by Formula 402, and xc1 is 1, 2, or 3, wherein when xc1 is two or more, two or more L₄₀₁(S) are identical to or different from each other,
L₄₀₂ is an organic ligand, and xc2 is an integer selected from 0 to 4, wherein when xc2 is two or more, two or more L₄₀₂(s) are identical to or different from each other,
X₄₀₁ to X₄₀₄ are each independently nitrogen or carbon,
X₄₀₁ and X₄₀₃ are connected to each other via a single bond or a double bond, and X₄₀₂ and X₄₀₄ are connected to each other via a single bond or a double bond,
A₄₀₁ and A₄₀₂ are each independently a C₅-C₆₀ carbocyclic group or a C₁-C₆₀ heterocyclic group,
X₄₀₅ is selected from a single bond, *—O—*′, *—S—*′, *—C(═O)—*′, *—N(Q₄₁₁)-*′, *—C(Q₄₁₁)(Q₄₁₂)-*′, *—C(Q₄₁₁)=C(Q₄₁₂)-*′, *—C(Q₄₁₁)=*′, and *═C(Q₄₁₁)=*′, wherein Q₄₁₁ and Q₄₁₂ are each independently selected from hydrogen, deuterium, a C₁-C₂₀ alkyl group, a C₁-C₂₀ alkoxy group, a phenyl group, a biphenyl group, a terphenyl group, and a naphthyl group,
X₄₀₆ is selected from a single bond, O, and S,
R₄₀₁ and R₄₀₂ are each independently selected from hydrogen, deuterium, —F, —Cl, —Br, —I, —CD₃, —CF₃, a hydroxyl group, a cyano group, a nitro group, an amidino group, a hydrazino group, a hydrazono group, a substituted or unsubstituted C₁-C₂₀ alkyl group, a substituted or unsubstituted C₁-C₂₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), and —P(═O)(Q₄₀₁)(Q₄₀₂), wherein Q₄₀₁ to Q₄₀₃ are each independently selected from a C₁-C₁₀ alkyl group, a C₁-C₁₀ alkoxy group, a C₆-C₂₀ aryl group, and a C₁-C₂₀ heteroaryl group,
xc11 and xc12 are each independently an integer selected from 0 to 10, and
* and *′ in Formula 402 each independently indicate a binding site to M in Formula 401.

16. The organic light-emitting device of claim 1, wherein
the organic layer comprises an electron transport region between the emission layer and the second electrode,
the electron transport region comprises an electron transport layer and an electron injection layer, and
the electron transport layer comprises at least one selected from an alkaline metal complex and an alkaline earth-metal complex.

17. The organic light-emitting device of claim 1, wherein
the organic layer comprises an electron transport region between the emission layer and the second electrode,
the electron transport region comprises an electron transport layer and an electron injection layer, and
the electron injection layer comprises an alkaline metal, an alkaline earth metal, a rare-earth metal, an alkaline metal compound, an alkaline earth-metal compound, a rare-earth metal compound, an alkaline metal complex, an alkaline earth-metal complex, a rare-earth metal complex, or a combination thereof.

18. The organic light-emitting device of claim 1, wherein
the organic layer comprises a hole transport region between the emission layer and the first electrode,
the hole transport region comprises a p-dopant, and
the p-dopant has a lowest unoccupied molecular orbital (LUMO) energy level of −3.5 eV or less.

19. The organic light-emitting device of claim 18, wherein
the p-dopant comprises a cyano group-containing compound.

20. The organic light-emitting device of claim 1, wherein
the emission layer is a first-color-light emission layer,
the organic layer further comprises i) at least one second-color-light emission layer, wherein the first color light and the second color light are identical to or different from each other, or ii) at least one second-color-light emission layer and at least one third-color-light-emission layer, wherein the first color light, the second color light, and third color light are identical to or different from one another, and
when the organic light-emitting device operates, mixed light comprising the first color light and the second color light is emitted, or mixed light comprising the first colorlight, the second color light, and the third color light is emitted.
